(19) United States
(12) Patent Application Publication
(10) Pub. No.: US 2017/0110669 A1
(43) Pub. Date: Apr. 20, 2017

(54) ORGANIC LIGHT EMITTING DEVICE AND DISPLAY DEVICE HAVING THE SAME

(71) Applicant: SAMSUNG DISPLAY CO., LTD., Yongin-si (KR)

(72) Inventor: Jahyun IM, Yongin-si (KR)

(21) Appl. No.: 15/293,641

(22) Filed: Oct. 14, 2016

(30) Foreign Application Priority Data
Oct. 20, 2015 (KR) 10-2015-0146298

(51) Int. Cl. H01L 51/00; C09K 11/06; C09K 11/02

(52) U.S. Cl. CPC H01L 51/0071; C09K 11/025; C09K 11/06; H01L 51/0052; H01L 51/0054; H01L 51/0072; H01L 51/0058; H01L 51/0061; H01L 51/006; H01L 51/0067; H01L 51/5206

(57) ABSTRACT

An organic light emitting device and a display device, the organic light emitting device including an anode; a hole transport region on the anode; an emission layer provided on the hole transport region, the emission layer including a first host and a dopant; a first host layer on the emission layer, the first host layer including a second host; an electron transport region on the first host layer; and a cathode on the electron transport region, wherein the second host is represented by the following Formula 1:

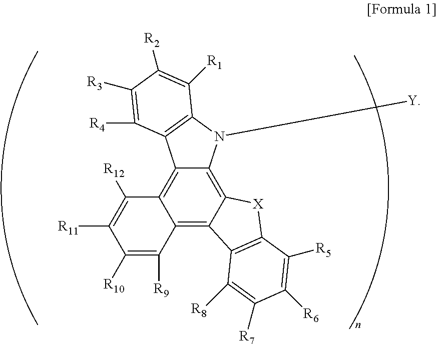

### CROSS-REFERENCE TO RELATED APPLICATION

Korean Patent Application No. 10-2015-0146298, filed on Oct. 20, 2015, in the Korean Intellectual Property Office, and entitled: “Organic Light Emitting Device and Display Device Having the Same,” is incorporated by reference herein in its entirety.

### BACKGROUND

1. Field

Embodiments relate to an organic light emitting device and a display device having the same.

2. Description of the Related Art

Flat panel display devices may be mainly classified as a light emitting type and a light receiving type. The light emitting type may include a flat cathode ray tube, a plasma display panel, and an organic light emitting display (OLED). The OLED is a self-luminescent display and has wide viewing angles, good contrast, and rapid response times.

Accordingly, the OLED may be applied to display devices for mobile devices such as digital cameras, video cameras, camcorders, portable information terminals, smart phones, ultra slim laptops, tablet personal computers, and flexible display devices, large-sized electronic products such as ultra slim televisions, or large-sized electric products, and receives much attention.

The OLED may reproduce colors on the basis of emitting light via the recombination of holes injected from an anode and electrons injected from a cathode in an emission layer, and light is emitted by the transition of excitons obtained from the recombination of the injected holes and electrons from an excited state to a ground state.

### SUMMARY

Embodiments are directed to an organic light emitting device and a display device having the same.

The present disclosure provides an organic light emitting device maintaining emission efficiency at high temperatures.

The present disclosure also provides a display device including the organic light emitting device maintaining emission efficiency at high temperatures.

An embodiment provides an organic light emitting device includes an anode, a hole transport region, an emission layer, a first host layer, an electron transport region, and a cathode. The hole transport region is provided on the anode. The emission layer is provided on the hole transport region and includes a first host and a dopant. The first host layer is provided on the emission layer and includes a second host. The electron transport region is provided on the first host layer. The cathode is provided on the electron transport region. The second host is represented by the following Formula 1.

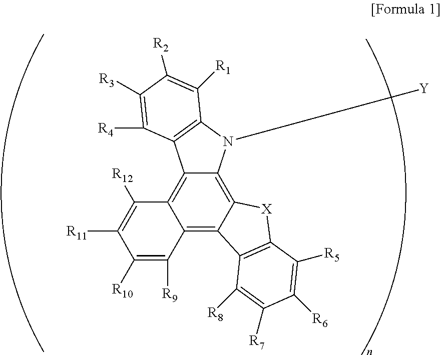

In Formula 1, R₁, R₂, R₃, R₄, R₅, R₆, R₇, R₈, R₉, R₁₀, and R₁₂ are each independently a hydrogen atom, a halogen atom, a cyano group, an alkoxy group, a thiol group, a substituted or unsubstituted alkyl group having 1 to 50 carbon atoms, a substituted or unsubstituted alkoxy group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphor, or silicon, a substituted or unsubstituted heteroaryl group having 5 to 60 carbon atoms and including at least one of sulfur, nitrogen, oxygen, phosphor, or silicon, or a substituted or unsubstituted heteroaryloxy group having 5 to 60 carbon atoms and including at least one of sulfur, nitrogen, oxygen, phosphor, or silicon, X is sulfur, oxygen, or silicon, Y is a hydrogen atom, a halogen atom, a cyano group, an alkoxy group, a thiol group, a substituted or unsubstituted alkyl group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphor, or silicon, a substituted or unsubstituted heteroaryl group having 5 to 60 carbon atoms and including at least one of sulfur, nitrogen, oxygen, phosphor, or silicon, or a substituted or unsubstituted heteroaryloxy group having 5 to 60 carbon atoms and including at least one of sulfur, nitrogen, oxygen, phosphor, or silicon, and n is an integer from 1 to 3.

In an embodiment, the first host layer may not include the dopant.

In an embodiment, R₁, R₂, R₃, R₄, R₅, R₆, R₇, R₈, R₉, R₁₀, R₁₁, or R₁₂ may be combined with an adjacent group to form a ring.

In an embodiment, the second host may include at least one compound of the compounds in the following Compound Group 1.

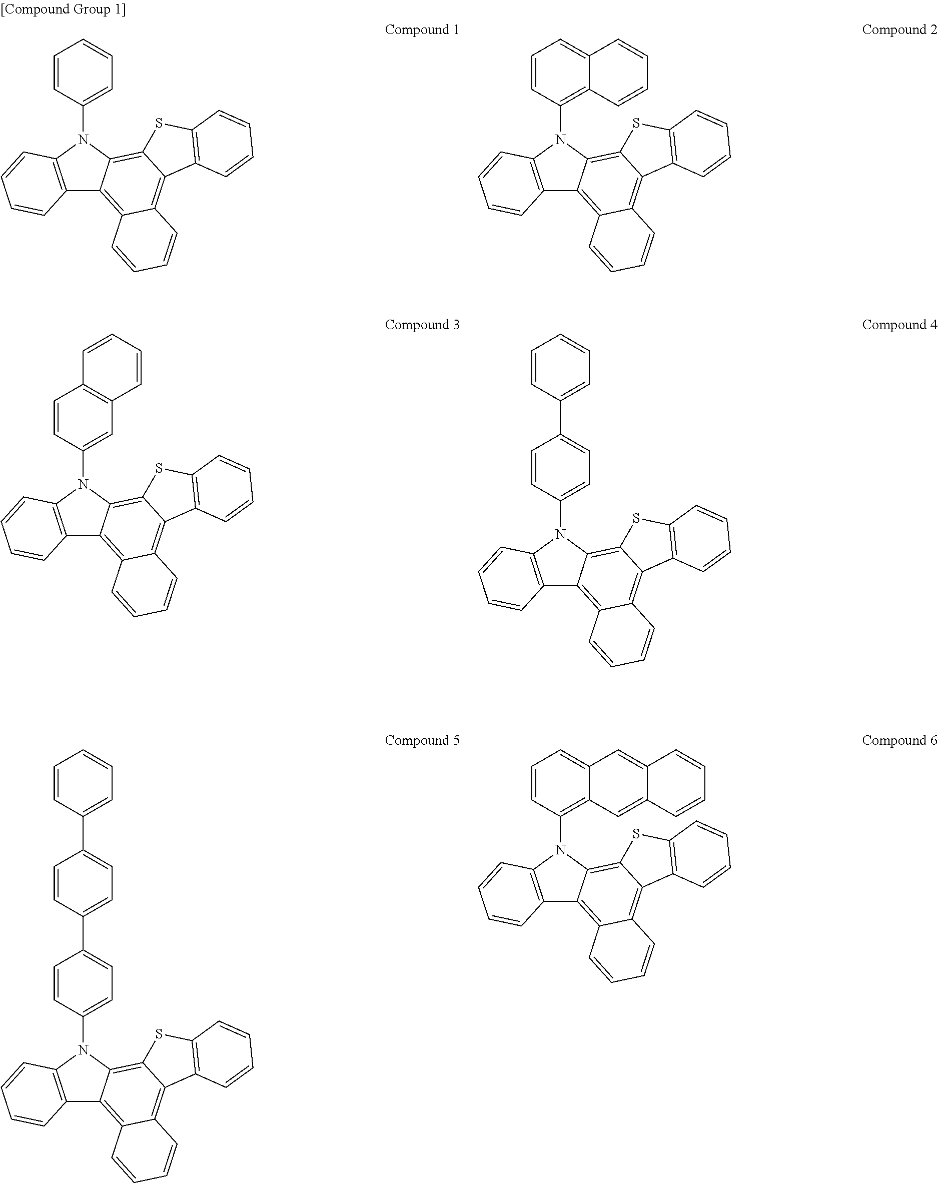 [SMILES: c1ccc(-n2c3ccccc3c3c4ccccc4c4c5ccccc5sc4c32)cc1 ; c1ccc2c(-n3c4ccccc4c4c5ccccc5c5c6ccccc6sc5c43)cccc2c1 ; c1ccc2cc(-n3c4ccccc4c4c5ccccc5c5c6ccccc6sc5c43)ccc2c1 ; c1ccc(-c2ccc(-n3c4ccccc4c4c5ccccc5c5c6ccccc6sc5c43)cc2)cc1 ; c1ccc(-c2ccc(-c3ccc(-n4c5ccccc5c5c6ccccc6c6c7ccccc7sc6c54)cc3)cc2)cc1 ; c1ccc2cc3c(-n4c5ccccc5c5c6ccccc6c6c7ccccc7sc6c54)cccc3cc2c1]

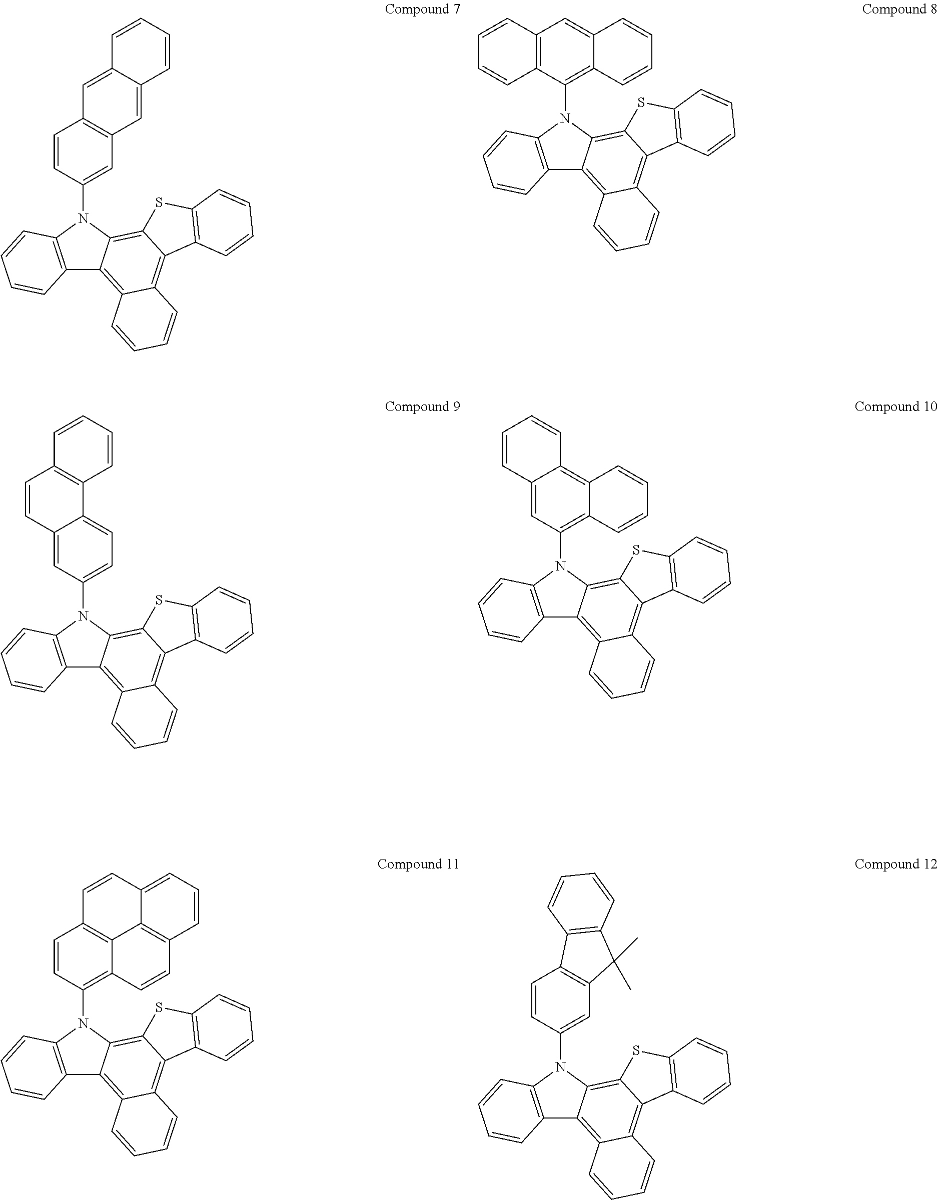 [SMILES: c1ccc2cc3cc(-n4c5ccccc5c5c6ccccc6c6c7ccccc7sc6c54)ccc3cc2c1 ; c1ccc2c(-n3c4ccccc4c4c5ccccc5c5c6ccccc6sc5c43)c3ccccc3cc2c1 ; c1ccc2c(c1)ccc1cc(-n3c4ccccc4c4c5ccccc5c5c6ccccc6sc5c43)ccc12 ; c1ccc2c(c1)cc(-n1c3ccccc3c3c4ccccc4c4c5ccccc5sc4c31)c1ccccc12 ; c1cc2ccc3ccc(-n4c5ccccc5c5c6ccccc6c6c7ccccc7sc6c54)c4ccc(c1)c2c34 ; CC1(C)c2ccccc2-c2ccc(-n3c4ccccc4c4c5ccccc5c5c6ccccc6sc5c43)cc21]

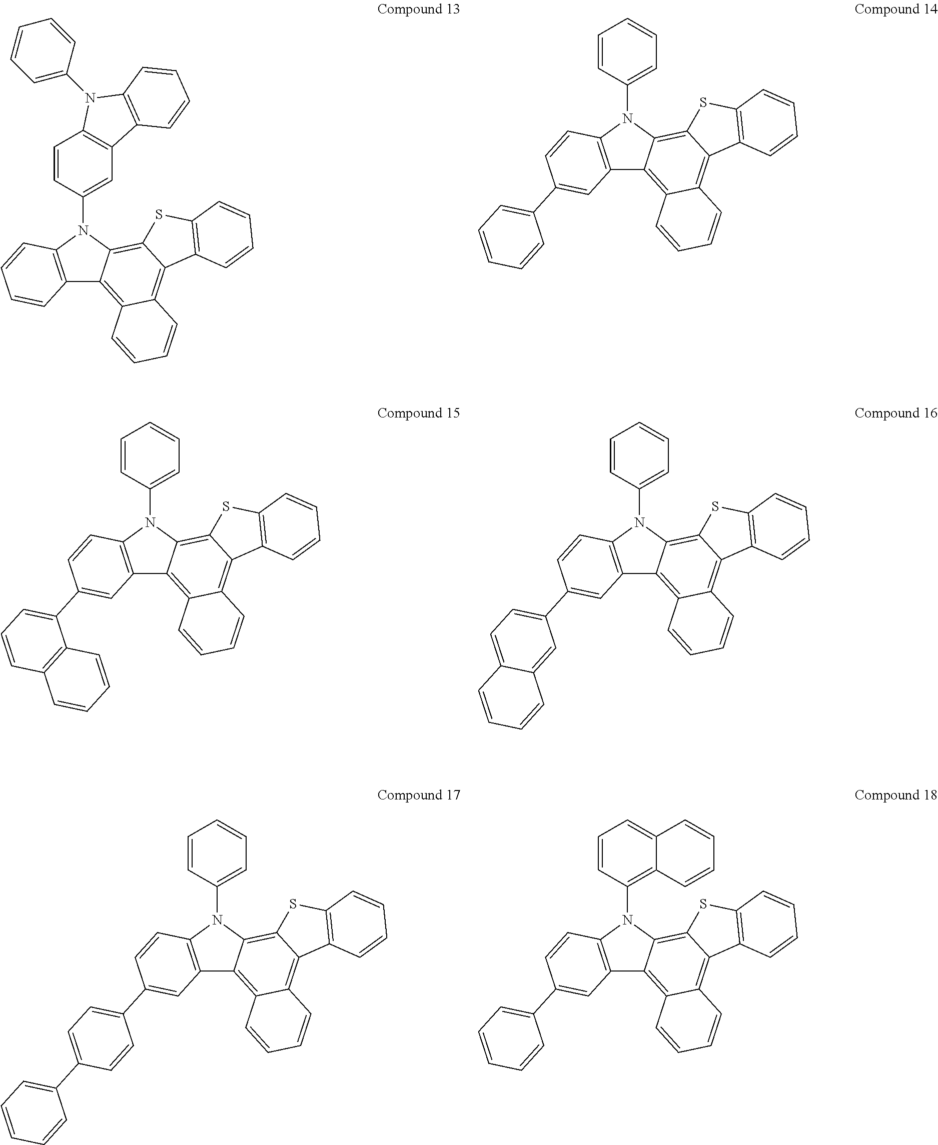 [SMILES: c1ccc(-n2c3ccccc3c3cc(-n4c5ccccc5c5c6ccccc6c6c7ccccc7sc6c54)ccc32)cc1 ; c1ccc(-c2ccc3c(c2)c2c4ccccc4c4c5ccccc5sc4c2n3-c2ccccc2)cc1 ; c1ccc(-n2c3ccc(-c4cccc5ccccc45)cc3c3c4ccccc4c4c5ccccc5sc4c32)cc1 ; c1ccc(-n2c3ccc(-c4ccc5ccccc5c4)cc3c3c4ccccc4c4c5ccccc5sc4c32)cc1 ; c1ccc(-c2ccc(-c3ccc4c(c3)c3c5ccccc5c5c6ccccc6sc5c3n4-c3ccccc3)cc2)cc1 ; c1ccc(-c2ccc3c(c2)c2c4ccccc4c4c5ccccc5sc4c2n3-c2cccc3ccccc23)cc1]

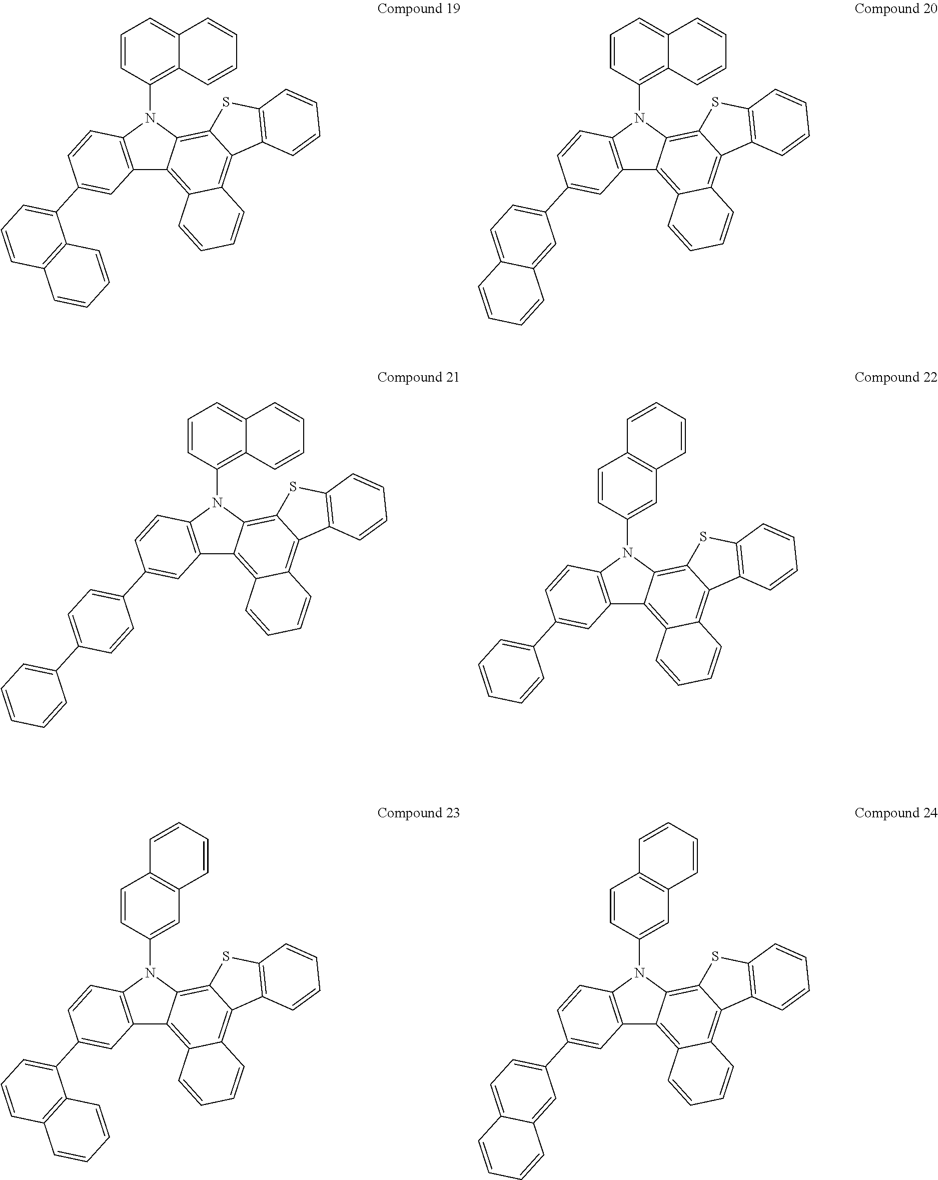 [SMILES: c1ccc2c(-c3ccc4c(c3)c3c5ccccc5c5c6ccccc6sc5c3n4-c3cccc4ccccc34)cccc2c1 ; c1ccc2cc(-c3ccc4c(c3)c3c5ccccc5c5c6ccccc6sc5c3n4-c3cccc4ccccc34)ccc2c1 ; c1ccc(-c2ccc(-c3ccc4c(c3)c3c5ccccc5c5c6ccccc6sc5c3n4-c3cccc4ccccc34)cc2)cc1 ; c1ccc(-c2ccc3c(c2)c2c4ccccc4c4c5ccccc5sc4c2n3-c2ccc3ccccc3c2)cc1 ; c1ccc2cc(-n3c4ccc(-c5cccc6ccccc56)cc4c4c5ccccc5c5c6ccccc6sc5c43)ccc2c1 ; c1ccc2cc(-c3ccc4c(c3)c3c5ccccc5c5c6ccccc6sc5c3n4-c3ccc4ccccc4c3)ccc2c1]

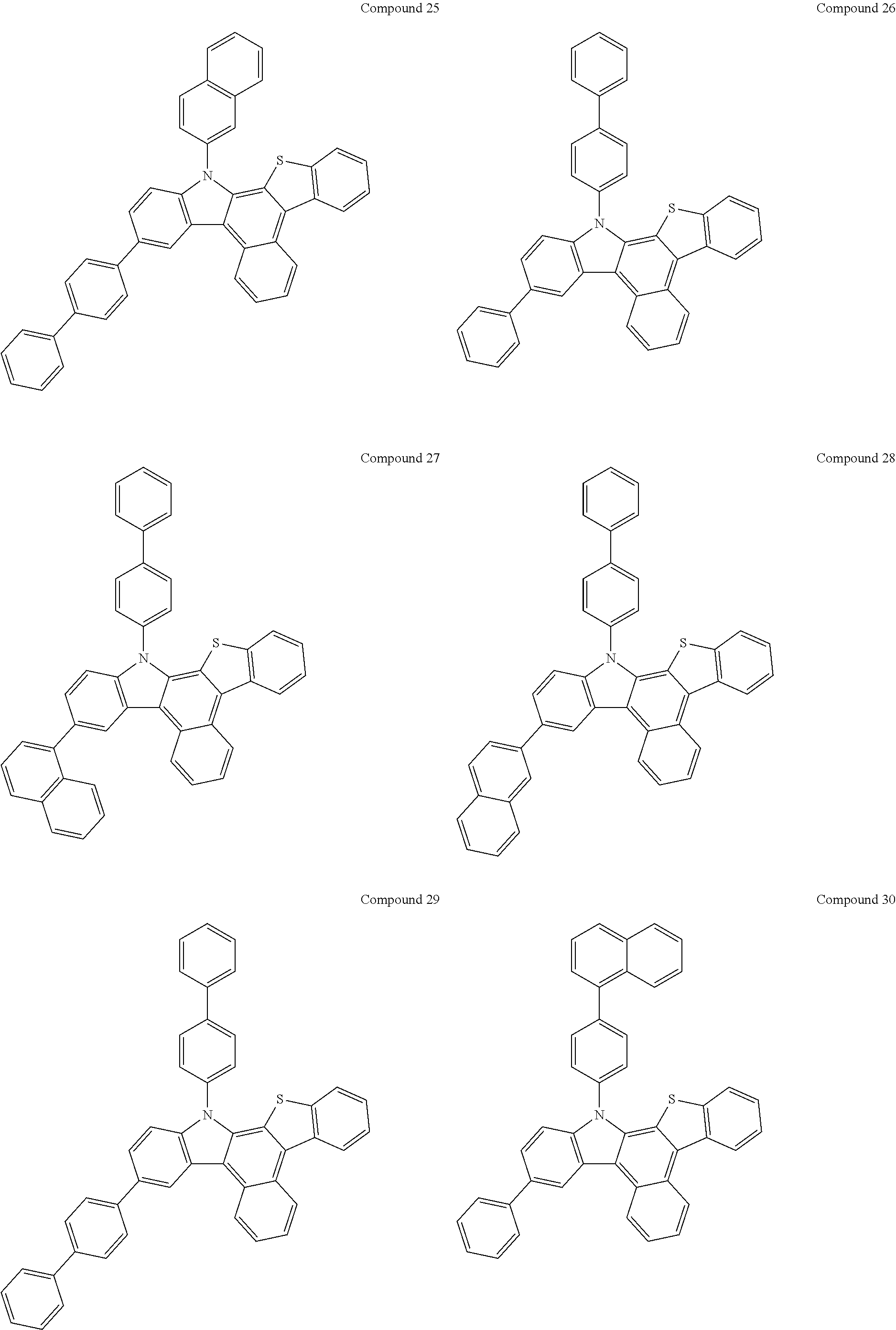 [SMILES: c1ccc(-c2ccc(-c3ccc4c(c3)c3c5ccccc5c5c6ccccc6sc5c3n4-c3ccc4ccccc4c3)cc2)cc1 ; c1ccc(-c2ccc(-n3c4ccc(-c5ccccc5)cc4c4c5ccccc5c5c6ccccc6sc5c43)cc2)cc1 ; c1ccc(-c2ccc(-n3c4ccc(-c5cccc6ccccc56)cc4c4c5ccccc5c5c6ccccc6sc5c43)cc2)cc1 ; c1ccc(-c2ccc(-n3c4ccc(-c5ccc6ccccc6c5)cc4c4c5ccccc5c5c6ccccc6sc5c43)cc2)cc1 ; c1ccc(-c2ccc(-c3ccc4c(c3)c3c5ccccc5c5c6ccccc6sc5c3n4-c3ccc(-c4ccccc4)cc3)cc2)cc1 ; c1ccc(-c2ccc3c(c2)c2c4ccccc4c4c5ccccc5sc4c2n3-c2ccc(-c3cccc4ccccc34)cc2)cc1]

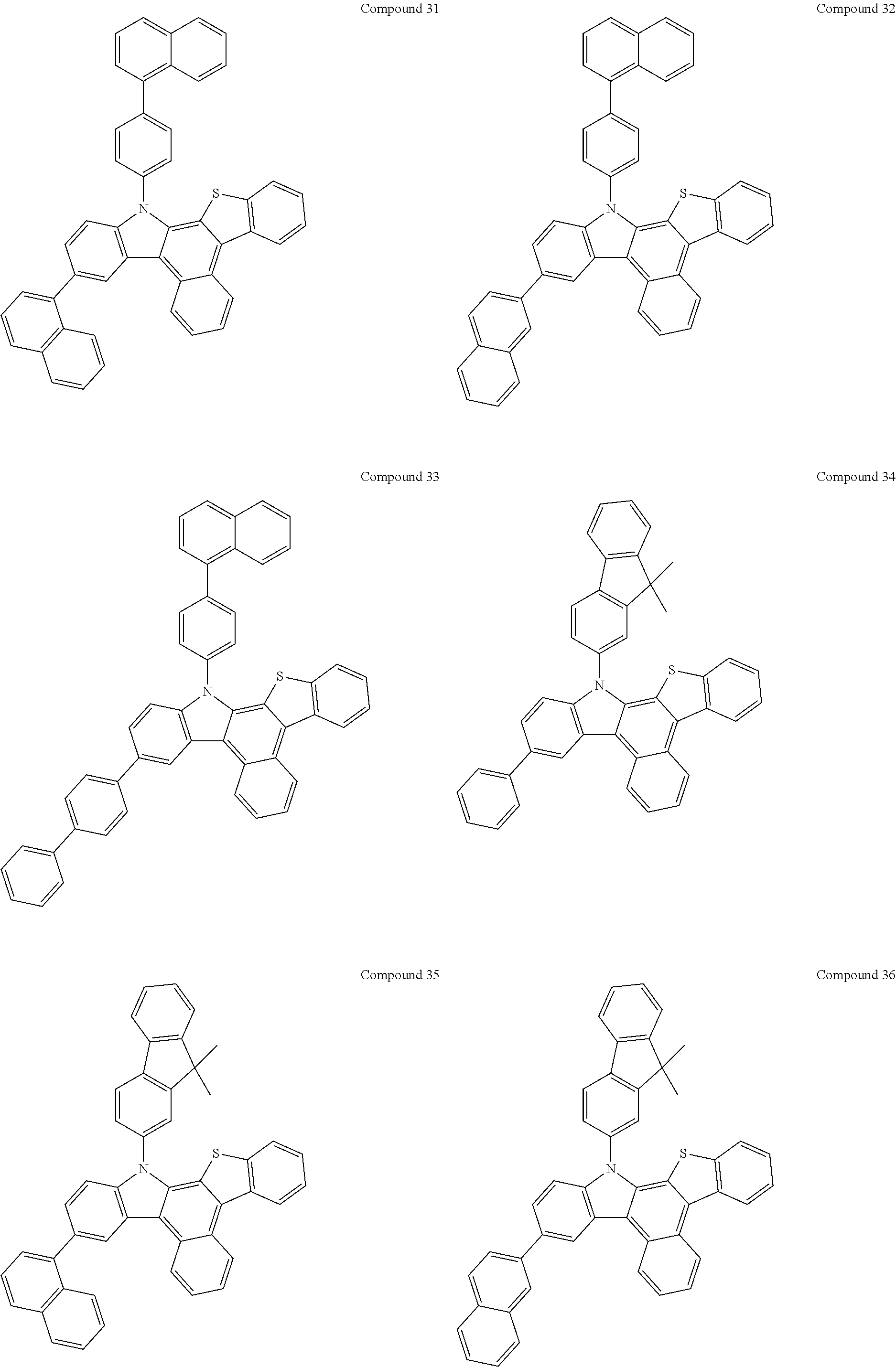 [SMILES: c1ccc2c(-c3ccc(-n4c5ccc(-c6cccc7ccccc67)cc5c5c6ccccc6c6c7ccccc7sc6c54)cc3)cccc2c1 ; c1ccc2cc(-c3ccc4c(c3)c3c5ccccc5c5c6ccccc6sc5c3n4-c3ccc(-c4cccc5ccccc45)cc3)ccc2c1 ; c1ccc(-c2ccc(-c3ccc4c(c3)c3c5ccccc5c5c6ccccc6sc5c3n4-c3ccc(-c4cccc5ccccc45)cc3)cc2)cc1 ; CC1(C)c2ccccc2-c2ccc(-n3c4ccc(-c5ccccc5)cc4c4c5ccccc5c5c6ccccc6sc5c43)cc21 ; CC1(C)c2ccccc2-c2ccc(-n3c4ccc(-c5cccc6ccccc56)cc4c4c5ccccc5c5c6ccccc6sc5c43)cc21 ; CC1(C)c2ccccc2-c2ccc(-n3c4ccc(-c5ccc6ccccc6c5)cc4c4c5ccccc5c5c6ccccc6sc5c43)cc21]

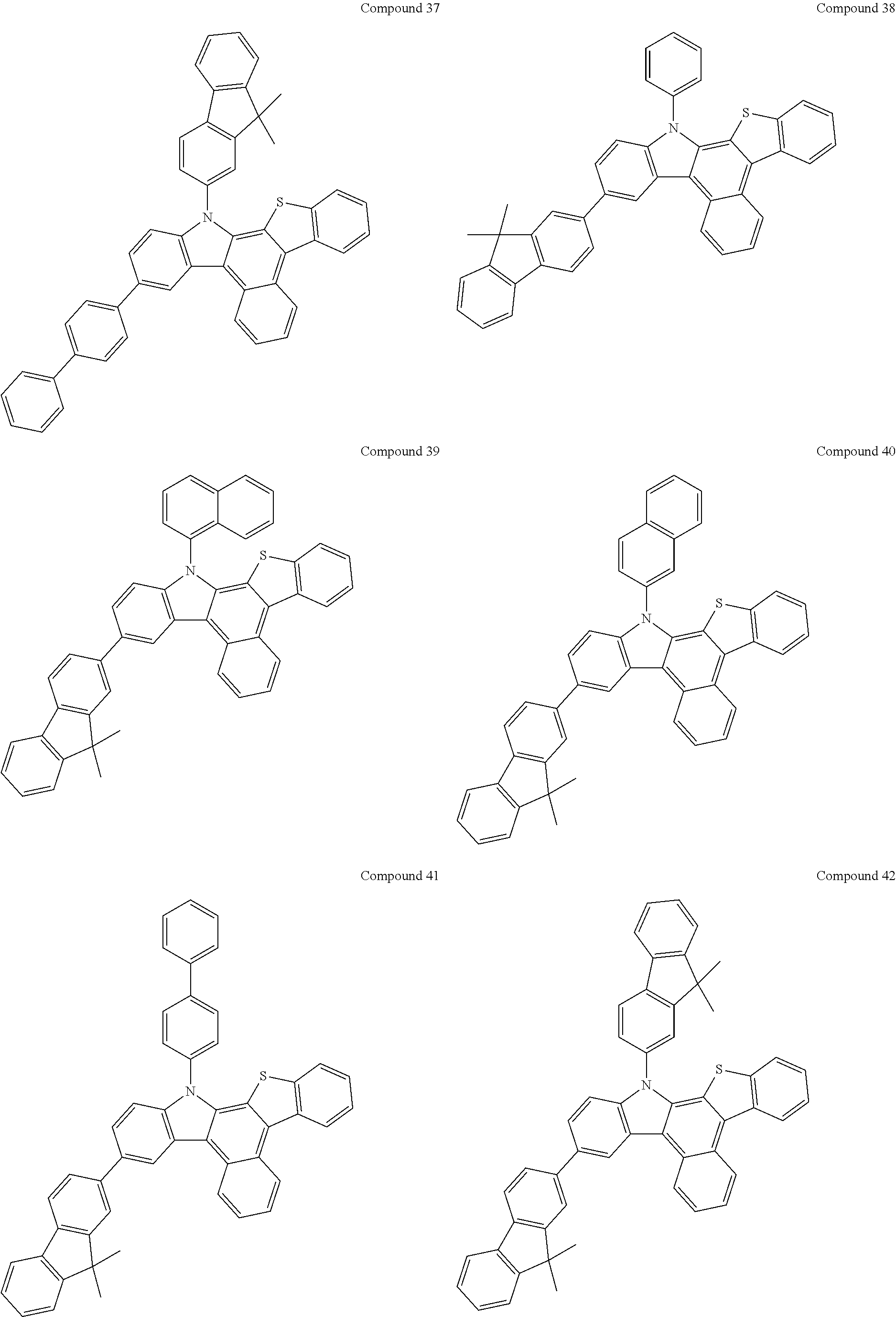

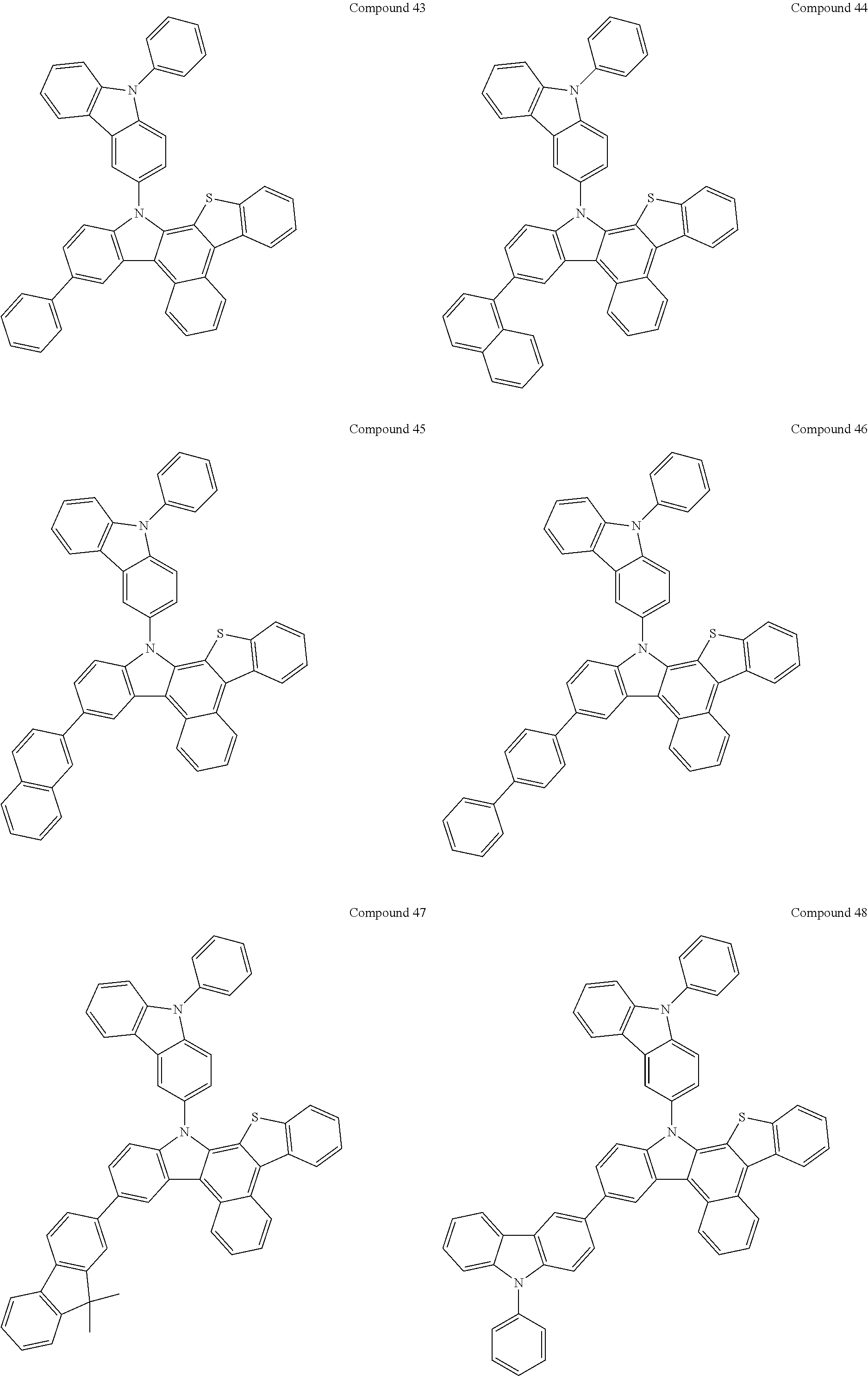

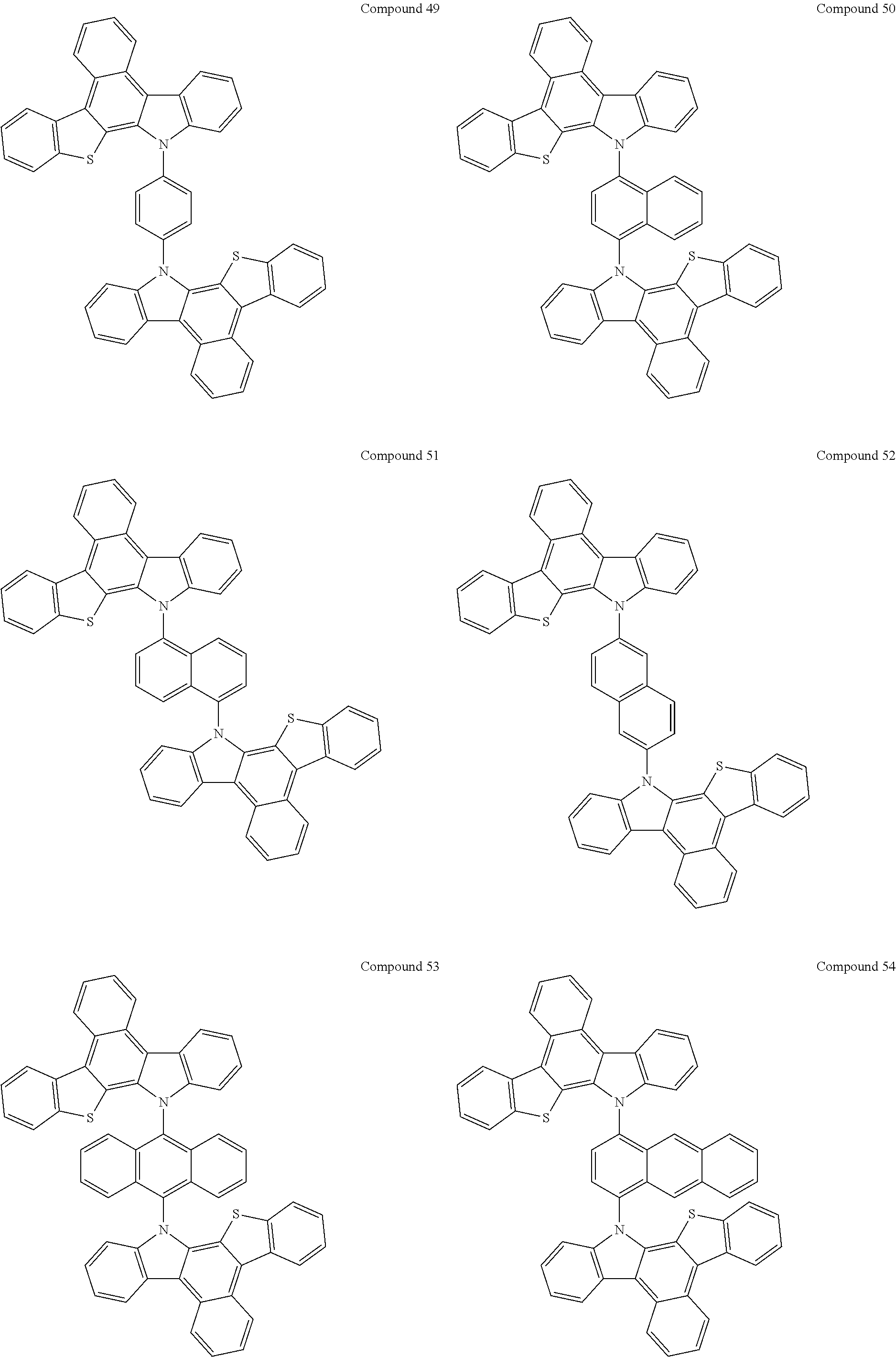

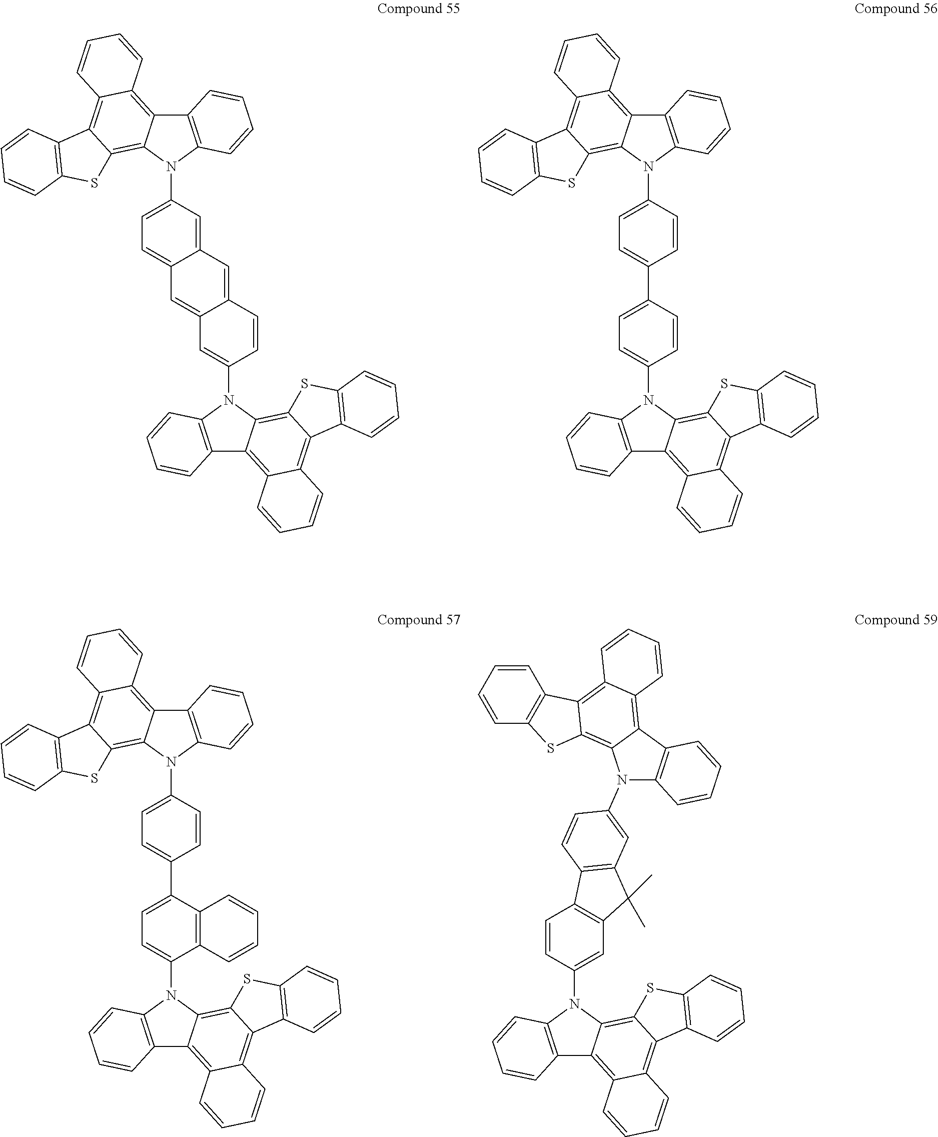 [SMILES: c1ccc2c(c1)sc1c2c2ccccc2c2c3ccccc3n(-c3ccc4cc5cc(-n6c7ccccc7c7c8ccccc8c8c9ccccc9sc8c76)ccc5cc4c3)c12 ; c1ccc2c(c1)sc1c2c2ccccc2c2c3ccccc3n(-c3ccc(-c4ccc(-n5c6ccccc6c6c7ccccc7c7c8ccccc8sc7c65)cc4)cc3)c12 ; c1ccc2c(c1)sc1c2c2ccccc2c2c3ccccc3n(-c3ccc(-c4ccc(-n5c6ccccc6c6c7ccccc7c7c8ccccc8sc7c65)c5ccccc45)cc3)c12 ; CC1(C)c2cc(-n3c4ccccc4c4c5ccccc5c5c6ccccc6sc5c43)ccc2-c2ccc(-n3c4ccccc4c4c5ccccc5c5c6ccccc6sc5c43)cc21]

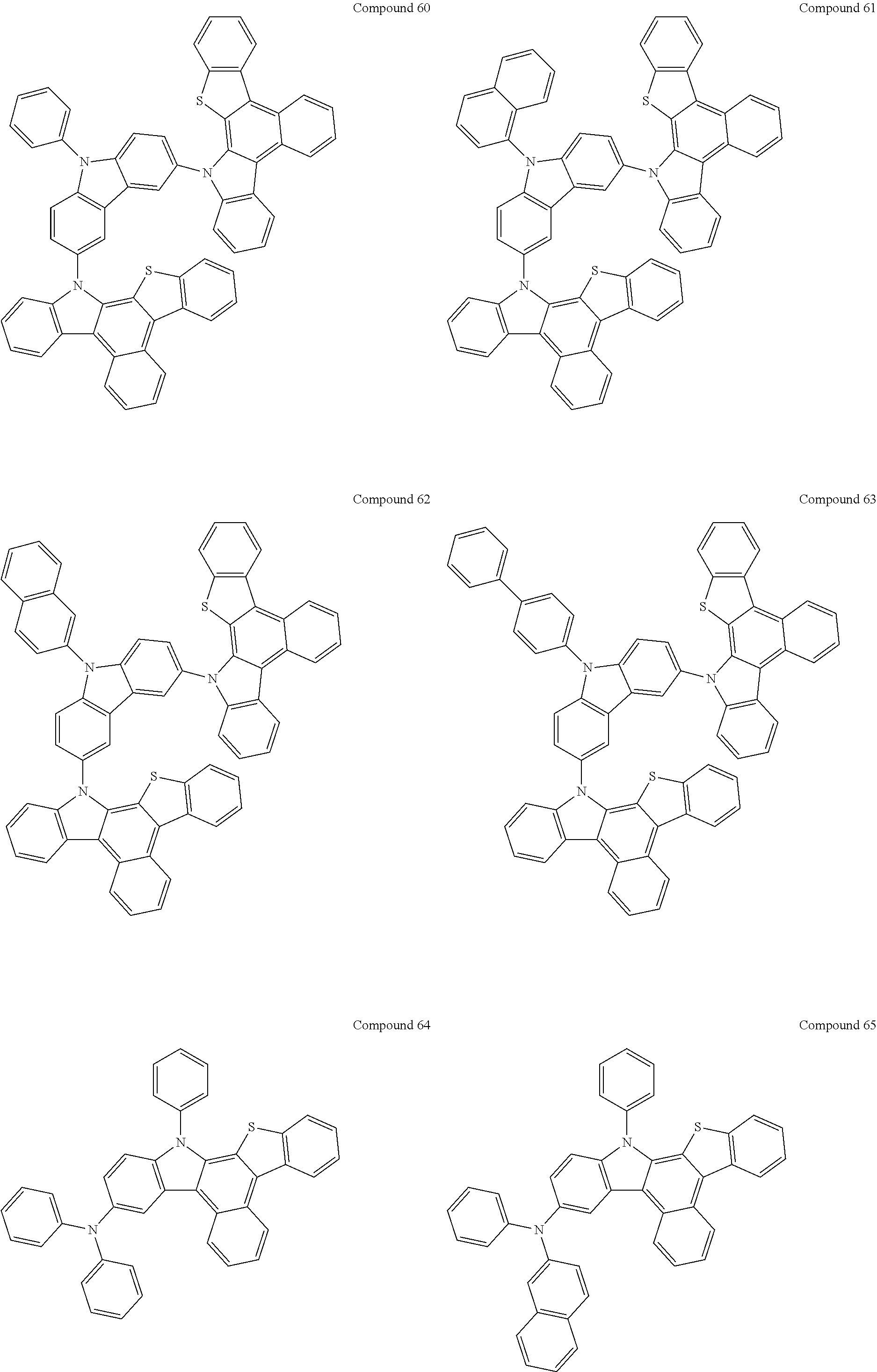

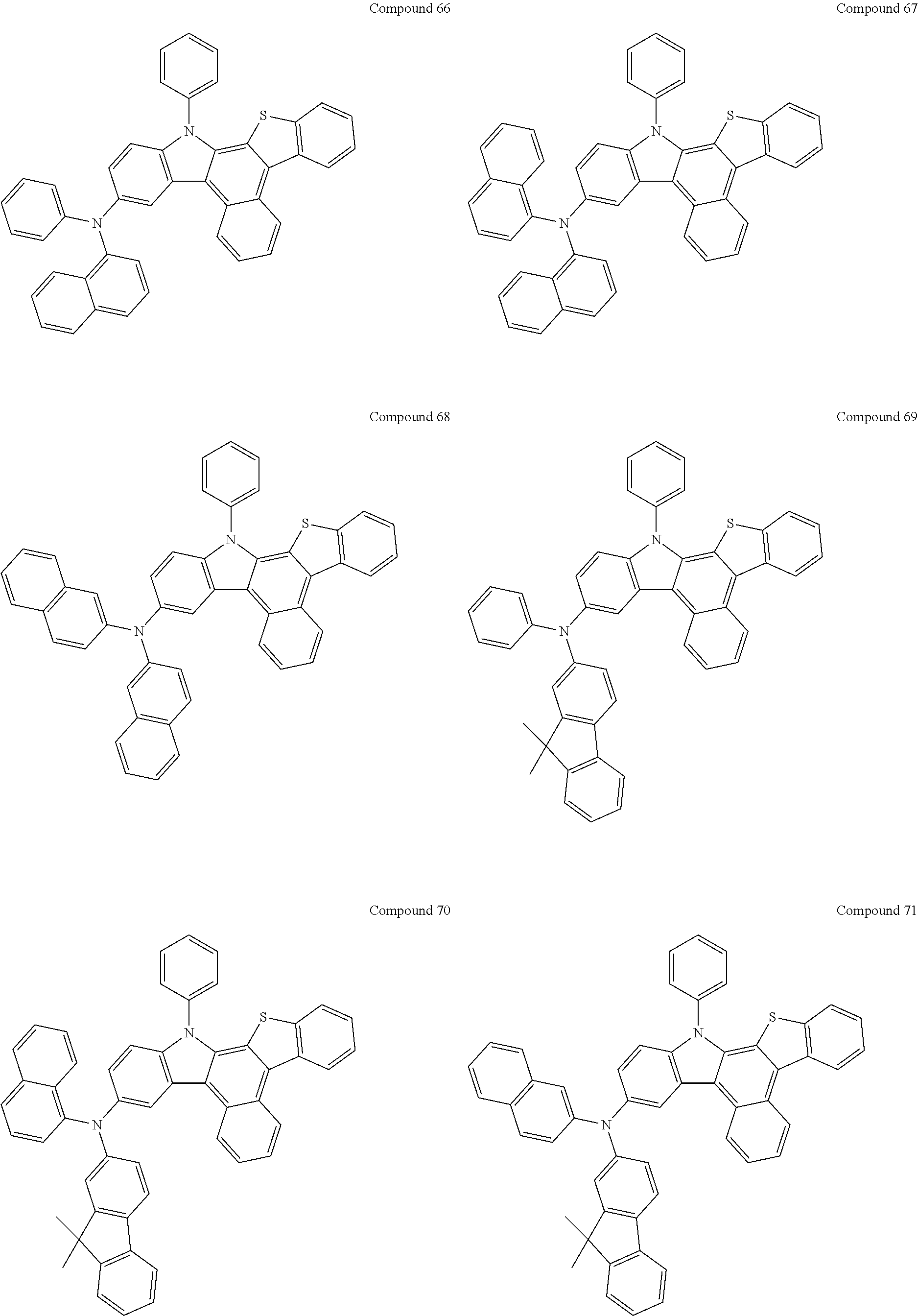

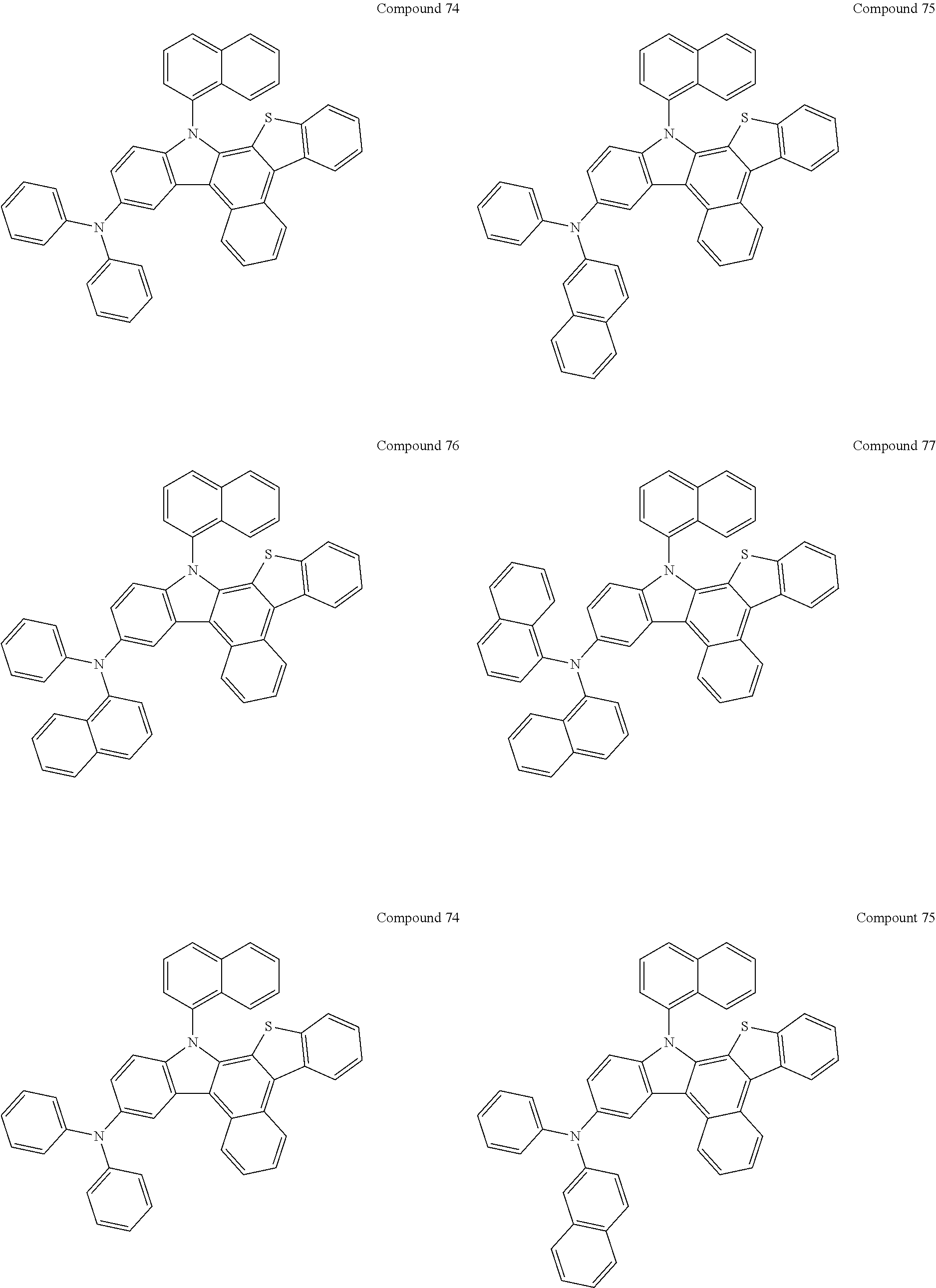 [SMILES: c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1 ; c1ccc(N(c2ccc3c(c2)c2c4ccccc4c4c5ccccc5sc4c2n3-c2cccc3ccccc23)c2cccc3ccccc23)cc1 ; c1ccc2c(N(c3ccc4c(c3)c3c5ccccc5c5c6ccccc6sc5c3n4-c3cccc4ccccc34)c3cccc4ccccc34)cccc2c1 ; c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1]

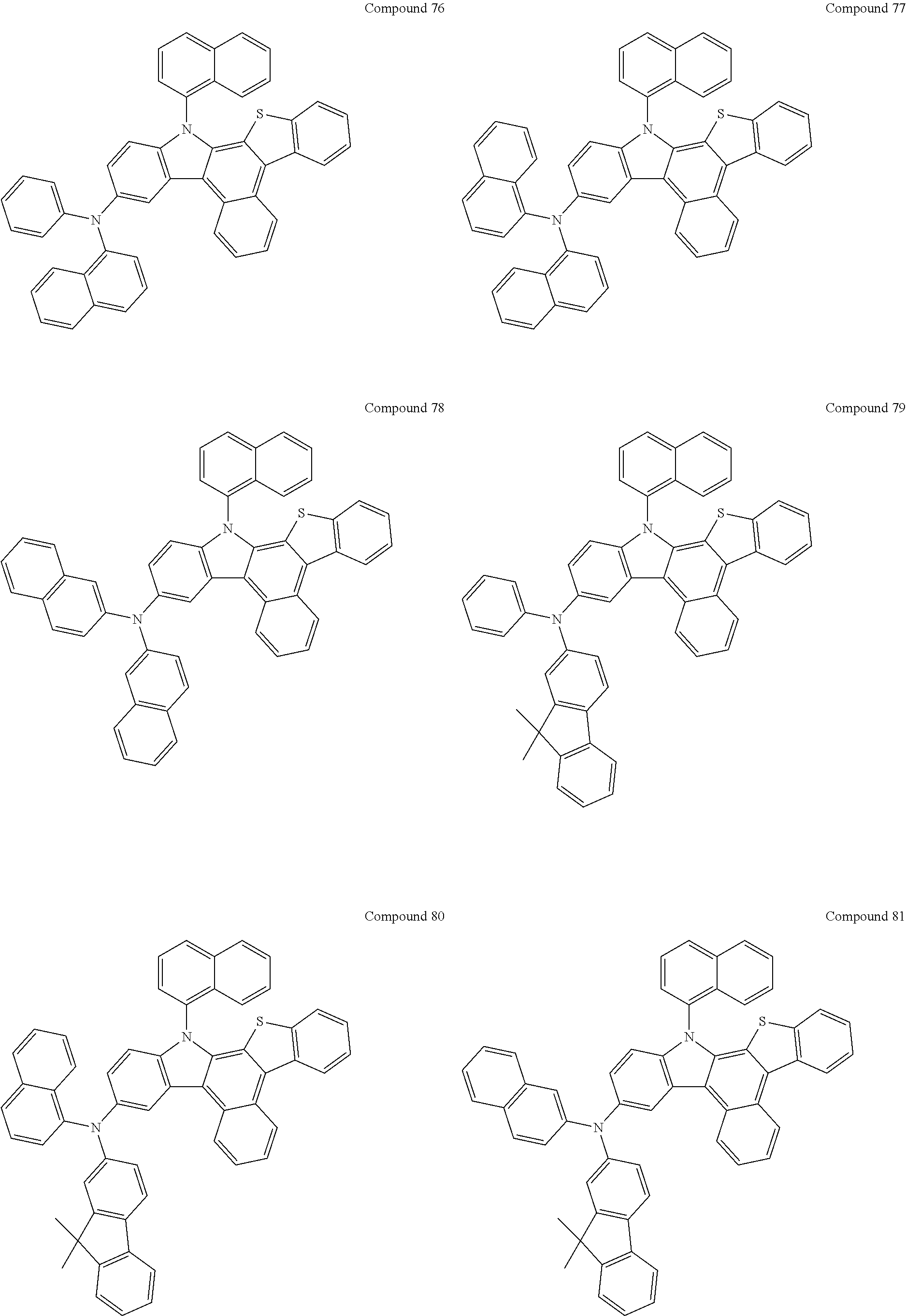

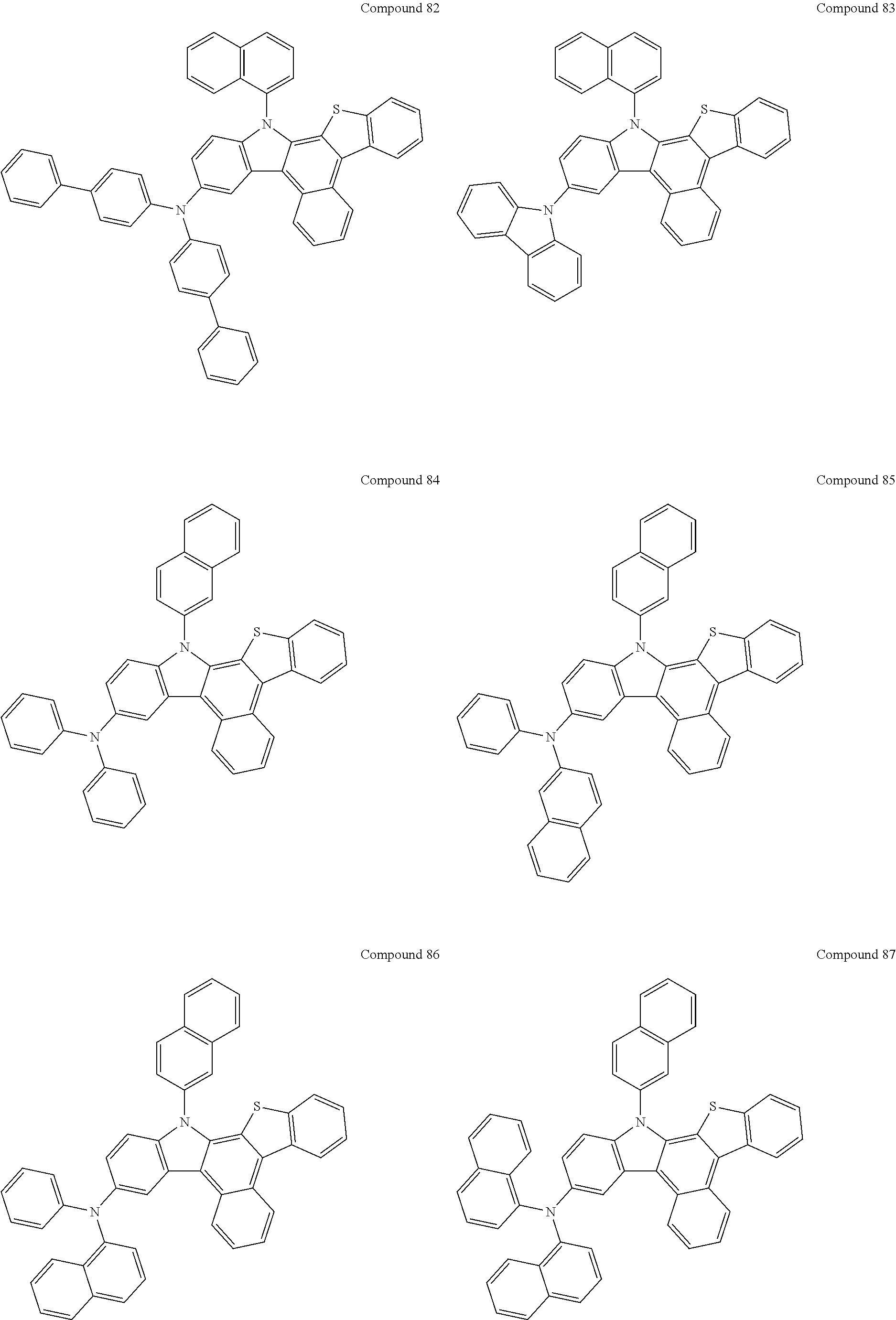

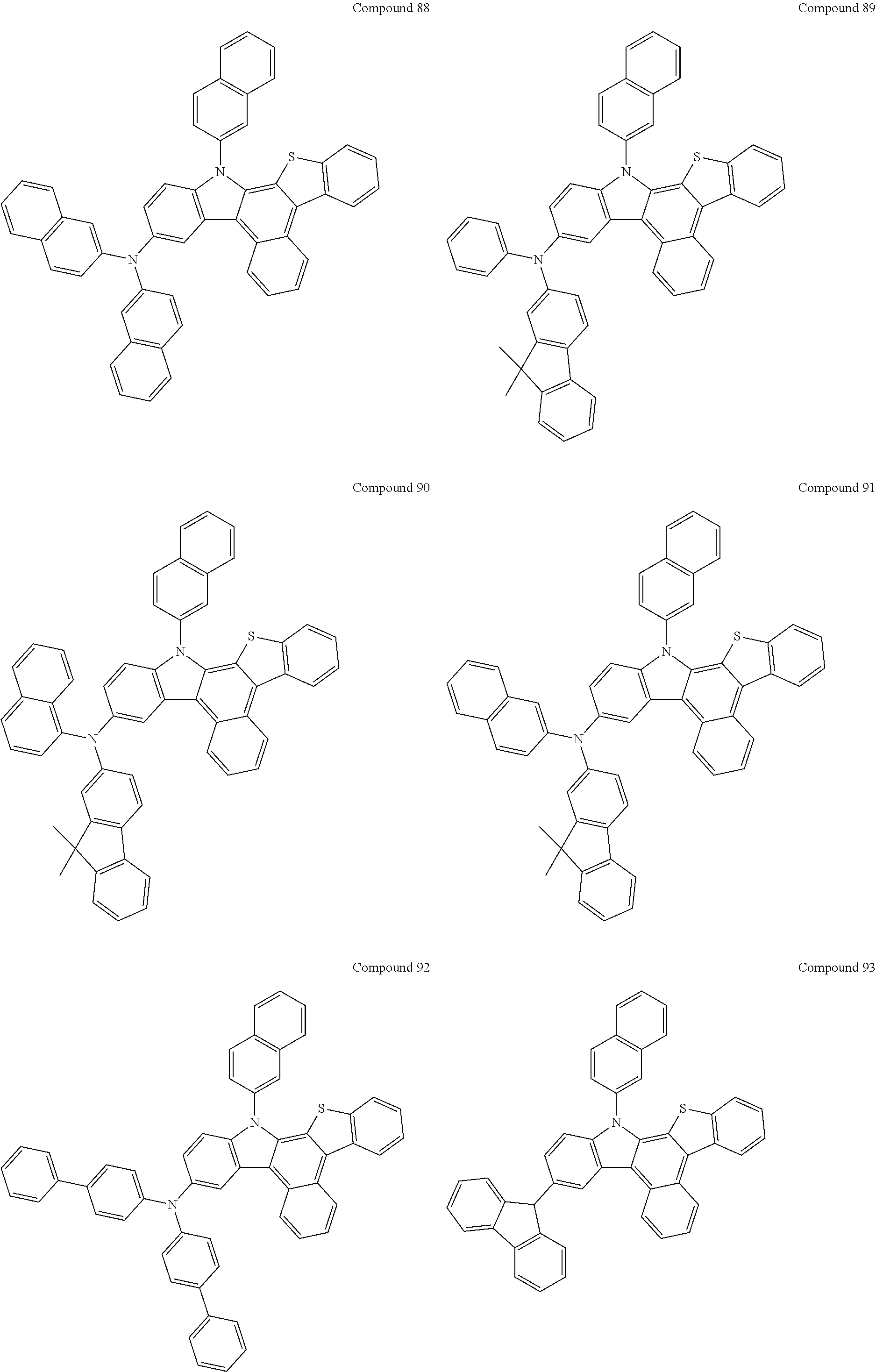

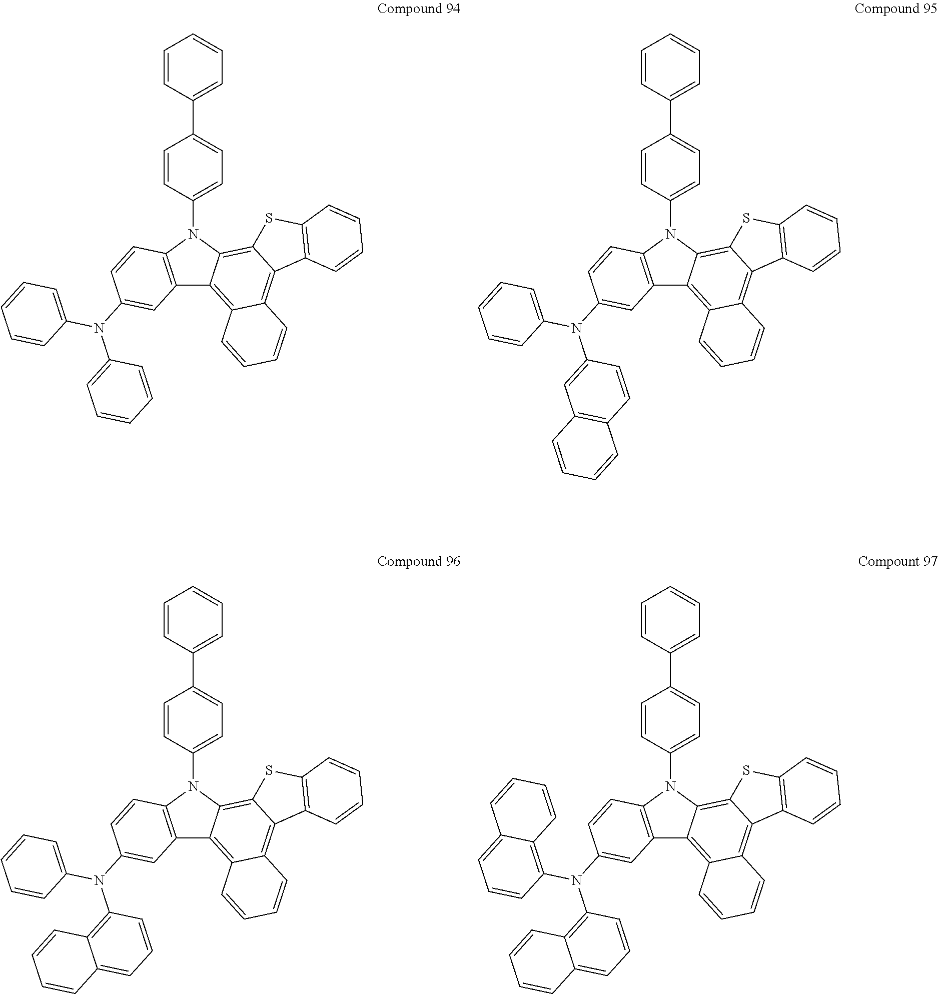 [SMILES: c1ccc(-c2ccc(-n3c4ccc(N(c5ccccc5)c5ccccc5)cc4c4c5ccccc5c5c6ccccc6sc5c43)cc2)cc1 ; c1ccc(-c2ccc(-n3c4ccc(N(c5ccccc5)c5ccc6ccccc6c5)cc4c4c5ccccc5c5c6ccccc6sc5c43)cc2)cc1 ; c1ccc(-c2ccc(-n3c4ccc(N(c5ccccc5)c5cccc6ccccc56)cc4c4c5ccccc5c5c6ccccc6sc5c43)cc2)cc1 ; c1ccc(-c2ccc(-n3c4ccc(N(c5cccc6ccccc56)c5cccc6ccccc56)cc4c4c5ccccc5c5c6ccccc6sc5c43)cc2)cc1]

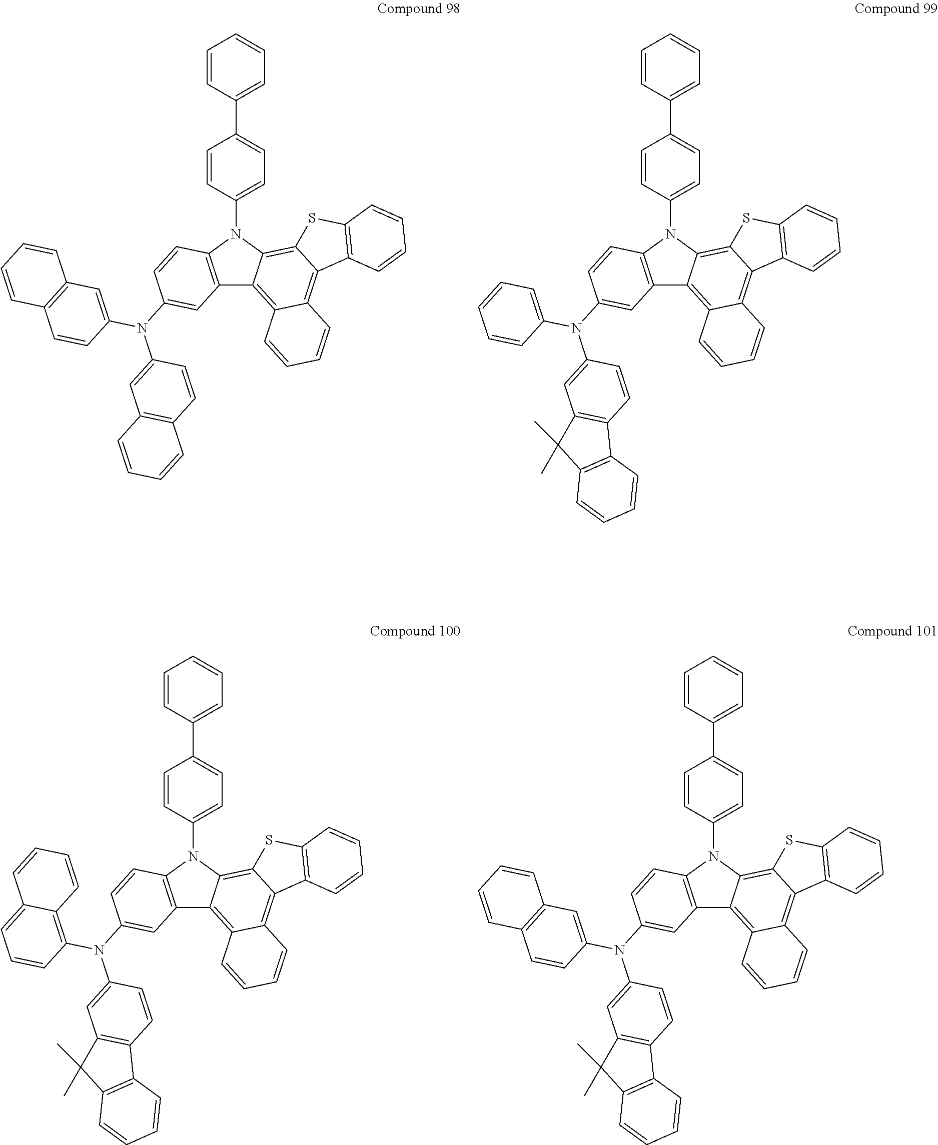 [SMILES: c1ccc(-c2ccc(-n3c4ccc(N(c5ccc6ccccc6c5)c5ccc6ccccc6c5)cc4c4c5ccccc5c5c6ccccc6sc5c43)cc2)cc1 ; CC1(C)c2ccccc2-c2ccc(N(c3ccccc3)c3ccc4c(c3)c3c5ccccc5c5c6ccccc6sc5c3n4-c3ccc(-c4ccccc4)cc3)cc21 ; CC1(C)c2ccccc2-c2ccc(N(c3ccc4c(c3)c3c5ccccc5c5c6ccccc6sc5c3n4-c3ccc(-c4ccccc4)cc3)c3cccc4ccccc34)cc21 ; CC1(C)c2ccccc2-c2ccc(N(c3ccc4ccccc4c3)c3ccc4c(c3)c3c5ccccc5c5c6ccccc6sc5c3n4-c3ccc(-c4ccccc4)cc3)cc21]

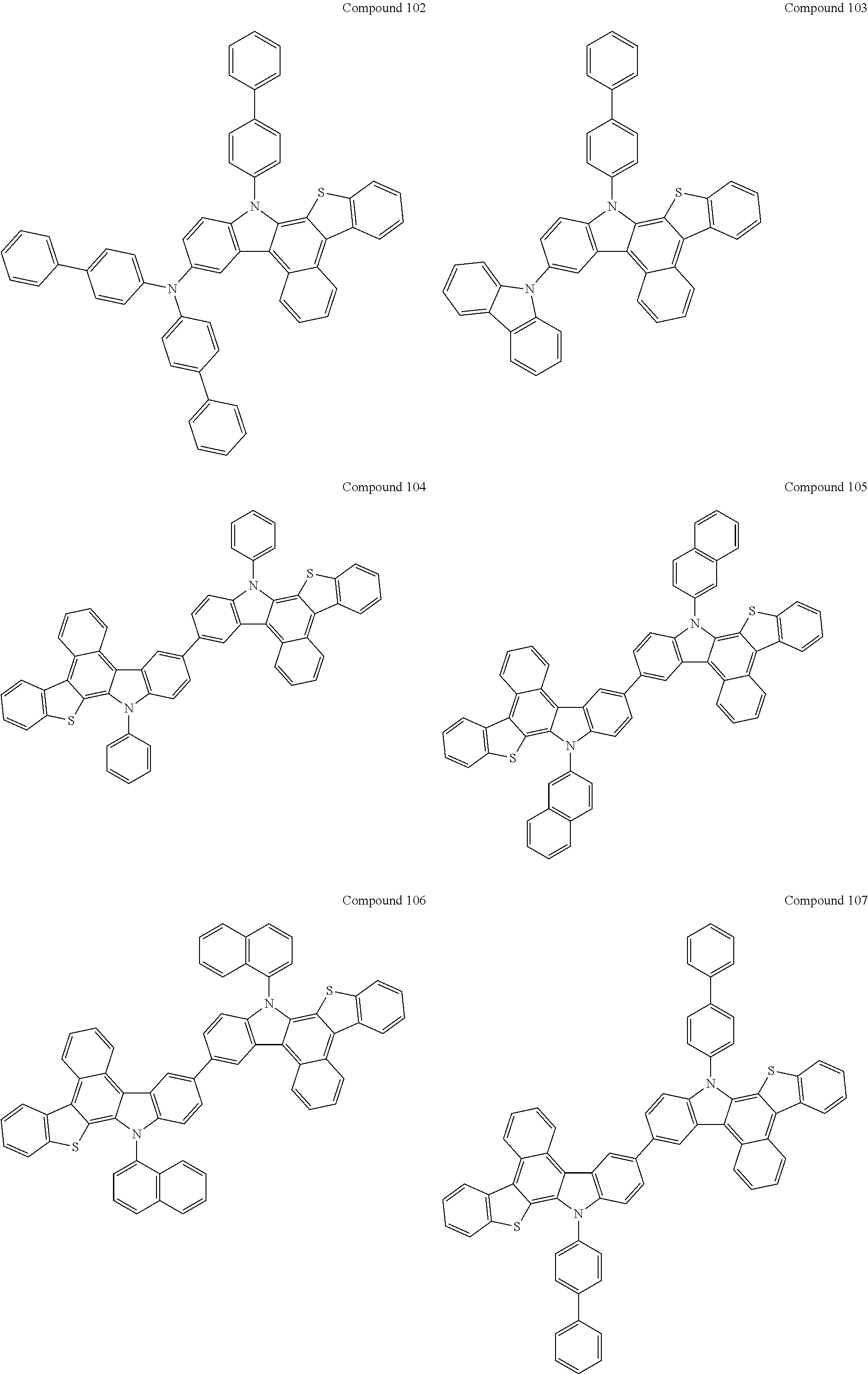

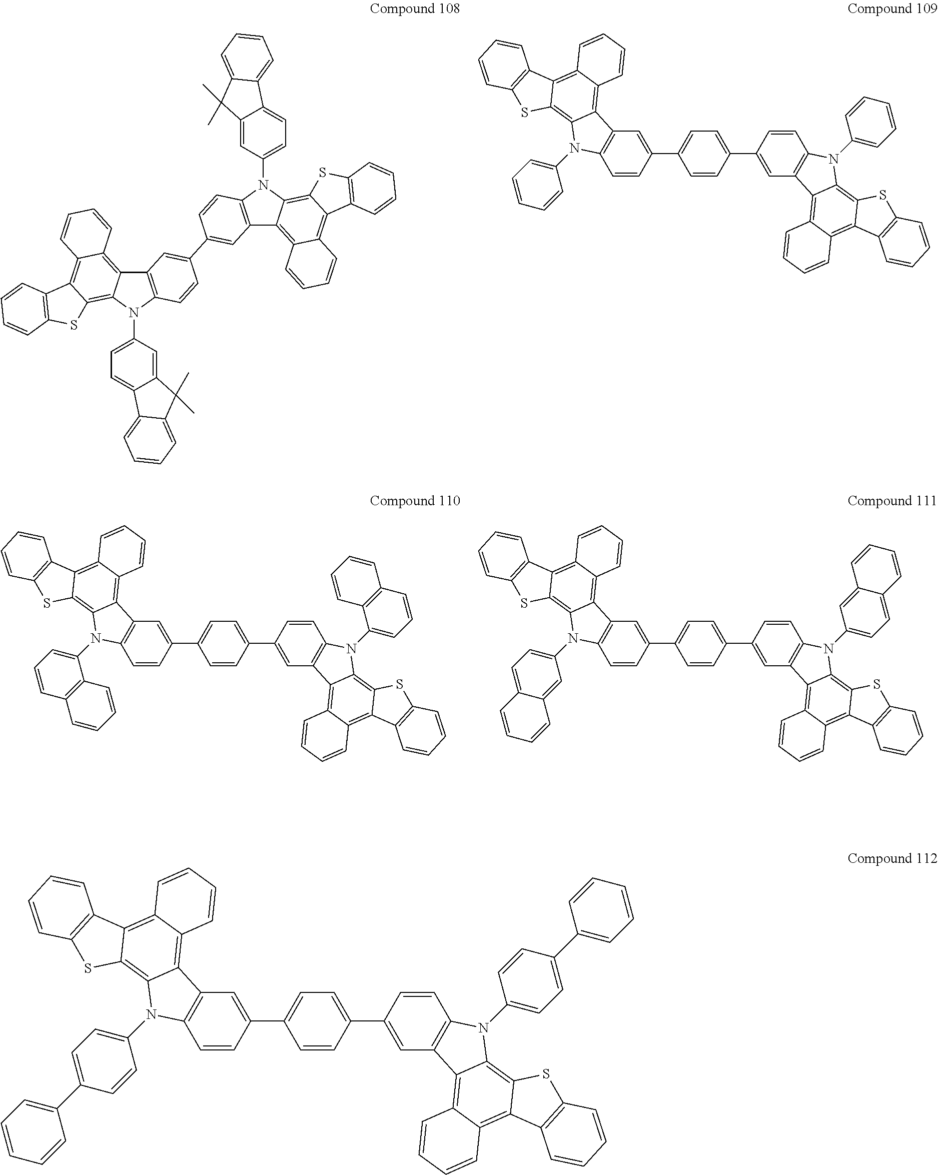

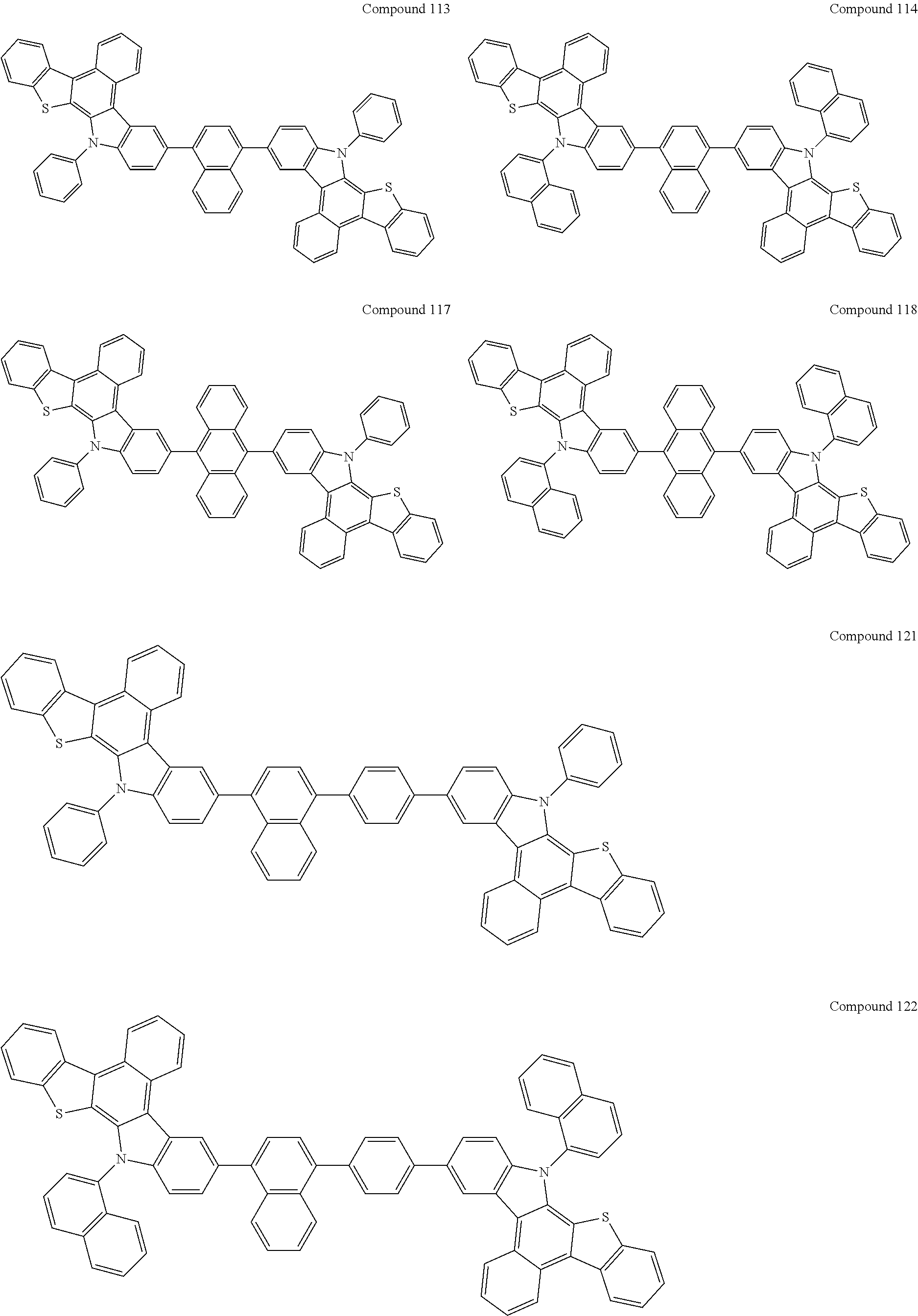

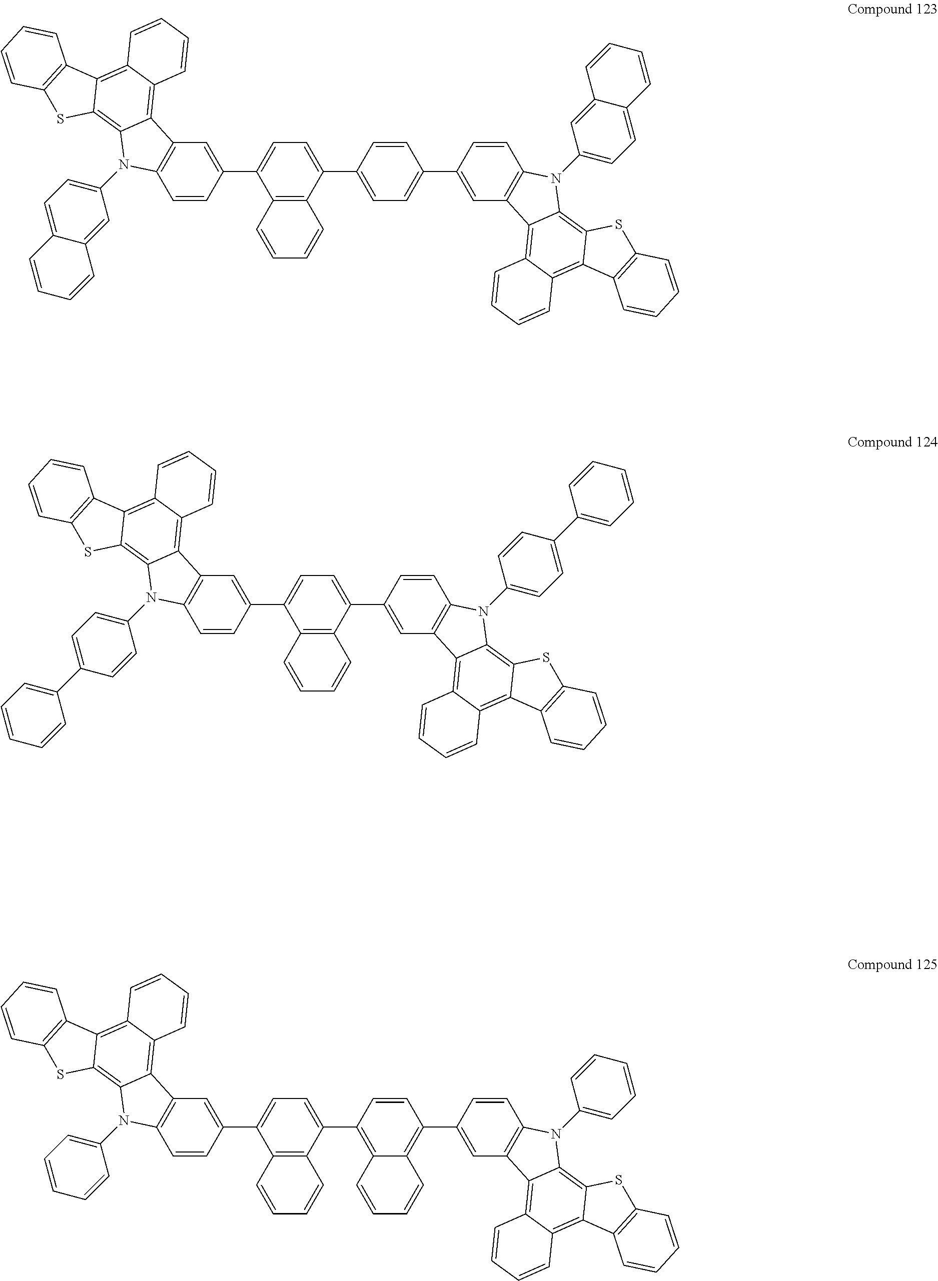 [SMILES: c1ccc2cc(-n3c4ccc(-c5ccc(-c6ccc(-c7ccc8c(c7)c7c9ccccc9c9c%10ccccc%10sc9c7n8-c7ccc8ccccc8c7)c7ccccc67)cc5)cc4c4c5ccccc5c5c6ccccc6sc5c43)ccc2c1 ; c1ccc(-c2ccc(-n3c4ccc(-c5ccc(-c6ccc7c(c6)c6c8ccccc8c8c9ccccc9sc8c6n7-c6ccc(-c7ccccc7)cc6)c6ccccc56)cc4c4c5ccccc5c5c6ccccc6sc5c43)cc2)cc1 ; c1ccc(-n2c3ccc(-c4ccc(-c5ccc(-c6ccc7c(c6)c6c8ccccc8c8c9ccccc9sc8c6n7-c6ccccc6)c6ccccc56)c5ccccc45)cc3c3c4ccccc4c4c5ccccc5sc4c32)cc1]

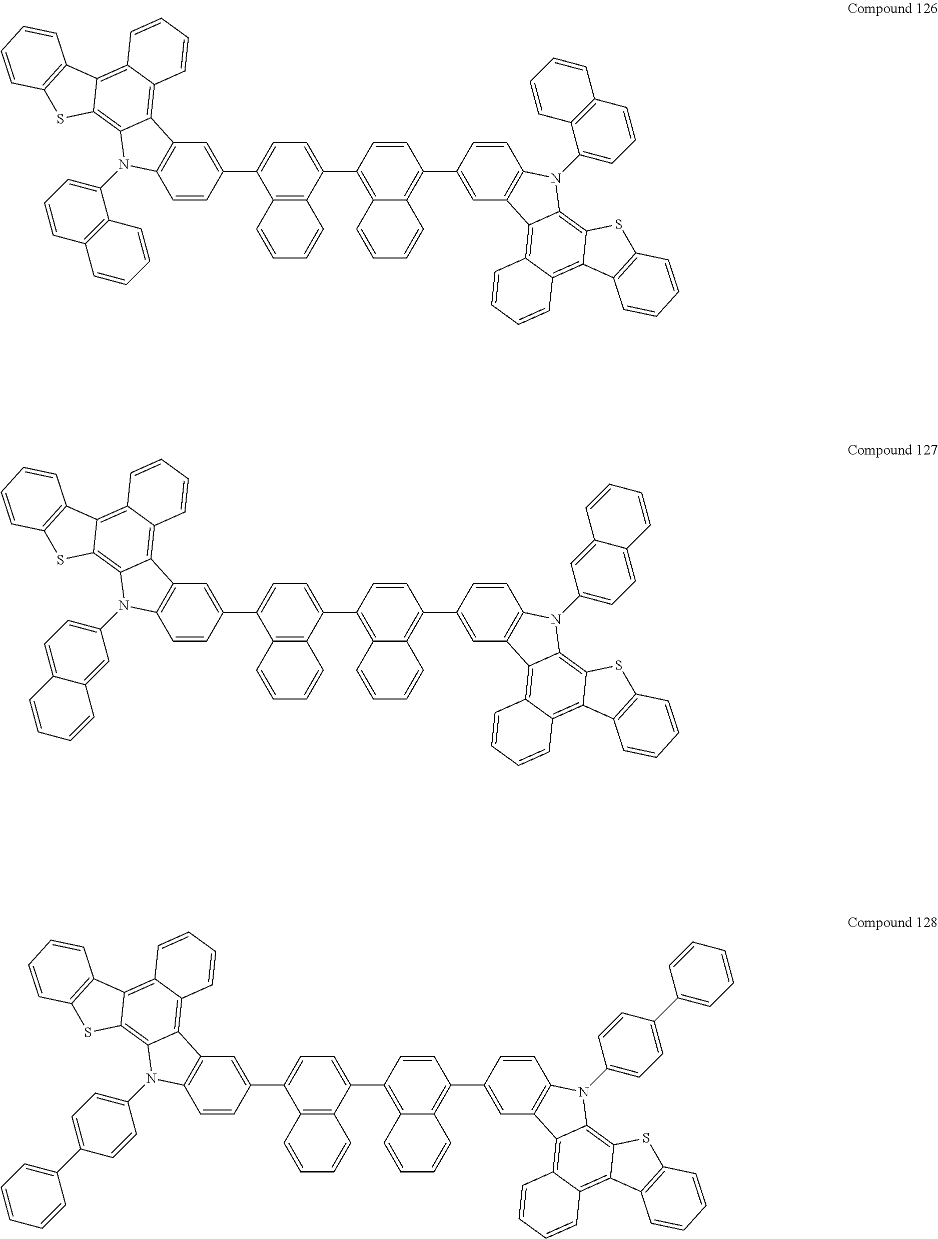 [SMILES: c1ccc2c(-n3c4ccc(-c5ccc(-c6ccc(-c7ccc8c(c7)c7c9ccccc9c9c%10ccccc%10sc9c7n8-c7cccc8ccccc78)c7ccccc67)c6ccccc56)cc4c4c5ccccc5c5c6ccccc6sc5c43)cccc2c1 ; c1ccc2cc(-n3c4ccc(-c5ccc(-c6ccc(-c7ccc8c(c7)c7c9ccccc9c9c%10ccccc%10sc9c7n8-c7ccc8ccccc8c7)c7ccccc67)c6ccccc56)cc4c4c5ccccc5c5c6ccccc6sc5c43)ccc2c1 ; c1ccc(-c2ccc(-n3c4ccc(-c5ccc(-c6ccc(-c7ccc8c(c7)c7c9ccccc9c9c%10ccccc%10sc9c7n8-c7ccc(-c8ccccc8)cc7)c7ccccc67)c6ccccc56)cc4c4c5ccccc5c5c6ccccc6sc5c43)cc2)cc1]

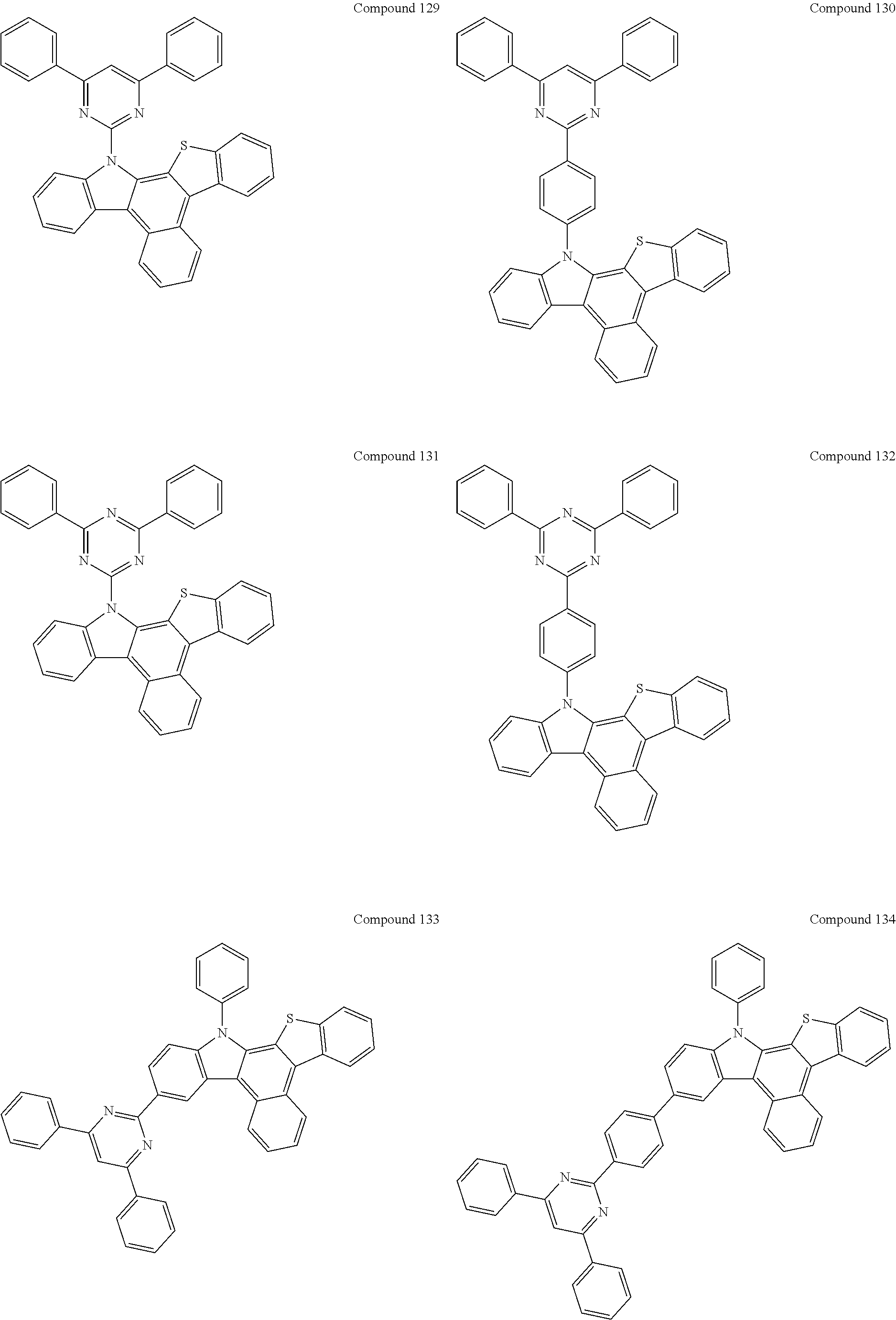 [SMILES: c1ccc(-c2cc(-c3ccccc3)nc(-n3c4ccccc4c4c5ccccc5c5c6ccccc6sc5c43)n2)cc1 ; c1ccc(-c2cc(-c3ccccc3)nc(-c3ccc(-n4c5ccccc5c5c6ccccc6c6c7ccccc7sc6c54)cc3)n2)cc1 ; c1ccc(-c2nc(-c3ccccc3)nc(-n3c4ccccc4c4c5ccccc5c5c6ccccc6sc5c43)n2)cc1 ; c1ccc(-c2nc(-c3ccccc3)nc(-c3ccc(-n4c5ccccc5c5c6ccccc6c6c7ccccc7sc6c54)cc3)n2)cc1 ; c1ccc(-c2cc(-c3ccccc3)nc(-c3ccc4c(c3)c3c5ccccc5c5c6ccccc6sc5c3n4-c3ccccc3)n2)cc1 ; c1ccc(-c2cc(-c3ccccc3)nc(-c3ccc(-c4ccc5c(c4)c4c6ccccc6c6c7ccccc7sc6c4n5-c4ccccc4)cc3)n2)cc1]

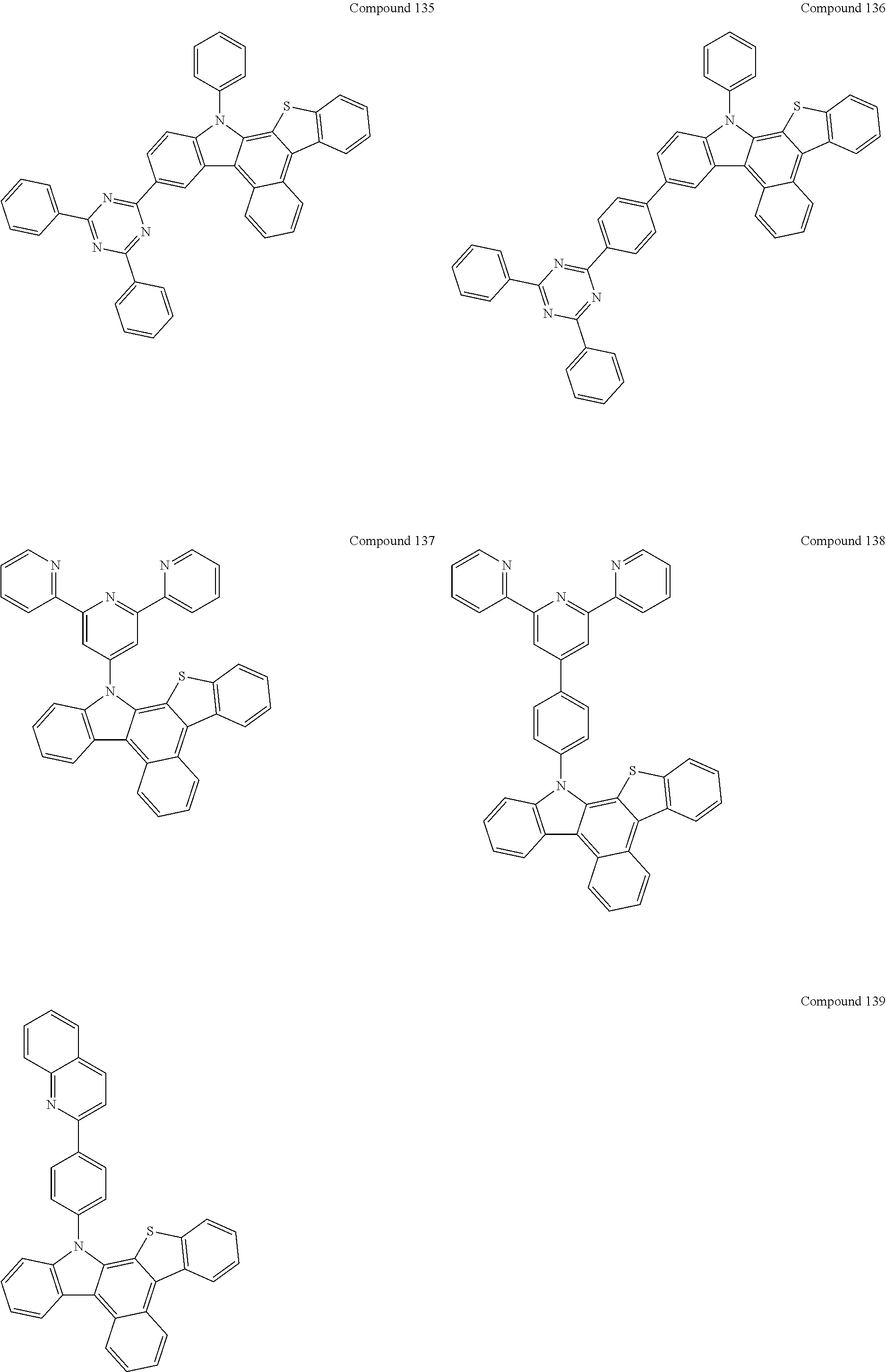 [SMILES: c1ccc(-c2nc(-c3ccccc3)nc(-c3ccc4c(c3)c3c5ccccc5c5c6ccccc6sc5c3n4-c3ccccc3)n2)cc1 ; c1ccc(-c2nc(-c3ccccc3)nc(-c3ccc(-c4ccc5c(c4)c4c6ccccc6c6c7ccccc7sc6c4n5-c4ccccc4)cc3)n2)cc1 ; c1ccc(-c2cc(-n3c4ccccc4c4c5ccccc5c5c6ccccc6sc5c43)cc(-c3ccccn3)n2)nc1 ; c1ccc(-c2cc(-c3ccc(-n4c5ccccc5c5c6ccccc6c6c7ccccc7sc6c54)cc3)cc(-c3ccccn3)n2)nc1 ; c1ccc2nc(-c3ccc(-n4c5ccccc5c5c6ccccc6c6c7ccccc7sc6c54)cc3)ccc2c1]

In an embodiment, the light emitting device may further include a second host layer provided between the hole transport region and the emission layer and including a third host.

In an embodiment, the third host may be represented by Formula 1.

In an embodiment, the second host layer may not include the dopant.

In an embodiment, the third host may include at least one compound of the compounds in the following Compound Group 1.

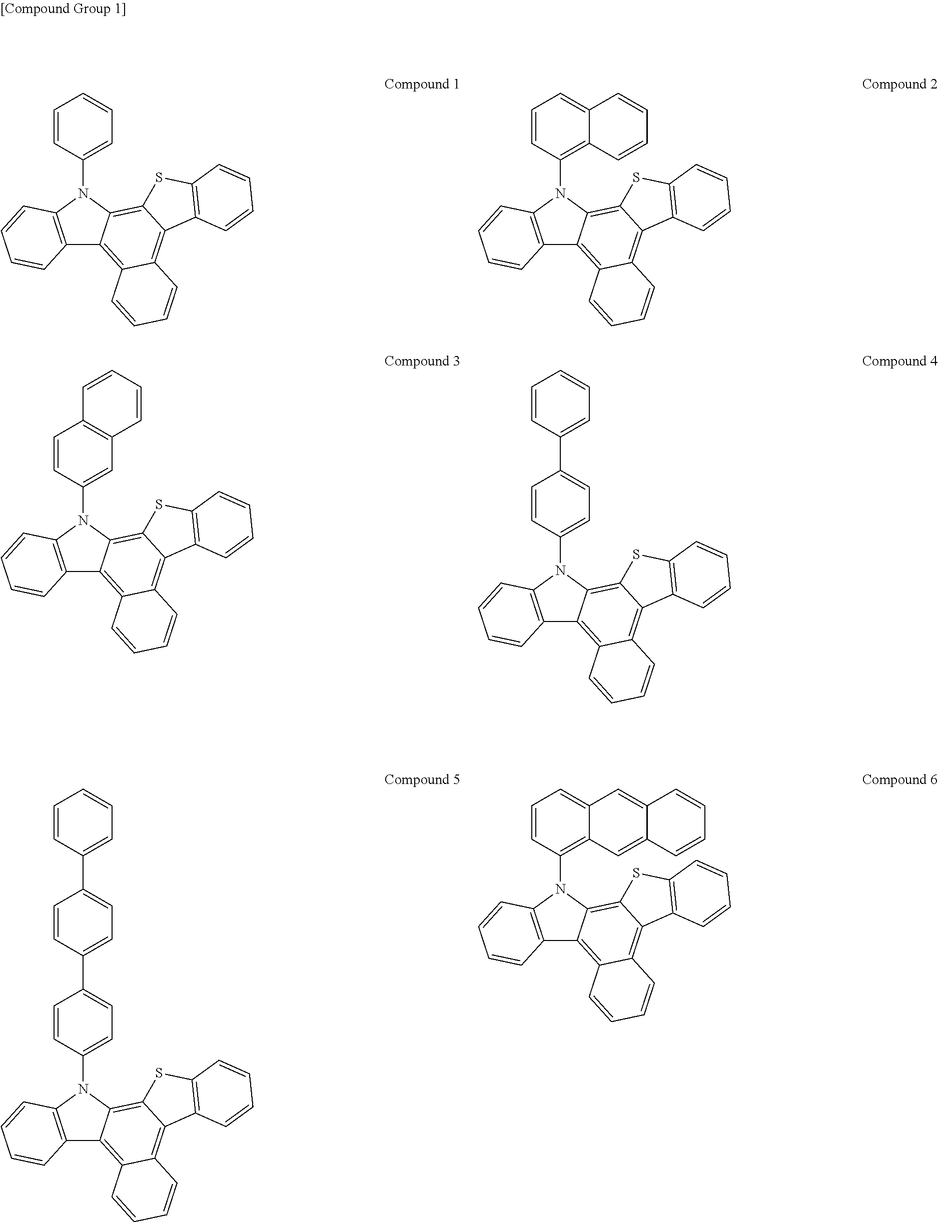 [SMILES: c1ccc(-n2c3ccccc3c3c4ccccc4c4c5ccccc5sc4c32)cc1 ; c1ccc2c(-n3c4ccccc4c4c5ccccc5c5c6ccccc6sc5c43)cccc2c1 ; c1ccc2cc(-n3c4ccccc4c4c5ccccc5c5c6ccccc6sc5c43)ccc2c1 ; c1ccc(-c2ccc(-n3c4ccccc4c4c5ccccc5c5c6ccccc6sc5c43)cc2)cc1 ; c1ccc(-c2ccc(-c3ccc(-n4c5ccccc5c5c6ccccc6c6c7ccccc7sc6c54)cc3)cc2)cc1 ; c1ccc2cc3c(-n4c5ccccc5c5c6ccccc6c6c7ccccc7sc6c54)cccc3cc2c1]

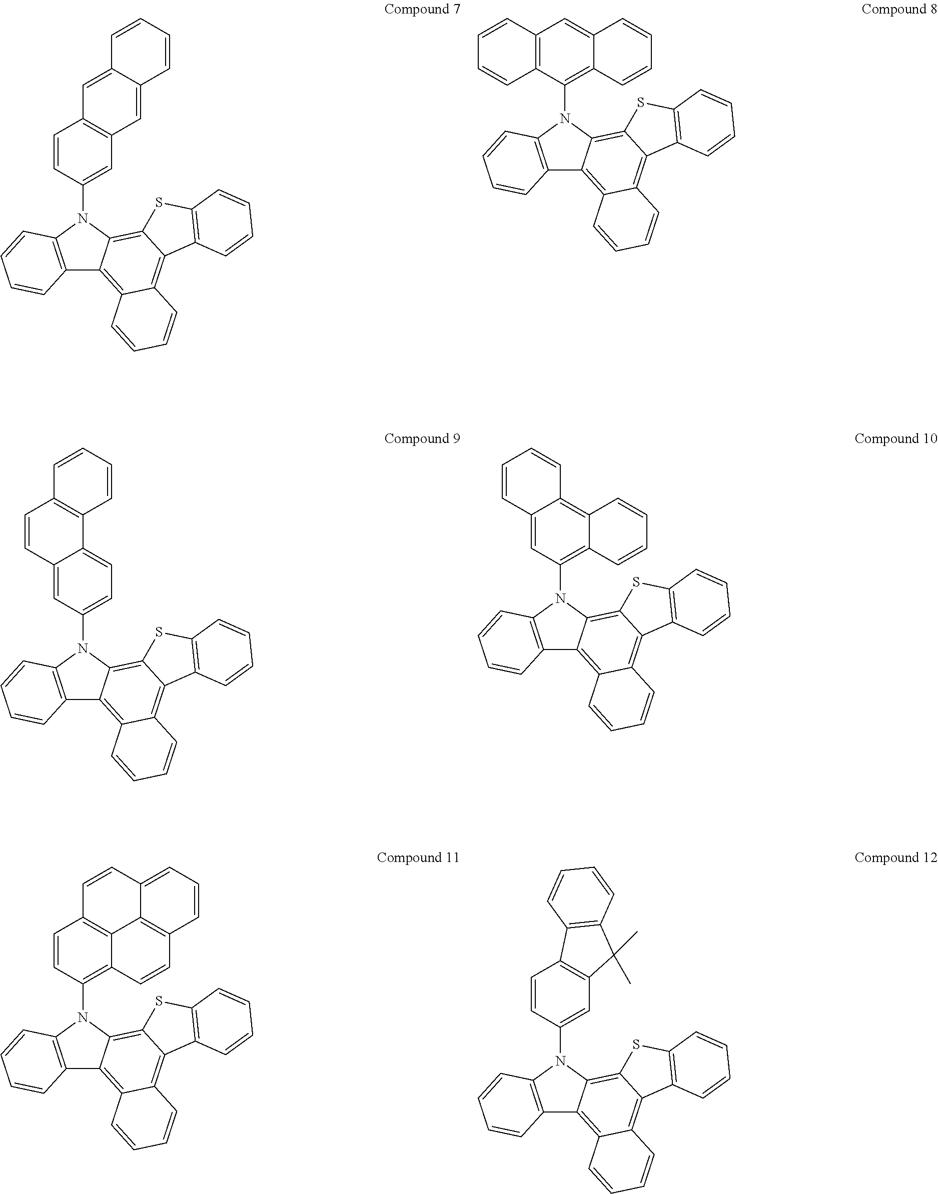 [SMILES: c1ccc2cc3cc(-n4c5ccccc5c5c6ccccc6c6c7ccccc7sc6c54)ccc3cc2c1 ; c1ccc2c(-n3c4ccccc4c4c5ccccc5c5c6ccccc6sc5c43)c3ccccc3cc2c1 ; c1ccc2c(c1)ccc1cc(-n3c4ccccc4c4c5ccccc5c5c6ccccc6sc5c43)ccc12 ; c1ccc2c(c1)cc(-n1c3ccccc3c3c4ccccc4c4c5ccccc5sc4c31)c1ccccc12 ; c1cc2ccc3ccc(-n4c5ccccc5c5c6ccccc6c6c7ccccc7sc6c54)c4ccc(c1)c2c34 ; CC1(C)c2ccccc2-c2ccc(-n3c4ccccc4c4c5ccccc5c5c6ccccc6sc5c43)cc21]

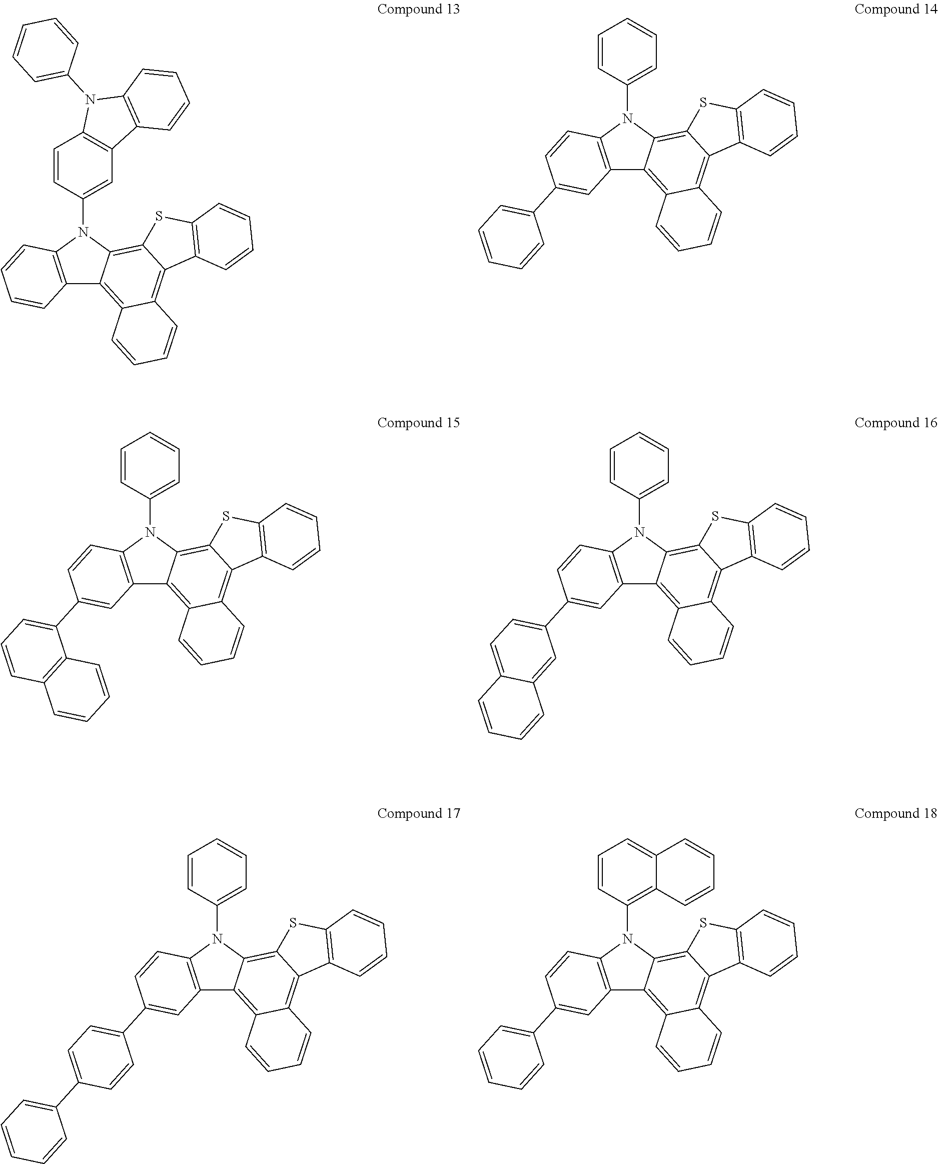 [SMILES: c1ccc(-n2c3ccccc3c3cc(-n4c5ccccc5c5c6ccccc6c6c7ccccc7sc6c54)ccc32)cc1 ; c1ccc(-c2ccc3c(c2)c2c4ccccc4c4c5ccccc5sc4c2n3-c2ccccc2)cc1 ; c1ccc(-n2c3ccc(-c4cccc5ccccc45)cc3c3c4ccccc4c4c5ccccc5sc4c32)cc1 ; c1ccc(-n2c3ccc(-c4ccc5ccccc5c4)cc3c3c4ccccc4c4c5ccccc5sc4c32)cc1 ; c1ccc(-c2ccc(-c3ccc4c(c3)c3c5ccccc5c5c6ccccc6sc5c3n4-c3ccccc3)cc2)cc1 ; c1ccc(-c2ccc3c(c2)c2c4ccccc4c4c5ccccc5sc4c2n3-c2cccc3ccccc23)cc1]

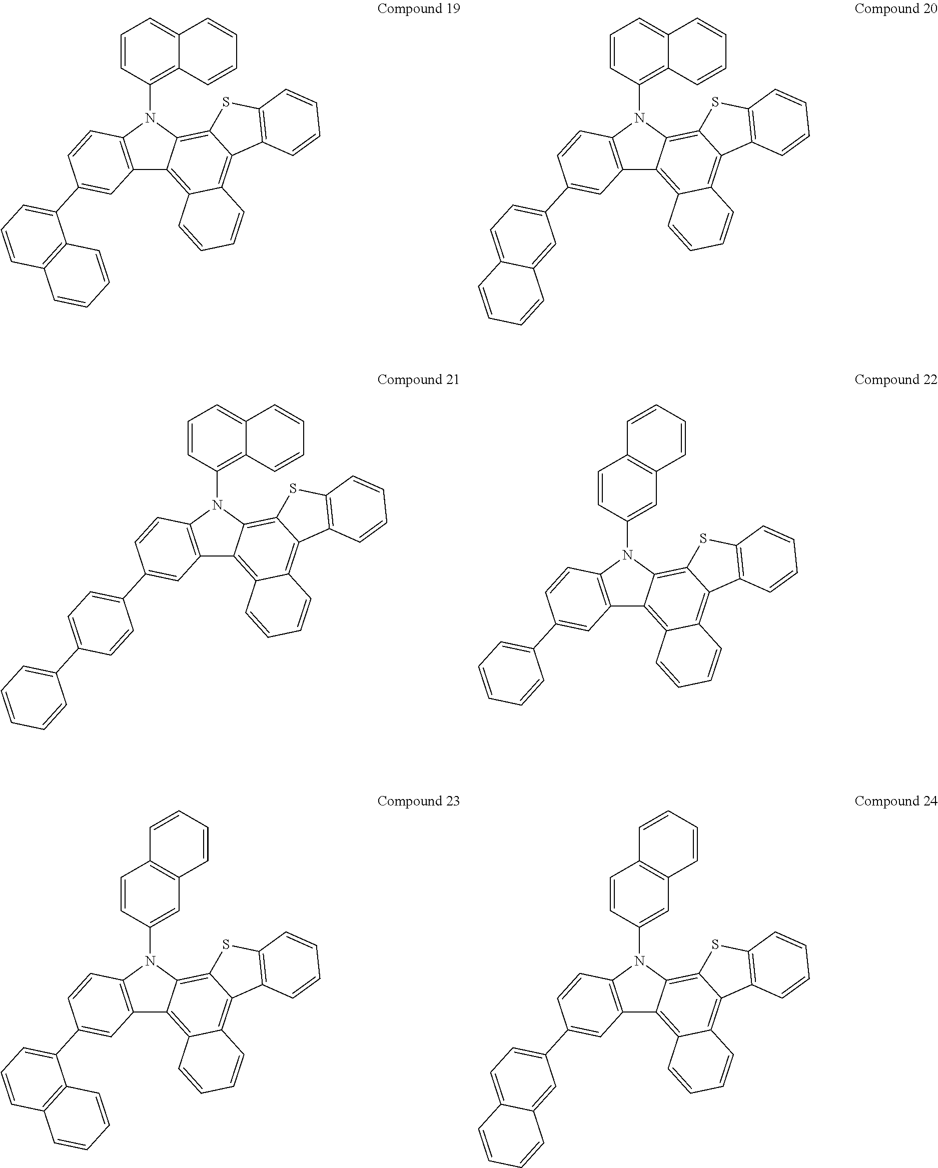 [SMILES: c1ccc2c(-c3ccc4c(c3)c3c5ccccc5c5c6ccccc6sc5c3n4-c3cccc4ccccc34)cccc2c1 ; c1ccc2cc(-c3ccc4c(c3)c3c5ccccc5c5c6ccccc6sc5c3n4-c3cccc4ccccc34)ccc2c1 ; c1ccc(-c2ccc(-c3ccc4c(c3)c3c5ccccc5c5c6ccccc6sc5c3n4-c3cccc4ccccc34)cc2)cc1 ; c1ccc(-c2ccc3c(c2)c2c4ccccc4c4c5ccccc5sc4c2n3-c2ccc3ccccc3c2)cc1 ; c1ccc2cc(-n3c4ccc(-c5cccc6ccccc56)cc4c4c5ccccc5c5c6ccccc6sc5c43)ccc2c1 ; c1ccc2cc(-c3ccc4c(c3)c3c5ccccc5c5c6ccccc6sc5c3n4-c3ccc4ccccc4c3)ccc2c1]

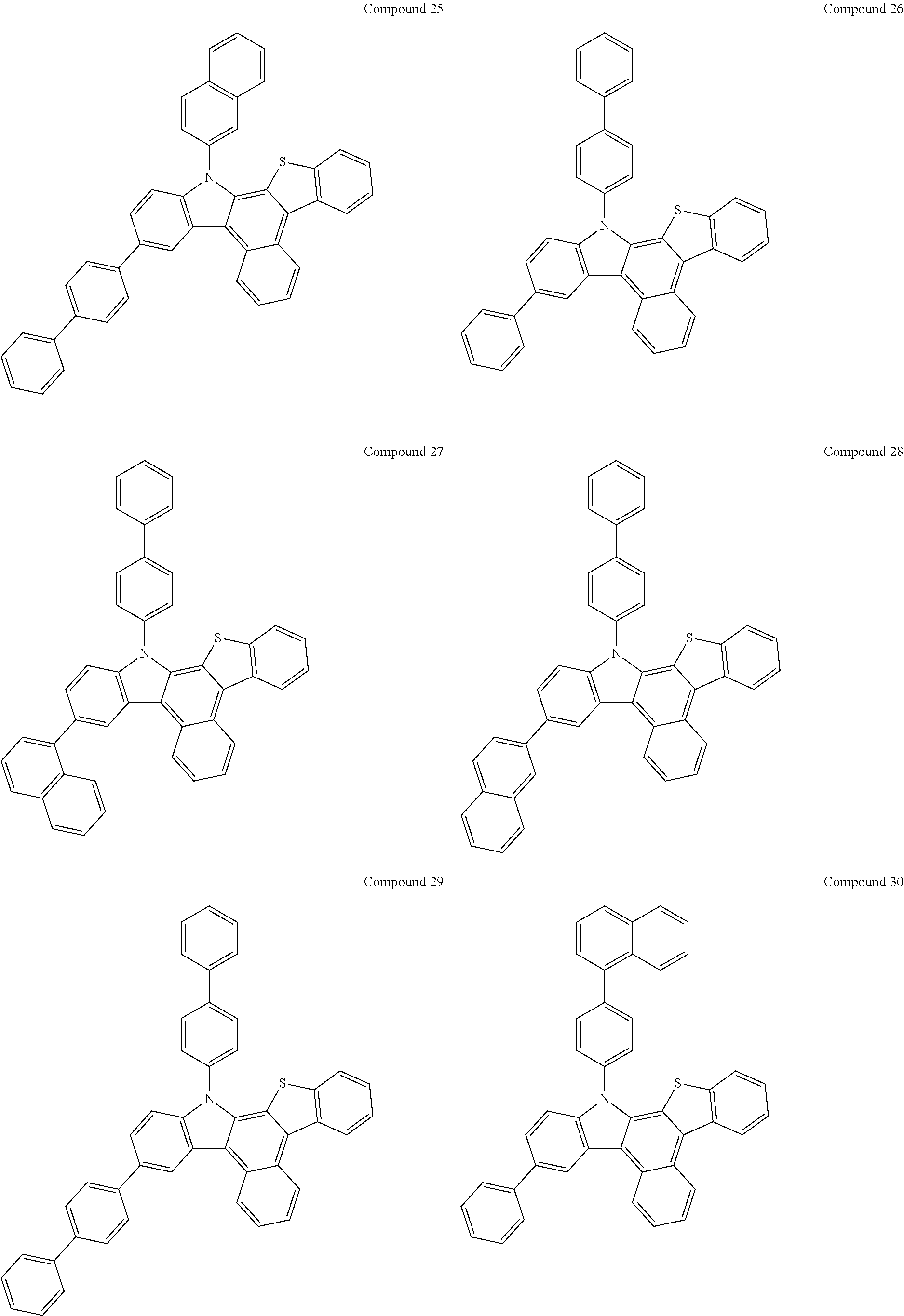 [SMILES: c1ccc(-c2ccc(-c3ccc4c(c3)c3c5ccccc5c5c6ccccc6sc5c3n4-c3ccc4ccccc4c3)cc2)cc1 ; c1ccc(-c2ccc(-n3c4ccc(-c5ccccc5)cc4c4c5ccccc5c5c6ccccc6sc5c43)cc2)cc1 ; c1ccc(-c2ccc(-n3c4ccc(-c5cccc6ccccc56)cc4c4c5ccccc5c5c6ccccc6sc5c43)cc2)cc1 ; c1ccc(-c2ccc(-n3c4ccc(-c5ccc6ccccc6c5)cc4c4c5ccccc5c5c6ccccc6sc5c43)cc2)cc1 ; c1ccc(-c2ccc(-c3ccc4c(c3)c3c5ccccc5c5c6ccccc6sc5c3n4-c3ccc(-c4ccccc4)cc3)cc2)cc1 ; c1ccc(-c2ccc3c(c2)c2c4ccccc4c4c5ccccc5sc4c2n3-c2ccc(-c3cccc4ccccc34)cc2)cc1]

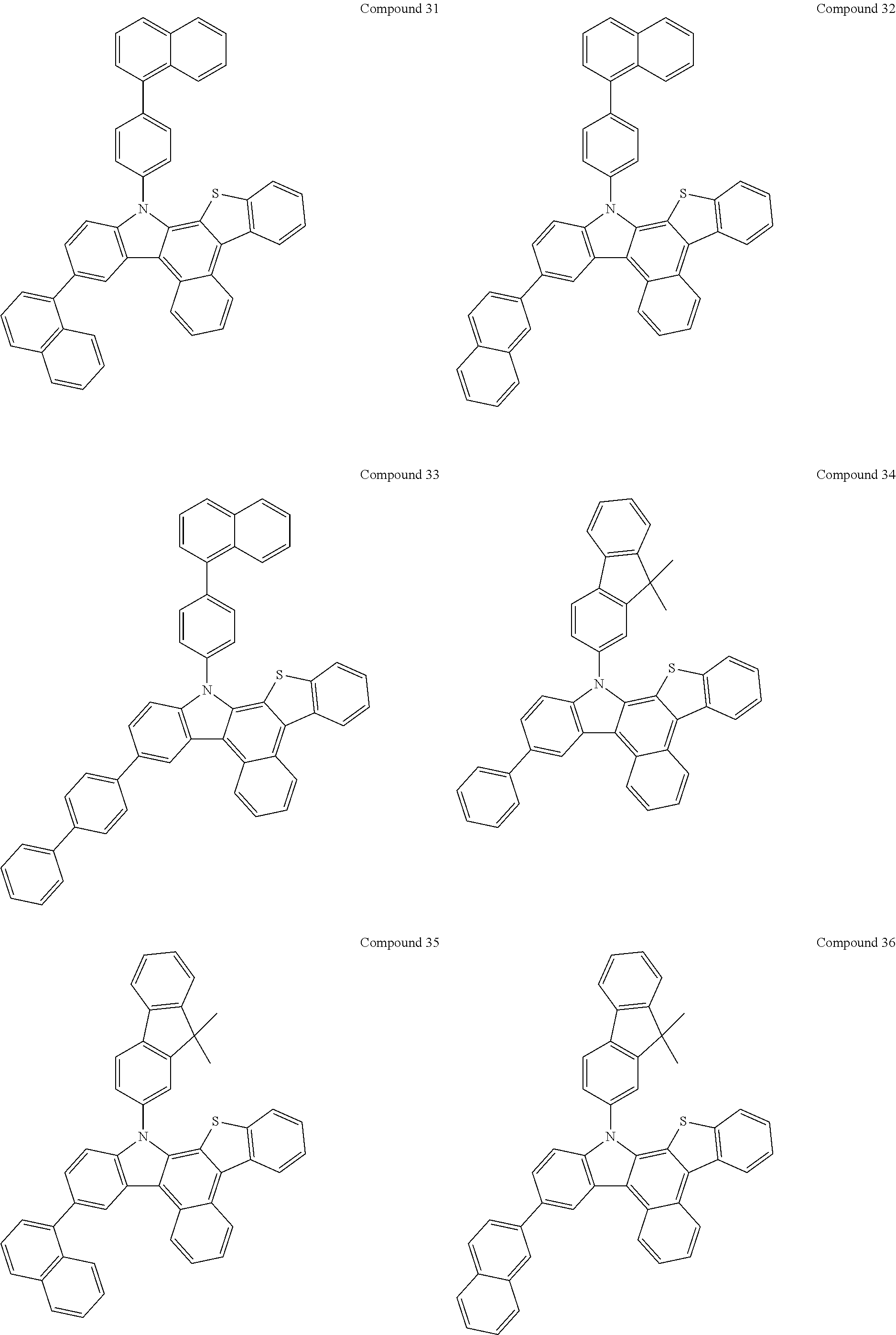 [SMILES: c1ccc2c(-c3ccc(-n4c5ccc(-c6cccc7ccccc67)cc5c5c6ccccc6c6c7ccccc7sc6c54)cc3)cccc2c1 ; c1ccc2cc(-c3ccc4c(c3)c3c5ccccc5c5c6ccccc6sc5c3n4-c3ccc(-c4cccc5ccccc45)cc3)ccc2c1 ; c1ccc(-c2ccc(-c3ccc4c(c3)c3c5ccccc5c5c6ccccc6sc5c3n4-c3ccc(-c4cccc5ccccc45)cc3)cc2)cc1 ; CC1(C)c2ccccc2-c2ccc(-n3c4ccc(-c5ccccc5)cc4c4c5ccccc5c5c6ccccc6sc5c43)cc21 ; CC1(C)c2ccccc2-c2ccc(-n3c4ccc(-c5cccc6ccccc56)cc4c4c5ccccc5c5c6ccccc6sc5c43)cc21 ; CC1(C)c2ccccc2-c2ccc(-n3c4ccc(-c5ccc6ccccc6c5)cc4c4c5ccccc5c5c6ccccc6sc5c43)cc21]

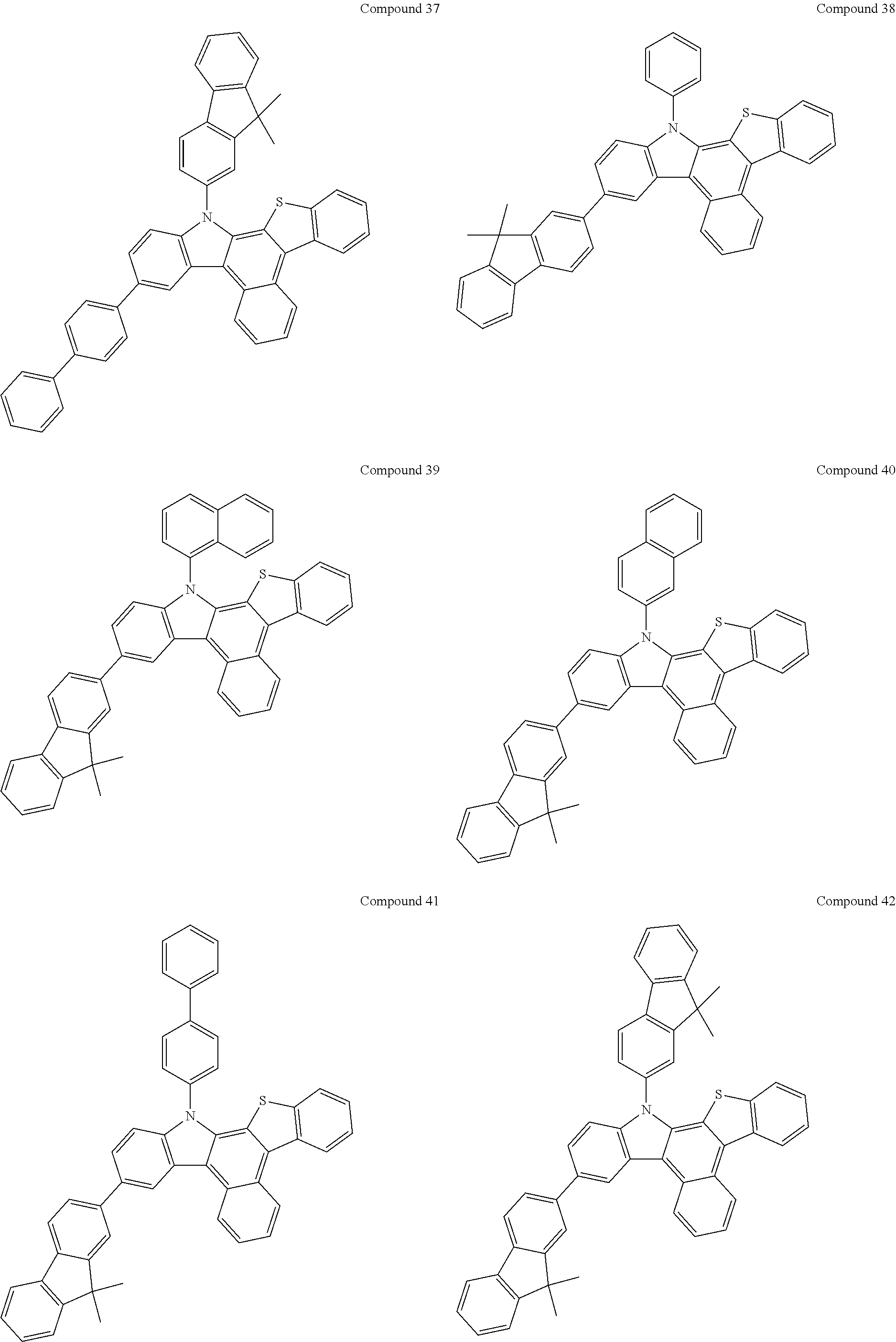

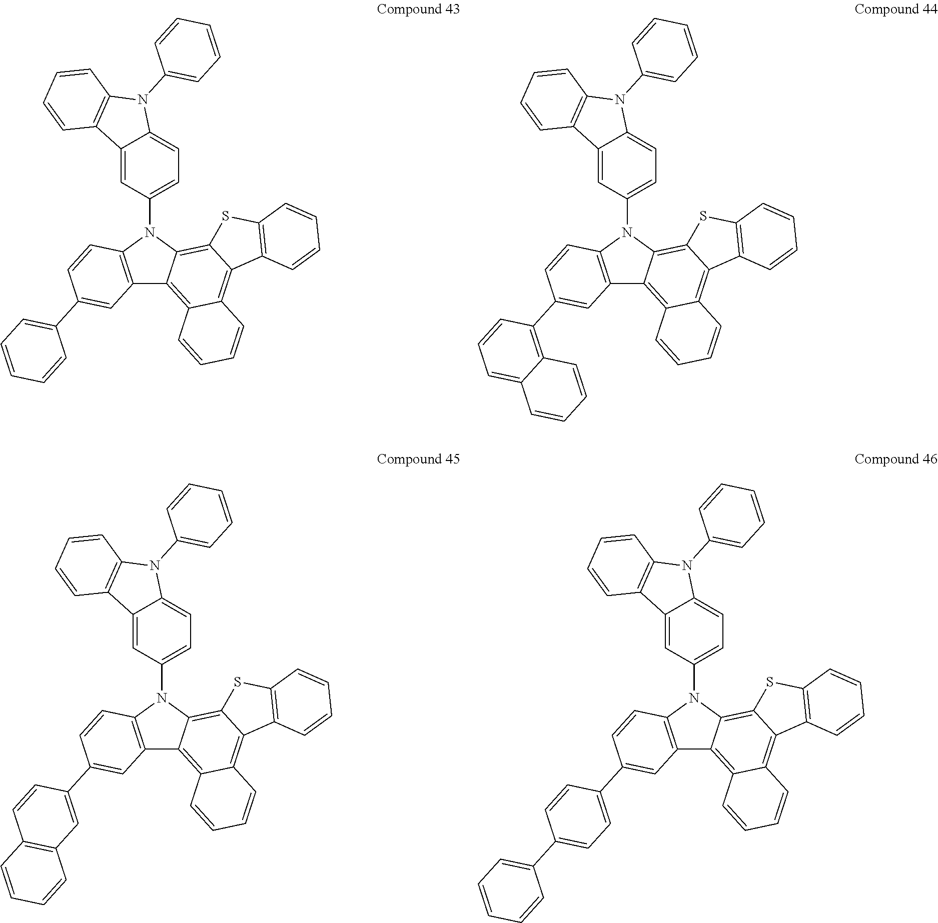 [SMILES: c1ccc(-c2ccc3c(c2)c2c4ccccc4c4c5ccccc5sc4c2n3-c2ccc3c(c2)c2ccccc2n3-c2ccccc2)cc1 ; c1ccc(-n2c3ccccc3c3cc(-n4c5ccc(-c6cccc7ccccc67)cc5c5c6ccccc6c6c7ccccc7sc6c54)ccc32)cc1 ; c1ccc(-n2c3ccccc3c3cc(-n4c5ccc(-c6ccc7ccccc7c6)cc5c5c6ccccc6c6c7ccccc7sc6c54)ccc32)cc1 ; c1ccc(-c2ccc(-c3ccc4c(c3)c3c5ccccc5c5c6ccccc6sc5c3n4-c3ccc4c(c3)c3ccccc3n4-c3ccccc3)cc2)cc1]

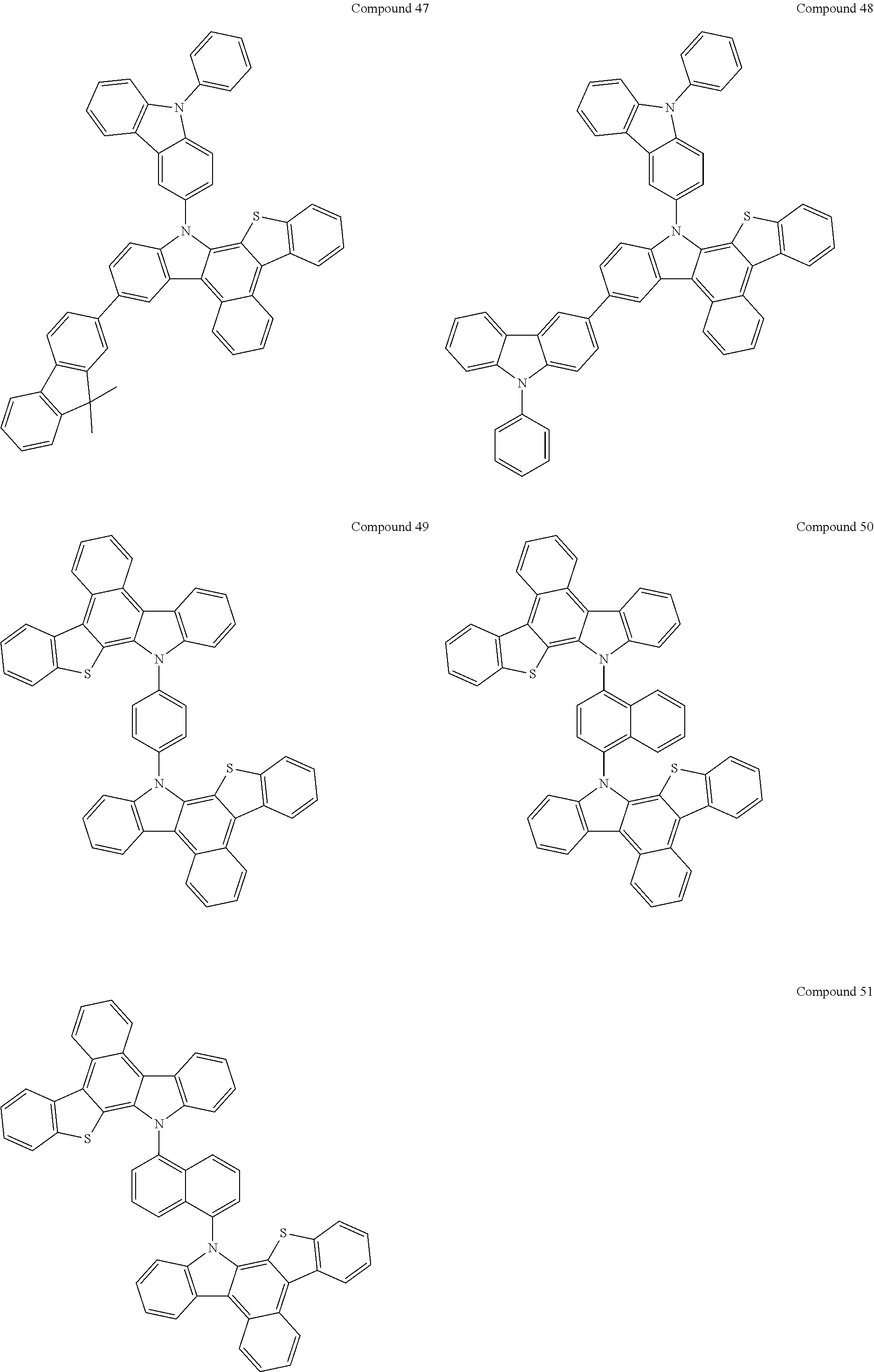 [SMILES: CC1(C)c2ccccc2-c2ccc(-c3ccc4c(c3)c3c5ccccc5c5c6ccccc6sc5c3n4-c3ccc4c(c3)c3ccccc3n4-c3ccccc3)cc21 ; c1ccc(-n2c3ccccc3c3cc(-c4ccc5c(c4)c4c6ccccc6c6c7ccccc7sc6c4n5-c4ccc5c(c4)c4ccccc4n5-c4ccccc4)ccc32)cc1 ; c1ccc2c(c1)sc1c2c2ccccc2c2c3ccccc3n(-c3ccc(-n4c5ccccc5c5c6ccccc6c6c7ccccc7sc6c54)cc3)c12 ; c1ccc2c(c1)sc1c2c2ccccc2c2c3ccccc3n(-c3ccc(-n4c5ccccc5c5c6ccccc6c6c7ccccc7sc6c54)c4ccccc34)c12 ; c1ccc2c(c1)sc1c2c2ccccc2c2c3ccccc3n(-c3cccc4c(-n5c6ccccc6c6c7ccccc7c7c8ccccc8sc7c65)cccc34)c12]

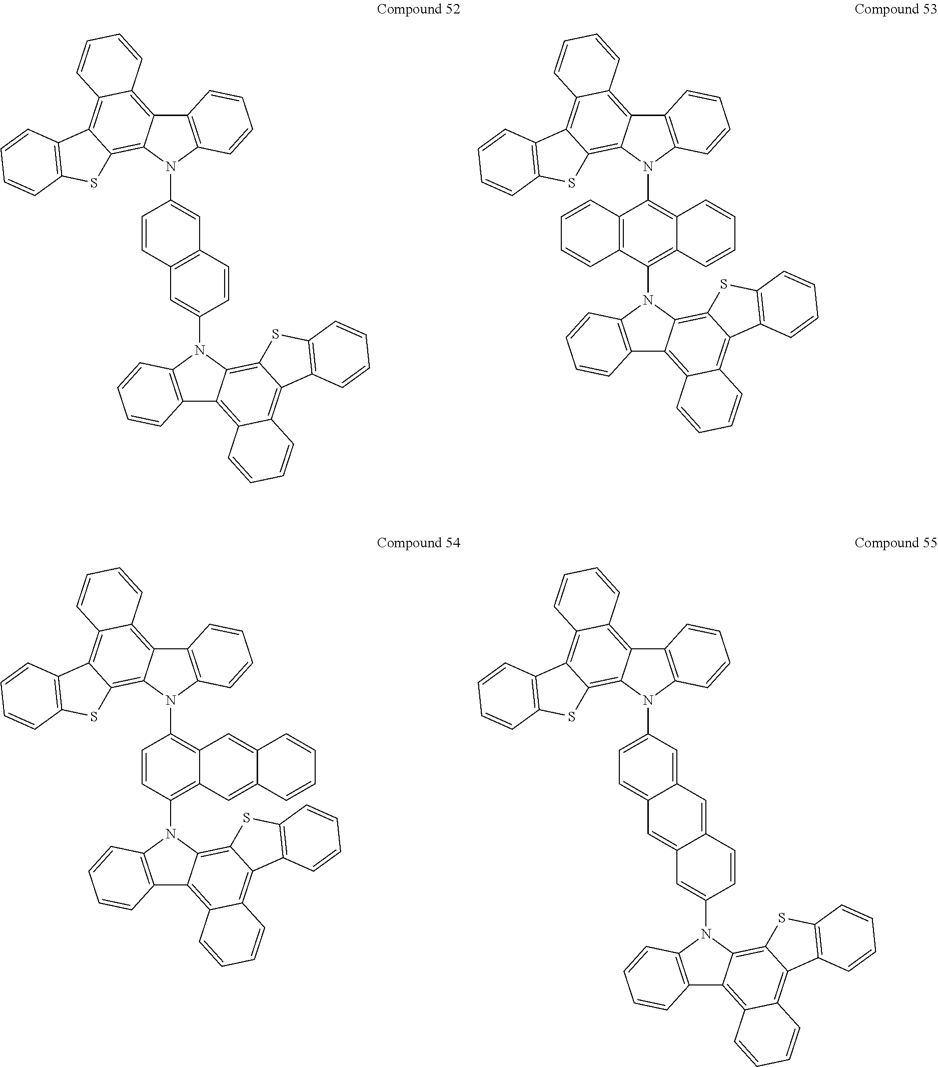 [SMILES: c1ccc2c(c1)sc1c2c2ccccc2c2c3ccccc3n(-c3ccc4cc(-n5c6ccccc6c6c7ccccc7c7c8ccccc8sc7c65)ccc4c3)c12 ; c1ccc2c(c1)sc1c2c2ccccc2c2c3ccccc3n(-c3c4ccccc4c(-n4c5ccccc5c5c6ccccc6c6c7ccccc7sc6c54)c4ccccc34)c12 ; c1ccc2cc3c(-n4c5ccccc5c5c6ccccc6c6c7ccccc7sc6c54)ccc(-n4c5ccccc5c5c6ccccc6c6c7ccccc7sc6c54)c3cc2c1 ; c1ccc2c(c1)sc1c2c2ccccc2c2c3ccccc3n(-c3ccc4cc5cc(-n6c7ccccc7c7c8ccccc8c8c9ccccc9sc8c76)ccc5cc4c3)c12]

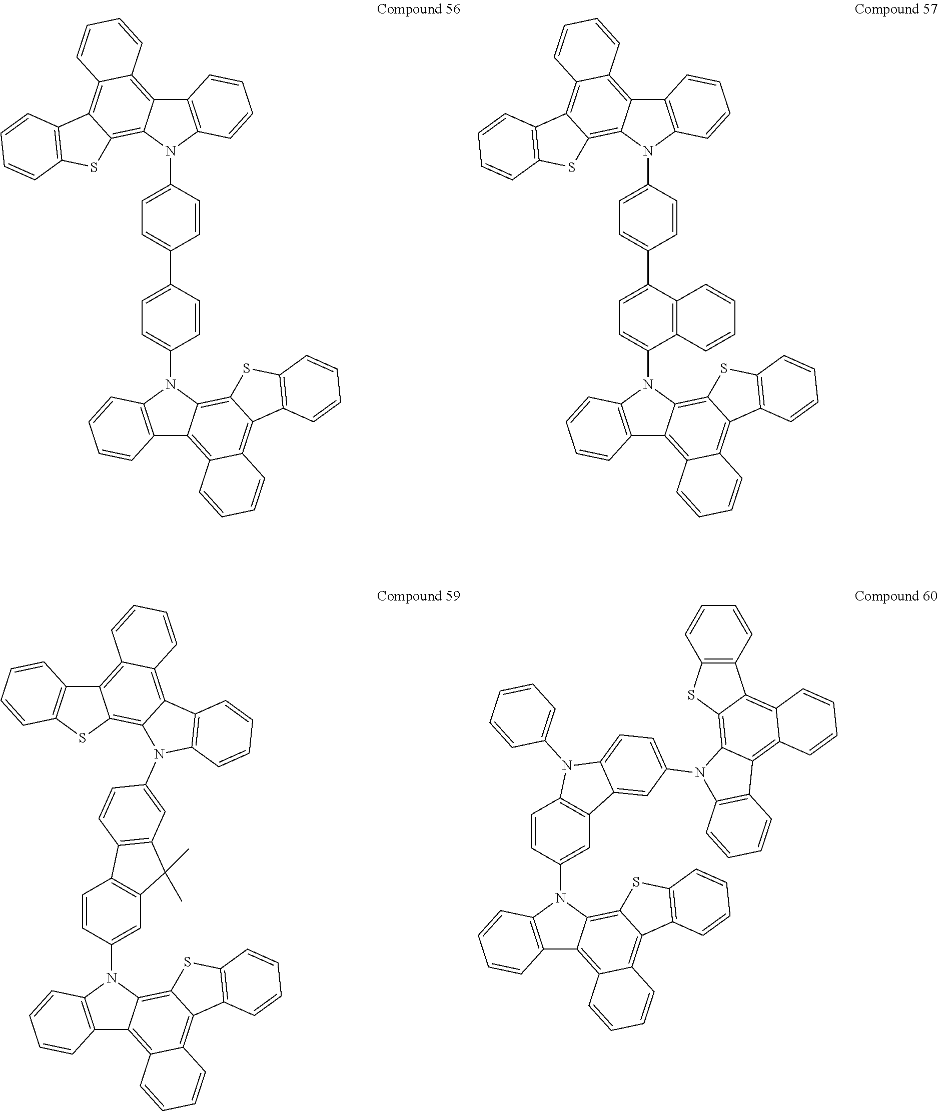 [SMILES: c1ccc2c(c1)sc1c2c2ccccc2c2c3ccccc3n(-c3ccc(-c4ccc(-n5c6ccccc6c6c7ccccc7c7c8ccccc8sc7c65)cc4)cc3)c12 ; c1ccc2c(c1)sc1c2c2ccccc2c2c3ccccc3n(-c3ccc(-c4ccc(-n5c6ccccc6c6c7ccccc7c7c8ccccc8sc7c65)c5ccccc45)cc3)c12 ; CC1(C)c2cc(-n3c4ccccc4c4c5ccccc5c5c6ccccc6sc5c43)ccc2-c2ccc(-n3c4ccccc4c4c5ccccc5c5c6ccccc6sc5c43)cc21 ; c1ccc(-n2c3ccc(-n4c5ccccc5c5c6ccccc6c6c7ccccc7sc6c54)cc3c3cc(-n4c5ccccc5c5c6ccccc6c6c7ccccc7sc6c54)ccc32)cc1]

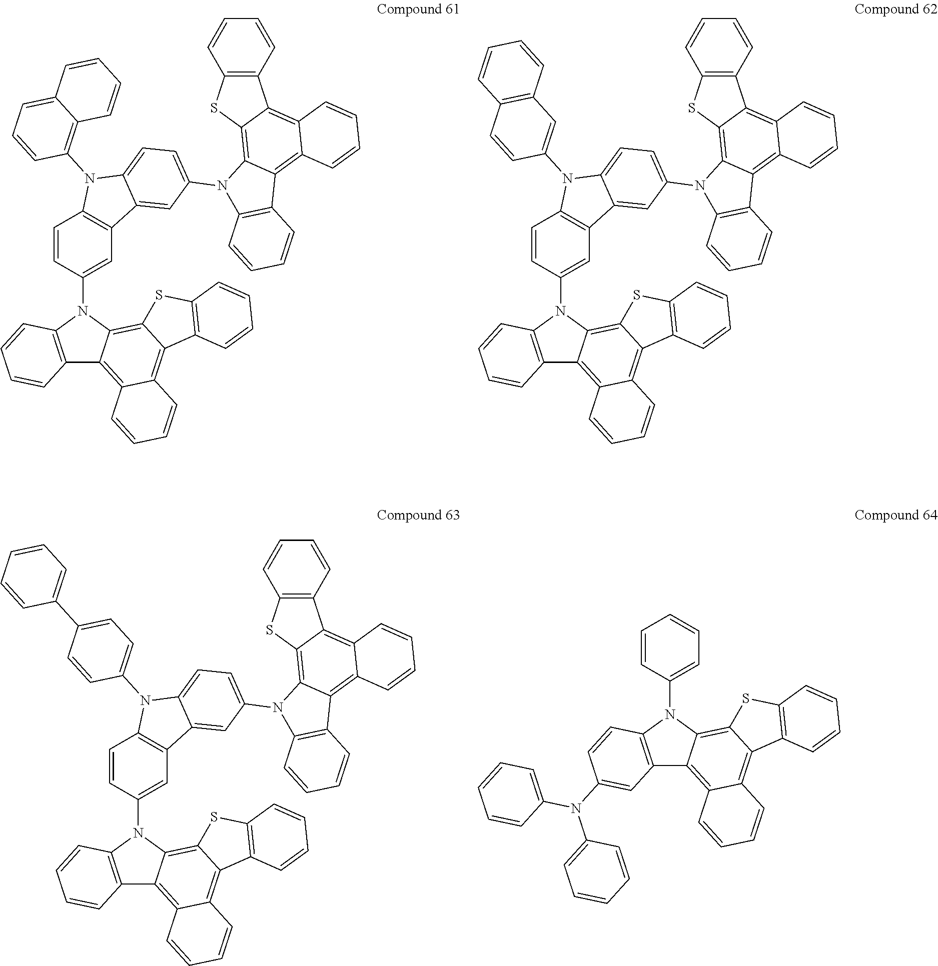 [SMILES: c1ccc2c(-n3c4ccc(-n5c6ccccc6c6c7ccccc7c7c8ccccc8sc7c65)cc4c4cc(-n5c6ccccc6c6c7ccccc7c7c8ccccc8sc7c65)ccc43)cccc2c1 ; c1ccc2cc(-n3c4ccc(-n5c6ccccc6c6c7ccccc7c7c8ccccc8sc7c65)cc4c4cc(-n5c6ccccc6c6c7ccccc7c7c8ccccc8sc7c65)ccc43)ccc2c1 ; c1ccc(-c2ccc(-n3c4ccc(-n5c6ccccc6c6c7ccccc7c7c8ccccc8sc7c65)cc4c4cc(-n5c6ccccc6c6c7ccccc7c7c8ccccc8sc7c65)ccc43)cc2)cc1 ; c1ccc(N(c2ccccc2)c2ccc3c(c2)c2c4ccccc4c4c5ccccc5sc4c2n3-c2ccccc2)cc1]

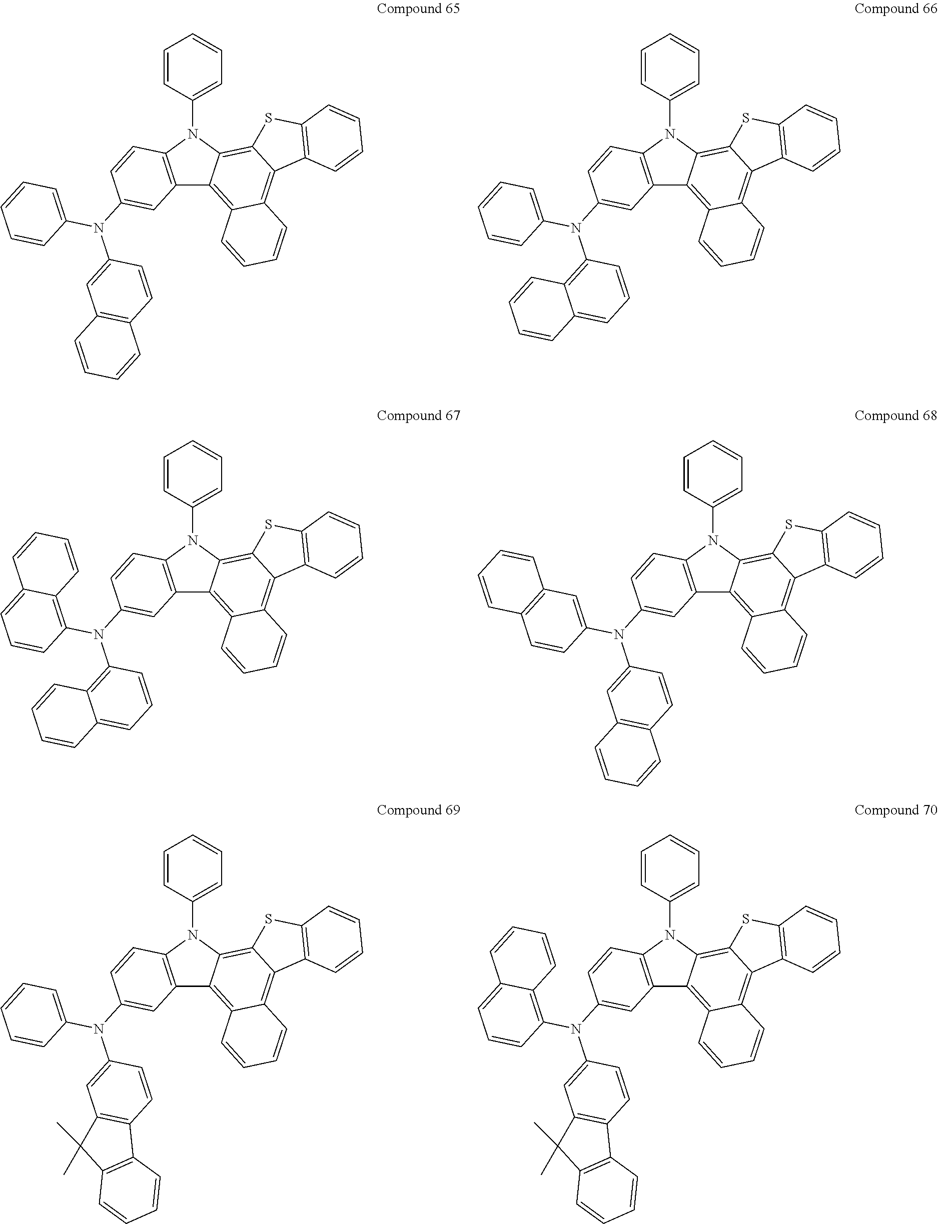 [SMILES: c1ccc(N(c2ccc3ccccc3c2)c2ccc3c(c2)c2c4ccccc4c4c5ccccc5sc4c2n3-c2ccccc2)cc1 ; c1ccc(N(c2ccc3c(c2)c2c4ccccc4c4c5ccccc5sc4c2n3-c2ccccc2)c2cccc3ccccc23)cc1 ; c1ccc(-n2c3ccc(N(c4cccc5ccccc45)c4cccc5ccccc45)cc3c3c4ccccc4c4c5ccccc5sc4c32)cc1 ; c1ccc(-n2c3ccc(N(c4ccc5ccccc5c4)c4ccc5ccccc5c4)cc3c3c4ccccc4c4c5ccccc5sc4c32)cc1 ; CC1(C)c2ccccc2-c2ccc(N(c3ccccc3)c3ccc4c(c3)c3c5ccccc5c5c6ccccc6sc5c3n4-c3ccccc3)cc21 ; CC1(C)c2ccccc2-c2ccc(N(c3ccc4c(c3)c3c5ccccc5c5c6ccccc6sc5c3n4-c3ccccc3)c3cccc4ccccc34)cc21]

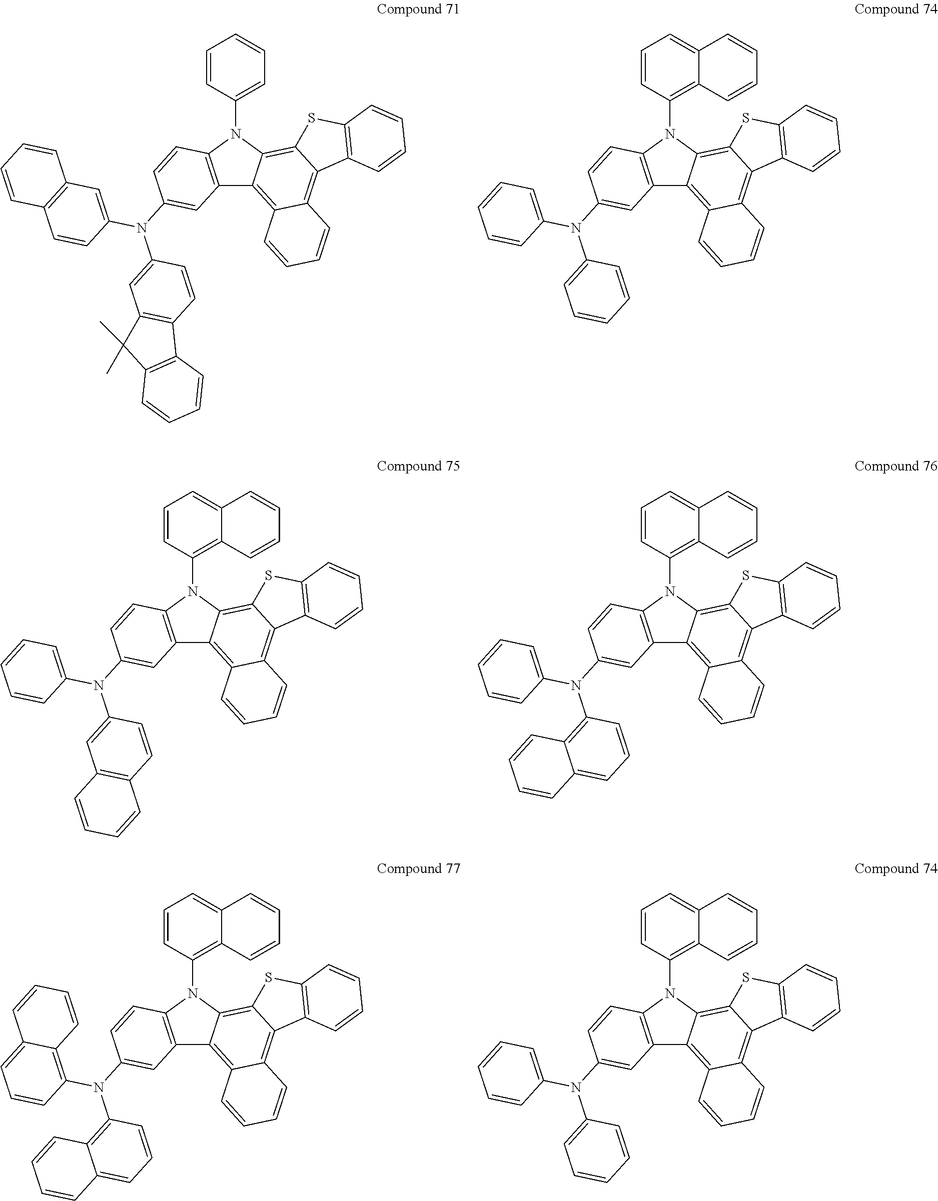 [SMILES: CC1(C)c2ccccc2-c2ccc(N(c3ccc4ccccc4c3)c3ccc4c(c3)c3c5ccccc5c5c6ccccc6sc5c3n4-c3ccccc3)cc21 ; c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1 ; c1ccc(N(c2ccc3c(c2)c2c4ccccc4c4c5ccccc5sc4c2n3-c2cccc3ccccc23)c2cccc3ccccc23)cc1 ; c1ccc2c(N(c3ccc4c(c3)c3c5ccccc5c5c6ccccc6sc5c3n4-c3cccc4ccccc34)c3cccc4ccccc34)cccc2c1 ; c1ccc(N(c2ccccc2)c2ccc3c(c2)c2c4ccccc4c4c5ccccc5sc4c2n3-c2cccc3ccccc23)cc1]

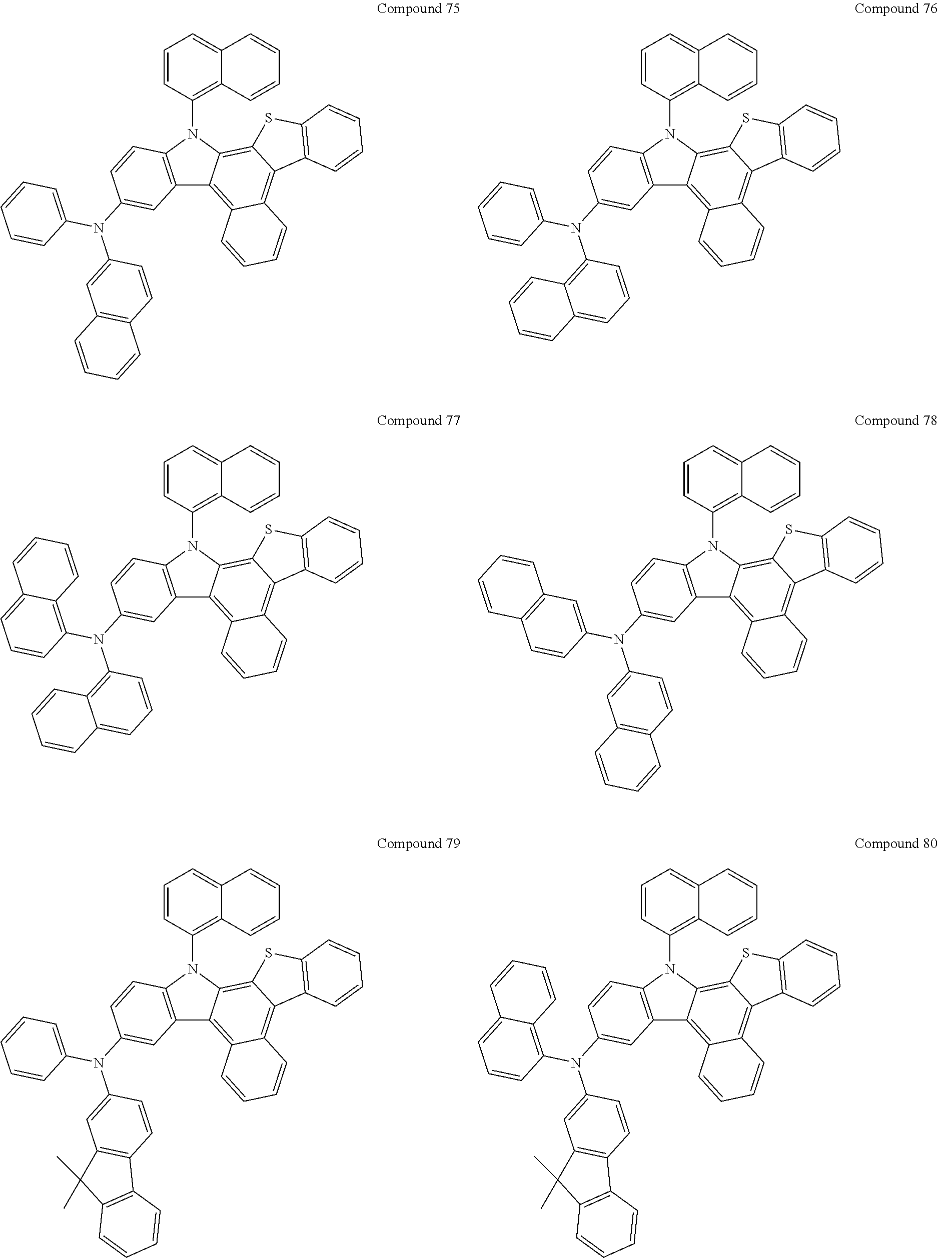

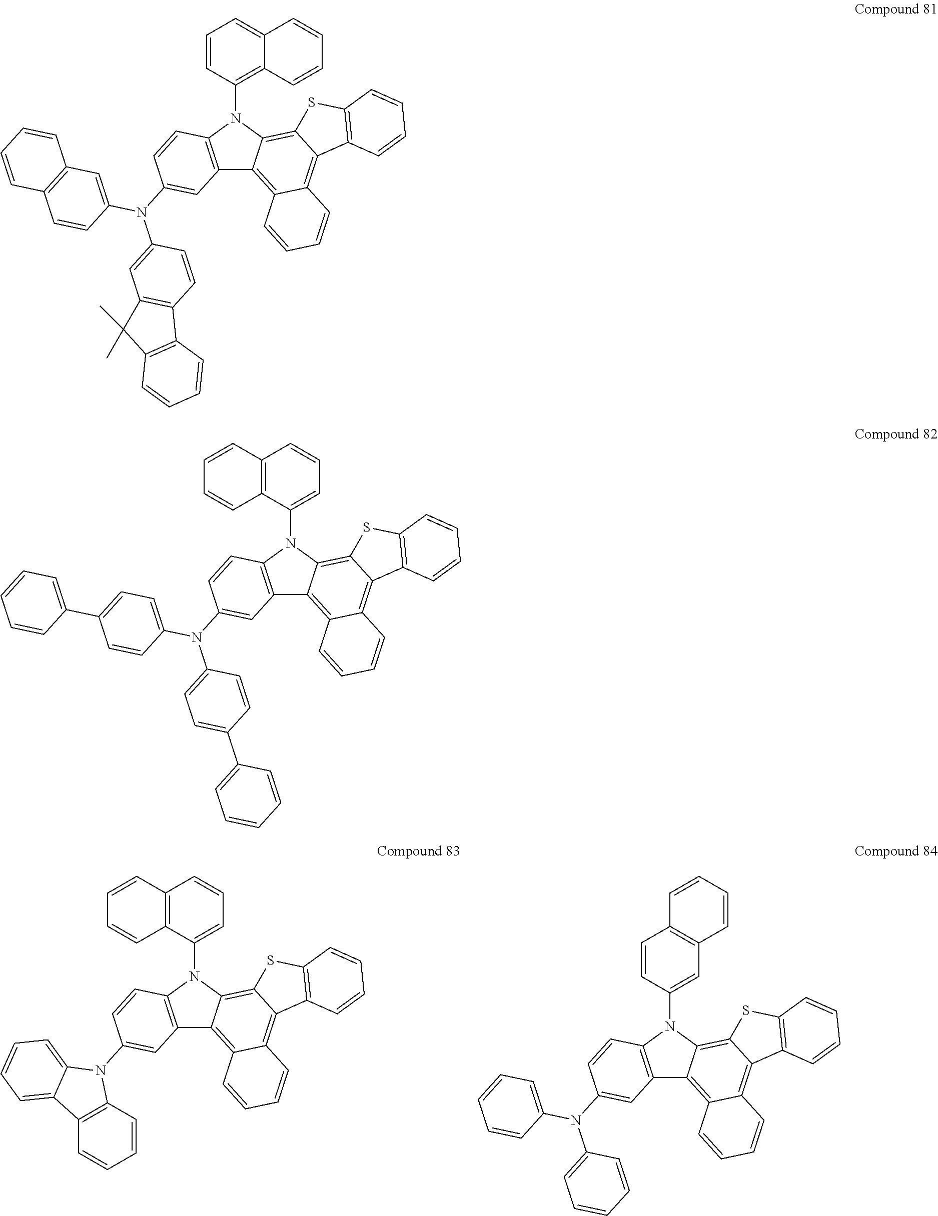 [SMILES: CC1(C)c2ccccc2-c2ccc(N(c3ccc4ccccc4c3)c3ccc4c(c3)c3c5ccccc5c5c6ccccc6sc5c3n4-c3cccc4ccccc34)cc21 ; c1ccc(-c2ccc(N(c3ccc(-c4ccccc4)cc3)c3ccc4c(c3)c3c5ccccc5c5c6ccccc6sc5c3n4-c3cccc4ccccc34)cc2)cc1 ; c1ccc2c(-n3c4ccc(-n5c6ccccc6c6ccccc65)cc4c4c5ccccc5c5c6ccccc6sc5c43)cccc2c1 ; c1ccc(N(c2ccccc2)c2ccc3c(c2)c2c4ccccc4c4c5ccccc5sc4c2n3-c2ccc3ccccc3c2)cc1]

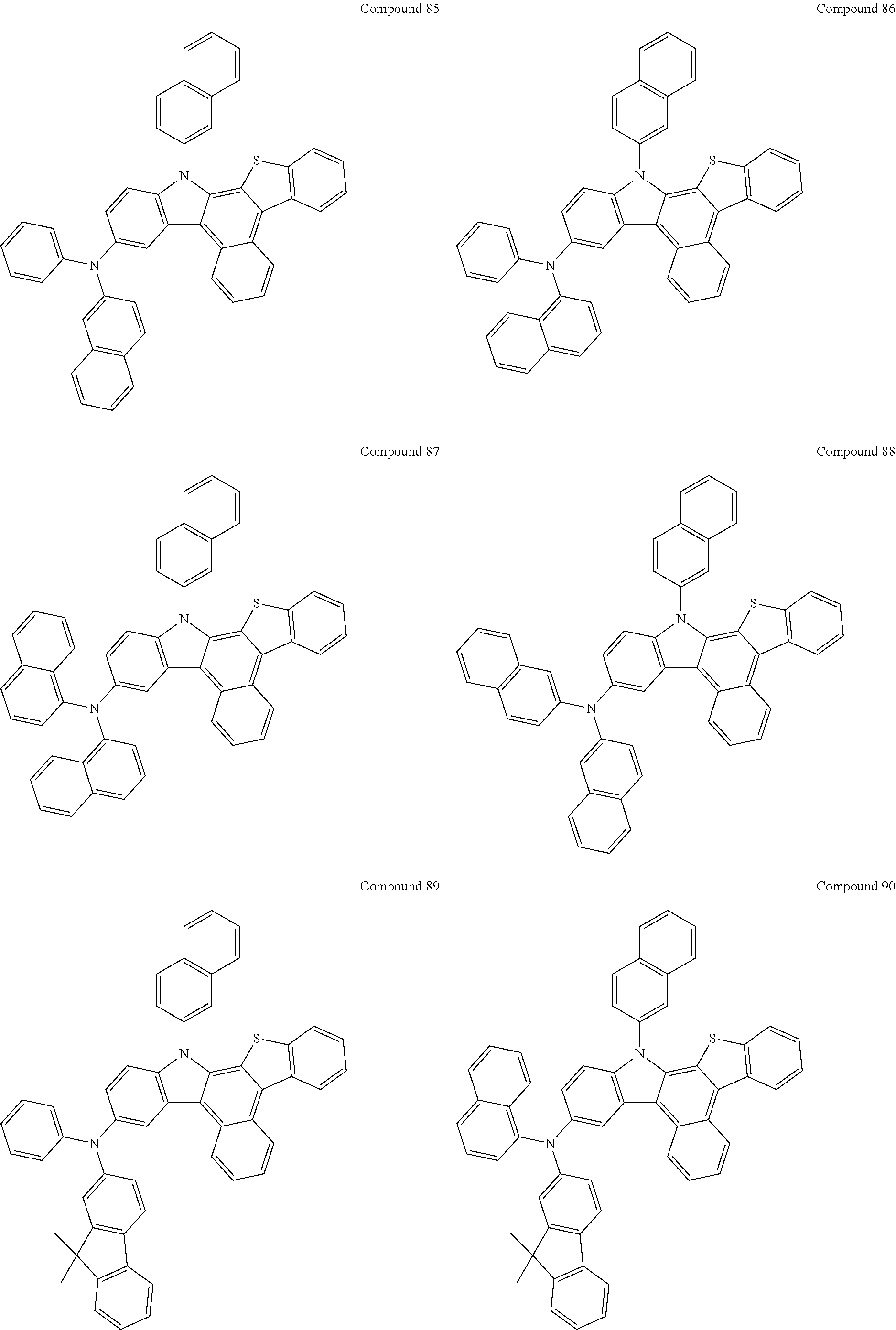

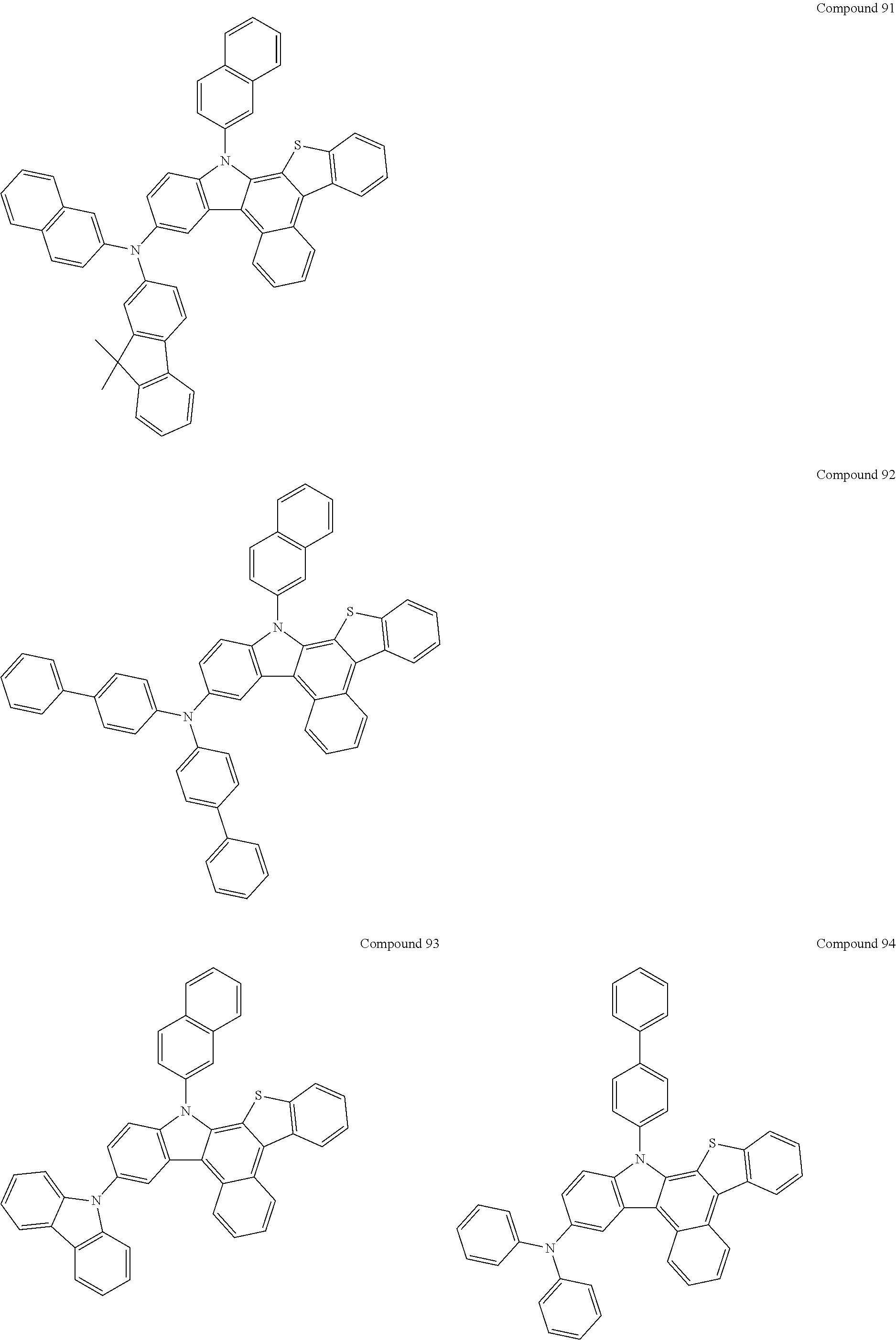 [SMILES: CC1(C)c2ccccc2-c2ccc(N(c3ccc4ccccc4c3)c3ccc4c(c3)c3c5ccccc5c5c6ccccc6sc5c3n4-c3ccc4ccccc4c3)cc21 ; c1ccc(-c2ccc(N(c3ccc(-c4ccccc4)cc3)c3ccc4c(c3)c3c5ccccc5c5c6ccccc6sc5c3n4-c3ccc4ccccc4c3)cc2)cc1 ; c1ccc2cc(-n3c4ccc(-n5c6ccccc6c6ccccc65)cc4c4c5ccccc5c5c6ccccc6sc5c43)ccc2c1 ; c1ccc(-c2ccc(-n3c4ccc(N(c5ccccc5)c5ccccc5)cc4c4c5ccccc5c5c6ccccc6sc5c43)cc2)cc1]

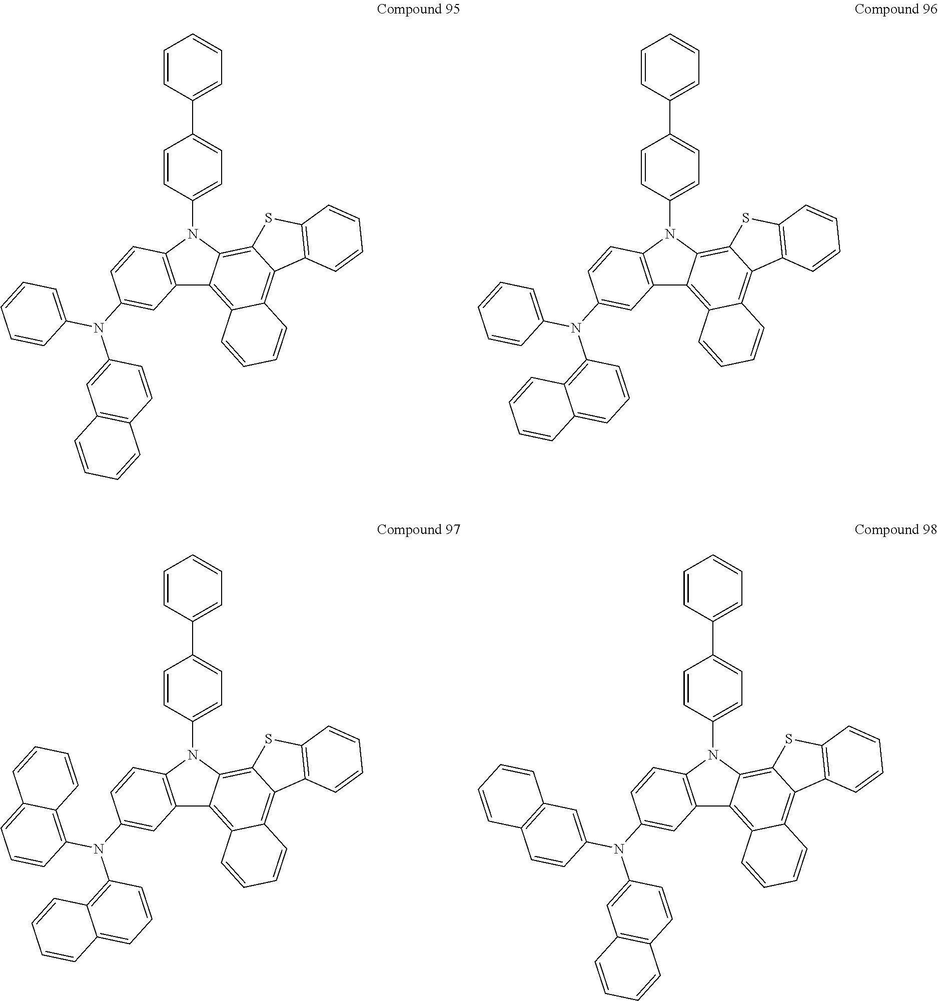 [SMILES: c1ccc(-c2ccc(-n3c4ccc(N(c5ccccc5)c5ccc6ccccc6c5)cc4c4c5ccccc5c5c6ccccc6sc5c43)cc2)cc1 ; c1ccc(-c2ccc(-n3c4ccc(N(c5ccccc5)c5cccc6ccccc56)cc4c4c5ccccc5c5c6ccccc6sc5c43)cc2)cc1 ; c1ccc(-c2ccc(-n3c4ccc(N(c5cccc6ccccc56)c5cccc6ccccc56)cc4c4c5ccccc5c5c6ccccc6sc5c43)cc2)cc1 ; c1ccc(-c2ccc(-n3c4ccc(N(c5ccc6ccccc6c5)c5ccc6ccccc6c5)cc4c4c5ccccc5c5c6ccccc6sc5c43)cc2)cc1]

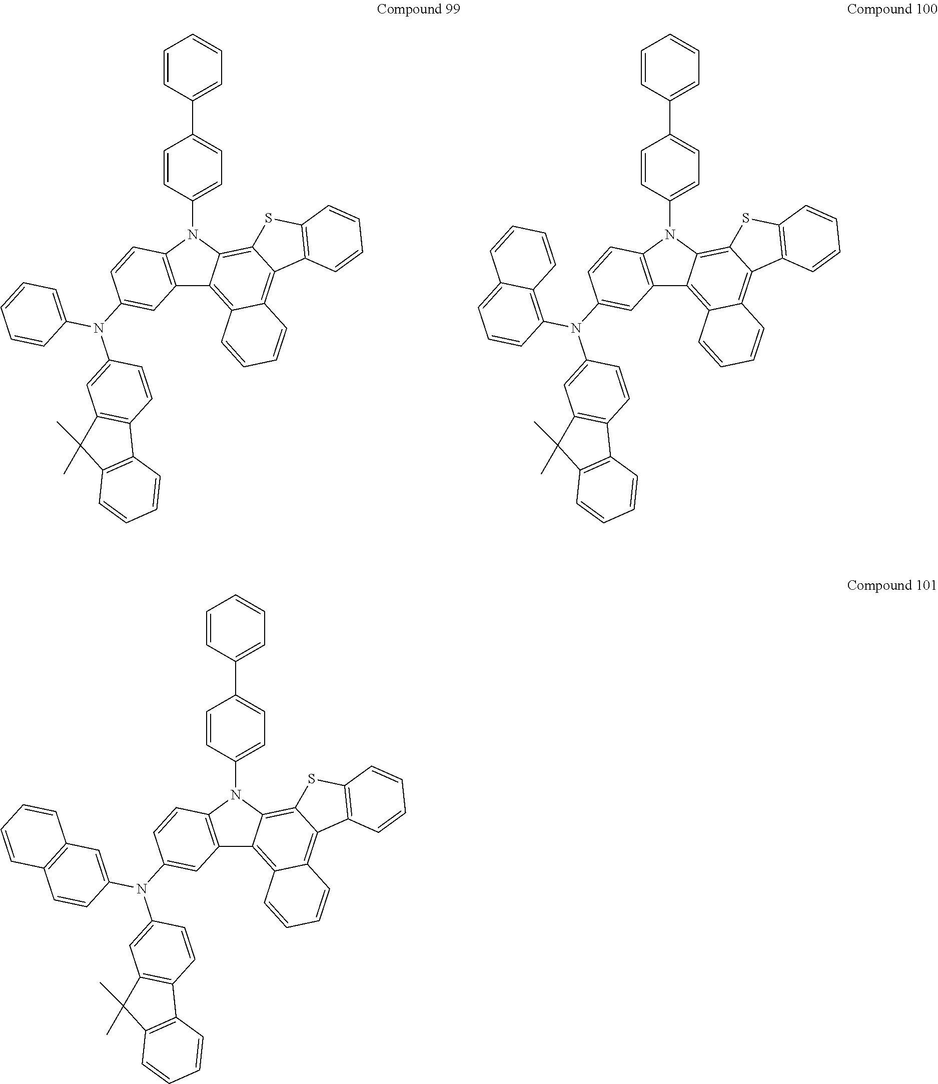 [SMILES: CC1(C)c2ccccc2-c2ccc(N(c3ccccc3)c3ccc4c(c3)c3c5ccccc5c5c6ccccc6sc5c3n4-c3ccc(-c4ccccc4)cc3)cc21 ; CC1(C)c2ccccc2-c2ccc(N(c3ccc4c(c3)c3c5ccccc5c5c6ccccc6sc5c3n4-c3ccc(-c4ccccc4)cc3)c3cccc4ccccc34)cc21 ; CC1(C)c2ccccc2-c2ccc(N(c3ccc4ccccc4c3)c3ccc4c(c3)c3c5ccccc5c5c6ccccc6sc5c3n4-c3ccc(-c4ccccc4)cc3)cc21]

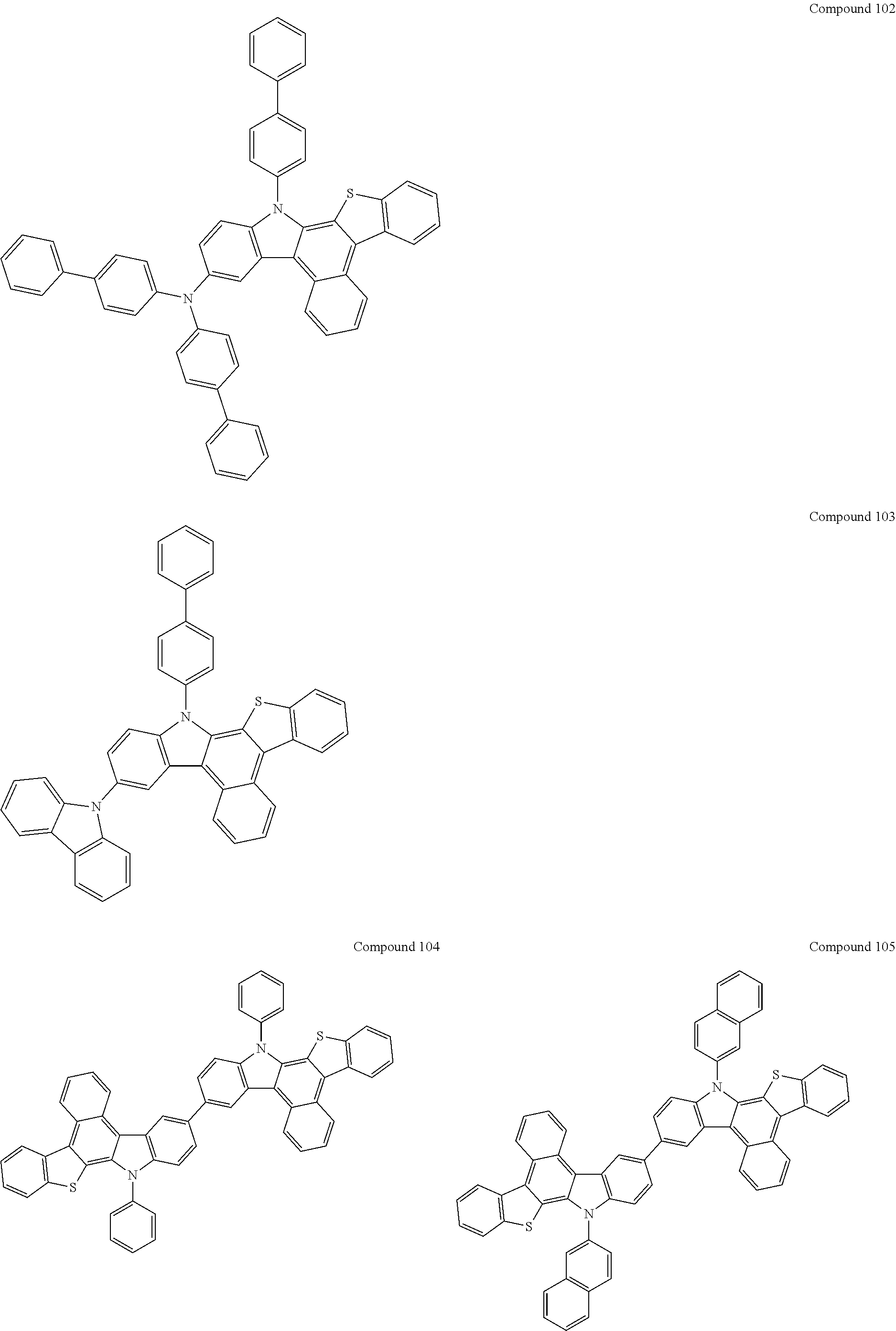 [SMILES: c1ccc(-c2ccc(N(c3ccc(-c4ccccc4)cc3)c3ccc4c(c3)c3c5ccccc5c5c6ccccc6sc5c3n4-c3ccc(-c4ccccc4)cc3)cc2)cc1 ; c1ccc(-c2ccc(-n3c4ccc(-n5c6ccccc6c6ccccc65)cc4c4c5ccccc5c5c6ccccc6sc5c43)cc2)cc1 ; c1ccc(-n2c3ccc(-c4ccc5c(c4)c4c6ccccc6c6c7ccccc7sc6c4n5-c4ccccc4)cc3c3c4ccccc4c4c5ccccc5sc4c32)cc1 ; c1ccc2cc(-n3c4ccc(-c5ccc6c(c5)c5c7ccccc7c7c8ccccc8sc7c5n6-c5ccc6ccccc6c5)cc4c4c5ccccc5c5c6ccccc6sc5c43)ccc2c1]

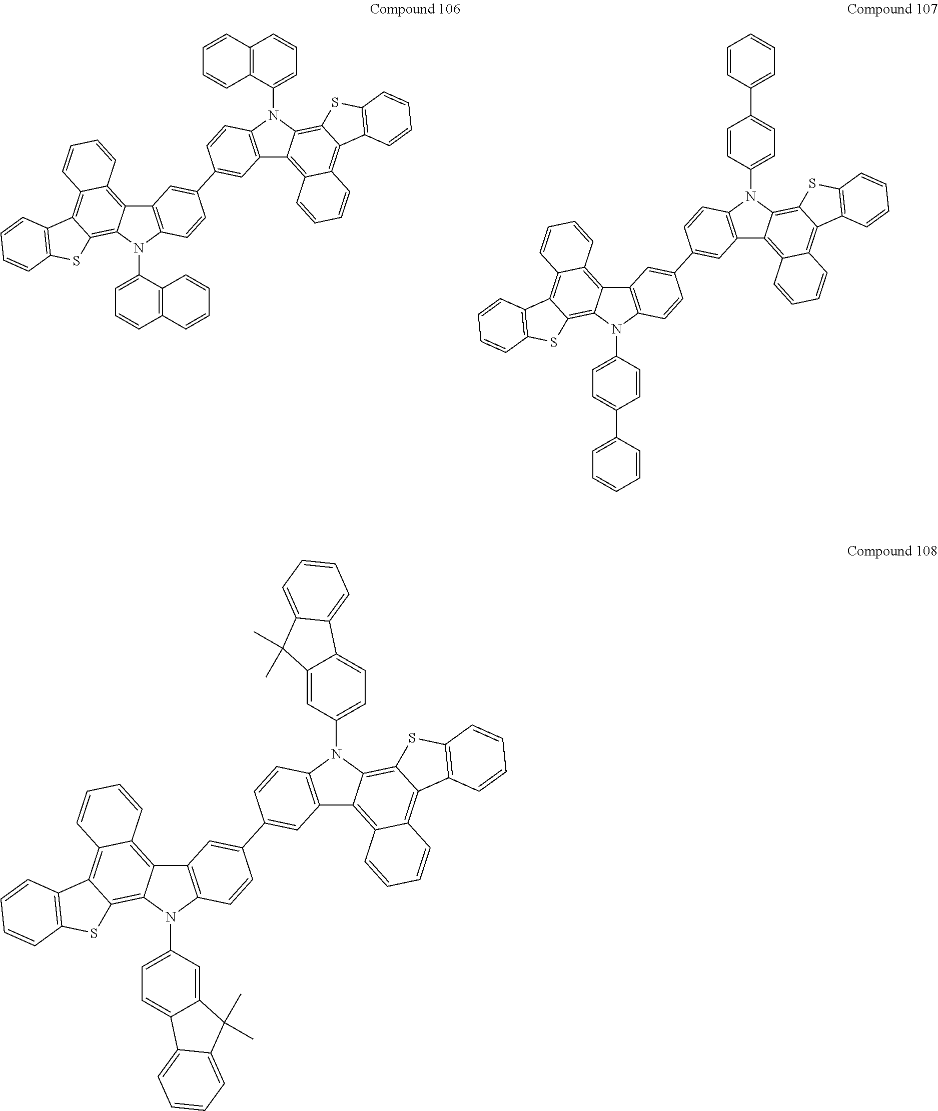 [SMILES: c1ccc2c(-n3c4ccc(-c5ccc6c(c5)c5c7ccccc7c7c8ccccc8sc7c5n6-c5cccc6ccccc56)cc4c4c5ccccc5c5c6ccccc6sc5c43)cccc2c1 ; c1ccc(-c2ccc(-n3c4ccc(-c5ccc6c(c5)c5c7ccccc7c7c8ccccc8sc7c5n6-c5ccc(-c6ccccc6)cc5)cc4c4c5ccccc5c5c6ccccc6sc5c43)cc2)cc1 ; CC1(C)c2ccccc2-c2ccc(-n3c4ccc(-c5ccc6c(c5)c5c7ccccc7c7c8ccccc8sc7c5n6-c5ccc6c(c5)C(C)(C)c5ccccc5-6)cc4c4c5ccccc5c5c6ccccc6sc5c43)cc21]

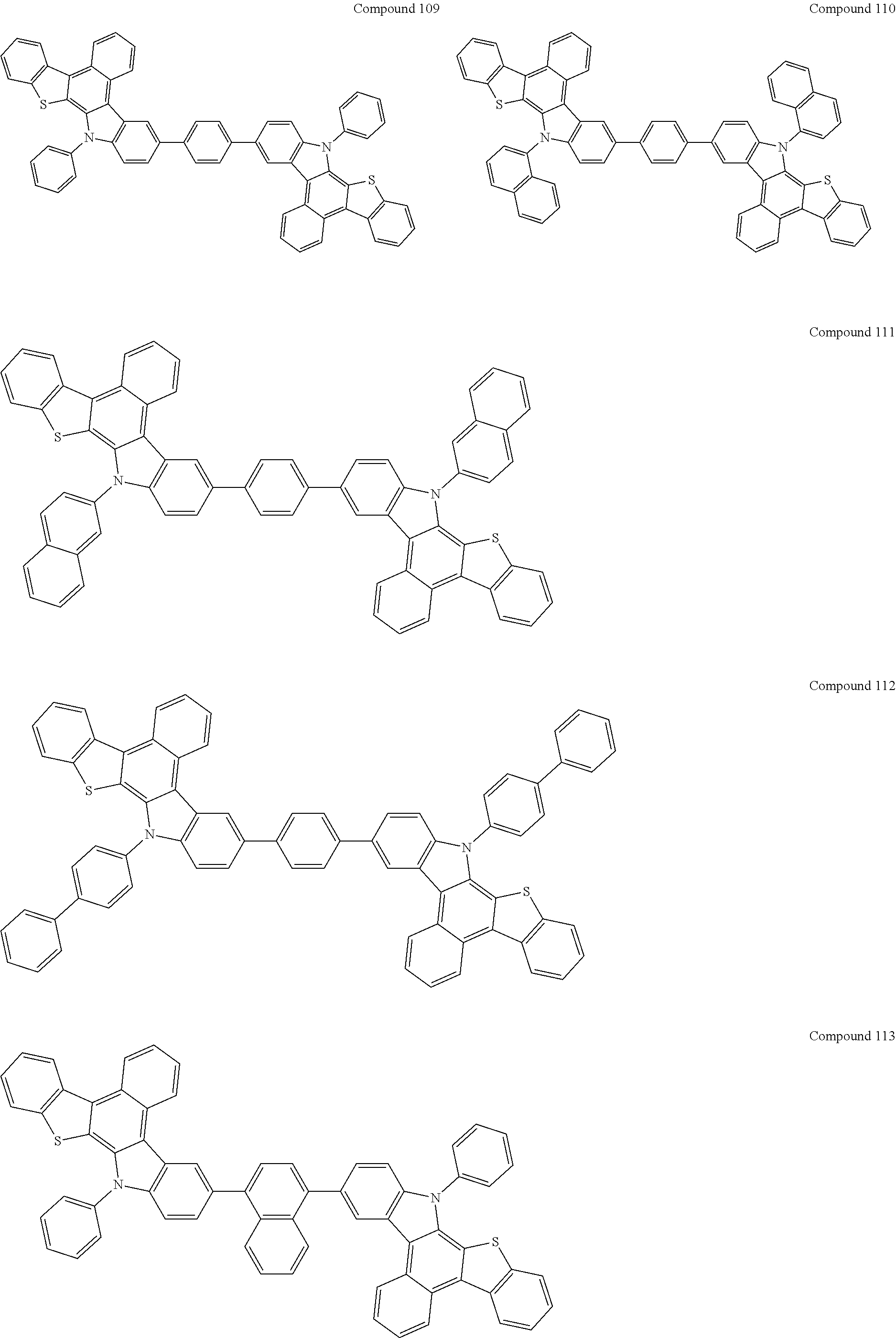

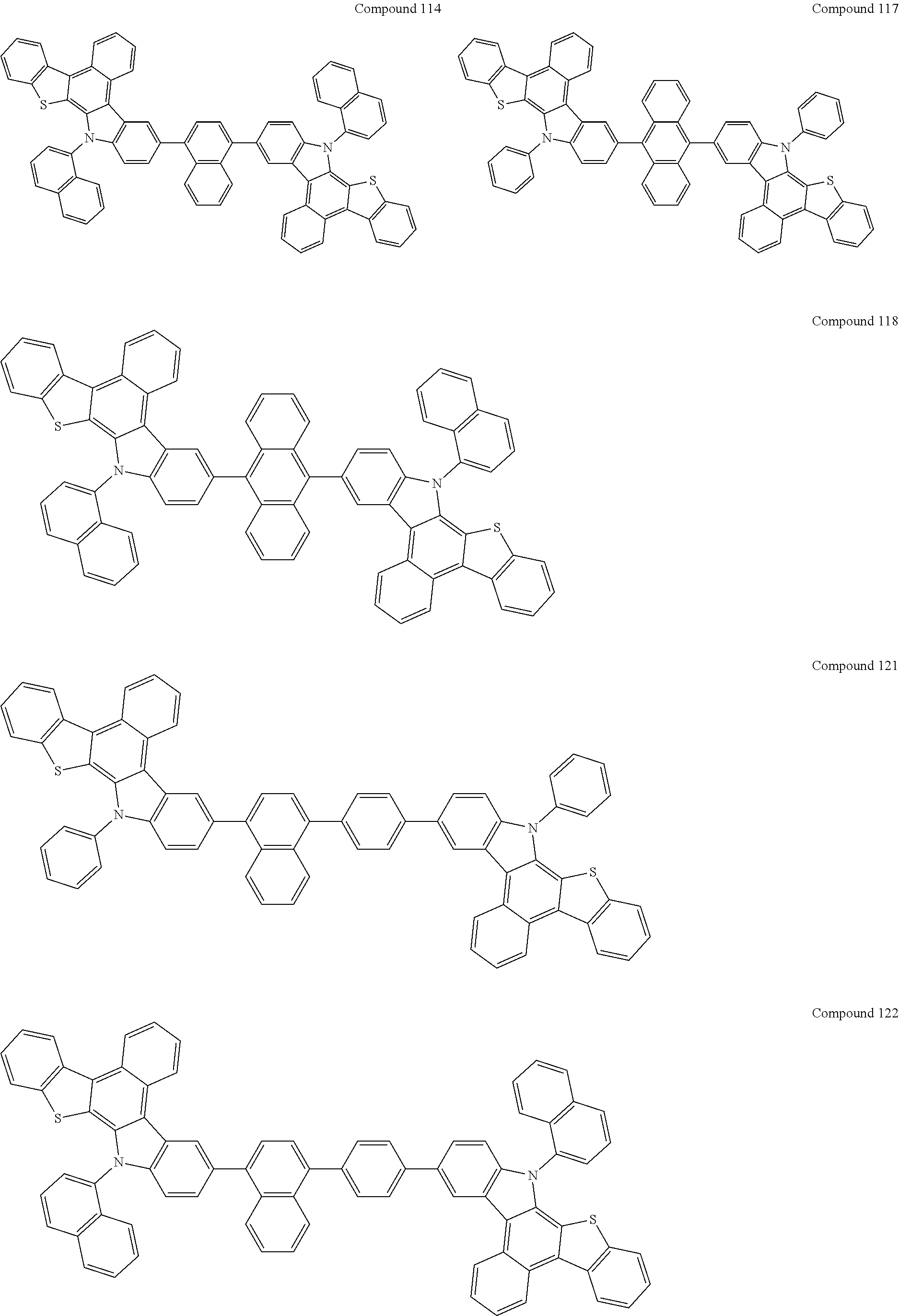

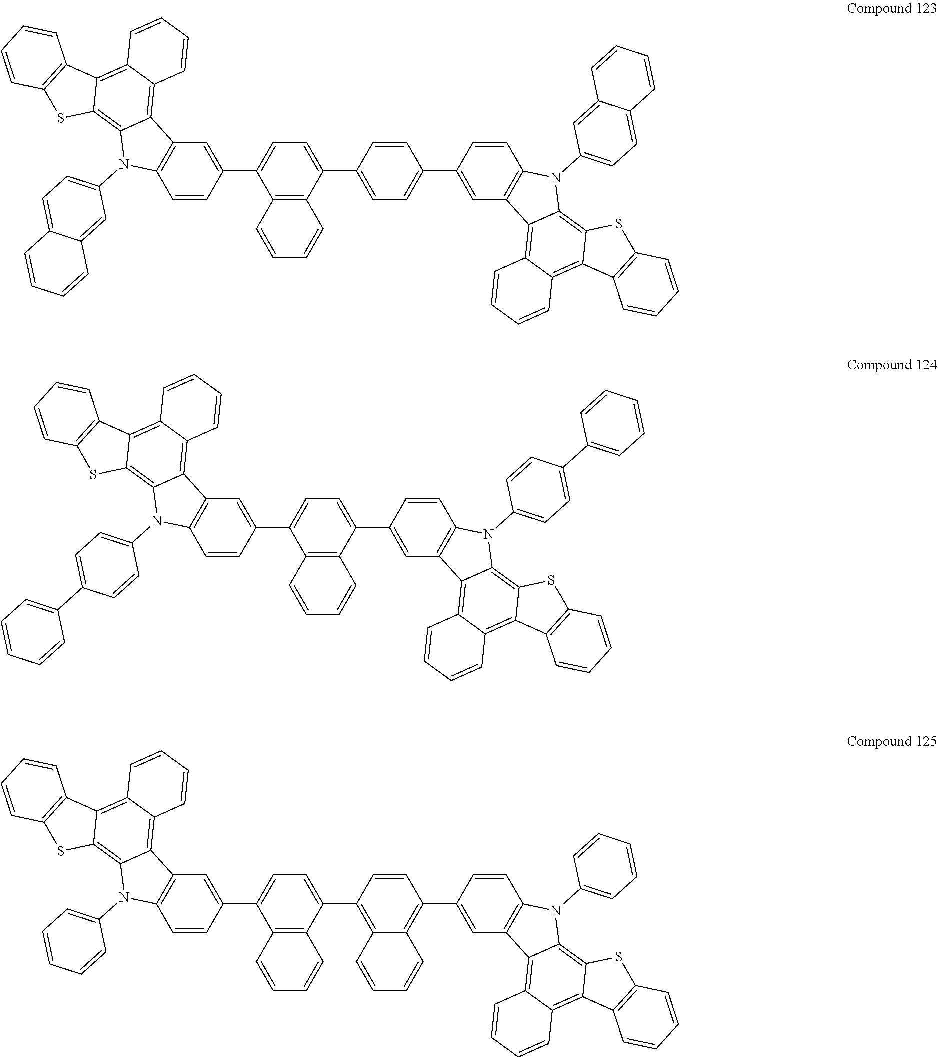 [SMILES: c1ccc2cc(-n3c4ccc(-c5ccc(-c6ccc(-c7ccc8c(c7)c7c9ccccc9c9c%10ccccc%10sc9c7n8-c7ccc8ccccc8c7)c7ccccc67)cc5)cc4c4c5ccccc5c5c6ccccc6sc5c43)ccc2c1 ; c1ccc(-c2ccc(-n3c4ccc(-c5ccc(-c6ccc7c(c6)c6c8ccccc8c8c9ccccc9sc8c6n7-c6ccc(-c7ccccc7)cc6)c6ccccc56)cc4c4c5ccccc5c5c6ccccc6sc5c43)cc2)cc1 ; c1ccc(-n2c3ccc(-c4ccc(-c5ccc(-c6ccc7c(c6)c6c8ccccc8c8c9ccccc9sc8c6n7-c6ccccc6)c6ccccc56)c5ccccc45)cc3c3c4ccccc4c4c5ccccc5sc4c32)cc1]

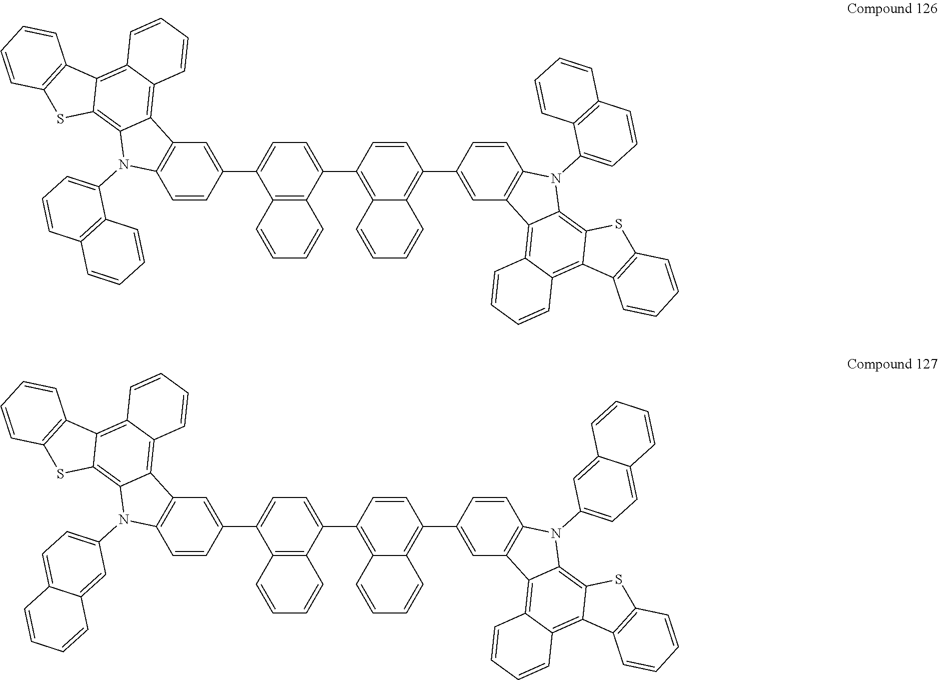 [SMILES: c1ccc2c(-n3c4ccc(-c5ccc(-c6ccc(-c7ccc8c(c7)c7c9ccccc9c9c%10ccccc%10sc9c7n8-c7cccc8ccccc78)c7ccccc67)c6ccccc56)cc4c4c5ccccc5c5c6ccccc6sc5c43)cccc2c1 ; c1ccc2cc(-n3c4ccc(-c5ccc(-c6ccc(-c7ccc8c(c7)c7c9ccccc9c9c%10ccccc%10sc9c7n8-c7ccc8ccccc8c7)c7ccccc67)c6ccccc56)cc4c4c5ccccc5c5c6ccccc6sc5c43)ccc2c1]

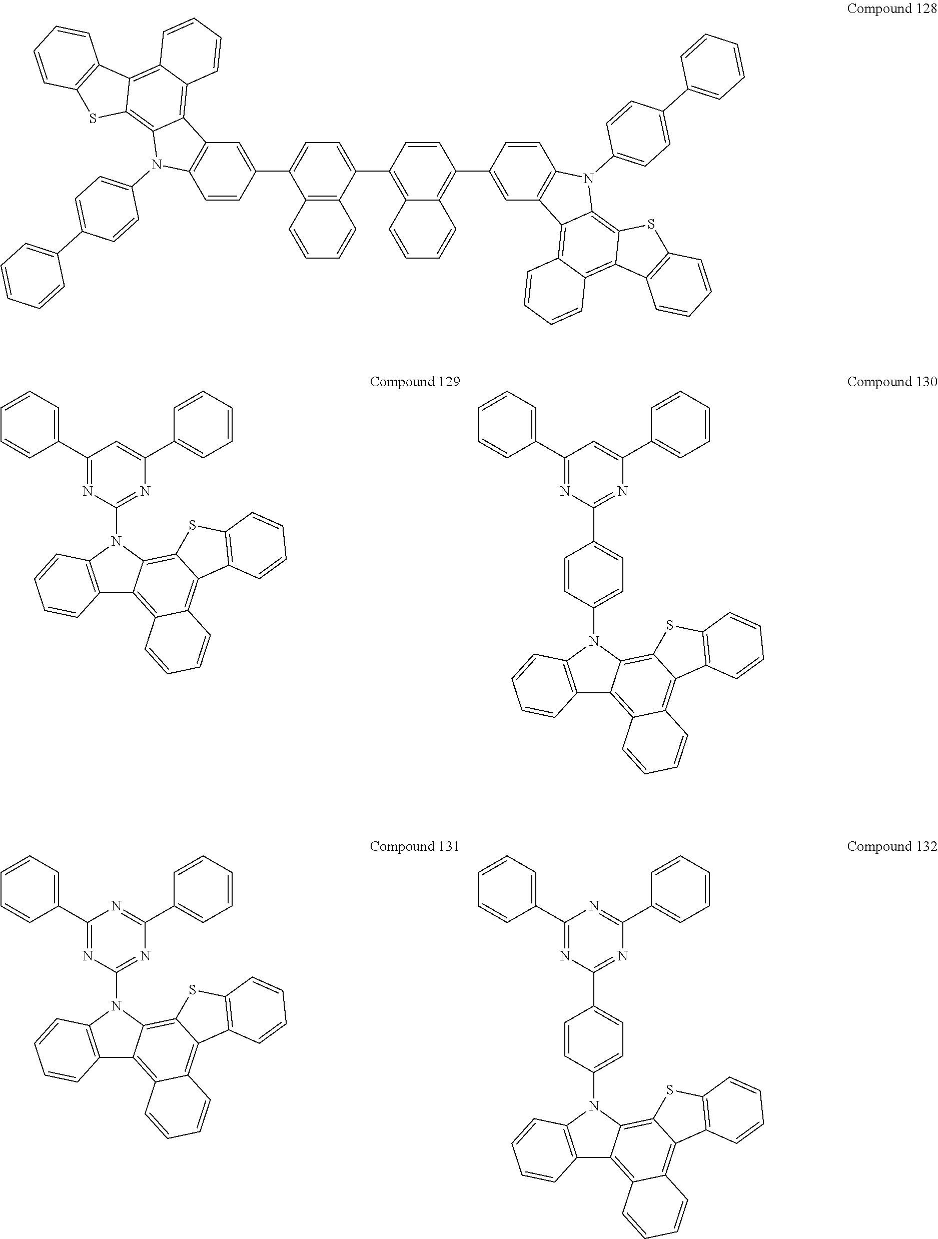 [SMILES: c1ccc(-c2ccc(-n3c4ccc(-c5ccc(-c6ccc(-c7ccc8c(c7)c7c9ccccc9c9c%10ccccc%10sc9c7n8-c7ccc(-c8ccccc8)cc7)c7ccccc67)c6ccccc56)cc4c4c5ccccc5c5c6ccccc6sc5c43)cc2)cc1 ; c1ccc(-c2cc(-c3ccccc3)nc(-n3c4ccccc4c4c5ccccc5c5c6ccccc6sc5c43)n2)cc1 ; c1ccc(-c2cc(-c3ccccc3)nc(-c3ccc(-n4c5ccccc5c5c6ccccc6c6c7ccccc7sc6c54)cc3)n2)cc1 ; c1ccc(-c2nc(-c3ccccc3)nc(-n3c4ccccc4c4c5ccccc5c5c6ccccc6sc5c43)n2)cc1 ; c1ccc(-c2nc(-c3ccccc3)nc(-c3ccc(-n4c5ccccc5c5c6ccccc6c6c7ccccc7sc6c54)cc3)n2)cc1]

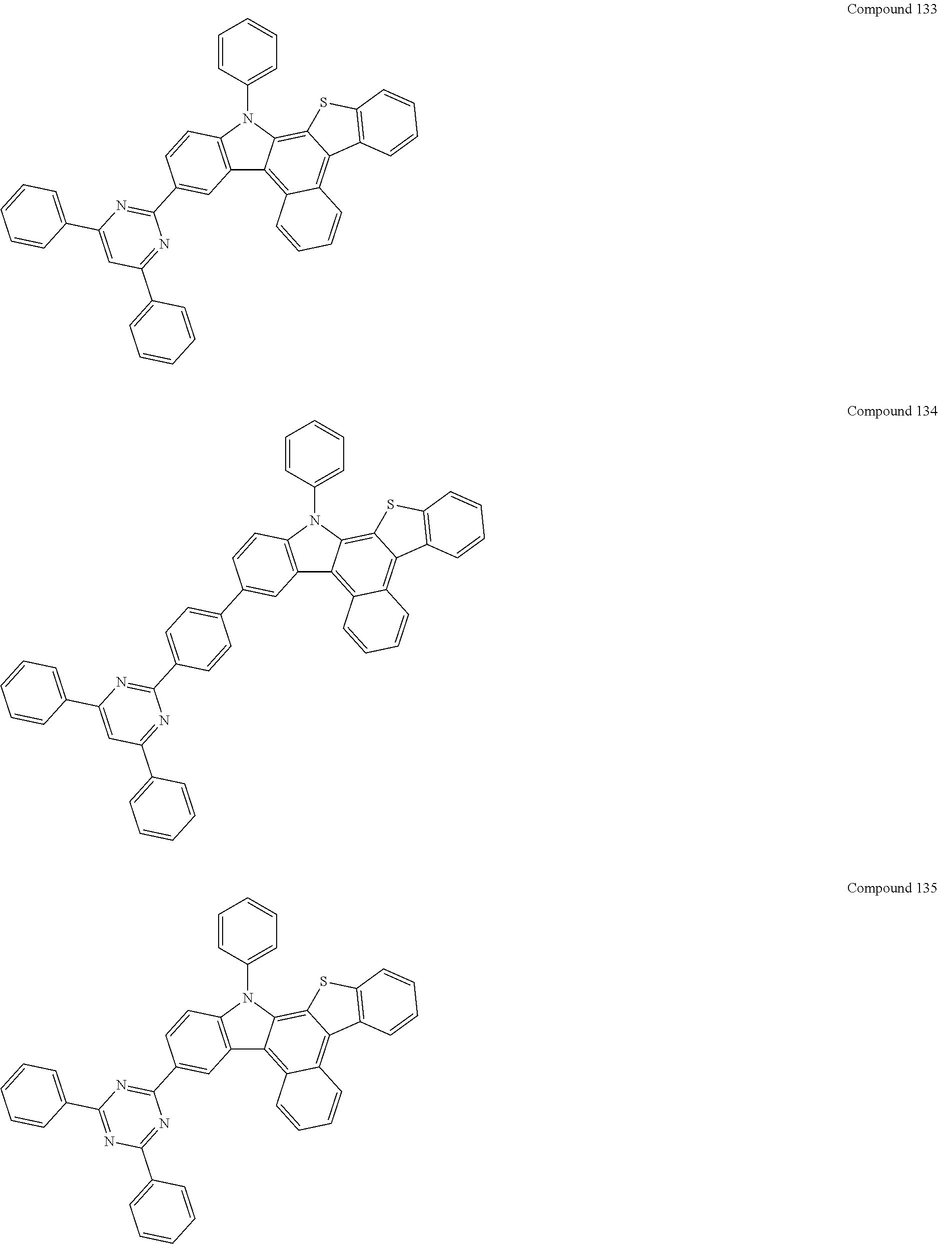 [SMILES: c1ccc(-c2cc(-c3ccccc3)nc(-c3ccc4c(c3)c3c5ccccc5c5c6ccccc6sc5c3n4-c3ccccc3)n2)cc1 ; c1ccc(-c2cc(-c3ccccc3)nc(-c3ccc(-c4ccc5c(c4)c4c6ccccc6c6c7ccccc7sc6c4n5-c4ccccc4)cc3)n2)cc1 ; c1ccc(-c2nc(-c3ccccc3)nc(-c3ccc4c(c3)c3c5ccccc5c5c6ccccc6sc5c3n4-c3ccccc3)n2)cc1]

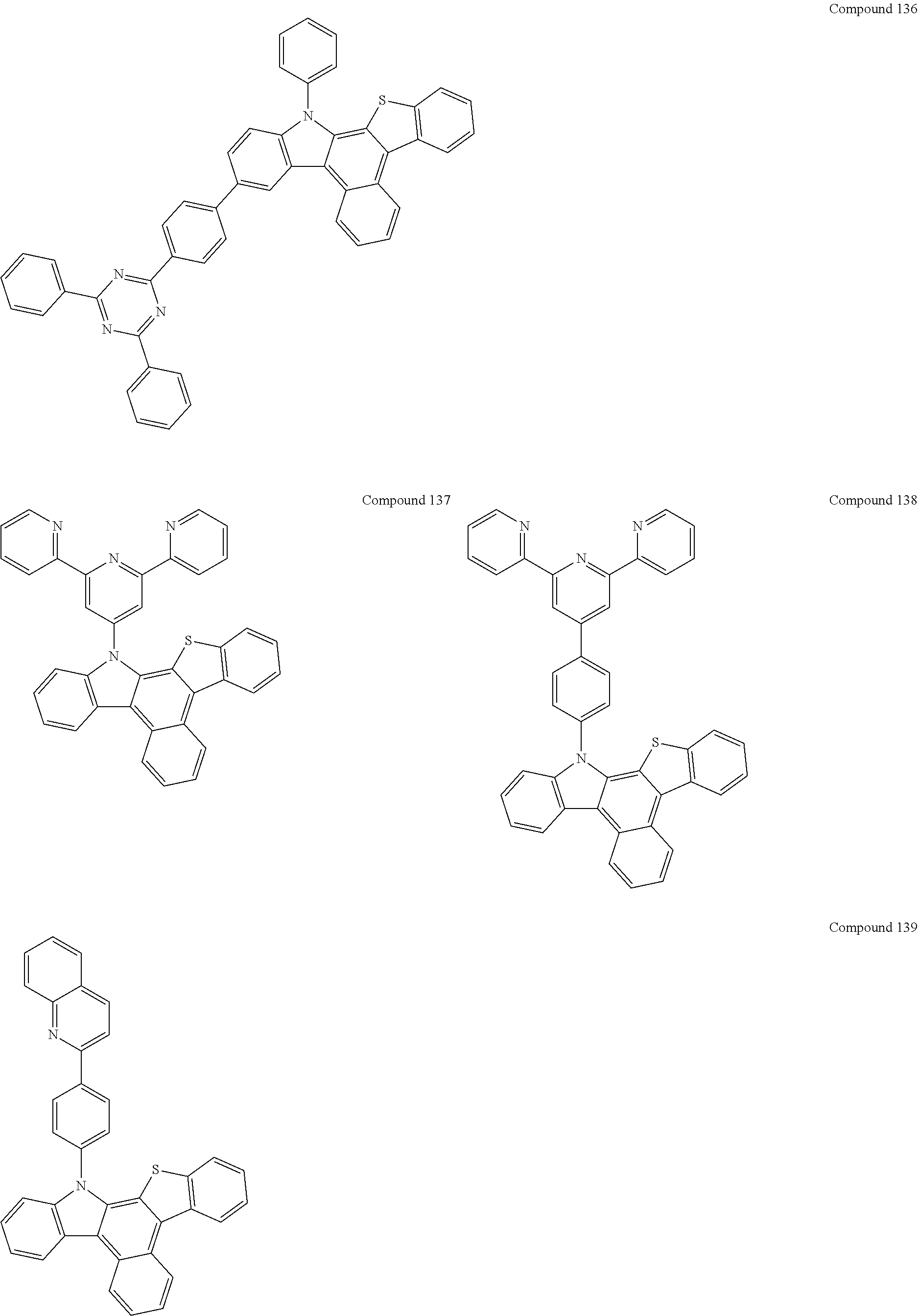 [SMILES: c1ccc(-c2nc(-c3ccccc3)nc(-c3ccc(-c4ccc5c(c4)c4c6ccccc6c6c7ccccc7sc6c4n5-c4ccccc4)cc3)n2)cc1 ; c1ccc(-c2cc(-n3c4ccccc4c4c5ccccc5c5c6ccccc6sc5c43)cc(-c3ccccn3)n2)nc1 ; c1ccc(-c2cc(-c3ccc(-n4c5ccccc5c5c6ccccc6c6c7ccccc7sc6c54)cc3)cc(-c3ccccn3)n2)nc1 ; c1ccc2nc(-c3ccc(-n4c5ccccc5c5c6ccccc6c6c7ccccc7sc6c54)cc3)ccc2c1]

In an embodiment, the emission layer may include a first sub emission layer, a third host layer, and a second sub emission layer. The first sub emission layer may include the first host and the dopant. The third host layer may be provided on the first sub emission layer and include a fourth host. The second sub emission layer may be provided on the third host layer and include the first host and the dopant.

In an embodiment, the fourth host may be represented by Formula 1.

In an embodiment, the third host layer may not include the dopant.

In an embodiment, the fourth host may include at least one compound of the compounds in the following Compound Group 1.

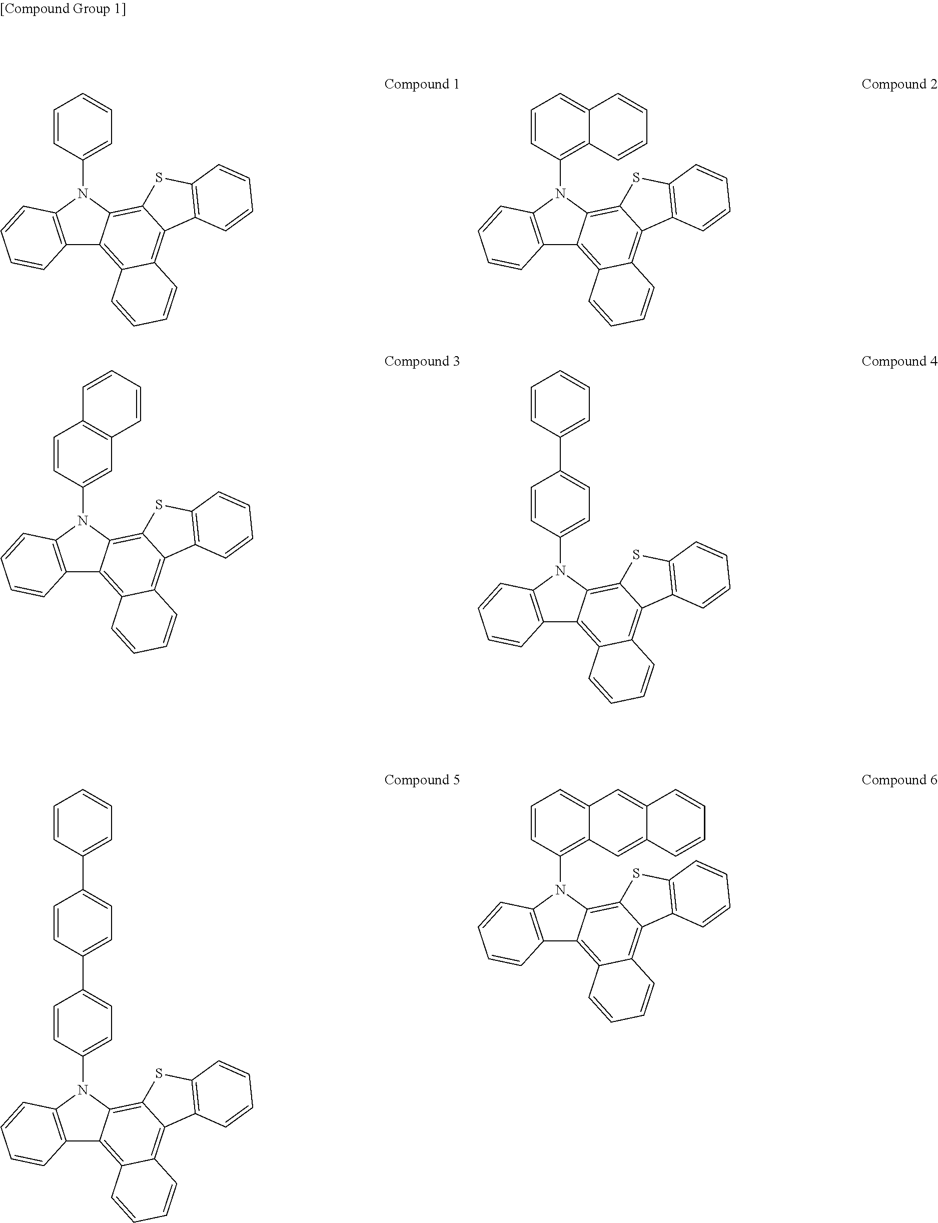 [SMILES: c1ccc(-n2c3ccccc3c3c4ccccc4c4c5ccccc5sc4c32)cc1 ; c1ccc2c(-n3c4ccccc4c4c5ccccc5c5c6ccccc6sc5c43)cccc2c1 ; c1ccc2cc(-n3c4ccccc4c4c5ccccc5c5c6ccccc6sc5c43)ccc2c1 ; c1ccc(-c2ccc(-n3c4ccccc4c4c5ccccc5c5c6ccccc6sc5c43)cc2)cc1 ; c1ccc(-c2ccc(-c3ccc(-n4c5ccccc5c5c6ccccc6c6c7ccccc7sc6c54)cc3)cc2)cc1 ; c1ccc2cc3c(-n4c5ccccc5c5c6ccccc6c6c7ccccc7sc6c54)cccc3cc2c1]

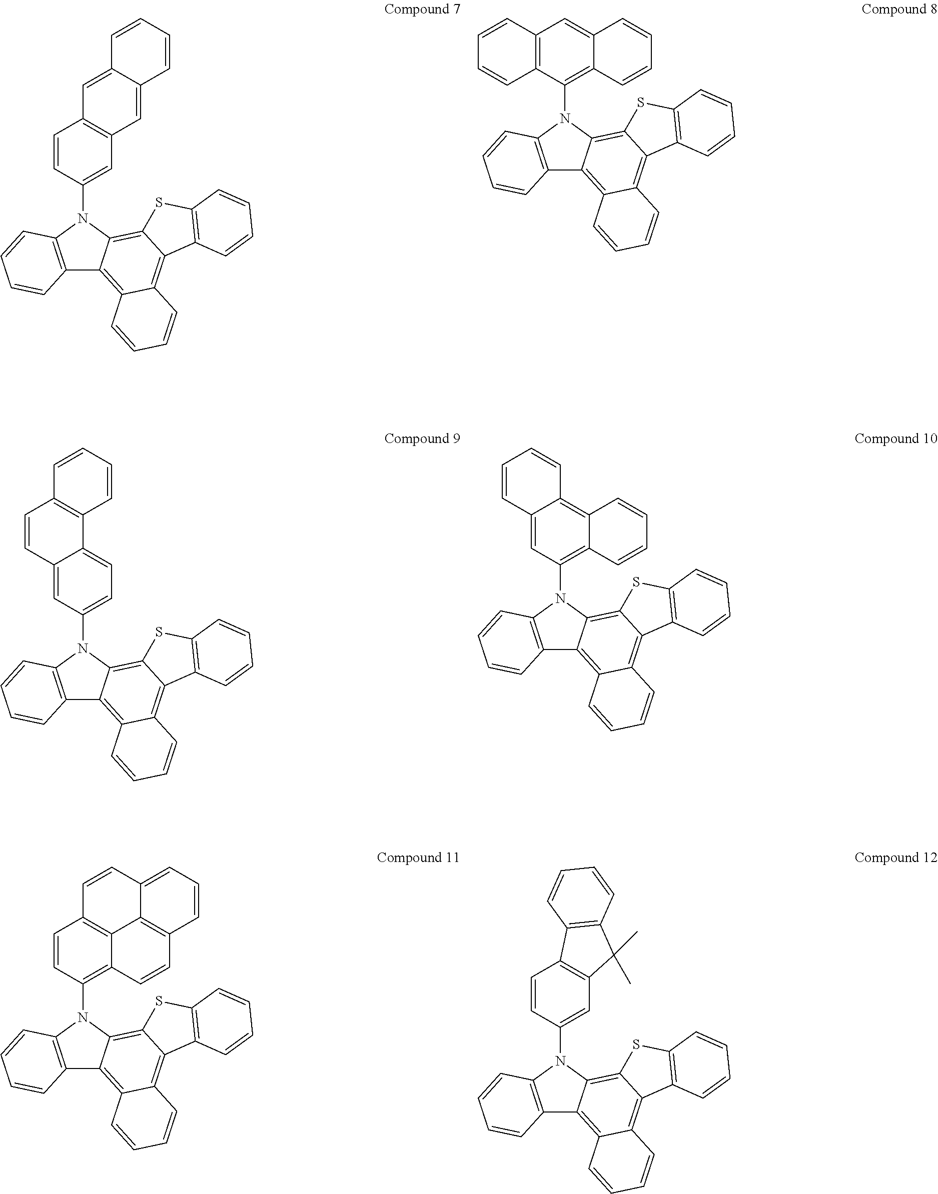 [SMILES: c1ccc2cc3cc(-n4c5ccccc5c5c6ccccc6c6c7ccccc7sc6c54)ccc3cc2c1 ; c1ccc2c(-n3c4ccccc4c4c5ccccc5c5c6ccccc6sc5c43)c3ccccc3cc2c1 ; c1ccc2c(c1)ccc1cc(-n3c4ccccc4c4c5ccccc5c5c6ccccc6sc5c43)ccc12 ; c1ccc2c(c1)cc(-n1c3ccccc3c3c4ccccc4c4c5ccccc5sc4c31)c1ccccc12 ; c1cc2ccc3ccc(-n4c5ccccc5c5c6ccccc6c6c7ccccc7sc6c54)c4ccc(c1)c2c34 ; CC1(C)c2ccccc2-c2ccc(-n3c4ccccc4c4c5ccccc5c5c6ccccc6sc5c43)cc21]

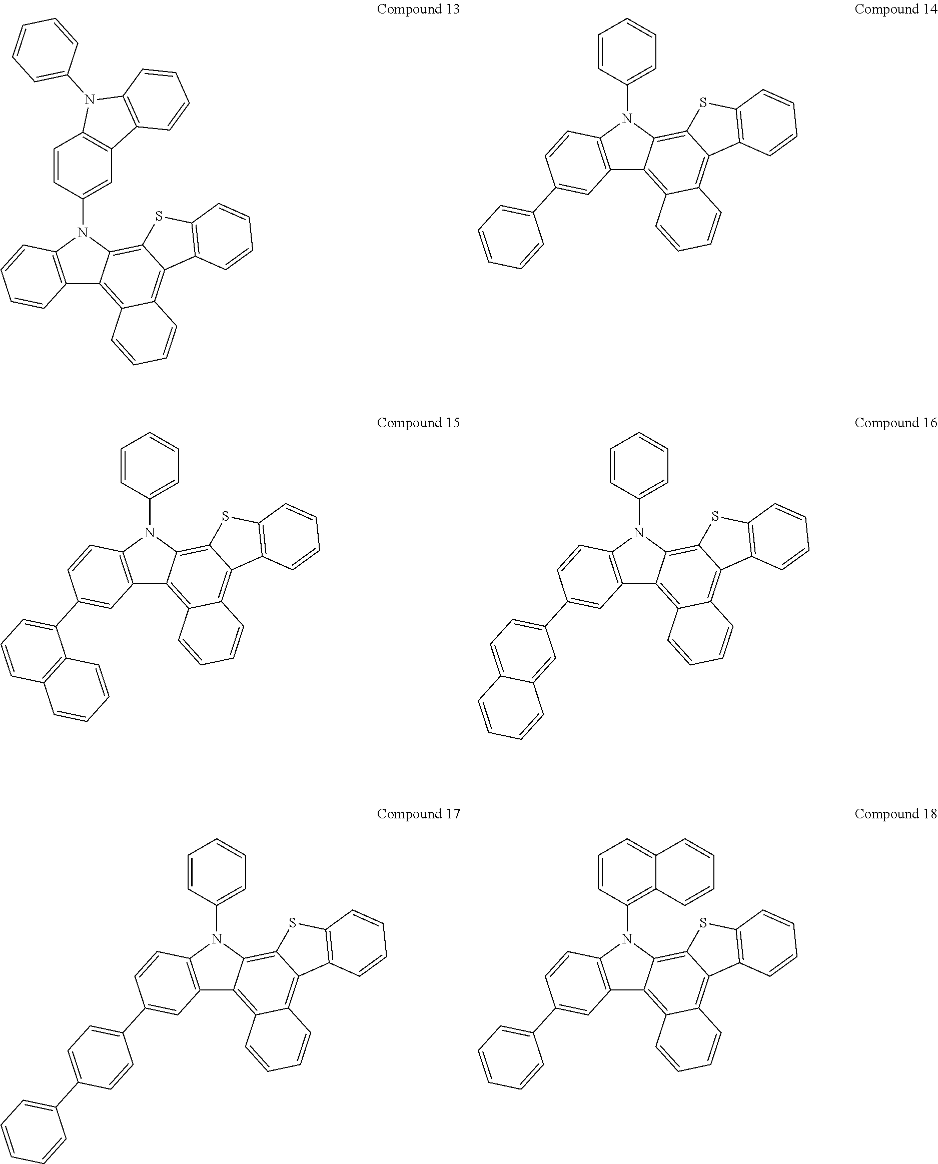 [SMILES: c1ccc(-n2c3ccccc3c3cc(-n4c5ccccc5c5c6ccccc6c6c7ccccc7sc6c54)ccc32)cc1 ; c1ccc(-c2ccc3c(c2)c2c4ccccc4c4c5ccccc5sc4c2n3-c2ccccc2)cc1 ; c1ccc(-n2c3ccc(-c4cccc5ccccc45)cc3c3c4ccccc4c4c5ccccc5sc4c32)cc1 ; c1ccc(-n2c3ccc(-c4ccc5ccccc5c4)cc3c3c4ccccc4c4c5ccccc5sc4c32)cc1 ; c1ccc(-c2ccc(-c3ccc4c(c3)c3c5ccccc5c5c6ccccc6sc5c3n4-c3ccccc3)cc2)cc1 ; c1ccc(-c2ccc3c(c2)c2c4ccccc4c4c5ccccc5sc4c2n3-c2cccc3ccccc23)cc1]

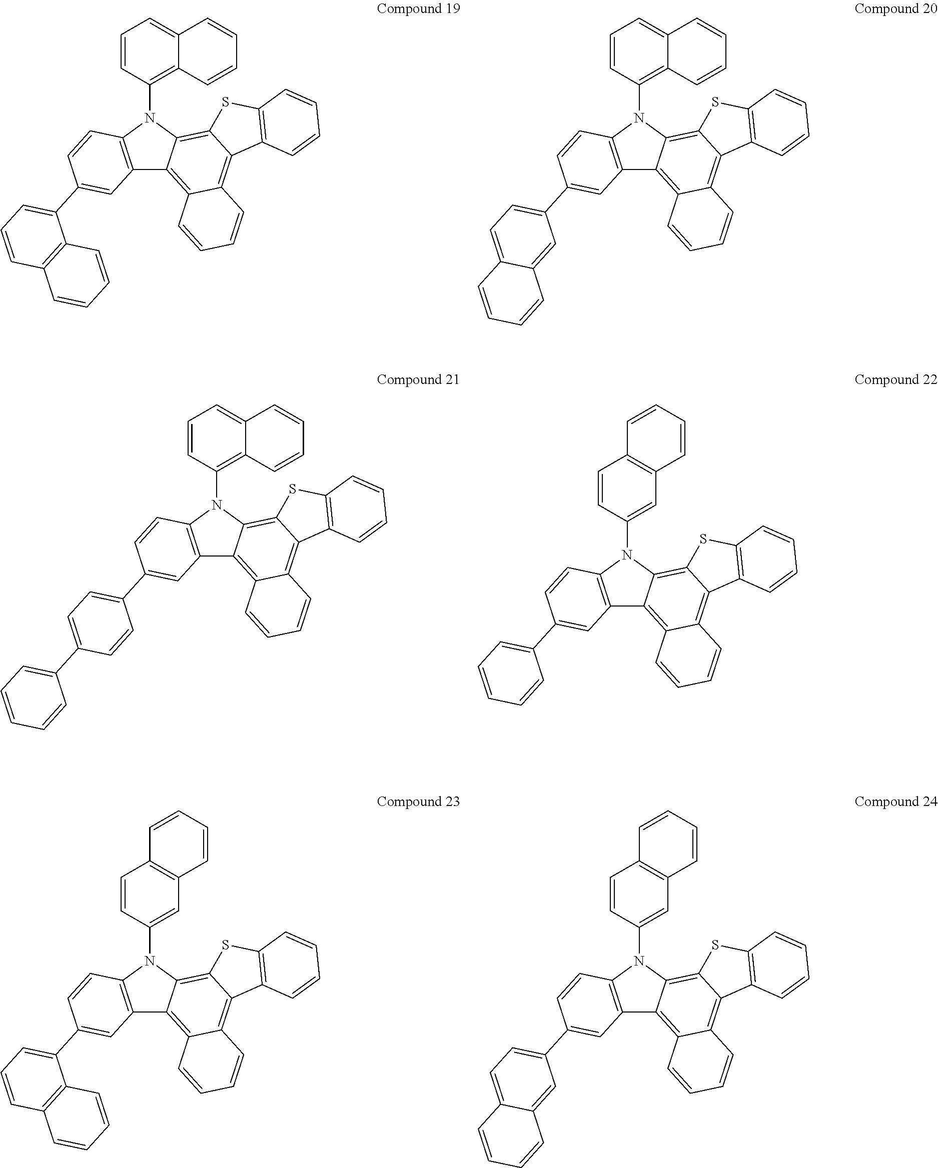 [SMILES: c1ccc2c(-c3ccc4c(c3)c3c5ccccc5c5c6ccccc6sc5c3n4-c3cccc4ccccc34)cccc2c1 ; c1ccc2cc(-c3ccc4c(c3)c3c5ccccc5c5c6ccccc6sc5c3n4-c3cccc4ccccc34)ccc2c1 ; c1ccc(-c2ccc(-c3ccc4c(c3)c3c5ccccc5c5c6ccccc6sc5c3n4-c3cccc4ccccc34)cc2)cc1 ; c1ccc(-c2ccc3c(c2)c2c4ccccc4c4c5ccccc5sc4c2n3-c2ccc3ccccc3c2)cc1 ; c1ccc2cc(-n3c4ccc(-c5cccc6ccccc56)cc4c4c5ccccc5c5c6ccccc6sc5c43)ccc2c1 ; c1ccc2cc(-c3ccc4c(c3)c3c5ccccc5c5c6ccccc6sc5c3n4-c3ccc4ccccc4c3)ccc2c1]

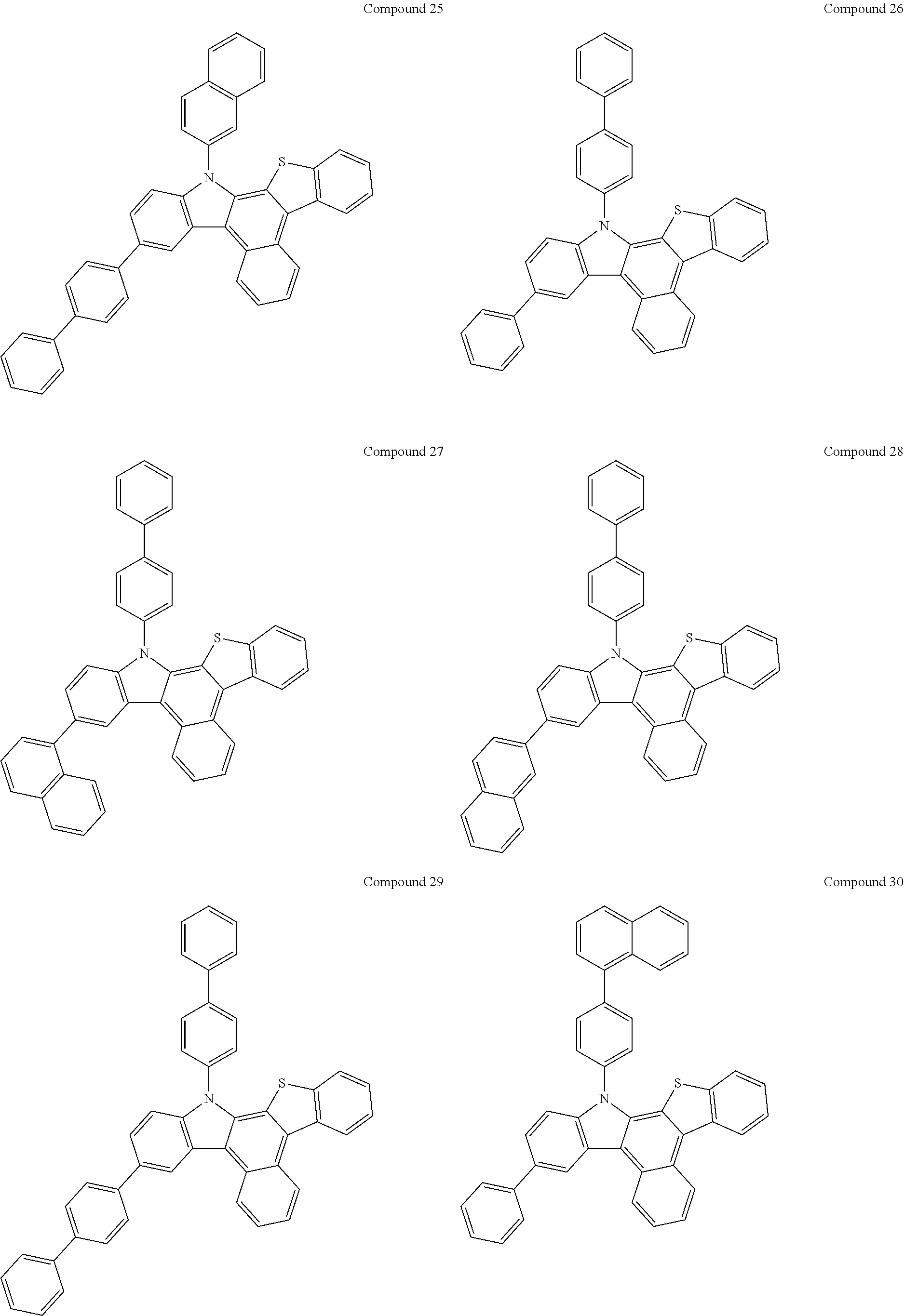 [SMILES: c1ccc(-c2ccc(-c3ccc4c(c3)c3c5ccccc5c5c6ccccc6sc5c3n4-c3ccc4ccccc4c3)cc2)cc1 ; c1ccc(-c2ccc(-n3c4ccc(-c5ccccc5)cc4c4c5ccccc5c5c6ccccc6sc5c43)cc2)cc1 ; c1ccc(-c2ccc(-n3c4ccc(-c5cccc6ccccc56)cc4c4c5ccccc5c5c6ccccc6sc5c43)cc2)cc1 ; c1ccc(-c2ccc(-n3c4ccc(-c5ccc6ccccc6c5)cc4c4c5ccccc5c5c6ccccc6sc5c43)cc2)cc1 ; c1ccc(-c2ccc(-c3ccc4c(c3)c3c5ccccc5c5c6ccccc6sc5c3n4-c3ccc(-c4ccccc4)cc3)cc2)cc1 ; c1ccc(-c2ccc3c(c2)c2c4ccccc4c4c5ccccc5sc4c2n3-c2ccc(-c3cccc4ccccc34)cc2)cc1]

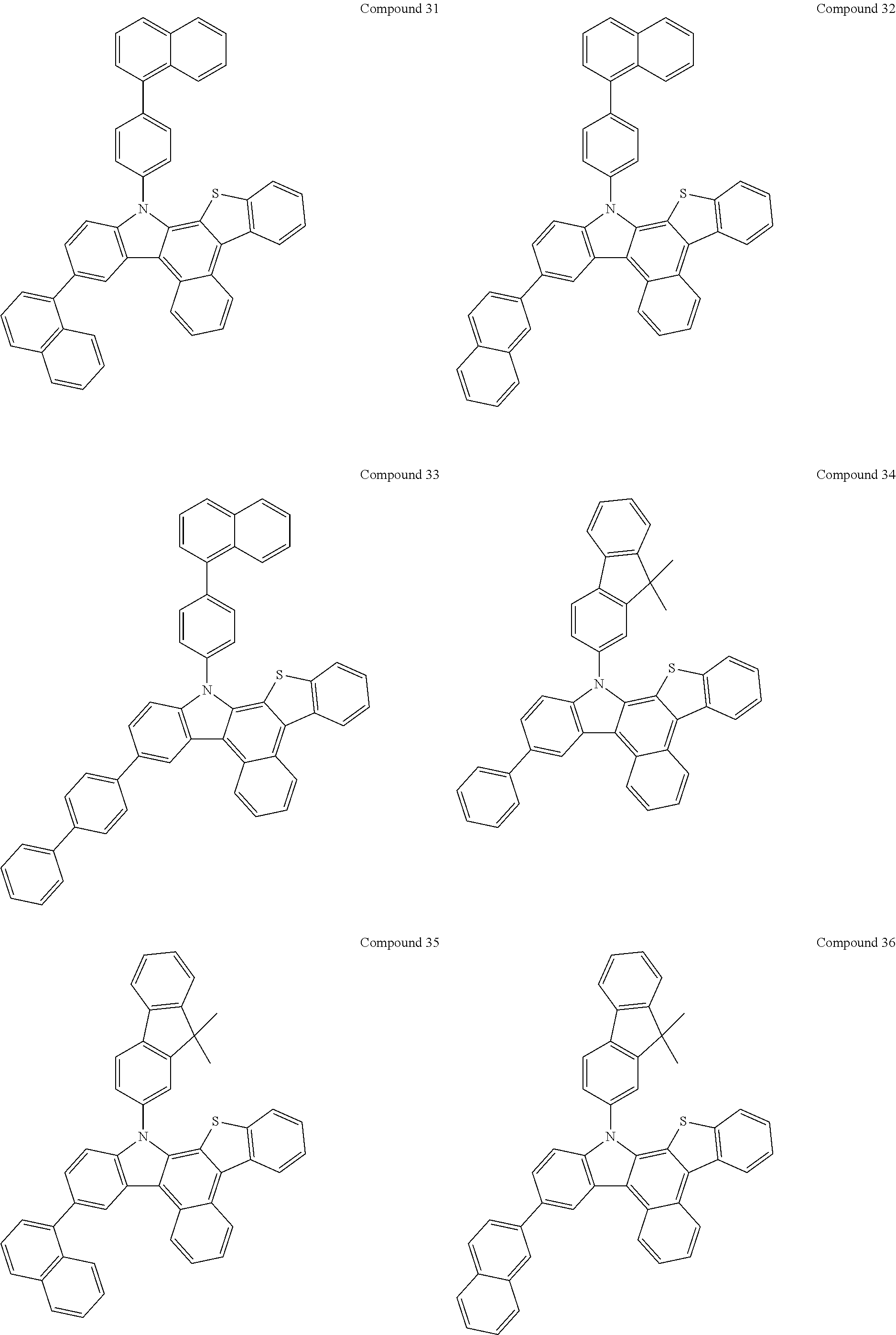 [SMILES: c1ccc2c(-c3ccc(-n4c5ccc(-c6cccc7ccccc67)cc5c5c6ccccc6c6c7ccccc7sc6c54)cc3)cccc2c1 ; c1ccc2cc(-c3ccc4c(c3)c3c5ccccc5c5c6ccccc6sc5c3n4-c3ccc(-c4cccc5ccccc45)cc3)ccc2c1 ; c1ccc(-c2ccc(-c3ccc4c(c3)c3c5ccccc5c5c6ccccc6sc5c3n4-c3ccc(-c4cccc5ccccc45)cc3)cc2)cc1 ; CC1(C)c2ccccc2-c2ccc(-n3c4ccc(-c5ccccc5)cc4c4c5ccccc5c5c6ccccc6sc5c43)cc21 ; CC1(C)c2ccccc2-c2ccc(-n3c4ccc(-c5cccc6ccccc56)cc4c4c5ccccc5c5c6ccccc6sc5c43)cc21 ; CC1(C)c2ccccc2-c2ccc(-n3c4ccc(-c5ccc6ccccc6c5)cc4c4c5ccccc5c5c6ccccc6sc5c43)cc21]

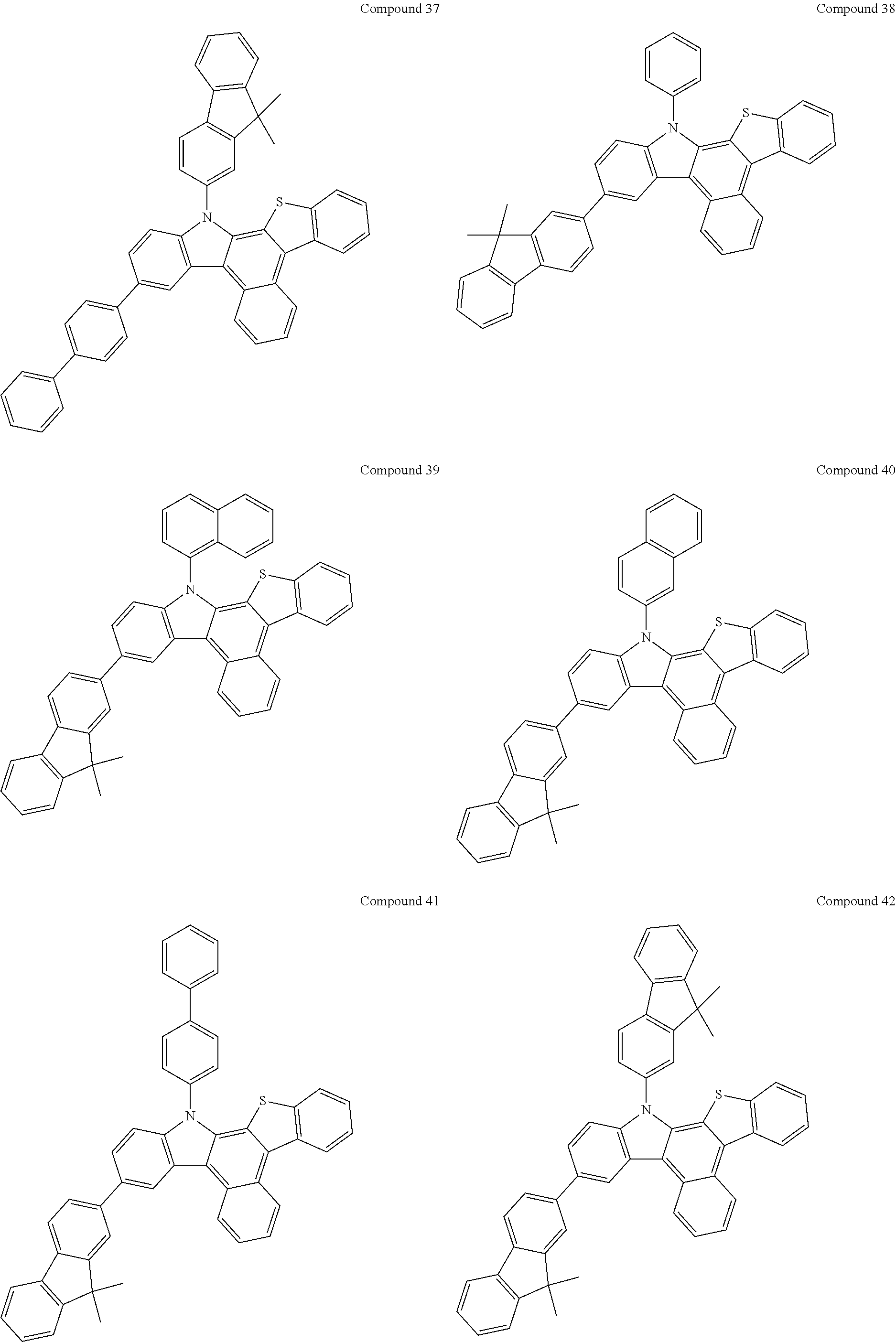

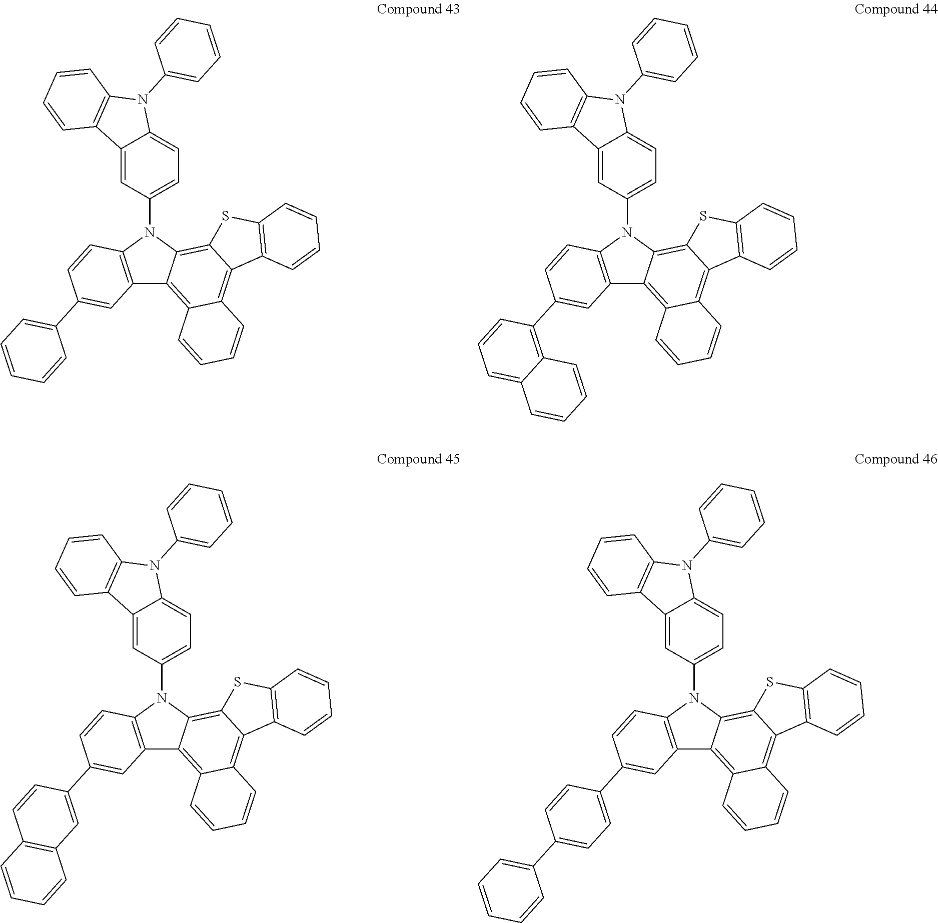 [SMILES: c1ccc(-c2ccc3c(c2)c2c4ccccc4c4c5ccccc5sc4c2n3-c2ccc3c(c2)c2ccccc2n3-c2ccccc2)cc1 ; c1ccc(-n2c3ccccc3c3cc(-n4c5ccc(-c6cccc7ccccc67)cc5c5c6ccccc6c6c7ccccc7sc6c54)ccc32)cc1 ; c1ccc(-n2c3ccccc3c3cc(-n4c5ccc(-c6ccc7ccccc7c6)cc5c5c6ccccc6c6c7ccccc7sc6c54)ccc32)cc1 ; c1ccc(-c2ccc(-c3ccc4c(c3)c3c5ccccc5c5c6ccccc6sc5c3n4-c3ccc4c(c3)c3ccccc3n4-c3ccccc3)cc2)cc1]

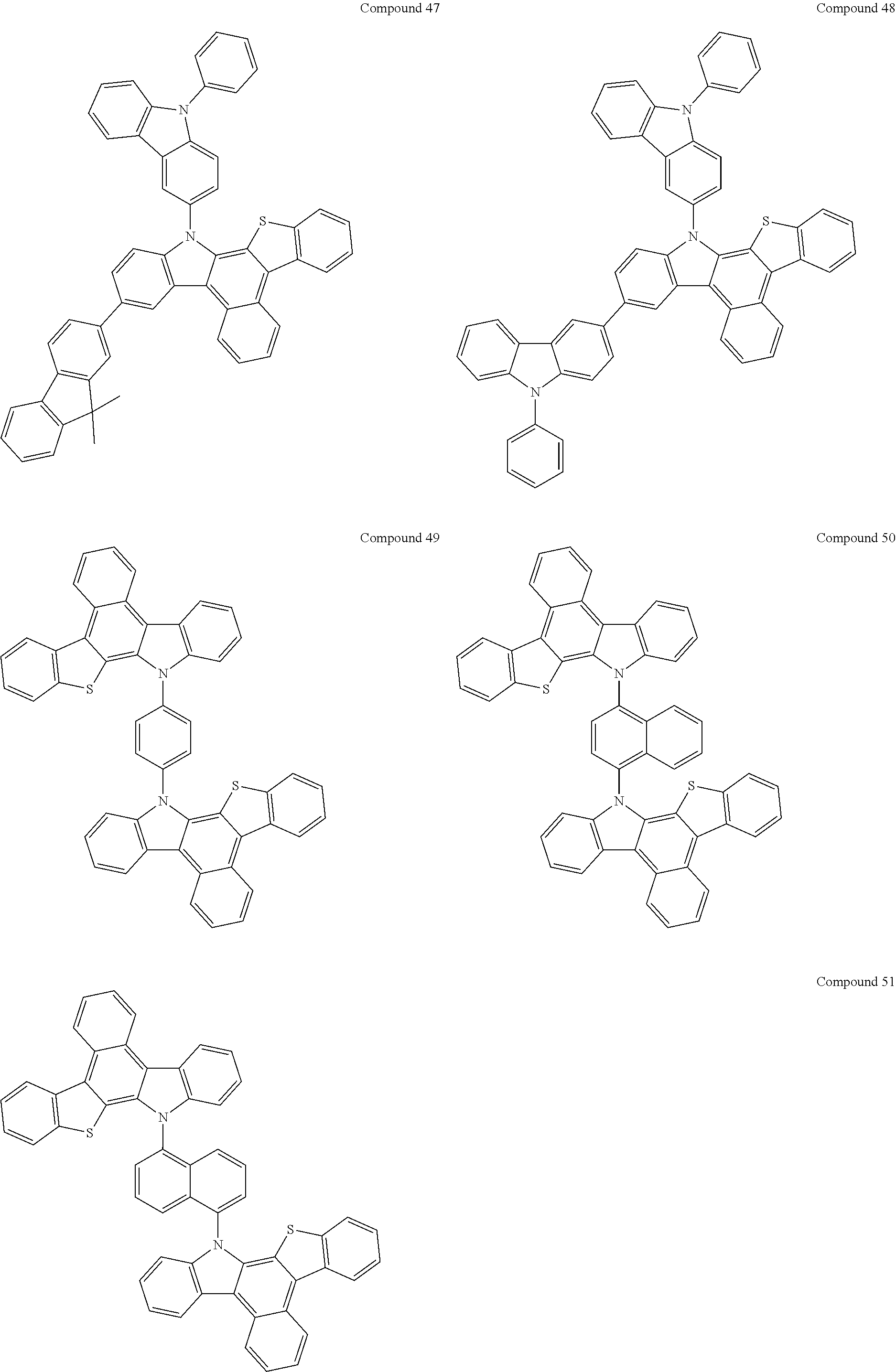 [SMILES: CC1(C)c2ccccc2-c2ccc(-c3ccc4c(c3)c3c5ccccc5c5c6ccccc6sc5c3n4-c3ccc4c(c3)c3ccccc3n4-c3ccccc3)cc21 ; c1ccc(-n2c3ccccc3c3cc(-c4ccc5c(c4)c4c6ccccc6c6c7ccccc7sc6c4n5-c4ccc5c(c4)c4ccccc4n5-c4ccccc4)ccc32)cc1 ; c1ccc2c(c1)sc1c2c2ccccc2c2c3ccccc3n(-c3ccc(-n4c5ccccc5c5c6ccccc6c6c7ccccc7sc6c54)cc3)c12 ; c1ccc2c(c1)sc1c2c2ccccc2c2c3ccccc3n(-c3ccc(-n4c5ccccc5c5c6ccccc6c6c7ccccc7sc6c54)c4ccccc34)c12 ; c1ccc2c(c1)sc1c2c2ccccc2c2c3ccccc3n(-c3cccc4c(-n5c6ccccc6c6c7ccccc7c7c8ccccc8sc7c65)cccc34)c12]

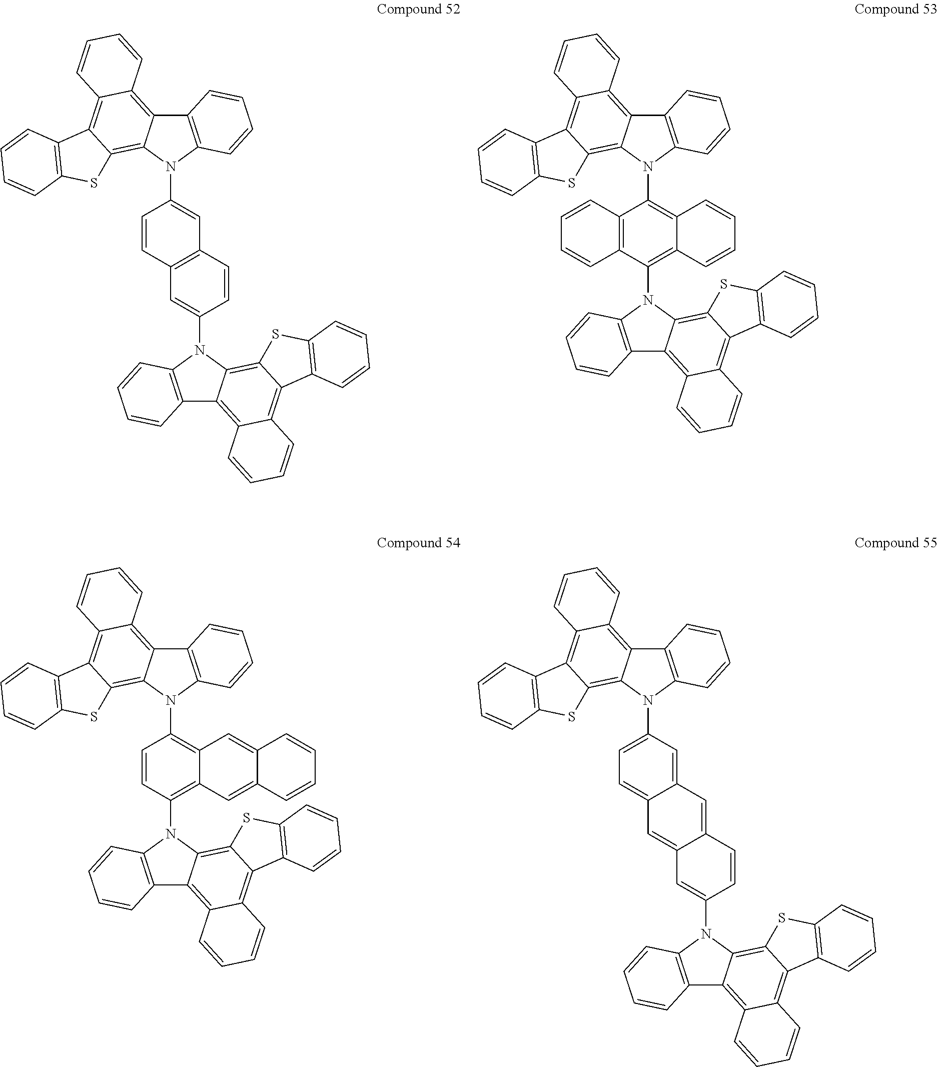 [SMILES: c1ccc2c(c1)sc1c2c2ccccc2c2c3ccccc3n(-c3ccc4cc(-n5c6ccccc6c6c7ccccc7c7c8ccccc8sc7c65)ccc4c3)c12 ; c1ccc2c(c1)sc1c2c2ccccc2c2c3ccccc3n(-c3c4ccccc4c(-n4c5ccccc5c5c6ccccc6c6c7ccccc7sc6c54)c4ccccc34)c12 ; c1ccc2cc3c(-n4c5ccccc5c5c6ccccc6c6c7ccccc7sc6c54)ccc(-n4c5ccccc5c5c6ccccc6c6c7ccccc7sc6c54)c3cc2c1 ; c1ccc2c(c1)sc1c2c2ccccc2c2c3ccccc3n(-c3ccc4cc5cc(-n6c7ccccc7c7c8ccccc8c8c9ccccc9sc8c76)ccc5cc4c3)c12]

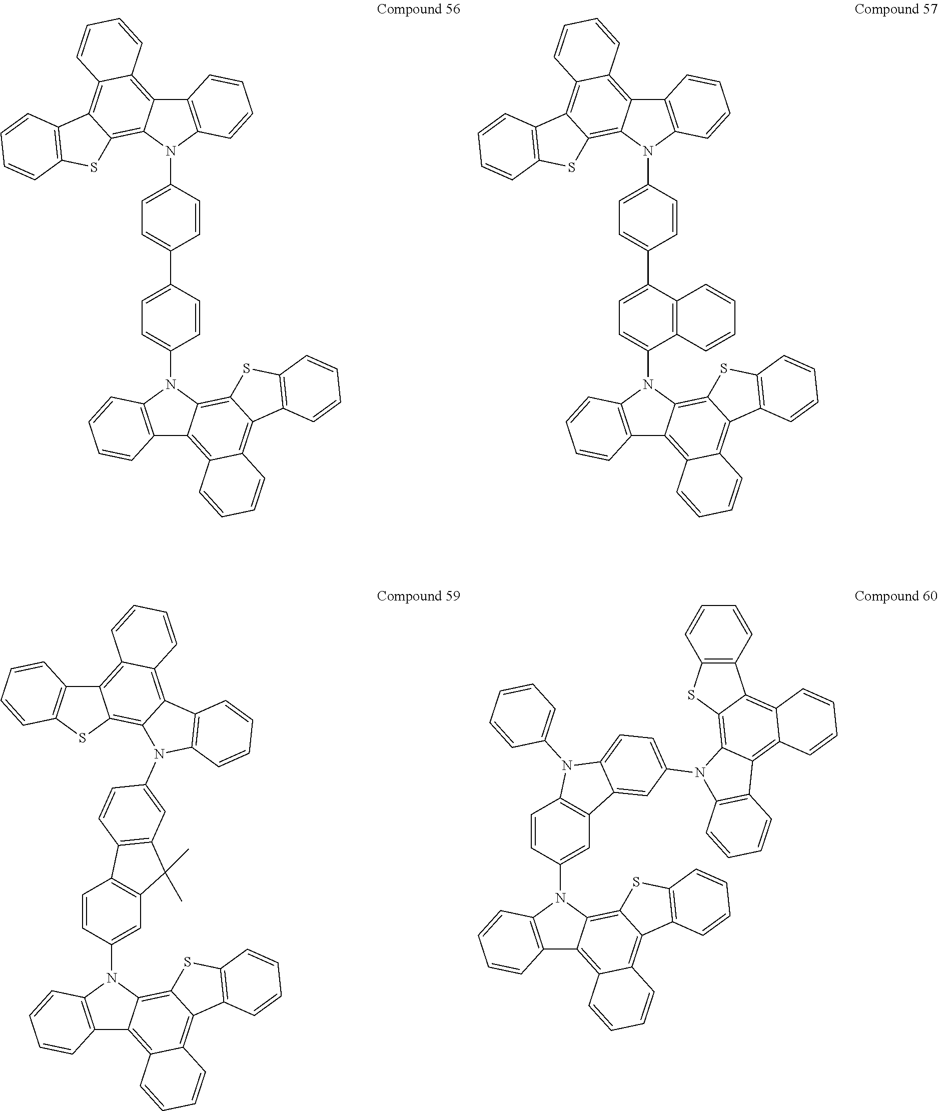 [SMILES: c1ccc2c(c1)sc1c2c2ccccc2c2c3ccccc3n(-c3ccc(-c4ccc(-n5c6ccccc6c6c7ccccc7c7c8ccccc8sc7c65)cc4)cc3)c12 ; c1ccc2c(c1)sc1c2c2ccccc2c2c3ccccc3n(-c3ccc(-c4ccc(-n5c6ccccc6c6c7ccccc7c7c8ccccc8sc7c65)c5ccccc45)cc3)c12 ; CC1(C)c2cc(-n3c4ccccc4c4c5ccccc5c5c6ccccc6sc5c43)ccc2-c2ccc(-n3c4ccccc4c4c5ccccc5c5c6ccccc6sc5c43)cc21 ; c1ccc(-n2c3ccc(-n4c5ccccc5c5c6ccccc6c6c7ccccc7sc6c54)cc3c3cc(-n4c5ccccc5c5c6ccccc6c6c7ccccc7sc6c54)ccc32)cc1]

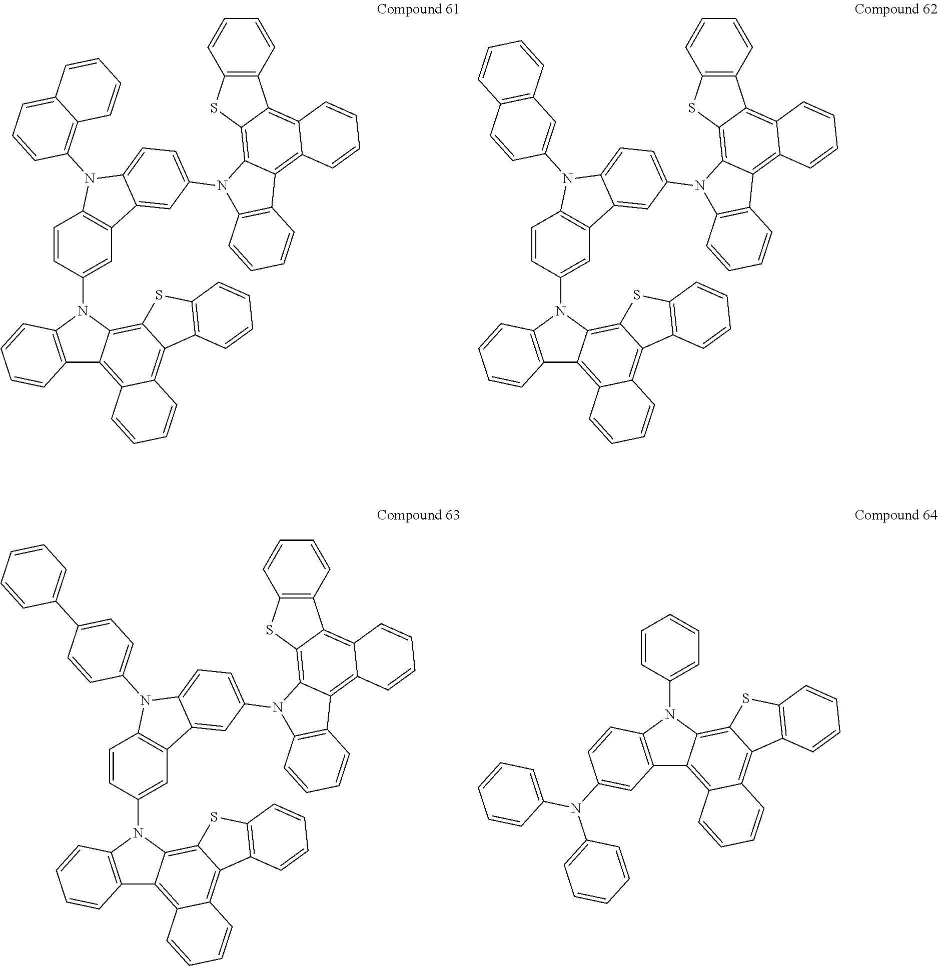 [SMILES: c1ccc2c(-n3c4ccc(-n5c6ccccc6c6c7ccccc7c7c8ccccc8sc7c65)cc4c4cc(-n5c6ccccc6c6c7ccccc7c7c8ccccc8sc7c65)ccc43)cccc2c1 ; c1ccc2cc(-n3c4ccc(-n5c6ccccc6c6c7ccccc7c7c8ccccc8sc7c65)cc4c4cc(-n5c6ccccc6c6c7ccccc7c7c8ccccc8sc7c65)ccc43)ccc2c1 ; c1ccc(-c2ccc(-n3c4ccc(-n5c6ccccc6c6c7ccccc7c7c8ccccc8sc7c65)cc4c4cc(-n5c6ccccc6c6c7ccccc7c7c8ccccc8sc7c65)ccc43)cc2)cc1 ; c1ccc(N(c2ccccc2)c2ccc3c(c2)c2c4ccccc4c4c5ccccc5sc4c2n3-c2ccccc2)cc1]

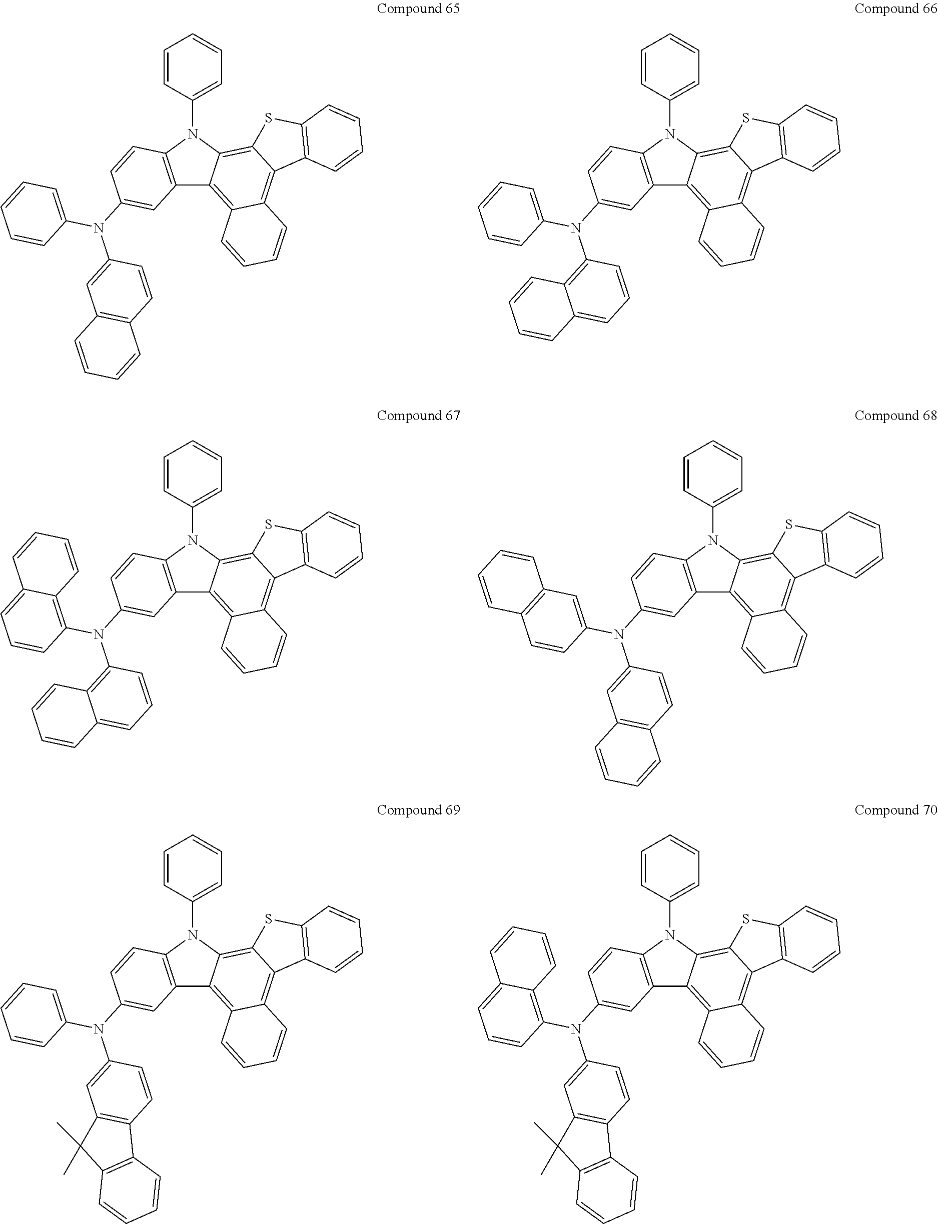 [SMILES: c1ccc(N(c2ccc3ccccc3c2)c2ccc3c(c2)c2c4ccccc4c4c5ccccc5sc4c2n3-c2ccccc2)cc1 ; c1ccc(N(c2ccc3c(c2)c2c4ccccc4c4c5ccccc5sc4c2n3-c2ccccc2)c2cccc3ccccc23)cc1 ; c1ccc(-n2c3ccc(N(c4cccc5ccccc45)c4cccc5ccccc45)cc3c3c4ccccc4c4c5ccccc5sc4c32)cc1 ; c1ccc(-n2c3ccc(N(c4ccc5ccccc5c4)c4ccc5ccccc5c4)cc3c3c4ccccc4c4c5ccccc5sc4c32)cc1 ; CC1(C)c2ccccc2-c2ccc(N(c3ccccc3)c3ccc4c(c3)c3c5ccccc5c5c6ccccc6sc5c3n4-c3ccccc3)cc21 ; CC1(C)c2ccccc2-c2ccc(N(c3ccc4c(c3)c3c5ccccc5c5c6ccccc6sc5c3n4-c3ccccc3)c3cccc4ccccc34)cc21]

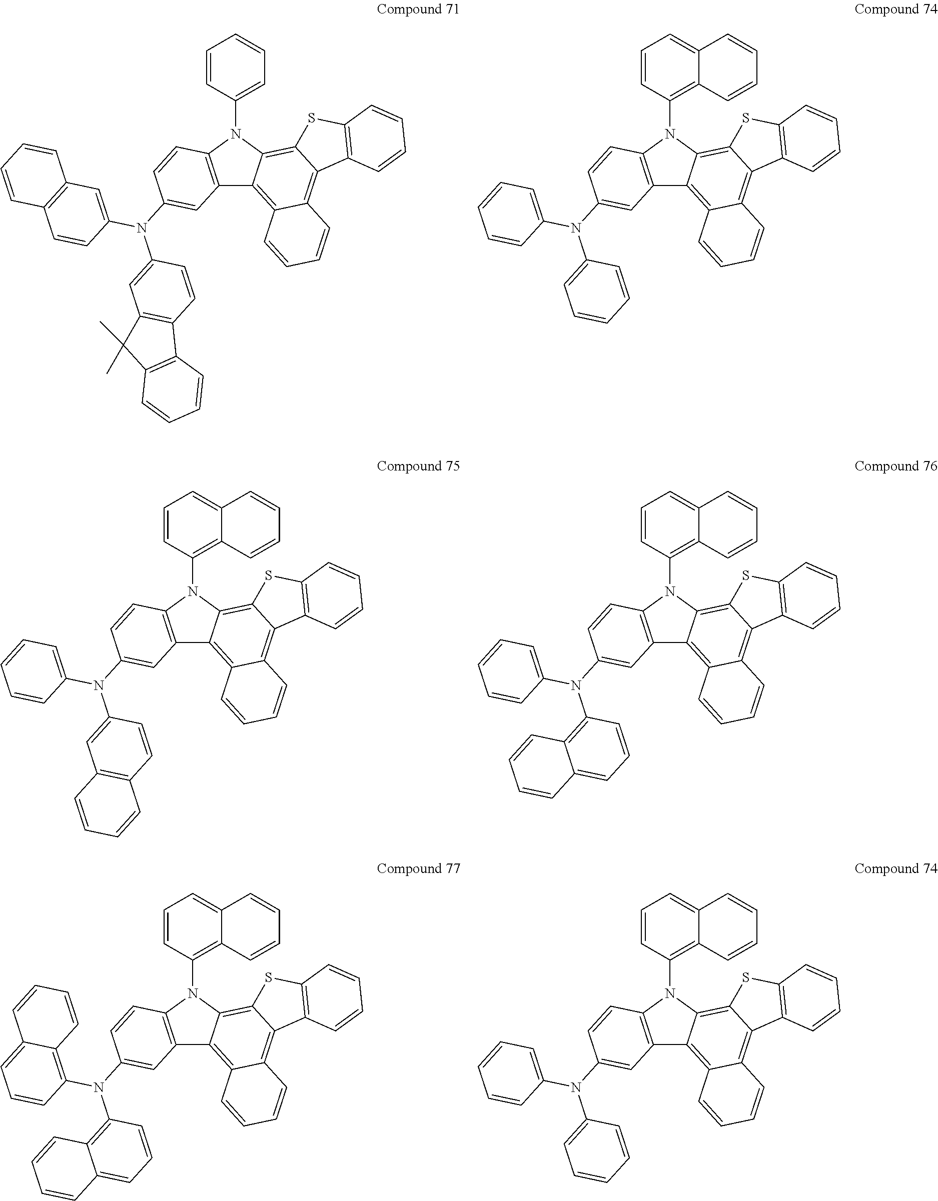 [SMILES: CC1(C)c2ccccc2-c2ccc(N(c3ccc4ccccc4c3)c3ccc4c(c3)c3c5ccccc5c5c6ccccc6sc5c3n4-c3ccccc3)cc21 ; c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1 ; c1ccc(N(c2ccc3c(c2)c2c4ccccc4c4c5ccccc5sc4c2n3-c2cccc3ccccc23)c2cccc3ccccc23)cc1 ; c1ccc2c(N(c3ccc4c(c3)c3c5ccccc5c5c6ccccc6sc5c3n4-c3cccc4ccccc34)c3cccc4ccccc34)cccc2c1 ; c1ccc(N(c2ccccc2)c2ccc3c(c2)c2c4ccccc4c4c5ccccc5sc4c2n3-c2cccc3ccccc23)cc1]

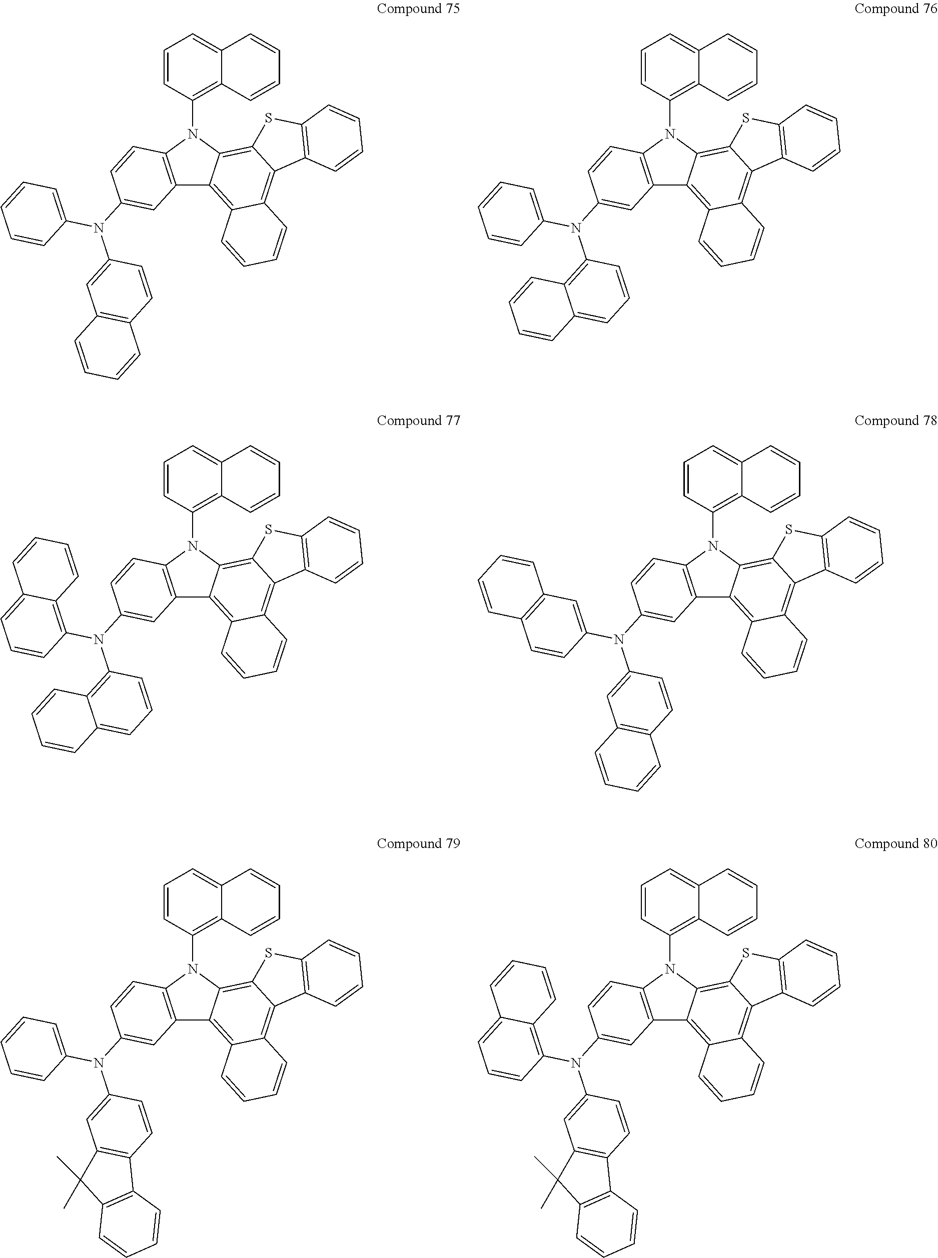

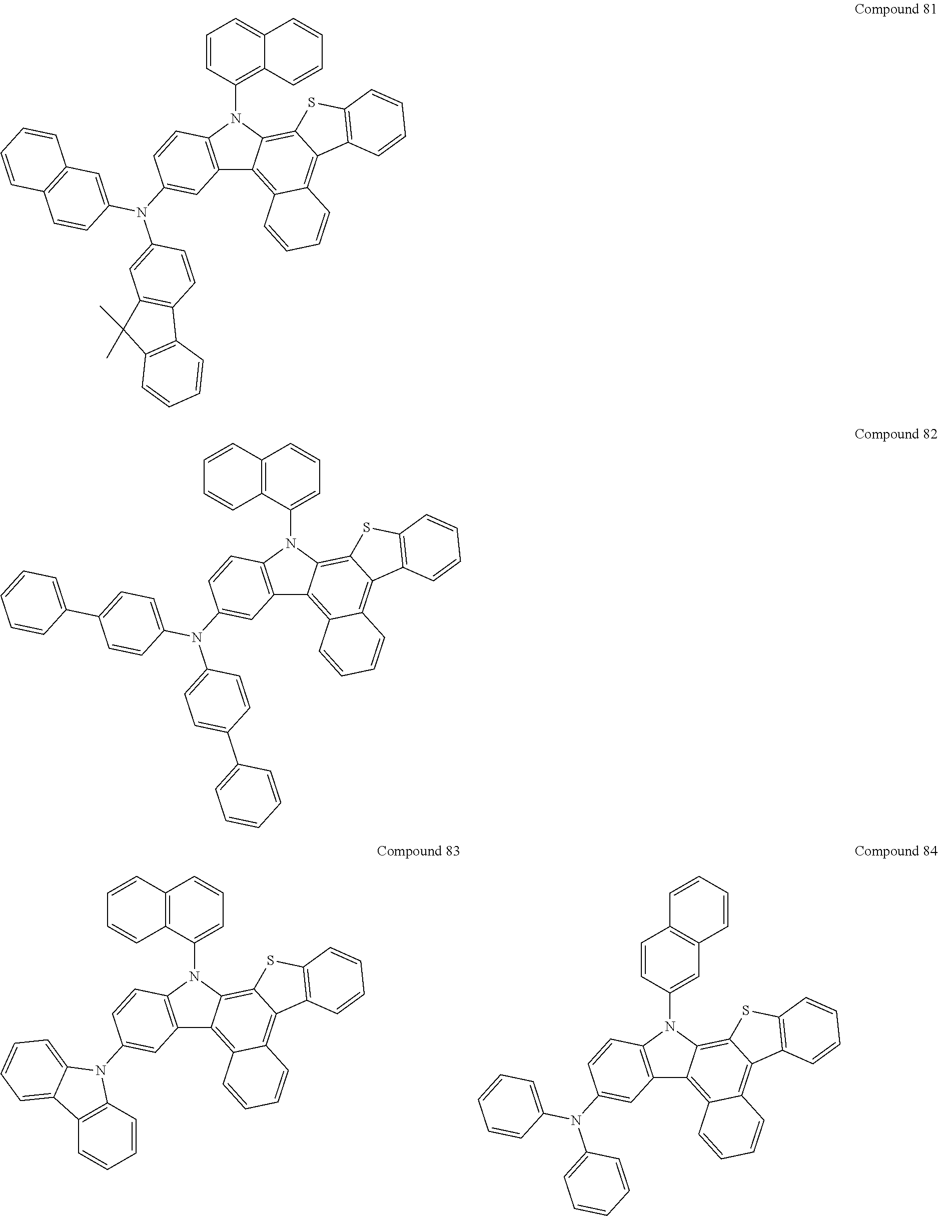 [SMILES: CC1(C)c2ccccc2-c2ccc(N(c3ccc4ccccc4c3)c3ccc4c(c3)c3c5ccccc5c5c6ccccc6sc5c3n4-c3cccc4ccccc34)cc21 ; c1ccc(-c2ccc(N(c3ccc(-c4ccccc4)cc3)c3ccc4c(c3)c3c5ccccc5c5c6ccccc6sc5c3n4-c3cccc4ccccc34)cc2)cc1 ; c1ccc2c(-n3c4ccc(-n5c6ccccc6c6ccccc65)cc4c4c5ccccc5c5c6ccccc6sc5c43)cccc2c1 ; c1ccc(N(c2ccccc2)c2ccc3c(c2)c2c4ccccc4c4c5ccccc5sc4c2n3-c2ccc3ccccc3c2)cc1]

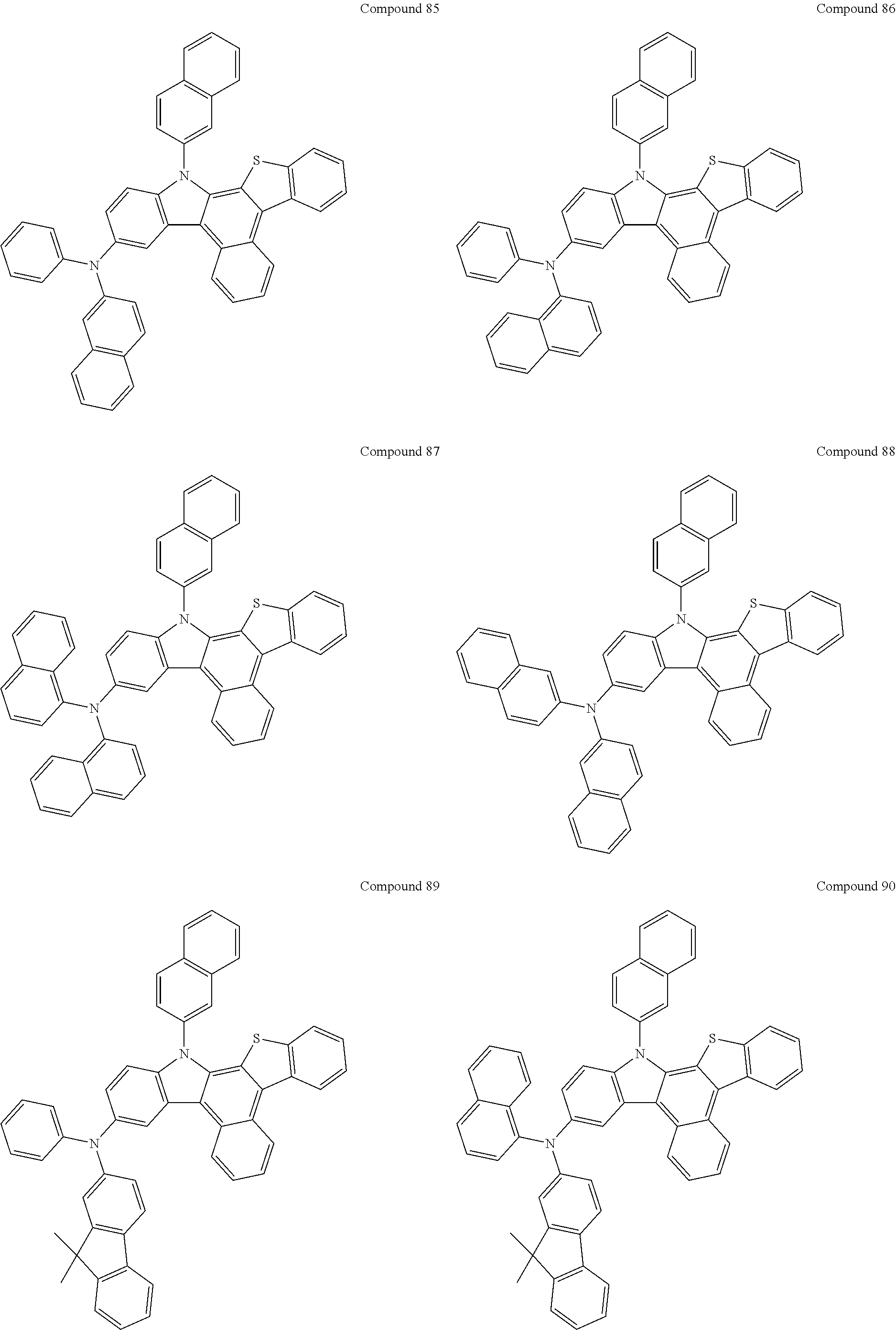

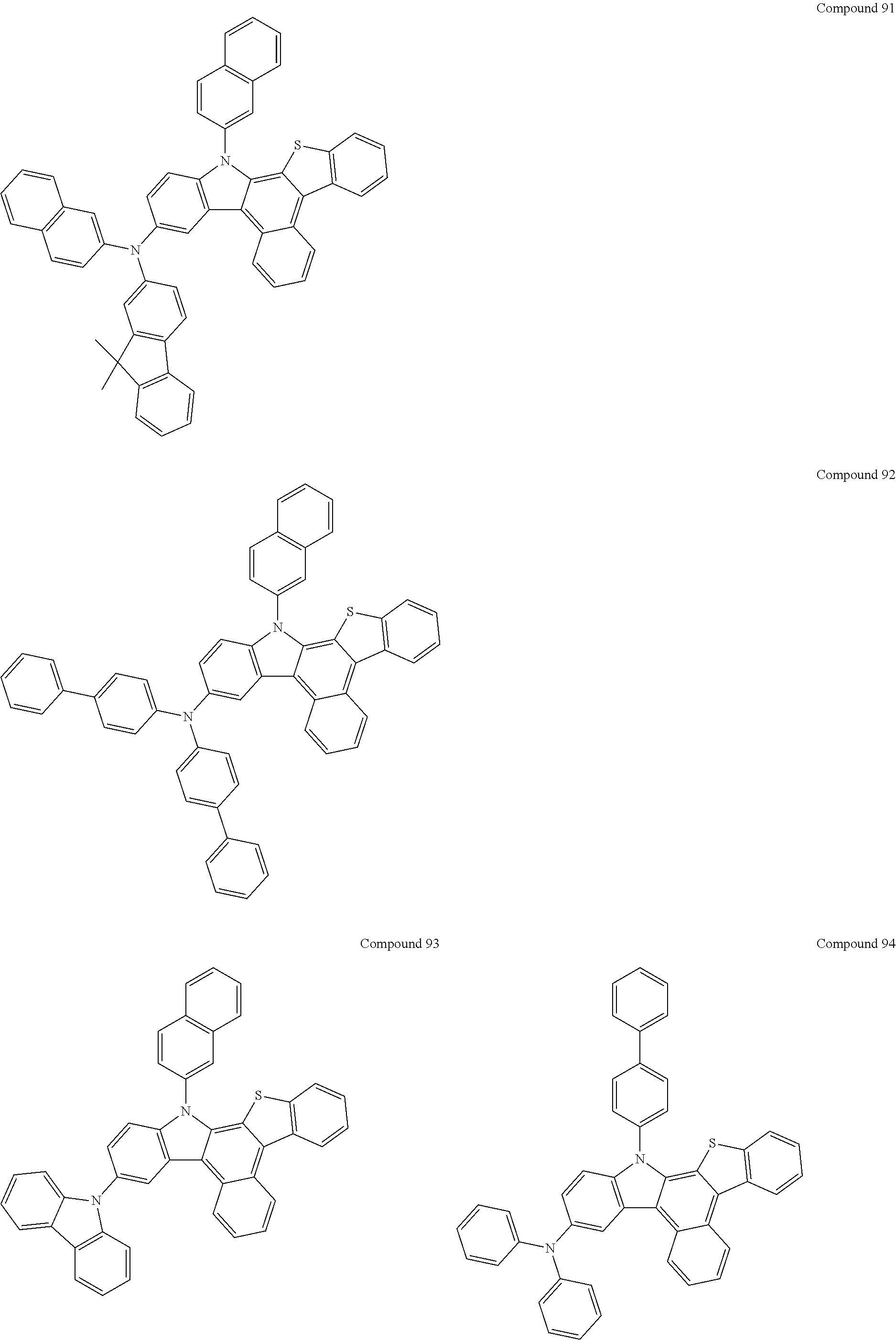 [SMILES: CC1(C)c2ccccc2-c2ccc(N(c3ccc4ccccc4c3)c3ccc4c(c3)c3c5ccccc5c5c6ccccc6sc5c3n4-c3ccc4ccccc4c3)cc21 ; c1ccc(-c2ccc(N(c3ccc(-c4ccccc4)cc3)c3ccc4c(c3)c3c5ccccc5c5c6ccccc6sc5c3n4-c3ccc4ccccc4c3)cc2)cc1 ; c1ccc2cc(-n3c4ccc(-n5c6ccccc6c6ccccc65)cc4c4c5ccccc5c5c6ccccc6sc5c43)ccc2c1 ; c1ccc(-c2ccc(-n3c4ccc(N(c5ccccc5)c5ccccc5)cc4c4c5ccccc5c5c6ccccc6sc5c43)cc2)cc1]

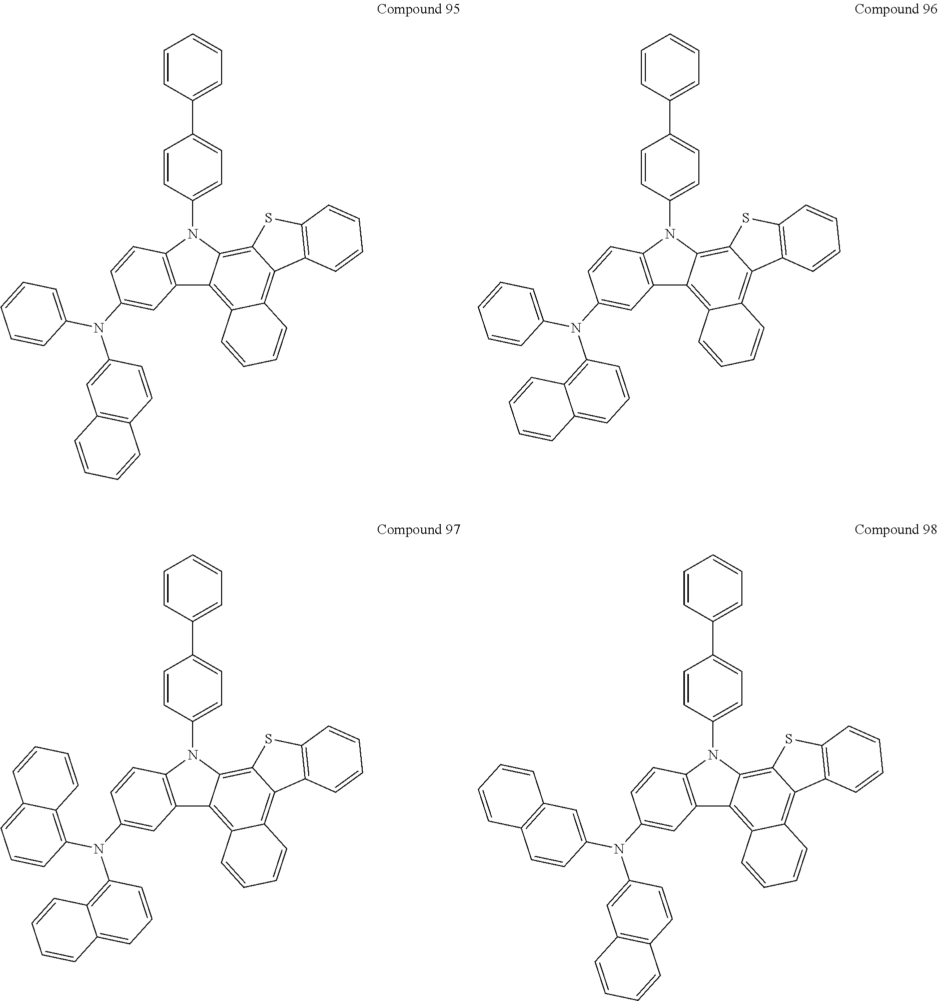 [SMILES: c1ccc(-c2ccc(-n3c4ccc(N(c5ccccc5)c5ccc6ccccc6c5)cc4c4c5ccccc5c5c6ccccc6sc5c43)cc2)cc1 ; c1ccc(-c2ccc(-n3c4ccc(N(c5ccccc5)c5cccc6ccccc56)cc4c4c5ccccc5c5c6ccccc6sc5c43)cc2)cc1 ; c1ccc(-c2ccc(-n3c4ccc(N(c5cccc6ccccc56)c5cccc6ccccc56)cc4c4c5ccccc5c5c6ccccc6sc5c43)cc2)cc1 ; c1ccc(-c2ccc(-n3c4ccc(N(c5ccc6ccccc6c5)c5ccc6ccccc6c5)cc4c4c5ccccc5c5c6ccccc6sc5c43)cc2)cc1]

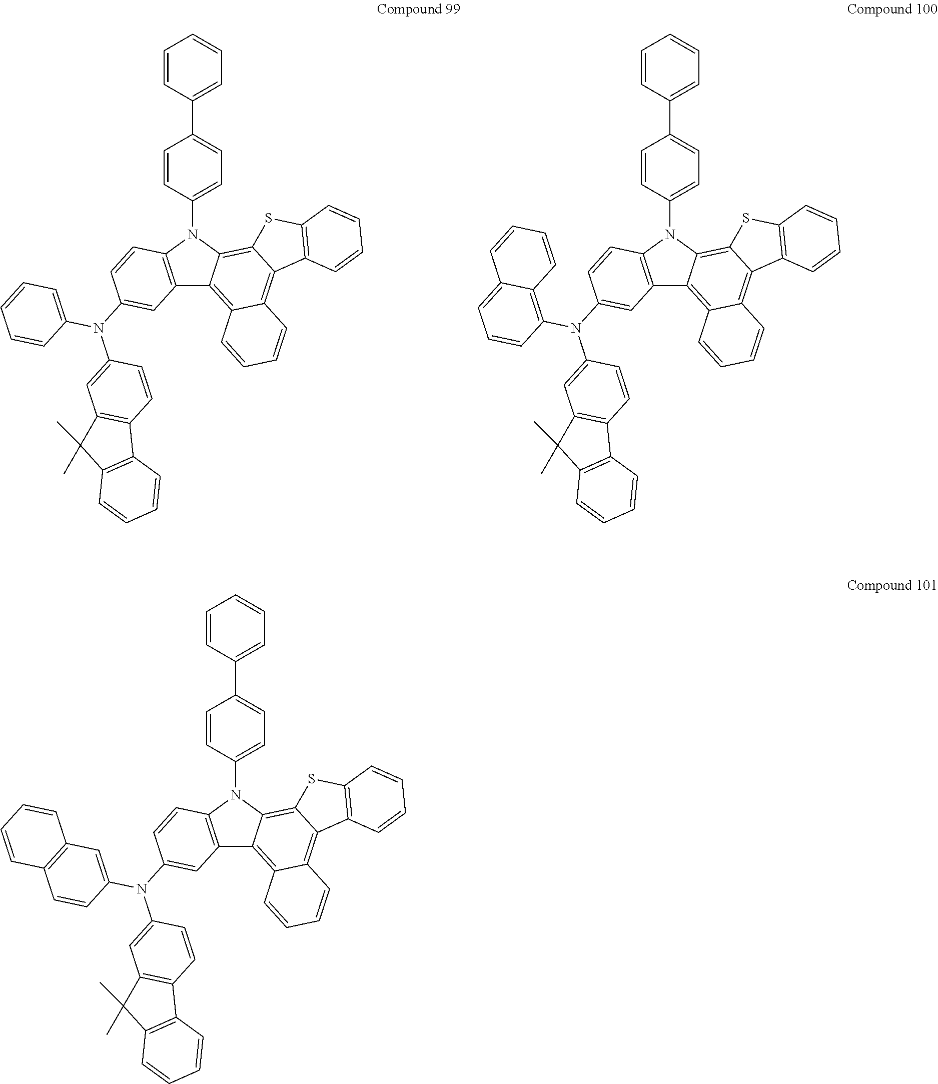 [SMILES: CC1(C)c2ccccc2-c2ccc(N(c3ccccc3)c3ccc4c(c3)c3c5ccccc5c5c6ccccc6sc5c3n4-c3ccc(-c4ccccc4)cc3)cc21 ; CC1(C)c2ccccc2-c2ccc(N(c3ccc4c(c3)c3c5ccccc5c5c6ccccc6sc5c3n4-c3ccc(-c4ccccc4)cc3)c3cccc4ccccc34)cc21 ; CC1(C)c2ccccc2-c2ccc(N(c3ccc4ccccc4c3)c3ccc4c(c3)c3c5ccccc5c5c6ccccc6sc5c3n4-c3ccc(-c4ccccc4)cc3)cc21]

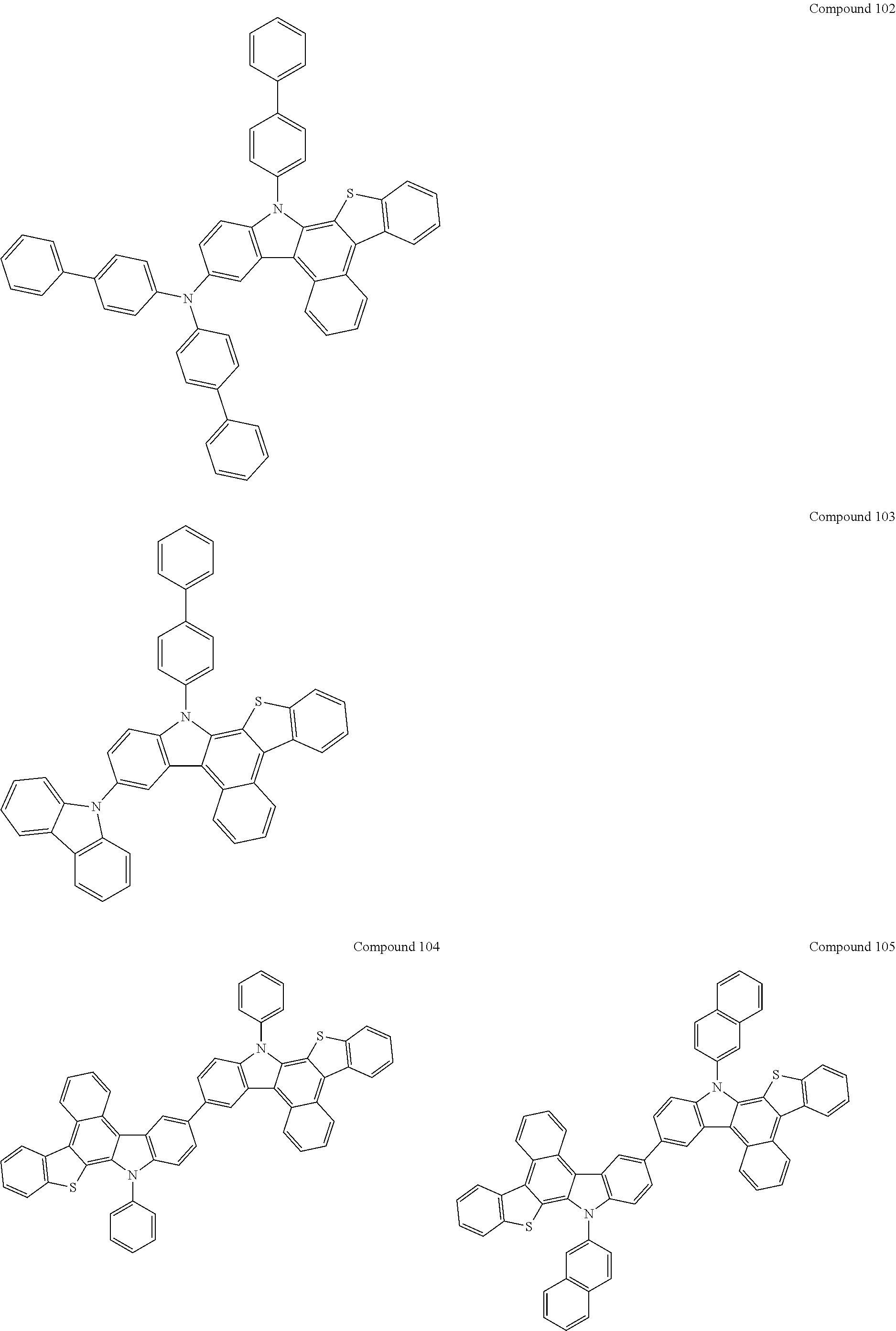 [SMILES: c1ccc(-c2ccc(N(c3ccc(-c4ccccc4)cc3)c3ccc4c(c3)c3c5ccccc5c5c6ccccc6sc5c3n4-c3ccc(-c4ccccc4)cc3)cc2)cc1 ; c1ccc(-c2ccc(-n3c4ccc(-n5c6ccccc6c6ccccc65)cc4c4c5ccccc5c5c6ccccc6sc5c43)cc2)cc1 ; c1ccc(-n2c3ccc(-c4ccc5c(c4)c4c6ccccc6c6c7ccccc7sc6c4n5-c4ccccc4)cc3c3c4ccccc4c4c5ccccc5sc4c32)cc1 ; c1ccc2cc(-n3c4ccc(-c5ccc6c(c5)c5c7ccccc7c7c8ccccc8sc7c5n6-c5ccc6ccccc6c5)cc4c4c5ccccc5c5c6ccccc6sc5c43)ccc2c1]

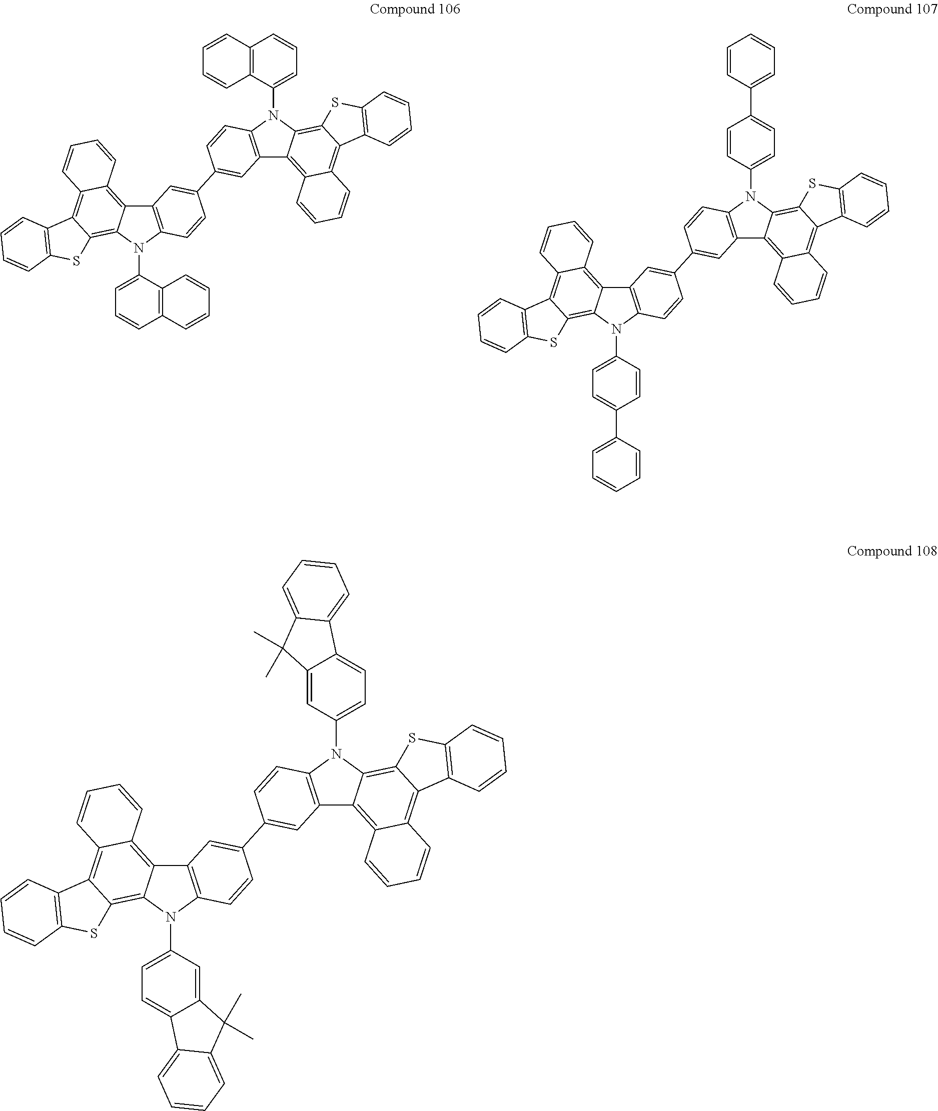 [SMILES: c1ccc2c(-n3c4ccc(-c5ccc6c(c5)c5c7ccccc7c7c8ccccc8sc7c5n6-c5cccc6ccccc56)cc4c4c5ccccc5c5c6ccccc6sc5c43)cccc2c1 ; c1ccc(-c2ccc(-n3c4ccc(-c5ccc6c(c5)c5c7ccccc7c7c8ccccc8sc7c5n6-c5ccc(-c6ccccc6)cc5)cc4c4c5ccccc5c5c6ccccc6sc5c43)cc2)cc1 ; CC1(C)c2ccccc2-c2ccc(-n3c4ccc(-c5ccc6c(c5)c5c7ccccc7c7c8ccccc8sc7c5n6-c5ccc6c(c5)C(C)(C)c5ccccc5-6)cc4c4c5ccccc5c5c6ccccc6sc5c43)cc21]

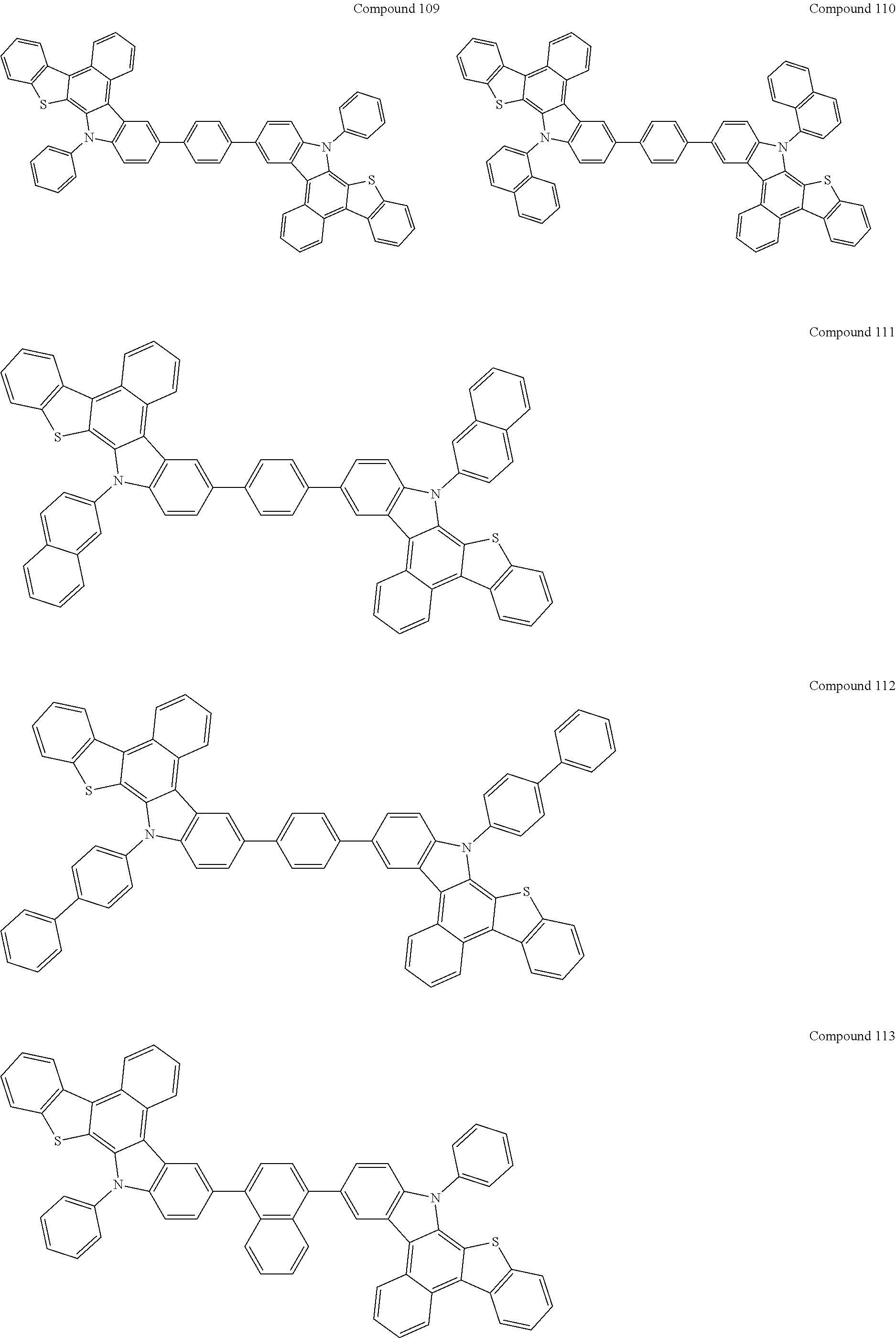

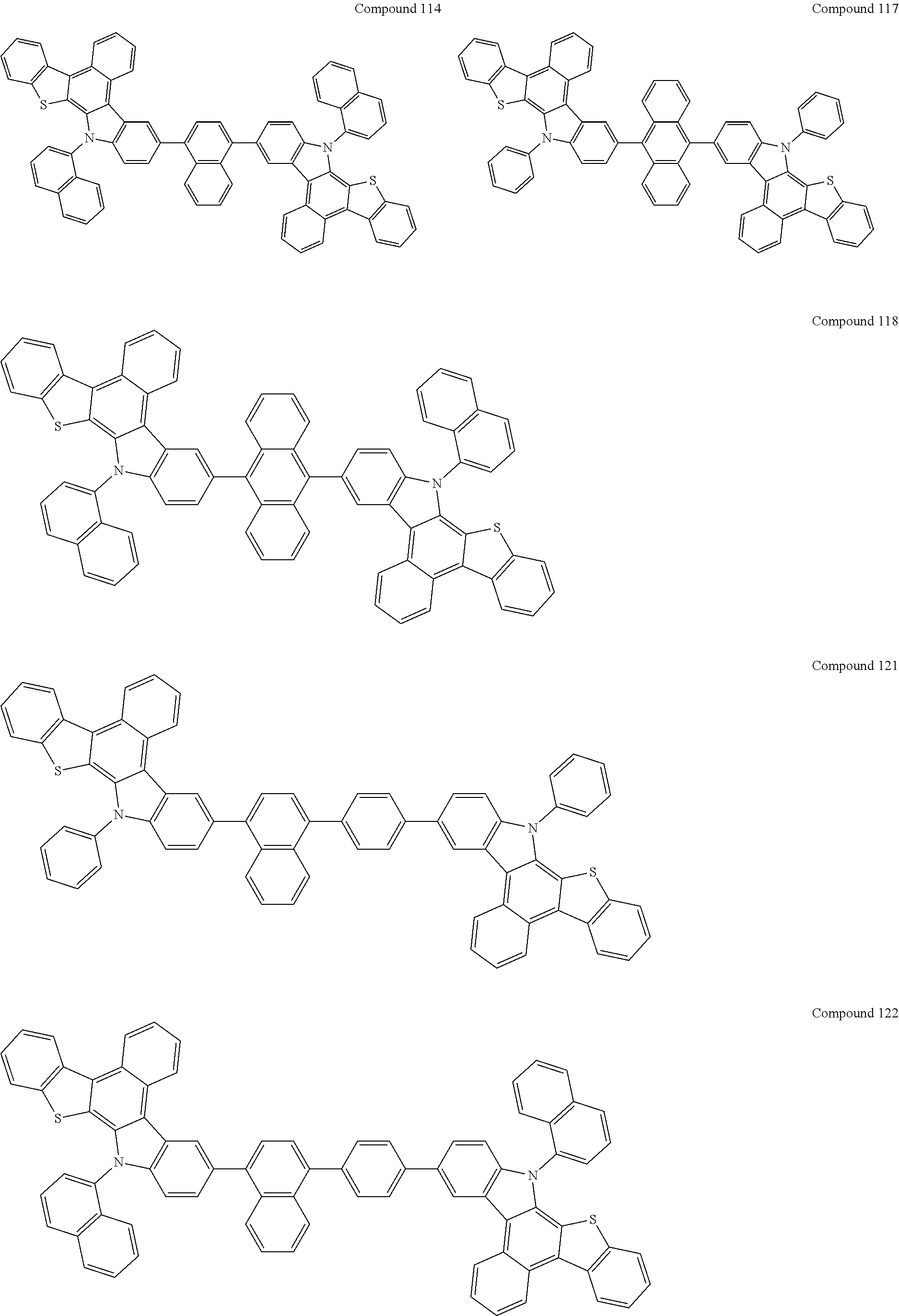

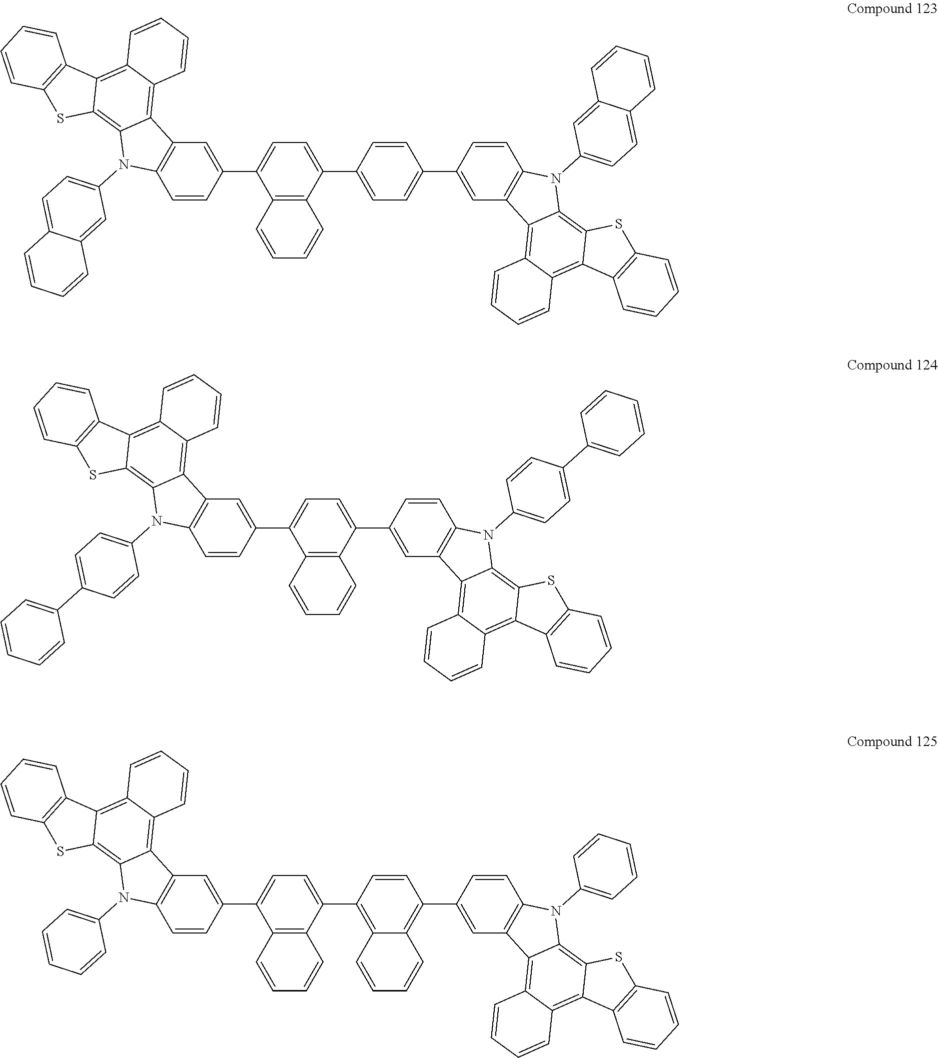 [SMILES: c1ccc2cc(-n3c4ccc(-c5ccc(-c6ccc(-c7ccc8c(c7)c7c9ccccc9c9c%10ccccc%10sc9c7n8-c7ccc8ccccc8c7)c7ccccc67)cc5)cc4c4c5ccccc5c5c6ccccc6sc5c43)ccc2c1 ; c1ccc(-c2ccc(-n3c4ccc(-c5ccc(-c6ccc7c(c6)c6c8ccccc8c8c9ccccc9sc8c6n7-c6ccc(-c7ccccc7)cc6)c6ccccc56)cc4c4c5ccccc5c5c6ccccc6sc5c43)cc2)cc1 ; c1ccc(-n2c3ccc(-c4ccc(-c5ccc(-c6ccc7c(c6)c6c8ccccc8c8c9ccccc9sc8c6n7-c6ccccc6)c6ccccc56)c5ccccc45)cc3c3c4ccccc4c4c5ccccc5sc4c32)cc1]

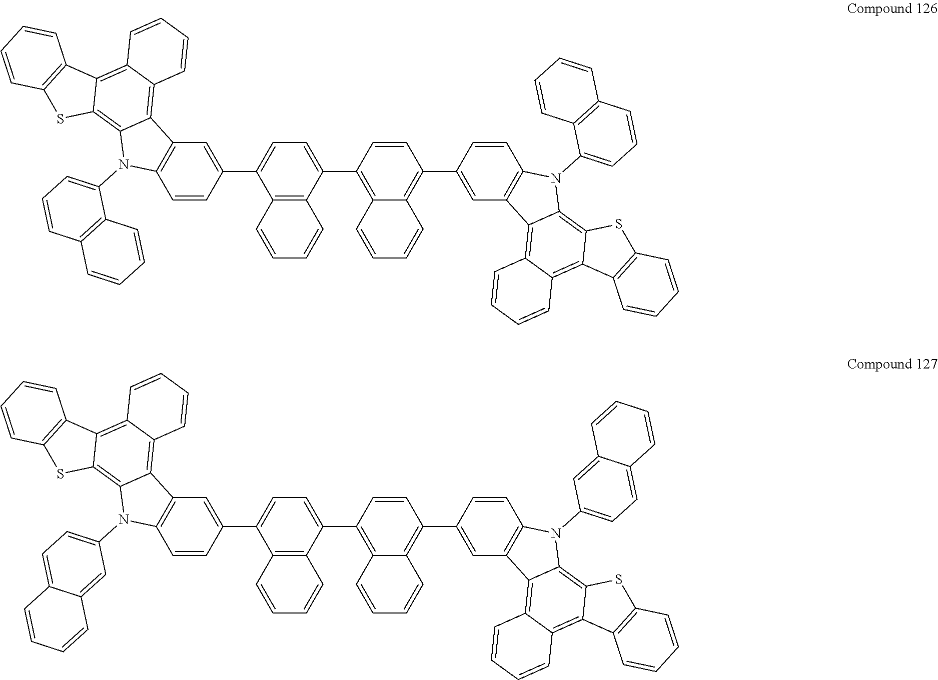 [SMILES: c1ccc2c(-n3c4ccc(-c5ccc(-c6ccc(-c7ccc8c(c7)c7c9ccccc9c9c%10ccccc%10sc9c7n8-c7cccc8ccccc78)c7ccccc67)c6ccccc56)cc4c4c5ccccc5c5c6ccccc6sc5c43)cccc2c1 ; c1ccc2cc(-n3c4ccc(-c5ccc(-c6ccc(-c7ccc8c(c7)c7c9ccccc9c9c%10ccccc%10sc9c7n8-c7ccc8ccccc8c7)c7ccccc67)c6ccccc56)cc4c4c5ccccc5c5c6ccccc6sc5c43)ccc2c1]

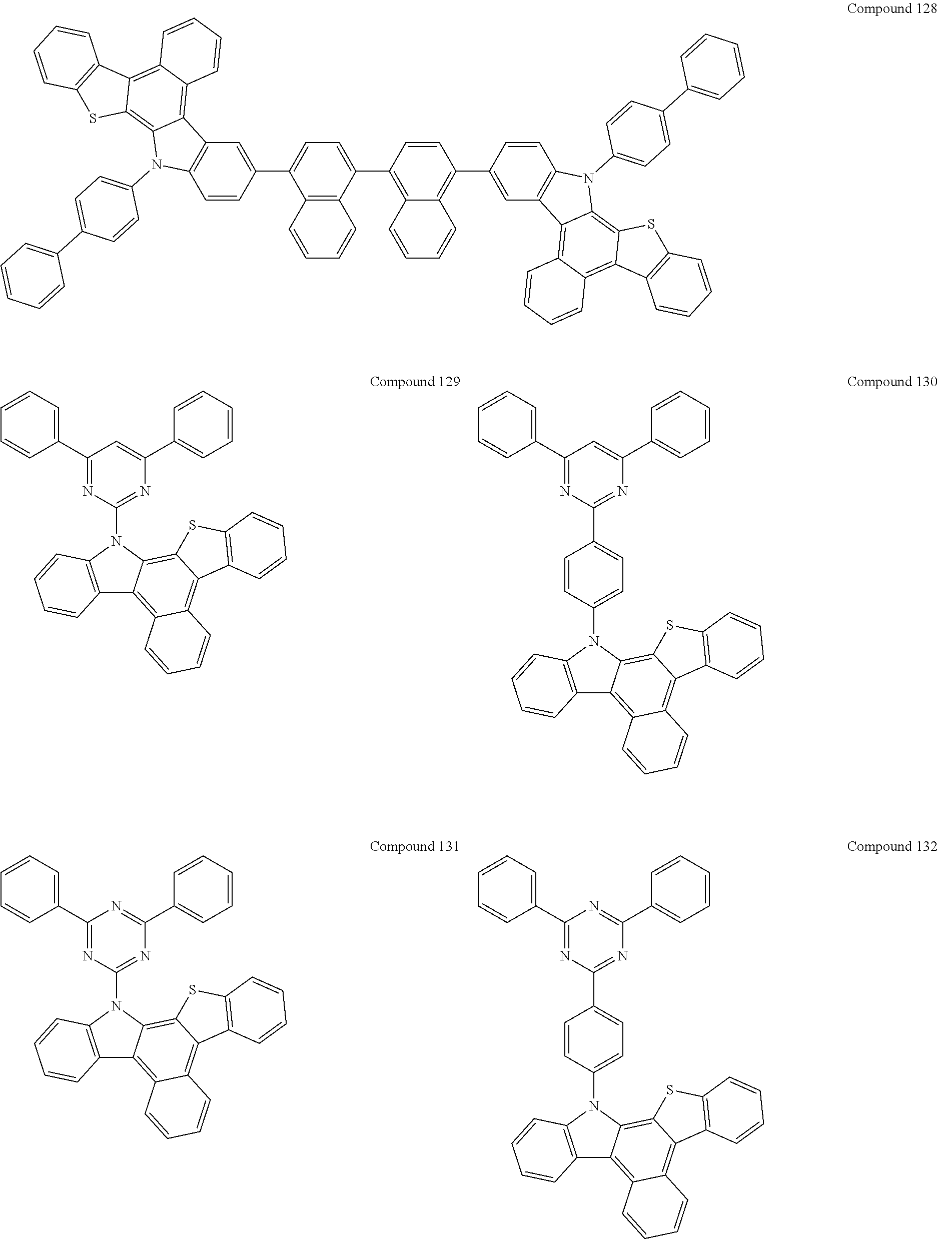 [SMILES: c1ccc(-c2ccc(-n3c4ccc(-c5ccc(-c6ccc(-c7ccc8c(c7)c7c9ccccc9c9c%10ccccc%10sc9c7n8-c7ccc(-c8ccccc8)cc7)c7ccccc67)c6ccccc56)cc4c4c5ccccc5c5c6ccccc6sc5c43)cc2)cc1 ; c1ccc(-c2cc(-c3ccccc3)nc(-n3c4ccccc4c4c5ccccc5c5c6ccccc6sc5c43)n2)cc1 ; c1ccc(-c2cc(-c3ccccc3)nc(-c3ccc(-n4c5ccccc5c5c6ccccc6c6c7ccccc7sc6c54)cc3)n2)cc1 ; c1ccc(-c2nc(-c3ccccc3)nc(-n3c4ccccc4c4c5ccccc5c5c6ccccc6sc5c43)n2)cc1 ; c1ccc(-c2nc(-c3ccccc3)nc(-c3ccc(-n4c5ccccc5c5c6ccccc6c6c7ccccc7sc6c54)cc3)n2)cc1]

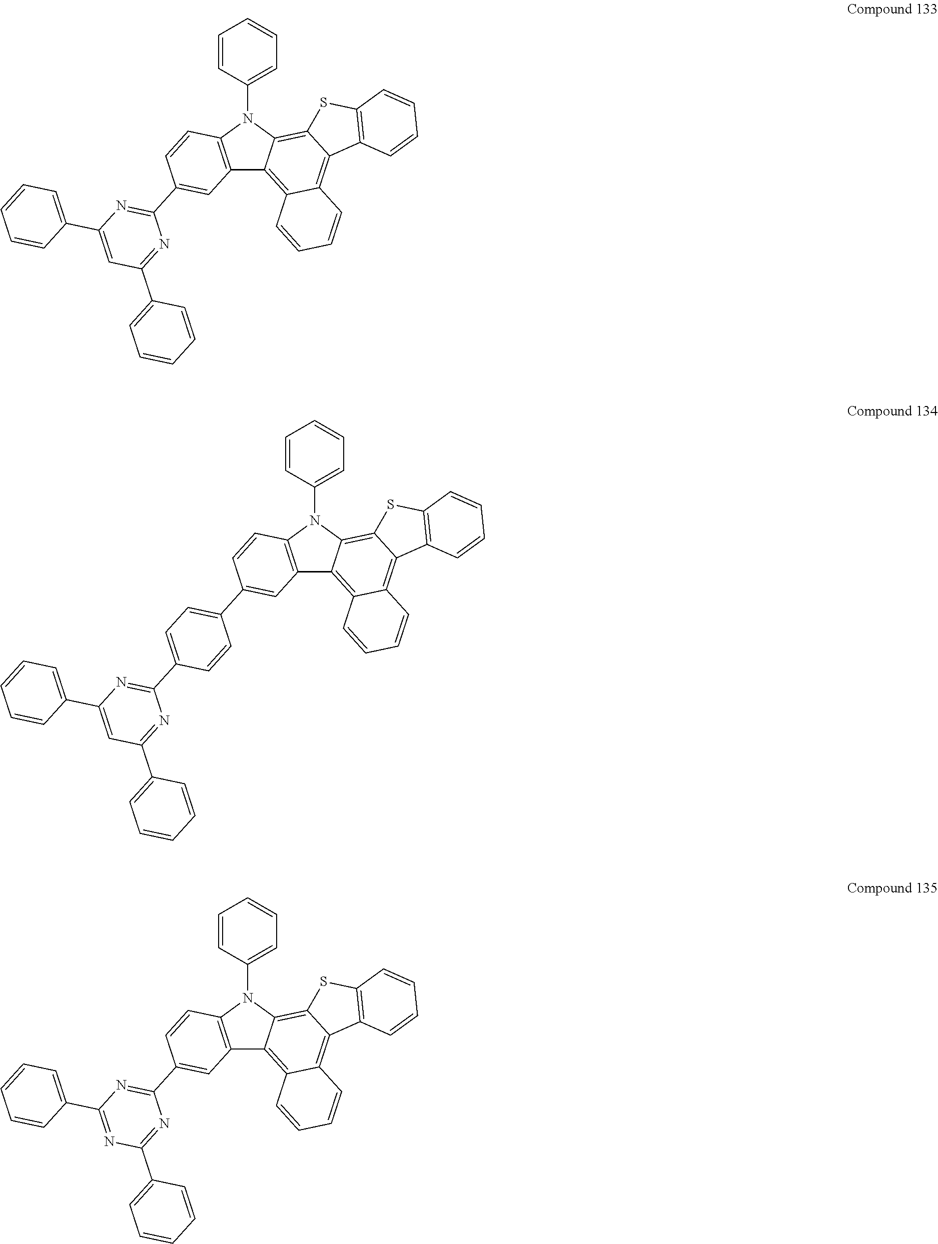 [SMILES: c1ccc(-c2cc(-c3ccccc3)nc(-c3ccc4c(c3)c3c5ccccc5c5c6ccccc6sc5c3n4-c3ccccc3)n2)cc1 ; c1ccc(-c2cc(-c3ccccc3)nc(-c3ccc(-c4ccc5c(c4)c4c6ccccc6c6c7ccccc7sc6c4n5-c4ccccc4)cc3)n2)cc1 ; c1ccc(-c2nc(-c3ccccc3)nc(-c3ccc4c(c3)c3c5ccccc5c5c6ccccc6sc5c3n4-c3ccccc3)n2)cc1]

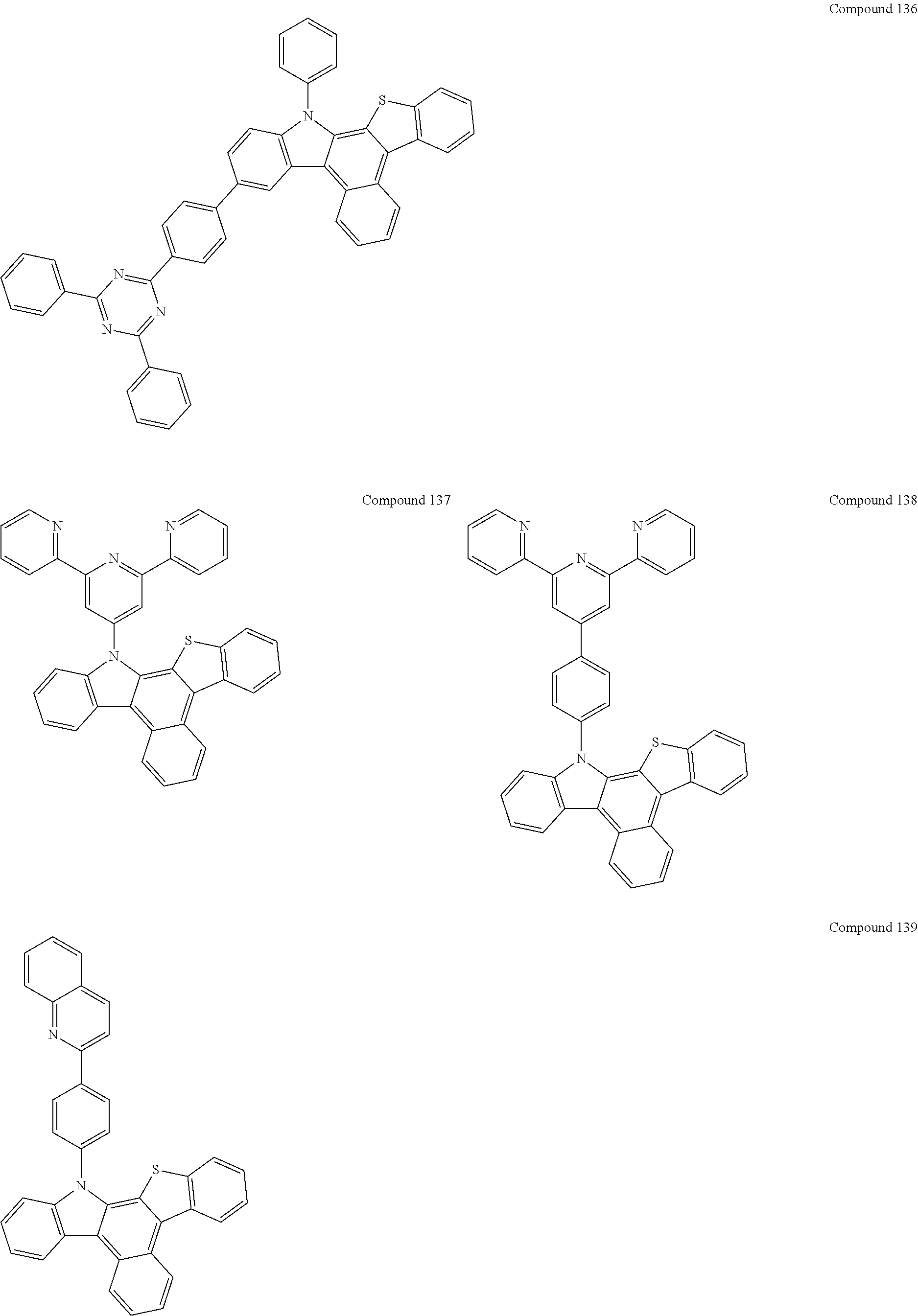 [SMILES: c1ccc(-c2nc(-c3ccccc3)nc(-c3ccc(-c4ccc5c(c4)c4c6ccccc6c6c7ccccc7sc6c4n5-c4ccccc4)cc3)n2)cc1 ; c1ccc(-c2cc(-n3c4ccccc4c4c5ccccc5c5c6ccccc6sc5c43)cc(-c3ccccn3)n2)nc1 ; c1ccc(-c2cc(-c3ccc(-n4c5ccccc5c5c6ccccc6c6c7ccccc7sc6c54)cc3)cc(-c3ccccn3)n2)nc1 ; c1ccc2nc(-c3ccc(-n4c5ccccc5c5c6ccccc6c6c7ccccc7sc6c54)cc3)ccc2c1]

In an embodiment, the emission layer may emit red light.

In an embodiment, the hole transport region may include a hole injection layer, and a hole transport layer provided on the hole injection layer.

In an embodiment, the electron transport region may include an electron transport layer, and an electron injection layer provided on the electron transport layer.

In an embodiment, a display device includes a plurality of pixels. One of the pixels include an anode a hole transport region, an emission layer, a first host layer, an electron transport region, and a cathode. The hole transport region is provided on the anode. The emission layer is provided on the hole transport region and includes a first host and a dopant. The first host layer is provided on the emission layer and includes a second host. The electron transport region is provided on the host layer. The cathode is provided on the electron transport region. The second host is represented by the following Formula 1.

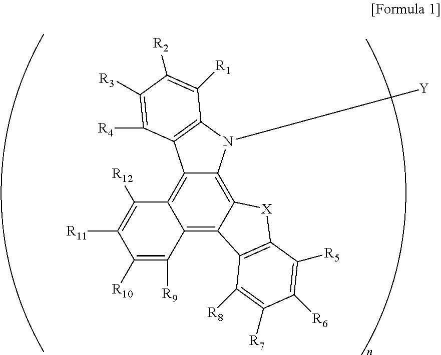

In Formula 1, R₁, R₂, R₃, R₄, R₅, R₆, R₇, R₈, R₉, R₁₀, R₁₁, and R₁₂ are each independently a hydrogen atom, a halogen atom, a cyano group, an alkoxy group, a thiol group, a substituted or unsubstituted alkyl group having 1 to 50 carbon atoms, a substituted or unsubstituted alkoxy group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphor, or silicon, a substituted or unsubstituted heteroaryl group having 5 to 60 carbon atoms and including at least one of sulfur, nitrogen, oxygen, phosphor, or silicon, or a substituted or unsubstituted heteroaryloxy group having 5 to 60 carbon atoms and including at least one of sulfur, nitrogen, oxygen, phosphor, or silicon, X is sulfur, oxygen, or silicon, Y is a hydrogen atom, a halogen atom, a cyano group, an alkoxy group, a thiol group, a substituted or unsubstituted alkyl group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphor, or silicon, a substituted or unsubstituted heteroaryl group having 5 to 60 carbon atoms and including at least one of sulfur, nitrogen, oxygen, phosphor, or silicon, or a substituted or unsubstituted heteroaryloxy group having 5 to 60 carbon atoms and including at least one of sulfur, nitrogen, oxygen, phosphor, or silicon, and n is an integer from 1 to 3.

In an embodiment, the first host layer may not include the dopant.

In an embodiment, the second host may include at least one compound of the compounds in the following Compound Group 1.

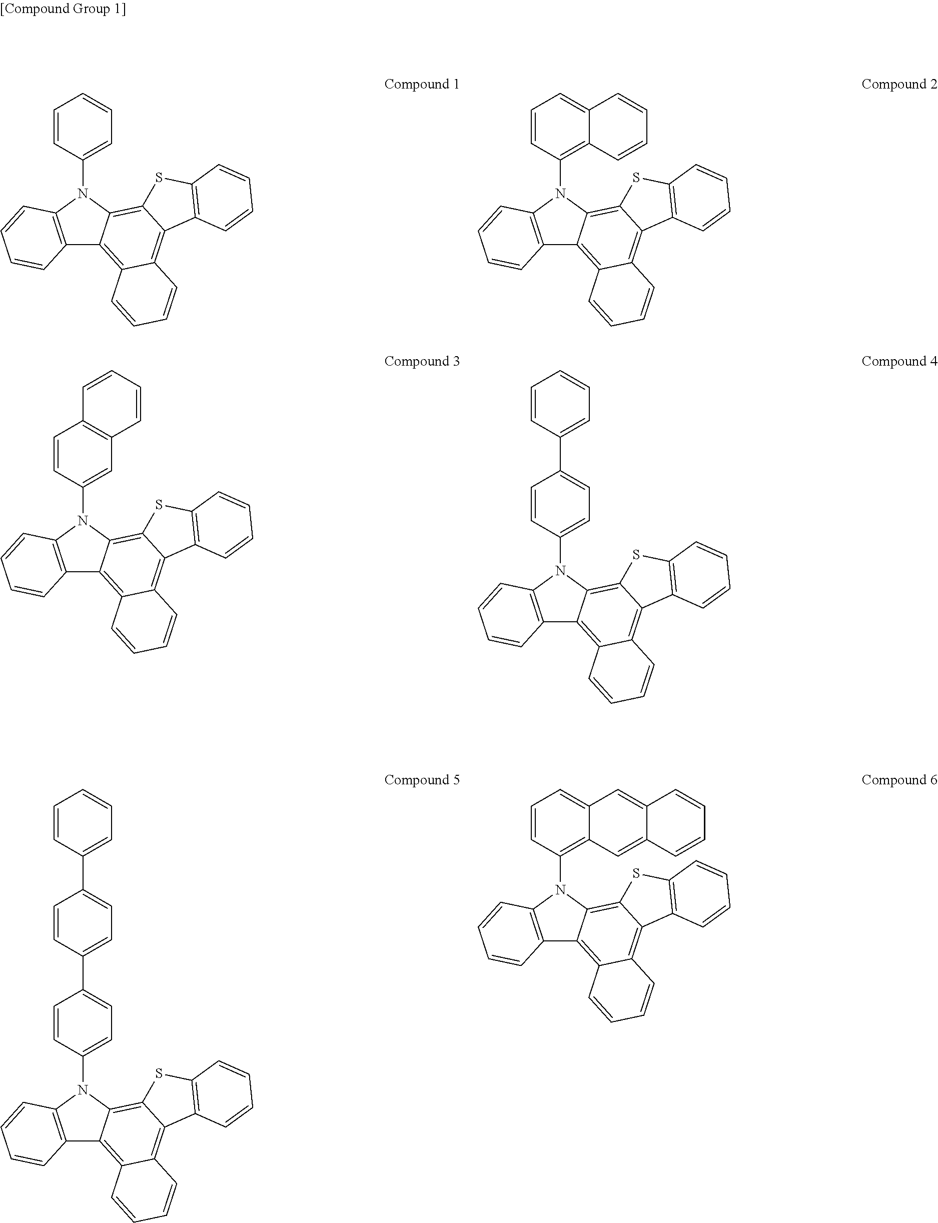 [SMILES: c1ccc(-n2c3ccccc3c3c4ccccc4c4c5ccccc5sc4c32)cc1 ; c1ccc2c(-n3c4ccccc4c4c5ccccc5c5c6ccccc6sc5c43)cccc2c1 ; c1ccc2cc(-n3c4ccccc4c4c5ccccc5c5c6ccccc6sc5c43)ccc2c1 ; c1ccc(-c2ccc(-n3c4ccccc4c4c5ccccc5c5c6ccccc6sc5c43)cc2)cc1 ; c1ccc(-c2ccc(-c3ccc(-n4c5ccccc5c5c6ccccc6c6c7ccccc7sc6c54)cc3)cc2)cc1 ; c1ccc2cc3c(-n4c5ccccc5c5c6ccccc6c6c7ccccc7sc6c54)cccc3cc2c1]

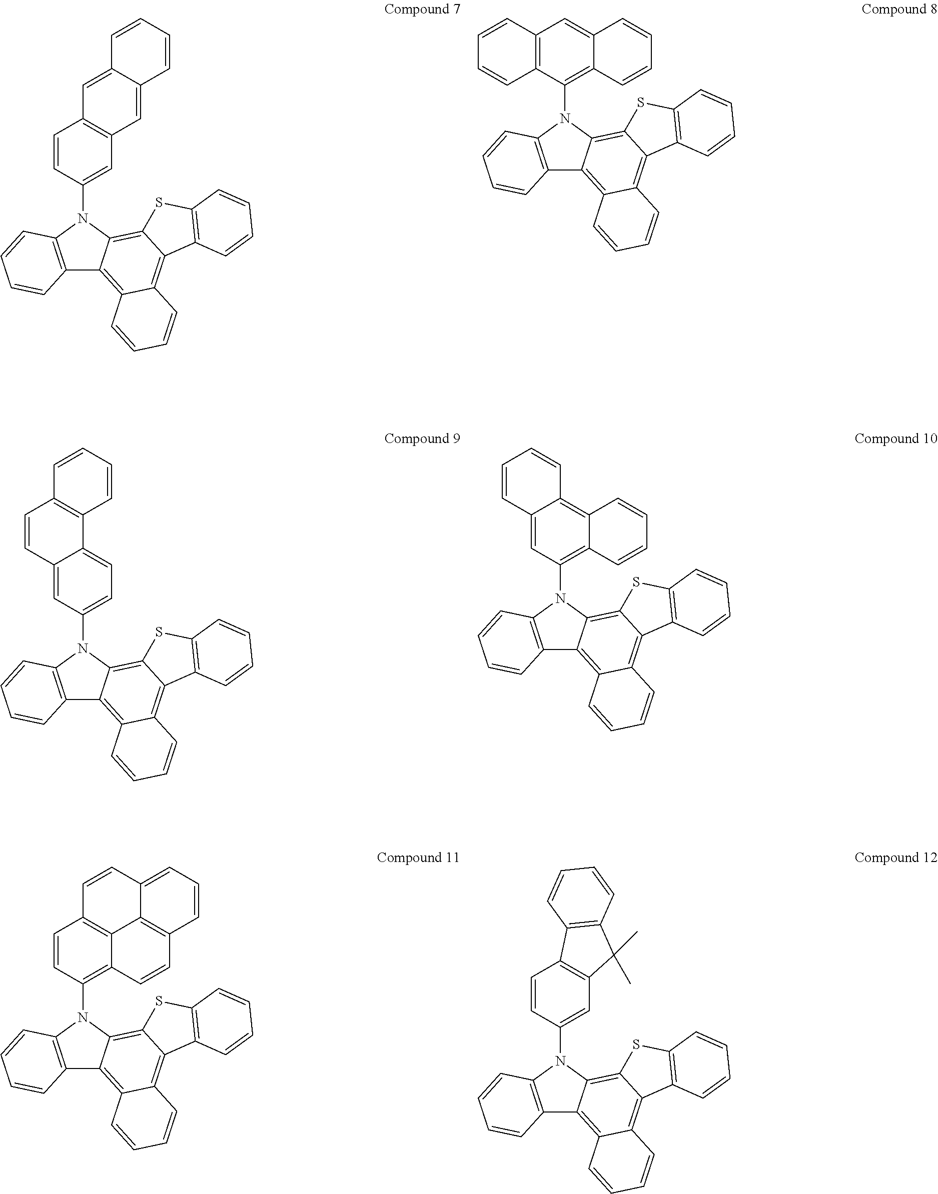 [SMILES: c1ccc2cc3cc(-n4c5ccccc5c5c6ccccc6c6c7ccccc7sc6c54)ccc3cc2c1 ; c1ccc2c(-n3c4ccccc4c4c5ccccc5c5c6ccccc6sc5c43)c3ccccc3cc2c1 ; c1ccc2c(c1)ccc1cc(-n3c4ccccc4c4c5ccccc5c5c6ccccc6sc5c43)ccc12 ; c1ccc2c(c1)cc(-n1c3ccccc3c3c4ccccc4c4c5ccccc5sc4c31)c1ccccc12 ; c1cc2ccc3ccc(-n4c5ccccc5c5c6ccccc6c6c7ccccc7sc6c54)c4ccc(c1)c2c34 ; CC1(C)c2ccccc2-c2ccc(-n3c4ccccc4c4c5ccccc5c5c6ccccc6sc5c43)cc21]

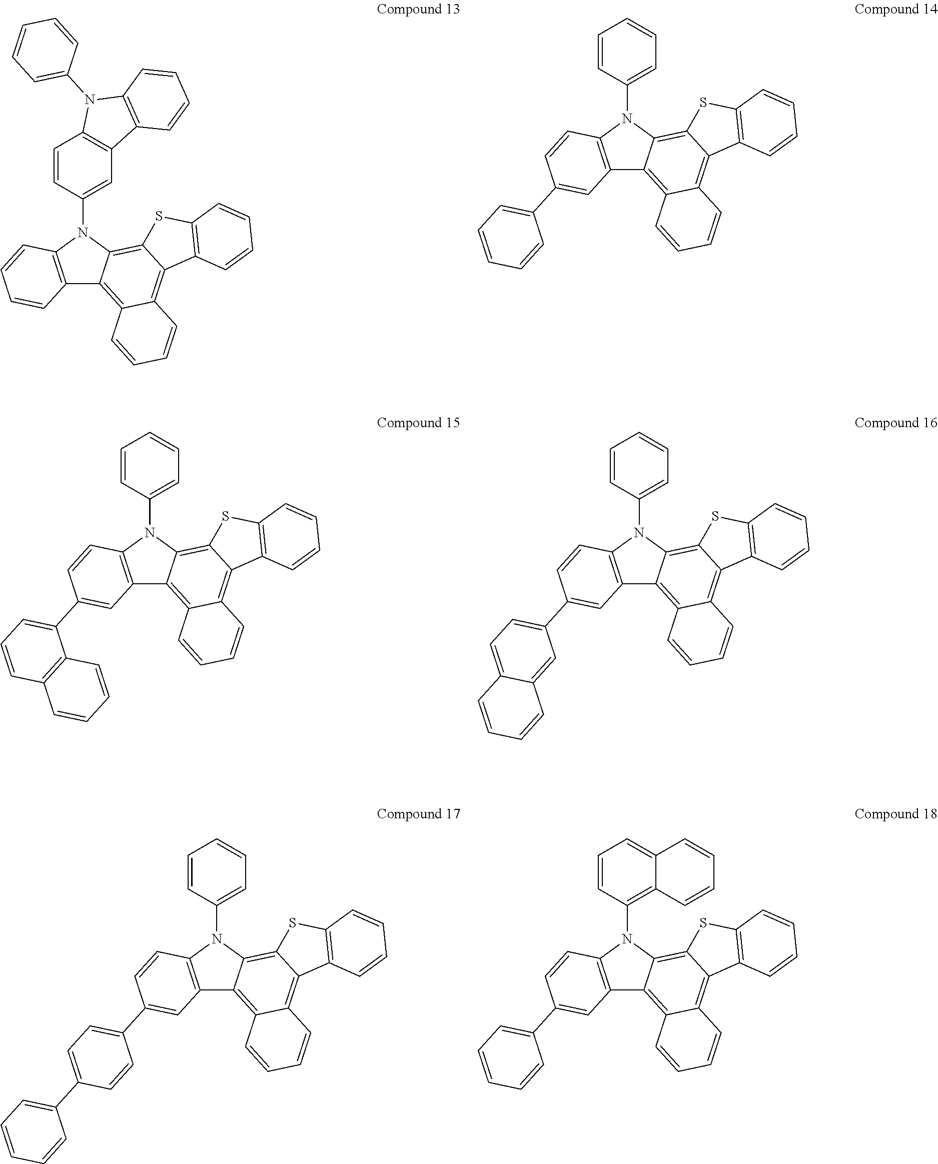 [SMILES: c1ccc(-n2c3ccccc3c3cc(-n4c5ccccc5c5c6ccccc6c6c7ccccc7sc6c54)ccc32)cc1 ; c1ccc(-c2ccc3c(c2)c2c4ccccc4c4c5ccccc5sc4c2n3-c2ccccc2)cc1 ; c1ccc(-n2c3ccc(-c4cccc5ccccc45)cc3c3c4ccccc4c4c5ccccc5sc4c32)cc1 ; c1ccc(-n2c3ccc(-c4ccc5ccccc5c4)cc3c3c4ccccc4c4c5ccccc5sc4c32)cc1 ; c1ccc(-c2ccc(-c3ccc4c(c3)c3c5ccccc5c5c6ccccc6sc5c3n4-c3ccccc3)cc2)cc1 ; c1ccc(-c2ccc3c(c2)c2c4ccccc4c4c5ccccc5sc4c2n3-c2cccc3ccccc23)cc1]

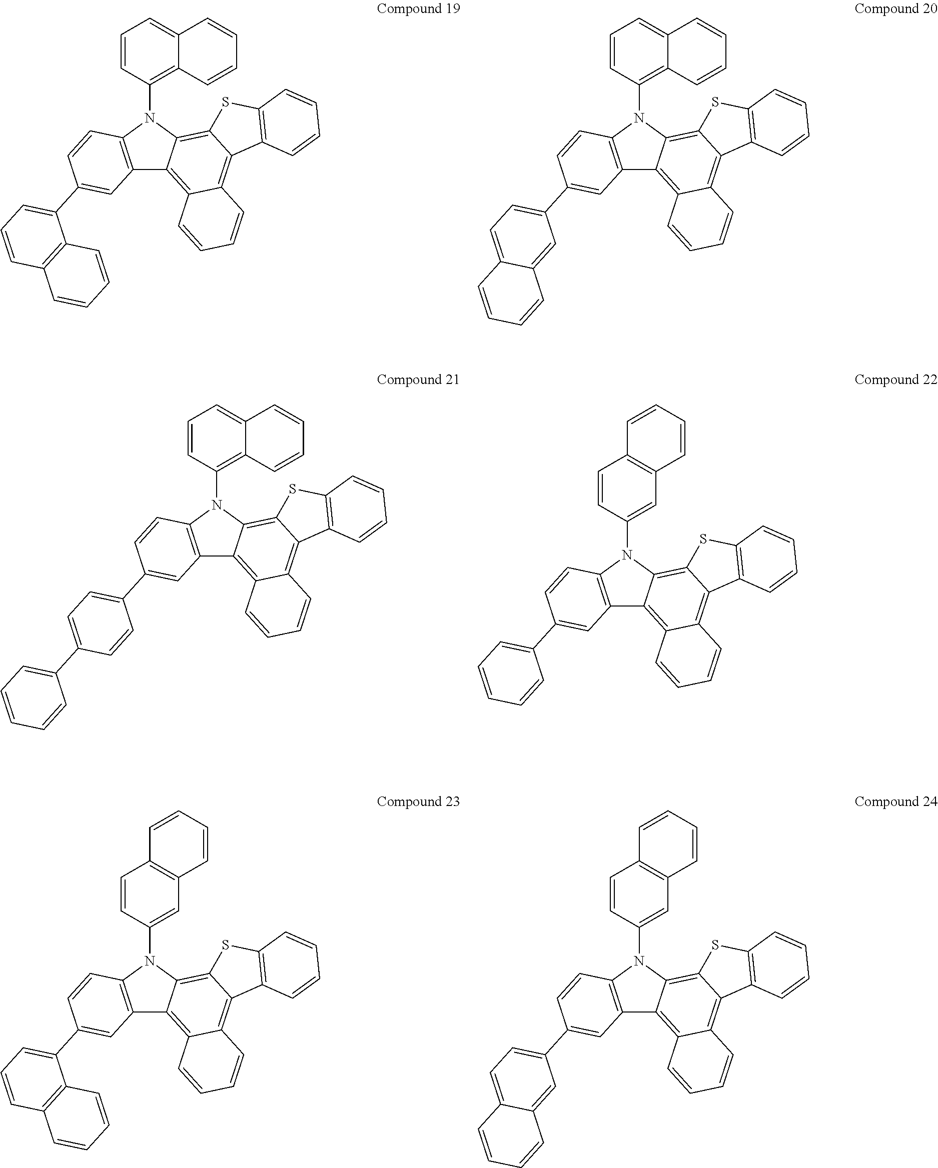 [SMILES: c1ccc2c(-c3ccc4c(c3)c3c5ccccc5c5c6ccccc6sc5c3n4-c3cccc4ccccc34)cccc2c1 ; c1ccc2cc(-c3ccc4c(c3)c3c5ccccc5c5c6ccccc6sc5c3n4-c3cccc4ccccc34)ccc2c1 ; c1ccc(-c2ccc(-c3ccc4c(c3)c3c5ccccc5c5c6ccccc6sc5c3n4-c3cccc4ccccc34)cc2)cc1 ; c1ccc(-c2ccc3c(c2)c2c4ccccc4c4c5ccccc5sc4c2n3-c2ccc3ccccc3c2)cc1 ; c1ccc2cc(-n3c4ccc(-c5cccc6ccccc56)cc4c4c5ccccc5c5c6ccccc6sc5c43)ccc2c1 ; c1ccc2cc(-c3ccc4c(c3)c3c5ccccc5c5c6ccccc6sc5c3n4-c3ccc4ccccc4c3)ccc2c1]

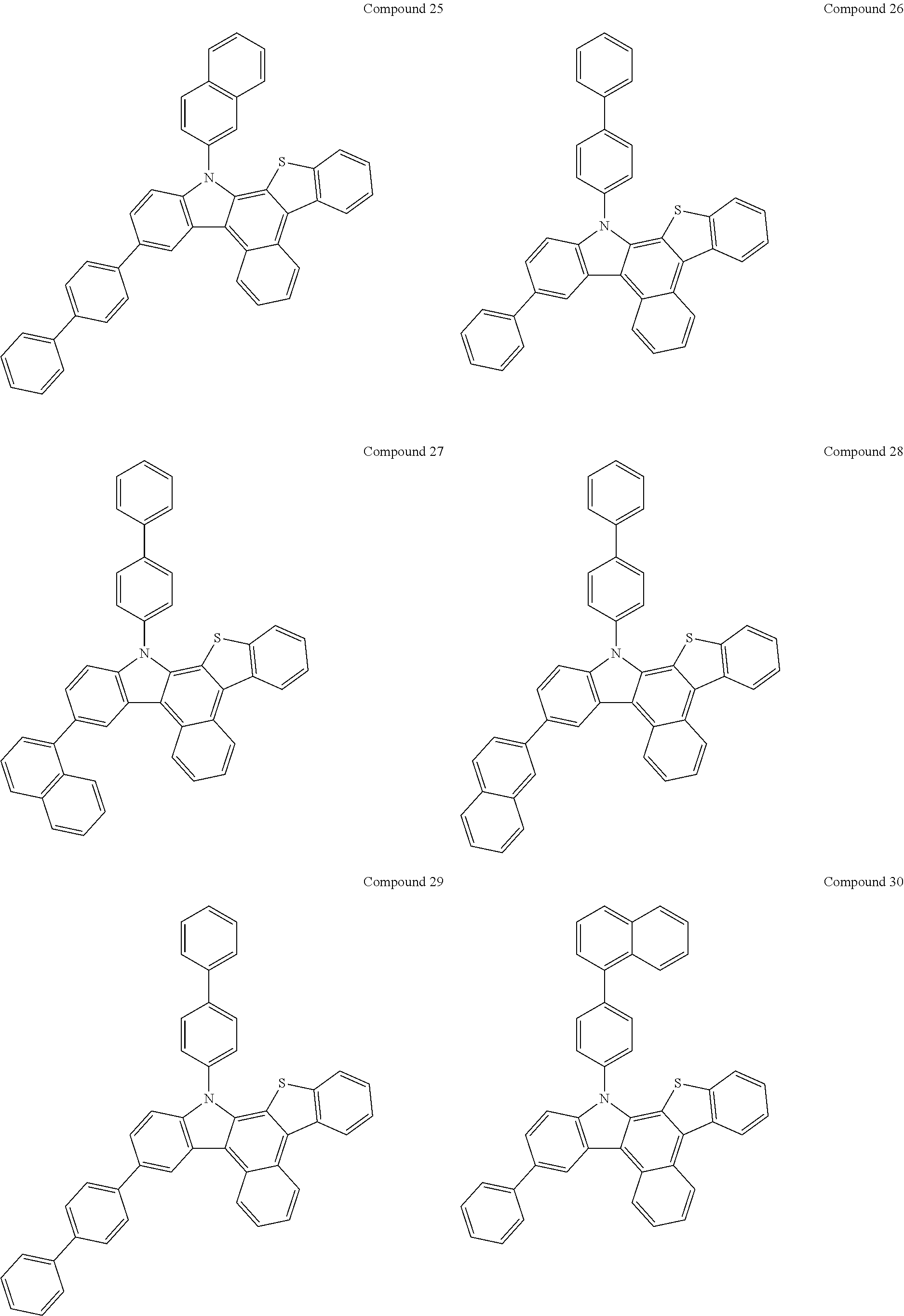 [SMILES: c1ccc(-c2ccc(-c3ccc4c(c3)c3c5ccccc5c5c6ccccc6sc5c3n4-c3ccc4ccccc4c3)cc2)cc1 ; c1ccc(-c2ccc(-n3c4ccc(-c5ccccc5)cc4c4c5ccccc5c5c6ccccc6sc5c43)cc2)cc1 ; c1ccc(-c2ccc(-n3c4ccc(-c5cccc6ccccc56)cc4c4c5ccccc5c5c6ccccc6sc5c43)cc2)cc1 ; c1ccc(-c2ccc(-n3c4ccc(-c5ccc6ccccc6c5)cc4c4c5ccccc5c5c6ccccc6sc5c43)cc2)cc1 ; c1ccc(-c2ccc(-c3ccc4c(c3)c3c5ccccc5c5c6ccccc6sc5c3n4-c3ccc(-c4ccccc4)cc3)cc2)cc1 ; c1ccc(-c2ccc3c(c2)c2c4ccccc4c4c5ccccc5sc4c2n3-c2ccc(-c3cccc4ccccc34)cc2)cc1]

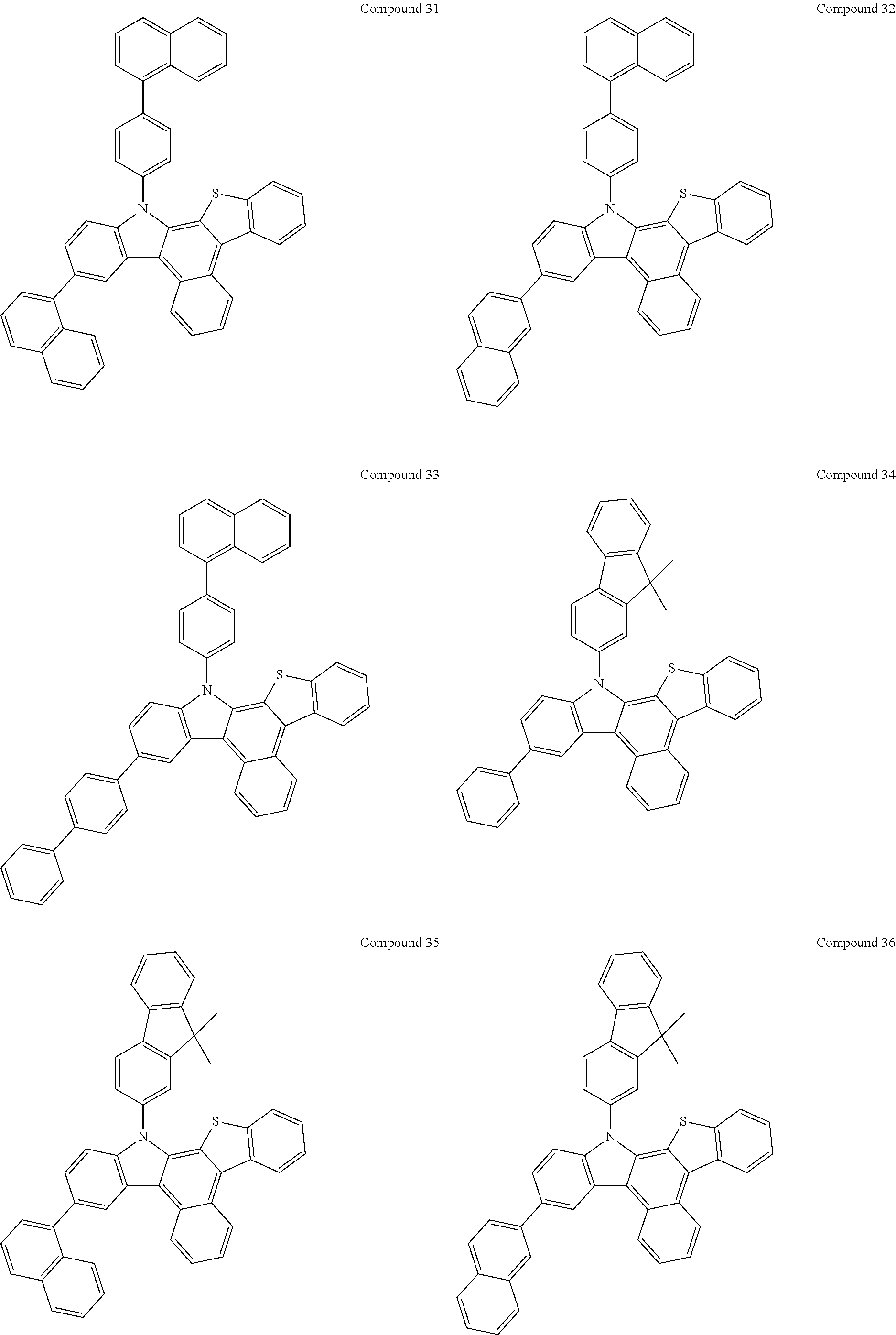 [SMILES: c1ccc2c(-c3ccc(-n4c5ccc(-c6cccc7ccccc67)cc5c5c6ccccc6c6c7ccccc7sc6c54)cc3)cccc2c1 ; c1ccc2cc(-c3ccc4c(c3)c3c5ccccc5c5c6ccccc6sc5c3n4-c3ccc(-c4cccc5ccccc45)cc3)ccc2c1 ; c1ccc(-c2ccc(-c3ccc4c(c3)c3c5ccccc5c5c6ccccc6sc5c3n4-c3ccc(-c4cccc5ccccc45)cc3)cc2)cc1 ; CC1(C)c2ccccc2-c2ccc(-n3c4ccc(-c5ccccc5)cc4c4c5ccccc5c5c6ccccc6sc5c43)cc21 ; CC1(C)c2ccccc2-c2ccc(-n3c4ccc(-c5cccc6ccccc56)cc4c4c5ccccc5c5c6ccccc6sc5c43)cc21 ; CC1(C)c2ccccc2-c2ccc(-n3c4ccc(-c5ccc6ccccc6c5)cc4c4c5ccccc5c5c6ccccc6sc5c43)cc21]

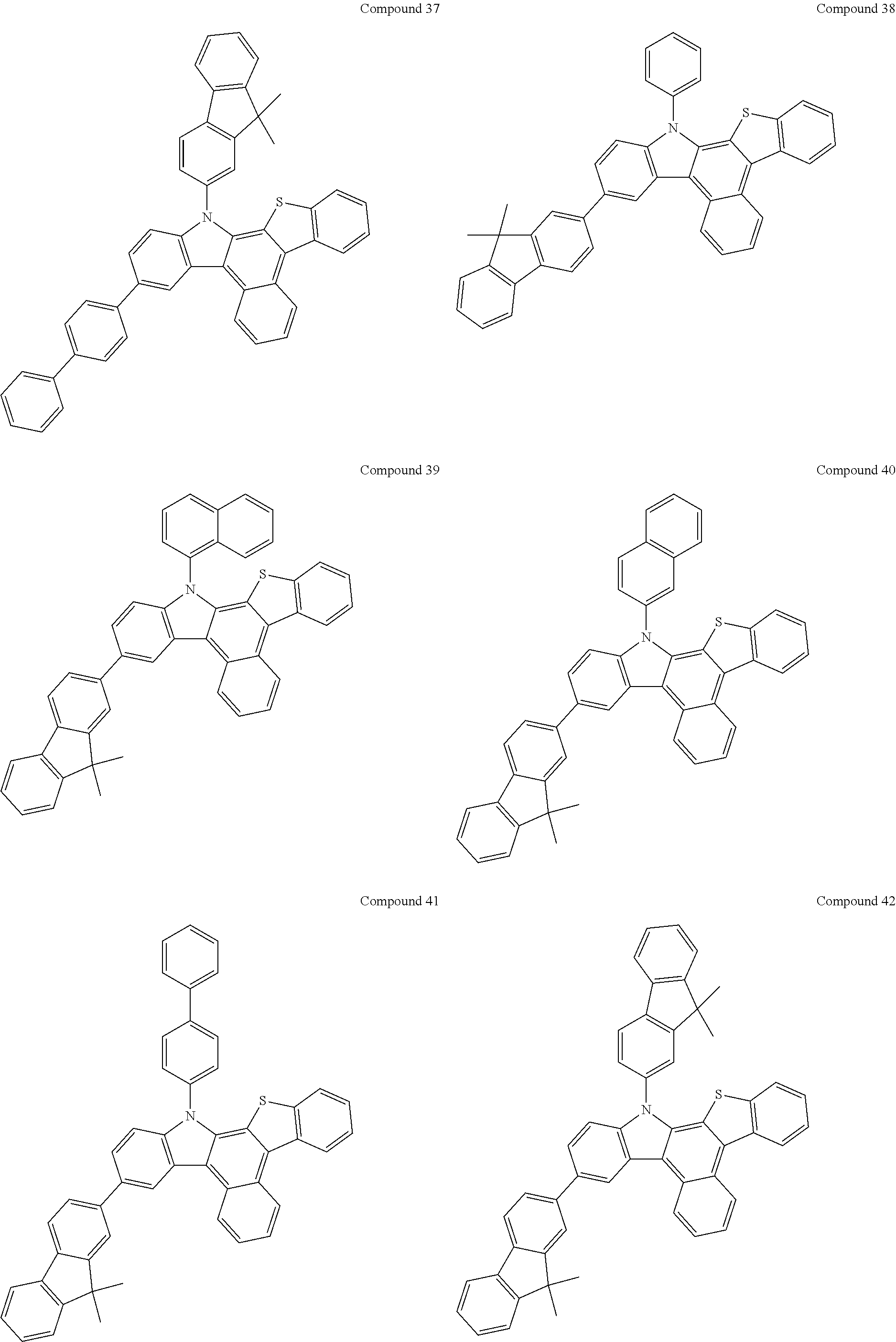

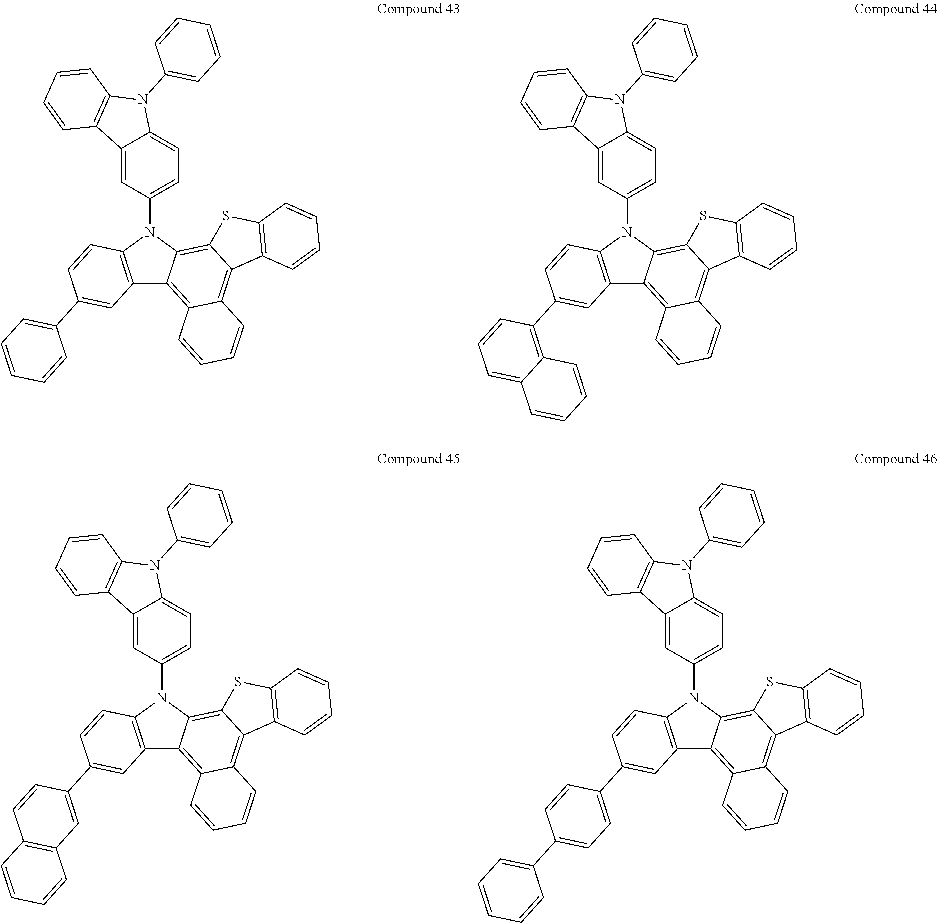 [SMILES: c1ccc(-c2ccc3c(c2)c2c4ccccc4c4c5ccccc5sc4c2n3-c2ccc3c(c2)c2ccccc2n3-c2ccccc2)cc1 ; c1ccc(-n2c3ccccc3c3cc(-n4c5ccc(-c6cccc7ccccc67)cc5c5c6ccccc6c6c7ccccc7sc6c54)ccc32)cc1 ; c1ccc(-n2c3ccccc3c3cc(-n4c5ccc(-c6ccc7ccccc7c6)cc5c5c6ccccc6c6c7ccccc7sc6c54)ccc32)cc1 ; c1ccc(-c2ccc(-c3ccc4c(c3)c3c5ccccc5c5c6ccccc6sc5c3n4-c3ccc4c(c3)c3ccccc3n4-c3ccccc3)cc2)cc1]

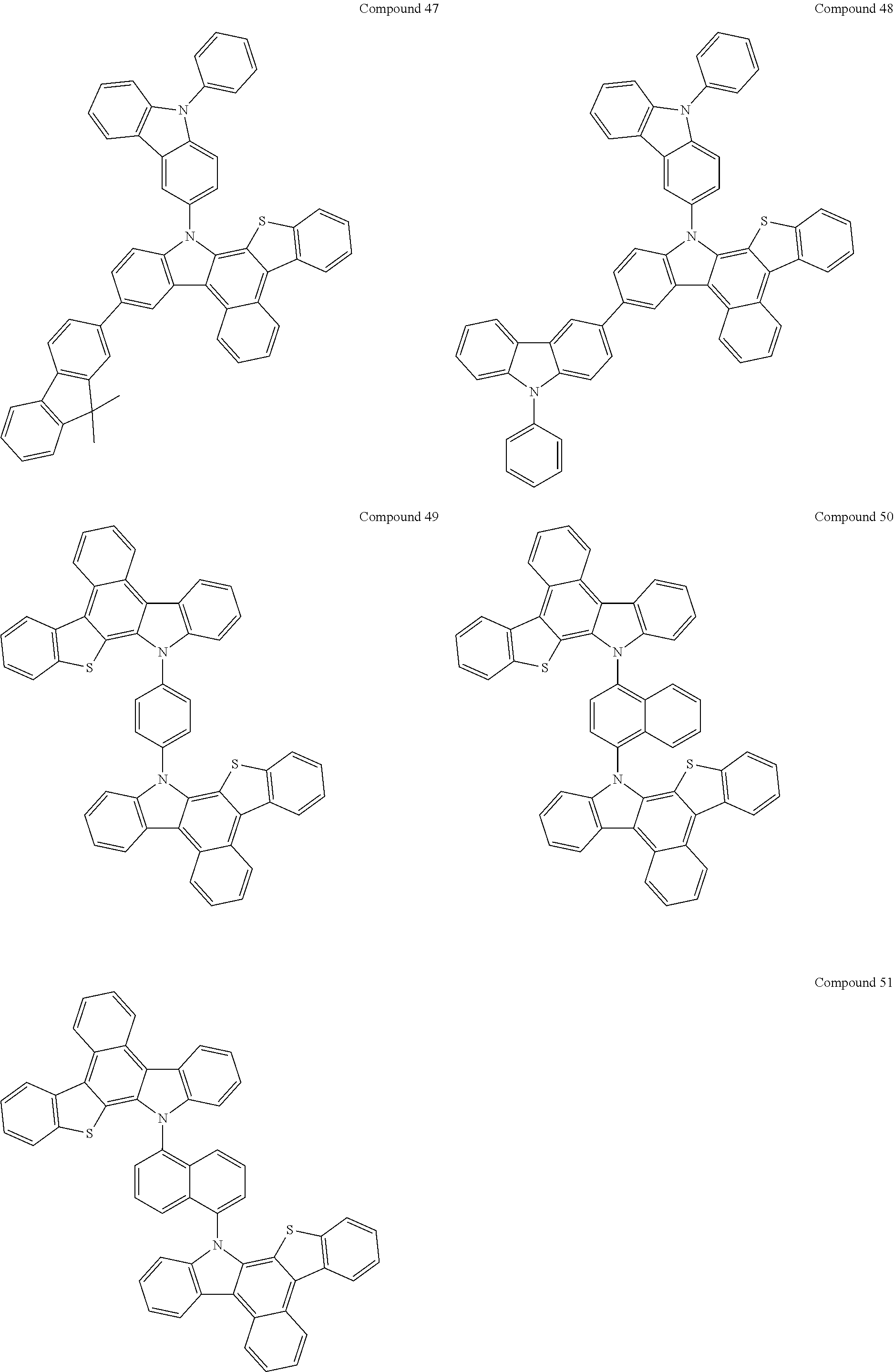 [SMILES: CC1(C)c2ccccc2-c2ccc(-c3ccc4c(c3)c3c5ccccc5c5c6ccccc6sc5c3n4-c3ccc4c(c3)c3ccccc3n4-c3ccccc3)cc21 ; c1ccc(-n2c3ccccc3c3cc(-c4ccc5c(c4)c4c6ccccc6c6c7ccccc7sc6c4n5-c4ccc5c(c4)c4ccccc4n5-c4ccccc4)ccc32)cc1 ; c1ccc2c(c1)sc1c2c2ccccc2c2c3ccccc3n(-c3ccc(-n4c5ccccc5c5c6ccccc6c6c7ccccc7sc6c54)cc3)c12 ; c1ccc2c(c1)sc1c2c2ccccc2c2c3ccccc3n(-c3ccc(-n4c5ccccc5c5c6ccccc6c6c7ccccc7sc6c54)c4ccccc34)c12 ; c1ccc2c(c1)sc1c2c2ccccc2c2c3ccccc3n(-c3cccc4c(-n5c6ccccc6c6c7ccccc7c7c8ccccc8sc7c65)cccc34)c12]

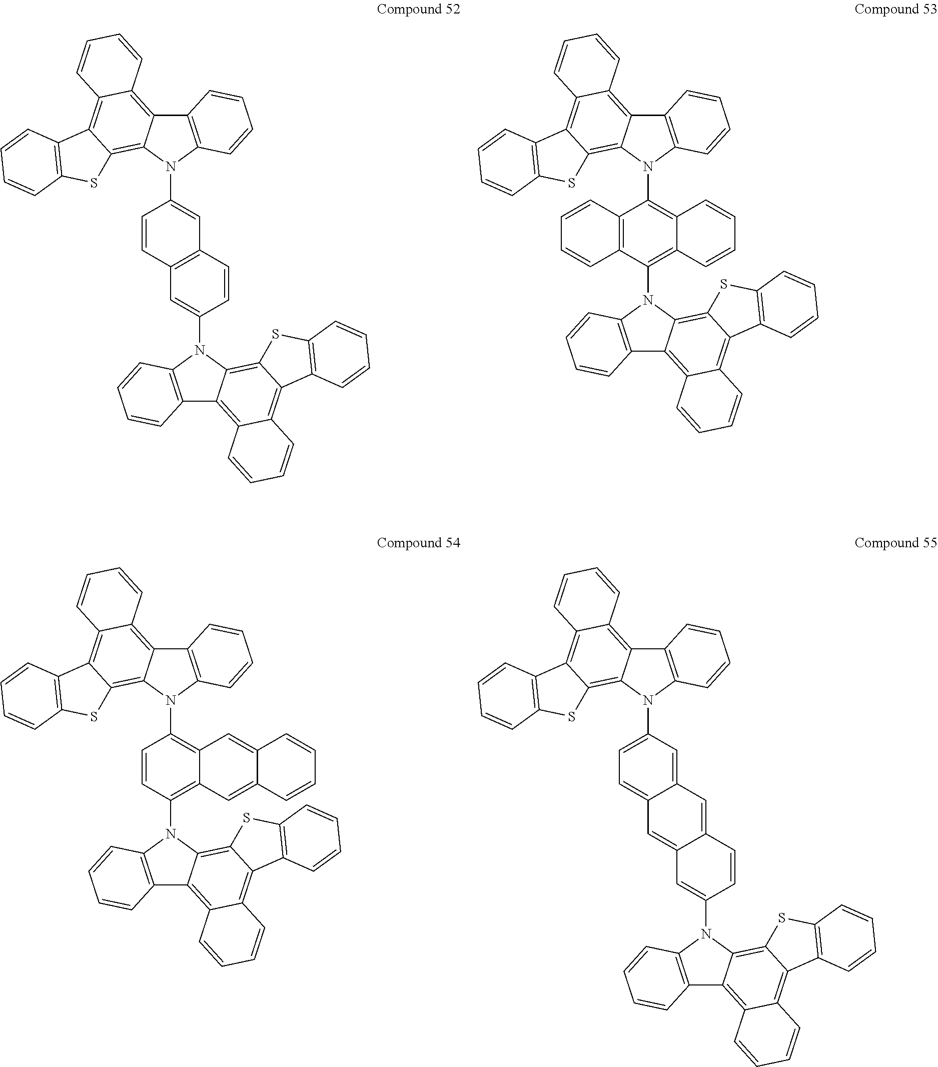 [SMILES: c1ccc2c(c1)sc1c2c2ccccc2c2c3ccccc3n(-c3ccc4cc(-n5c6ccccc6c6c7ccccc7c7c8ccccc8sc7c65)ccc4c3)c12 ; c1ccc2c(c1)sc1c2c2ccccc2c2c3ccccc3n(-c3c4ccccc4c(-n4c5ccccc5c5c6ccccc6c6c7ccccc7sc6c54)c4ccccc34)c12 ; c1ccc2cc3c(-n4c5ccccc5c5c6ccccc6c6c7ccccc7sc6c54)ccc(-n4c5ccccc5c5c6ccccc6c6c7ccccc7sc6c54)c3cc2c1 ; c1ccc2c(c1)sc1c2c2ccccc2c2c3ccccc3n(-c3ccc4cc5cc(-n6c7ccccc7c7c8ccccc8c8c9ccccc9sc8c76)ccc5cc4c3)c12]

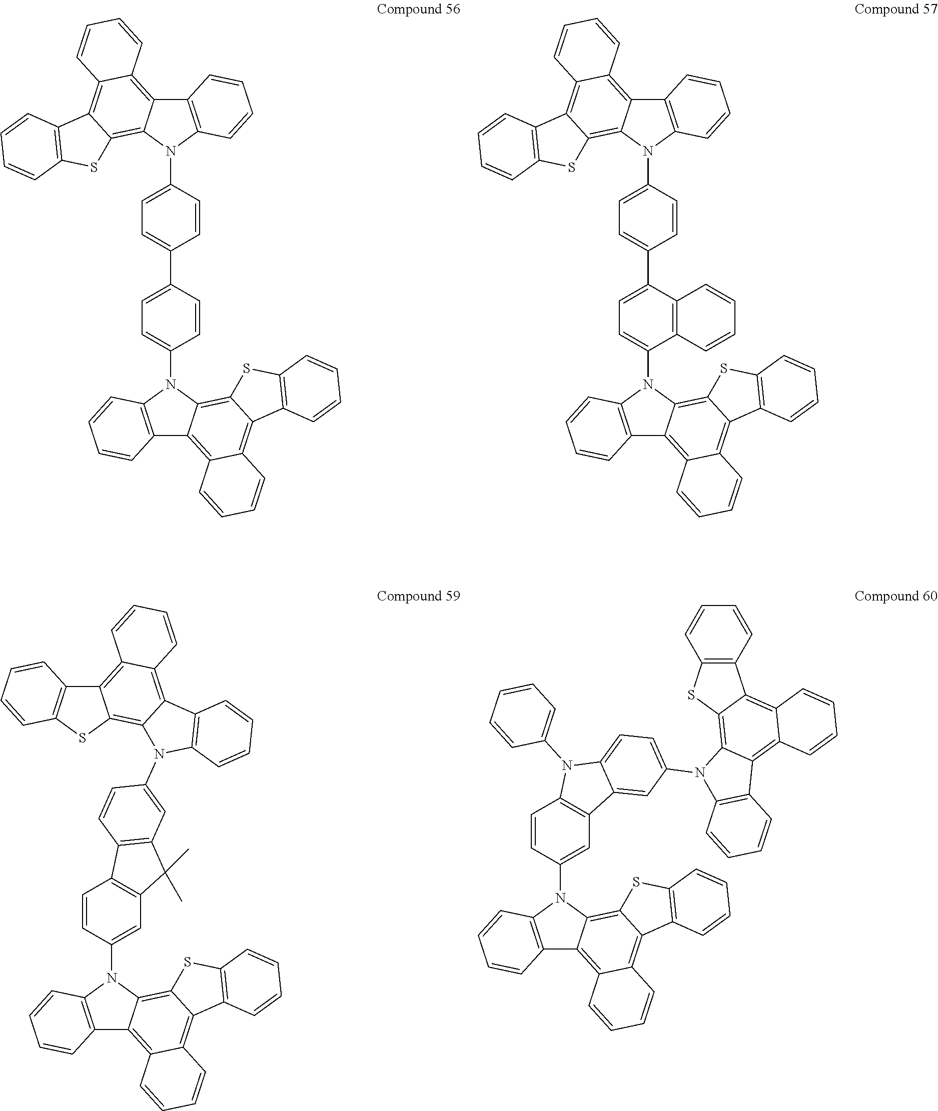 [SMILES: c1ccc2c(c1)sc1c2c2ccccc2c2c3ccccc3n(-c3ccc(-c4ccc(-n5c6ccccc6c6c7ccccc7c7c8ccccc8sc7c65)cc4)cc3)c12 ; c1ccc2c(c1)sc1c2c2ccccc2c2c3ccccc3n(-c3ccc(-c4ccc(-n5c6ccccc6c6c7ccccc7c7c8ccccc8sc7c65)c5ccccc45)cc3)c12 ; CC1(C)c2cc(-n3c4ccccc4c4c5ccccc5c5c6ccccc6sc5c43)ccc2-c2ccc(-n3c4ccccc4c4c5ccccc5c5c6ccccc6sc5c43)cc21 ; c1ccc(-n2c3ccc(-n4c5ccccc5c5c6ccccc6c6c7ccccc7sc6c54)cc3c3cc(-n4c5ccccc5c5c6ccccc6c6c7ccccc7sc6c54)ccc32)cc1]

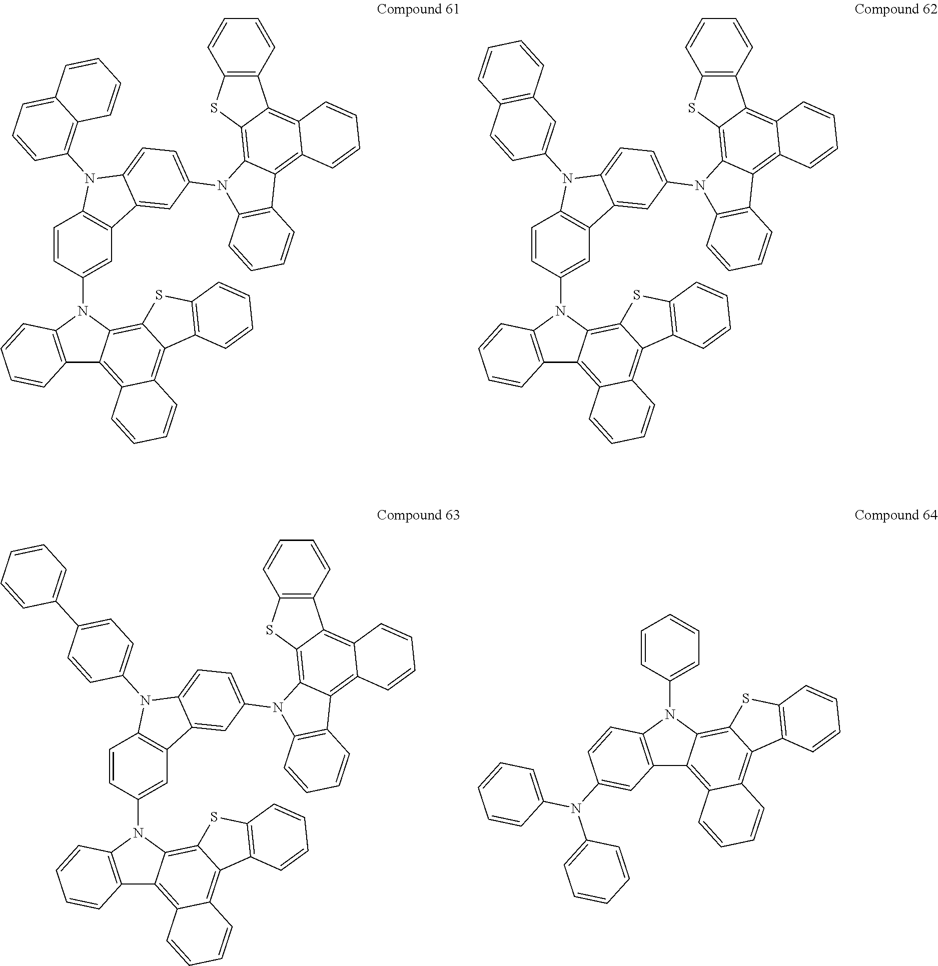 [SMILES: c1ccc2c(-n3c4ccc(-n5c6ccccc6c6c7ccccc7c7c8ccccc8sc7c65)cc4c4cc(-n5c6ccccc6c6c7ccccc7c7c8ccccc8sc7c65)ccc43)cccc2c1 ; c1ccc2cc(-n3c4ccc(-n5c6ccccc6c6c7ccccc7c7c8ccccc8sc7c65)cc4c4cc(-n5c6ccccc6c6c7ccccc7c7c8ccccc8sc7c65)ccc43)ccc2c1 ; c1ccc(-c2ccc(-n3c4ccc(-n5c6ccccc6c6c7ccccc7c7c8ccccc8sc7c65)cc4c4cc(-n5c6ccccc6c6c7ccccc7c7c8ccccc8sc7c65)ccc43)cc2)cc1 ; c1ccc(N(c2ccccc2)c2ccc3c(c2)c2c4ccccc4c4c5ccccc5sc4c2n3-c2ccccc2)cc1]

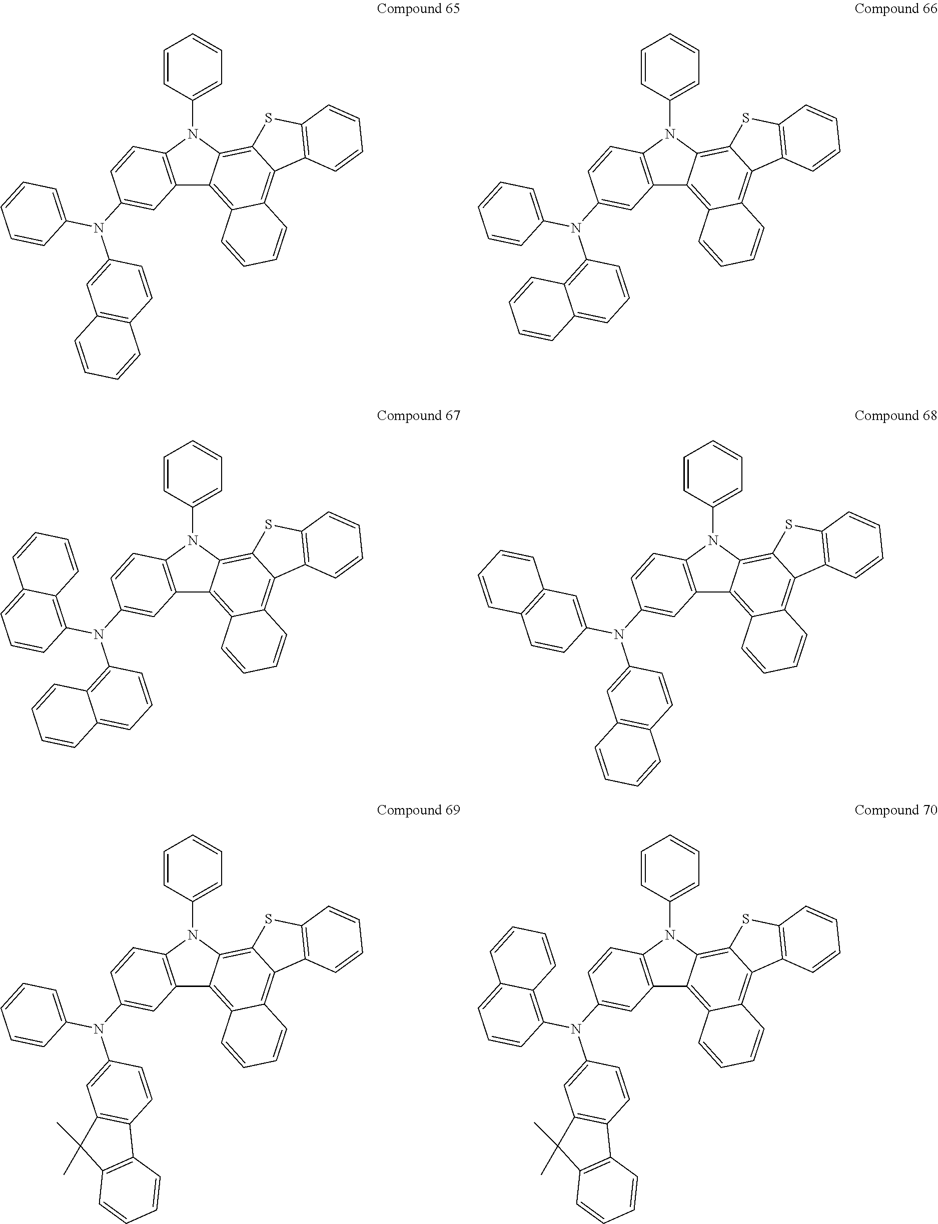 [SMILES: c1ccc(N(c2ccc3ccccc3c2)c2ccc3c(c2)c2c4ccccc4c4c5ccccc5sc4c2n3-c2ccccc2)cc1 ; c1ccc(N(c2ccc3c(c2)c2c4ccccc4c4c5ccccc5sc4c2n3-c2ccccc2)c2cccc3ccccc23)cc1 ; c1ccc(-n2c3ccc(N(c4cccc5ccccc45)c4cccc5ccccc45)cc3c3c4ccccc4c4c5ccccc5sc4c32)cc1 ; c1ccc(-n2c3ccc(N(c4ccc5ccccc5c4)c4ccc5ccccc5c4)cc3c3c4ccccc4c4c5ccccc5sc4c32)cc1 ; CC1(C)c2ccccc2-c2ccc(N(c3ccccc3)c3ccc4c(c3)c3c5ccccc5c5c6ccccc6sc5c3n4-c3ccccc3)cc21 ; CC1(C)c2ccccc2-c2ccc(N(c3ccc4c(c3)c3c5ccccc5c5c6ccccc6sc5c3n4-c3ccccc3)c3cccc4ccccc34)cc21]

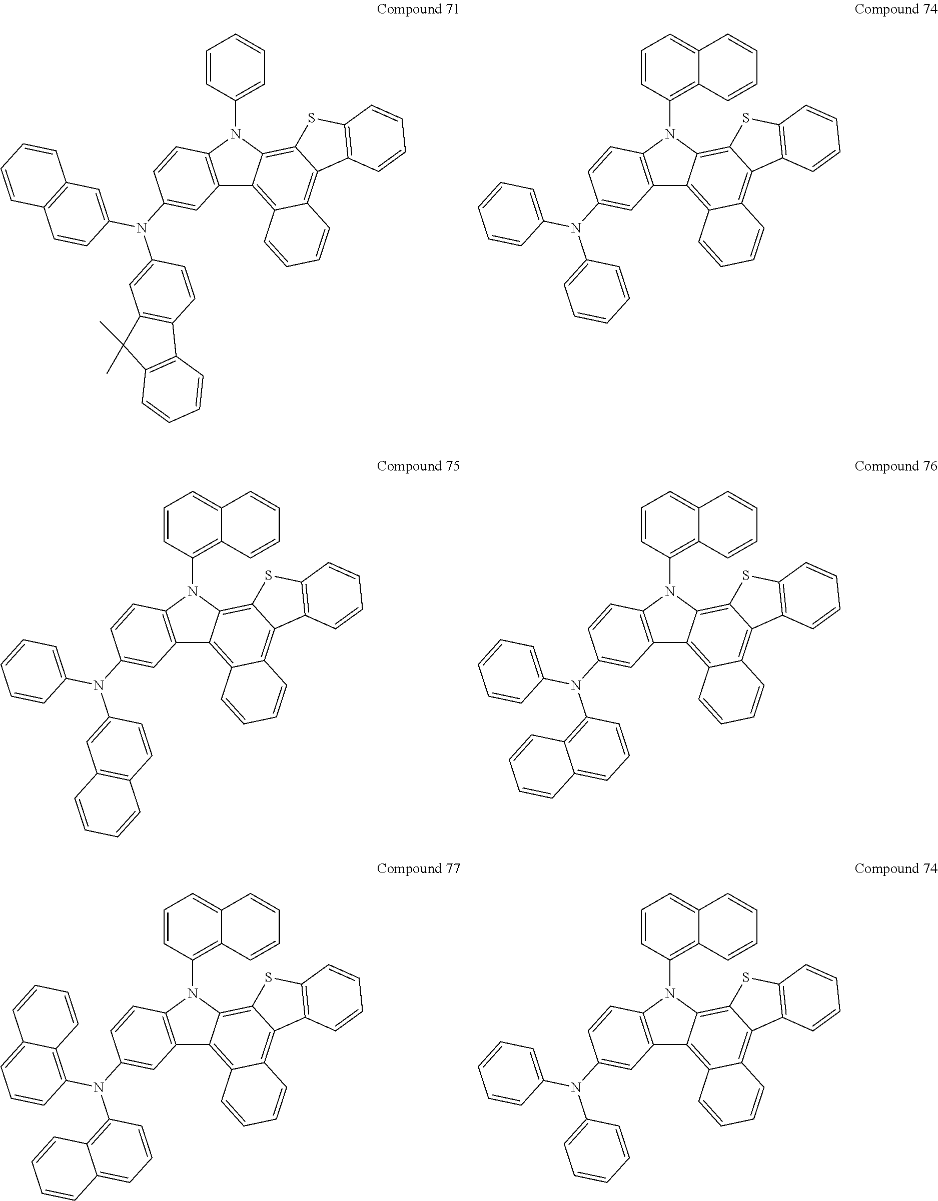 [SMILES: CC1(C)c2ccccc2-c2ccc(N(c3ccc4ccccc4c3)c3ccc4c(c3)c3c5ccccc5c5c6ccccc6sc5c3n4-c3ccccc3)cc21 ; c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1 ; c1ccc(N(c2ccc3c(c2)c2c4ccccc4c4c5ccccc5sc4c2n3-c2cccc3ccccc23)c2cccc3ccccc23)cc1 ; c1ccc2c(N(c3ccc4c(c3)c3c5ccccc5c5c6ccccc6sc5c3n4-c3cccc4ccccc34)c3cccc4ccccc34)cccc2c1 ; c1ccc(N(c2ccccc2)c2ccc3c(c2)c2c4ccccc4c4c5ccccc5sc4c2n3-c2cccc3ccccc23)cc1]

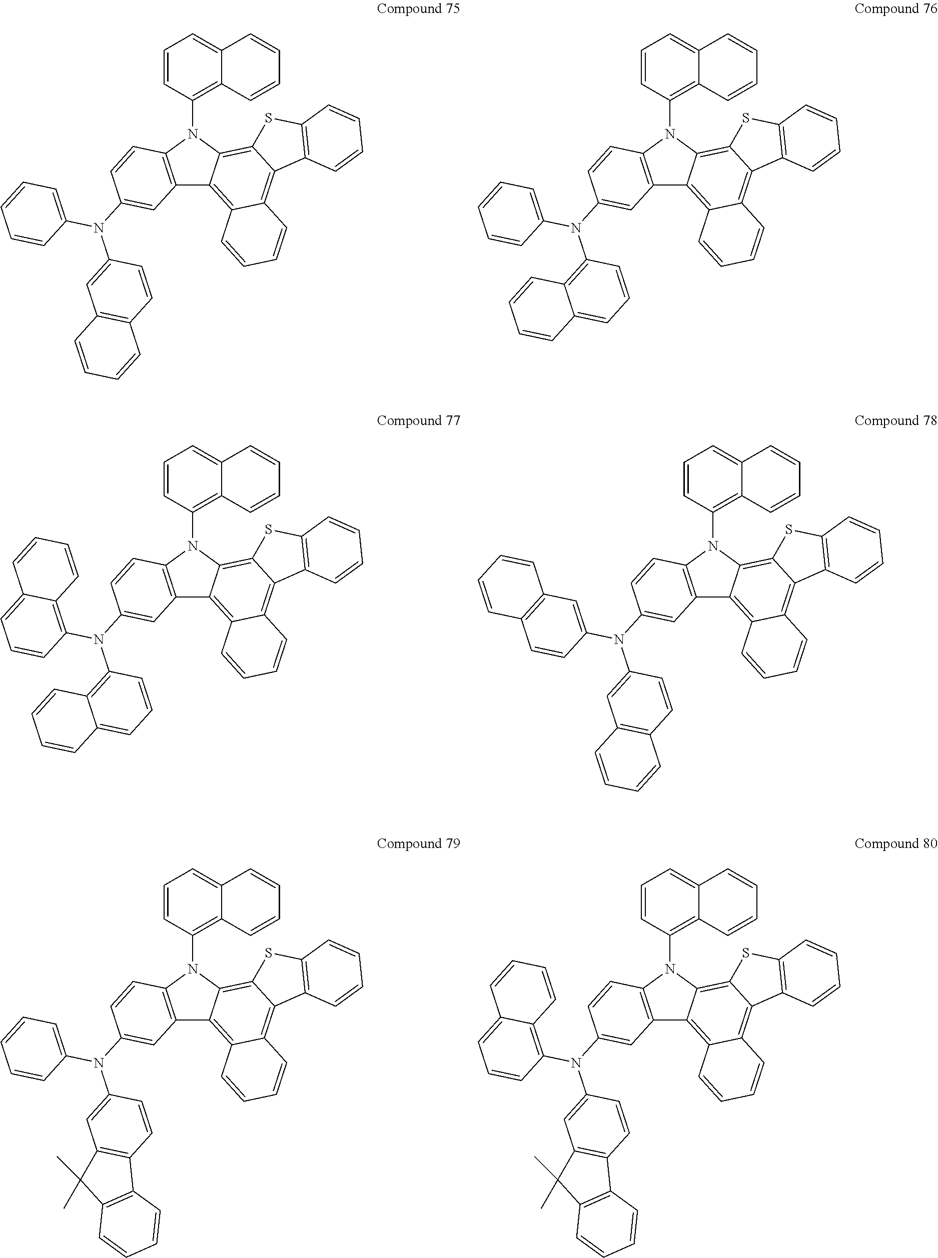

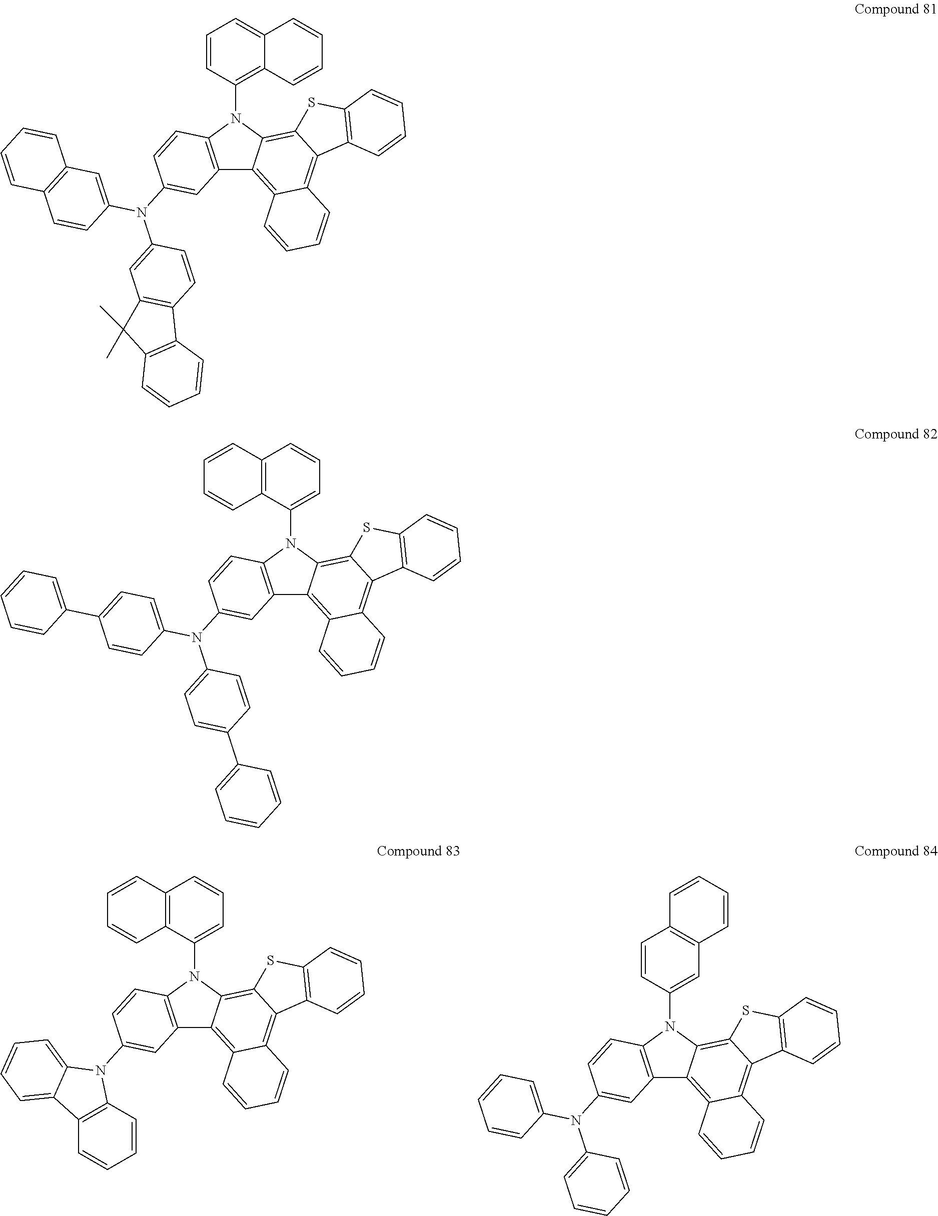 [SMILES: CC1(C)c2ccccc2-c2ccc(N(c3ccc4ccccc4c3)c3ccc4c(c3)c3c5ccccc5c5c6ccccc6sc5c3n4-c3cccc4ccccc34)cc21 ; c1ccc(-c2ccc(N(c3ccc(-c4ccccc4)cc3)c3ccc4c(c3)c3c5ccccc5c5c6ccccc6sc5c3n4-c3cccc4ccccc34)cc2)cc1 ; c1ccc2c(-n3c4ccc(-n5c6ccccc6c6ccccc65)cc4c4c5ccccc5c5c6ccccc6sc5c43)cccc2c1 ; c1ccc(N(c2ccccc2)c2ccc3c(c2)c2c4ccccc4c4c5ccccc5sc4c2n3-c2ccc3ccccc3c2)cc1]

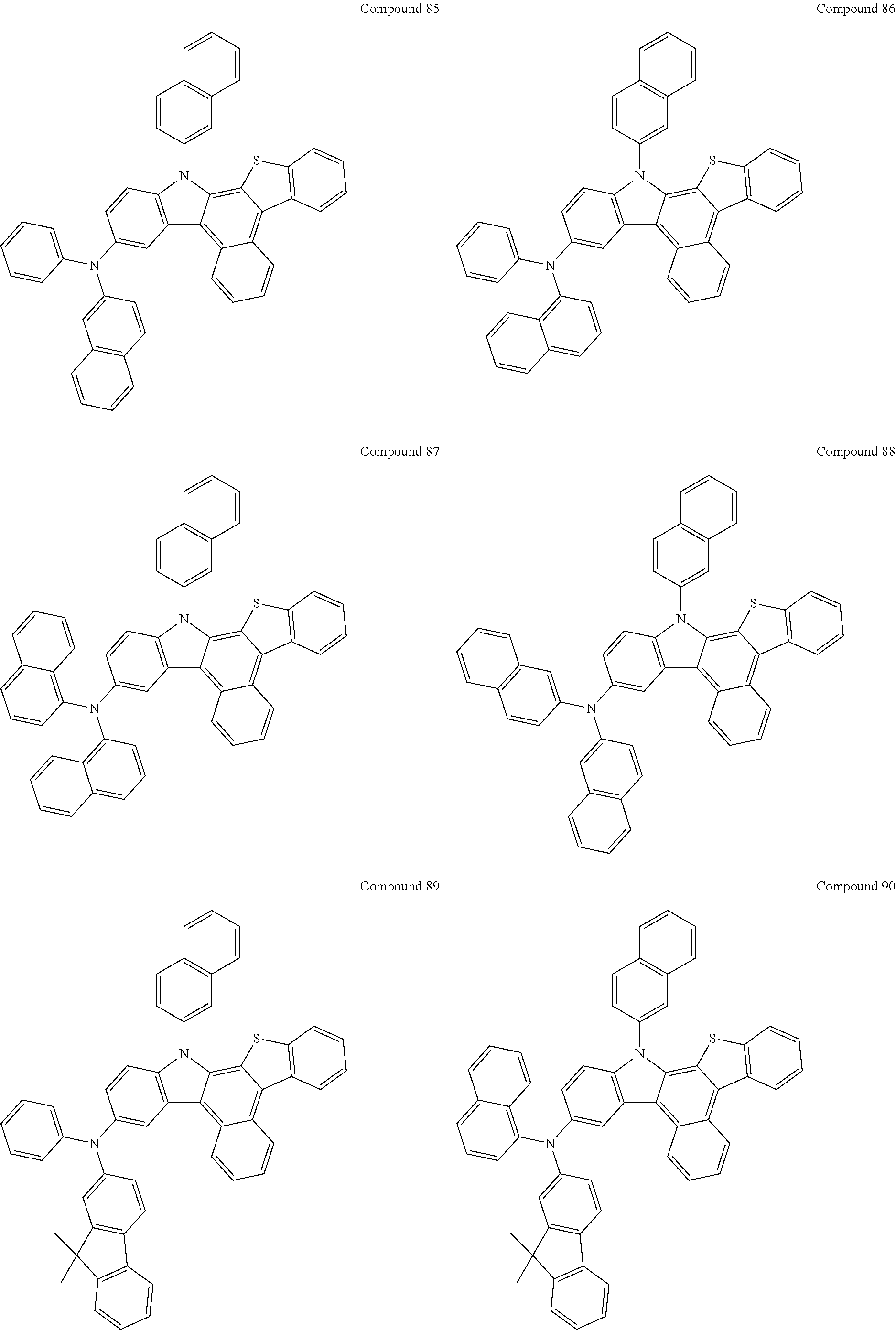

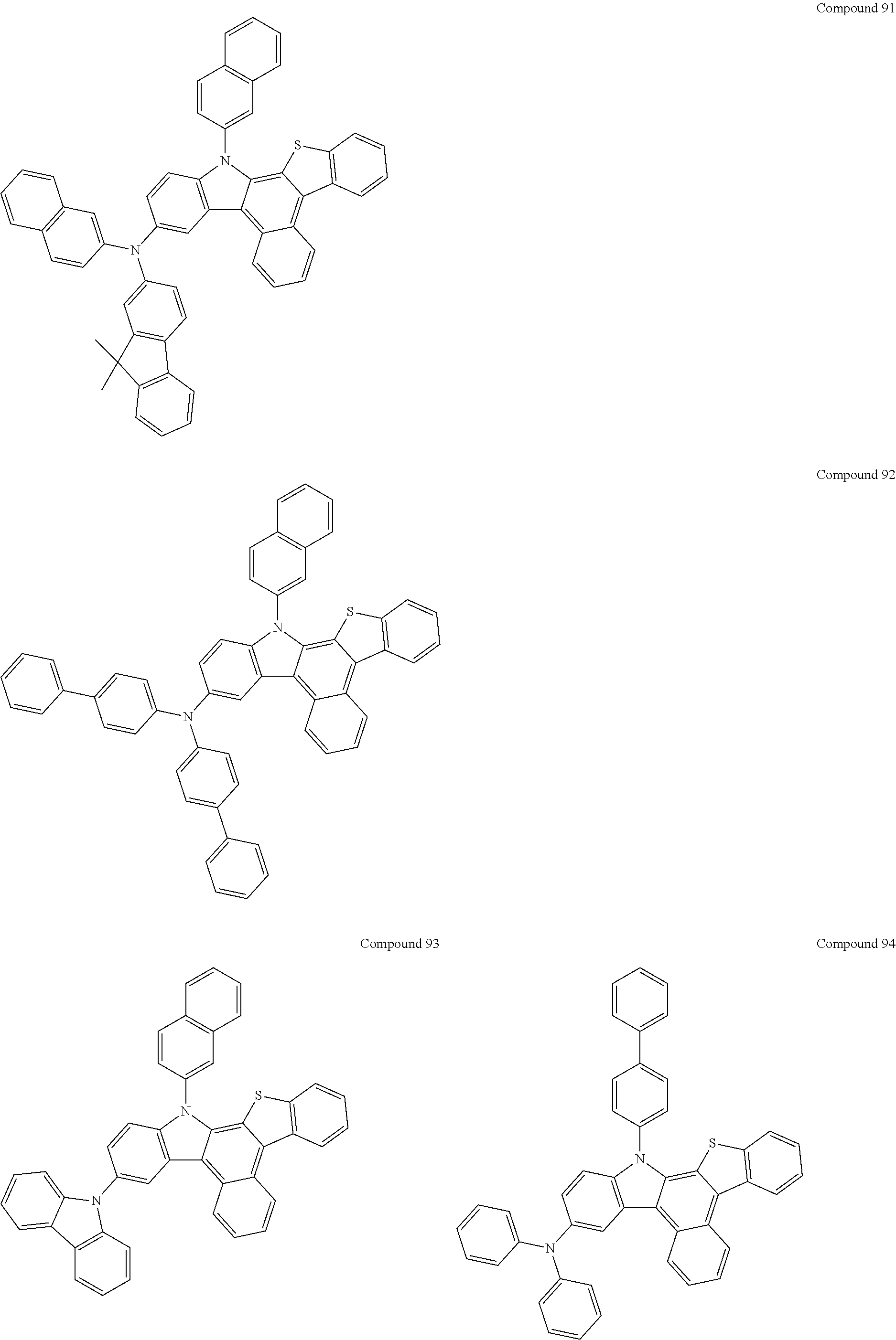 [SMILES: CC1(C)c2ccccc2-c2ccc(N(c3ccc4ccccc4c3)c3ccc4c(c3)c3c5ccccc5c5c6ccccc6sc5c3n4-c3ccc4ccccc4c3)cc21 ; c1ccc(-c2ccc(N(c3ccc(-c4ccccc4)cc3)c3ccc4c(c3)c3c5ccccc5c5c6ccccc6sc5c3n4-c3ccc4ccccc4c3)cc2)cc1 ; c1ccc2cc(-n3c4ccc(-n5c6ccccc6c6ccccc65)cc4c4c5ccccc5c5c6ccccc6sc5c43)ccc2c1 ; c1ccc(-c2ccc(-n3c4ccc(N(c5ccccc5)c5ccccc5)cc4c4c5ccccc5c5c6ccccc6sc5c43)cc2)cc1]

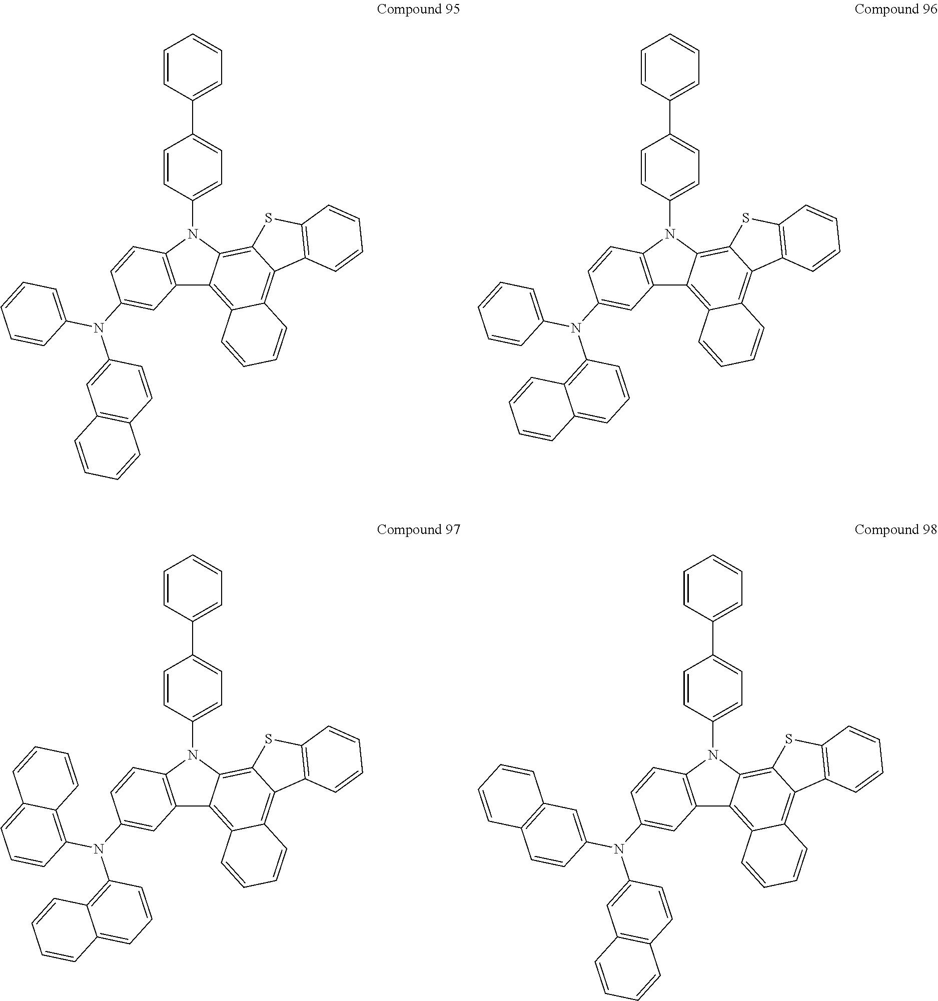 [SMILES: c1ccc(-c2ccc(-n3c4ccc(N(c5ccccc5)c5ccc6ccccc6c5)cc4c4c5ccccc5c5c6ccccc6sc5c43)cc2)cc1 ; c1ccc(-c2ccc(-n3c4ccc(N(c5ccccc5)c5cccc6ccccc56)cc4c4c5ccccc5c5c6ccccc6sc5c43)cc2)cc1 ; c1ccc(-c2ccc(-n3c4ccc(N(c5cccc6ccccc56)c5cccc6ccccc56)cc4c4c5ccccc5c5c6ccccc6sc5c43)cc2)cc1 ; c1ccc(-c2ccc(-n3c4ccc(N(c5ccc6ccccc6c5)c5ccc6ccccc6c5)cc4c4c5ccccc5c5c6ccccc6sc5c43)cc2)cc1]

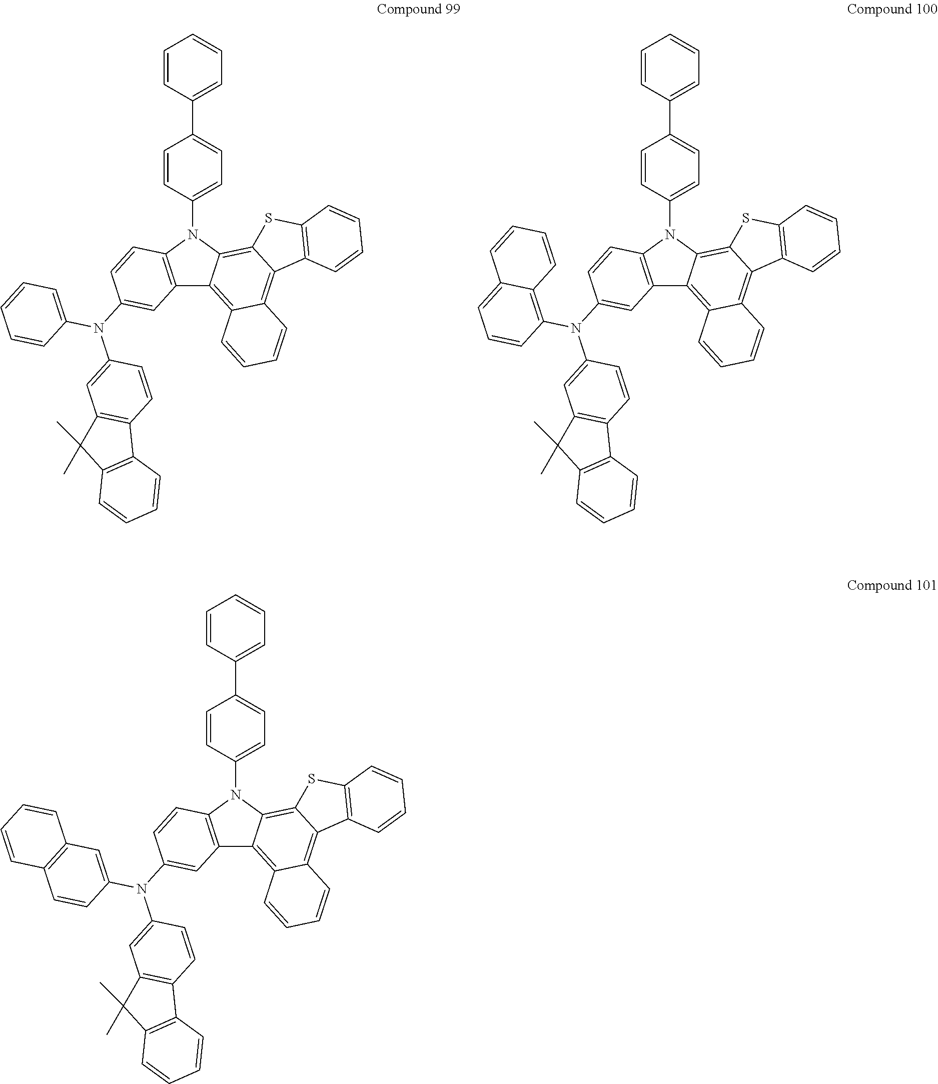 [SMILES: CC1(C)c2ccccc2-c2ccc(N(c3ccccc3)c3ccc4c(c3)c3c5ccccc5c5c6ccccc6sc5c3n4-c3ccc(-c4ccccc4)cc3)cc21 ; CC1(C)c2ccccc2-c2ccc(N(c3ccc4c(c3)c3c5ccccc5c5c6ccccc6sc5c3n4-c3ccc(-c4ccccc4)cc3)c3cccc4ccccc34)cc21 ; CC1(C)c2ccccc2-c2ccc(N(c3ccc4ccccc4c3)c3ccc4c(c3)c3c5ccccc5c5c6ccccc6sc5c3n4-c3ccc(-c4ccccc4)cc3)cc21]

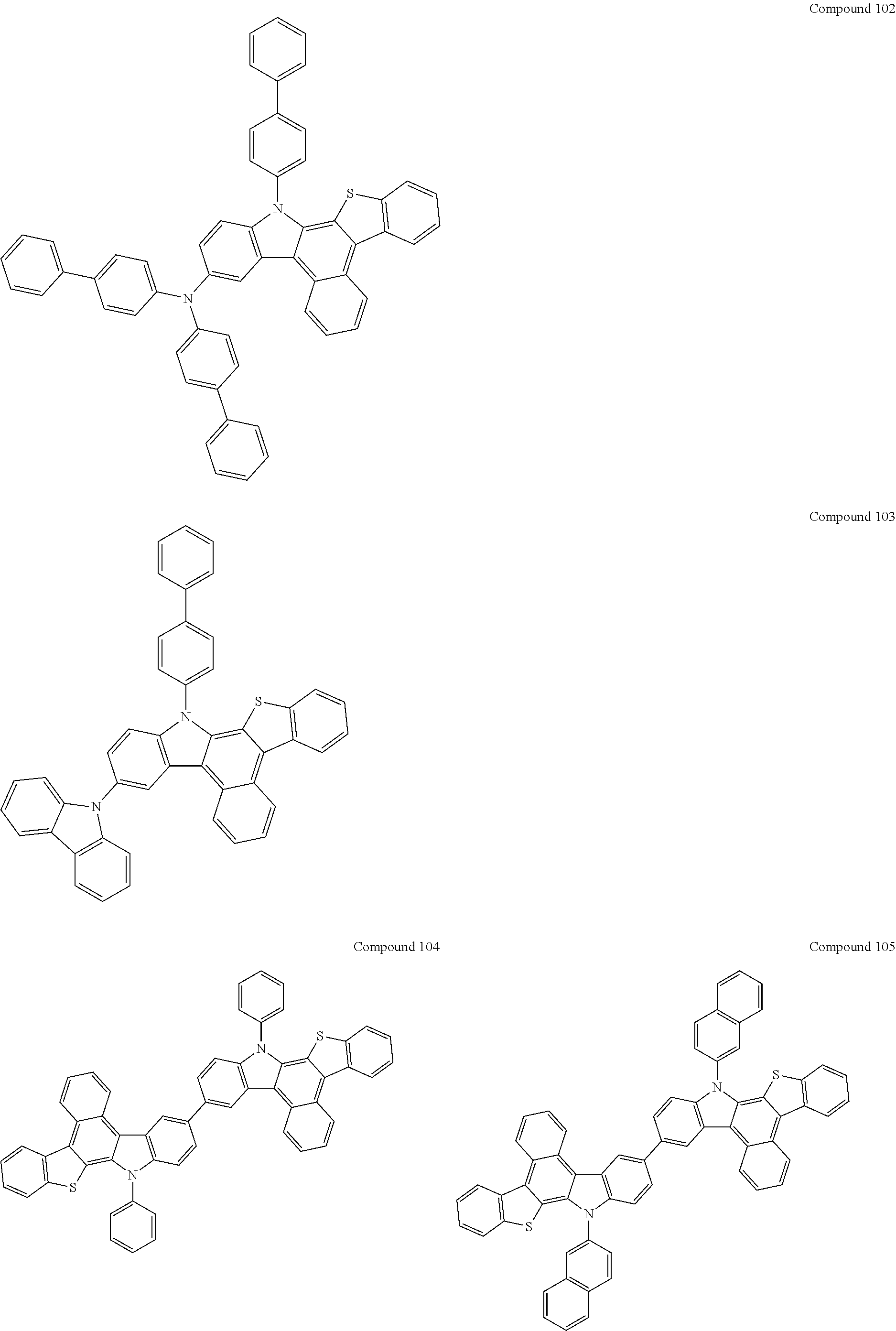 [SMILES: c1ccc(-c2ccc(N(c3ccc(-c4ccccc4)cc3)c3ccc4c(c3)c3c5ccccc5c5c6ccccc6sc5c3n4-c3ccc(-c4ccccc4)cc3)cc2)cc1 ; c1ccc(-c2ccc(-n3c4ccc(-n5c6ccccc6c6ccccc65)cc4c4c5ccccc5c5c6ccccc6sc5c43)cc2)cc1 ; c1ccc(-n2c3ccc(-c4ccc5c(c4)c4c6ccccc6c6c7ccccc7sc6c4n5-c4ccccc4)cc3c3c4ccccc4c4c5ccccc5sc4c32)cc1 ; c1ccc2cc(-n3c4ccc(-c5ccc6c(c5)c5c7ccccc7c7c8ccccc8sc7c5n6-c5ccc6ccccc6c5)cc4c4c5ccccc5c5c6ccccc6sc5c43)ccc2c1]

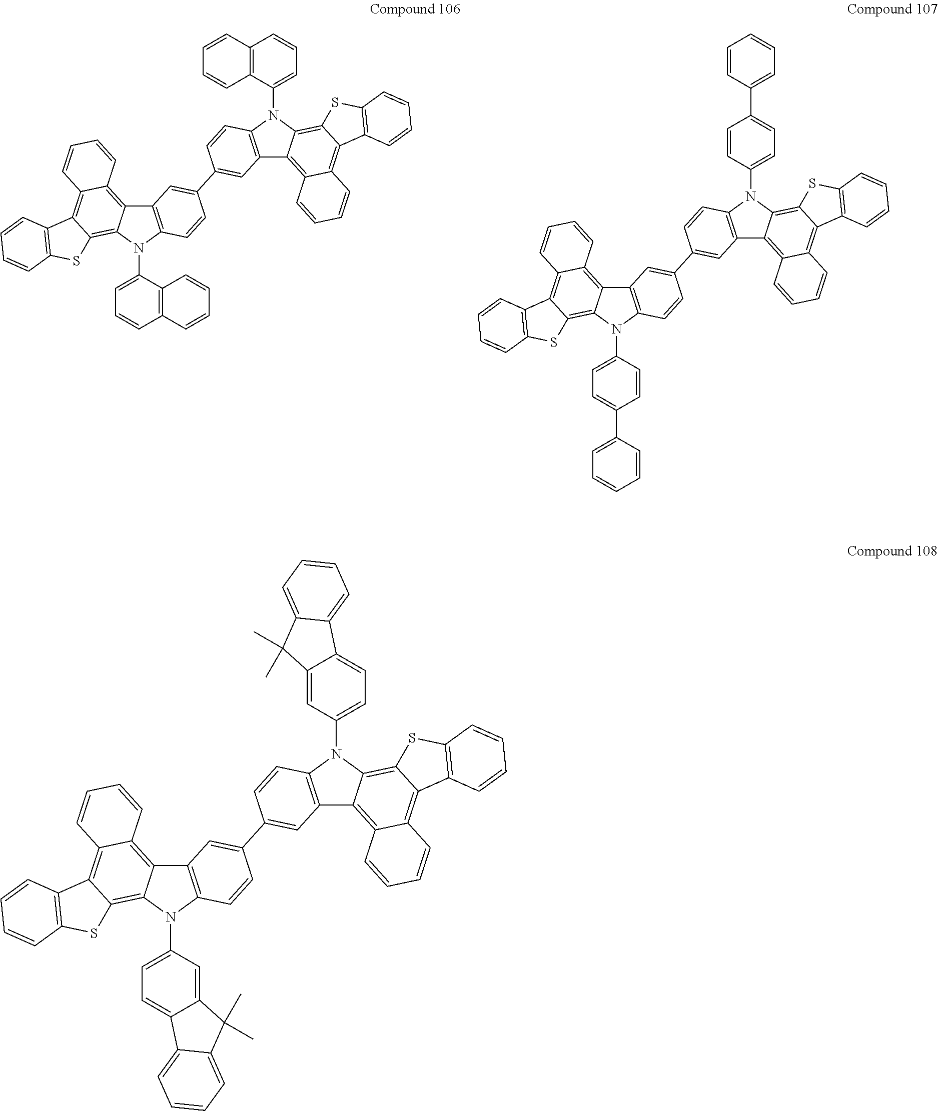 [SMILES: c1ccc2c(-n3c4ccc(-c5ccc6c(c5)c5c7ccccc7c7c8ccccc8sc7c5n6-c5cccc6ccccc56)cc4c4c5ccccc5c5c6ccccc6sc5c43)cccc2c1 ; c1ccc(-c2ccc(-n3c4ccc(-c5ccc6c(c5)c5c7ccccc7c7c8ccccc8sc7c5n6-c5ccc(-c6ccccc6)cc5)cc4c4c5ccccc5c5c6ccccc6sc5c43)cc2)cc1 ; CC1(C)c2ccccc2-c2ccc(-n3c4ccc(-c5ccc6c(c5)c5c7ccccc7c7c8ccccc8sc7c5n6-c5ccc6c(c5)C(C)(C)c5ccccc5-6)cc4c4c5ccccc5c5c6ccccc6sc5c43)cc21]

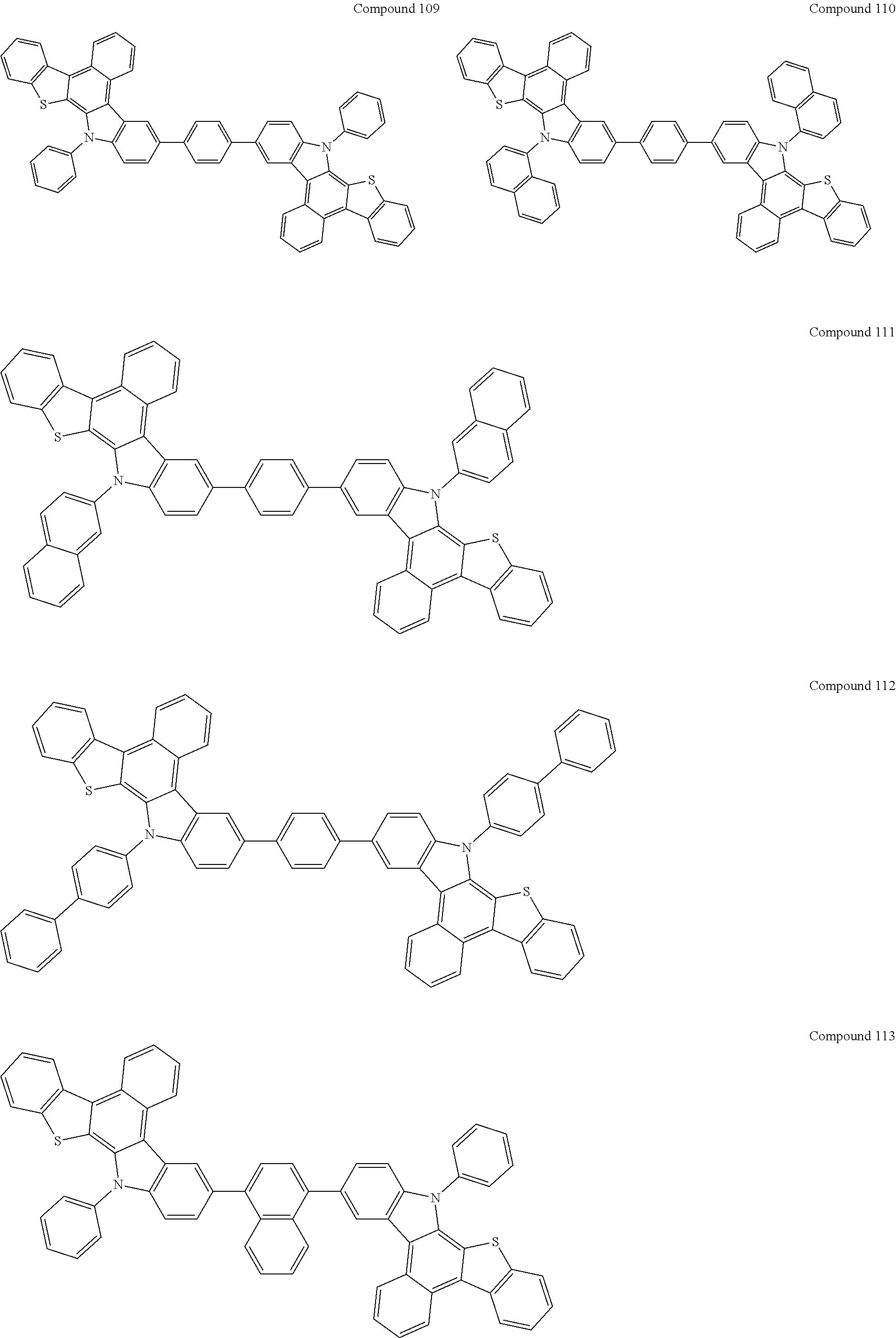

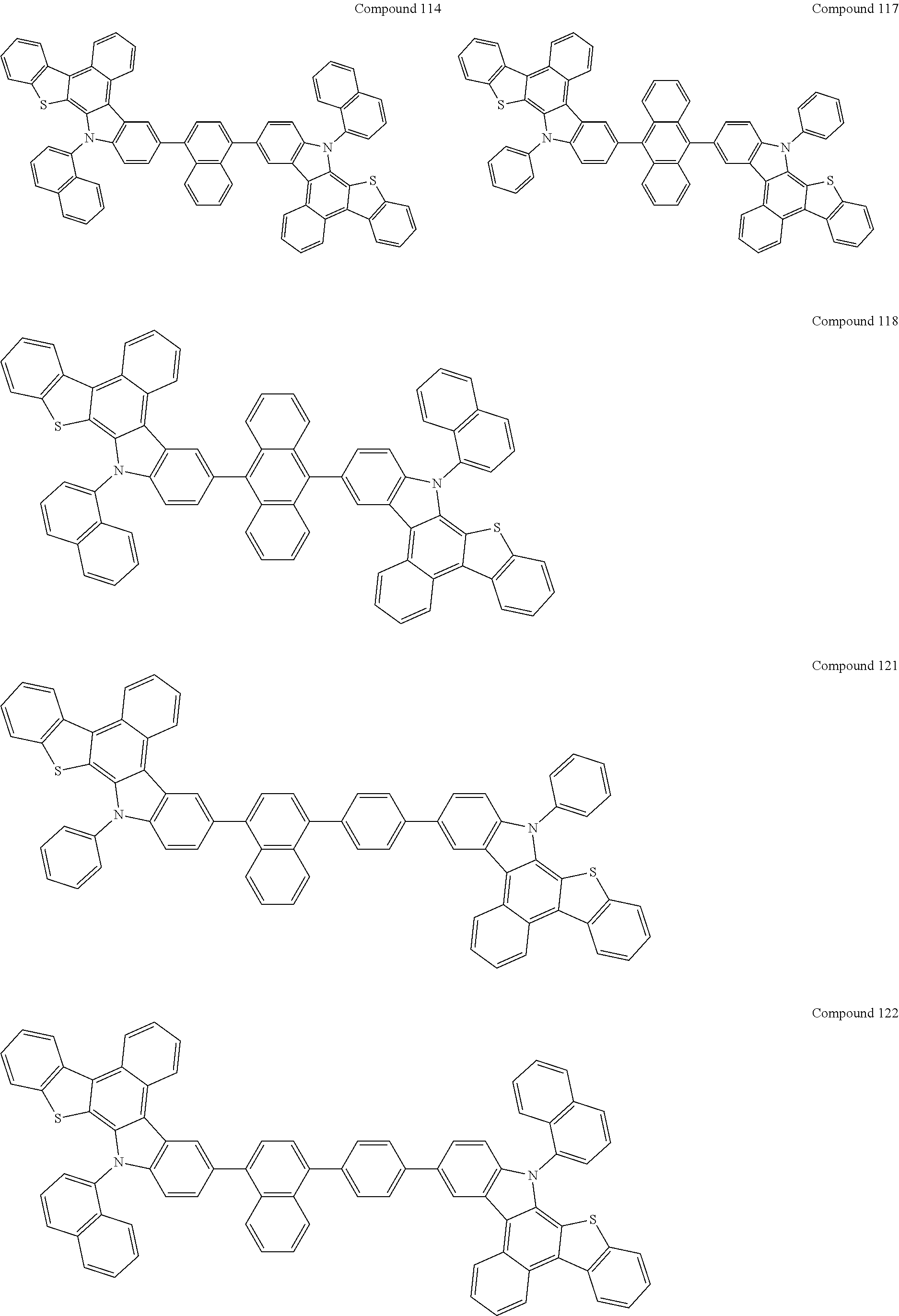

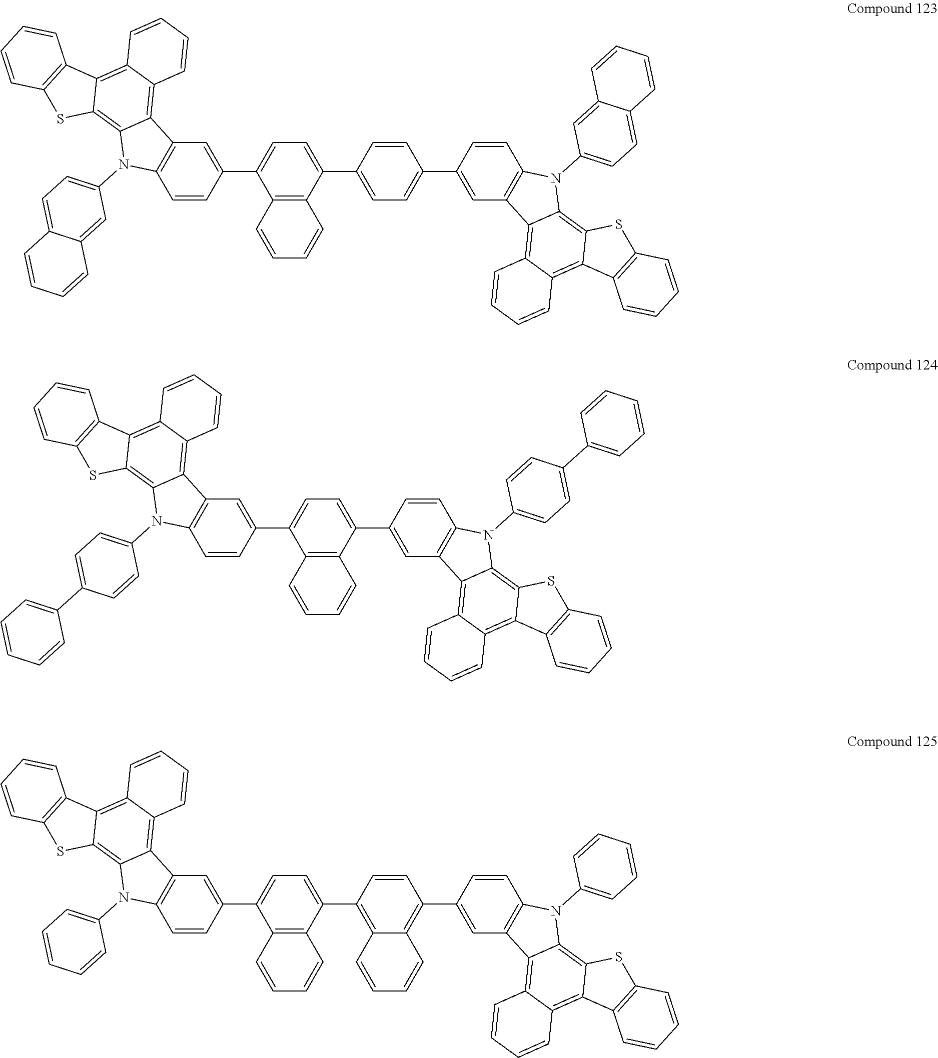 [SMILES: c1ccc2cc(-n3c4ccc(-c5ccc(-c6ccc(-c7ccc8c(c7)c7c9ccccc9c9c%10ccccc%10sc9c7n8-c7ccc8ccccc8c7)c7ccccc67)cc5)cc4c4c5ccccc5c5c6ccccc6sc5c43)ccc2c1 ; c1ccc(-c2ccc(-n3c4ccc(-c5ccc(-c6ccc7c(c6)c6c8ccccc8c8c9ccccc9sc8c6n7-c6ccc(-c7ccccc7)cc6)c6ccccc56)cc4c4c5ccccc5c5c6ccccc6sc5c43)cc2)cc1 ; c1ccc(-n2c3ccc(-c4ccc(-c5ccc(-c6ccc7c(c6)c6c8ccccc8c8c9ccccc9sc8c6n7-c6ccccc6)c6ccccc56)c5ccccc45)cc3c3c4ccccc4c4c5ccccc5sc4c32)cc1]

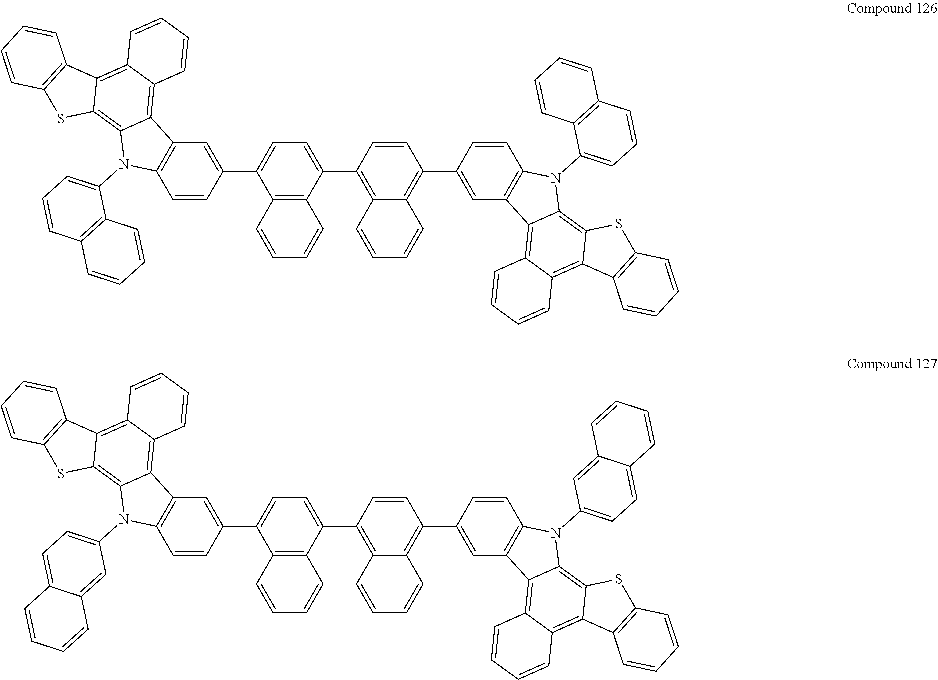 [SMILES: c1ccc2c(-n3c4ccc(-c5ccc(-c6ccc(-c7ccc8c(c7)c7c9ccccc9c9c%10ccccc%10sc9c7n8-c7cccc8ccccc78)c7ccccc67)c6ccccc56)cc4c4c5ccccc5c5c6ccccc6sc5c43)cccc2c1 ; c1ccc2cc(-n3c4ccc(-c5ccc(-c6ccc(-c7ccc8c(c7)c7c9ccccc9c9c%10ccccc%10sc9c7n8-c7ccc8ccccc8c7)c7ccccc67)c6ccccc56)cc4c4c5ccccc5c5c6ccccc6sc5c43)ccc2c1]

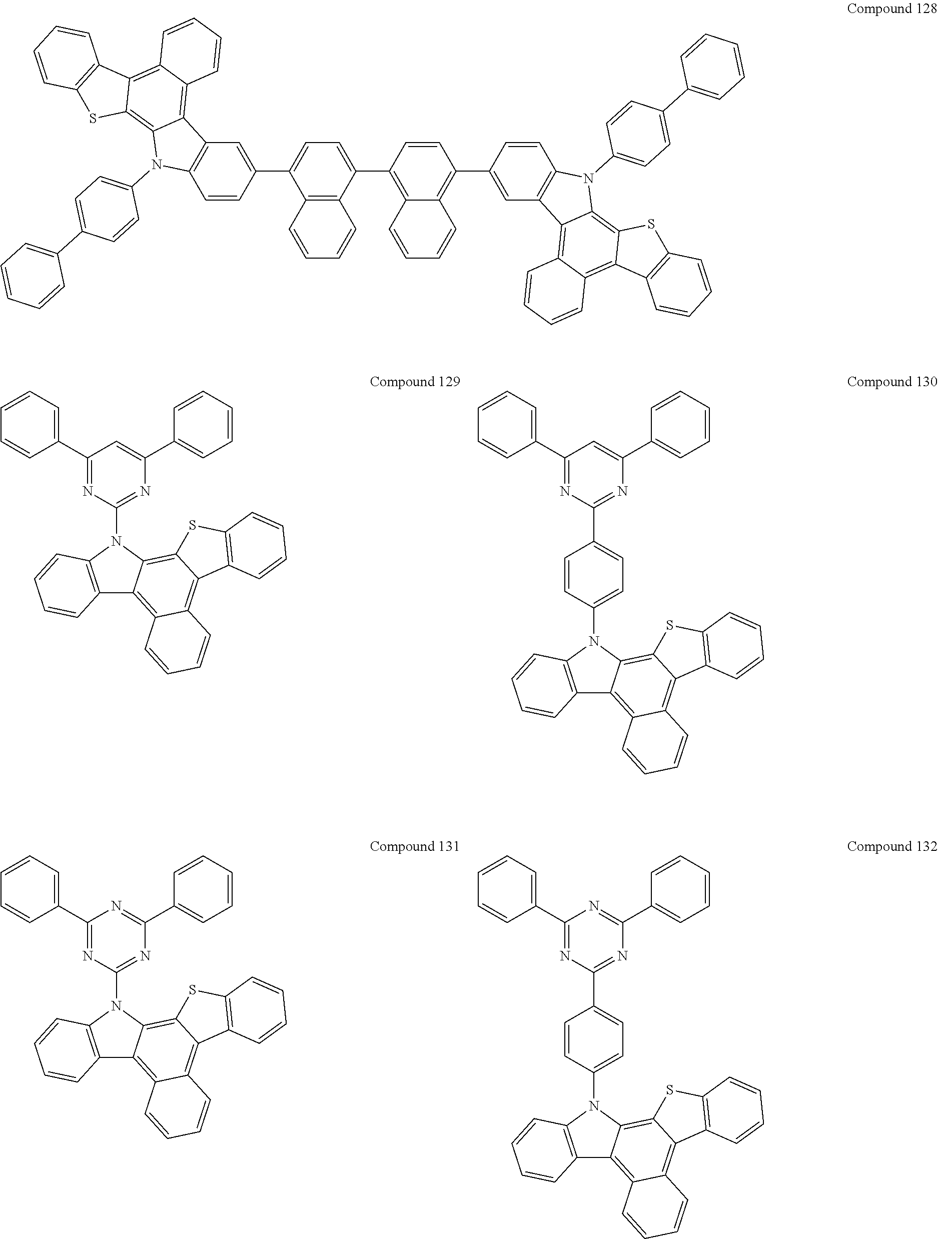 [SMILES: c1ccc(-c2ccc(-n3c4ccc(-c5ccc(-c6ccc(-c7ccc8c(c7)c7c9ccccc9c9c%10ccccc%10sc9c7n8-c7ccc(-c8ccccc8)cc7)c7ccccc67)c6ccccc56)cc4c4c5ccccc5c5c6ccccc6sc5c43)cc2)cc1 ; c1ccc(-c2cc(-c3ccccc3)nc(-n3c4ccccc4c4c5ccccc5c5c6ccccc6sc5c43)n2)cc1 ; c1ccc(-c2cc(-c3ccccc3)nc(-c3ccc(-n4c5ccccc5c5c6ccccc6c6c7ccccc7sc6c54)cc3)n2)cc1 ; c1ccc(-c2nc(-c3ccccc3)nc(-n3c4ccccc4c4c5ccccc5c5c6ccccc6sc5c43)n2)cc1 ; c1ccc(-c2nc(-c3ccccc3)nc(-c3ccc(-n4c5ccccc5c5c6ccccc6c6c7ccccc7sc6c54)cc3)n2)cc1]

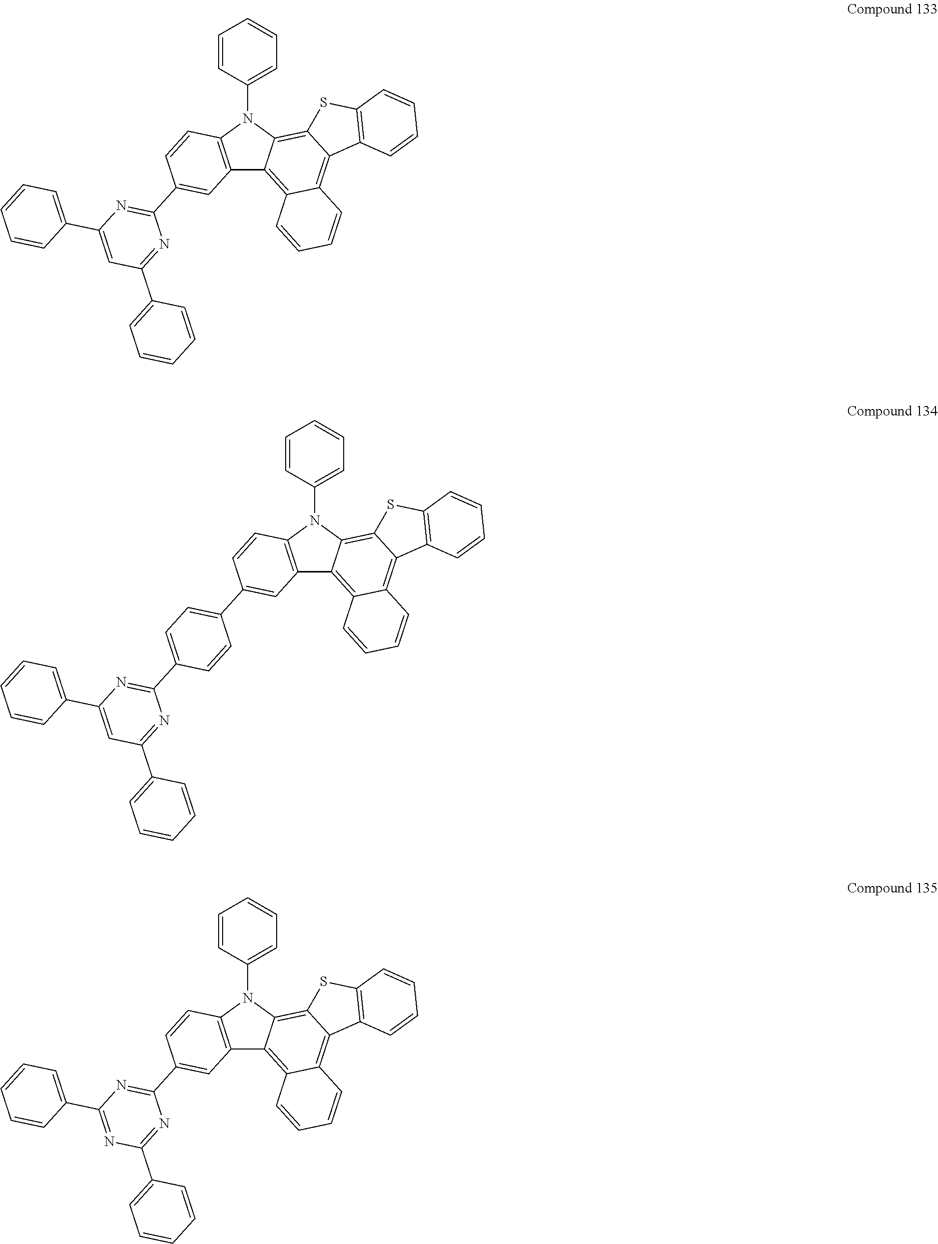 [SMILES: c1ccc(-c2cc(-c3ccccc3)nc(-c3ccc4c(c3)c3c5ccccc5c5c6ccccc6sc5c3n4-c3ccccc3)n2)cc1 ; c1ccc(-c2cc(-c3ccccc3)nc(-c3ccc(-c4ccc5c(c4)c4c6ccccc6c6c7ccccc7sc6c4n5-c4ccccc4)cc3)n2)cc1 ; c1ccc(-c2nc(-c3ccccc3)nc(-c3ccc4c(c3)c3c5ccccc5c5c6ccccc6sc5c3n4-c3ccccc3)n2)cc1]

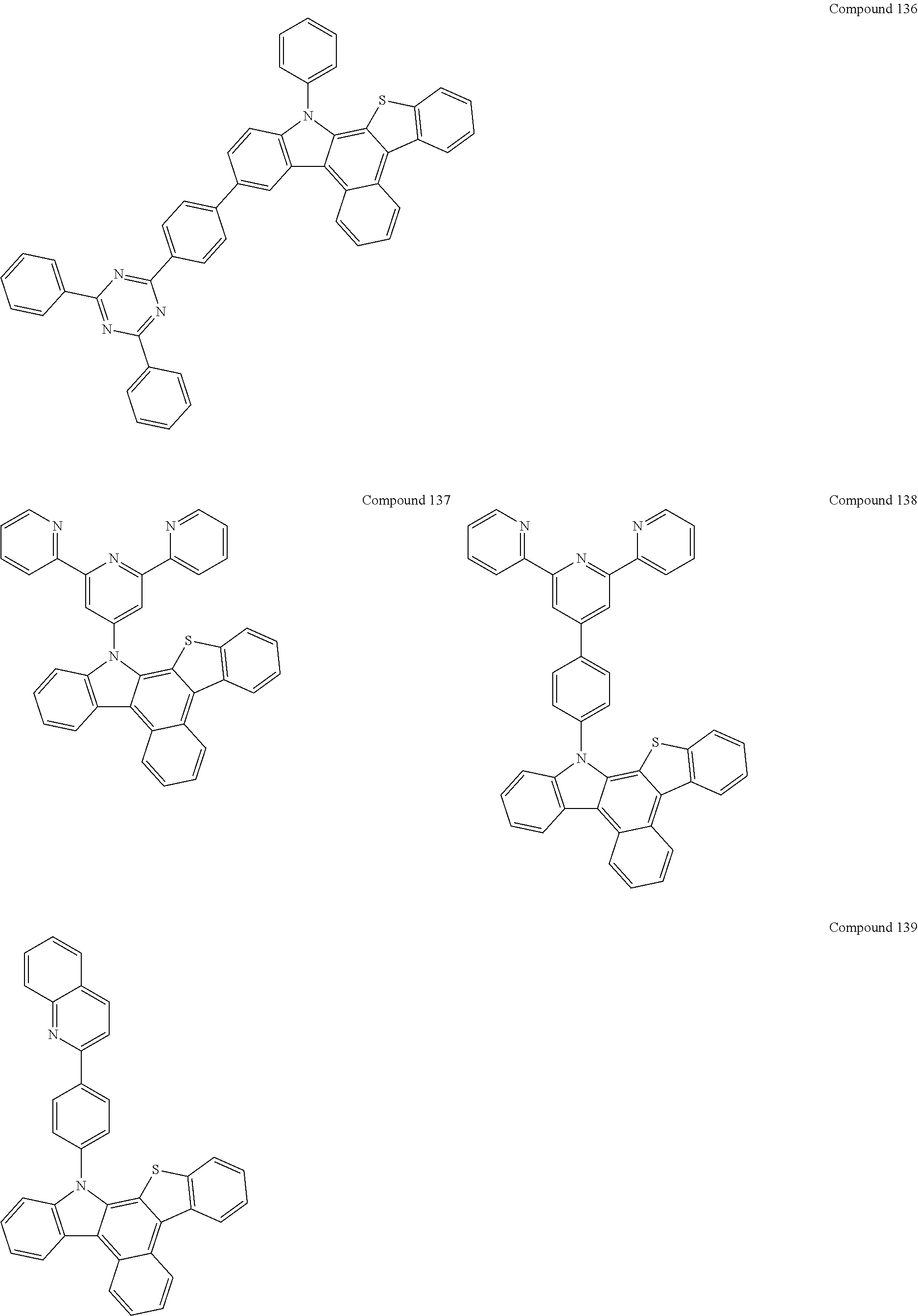 [SMILES: c1ccc(-c2nc(-c3ccccc3)nc(-c3ccc(-c4ccc5c(c4)c4c6ccccc6c6c7ccccc7sc6c4n5-c4ccccc4)cc3)n2)cc1 ; c1ccc(-c2cc(-n3c4ccccc4c4c5ccccc5c5c6ccccc6sc5c43)cc(-c3ccccn3)n2)nc1 ; c1ccc(-c2cc(-c3ccc(-n4c5ccccc5c5c6ccccc6c6c7ccccc7sc6c54)cc3)cc(-c3ccccn3)n2)nc1 ; c1ccc2nc(-c3ccc(-n4c5ccccc5c5c6ccccc6c6c7ccccc7sc6c54)cc3)ccc2c1]

In an embodiment, the display device may further include a second host layer provided between the hole transport region and the emission layer and including a third host. The third host may be represented by Formula 1.

In an embodiment, the emission layer may include a first sub emission layer including the first host and the dopant, a third host layer provided on the first sub emission layer and including a fourth host, and a second sub emission layer provided on the third host layer and including the first host and the dopant. The fourth host may be represented by Formula 1.

### BRIEF DESCRIPTION OF THE DRAWINGS

Features will be apparent to those of skill in the art by describing in detail exemplary embodiments with reference to the attached drawings in which:

FIGS. 1A and 1B illustrate schematic cross-sectional views of organic light emitting devices according to embodiments;

FIG. 2 illustrates a schematic cross-sectional view of an organic light emitting device according to an embodiment;

FIG. 3 illustrates a schematic cross-sectional view of an organic light emitting device according to an embodiment;

FIG. 4 illustrates a schematic perspective view of a display device according to an embodiment;

FIG. 5 illustrates a circuit diagram of one pixel included in a display device according to an embodiment;

FIG. 6 illustrates a plan view of one pixel included in a display device according to an embodiment; and

FIGS. 7A, 7B and 7C illustrate schematic cross-sectional views taken along line I-I′ in FIG. 6.

### DETAILED DESCRIPTION

The objects, other objects, features, and advantages will be easily understood from example embodiments below with reference to the accompanying drawings. The embodiments may, however, be embodied in different forms and should not be construed as limited. Rather, these embodiments are provided so that this description will be thorough and complete, and will fully convey the scope to those skilled in the art.

Like reference numerals refer to like elements throughout. In the drawings, the dimensions of structures may be exaggerated for clarity of illustration. It will be understood that, although the terms first, second, etc. may be used herein to describe various elements, these elements should not be limited by these terms. These terms are only used to distinguish one element from another element. Thus, a first element could be termed a second element without departing from the teachings herein. Similarly, a second element could be termed a first element. As used herein, the singular forms are intended to include the plural forms as well, unless the context clearly indicates otherwise. Herein, the term “or” is not an exclusive term.

It will be further understood that the terms, e.g., “comprises,” “includes” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof. It will also be understood that when a layer, a film, a region, a plate, etc. is referred to as being ‘on’ another part, it can be directly on the other part, or intervening layers may also be present. On the contrary, it will be understood that when a layer, a film, a region, a plate, etc. is referred to as being ‘under’ another part, it can be directly under, and one or more intervening layers may also be present.

Hereinafter, an organic light emitting device according to an embodiment will be explained.

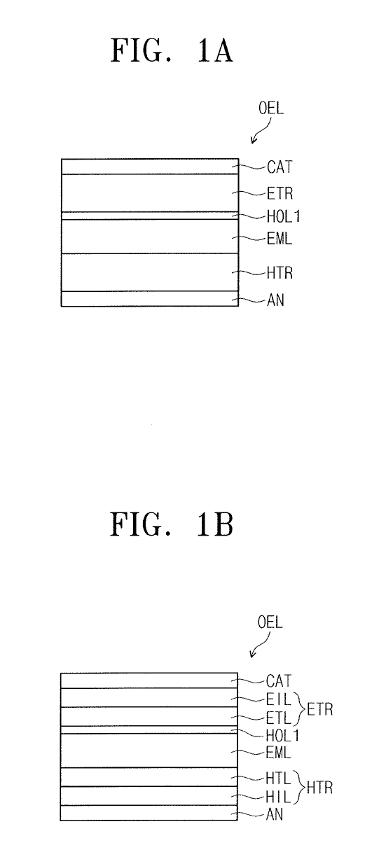

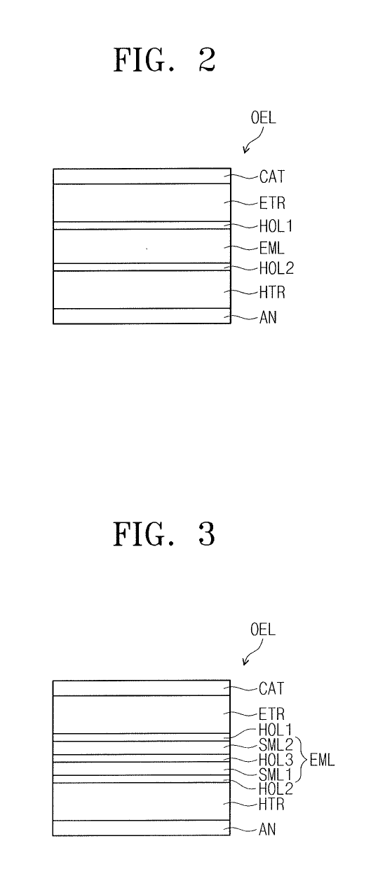

FIGS. 1A and 1B illustrate schematic cross-sectional views of organic light emitting devices according to embodiments. FIG. 2 illustrates a schematic cross-sectional view of an organic light emitting device according to an embodiment. FIG. 3 illustrates a schematic cross-sectional view of an organic light emitting device according to an embodiment.

Referring to FIGS. 1A, 1B, 2, and 3, an organic light emitting device OEL according to an embodiment may include an anode AN, a hole transport region HTR, an emission layer EML, a first host layer HOL1, an electron transport region ETR, and a cathode CAT.

The anode AN has conductivity. The anode AN may be a pixel electrode or an anode. The anode AN may be a transmissive electrode, a transflective electrode, or a reflective electrode. When the anode AN is the transmissive electrode, the anode AN may be formed using a transparent metal oxide such as indium tin oxide (ITO), indium zinc oxide (IZO), zinc oxide (ZnO), or indium tin zinc oxide (ITZO). When the anode AN is a transflective electrode or a reflective electrode, the anode AN may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). Also, the anode AN may include a plurality of layers including a reflective layer or a transflective layer formed using the above materials, and a transmissive layer formed using ITO, IZO, ZnO, or ITZO.

The hole transport region HTR may be provided on the anode AN. The hole transport region HTR may include at least one of a hole injection layer HIL, a hole transport layer HTL, a buffer layer, or an electron blocking layer.

The hole transport region HTR may have a single layer formed using a single material, a single layer formed using a plurality of different materials, or a multilayer structure including a plurality of layers formed using a plurality of different materials.

For example, the hole transport region HTR may have the structure of a single layer such as a hole injection layer HIL, and a hole transport layer HTL, and may have a structure of a single layer formed using a hole injection material and a hole transport material. In addition, the hole transport region HTR may have a structure of a single layer formed using a plurality of different materials, or a structure laminated from the anode AN of hole injection layer HIL/hole transport layer HTL, hole injection layer HIL/hole transport layer HTL/buffer layer, hole injection layer HIL/buffer layer, hole transport layer HTL/buffer layer, or hole injection layer HIL/hole transport layer HTL/electron blocking layer, without limitation.

The hole transport region HTR may be formed using various methods such as a vacuum deposition method, a spin coating method, a cast method, a Langmir-Blodgett (LB) method, an inkjet printing method, a laser printing method, and a laser induced thermal imaging (LITI) method.

When the hole transport region HTR includes the hole injection layer HIL, the hole transport region HTR may include a phthalocyanine compound such as copper phthalocyanine, N,N′-diphenyl-N,N′-bis-[4-(phenyl-m-tolyl-amino)-phenyl]-biphenyl-4,4″-diamine (DNTPD), 4,4′,4″-tris(3-methylphenylphenylamino)triphenylamine (m-MTDATA), 4,4′,4-tris(N,N-diphenylamino)triphenylamine (TDATA) 4,4″,4″-tris{N-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), etc., without limitation.

When the hole transport region HTR includes the hole transport layer HTL, the hole transport region HTR may include a carbazole derivative such as N-phenylcarbazole and polyvinyl carbazole, a fluorine-based derivative, N,N′-bis(3-methylphenyl)-N,N′-diphenyl-[1,1-biphenyl]-4,4′-diamine (TPD), a triphenylamine-based derivative such as 4,4′,4″-tris(N-carbazolyl)triphenylamine (TCTA), N,N′-di(1-naphthyl)-N,N′-diphenylbenzidine (NPB), 4,4′-cyclohexylidene bis[N,N-bis(4-methylphenyl)benzeneamine] (TAPC), etc., without limitation.

The thickness of the hole transport region HTR may be from about 100 Å to about 10,000 Å, for example, from about 100 Å to about 1,000 Å. When the hole transport region HTR includes both the hole injection layer HIL and the hole transport layer HTL, the thickness of the hole injection layer HIL may be from about 100 Å to about 10,000 Å, for example, from about 100 Å to about 1,000 Å, and the thickness of the hole transport layer HTL may be from about 50 Å to about 2,000 Å, for example, from about 100 Å to about 1,500 Å. When the thicknesses of the hole transport region HTR, the hole injection layer HIL, and the hole transport layer HTL satisfy the above-described ranges, satisfactory hole transport properties may be obtained without substantial increase of a driving voltage.

The hole transport region HTR may further include a charge generating material other than the above-described materials to improve conductivity. The charge generating material may be dispersed in the hole transport region HTR uniformly or non-uniformly. The charge generating material may be, for example, a p-dopant. The p-dopant may be one of a quinone derivative, a metal oxide, or a cyano group-containing compound, without limitation. For example, non-limiting examples of the p-dopant may include a quinone derivative such as tetracyanoquinodimethane (TCNQ), and 2,3,5,6-tetrafluoro-tetracyanoquinodimethane (F4-TCNQ), a metal oxide such as tungsten oxide, and molybdenum oxide, without limitation.

As described above, the hole transport region HTR may further include one of the buffer layer and the electron blocking layer other than the hole injection layer HIL and the hole transport layer HTL. The buffer layer may compensate an optical resonance distance according to the wavelength of light emitted from the emission layer EML and increase light emission efficiency. Materials included in the hole transport region HTR may be used as materials included in the buffer layer. The electron blocking layer is a layer preventing electron injection from the electron transport region ETR to the hole transport region HTR.

The emission layer EML may be provided on the hole transport region HTR. The thickness of the emission layer EML may be from about 350 Å to about 450 Å. The emission layer EML may include a first host and a dopant. The first host may be the same as or different from a second host that will be explained later.

The concentration of the dopant included in the emission layer EML may be uniform or non-uniform in the emission layer EML. For example, if the concentration of the dopant in the emission layer EML is non-uniform, the concentration distribution of the dopant in the emission layer EML may have one peak. For example, the concentration of the dopant may be higher in portions toward the central line of the emission layer EML when compared to each portion toward the first host layer HOL1 and the hole transport region HTR. However, the concentration of the dopant may be lower in portions toward the central line of the emission layer EML when compared to each portion of the first host layer HOL1 and the hole transport region HTR, without limitation. The central line of the emission layer EML may be a line passing the center of gravity of the emission layer EML and in parallel to a ground.

If the concentration of the dopant in the emission layer EML is non-uniform, the concentration distribution of the dopant in the emission layer EML may have at least two peaks. For example, the concentration of the dopant may be higher in portions toward the first sub central line and the second sub central line of the emission layer EML than each portion of the first host layer HOL1, the central line, and the hole transport region HTR. However, the concentration of the dopant may be lower in portions toward the first sub central line and the second sub central line of the emission layer EML than each portion of the first host layer HOL1, the central line, and the hole transport region HTR, without limitation. The first sub central line may be a line passing the middle of one side of the emission layer EML making contact with the first host layer HOL1 and the central line, in parallel to a ground. The second sub central line may be a line passing the center of one side of the emission layer EML making contact with the hole transport region HTR and the central line, in parallel to a ground.

The emission layer EML may emit red light. The emission layer EML may emit one of green light, blue light, white light, yellow light, or cyan light, without limitation.

When the first host and the second host are different, the first host may be any material commonly used without specific limitation and may include, for example, tris(8-hydroxyquinolino)aluminum (Alq3), 4,4′-bis(N-carbazolyl)-1,1′-biphenyl (CBP), poly(n-vinylcarbazole) (PVK), 9,10-di(naphthaline-2-yl)anthracene (ADN), 4,4′,4″-tris(carbazole-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), etc.

When the emission layer EML emits red light, the emission layer EML may further include a phosphorescent material including, for example, tris(dibenzoylmethanato)phenanthoroline europium (PBD:Eu(DBM)3(Phen)), or perylene. When the emission layer EML emits red light, the dopant included in the emission layer EML may be selected from a metal complex or an organometallic complex such as bis(1-phenylisoquinoline)acetylacetonate iridium (PIQIr(acac)), bis(1-phenylquinoline)acetylacetonate iridium (PQIr(acac), tris(1-phenylquinoline)iridium (PQIr), and octaethylporphyrin platinum (PtOEP).

When the emission layer EML emits green light, the emission layer EML may include a phosphorescent material including, for example, tris(8-hydroxyquinolino)aluminum (Alq3). When the emission layer EML emits green light the dopant included in the emission layer EML may be selected from a metal complex or an organometallic complex such as fac-tris(2-phenylpyridine)iridium (Ir(ppy)3).

When the emission layer EML emits blue light, the emission layer EML may further include a phosphorescent material including at least one selected from the group consisting of, for example, spiro-DPVBi (DPVBi), spiro-6P, distyryl-benzene (DSB), distyryl-arylene (DSA), a polyfluorene (PFO)-based polymer, and a poly(p-phenylene vinylene) (PPV)-based polymer. When the emission layer EML emits blue light, the dopant included in the emission layer EML may be selected from a metal complex or an organometallic complex such as (4,6-F2ppy)₂Irpic. The emission layer EML will be described in detail hereinafter.

The first host layer HOL1 may be provided on the emission layer EML. The first host layer HOL1 may include a second host. The first host layer HOL1 may not include a dopant. The first host layer HOL1 may not include the dopant included in the emission layer EML and a dopant different from the dopant included in the emission layer EML. The second host may be different from or the same as the first host. The second host may be a compound represented by the following Formula 1.

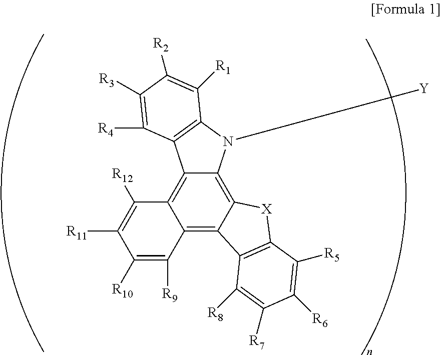

In Formula 1, R₁, R₂, R₃, R₄, R₅, R₆, R₇, R₈, R₉, R₁₀, R₁₁, and R₁₂ may each independently be or include, e.g., a hydrogen atom, a halogen atom, a cyano group, an alkoxy group, a thiol group, a substituted or unsubstituted alkyl group having 1 to 50 carbon atoms, a substituted or unsubstituted alkoxy group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphorus, or silicon, a substituted or unsubstituted heteroaryl group having 5 to 60 carbon atoms and including at least one of sulfur, nitrogen, oxygen, phosphorus, or silicon, or a substituted or unsubstituted heteroaryloxy group having 5 to 60 carbon atoms and including at least one of sulfur, nitrogen, oxygen, phosphorus, or silicon. X may be, e.g., sulfur, oxygen, or silicon. Y may be or may include, e.g., a hydrogen atom, a halogen atom, a cyano group, an alkoxy group, a thiol group, a substituted or unsubstituted alkyl group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphorus, or silicon, a substituted or unsubstituted heteroaryl group having 5 to 60 carbon atoms and including at least one of sulfur, nitrogen, oxygen, phosphorus, or silicon, or a substituted or unsubstituted heteroaryloxy group having 5 to 60 carbon atoms and including at least one of sulfur, nitrogen, oxygen, phosphorus, or silicon. n may be, e.g., an integer of 1 to 3.

In the description, the terms “substituted or unsubstituted” corresponds or refers to substituted or unsubstituted with at least one substituent selected from deuterium, a halogen group, a nitrile group, an amino group, a phosphine oxide group, an alkoxy group, an aryloxy group, an alkylthioxy group, an arylthioxy group, an alkylsulfoxy group, an arylsulfoxy group, a silyl group, a boron group, an alkyl group, a cycloalkyl group, an alkenyl group, an aryl group, an aralkyl group, an aralkenyl group, an alkylaryl group, an alkylamine group, a heteroarylamine group, an arylamine group, and a heterocyclic group, or corresponds to substituted or unsubstituted with a substituent obtained by connecting at least two substituents of the above-described substituents. For example, the substituent obtained by connecting at least two substituents may be a biphenyl group. For example, the biphenyl group may be an aryl group or may be interpreted as a substituent obtained by connecting two phenyl groups.

In an implementation, R₁, R₂, R₃, R₄, R₅, R₆, R₇, R₈, R₉, R₁₀, R₁₁, or R₁₂ may be separate or adjacent ones thereof may be combined to form a ring.

In an implementation, the second host may include at least one compound in the following Compound Group 1.

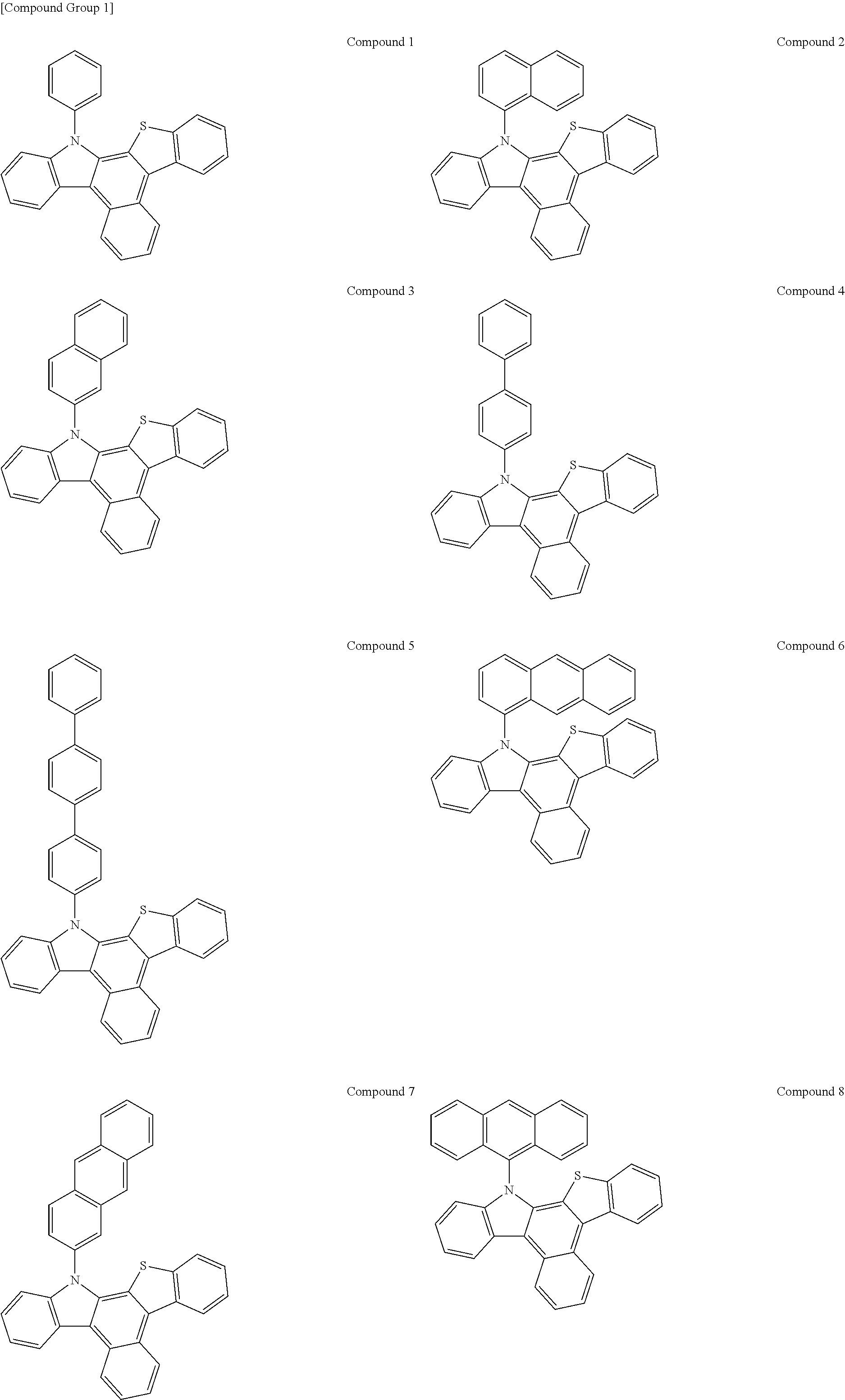

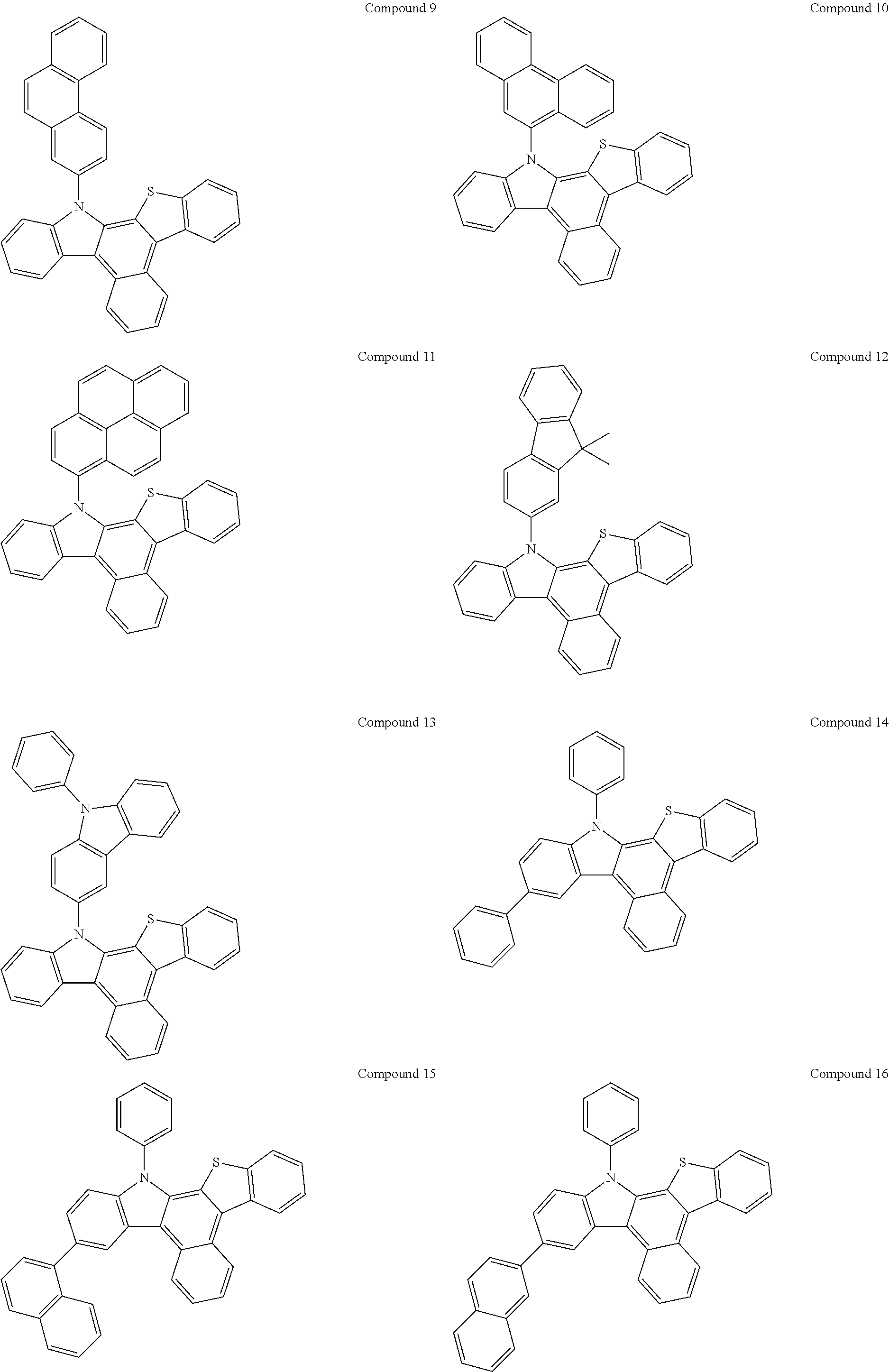

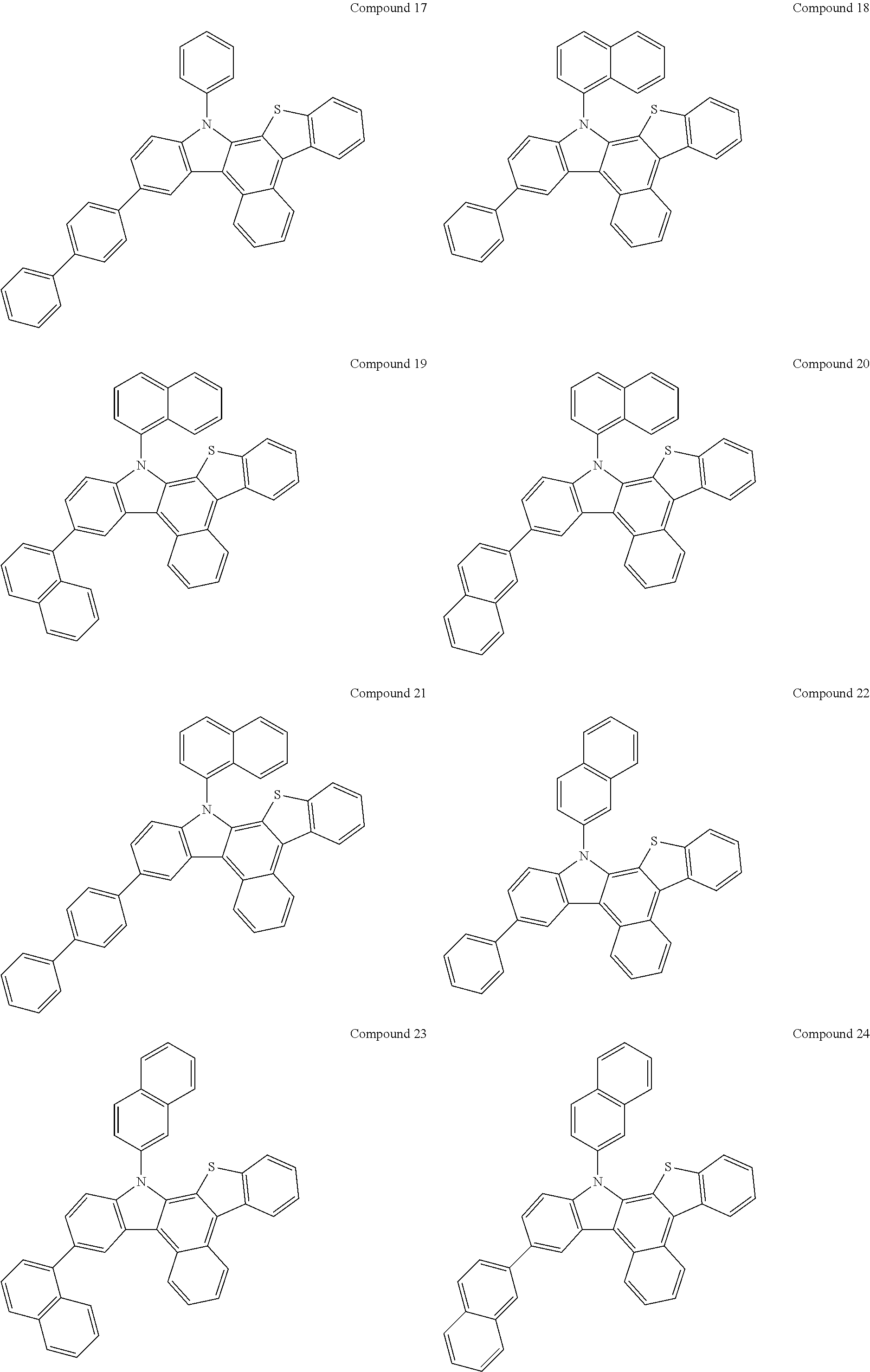

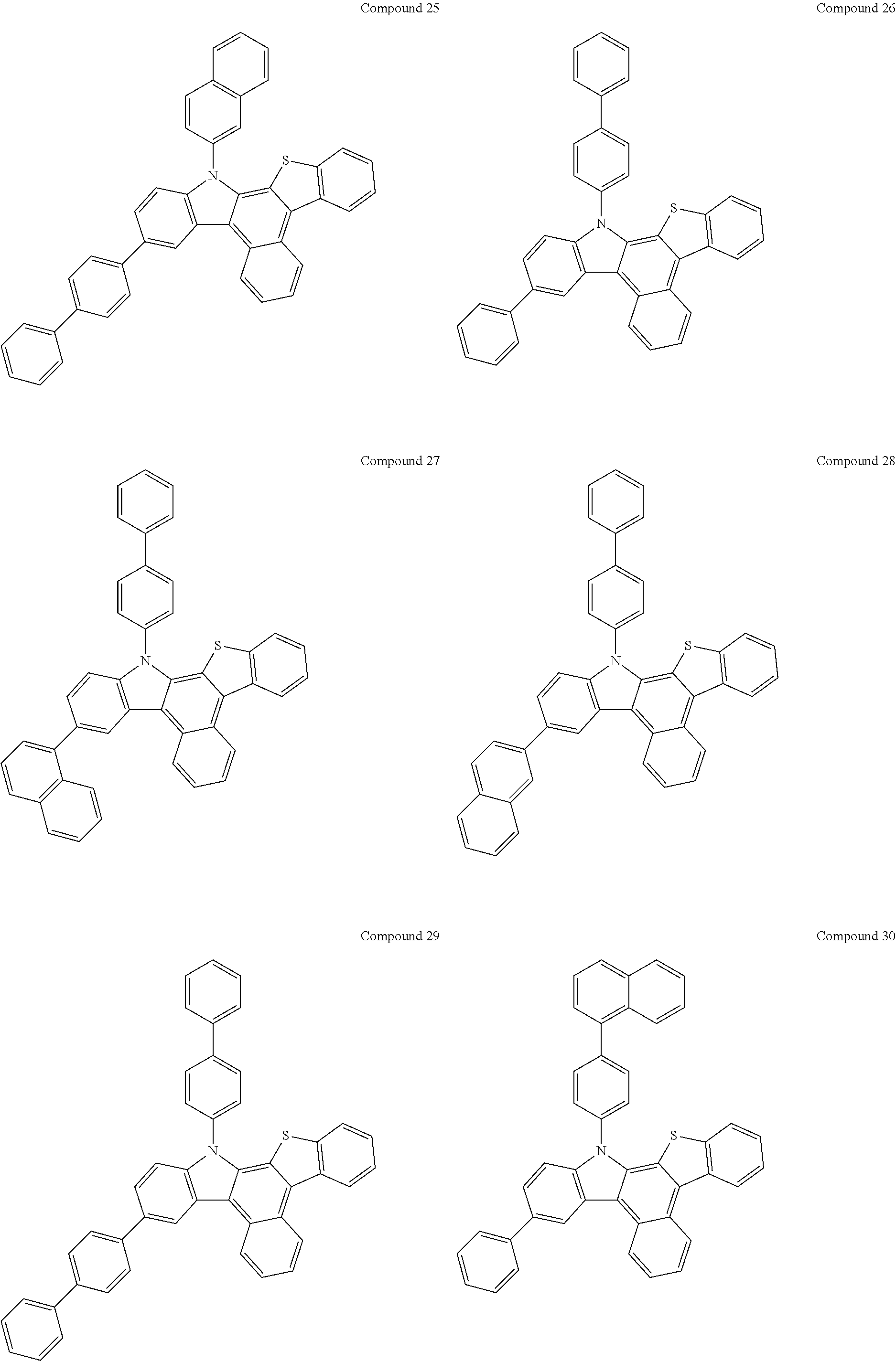 [SMILES: c1ccc(-c2ccc(-c3ccc4c(c3)c3c5ccccc5c5c6ccccc6sc5c3n4-c3ccc4ccccc4c3)cc2)cc1 ; c1ccc(-c2ccc(-n3c4ccc(-c5ccccc5)cc4c4c5ccccc5c5c6ccccc6sc5c43)cc2)cc1 ; c1ccc(-c2ccc(-n3c4ccc(-c5cccc6ccccc56)cc4c4c5ccccc5c5c6ccccc6sc5c43)cc2)cc1 ; c1ccc(-c2ccc(-n3c4ccc(-c5ccc6ccccc6c5)cc4c4c5ccccc5c5c6ccccc6sc5c43)cc2)cc1 ; c1ccc(-c2ccc(-c3ccc4c(c3)c3c5ccccc5c5c6ccccc6sc5c3n4-c3ccc(-c4ccccc4)cc3)cc2)cc1 ; c1ccc(-c2ccc3c(c2)c2c4ccccc4c4c5ccccc5sc4c2n3-c2ccc(-c3cccc4ccccc34)cc2)cc1]

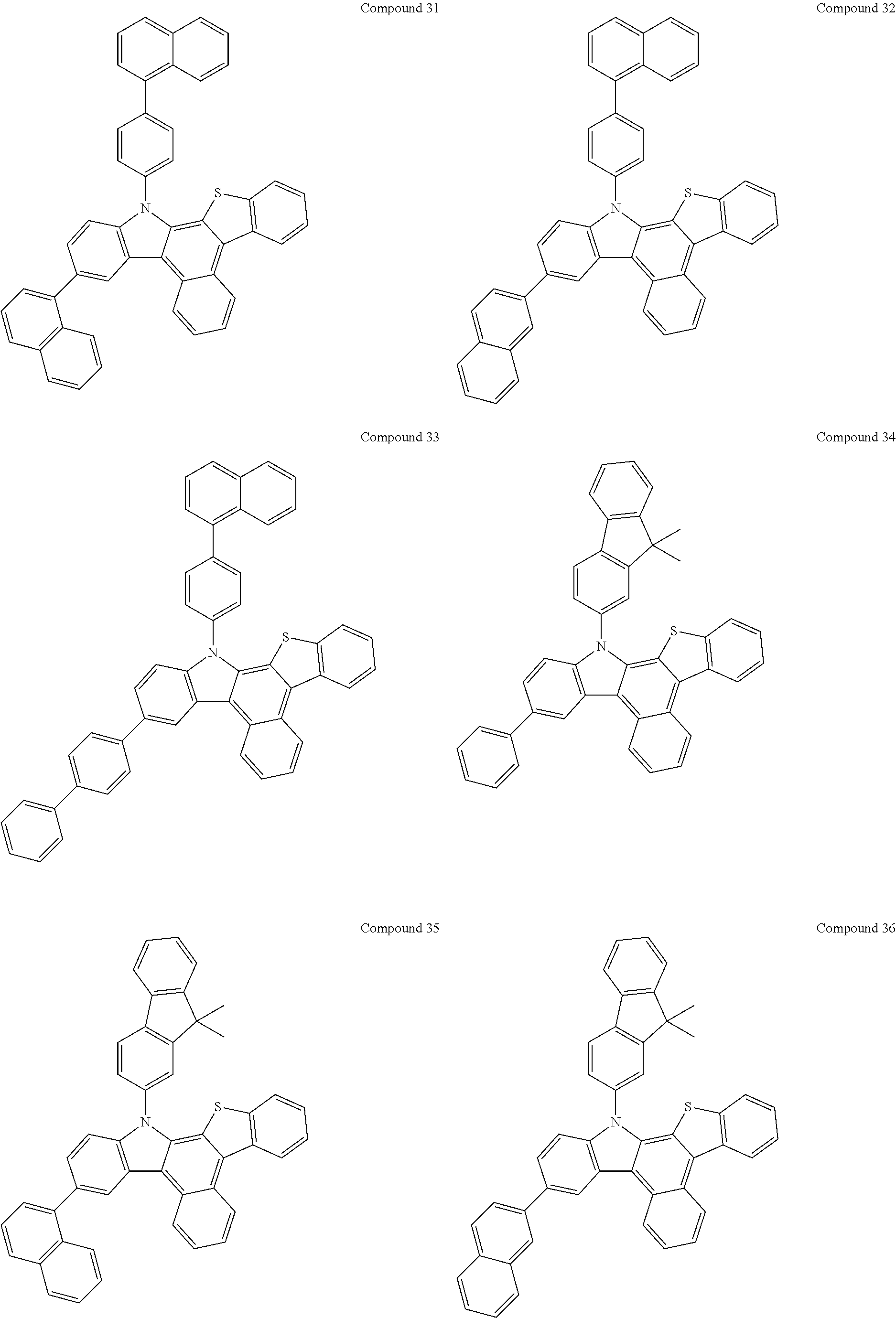 [SMILES: c1ccc2c(-c3ccc(-n4c5ccc(-c6cccc7ccccc67)cc5c5c6ccccc6c6c7ccccc7sc6c54)cc3)cccc2c1 ; c1ccc2cc(-c3ccc4c(c3)c3c5ccccc5c5c6ccccc6sc5c3n4-c3ccc(-c4cccc5ccccc45)cc3)ccc2c1 ; c1ccc(-c2ccc(-c3ccc4c(c3)c3c5ccccc5c5c6ccccc6sc5c3n4-c3ccc(-c4cccc5ccccc45)cc3)cc2)cc1 ; CC1(C)c2ccccc2-c2ccc(-n3c4ccc(-c5ccccc5)cc4c4c5ccccc5c5c6ccccc6sc5c43)cc21 ; CC1(C)c2ccccc2-c2ccc(-n3c4ccc(-c5cccc6ccccc56)cc4c4c5ccccc5c5c6ccccc6sc5c43)cc21 ; CC1(C)c2ccccc2-c2ccc(-n3c4ccc(-c5ccc6ccccc6c5)cc4c4c5ccccc5c5c6ccccc6sc5c43)cc21]

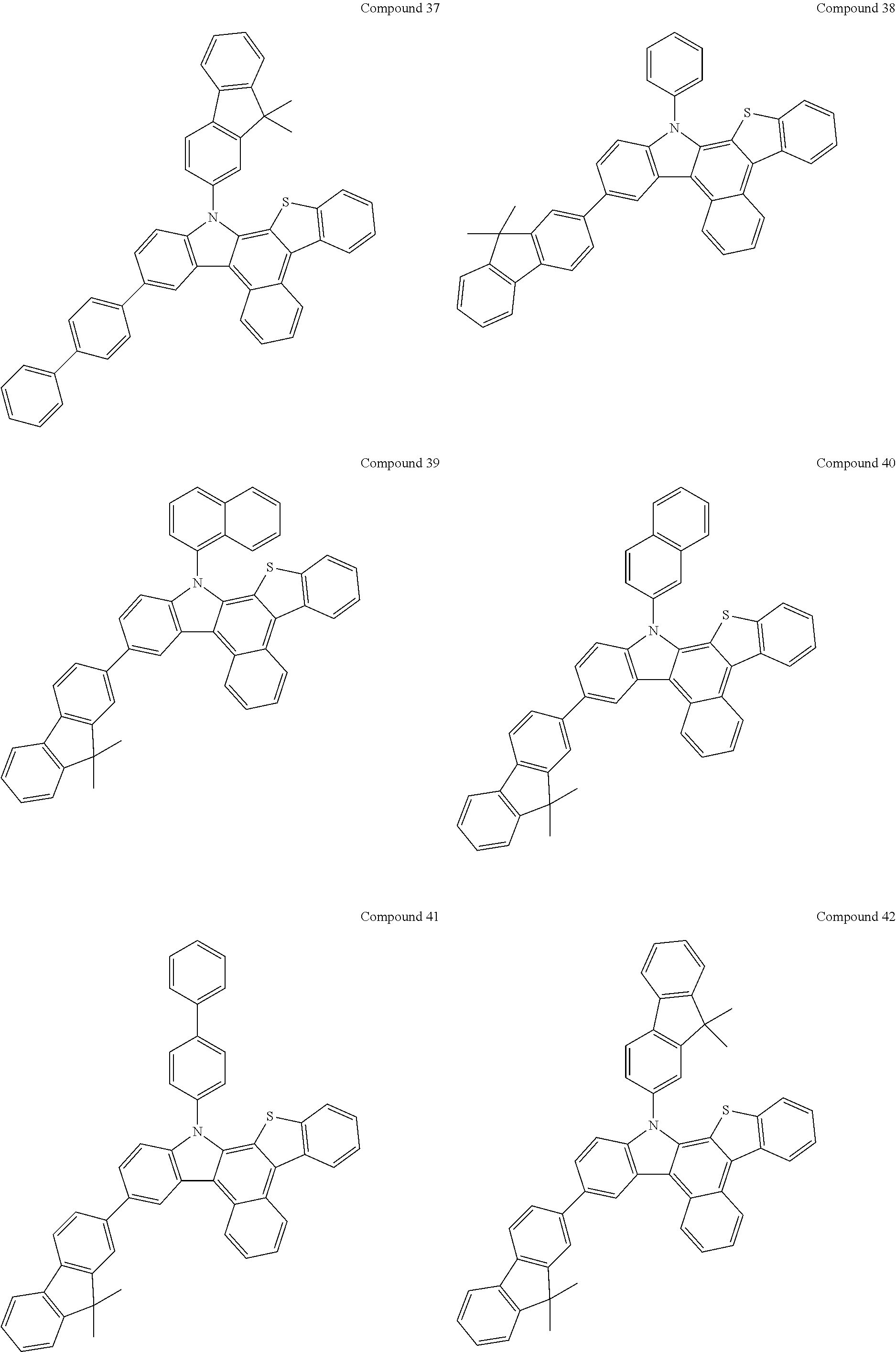

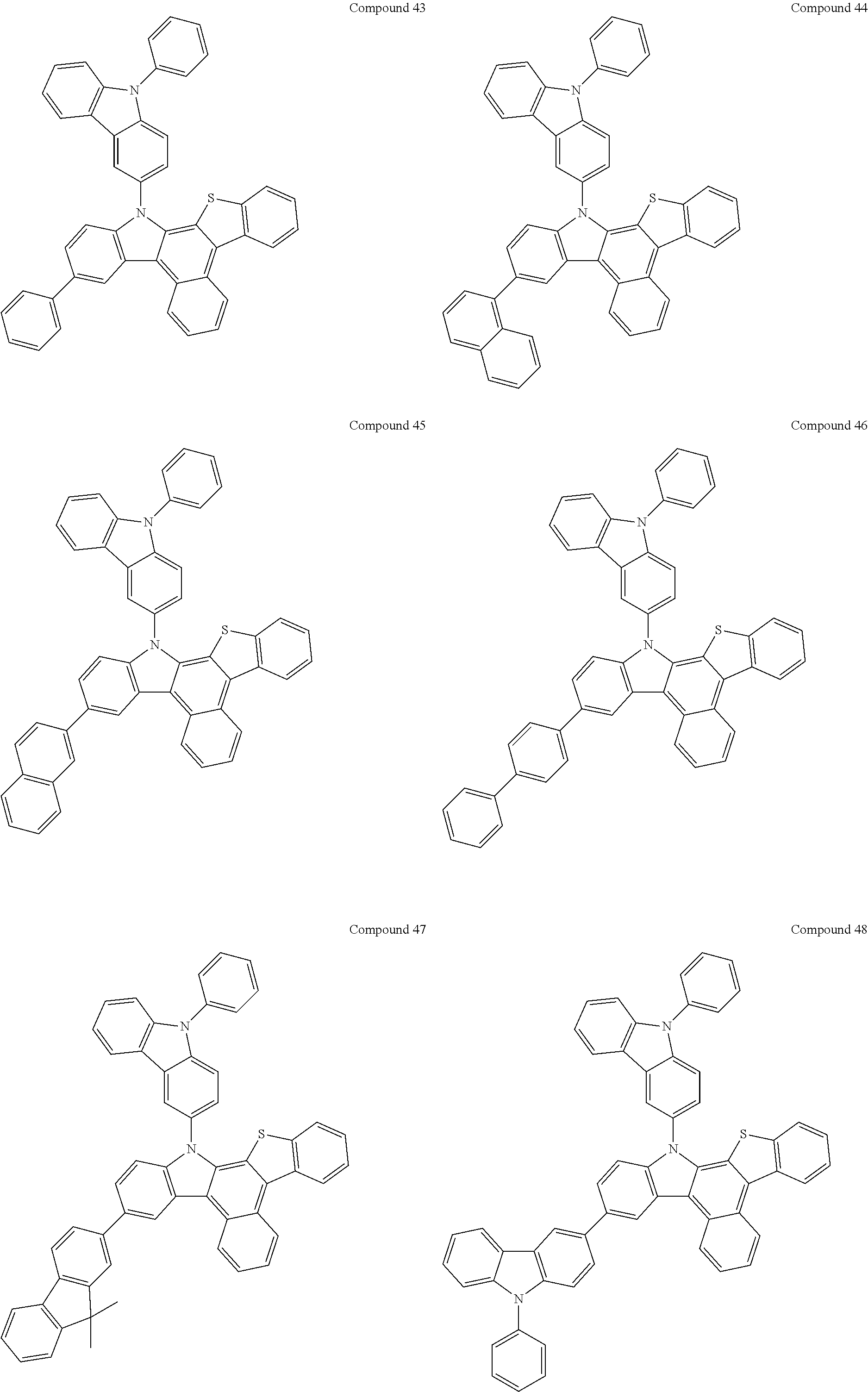

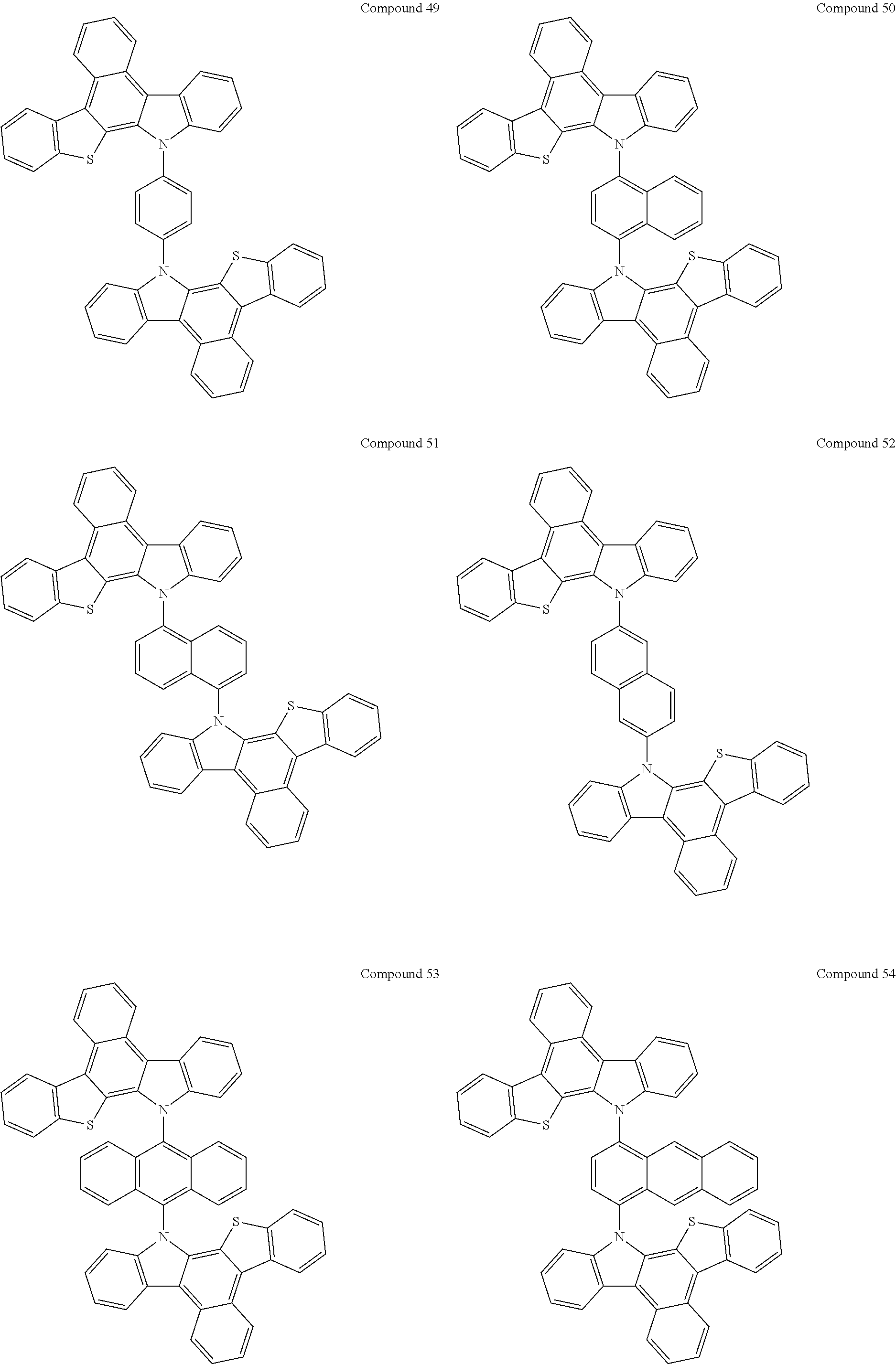

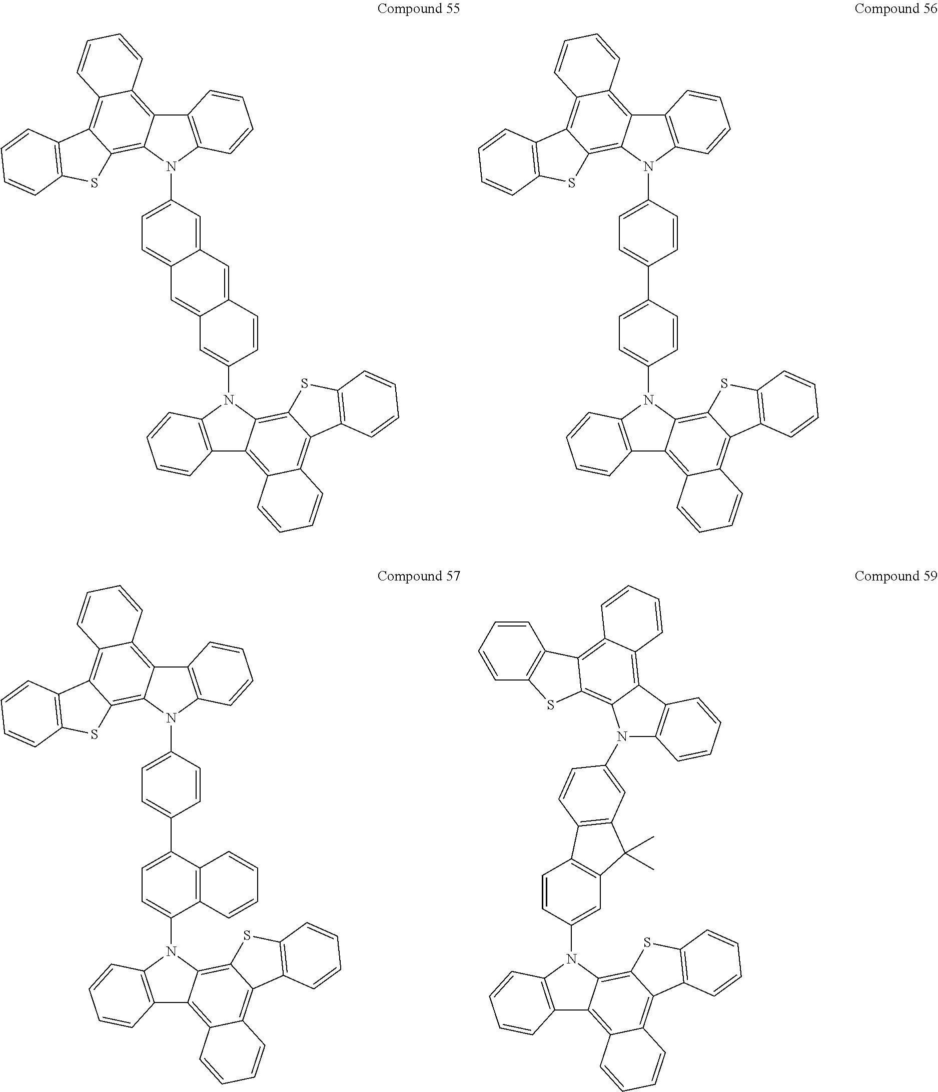 [SMILES: c1ccc2c(c1)sc1c2c2ccccc2c2c3ccccc3n(-c3ccc4cc5cc(-n6c7ccccc7c7c8ccccc8c8c9ccccc9sc8c76)ccc5cc4c3)c12 ; c1ccc2c(c1)sc1c2c2ccccc2c2c3ccccc3n(-c3ccc(-c4ccc(-n5c6ccccc6c6c7ccccc7c7c8ccccc8sc7c65)cc4)cc3)c12 ; c1ccc2c(c1)sc1c2c2ccccc2c2c3ccccc3n(-c3ccc(-c4ccc(-n5c6ccccc6c6c7ccccc7c7c8ccccc8sc7c65)c5ccccc45)cc3)c12 ; CC1(C)c2cc(-n3c4ccccc4c4c5ccccc5c5c6ccccc6sc5c43)ccc2-c2ccc(-n3c4ccccc4c4c5ccccc5c5c6ccccc6sc5c43)cc21]

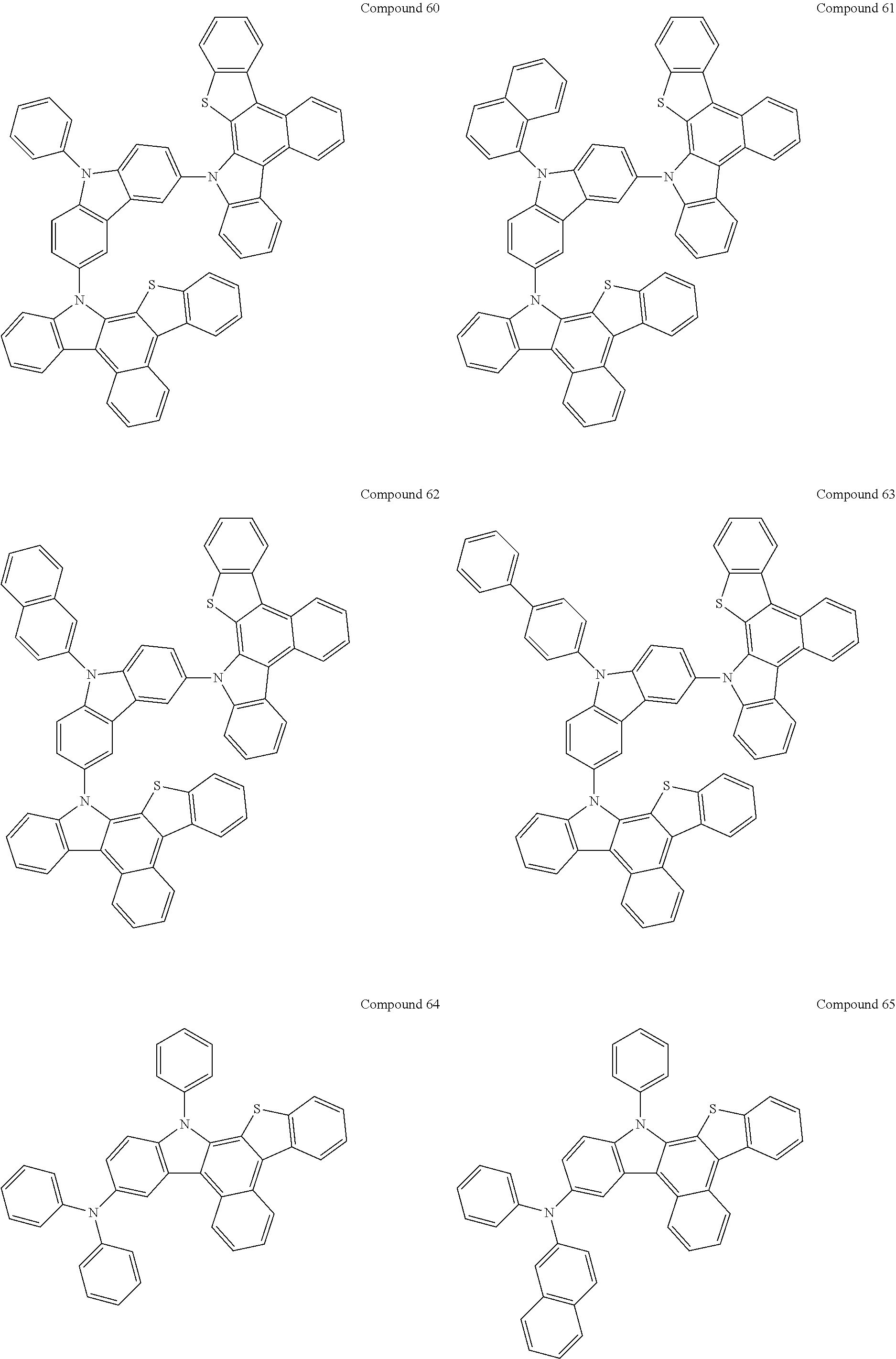

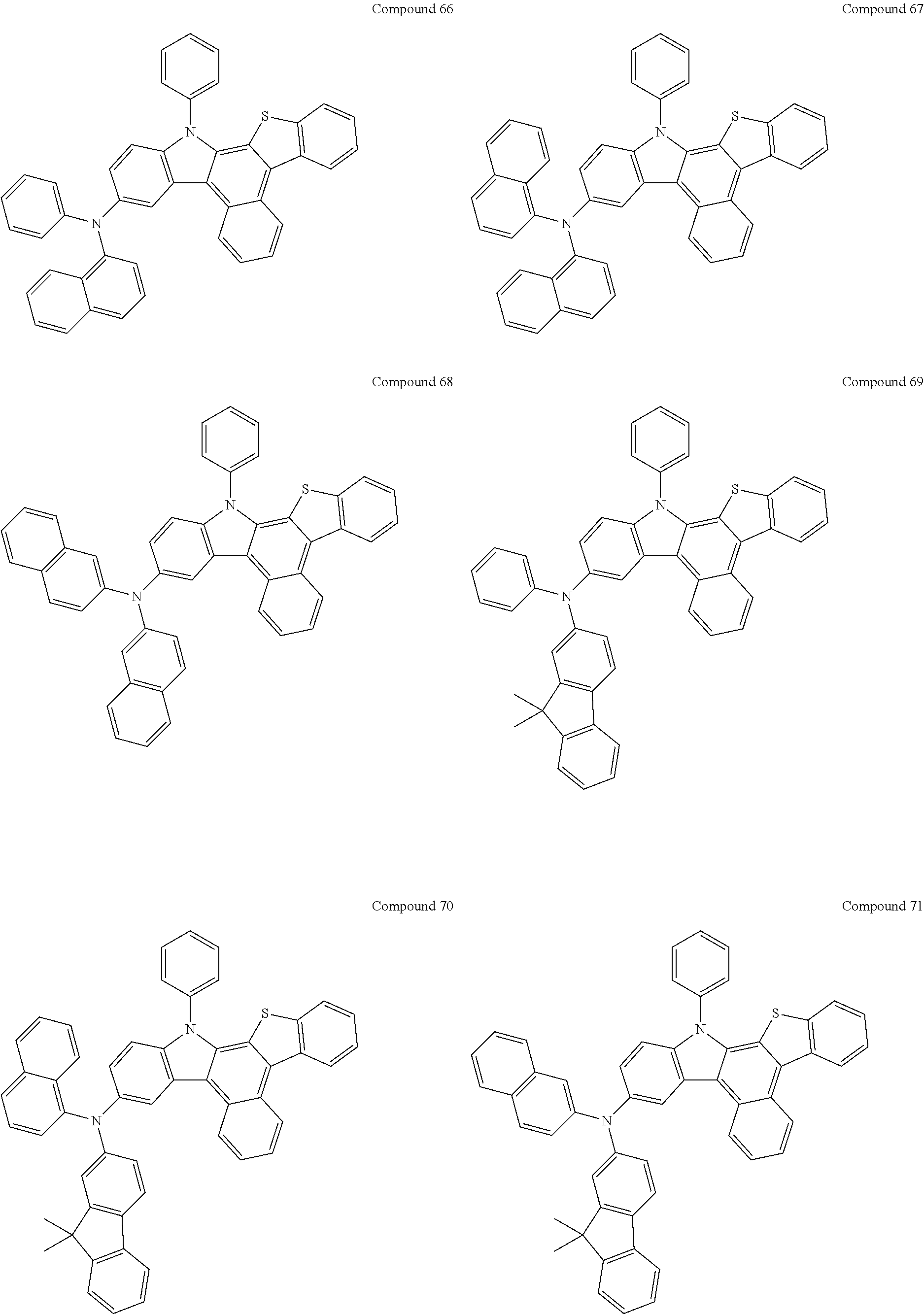

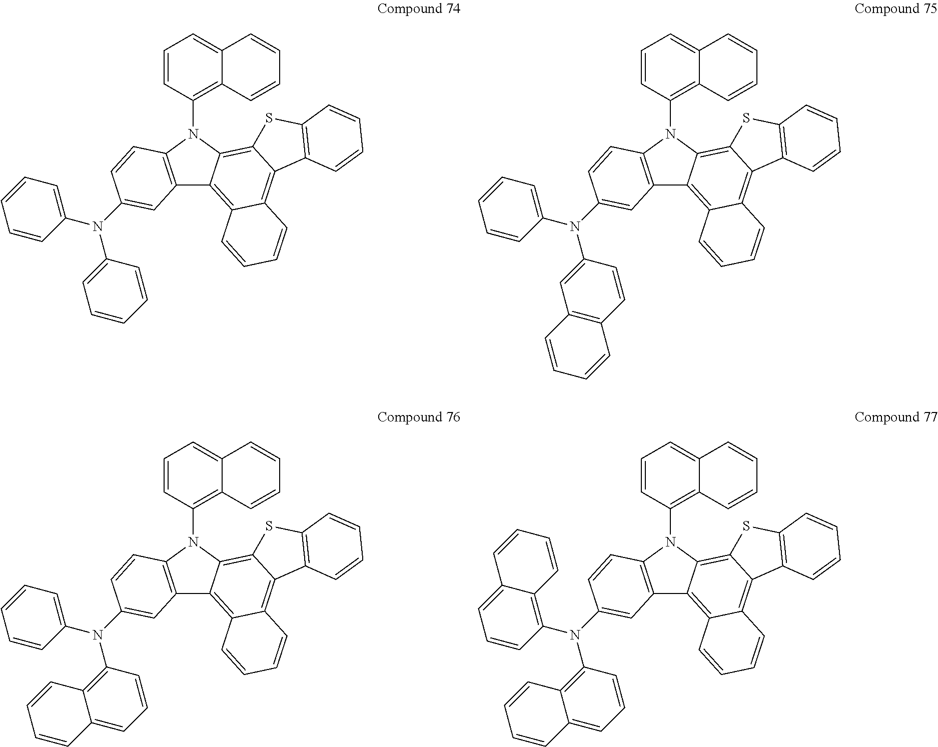 [SMILES: c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1 ; c1ccc(N(c2ccc3c(c2)c2c4ccccc4c4c5ccccc5sc4c2n3-c2cccc3ccccc23)c2cccc3ccccc23)cc1 ; c1ccc2c(N(c3ccc4c(c3)c3c5ccccc5c5c6ccccc6sc5c3n4-c3cccc4ccccc34)c3cccc4ccccc34)cccc2c1]

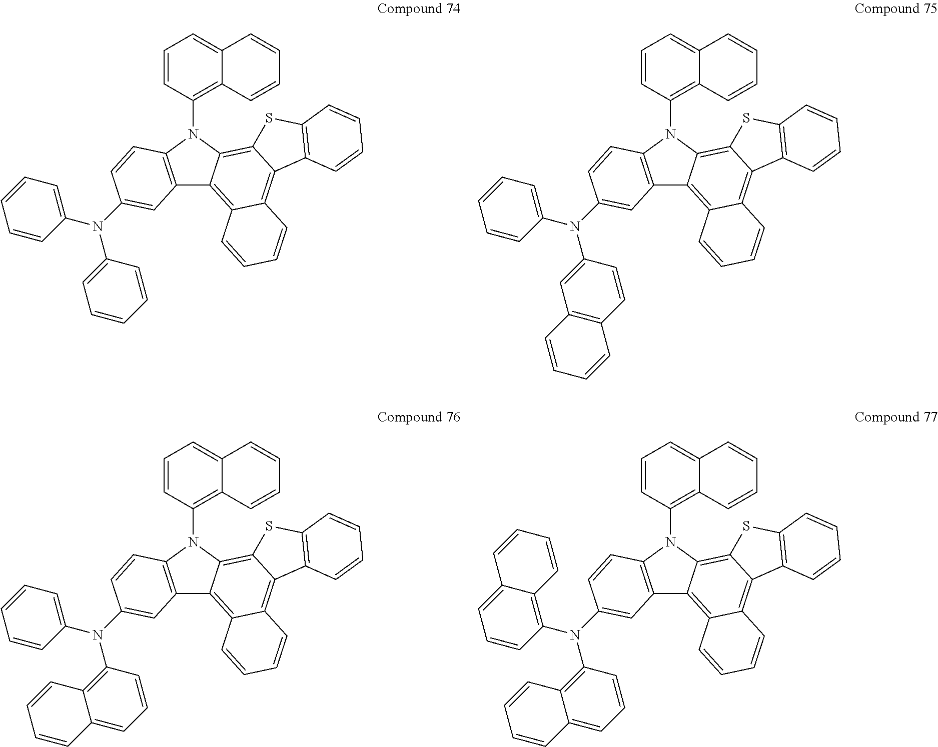 [SMILES: c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1 ; c1ccc(N(c2ccc3c(c2)c2c4ccccc4c4c5ccccc5sc4c2n3-c2cccc3ccccc23)c2cccc3ccccc23)cc1 ; c1ccc2c(N(c3ccc4c(c3)c3c5ccccc5c5c6ccccc6sc5c3n4-c3cccc4ccccc34)c3cccc4ccccc34)cccc2c1]

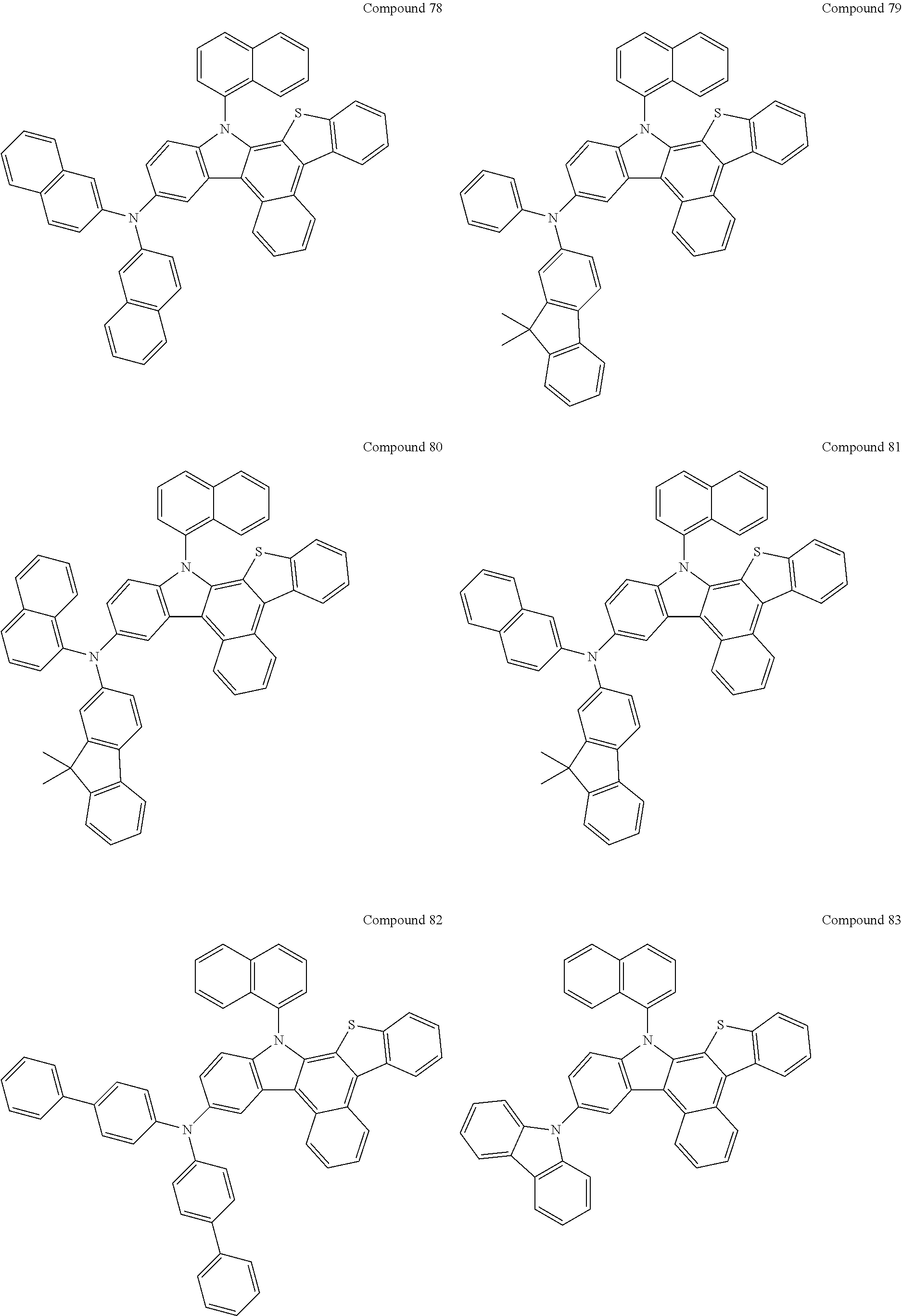

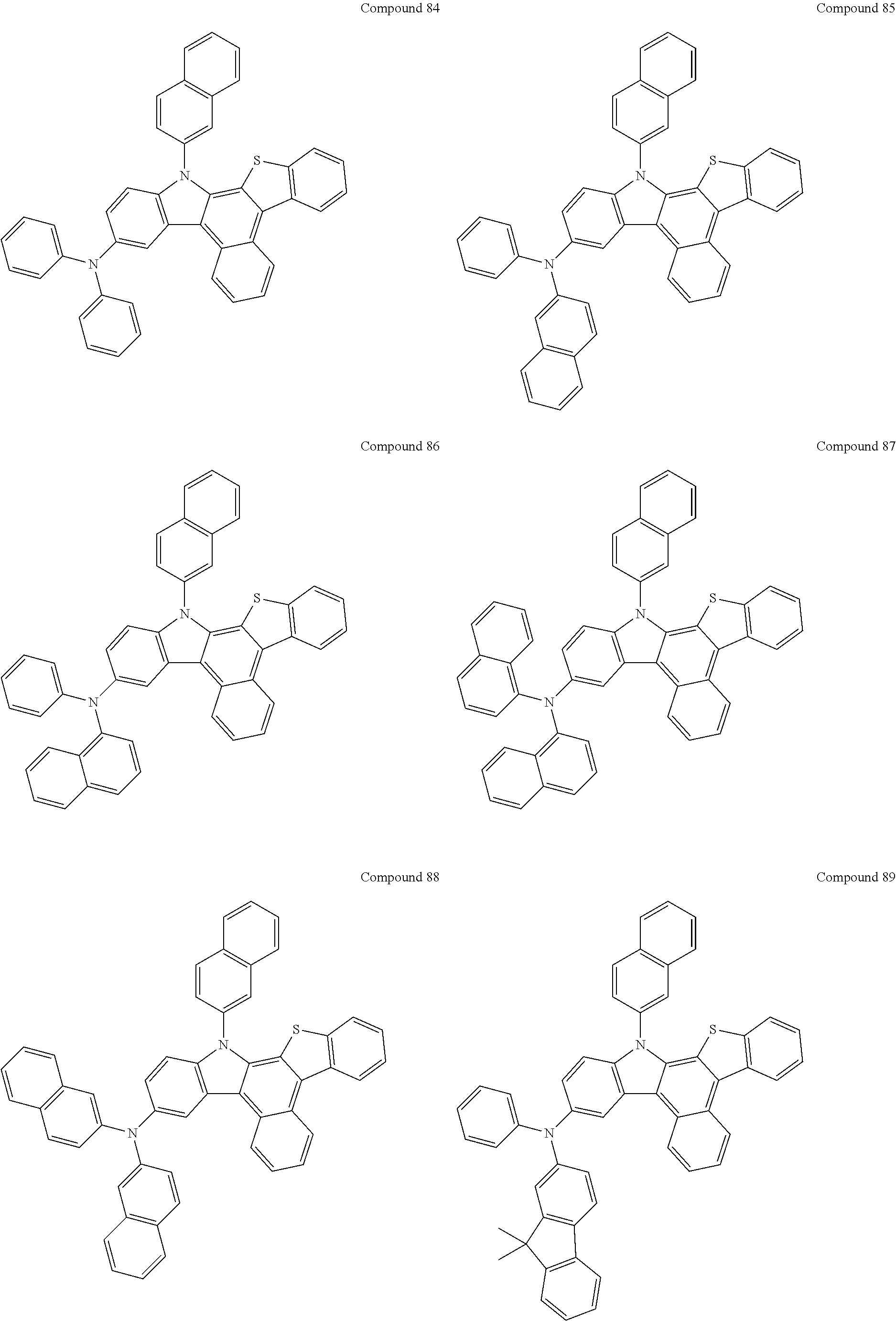

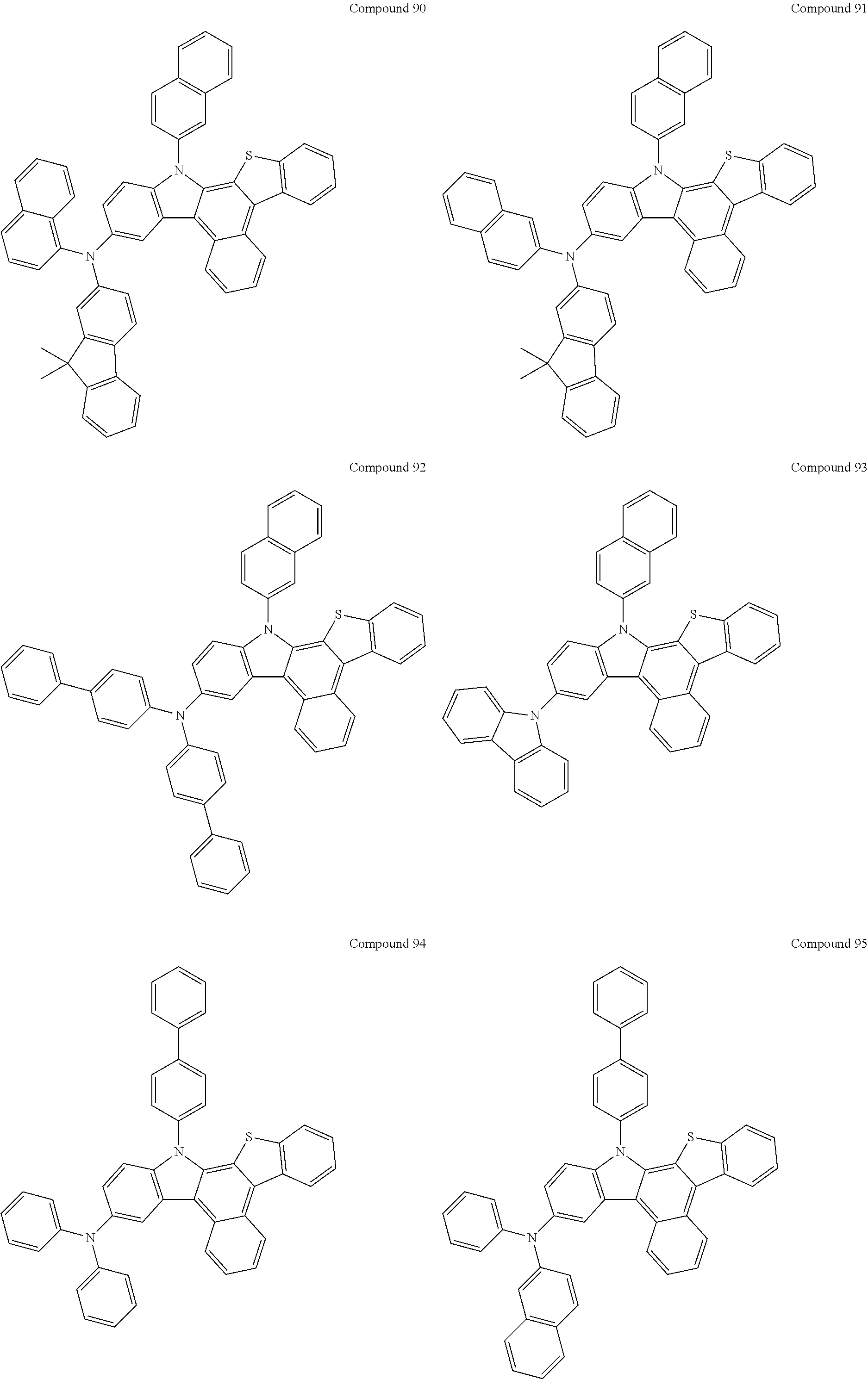

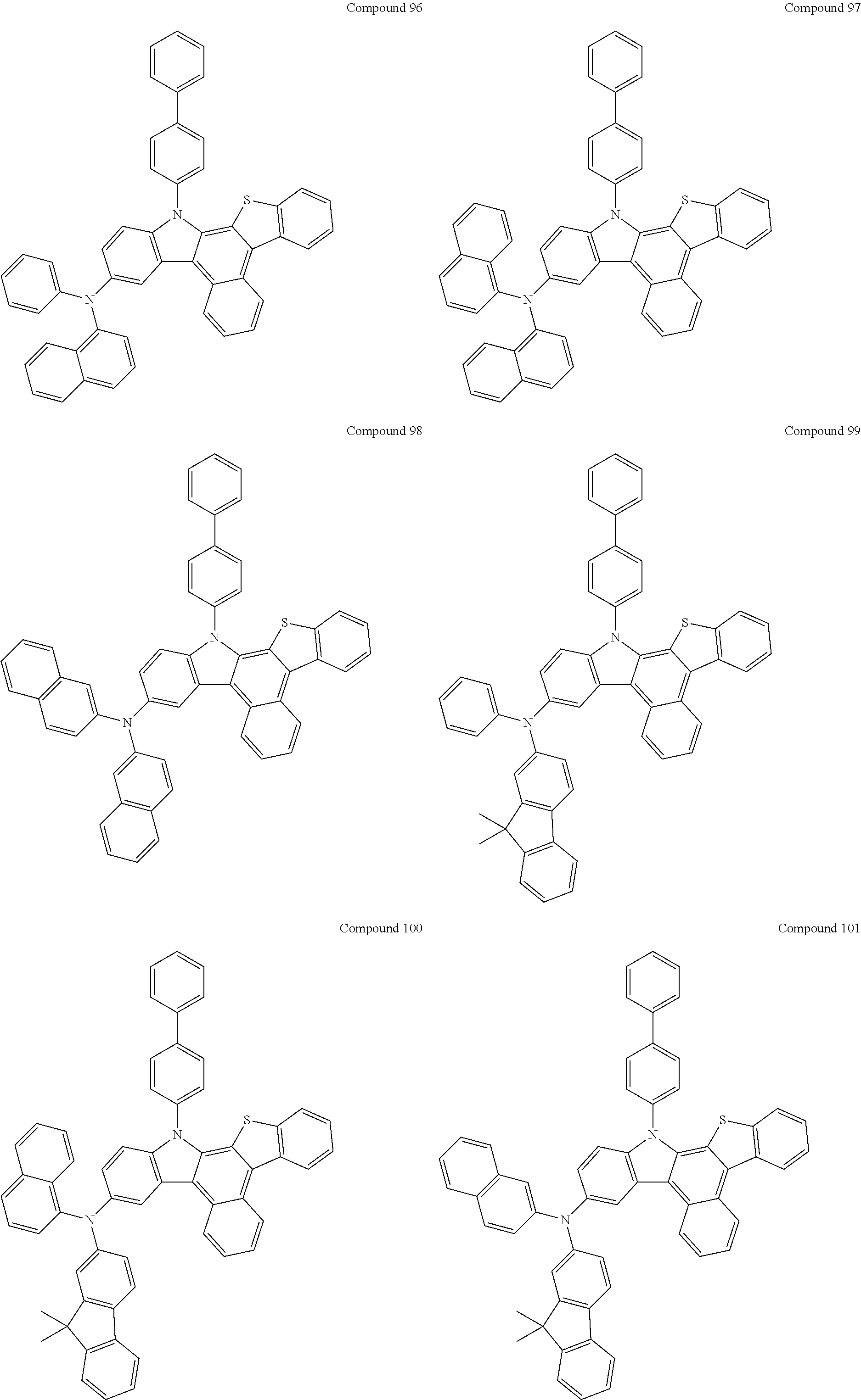

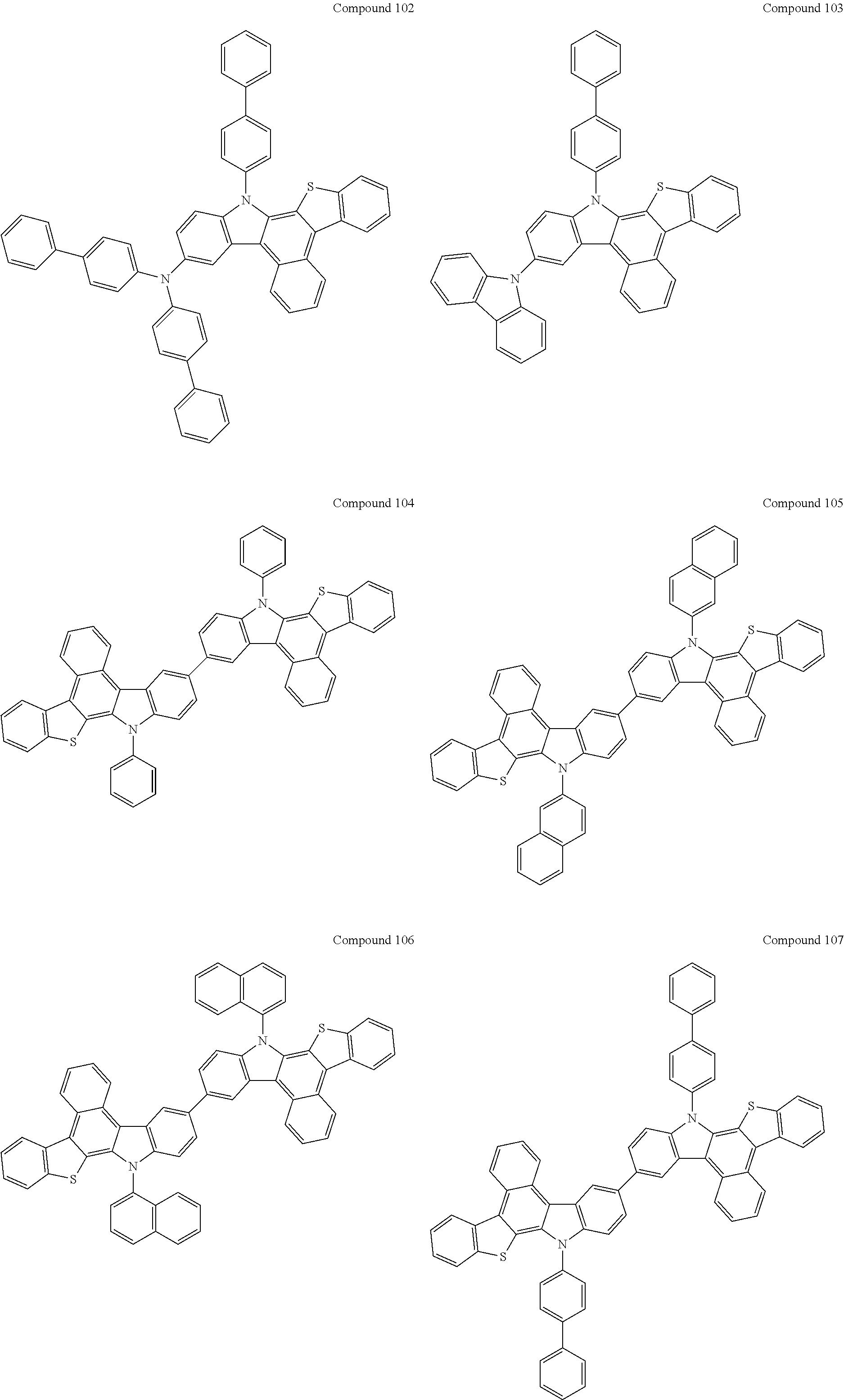

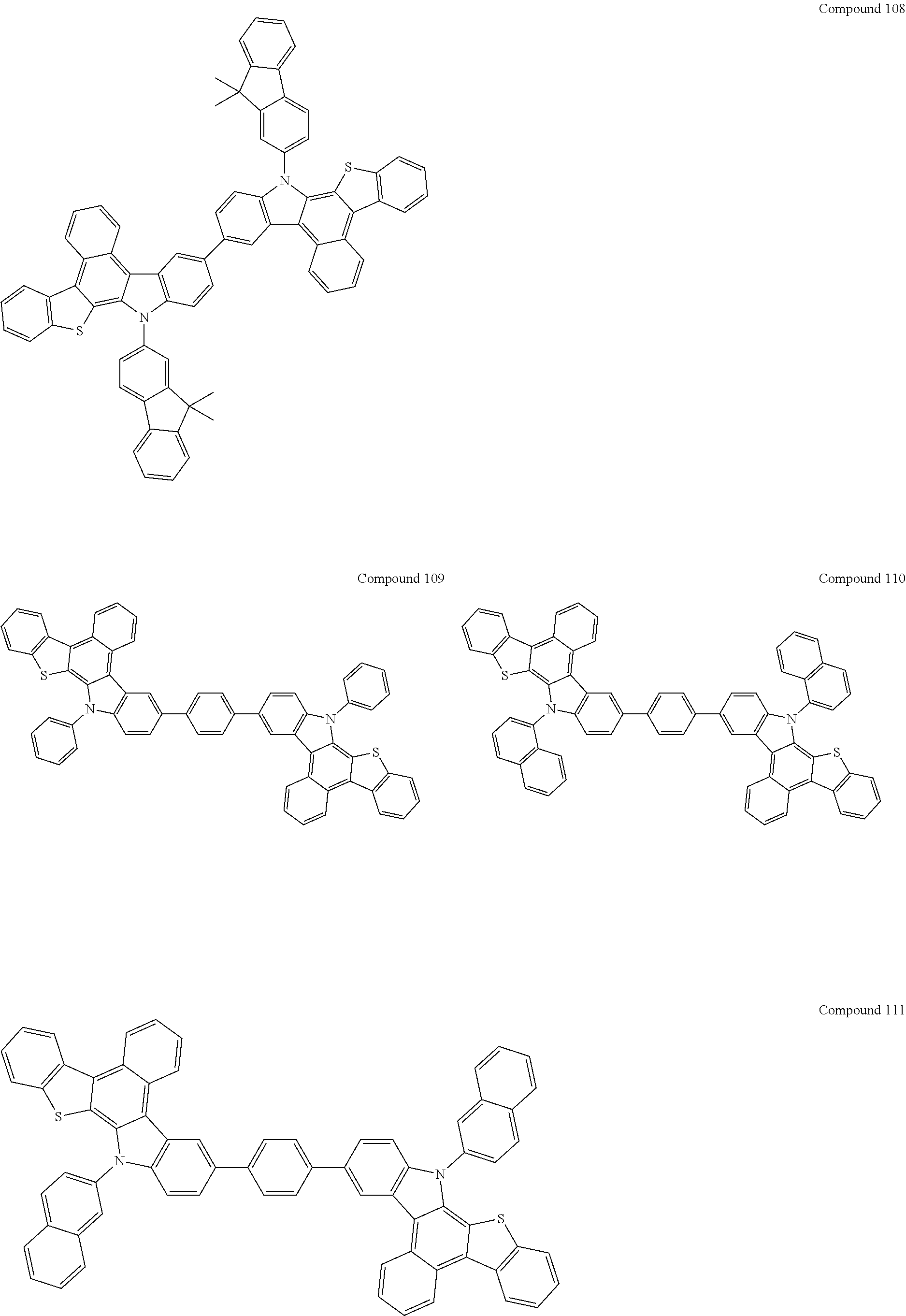 [SMILES: CC1(C)c2ccccc2-c2ccc(-n3c4ccc(-c5ccc6c(c5)c5c7ccccc7c7c8ccccc8sc7c5n6-c5ccc6c(c5)C(C)(C)c5ccccc5-6)cc4c4c5ccccc5c5c6ccccc6sc5c43)cc21 ; c1ccc(-n2c3ccc(-c4ccc(-c5ccc6c(c5)c5c7ccccc7c7c8ccccc8sc7c5n6-c5ccccc5)cc4)cc3c3c4ccccc4c4c5ccccc5sc4c32)cc1 ; c1ccc2c(-n3c4ccc(-c5ccc(-c6ccc7c(c6)c6c8ccccc8c8c9ccccc9sc8c6n7-c6cccc7ccccc67)cc5)cc4c4c5ccccc5c5c6ccccc6sc5c43)cccc2c1 ; c1ccc2cc(-n3c4ccc(-c5ccc(-c6ccc7c(c6)c6c8ccccc8c8c9ccccc9sc8c6n7-c6ccc7ccccc7c6)cc5)cc4c4c5ccccc5c5c6ccccc6sc5c43)ccc2c1]

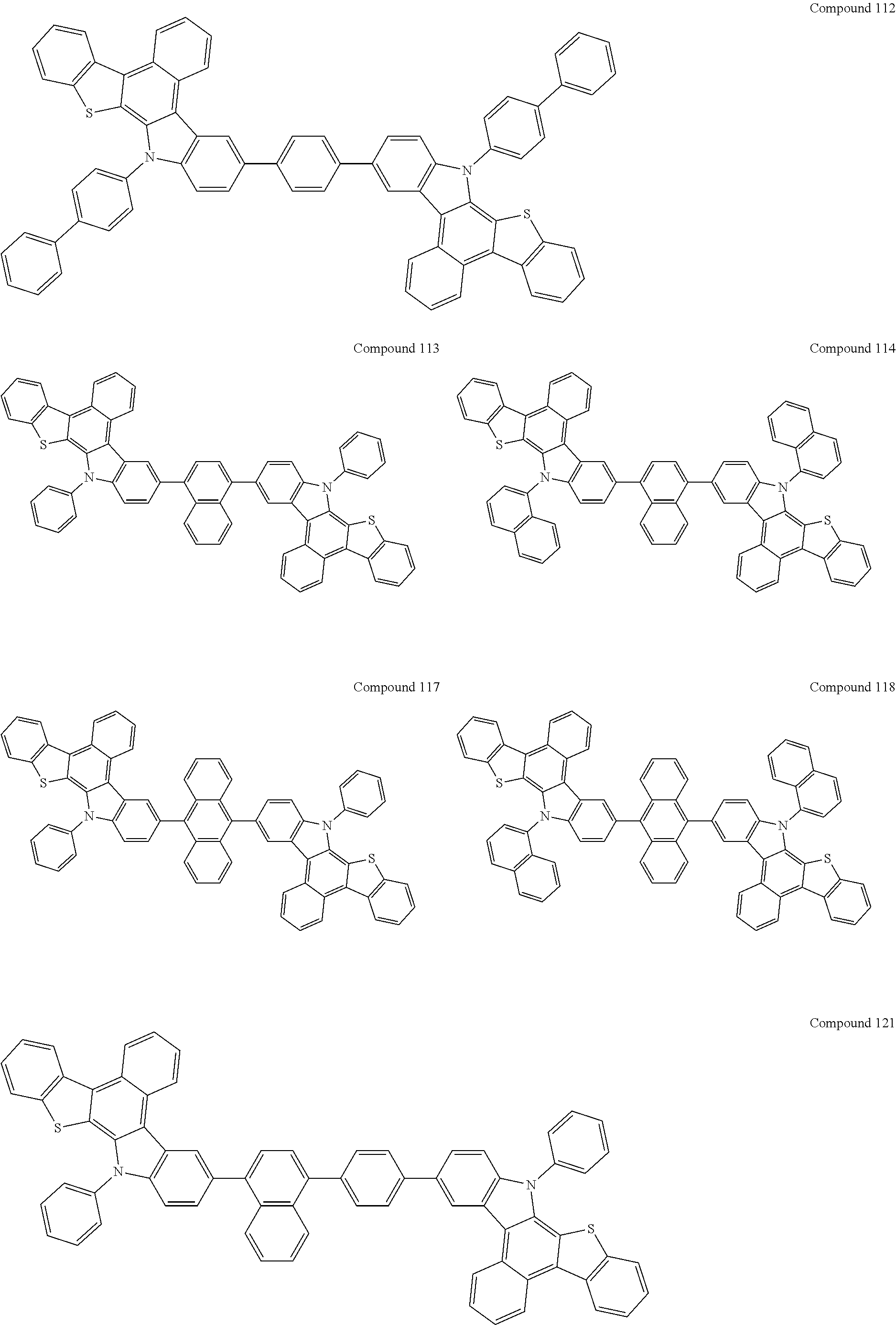

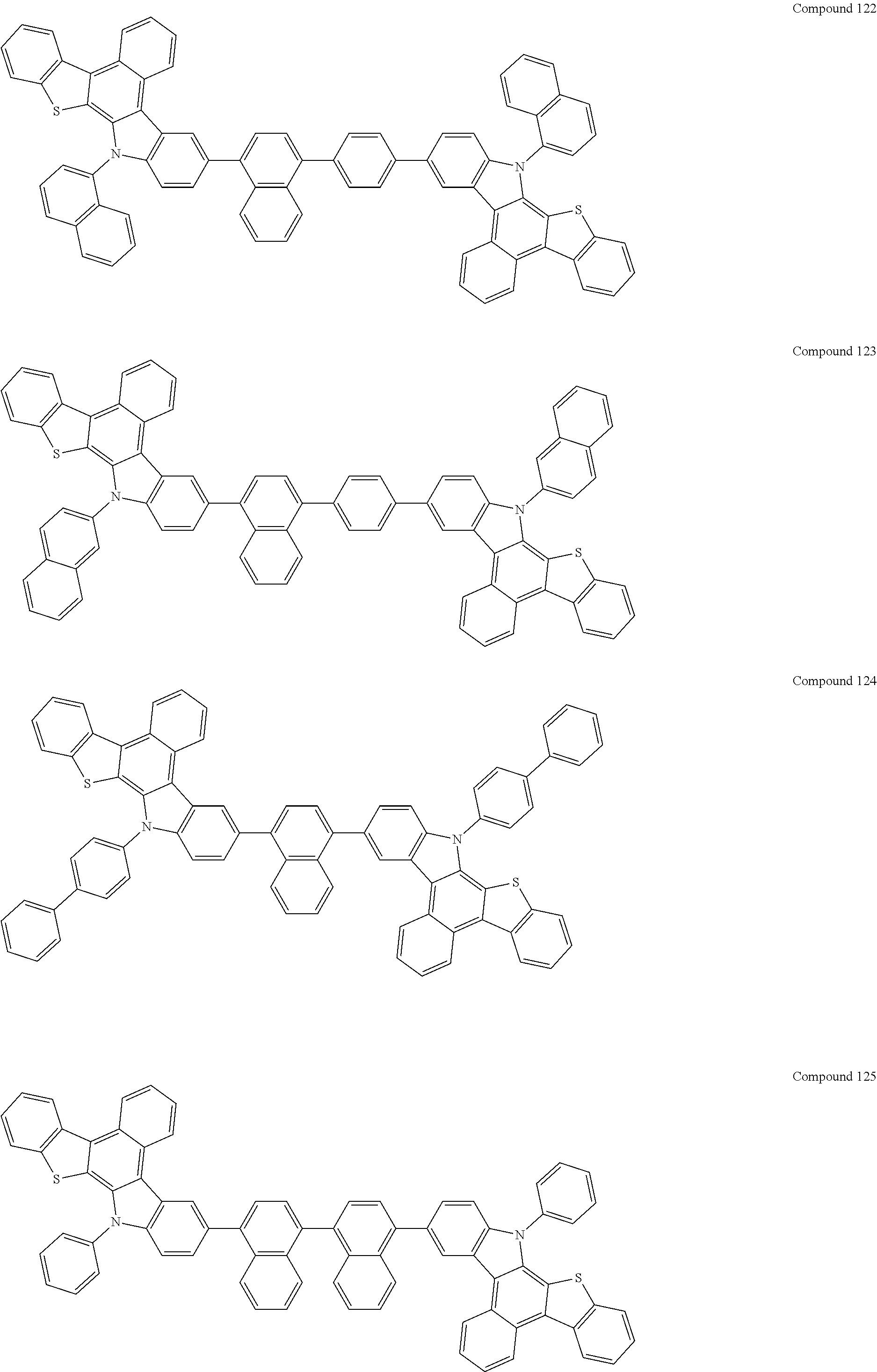

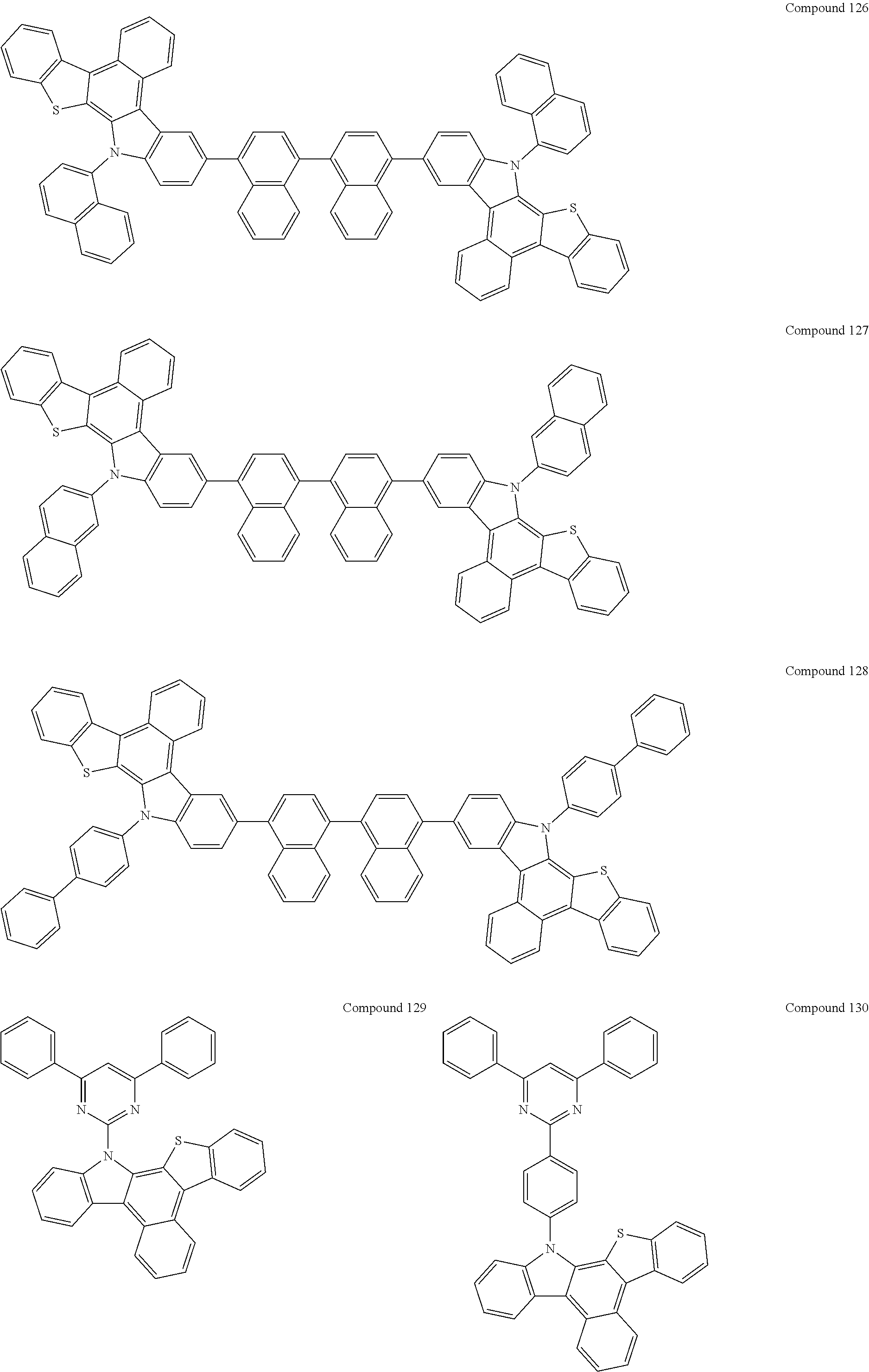

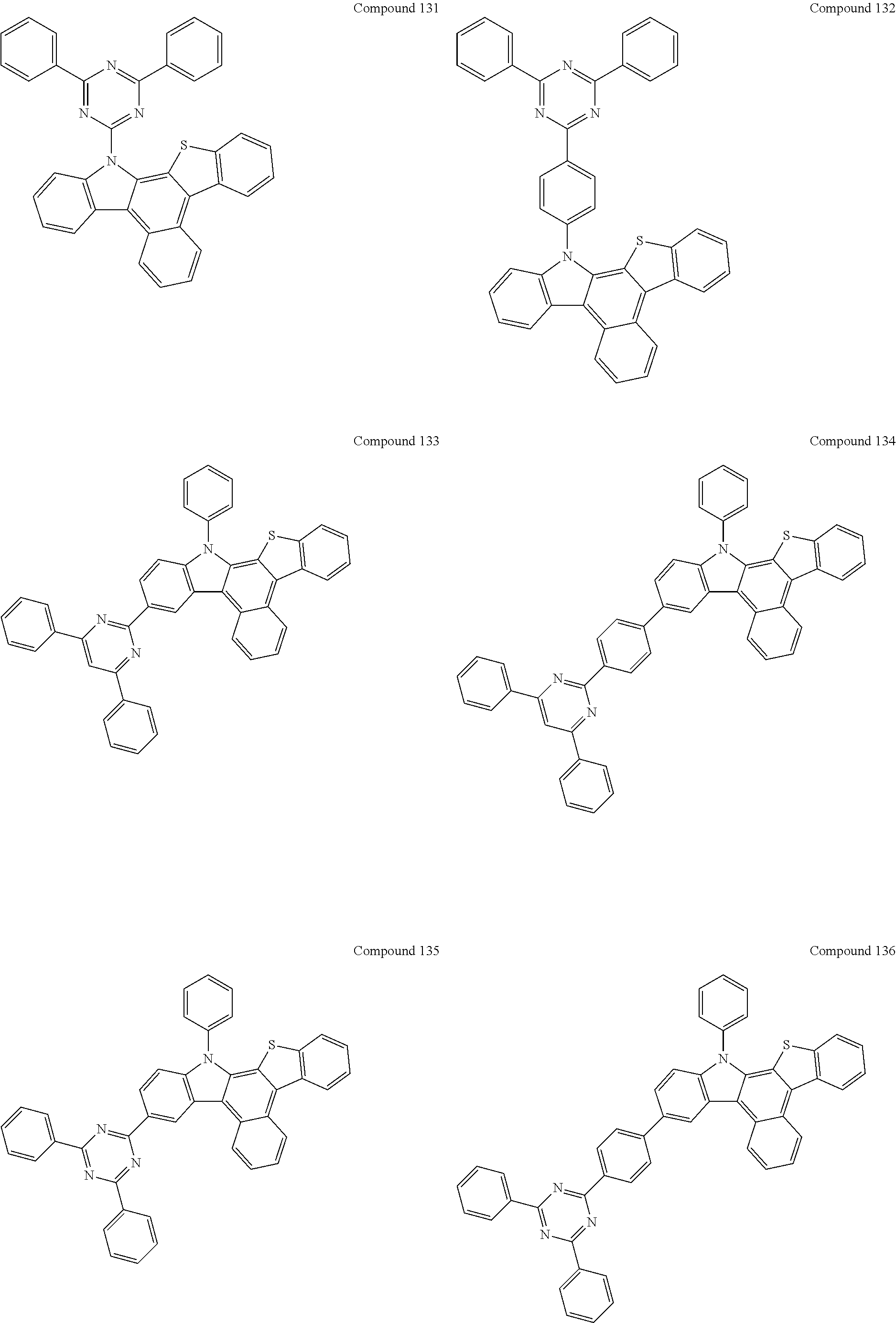

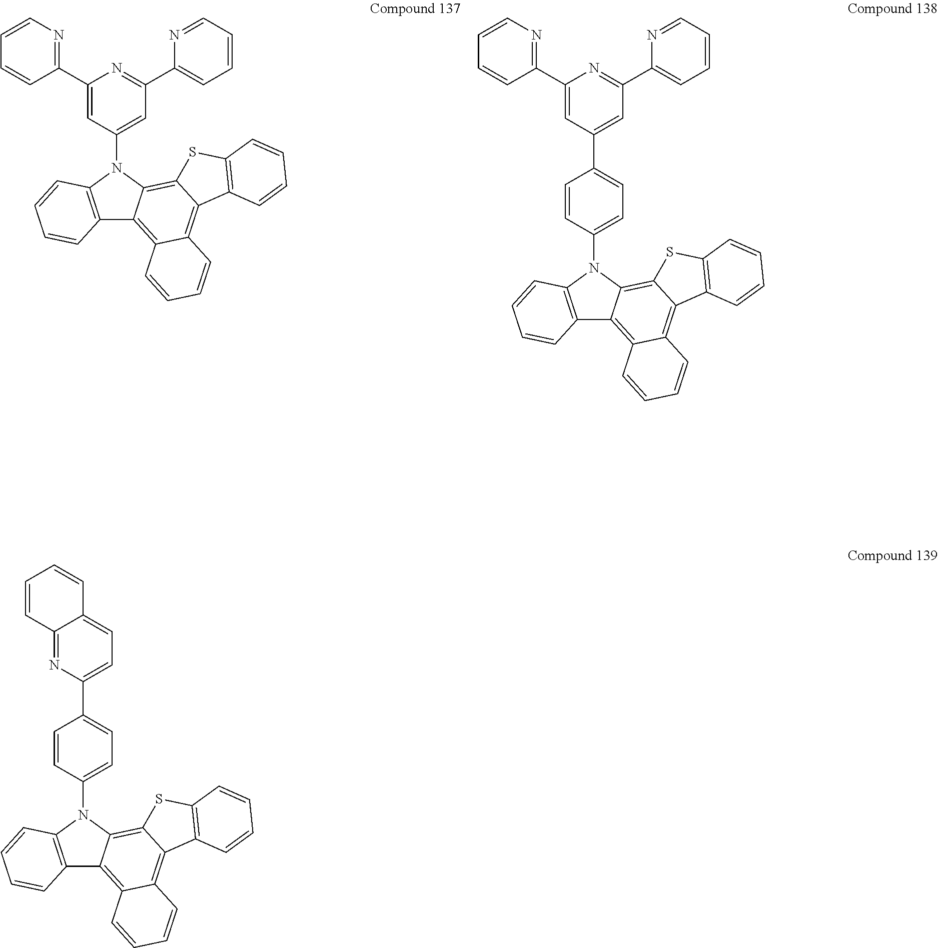 [SMILES: c1ccc(-c2cc(-n3c4ccccc4c4c5ccccc5c5c6ccccc6sc5c43)cc(-c3ccccn3)n2)nc1 ; c1ccc(-c2cc(-c3ccc(-n4c5ccccc5c5c6ccccc6c6c7ccccc7sc6c54)cc3)cc(-c3ccccn3)n2)nc1 ; c1ccc2nc(-c3ccc(-n4c5ccccc5c5c6ccccc6c6c7ccccc7sc6c54)cc3)ccc2c1]

A thickness of the first host layer HOL1 may be, e.g., from about 0.001% to about 10% of a thickness of the emission layer EML. The thickness of the first host layer HOL1 may be, e.g., from about 0.5 Å to about 30 Å.

The first host layer HOL1 may be between the emission layer EML and the electron transport region ETR. The first host layer HOL1 may make contact with, e.g., each of the emission layer EML and the electron transport region ETR.

The electron transport region ETR may be provided on the first host layer HOL1. The electron transport region ETR may include at least one of an electron blocking layer, an electron transport layer ETL, and an electron injection layer EIL, without limitation.

The electron transport region ETR may have a single layer formed using a single material, a single layer formed using a plurality of different materials, or a multilayer structure including a plurality of layers formed using a plurality of different materials.

For example, the electron transport region ETR may have the structure of a single layer such as the electron injection layer EIL, and the electron transport layer ETL, a single layer structure formed using an electron injection material and an electron transport material. In addition, the electron transport region ETR may have a structure laminated from the anode AN of electron transport layer ETL/electron injection layer EIL, buffer layer/electron transport layer ETL/electron injection layer EIL, buffer layer/electron injection layer EIL, buffer layer/electron transport layer ETL, or hole blocking layer/electron transport layer ETL/electron injection layer EIL, without limitation.

The electron transport region ETR may be formed using various methods such as a vacuum deposition method, a spin coating method, a cast method, a Langmir-Blodgett (LB) method, an inkjet printing method, a laser printing method, and a laser induced thermal imaging (LITI) method.

When the electron transport region ETR includes the electron transport layer ETL, the electron transport region ETR may include tris(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalene-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq2), 9,10-di(naphthalene-2-yl (ADN), or a mixture thereof, without limitation. The thickness of the electron transport layer ETL may be from about 100 Å to about 1.000 Å and may be from about 150 Å to about 500 Å. If the thickness of the electron transport layer ETL satisfies the above-described range, satisfactory electron transport property may be obtained without substantial increase of a driving voltage.

When the electron transport region ETR includes the electron injection layer EIL, the electron transport region ETR may include LiF, lithium quinolate (LiQ), Li₂O, BaO, NaCl, CsF, a metal in lanthanoides such as Yb, or a metal halide such as RbCl and RbI, without limitation. The electron injection layer EIL also may be formed using a mixture material of a hole transport material and an insulating organo metal salt. The organo metal salt may be a material having an energy band gap of about 4 eV or more. Particularly, the organo metal salt may include, for example, a metal acetate, a metal benzoate, a metal acetoacetate, a metal acetylacetonate, or a metal stearate. The thickness of the electron injection layer EIL may be from about 1 Å to about 100 Å, and from about 3 Å to about 90 Å. When the thickness of the electron injection layer EIL satisfies the above described range, satisfactory electron injection property may be obtained without inducing the substantial increase of a driving voltage.

The electron transport region ETR may include a hole blocking layer, as described above. The hole blocking layer may include at least one of, for example, 2,9-dimethyl-4,7-diphenyl-1,10-phenanthroline (BCP), or 4,7-diphenyl-1,10-phenanthroline (Bphen), without limitation.

The cathode CAT may be provided on the electron transport region ETR. The cathode CAT may be a common electrode or a cathode. The cathode CAT may be a transmissive electrode, a transflective electrode or a reflective electrode. When the cathode CAT is the transmissive electrode, the cathode CAT may include a transparent metal oxide, for example, ITO, IZO, ZnO, ITZO, etc.

When the cathode CAT is the transflective electrode or the reflective electrode, the cathode CAT may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). The cathode CAT may have a multilayered structure including a reflective layer or a transflective layer formed using the above-described materials and a transparent conductive layer formed using ITO, IZO, ZnO, ITZO, etc.

In an implementation, the cathode CAT may be connected with an auxiliary electrode. If the cathode CAT is connected with the auxiliary electrode, the resistance of the cathode CAT may decrease.

In the organic light emitting device OEL, voltages are applied to each of the anode AN and the cathode CAT, and holes injected from the anode AN transport via the hole transport region HTR to the emission layer EML, and electrons injected from the cathode CAT transport via the electron transport region ETR to the emission layer EML. The electrons and the holes are recombined in the emission layer EML to generate excitons, and the excitons may emit light via transition from an excited state to a ground state.

When the organic light emitting device OEL is a front emitting type, the anode AN may be a reflective electrode, and the cathode CAT may be a transmissive electrode or a transflective electrode. When the organic light emitting device OEL is a back emitting type, the anode AN may be a transmissive electrode or a transflective electrode, and the cathode CAT may be a reflective electrode.

Referring to FIGS. 2 and 3, the organic light emitting device OEL according to an embodiment may further include a second host layer HOL2 between the hole transport region HTR and the emission layer EML.

The second host layer HOL2 may include a third host. In an implementation, the second host layer HOL2 may not include a dopant. In an implementation, the second host layer HOL2 may not include the dopant included in the emission layer EML and a dopant different from the dopant included in the emission layer EML. In an implementation, the third host may be different from the first host and the second host, or may be the same as at least one of the first host or the second host. In an implementation, the third host may be represented by Formula 1. In an implementation, the third host may include at least one compound of Compound Group 1, above.

The thickness of the second host layer HOL2 may be the same as or different from the thickness of the first host layer HOLE The thickness of the second host layer HOL2 may be, e.g., from about 0.001% to about 10% of the thickness of the emission layer EML. The thickness of the second host layer HOL2 may be, e.g., from about 0.5 Å to about 30 Å.

The second host layer HOL2 may be between the emission layer EML and the hole transport region HTR. The second host layer HOL2 may make contact with each of the emission layer EML and the hole transport region HTR.

Referring to FIG. 3, the emission layer EML may include a first sub emission layer SML1, a third host layer HOL3, and a second sub emission layer SML2. The first sub emission layer SML1 may include a first host and a dopant. The third host layer HOL3 may be provided on the first sub emission layer SML1, and may include a fourth host. The second sub emission layer SML2 may be provided on the third host layer HOL3 and may include a first host and a dopant.

The first host included in the first sub emission layer SML1 and the first host included in the second sub emission layer SML2 may be the same or different. In an implementation, the first host included in the first sub emission layer SML1 and the first host included in the second sub emission layer SML2 may be the same as the fourth host or different from each other.

In an implementation, the third host layer HOL3 may include the fourth host. The third host layer HOL3 may not include a dopant. In an implementation, the third host layer HOL3 may not include the dopant included in the emission layer EML and a dopant different from the dopant included in the emission layer EML. In an implementation, the fourth host may be different from each of the first host and the third host, or may be the same as at least one of the first host or the third host. In an implementation, the fourth host may be represented by Formula 1. In an implementation, the fourth host may include at least one compound of Compound Group 1, above.

The thickness of the third host layer HOL3 may be the same as the thickness of the first host layer HOL1 or the second host layer HOL2, or may be different from at least one of the thicknesses of the first host layer HOL1 and the thickness of the second host layer HOL2.

At high temperatures, hole mobility of an organic light emitting device may decrease, and adhesiveness of an electron transport region with a cathode may be improved. Generally, electron mobility may be higher than hole mobility at high temperatures. Accordingly, the amount of electrons injected to the emission layer may increase at high temperatures, and the equilibrium of holes and electrons in the emission layer may be destroyed, thereby decreasing the emission efficiency of the organic light emitting device.

In some organic light emitting devices, an emission layer and an electron transport region may make direct contact, and an amount of electrons injected to the emission layer may increase at high temperatures, thereby destroying the equilibrium of holes and electrons in the emission layer and decreasing the emission efficiency of the organic light emitting device.

The organic light emitting device according to an embodiment may include a first host layer including a second host represented by Formula 1 between an emission layer and an electron transport region. At high temperatures, the mobility of the second host included in the first host layer may be lower than electron mobility. For example, the second host may help lower electron mobility of electrons in the first host layer. Accordingly, the first host layer may help prevent the increase of the amount of the electrons injected from the electron transport region into the emission layer. Accordingly, the organic light emitting device according to an embodiment may maintain emission efficiency at high temperatures. For example, the first host layer may help regulate electron mobility of electrons in the organic light emitting device.

Hereinafter a display device according to an embodiment will be explained. The explanation will be concentrated on different points from the organic light emitting device according to an embodiment described above, and unexplained parts will follow the explanation on the organic light emitting device according to an embodiment described above.

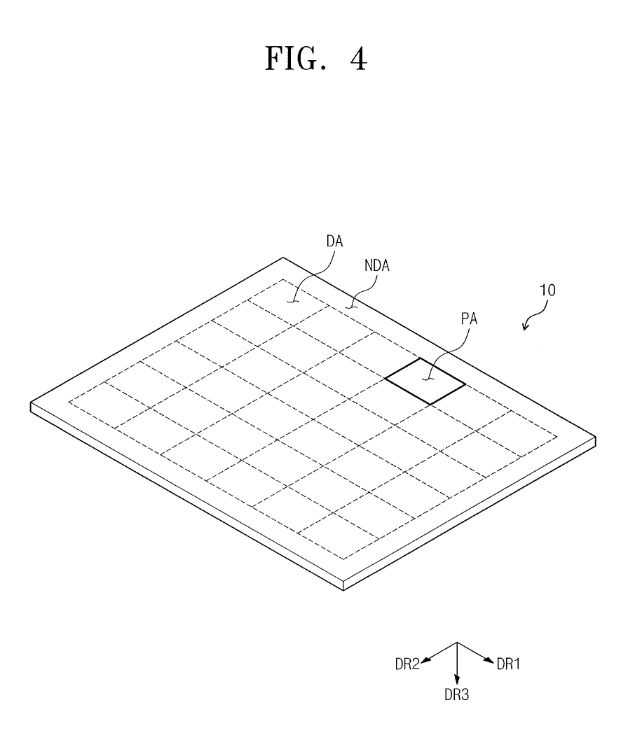

FIG. 4 illustrates a perspective view schematically showing a display device according to an embodiment.

Referring to FIG. 4, a display device 10 according to an embodiment may include a display area DA and a non-display area NDA. The display area DA may display images. When seen from the direction of the thickness of the display device 10 (for example, in DR3), the display area DA may have approximately a rectangle shape, without limitation.

The display area DA may include a plurality of pixel areas PA. The pixel areas PA may be disposed in a matrix shape. In the pixel areas PA, a plurality of pixels PX may be disposed. Each of the pixels PX may include sub-pixels. Each of the pixels PX may include an organic light emitting device (OEL in FIG. 1A).

A non-display area NDA may not display images. When seen from the direction of the thickness of the display device 10 (in DR3), the non-display area NDA may be, for example, surround the display area DA. The non-display area NDA may be adjacent to the display area DA in a first direction DR1 and a second direction DR2.

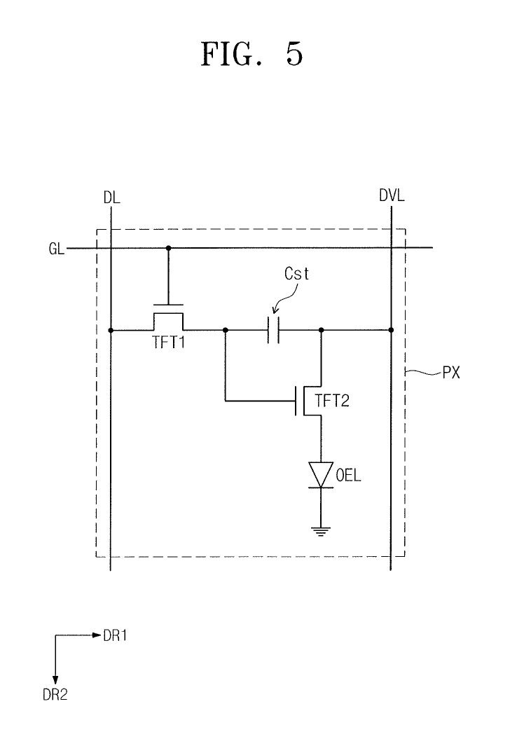

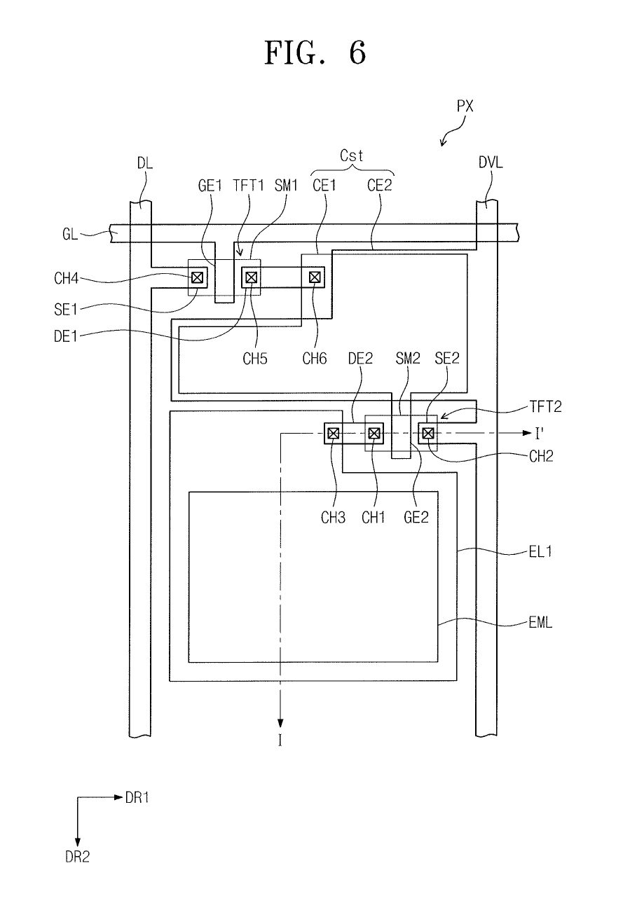

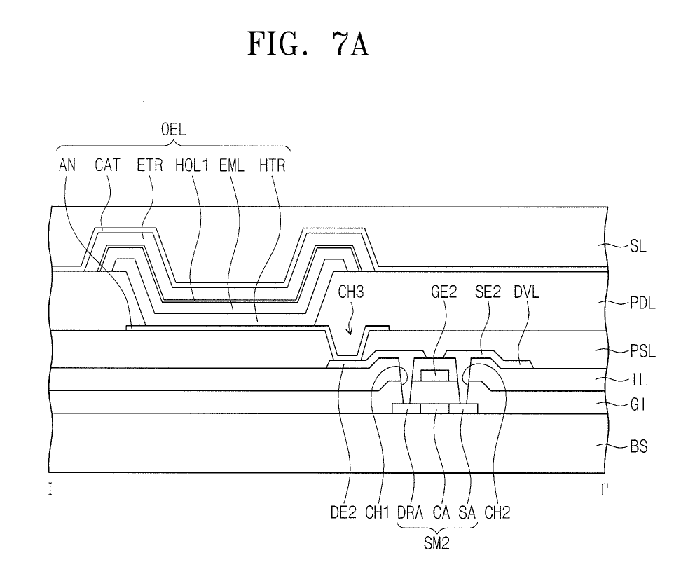

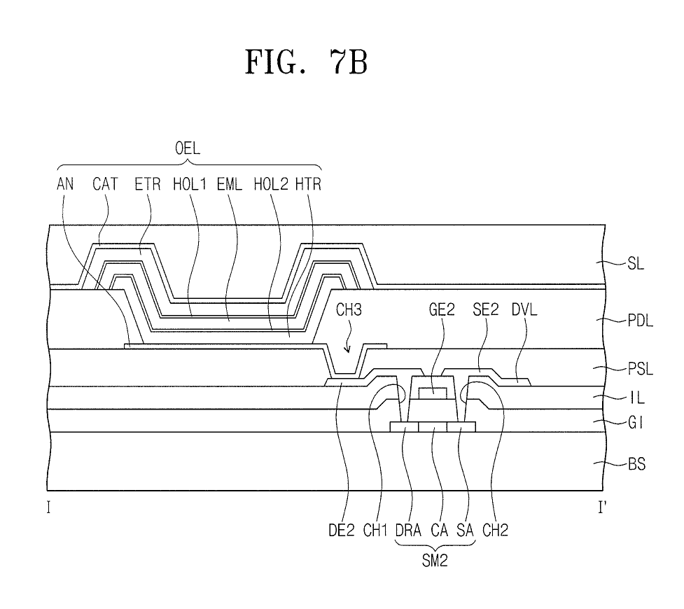

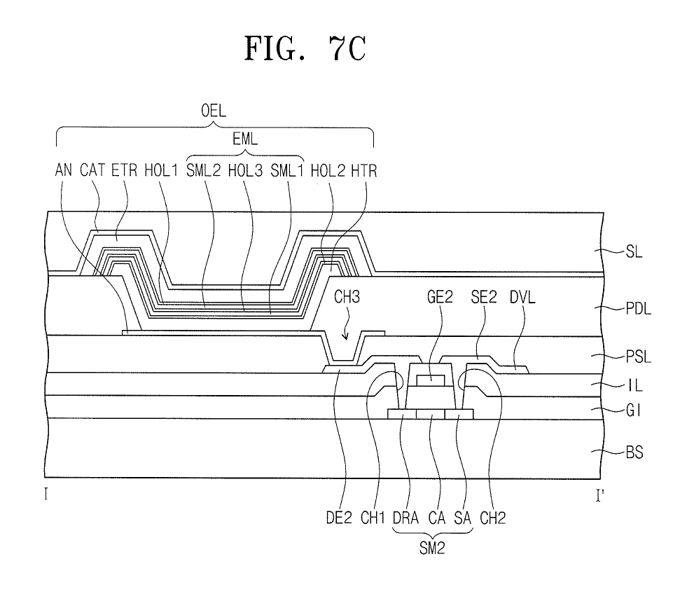

FIG. 5 illustrates a circuit diagram of a pixel included in a display device according to an embodiment. FIG. 6 illustrates a plan view of a pixel included in a display device according to an embodiment. FIGS. 7A, 7B, and 7C illustrate schematic cross-sectional views taken along line I-I′ in FIG. 6.

Referring to FIGS. 4, 5, 6, 7A, 7B, and 7C, each of the pixels PX may include a wire part including a gate line GL, a data line DL, and a driving voltage line DVL. Each of the pixels PX may include thin film transistors TFT1 and TFT2 connected to the wire part, an organic light emitting device OEL connected to the thin film transistors TFT1 and TFT2, and a capacitor Cst. Each of the pixels PX may emit light having a specific color, for example, one of red light, green light, blue light, white light, yellow light, or cyan light.

From the plan view of FIG. 6, each of the pixels PX have a rectangular shape, however each of the pixels PX may have at least one shape of a circle, an ellipse, a square, a parallelogram, a trapezoid, or a rhombus, without limitation. In addition, each of the pixels PX may have, for example, a quadrangle having at least one rounded corner from the plan view.

The gate line GL may be extended in a first direction DR1. The data line DL may be extended in a second direction DR2 crossing the gate line GL. The driving voltage line DVL may be extended in substantially the same direction as the data line DL, that is, the second direction DR2. The gate line GL transmits scanning signals to the thin film transistors TFT1 and TFT2, and the data line DL transmits data signals to the thin film transistors TFT1 and TFT2, and the driving voltage line DVL provides driving voltages to the thin film transistors TFT1 and TFT2.

The thin film transistors TFT1 and TFT2 may include a driving thin film transistor TFT2 for controlling the organic light emitting device OEL, and a switching thin film transistor TFT1 for switching the driving thin film transistor TFT2. In an embodiment, each of the pixels PX includes two thin film transistors TFT1 and TFT2, however an embodiment is not limited thereto. Each of the pixels PX may include one thin film transistor and one capacitor, or each of the pixels PX may include at least three thin film transistors and at least two capacitors.

The switching thin film transistor TFT1 may include a first gate electrode GE1, a first source electrode SE1, and a first drain electrode DEL The first gate electrode GE1 may be connected to the gate line GL, and the first source electrode SE1 may be connected to the data line DL. The first drain electrode DE1 may be connected to a first common electrode CE1 via a fifth contact hole CH5. The switching thin film transistor TFT1 may transmit data signals applied to the data line DL to the driving thin film transistor TFT2 according to scanning signals applied to the gate line GL.

The driving thin film transistor TFT2 may include a second gate electrode GE2, a second source electrode SE2, and a second drain electrode DE2. The second gate electrode GE2 may be connected to the first common electrode CE1. The second source electrode SE2 may be connected to the driving voltage line DVL. The second drain electrode DE2 may be connected to the anode AN via a third contact hole CH3.

The capacitor Cst may be connected between the second gate electrode GE2 and the second source electrode SE2 of the driving thin film transistor TFT2, and charges and maintains data signals inputted to the second gate electrode GE2 of the driving thin film transistor TFT2. The capacitor Cst may include the first common electrode CE1 connected to the first drain electrode DE1 via a sixth contact hole CH6 and a second common electrode CE2 connected to the driving voltage line DVL.

The display device 10 according to an embodiment may include a base substrate BS on which thin film transistors TFT1 and TFT2, and an organic light emitting device OEL are laminated. Any commonly used substrate may be used as the base substrate BS, without limitation, and may be formed using an insulating material such as glass, plastics, and quartz. As an organic polymer forming the base substrate BS, polyethylene terephthalate (PET), polyethylene naphthalate (PEN), polyimide, polyethersulfone, etc. may be used. The base substrate BS may be selected in consideration of mechanical strength, thermal stability, transparency, surface smoothness, easiness of handling, water-proof properties, etc.

On the base substrate BS, a substrate buffer layer (not shown) may be provided. The substrate buffer layer (not shown) may prevent the diffusion of impurities into the switching thin film transistor TFT1 and the driving thin film transistor TFT2. The substrate buffer layer (not shown) may be formed using silicon nitride (SiNx), silicon oxide (SiOx), silicon oxynitride (SiOxNy), etc., and may be omitted according to the material of the base substrate BS and process conditions.

On the base substrate BS, a first semiconductor layer SM1 and a second semiconductor layer SM2 may be provided. The first semiconductor layer SM1 and the second semiconductor layer SM2 may be formed using a semiconductor material and function as active layers of the switching thin film transistor TFT1 and the driving thin film transistor TFT2, respectively. Each of the first semiconductor layer SM1 and the second semiconductor layer SM2 may include a source area SA, a drain area DA, and a channel area CA provided between the source area SA and the drain area DA. Each of the first semiconductor layer SM1 and the second semiconductor layer SM2 may be formed by selecting inorganic semiconductor or organic semiconductor, respectively. The source area SA and the drain area DA may be doped with n-type impurities or p-type impurities.

On the first semiconductor layer SM1 and the second semiconductor layer SM2, a gate insulating layer GI may be provided. The gate insulating layer GI may cover the first semiconductor layer SM1 and the second semiconductor layer SM2. The gate insulating layer GI may include at least one of an organic insulating material or an inorganic insulating material.

On the gate insulating layer GI, a first gate electrode GE1 and a second gate electrode GE2 may be provided. Each of the first gate electrode GE1 and the second gate electrode GE2 may be formed to cover corresponding areas in the channel area CA of the first semiconductor layer SM1 and the second semiconductor layer SM2.

On the insulating interlayer IL, a first source electrode SE1, a first drain electrode DE1, a second source electrode SE2, and a second drain electrode DE2 may be provided. The second drain electrode DE2 may make contact with the drain area DA of the second semiconductor layer SM2 via a first contact hole CH1 formed in the gate insulating layer GI and the insulating interlayer IL, and the second source electrode SE2 may make contact with the source area SA of a second semiconductor layer SM2 by a second contact hole CH2 formed in the gate insulating layer GI and the insulating interlayer IL. The first source electrode SE1 may make contact with a source area (not shown) of the first semiconductor layer SM1 via a fourth contact hole CH4 formed in the gate insulating layer GI and the insulating interlayer IL, and the first drain electrode DE1 may make contact with a drain area (not shown) of the first semiconductor layer SM1 via a fifth contact hole CH5 formed in the gate insulating layer GI and the insulating interlayer IL.

On the first source electrode SE1, the first drain electrode DE1, the second source electrode SE2, and the second drain electrode DE2, a passivation layer PSL may be provided. The passivation layer PSL may play the role of passivating the switching thin film transistor TFT1 and the driving thin film transistor TFT2, or the role of planarizing the top surface thereof.

On the passivation layer PSL, an anode AN may be provided. The anode AN may be, for example, a pixel electrode or an anode. The anode AN may be connected to the second drain electrode DE2 of the driving thin film transistor TFT2 via the third contact hole CH3 formed in the passivation layer PSL.

The hole transport region HTR may be provided on the anode AN. The hole transport region HTR may include at least one of a hole injection layer HIL, a hole transport layer HTL, a buffer layer, or an electron blocking layer.

The emission layer EML may be provided on the hole transport region HTR. The emission layer EML may include a first host and a dopant. The first host may be the same as or different from a second host that will be explained later.

The emission layer EML may emit red light, and may emit one of green light, blue light, white light, yellow light, or cyan light, without limitation.

A first host layer HOL1 may be provided on the emission layer EML. The first host layer HOL1 may include a second host. The first host layer HOL1 may not include a dopant. The first host layer HOL1 may not include the dopant included in the emission layer EML and a dopant different from the dopant included in the emission layer EML. The second host may be different from or the same as the first host. The second host may be represented by the following Formula 1.

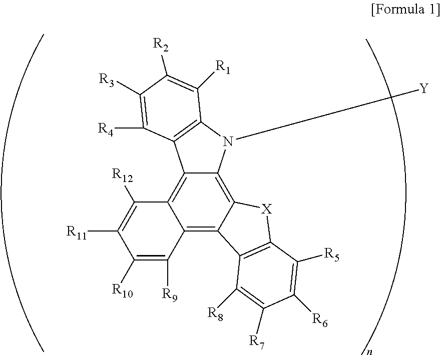

In Formula 1, R₁, R₂, R₃, R₄, R₅, R₆, R₇, R₈, R₉, R₁₀, R₁₁, and R₁₂ may each independently be or include, e.g., a hydrogen atom, a halogen atom, a cyano group, an alkoxy group, a thiol group, a substituted or unsubstituted alkyl group having 1 to 50 carbon atoms, a substituted or unsubstituted alkoxy group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphorus, or silicon, a substituted or unsubstituted heteroaryl group having 5 to 60 carbon atoms and including at least one of sulfur, nitrogen, oxygen, phosphorus, or silicon, or a substituted or unsubstituted heteroaryloxy group having 5 to 60 carbon atoms and including at least one of sulfur, nitrogen, oxygen, phosphorus, or silicon. X may be, e.g., sulfur, oxygen, or silicon. Y may be or may include, e.g., a hydrogen atom, a halogen atom, a cyano group, an alkoxy group, a thiol group, a substituted or unsubstituted alkyl group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphorus, or silicon, a substituted or unsubstituted heteroaryl group having 5 to 60 carbon atoms and including at least one of sulfur, nitrogen, oxygen, phosphorus, or silicon, or a substituted or unsubstituted heteroaryloxy group having 5 to 60 carbon atoms and including at least one of sulfur, nitrogen, oxygen, phosphorus, or silicon. n may be an integer of 1 to 3.

In an implementation, R₁, R₂, R₃, R₄, R₅, R₆, R₇, R₈, R₉, R₁₀, R₁₁, or R₁₂ may be separate or adjacent ones thereof may be combined or fused to form a ring.

In an implementation, the second host may include at least one compound of the following Compound Group 1.

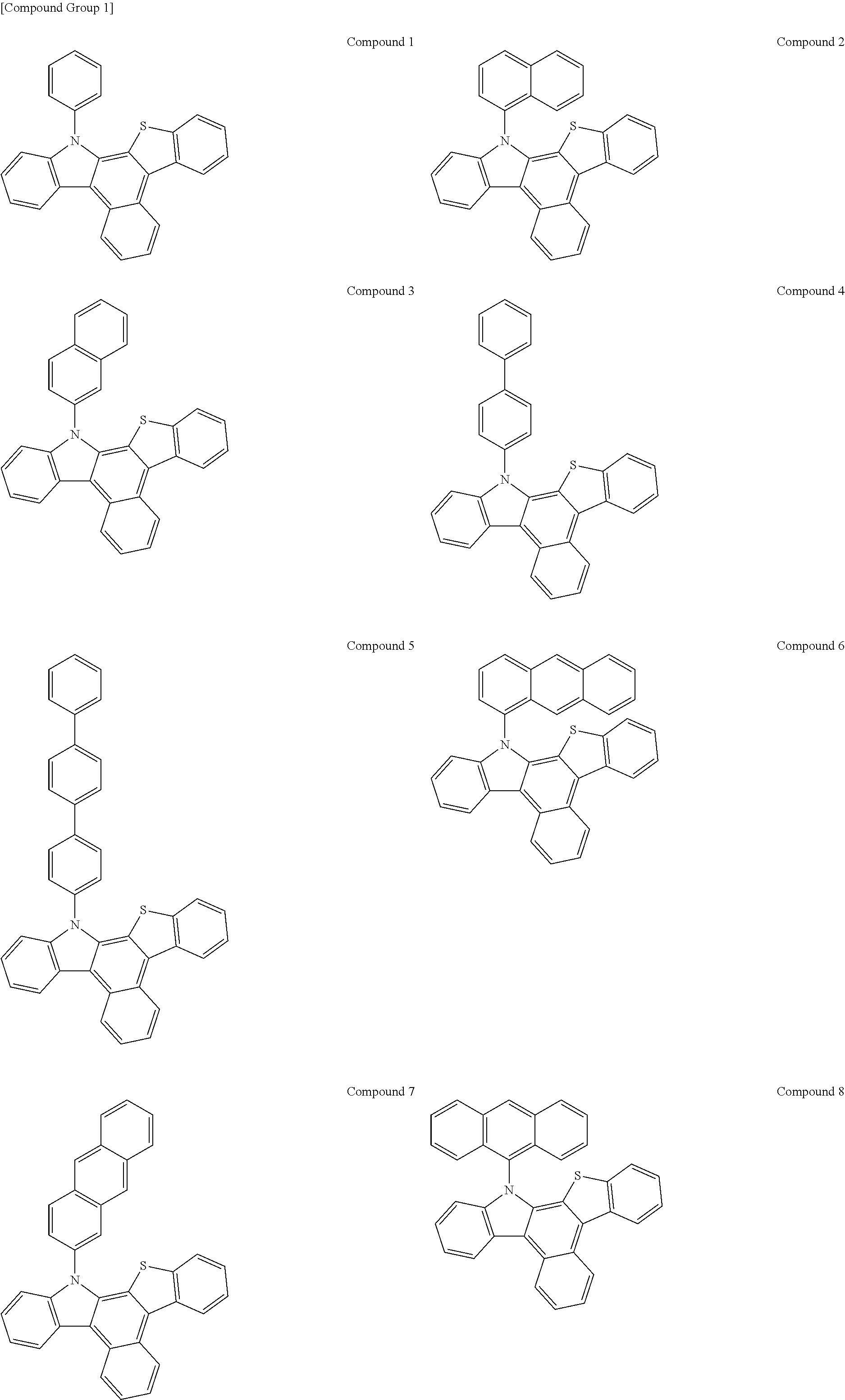

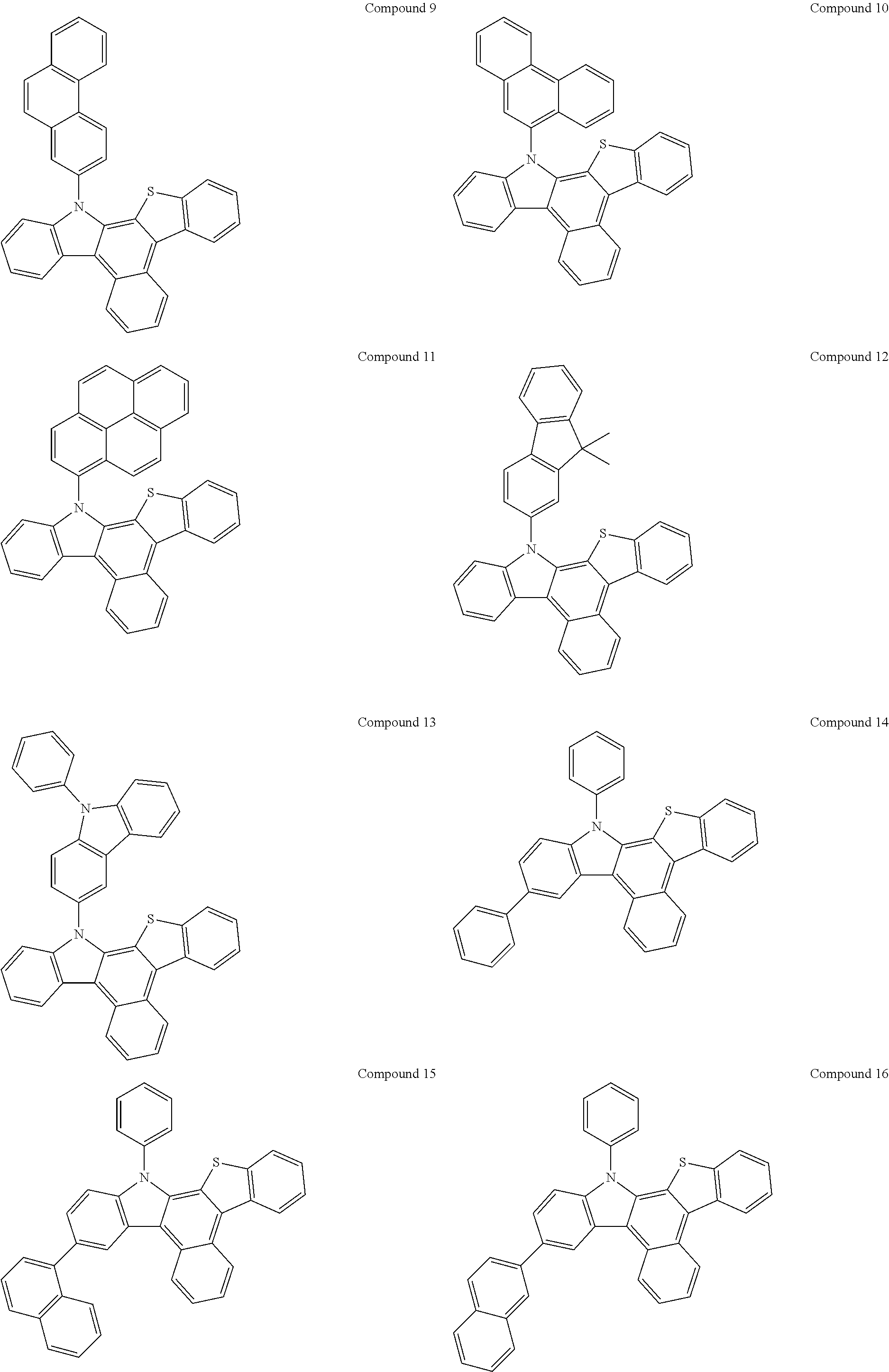

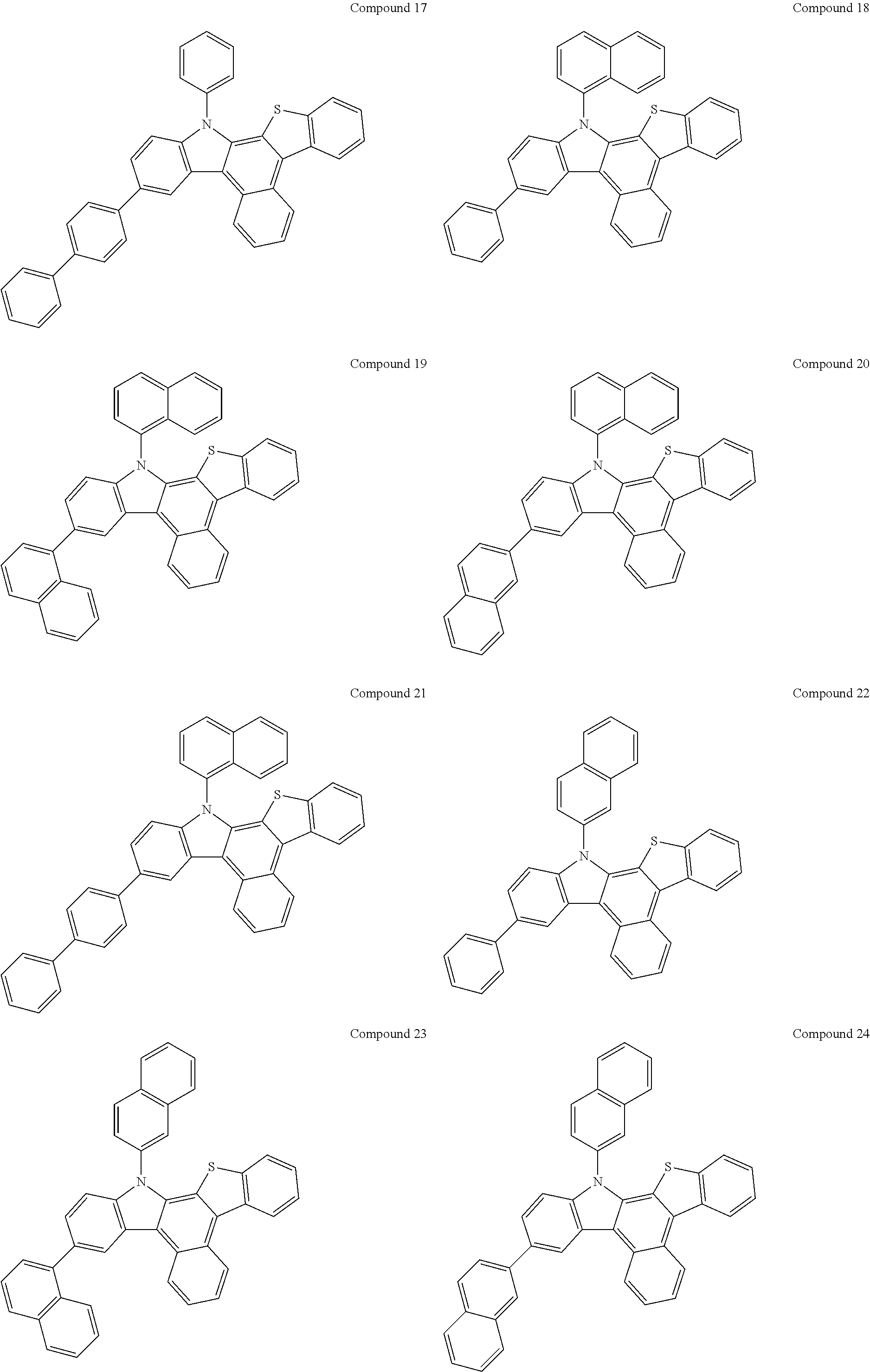

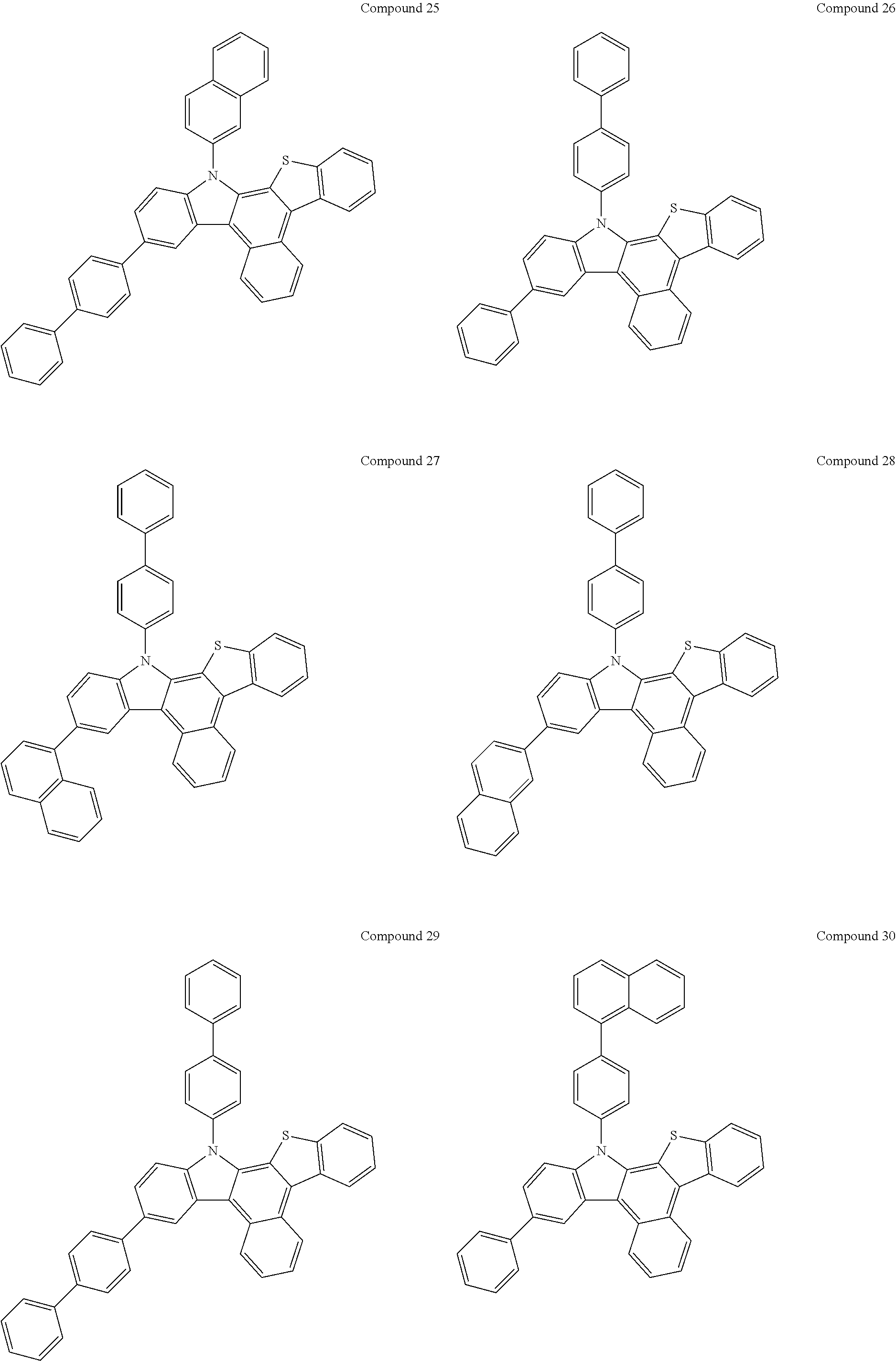 [SMILES: c1ccc(-c2ccc(-c3ccc4c(c3)c3c5ccccc5c5c6ccccc6sc5c3n4-c3ccc4ccccc4c3)cc2)cc1 ; c1ccc(-c2ccc(-n3c4ccc(-c5ccccc5)cc4c4c5ccccc5c5c6ccccc6sc5c43)cc2)cc1 ; c1ccc(-c2ccc(-n3c4ccc(-c5cccc6ccccc56)cc4c4c5ccccc5c5c6ccccc6sc5c43)cc2)cc1 ; c1ccc(-c2ccc(-n3c4ccc(-c5ccc6ccccc6c5)cc4c4c5ccccc5c5c6ccccc6sc5c43)cc2)cc1 ; c1ccc(-c2ccc(-c3ccc4c(c3)c3c5ccccc5c5c6ccccc6sc5c3n4-c3ccc(-c4ccccc4)cc3)cc2)cc1 ; c1ccc(-c2ccc3c(c2)c2c4ccccc4c4c5ccccc5sc4c2n3-c2ccc(-c3cccc4ccccc34)cc2)cc1]

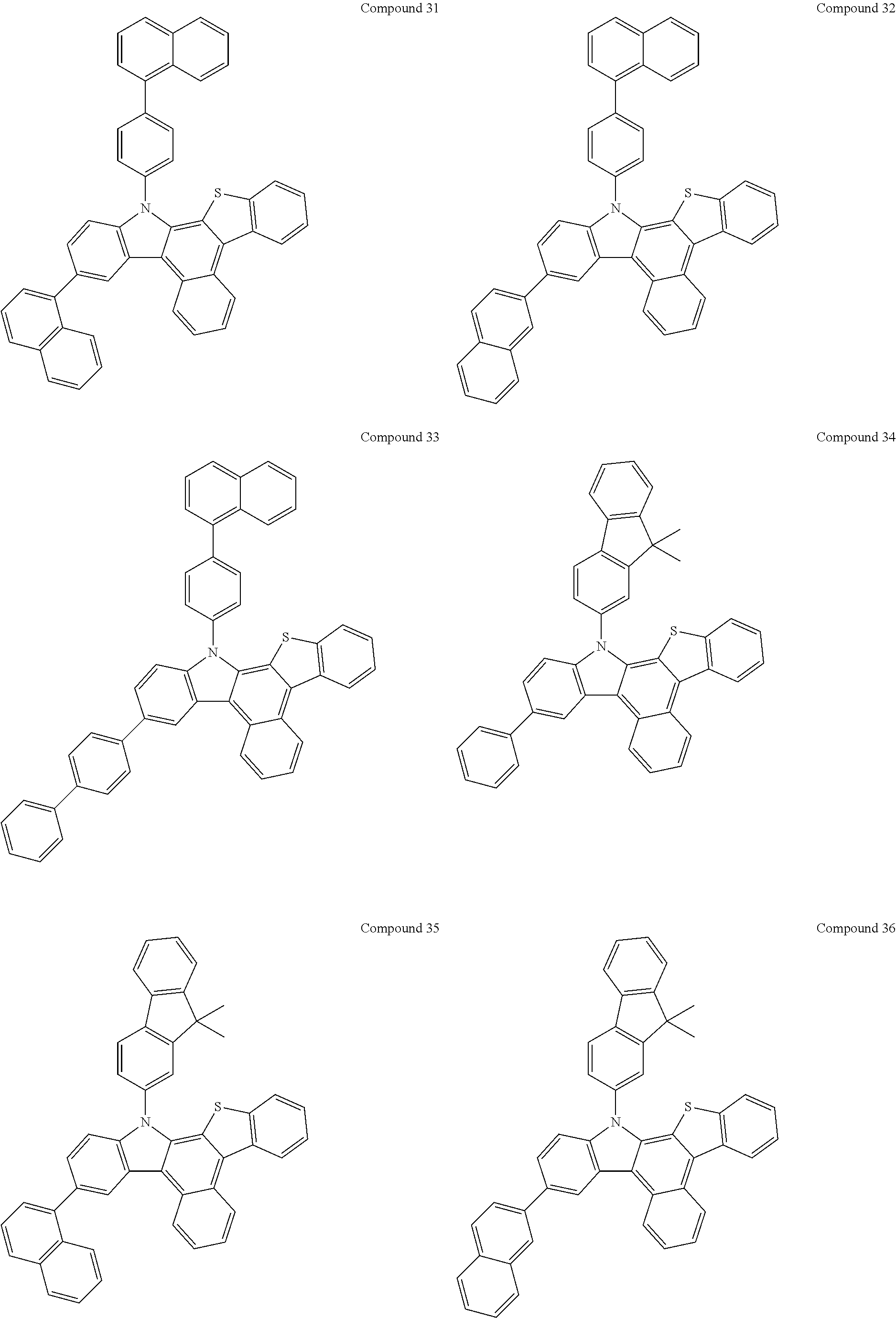 [SMILES: c1ccc2c(-c3ccc(-n4c5ccc(-c6cccc7ccccc67)cc5c5c6ccccc6c6c7ccccc7sc6c54)cc3)cccc2c1 ; c1ccc2cc(-c3ccc4c(c3)c3c5ccccc5c5c6ccccc6sc5c3n4-c3ccc(-c4cccc5ccccc45)cc3)ccc2c1 ; c1ccc(-c2ccc(-c3ccc4c(c3)c3c5ccccc5c5c6ccccc6sc5c3n4-c3ccc(-c4cccc5ccccc45)cc3)cc2)cc1 ; CC1(C)c2ccccc2-c2ccc(-n3c4ccc(-c5ccccc5)cc4c4c5ccccc5c5c6ccccc6sc5c43)cc21 ; CC1(C)c2ccccc2-c2ccc(-n3c4ccc(-c5cccc6ccccc56)cc4c4c5ccccc5c5c6ccccc6sc5c43)cc21 ; CC1(C)c2ccccc2-c2ccc(-n3c4ccc(-c5ccc6ccccc6c5)cc4c4c5ccccc5c5c6ccccc6sc5c43)cc21]

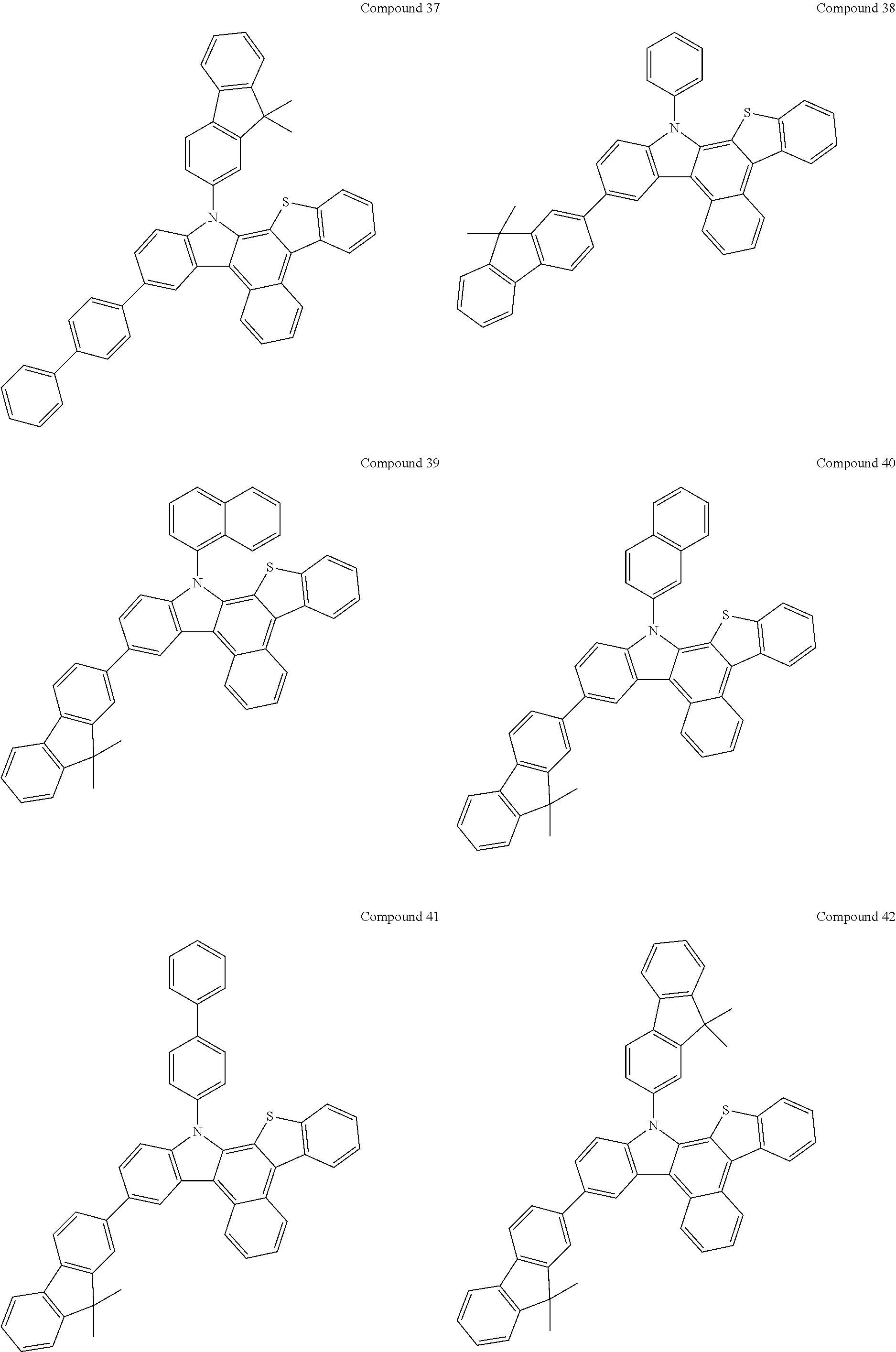

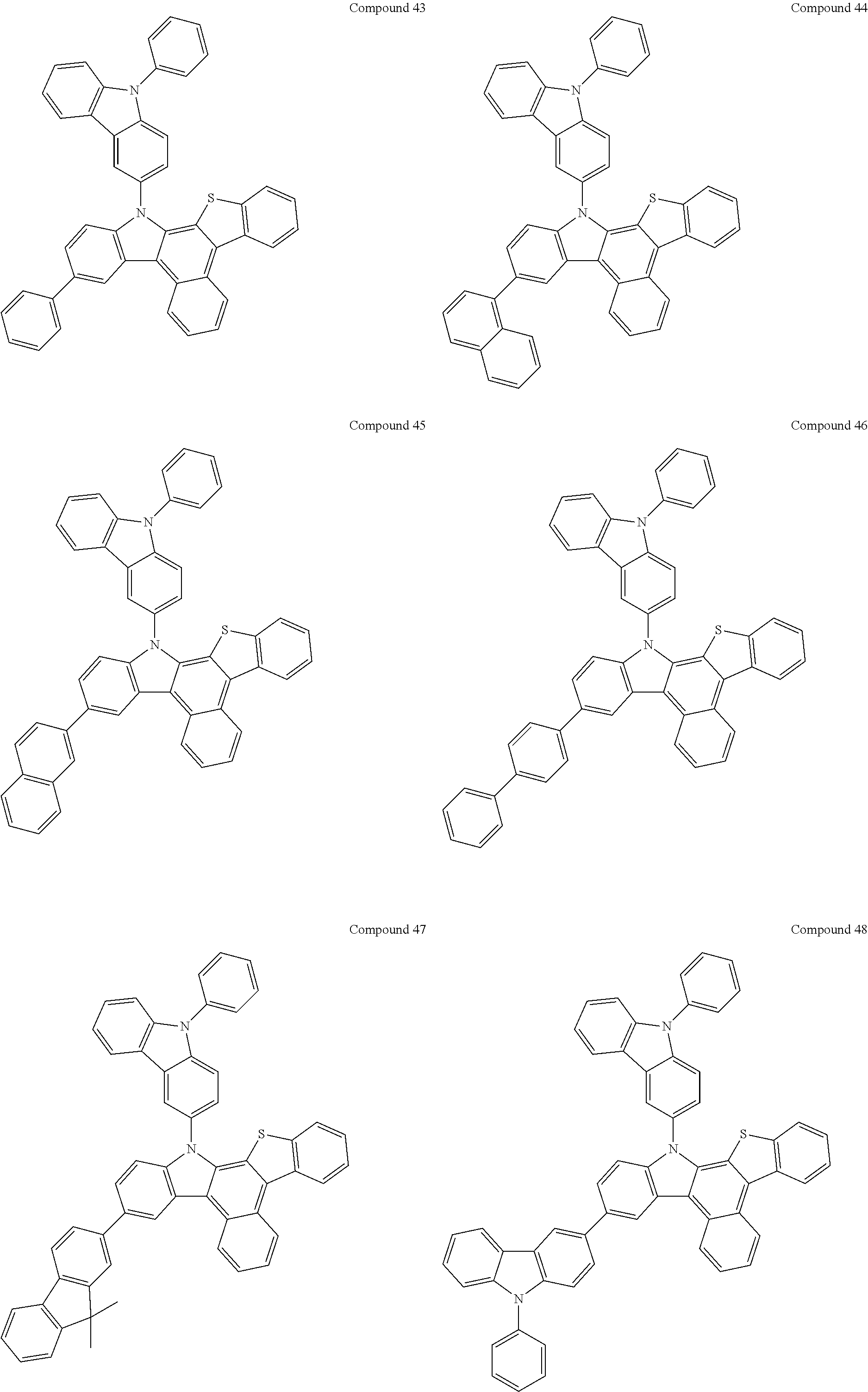

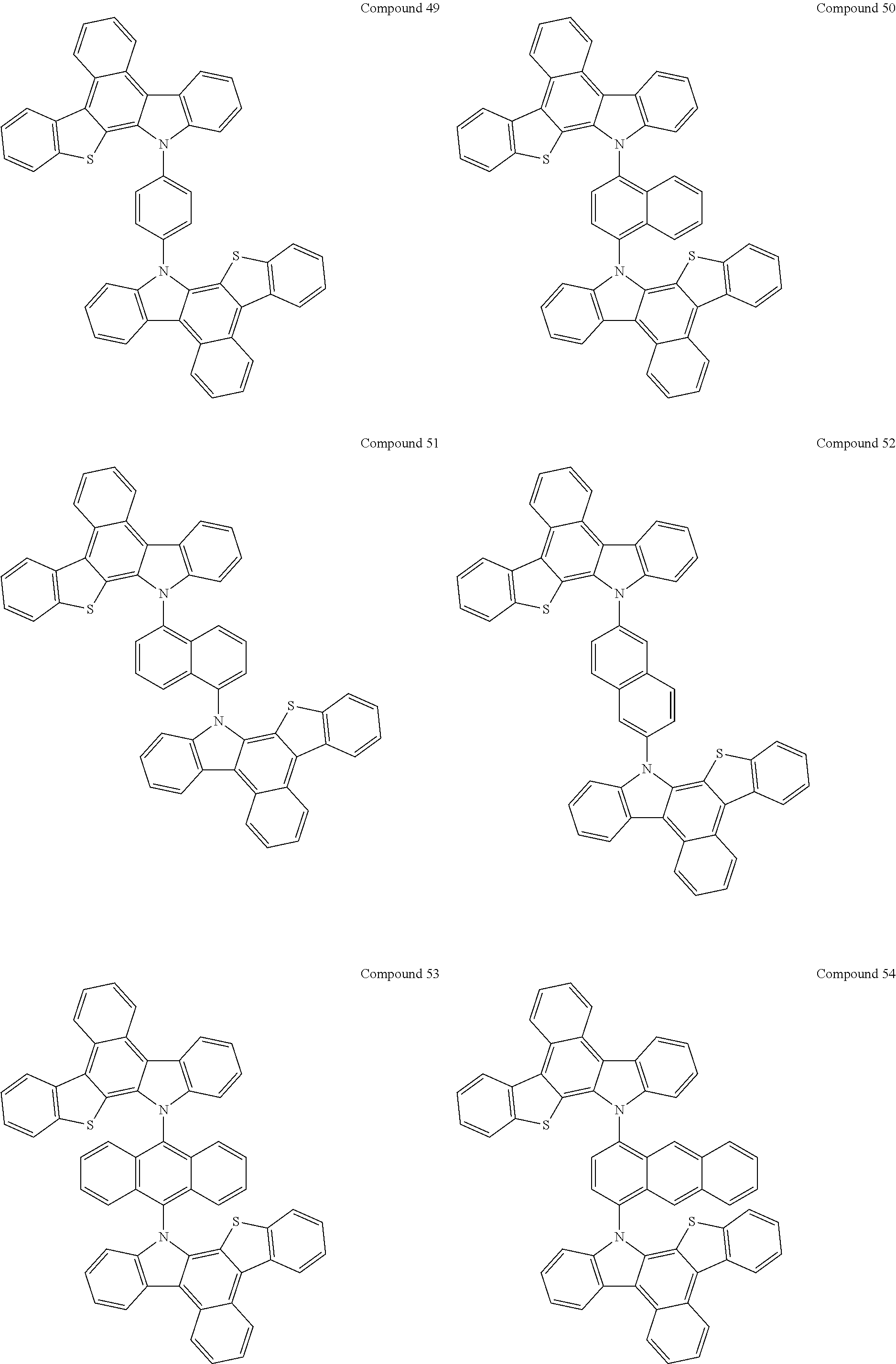

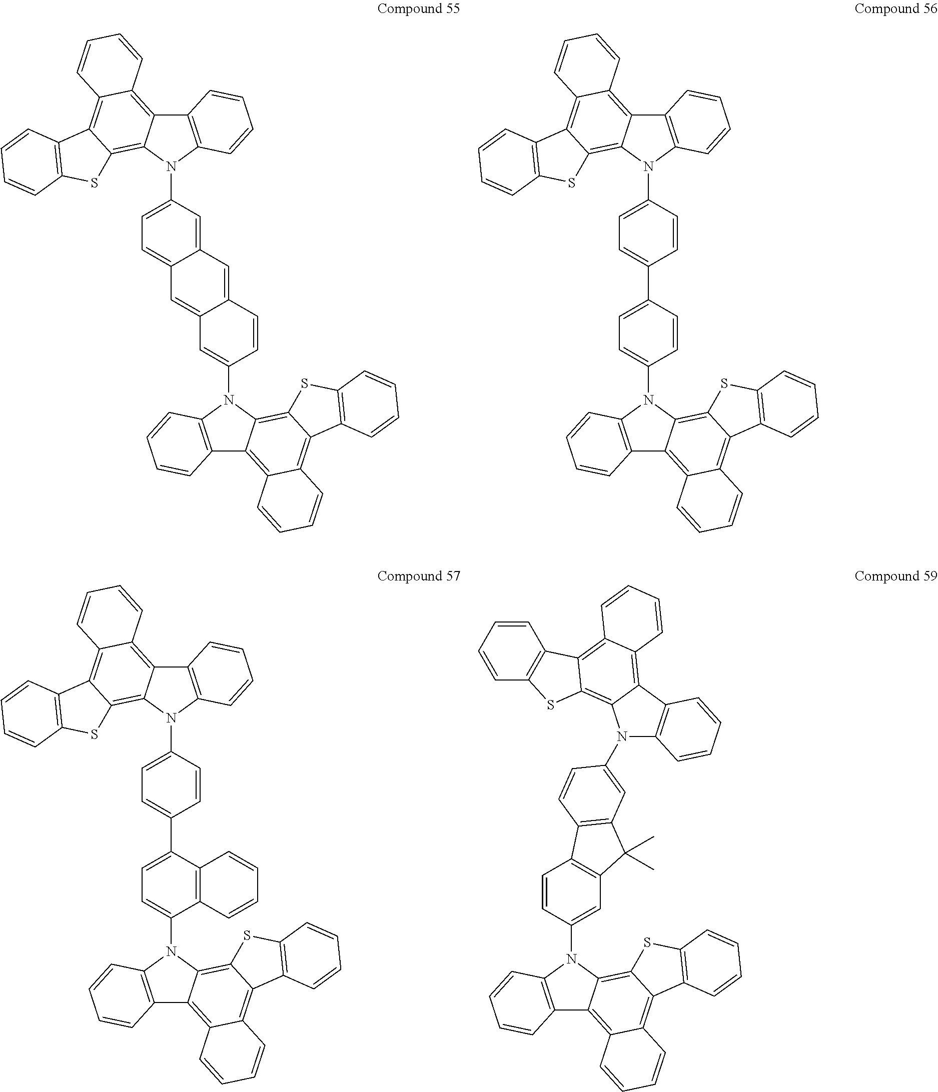 [SMILES: c1ccc2c(c1)sc1c2c2ccccc2c2c3ccccc3n(-c3ccc4cc5cc(-n6c7ccccc7c7c8ccccc8c8c9ccccc9sc8c76)ccc5cc4c3)c12 ; c1ccc2c(c1)sc1c2c2ccccc2c2c3ccccc3n(-c3ccc(-c4ccc(-n5c6ccccc6c6c7ccccc7c7c8ccccc8sc7c65)cc4)cc3)c12 ; c1ccc2c(c1)sc1c2c2ccccc2c2c3ccccc3n(-c3ccc(-c4ccc(-n5c6ccccc6c6c7ccccc7c7c8ccccc8sc7c65)c5ccccc45)cc3)c12 ; CC1(C)c2cc(-n3c4ccccc4c4c5ccccc5c5c6ccccc6sc5c43)ccc2-c2ccc(-n3c4ccccc4c4c5ccccc5c5c6ccccc6sc5c43)cc21]

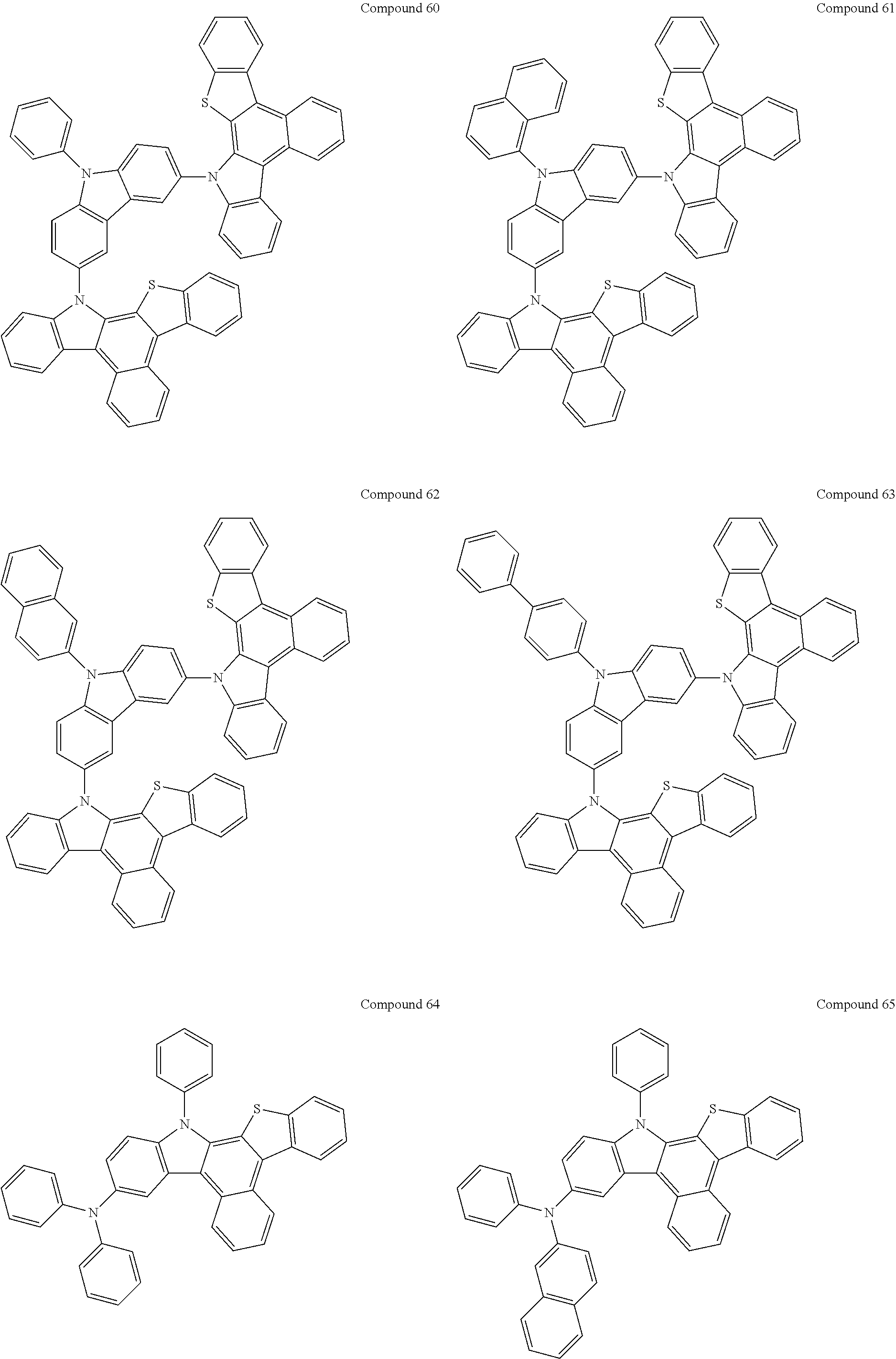

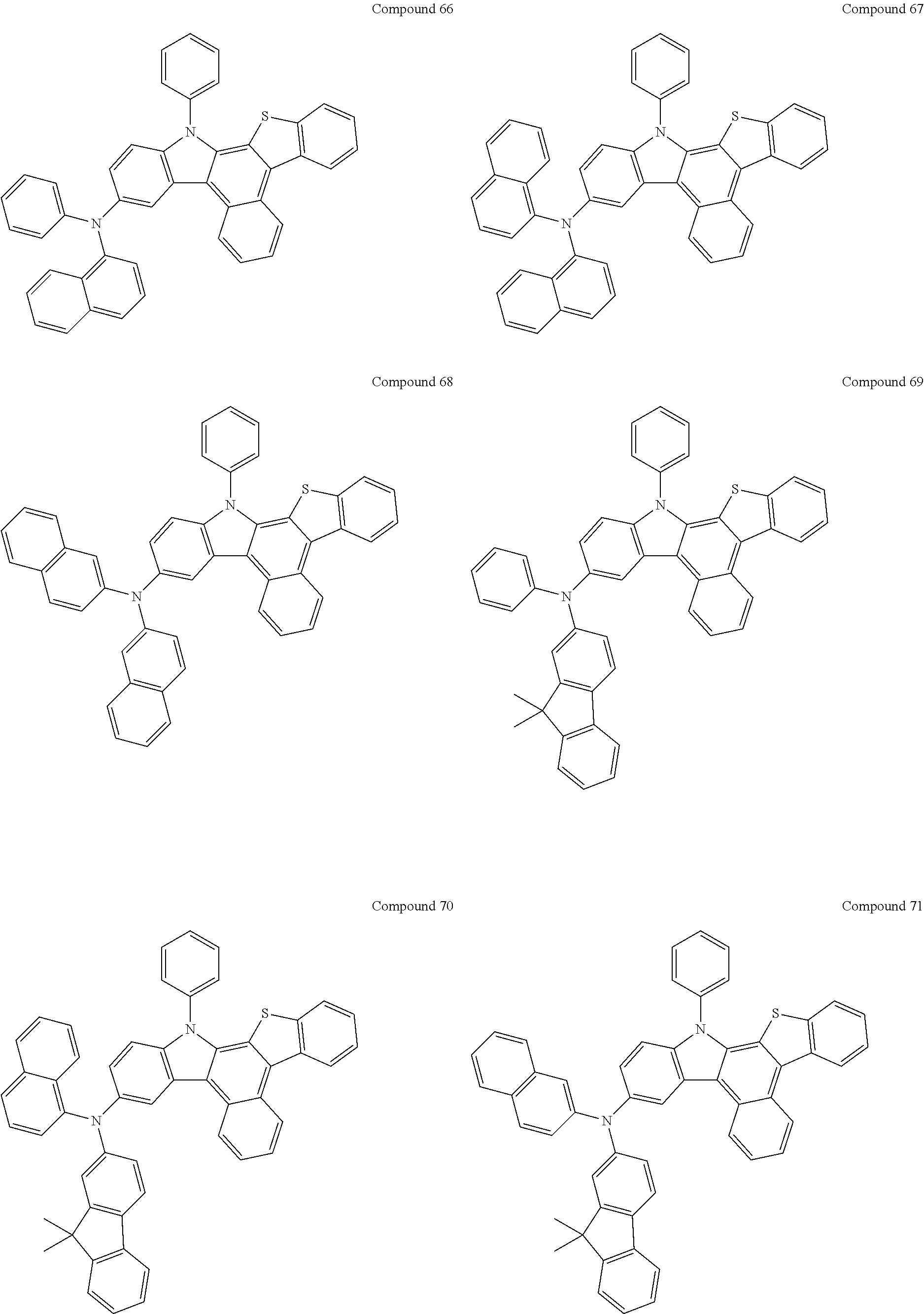

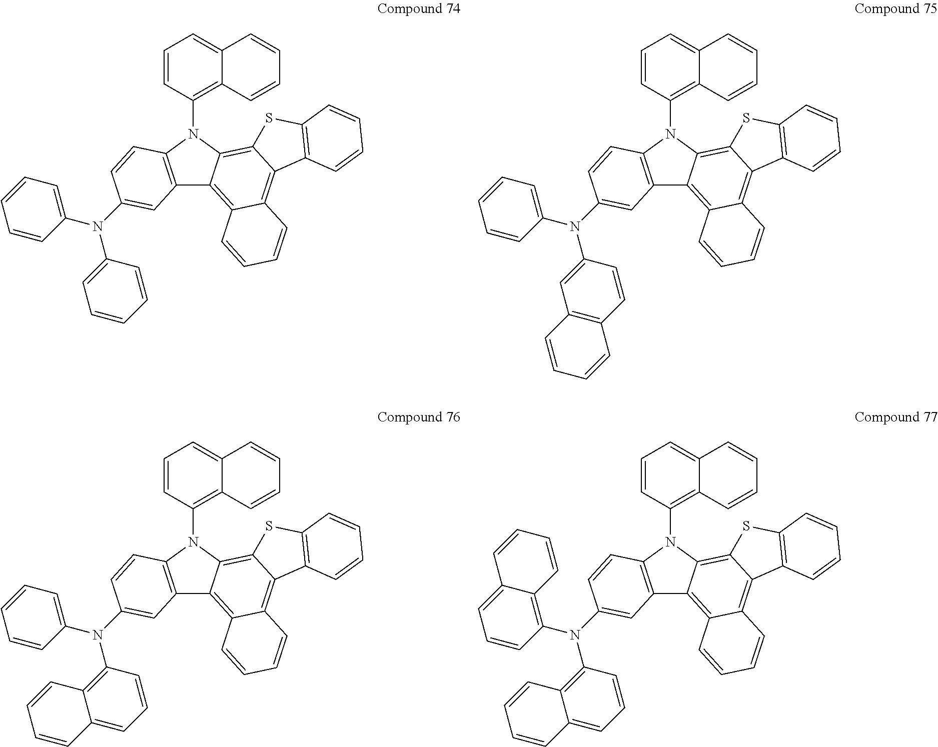 [SMILES: c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1 ; c1ccc(N(c2ccc3c(c2)c2c4ccccc4c4c5ccccc5sc4c2n3-c2cccc3ccccc23)c2cccc3ccccc23)cc1 ; c1ccc2c(N(c3ccc4c(c3)c3c5ccccc5c5c6ccccc6sc5c3n4-c3cccc4ccccc34)c3cccc4ccccc34)cccc2c1]

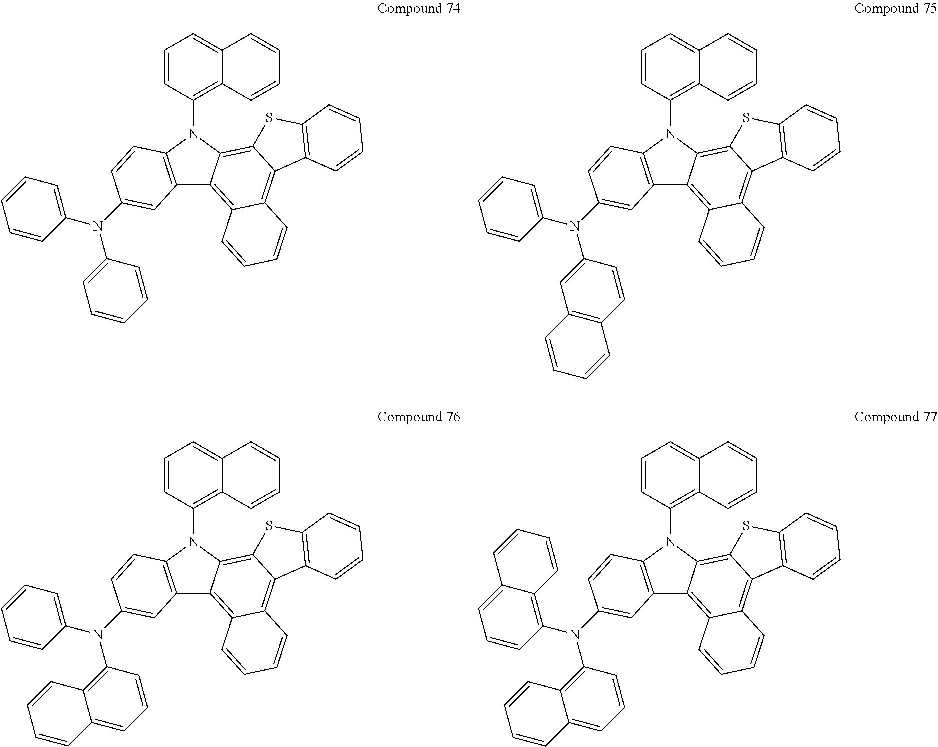 [SMILES: c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1 ; c1ccc(N(c2ccc3c(c2)c2c4ccccc4c4c5ccccc5sc4c2n3-c2cccc3ccccc23)c2cccc3ccccc23)cc1 ; c1ccc2c(N(c3ccc4c(c3)c3c5ccccc5c5c6ccccc6sc5c3n4-c3cccc4ccccc34)c3cccc4ccccc34)cccc2c1]

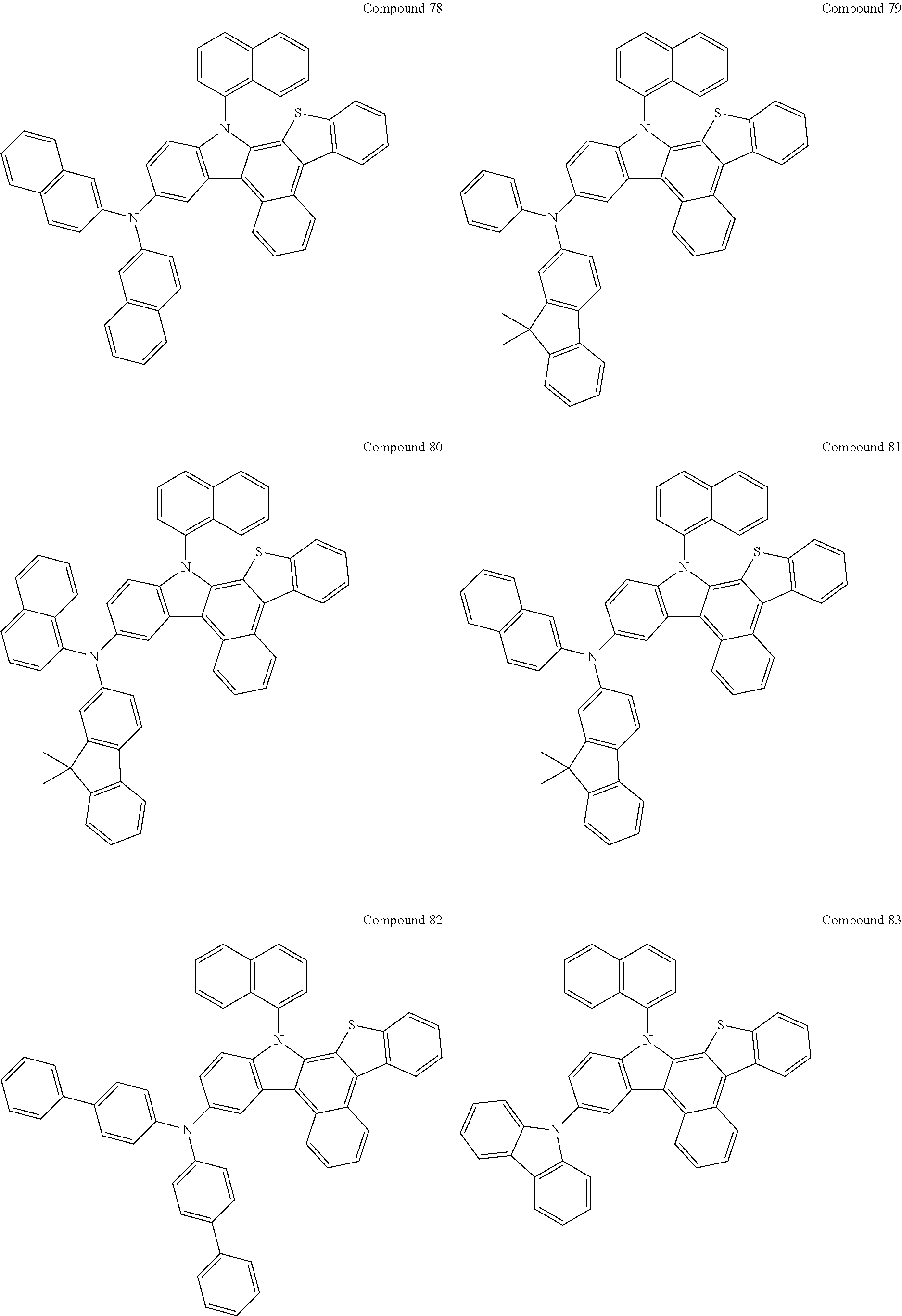

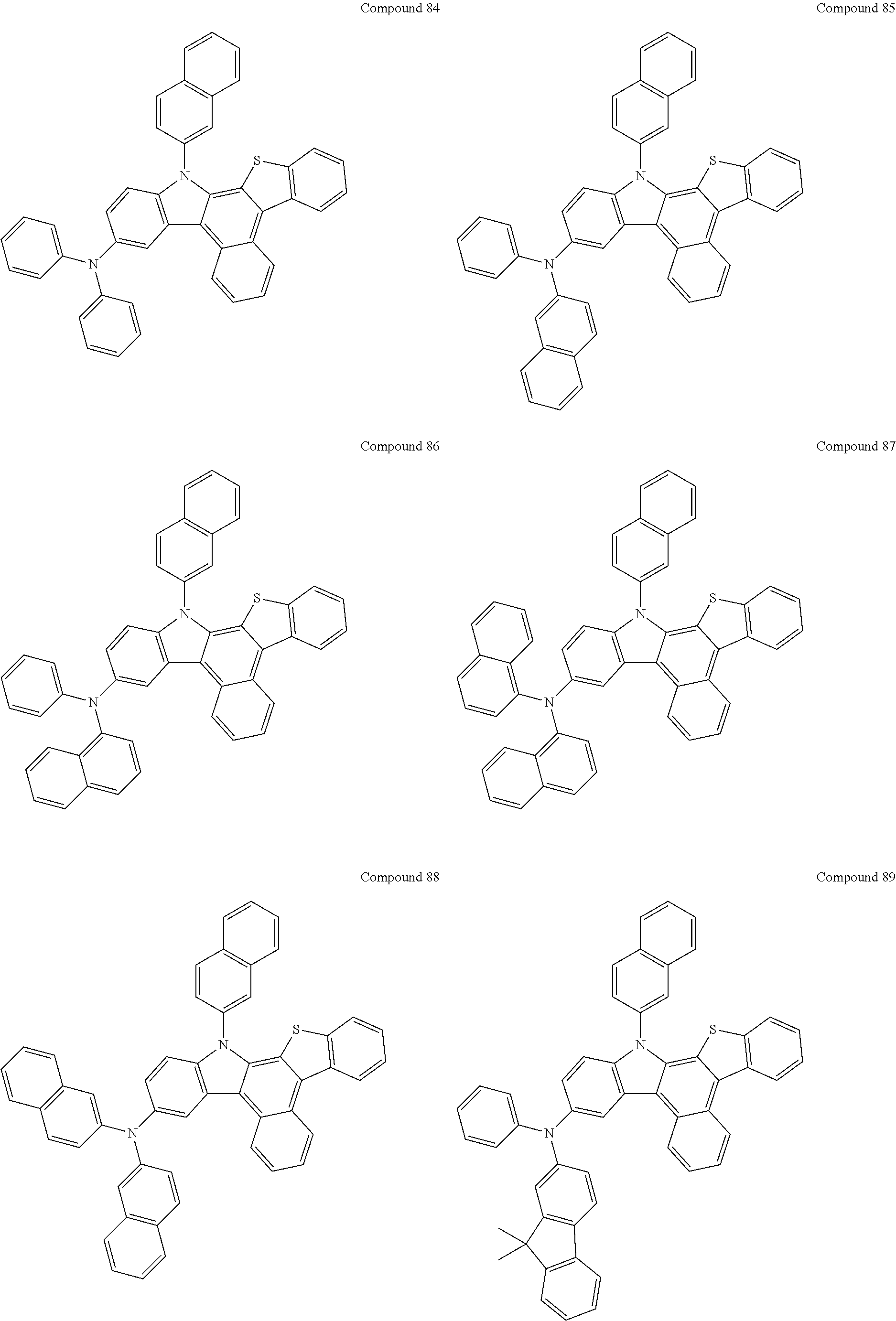

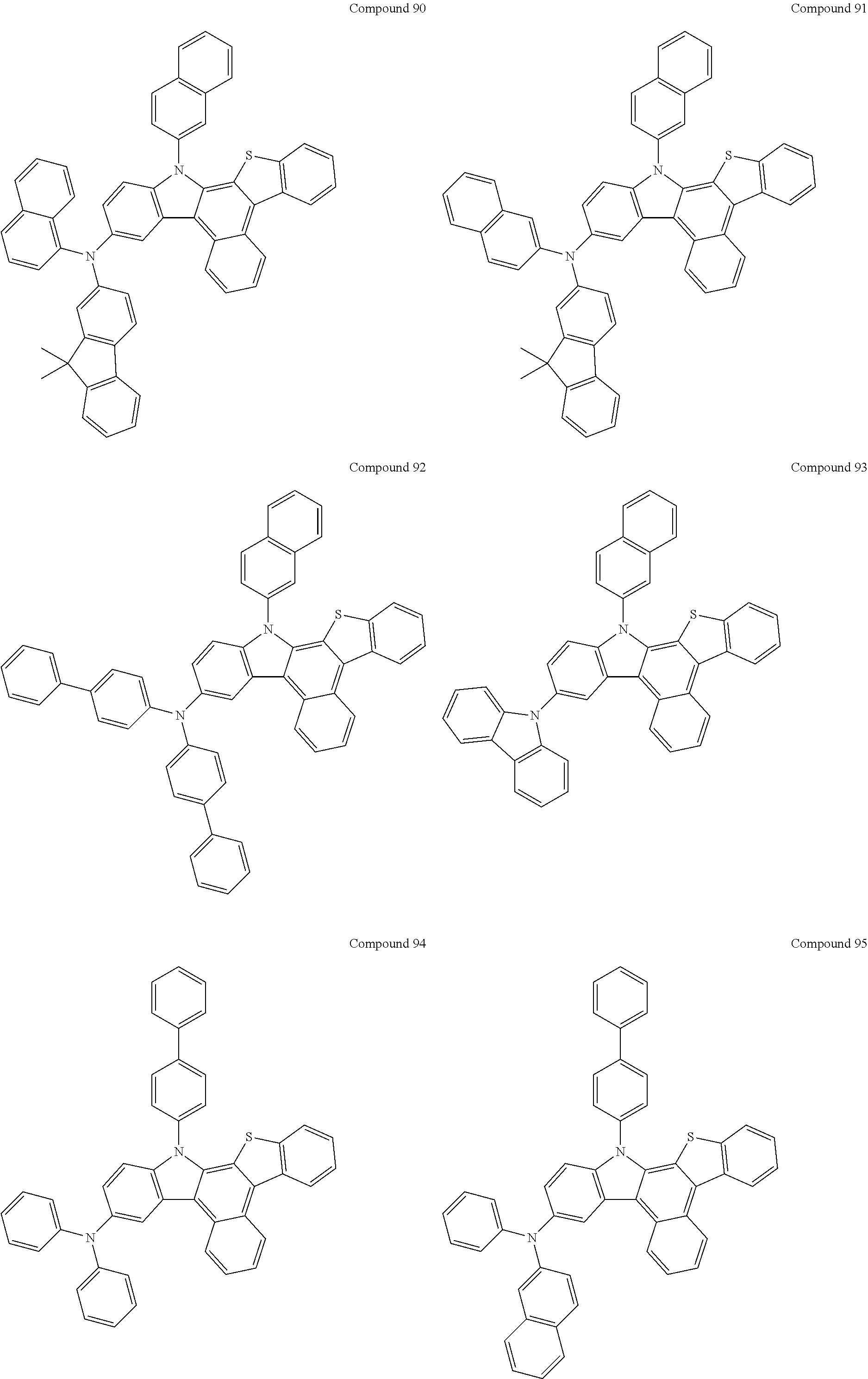

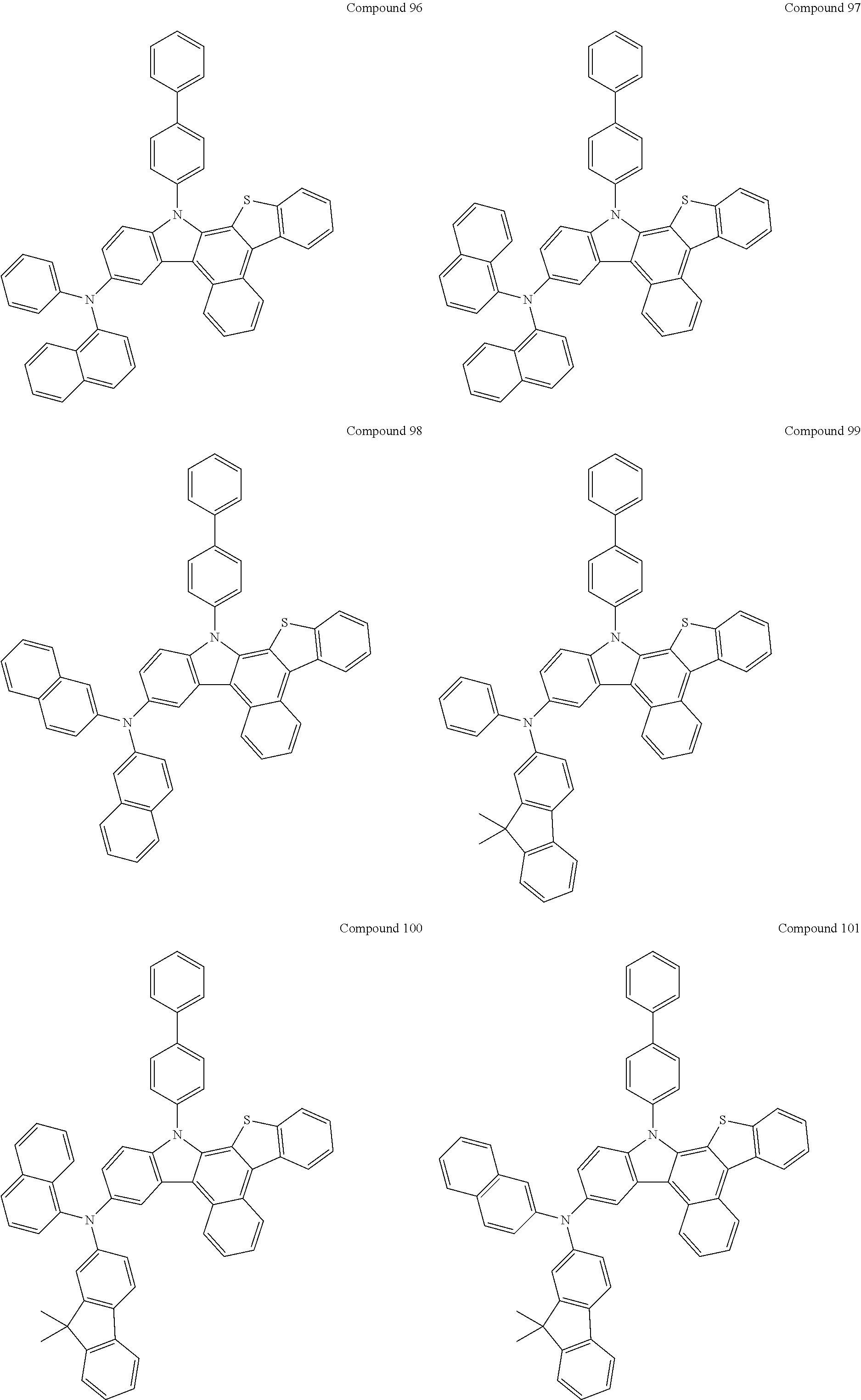

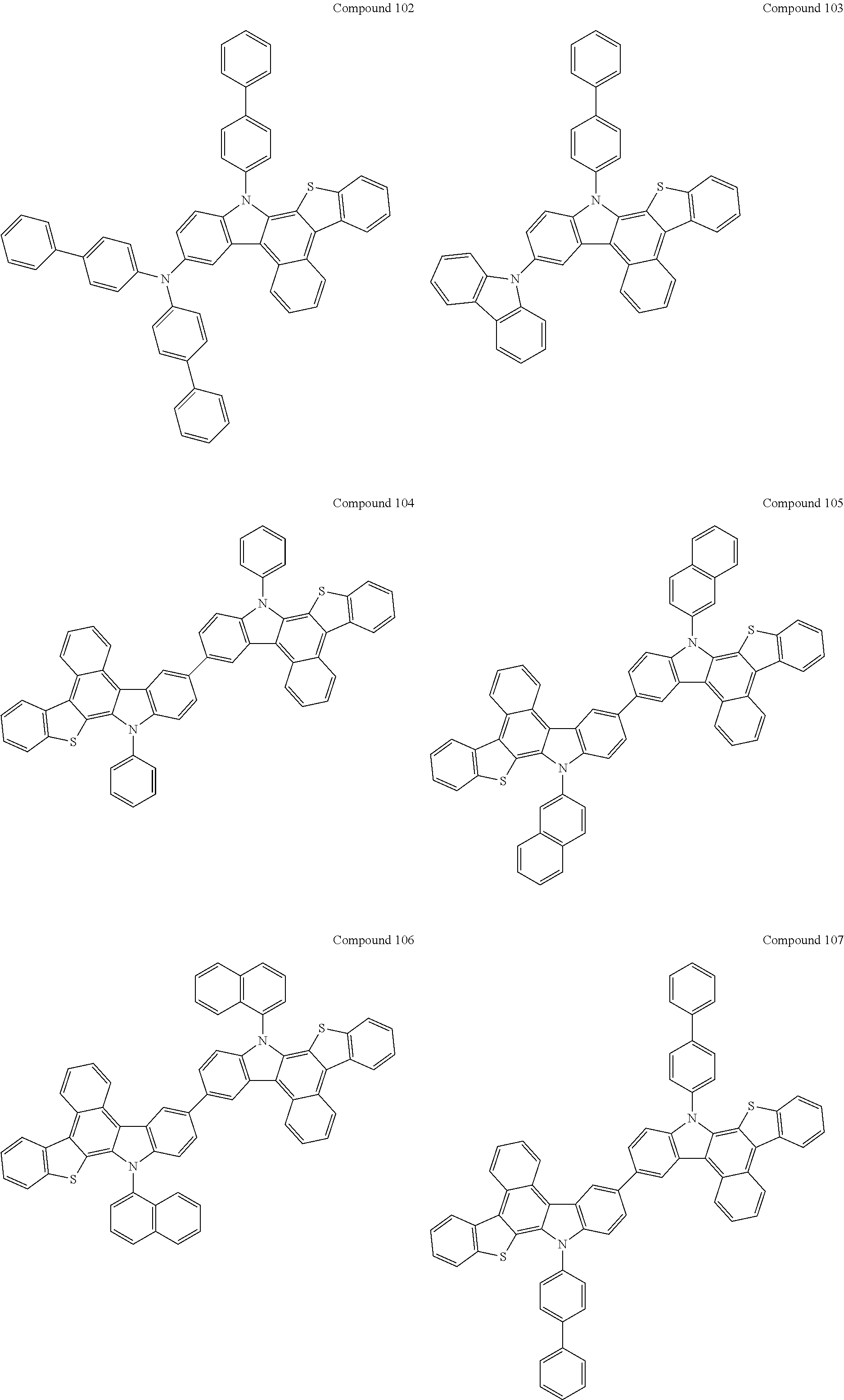

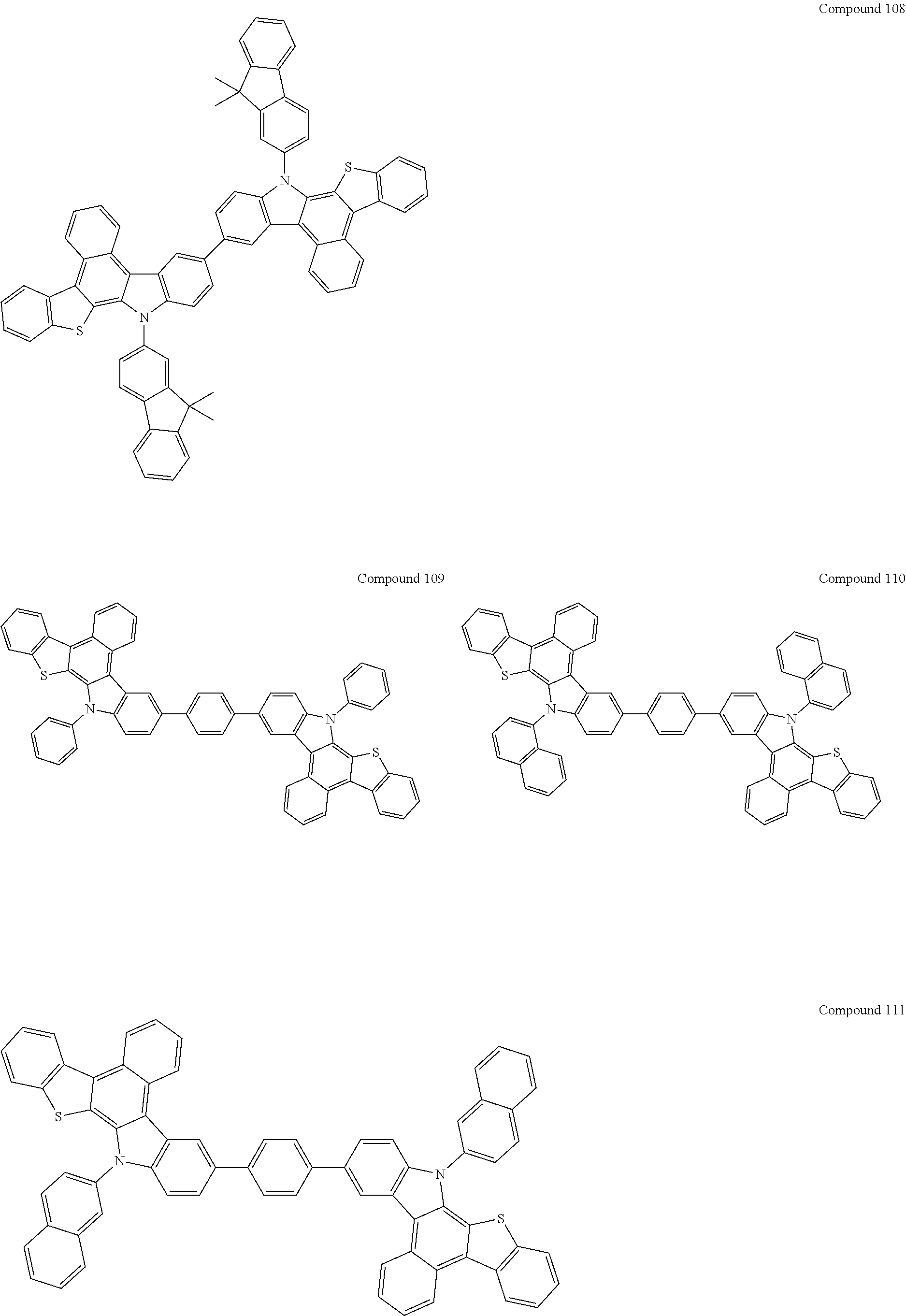 [SMILES: CC1(C)c2ccccc2-c2ccc(-n3c4ccc(-c5ccc6c(c5)c5c7ccccc7c7c8ccccc8sc7c5n6-c5ccc6c(c5)C(C)(C)c5ccccc5-6)cc4c4c5ccccc5c5c6ccccc6sc5c43)cc21 ; c1ccc(-n2c3ccc(-c4ccc(-c5ccc6c(c5)c5c7ccccc7c7c8ccccc8sc7c5n6-c5ccccc5)cc4)cc3c3c4ccccc4c4c5ccccc5sc4c32)cc1 ; c1ccc2c(-n3c4ccc(-c5ccc(-c6ccc7c(c6)c6c8ccccc8c8c9ccccc9sc8c6n7-c6cccc7ccccc67)cc5)cc4c4c5ccccc5c5c6ccccc6sc5c43)cccc2c1 ; c1ccc2cc(-n3c4ccc(-c5ccc(-c6ccc7c(c6)c6c8ccccc8c8c9ccccc9sc8c6n7-c6ccc7ccccc7c6)cc5)cc4c4c5ccccc5c5c6ccccc6sc5c43)ccc2c1]

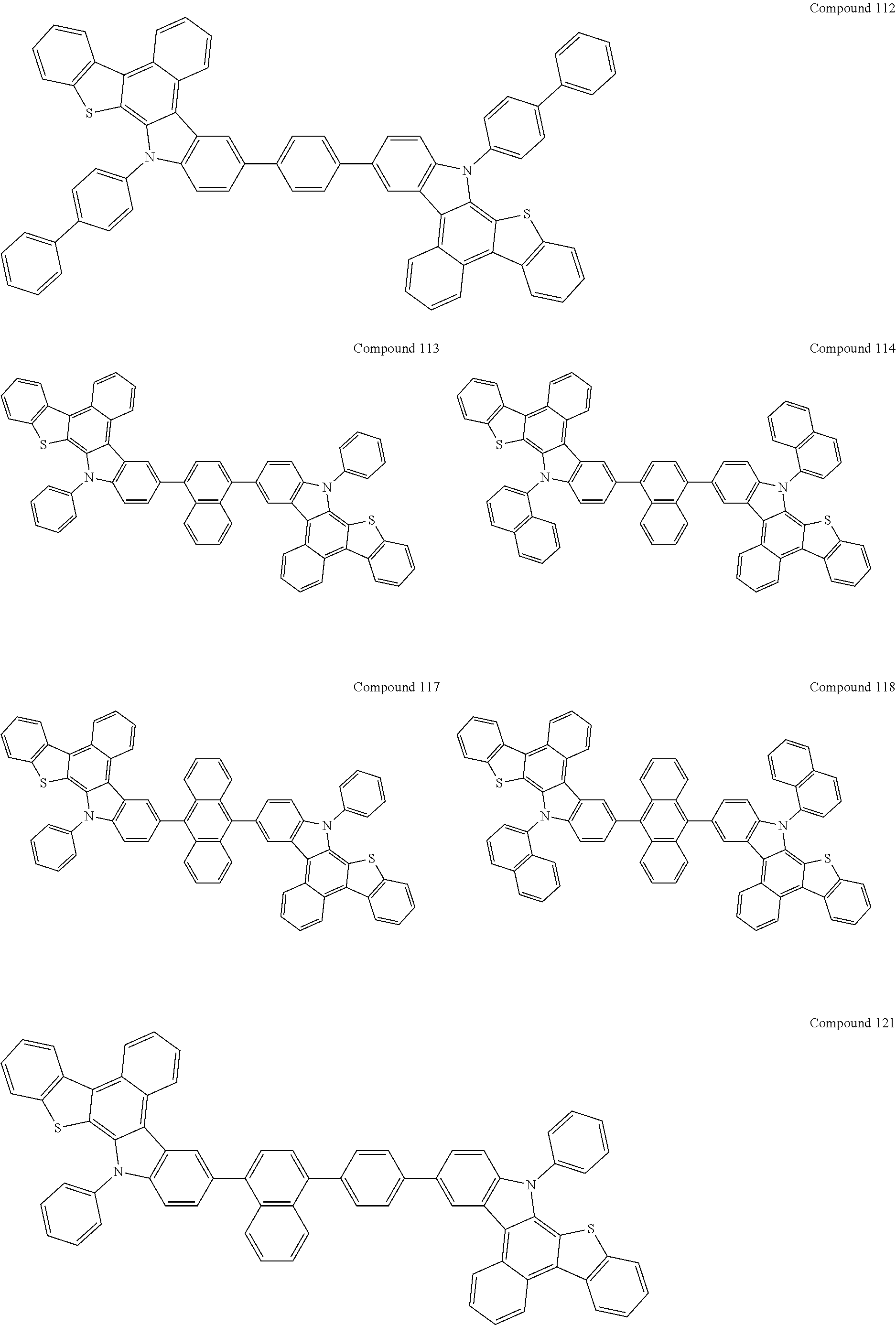

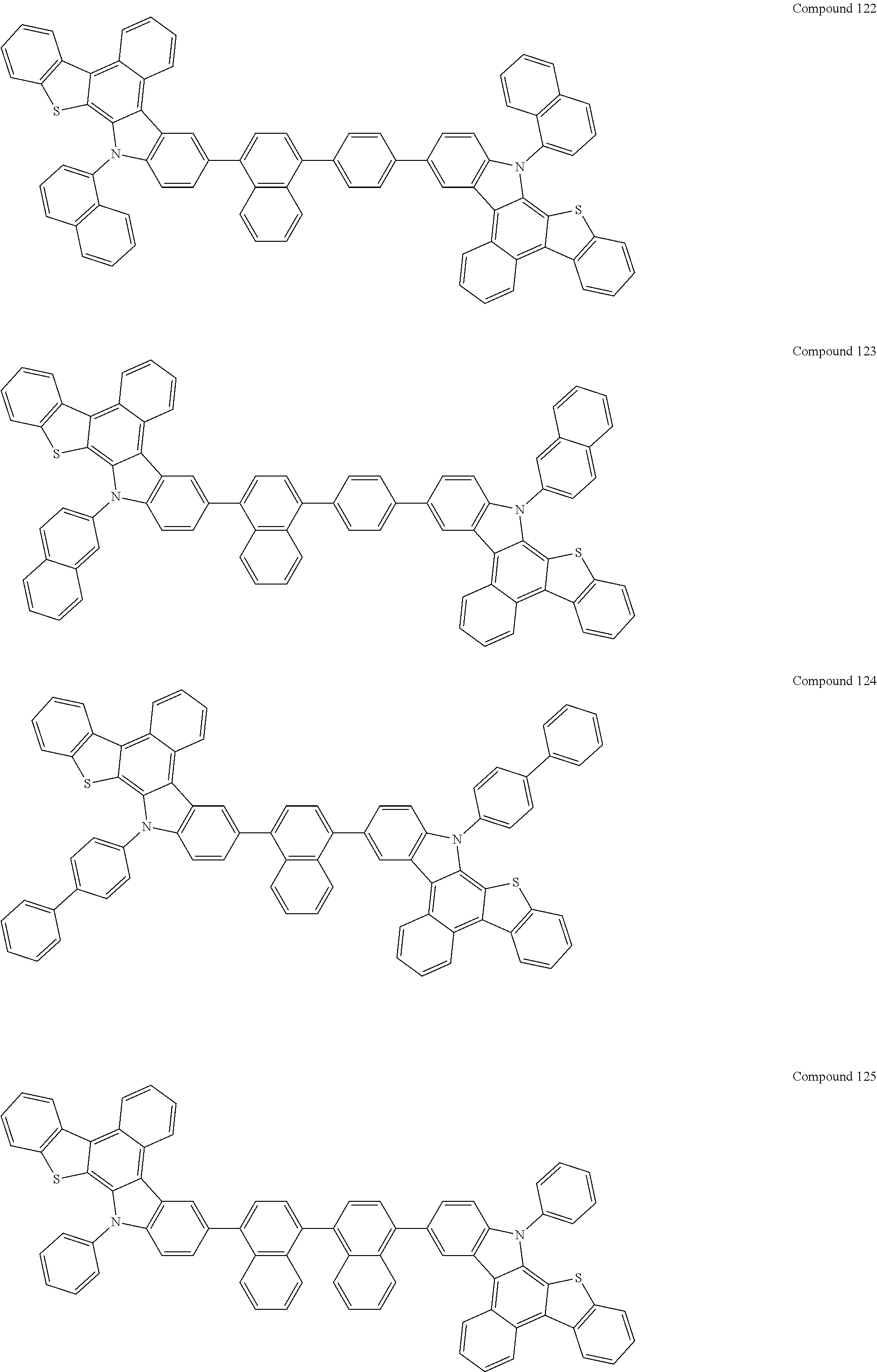

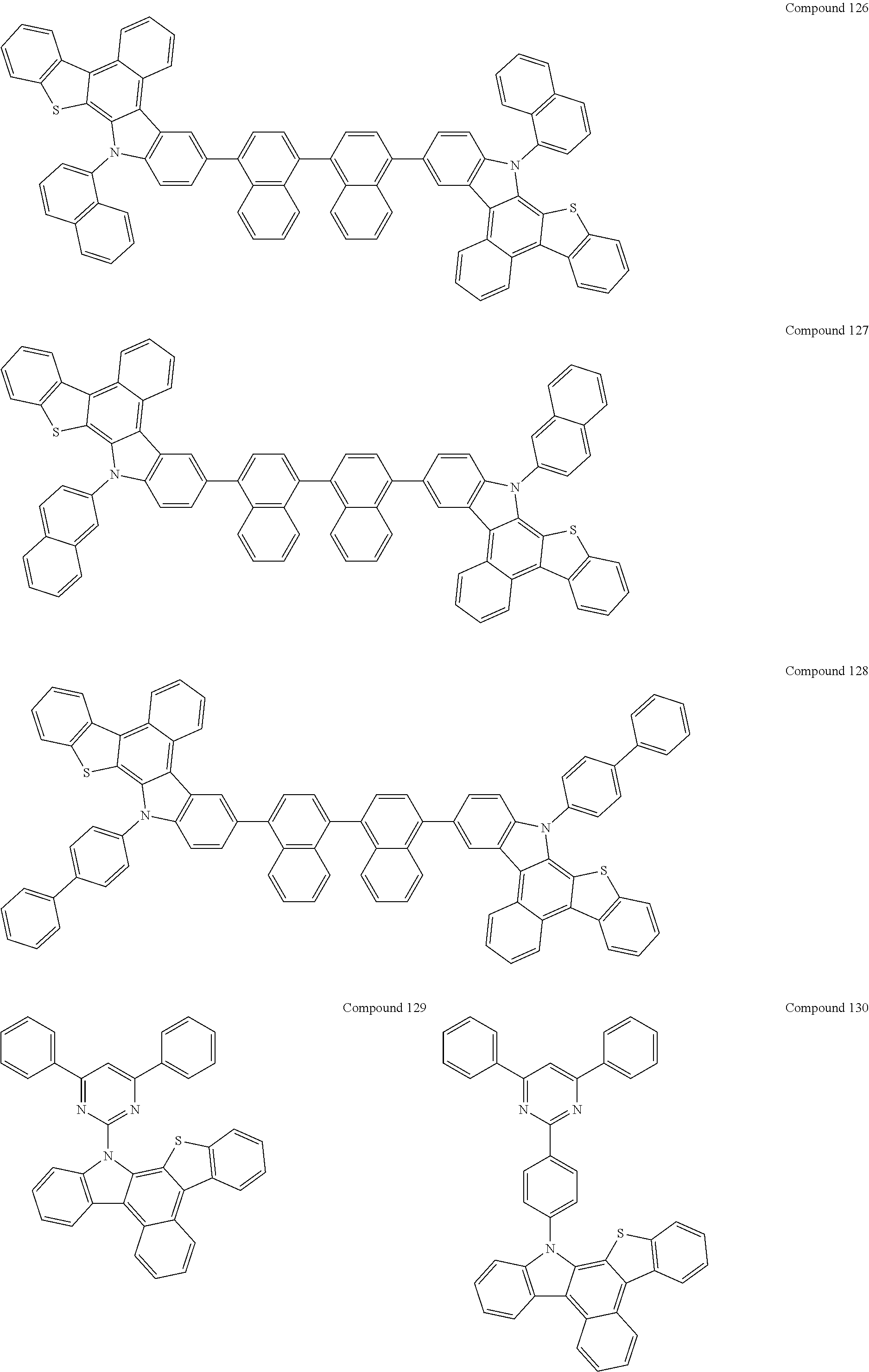

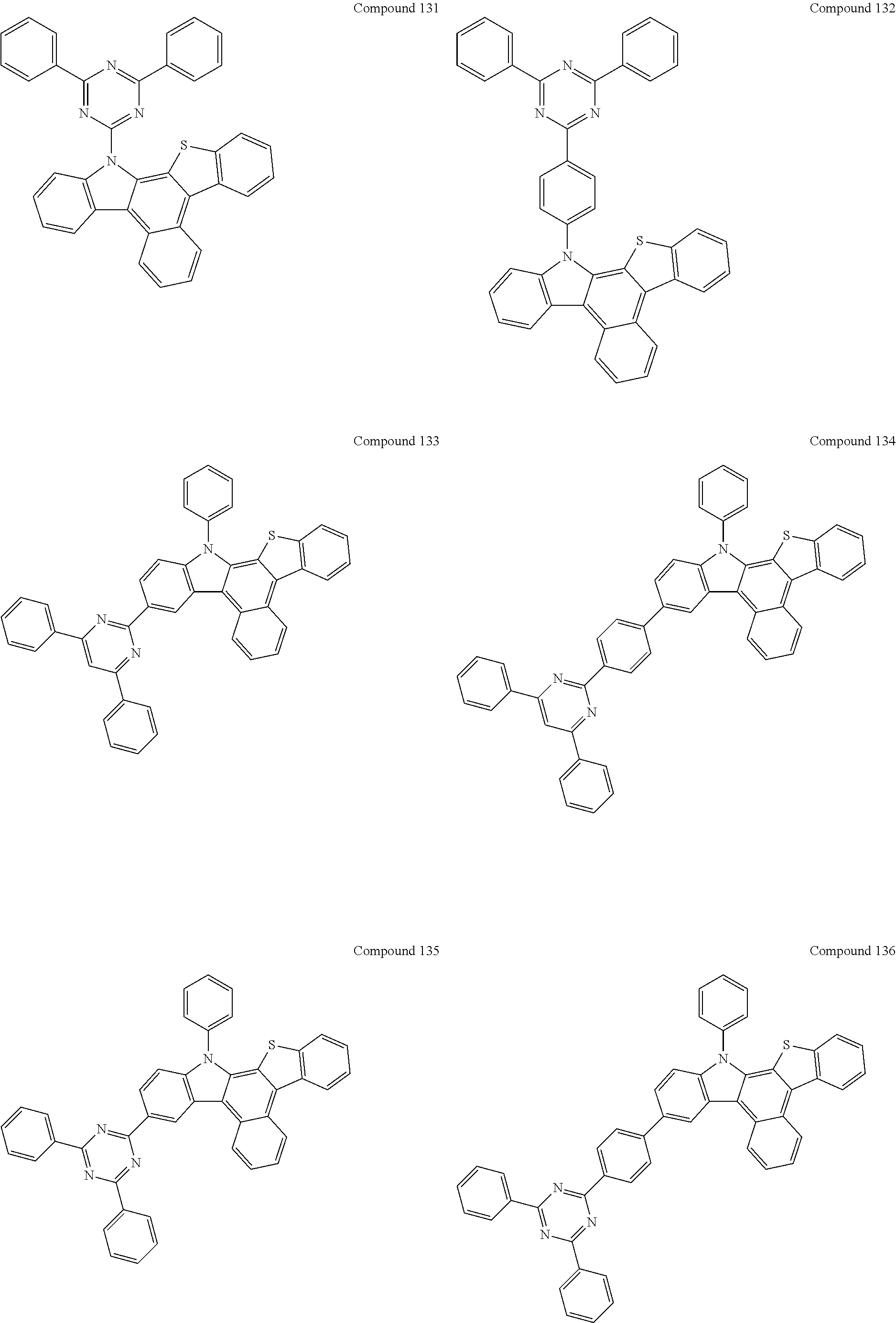

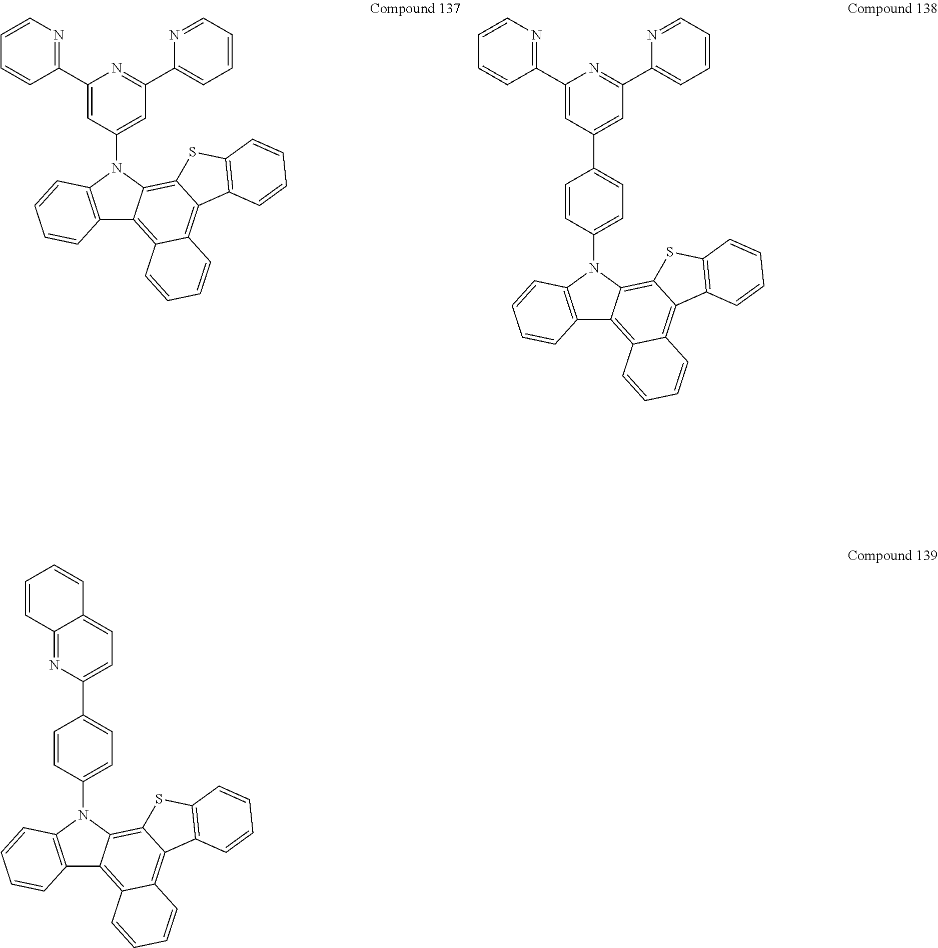 [SMILES: c1ccc(-c2cc(-n3c4ccccc4c4c5ccccc5c5c6ccccc6sc5c43)cc(-c3ccccn3)n2)nc1 ; c1ccc(-c2cc(-c3ccc(-n4c5ccccc5c5c6ccccc6c6c7ccccc7sc6c54)cc3)cc(-c3ccccn3)n2)nc1 ; c1ccc2nc(-c3ccc(-n4c5ccccc5c5c6ccccc6c6c7ccccc7sc6c54)cc3)ccc2c1]

An electron transport region ETR may be provided on the first host layer HOL1. The electron transport region ETR may include at least one of a hole blocking layer, an electron transport layer ETL, and an electron injection layer EIL, without limitation.

A cathode CAT may be provided on the electron transport region ETR. The cathode CAT may be a common electrode or a cathode. Even though not shown, the cathode CAT may be connected to an auxiliary electrode.

On the cathode CAT, a sealing layer SL may be provided. The sealing layer SL may cover the cathode CAT. The sealing layer SL may include at least one layer of an organic layer, an inorganic layer, and a hybrid layer including both an organic material and an inorganic material. The sealing layer SL may be a single layer, or a multilayer. The sealing layer SL may be, for example, a thin film sealing layer. The sealing layer SL may passivate the organic light emitting device OEL.

Referring to FIGS. 7B and 7C, the organic light emitting device OEL according to an embodiment may further include a second host layer HOL2 between the hole transport region HTR and the emission layer EML.

The second host layer HOL2 may include a third host. The second host layer HOL2 may not include a dopant. The second host layer HOL2 may not include the dopant included in the emission layer EML and a dopant different from the dopant included in the emission layer EML. The third host may be different from the first host and the second host, or may be the same as at least one of the first host or the second host. The third host may be represented by Formula 1. In an implementation, the third host may include at least one compound in Compound Group 1.

Referring to FIG. 7C, the emission layer EML may include a first sub emission layer SML1, a third host layer HOL3, and a second sub emission layer SML2. The first sub emission layer SML1 may include a first host and a dopant. The third host layer HOL3 may be provided on the first sub emission layer SML1 and may include a fourth host. The second sub emission layer SML2 may be provided on the third host layer HOL3 and include a first host and a dopant.

The third host layer HOL3 may include the fourth host. The third host layer HOL3 may not include a dopant. The third host layer HOL3 may not include the dopant included in the emission layer EML and a dopant different from the dopant included in the emission layer EML. The fourth host may be different from each of the first host and the third host, and/or may be the same as at least one of the first host or the third host. The fourth host may be represented by Formula 1. The fourth host may include at least one compound in Compound Group 1.

At high temperatures, the hole mobility of a display device may decrease, and the adhesiveness of an electron transport region and a cathode may be improved. Generally, electron mobility may be higher than hole mobility at high temperatures. Accordingly, the amount of electrons injected to the emission layer may increase at high temperatures, and the equilibrium of holes and electrons in the emission layer may be destroyed, thereby decreasing the emission efficiency of the organic light emitting device.

In some display devices, an emission layer and an electron transport region may make direct contact, and the amount of electrons injected into the emission layer at high temperatures may increase, thereby destroying the equilibrium of holes and electrons in the emission layer decreasing the emission efficiency of the display device.

The display device according to an embodiment may include a first host layer (including a second host represented by Formula 1) between an emission layer and an electron transport region. At high temperatures, the mobility of the second host included in the first host layer may be lower than electron mobility. For example, at high temperatures, the second hose included in the first host layer may lower electron mobility of electrons in the first host layer. Accordingly, the first host layer may help prevent the increase of the amount of electrons injected from the electron transport region into the emission layer. Accordingly, the display device according to an embodiment may help maintain emission efficiency at high temperatures.

The organic light emitting device according to an embodiment may maintain emission efficiency at high temperatures.

The display device according to an embodiment may maintain emission efficiency at high temperatures.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. An organic light emitting device, comprising:
an anode;
a hole transport region on the anode;
an emission layer provided on the hole transport region, the emission layer including a first host and a dopant;
a first host layer on the emission layer, the first host layer including a second host;
an electron transport region on the first host layer; and
a cathode on the electron transport region,
wherein the second host is represented by the following Formula 1: 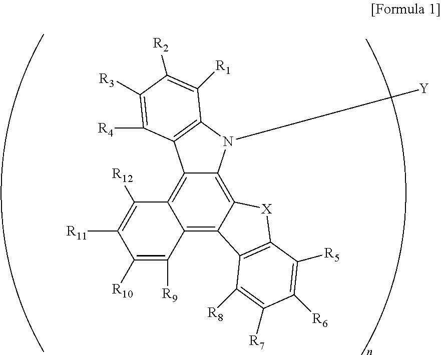
wherein, in Formula 1,
R₁, R₂, R₃, R₄, R₅, R₆, R₇, R₃, R₉, R₁₀, R₁₁, and R₁₂ are each independently a hydrogen atom, a halogen atom, a cyano group, an alkoxy group, a thiol group, a substituted or unsubstituted alkyl group having 1 to 50 carbon atoms, a substituted or unsubstituted alkoxy group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphorus, or silicon, a substituted or unsubstituted heteroaryl group having 5 to 60 carbon atoms and including at least one of sulfur, nitrogen, oxygen, phosphorus, or silicon, or a substituted or unsubstituted heteroaryloxy group having 5 to 60 carbon atoms and including at least one of sulfur, nitrogen, oxygen, phosphorus, or silicon,
R₁, R₂, R₃, R₄, R₅, R₆, R₇, R₈, R₉, R₁₀, R₁₁, and R₁₂ are separate or adjacent ones thereof are combined to form a ring
X is sulfur, oxygen, or silicon,
Y is a hydrogen atom, a halogen atom, a cyano group, an alkoxy group, a thiol group, a substituted or unsubstituted alkyl group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphorus, or silicon, a substituted or unsubstituted heteroaryl group having 5 to 60 carbon atoms and including at least one of sulfur, nitrogen, oxygen, phosphorus, or silicon, or a substituted or unsubstituted heteroaryloxy group having 5 to 60 carbon atoms and including at least one of sulfur, nitrogen, oxygen, phosphorus, or silicon, and
n is an integer of 1 to 3.

2. The organic light emitting device as claimed in claim 1, wherein the first host layer does not include the dopant.

3. The organic light emitting device as claimed in claim 1, wherein R₁, R₂, R₃, R₄, R₅, R₆, R₇, R₈, R₉, R₁₀, R₁₁, or R₁₂ is combined with an adjacent group to form a ring.

4. The organic light emitting device as claimed in claim 1, wherein the second host includes one of the following Compounds 1 to 57, 59 to 71, 74 to 114, and 117 to 139:

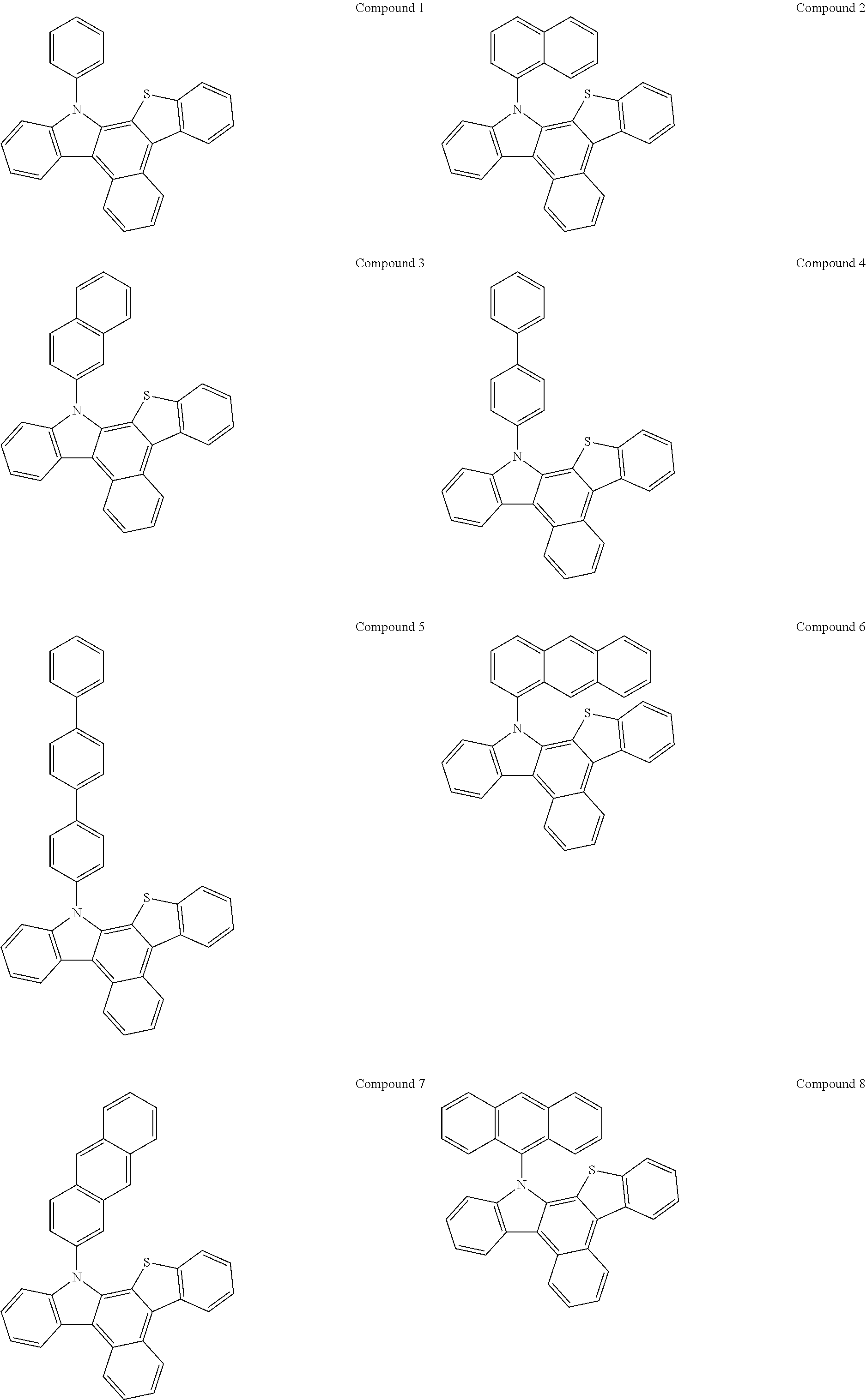

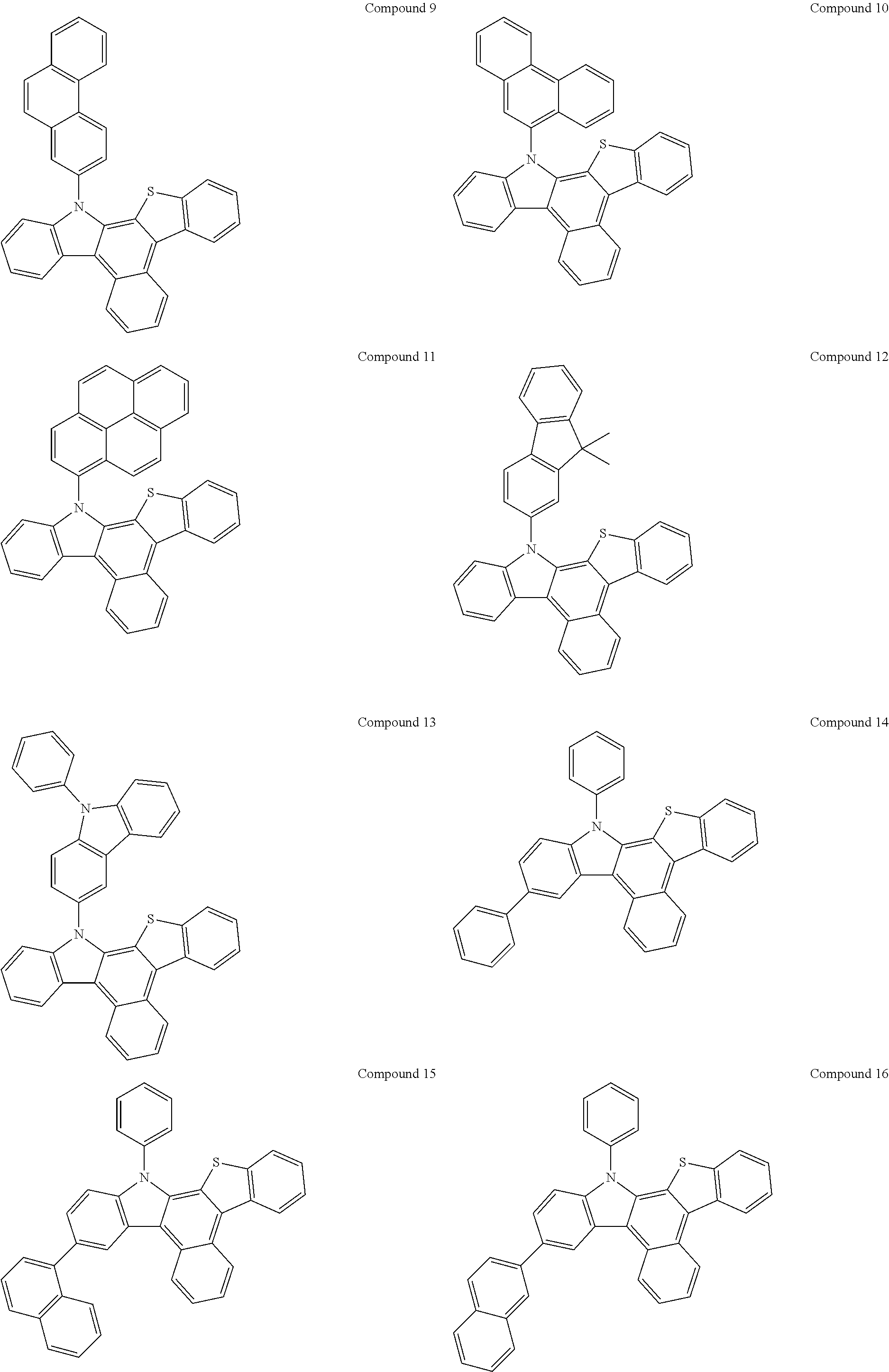

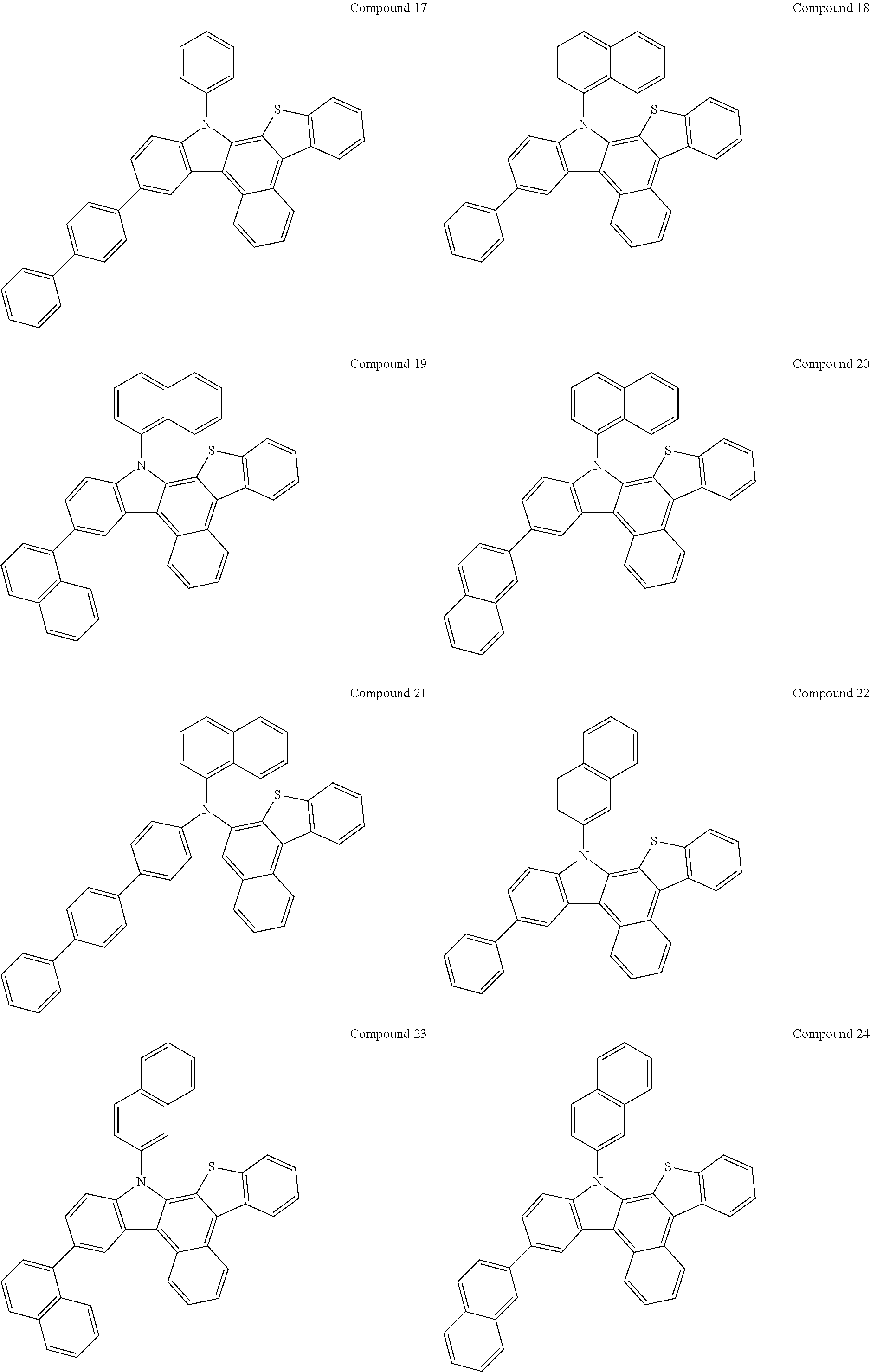

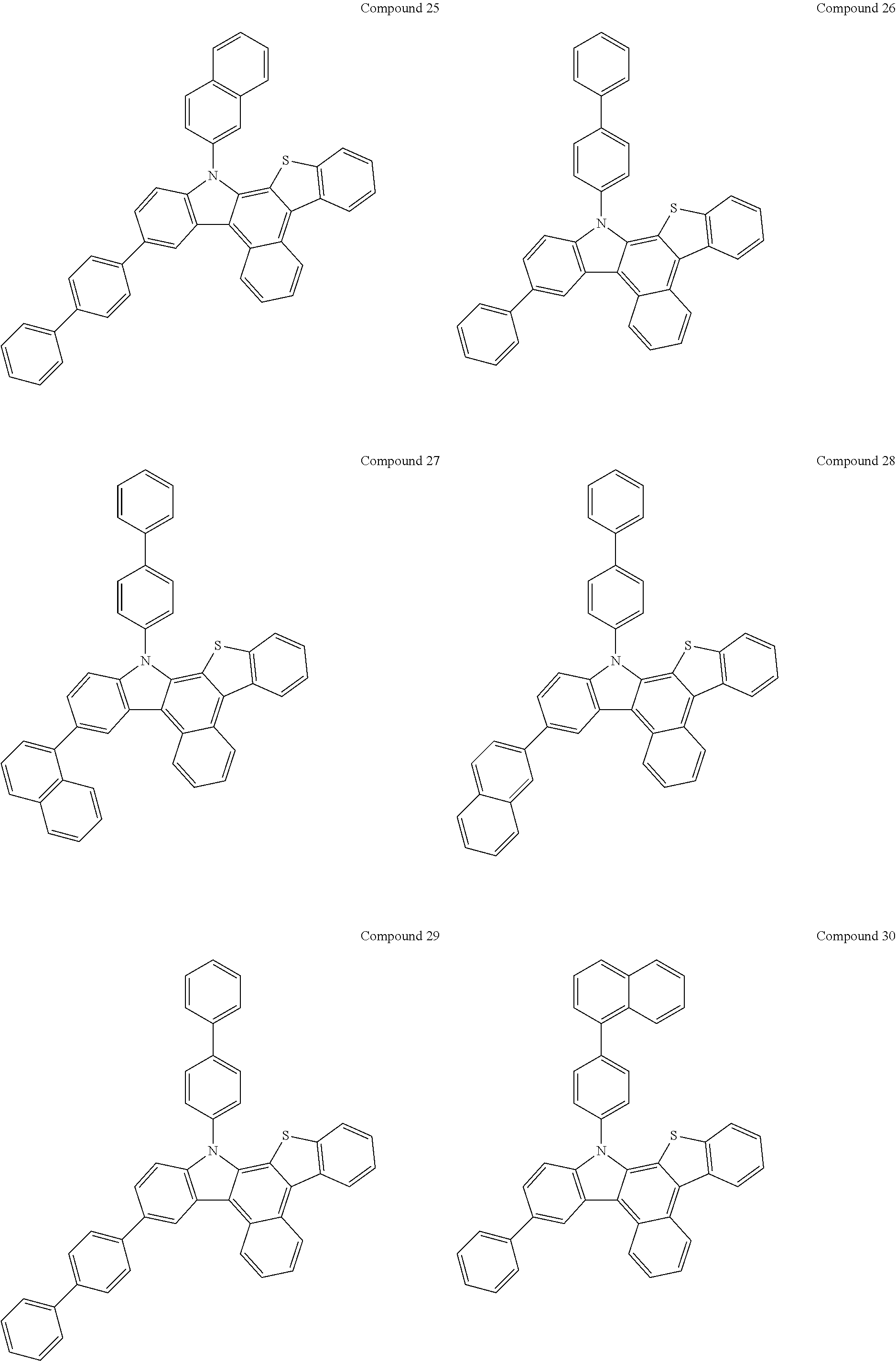 [SMILES: c1ccc(-c2ccc(-c3ccc4c(c3)c3c5ccccc5c5c6ccccc6sc5c3n4-c3ccc4ccccc4c3)cc2)cc1 ; c1ccc(-c2ccc(-n3c4ccc(-c5ccccc5)cc4c4c5ccccc5c5c6ccccc6sc5c43)cc2)cc1 ; c1ccc(-c2ccc(-n3c4ccc(-c5cccc6ccccc56)cc4c4c5ccccc5c5c6ccccc6sc5c43)cc2)cc1 ; c1ccc(-c2ccc(-n3c4ccc(-c5ccc6ccccc6c5)cc4c4c5ccccc5c5c6ccccc6sc5c43)cc2)cc1 ; c1ccc(-c2ccc(-c3ccc4c(c3)c3c5ccccc5c5c6ccccc6sc5c3n4-c3ccc(-c4ccccc4)cc3)cc2)cc1 ; c1ccc(-c2ccc3c(c2)c2c4ccccc4c4c5ccccc5sc4c2n3-c2ccc(-c3cccc4ccccc34)cc2)cc1]

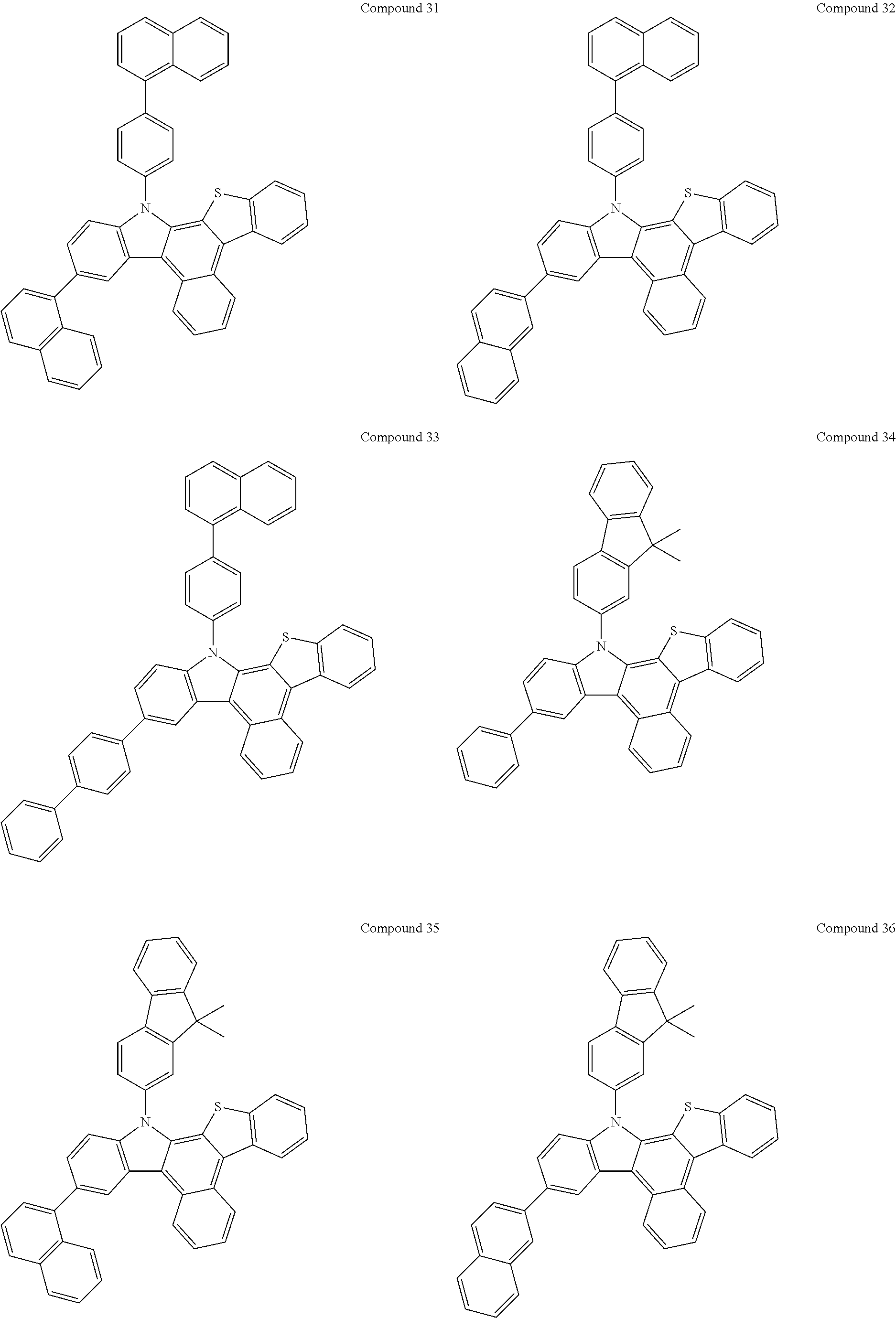 [SMILES: c1ccc2c(-c3ccc(-n4c5ccc(-c6cccc7ccccc67)cc5c5c6ccccc6c6c7ccccc7sc6c54)cc3)cccc2c1 ; c1ccc2cc(-c3ccc4c(c3)c3c5ccccc5c5c6ccccc6sc5c3n4-c3ccc(-c4cccc5ccccc45)cc3)ccc2c1 ; c1ccc(-c2ccc(-c3ccc4c(c3)c3c5ccccc5c5c6ccccc6sc5c3n4-c3ccc(-c4cccc5ccccc45)cc3)cc2)cc1 ; CC1(C)c2ccccc2-c2ccc(-n3c4ccc(-c5ccccc5)cc4c4c5ccccc5c5c6ccccc6sc5c43)cc21 ; CC1(C)c2ccccc2-c2ccc(-n3c4ccc(-c5cccc6ccccc56)cc4c4c5ccccc5c5c6ccccc6sc5c43)cc21 ; CC1(C)c2ccccc2-c2ccc(-n3c4ccc(-c5ccc6ccccc6c5)cc4c4c5ccccc5c5c6ccccc6sc5c43)cc21]

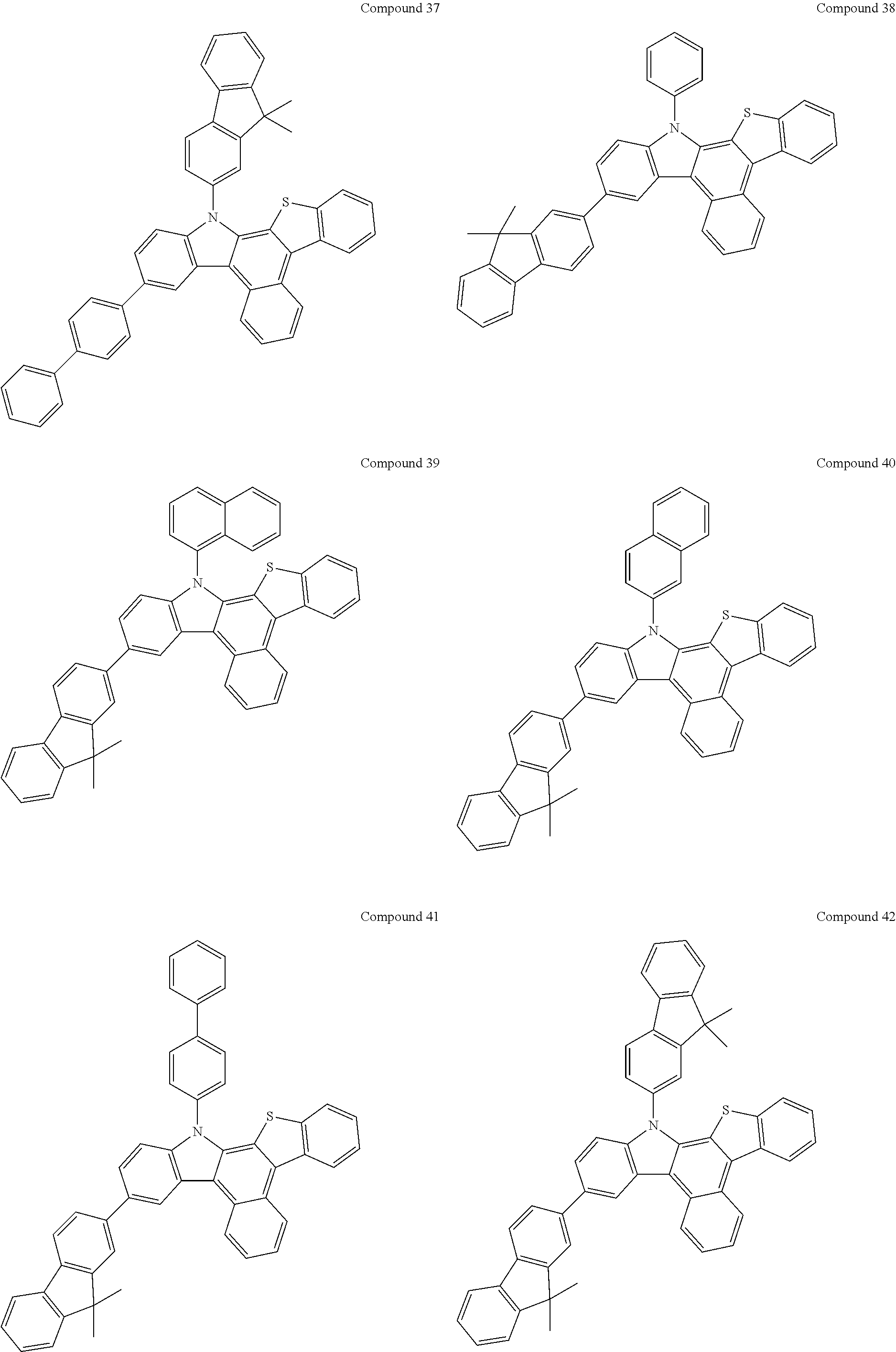

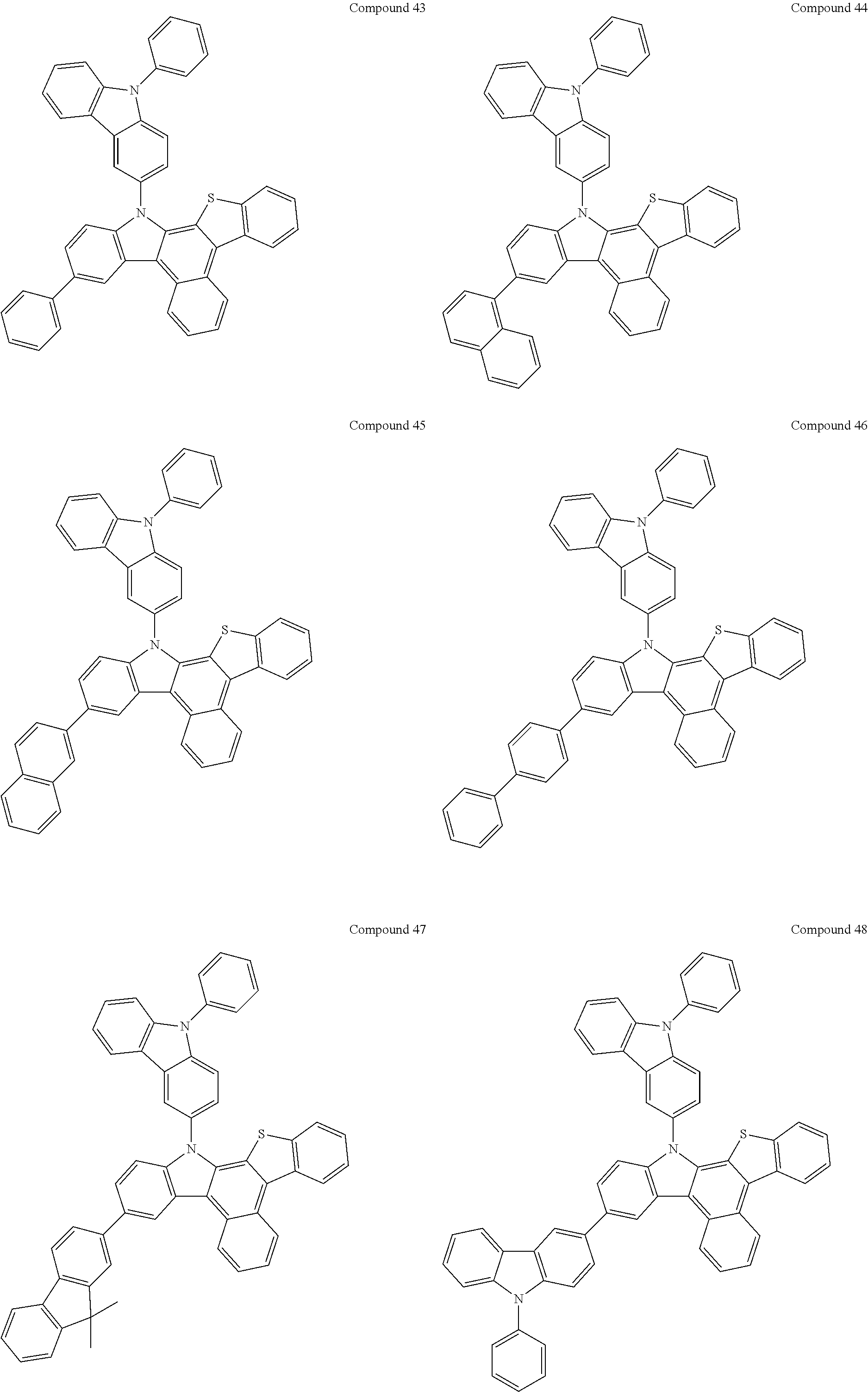

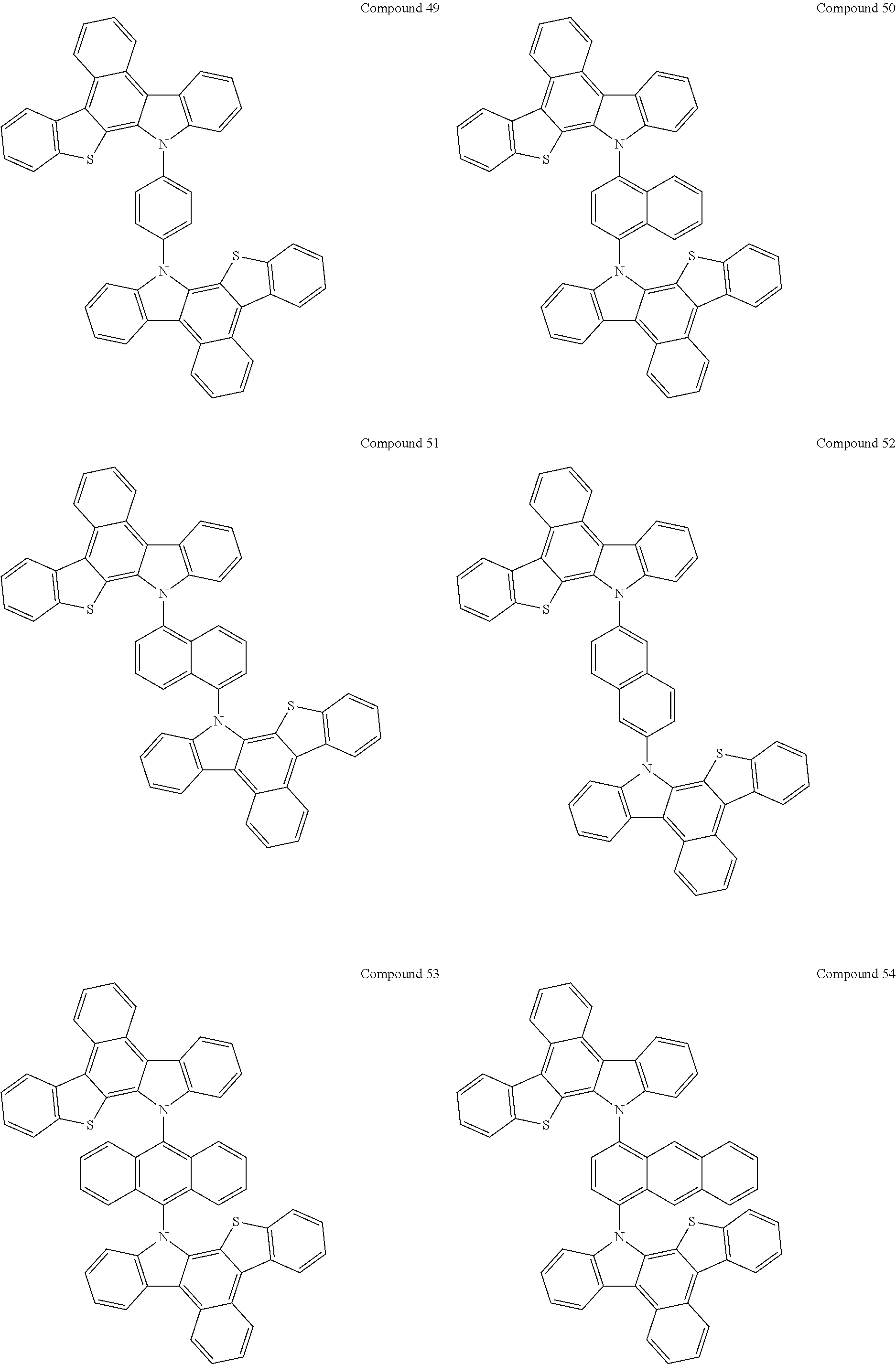

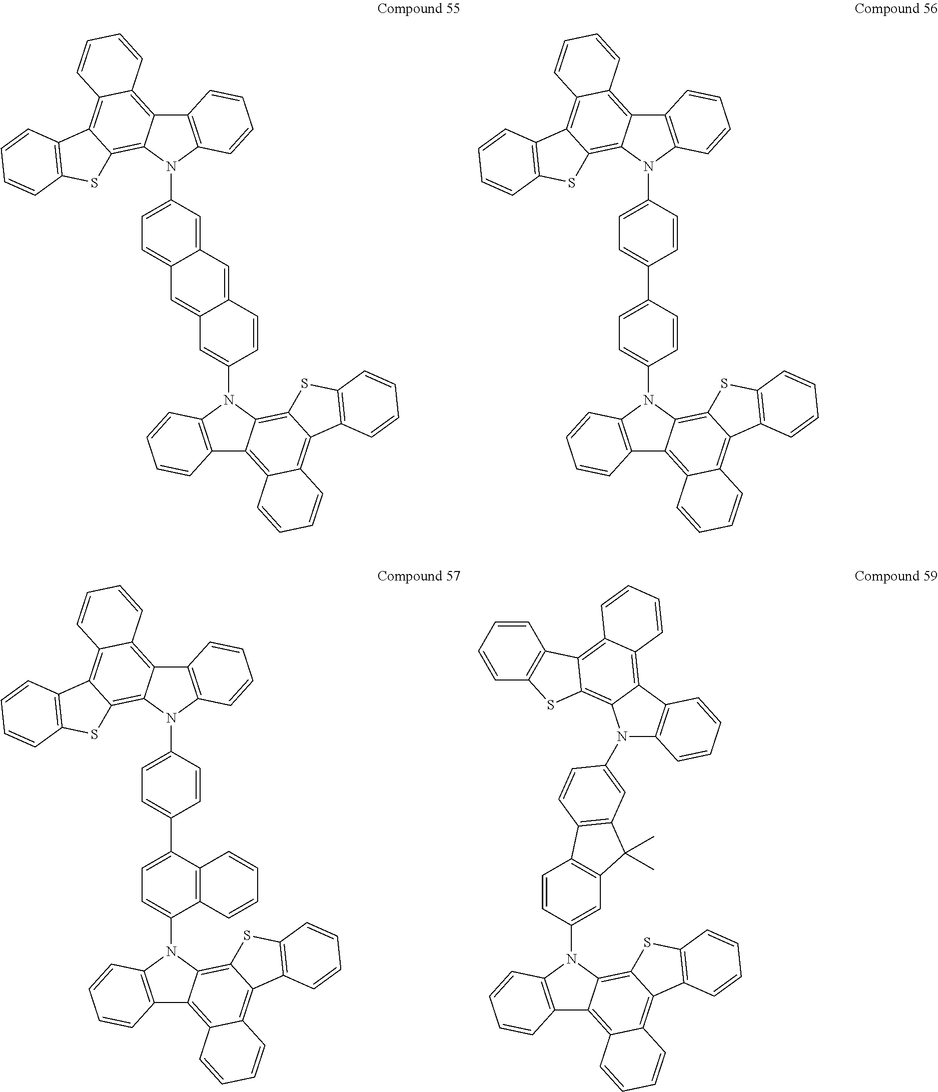 [SMILES: c1ccc2c(c1)sc1c2c2ccccc2c2c3ccccc3n(-c3ccc4cc5cc(-n6c7ccccc7c7c8ccccc8c8c9ccccc9sc8c76)ccc5cc4c3)c12 ; c1ccc2c(c1)sc1c2c2ccccc2c2c3ccccc3n(-c3ccc(-c4ccc(-n5c6ccccc6c6c7ccccc7c7c8ccccc8sc7c65)cc4)cc3)c12 ; c1ccc2c(c1)sc1c2c2ccccc2c2c3ccccc3n(-c3ccc(-c4ccc(-n5c6ccccc6c6c7ccccc7c7c8ccccc8sc7c65)c5ccccc45)cc3)c12 ; CC1(C)c2cc(-n3c4ccccc4c4c5ccccc5c5c6ccccc6sc5c43)ccc2-c2ccc(-n3c4ccccc4c4c5ccccc5c5c6ccccc6sc5c43)cc21]

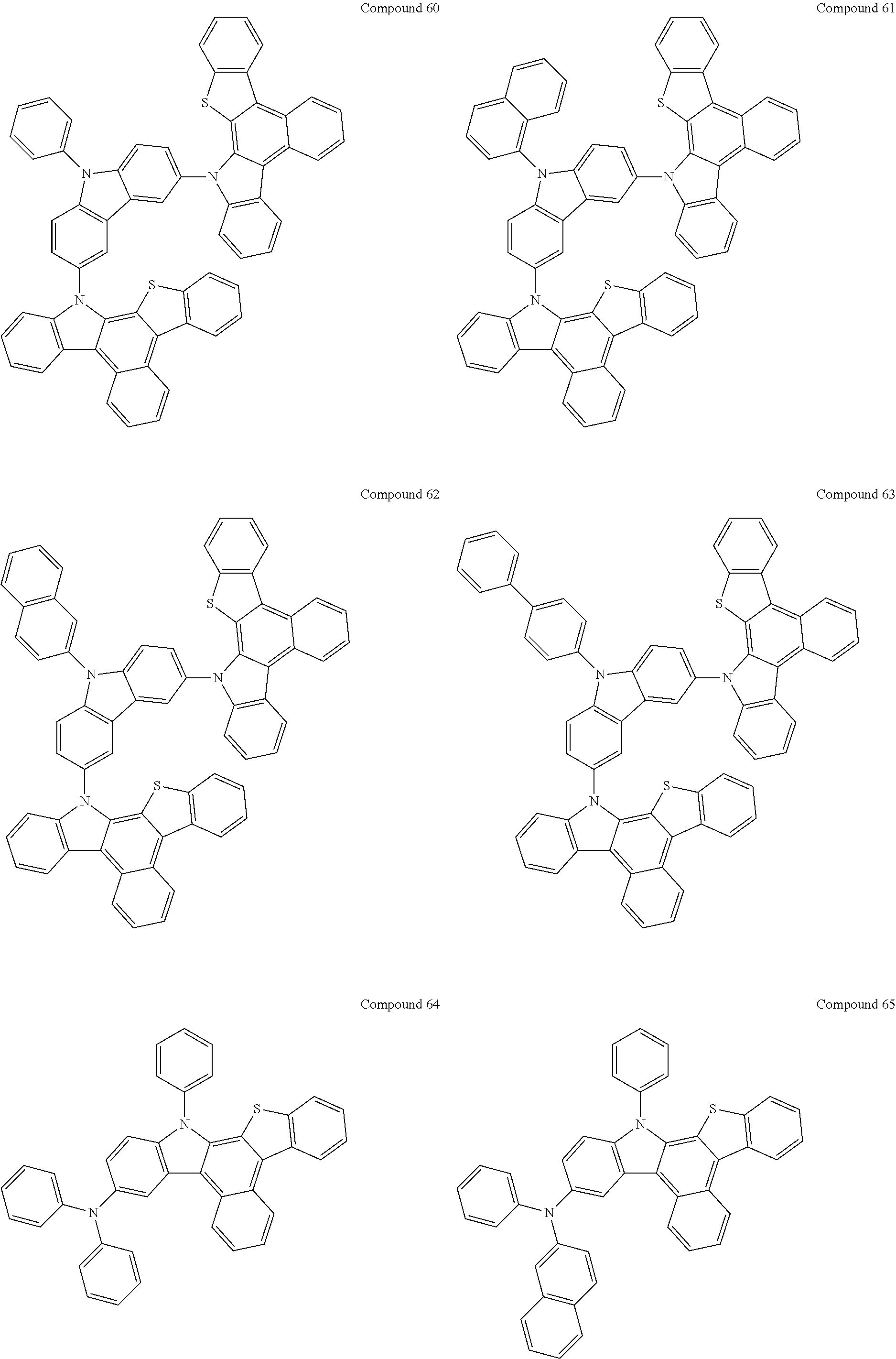

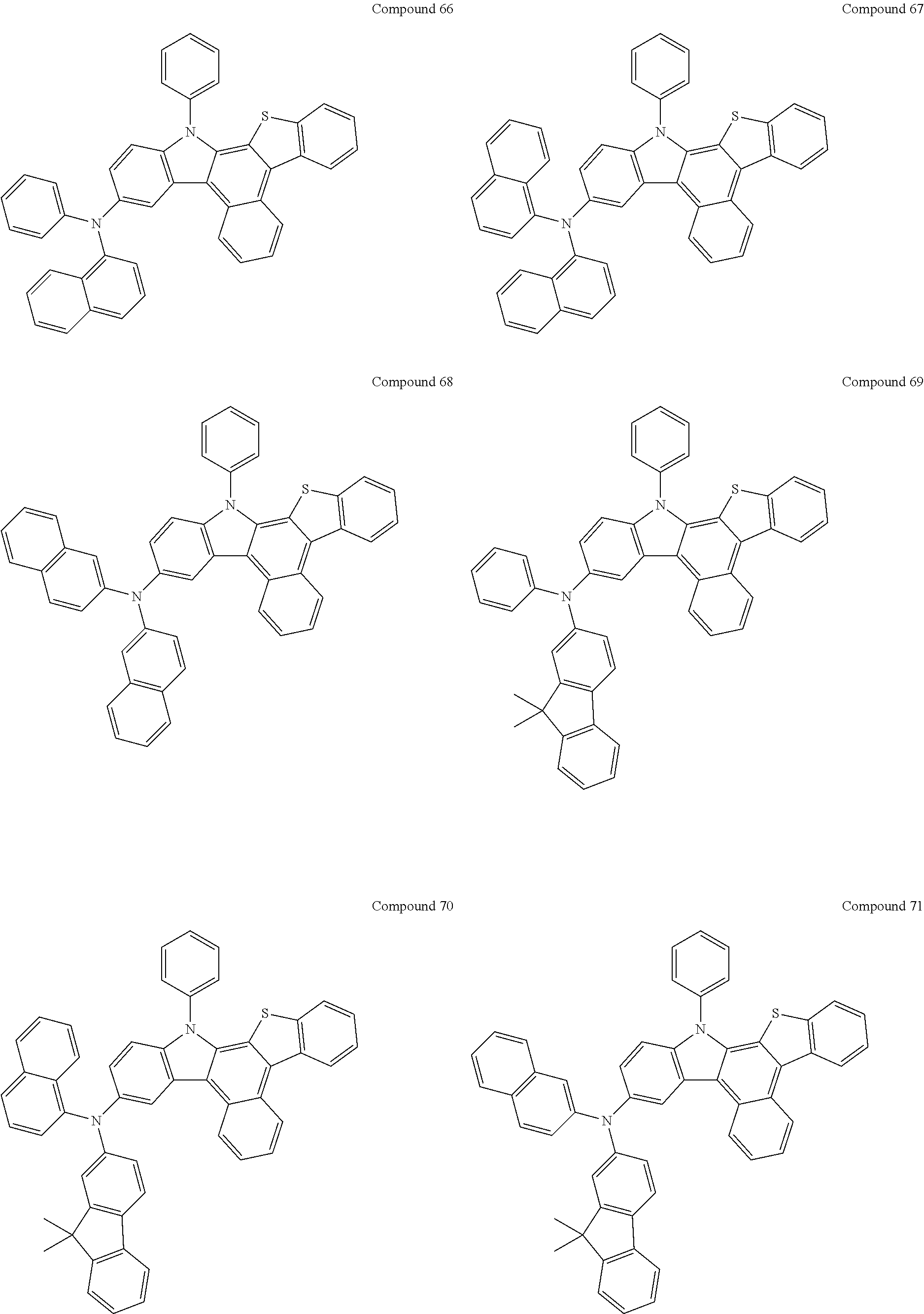

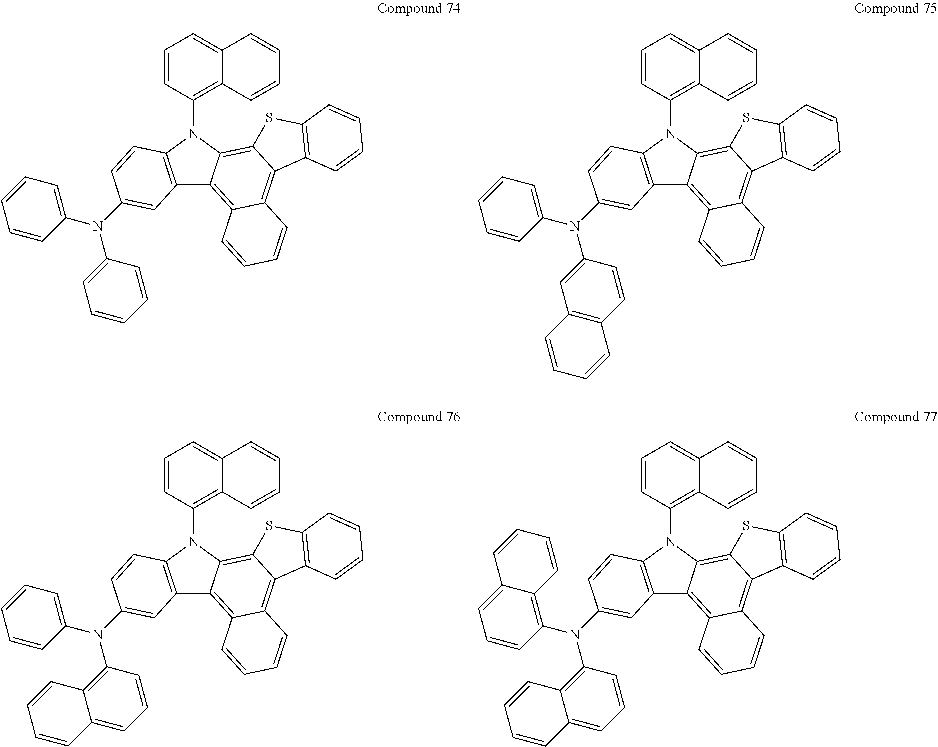 [SMILES: c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1 ; c1ccc(N(c2ccc3c(c2)c2c4ccccc4c4c5ccccc5sc4c2n3-c2cccc3ccccc23)c2cccc3ccccc23)cc1 ; c1ccc2c(N(c3ccc4c(c3)c3c5ccccc5c5c6ccccc6sc5c3n4-c3cccc4ccccc34)c3cccc4ccccc34)cccc2c1]

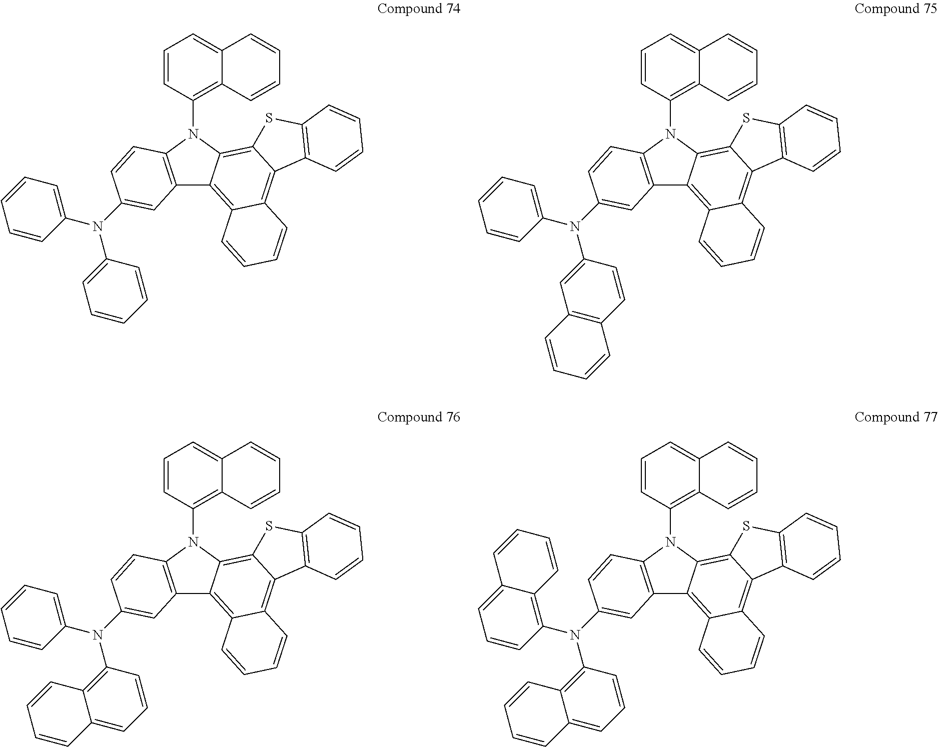 [SMILES: c1ccc(N(c2ccccc2)c2ccc3c(c2)c2c4ccccc4c4c5ccccc5sc4c2n3-c2cccc3ccccc23)cc1 ; c1ccc(N(c2ccc3ccccc3c2)c2ccc3c(c2)c2c4ccccc4c4c5ccccc5sc4c2n3-c2cccc3ccccc23)cc1 ; c1ccc(N(c2ccc3c(c2)c2c4ccccc4c4c5ccccc5sc4c2n3-c2cccc3ccccc23)c2cccc3ccccc23)cc1 ; c1ccc2c(N(c3ccc4c(c3)c3c5ccccc5c5c6ccccc6sc5c3n4-c3cccc4ccccc34)c3cccc4ccccc34)cccc2c1]

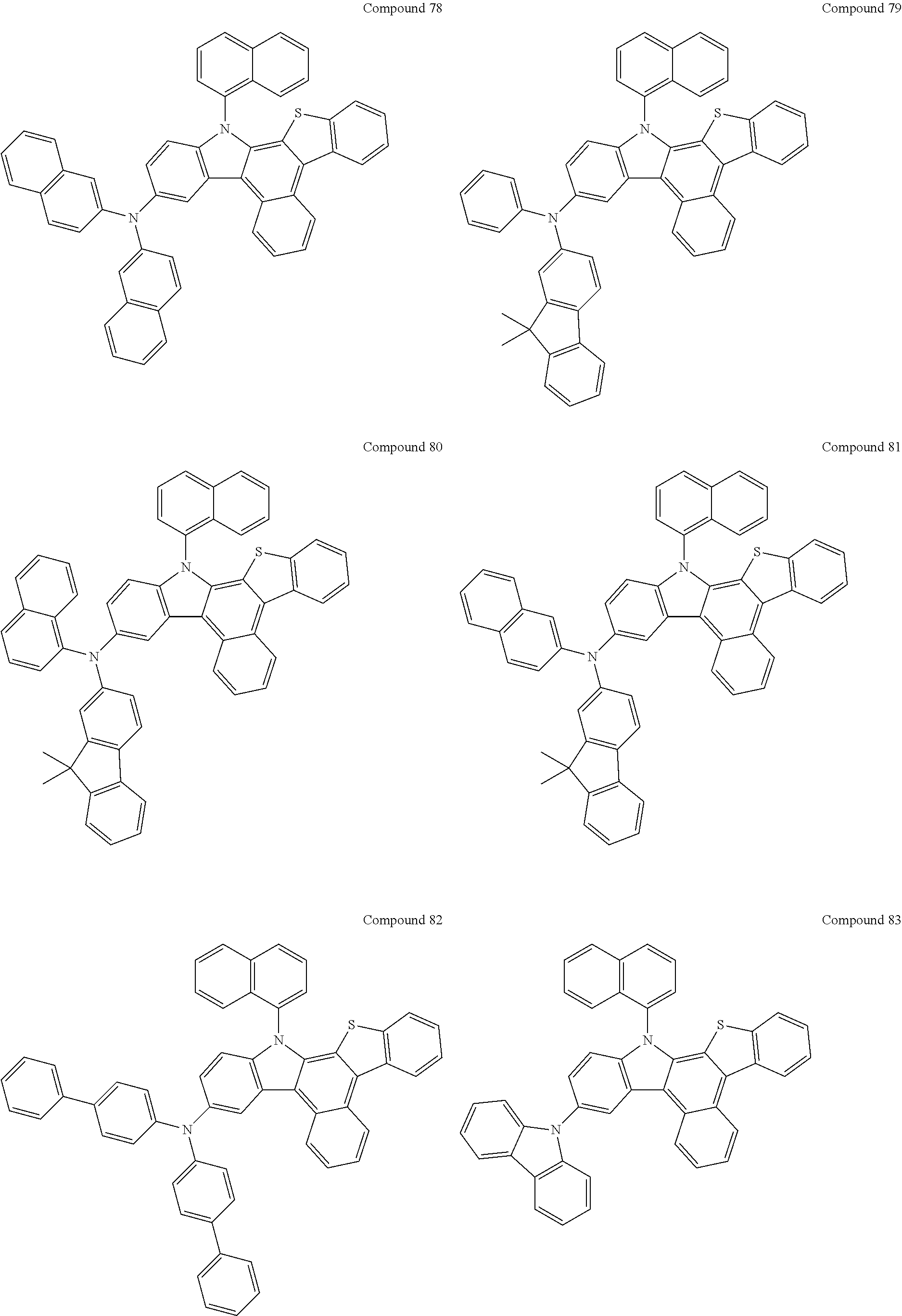

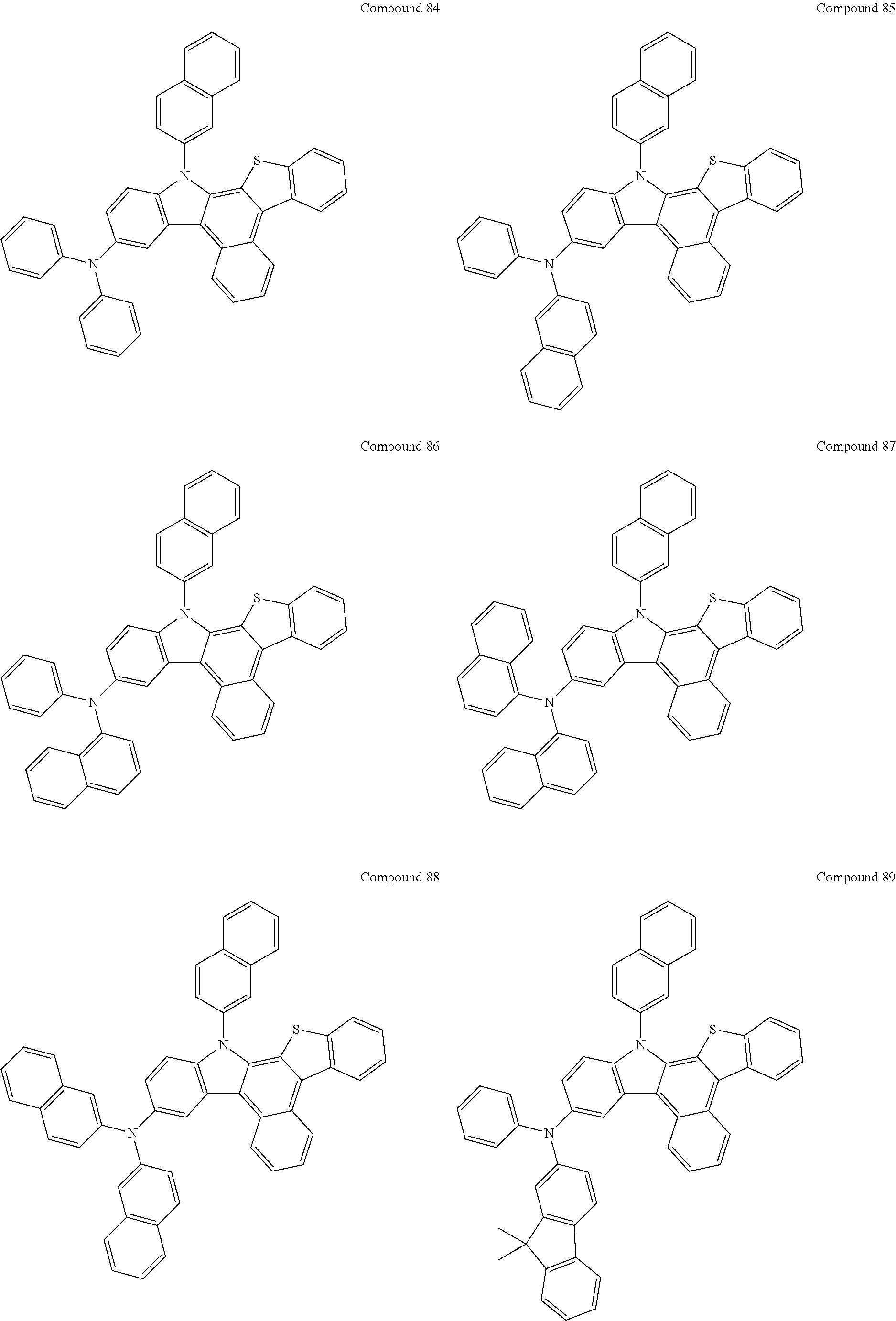

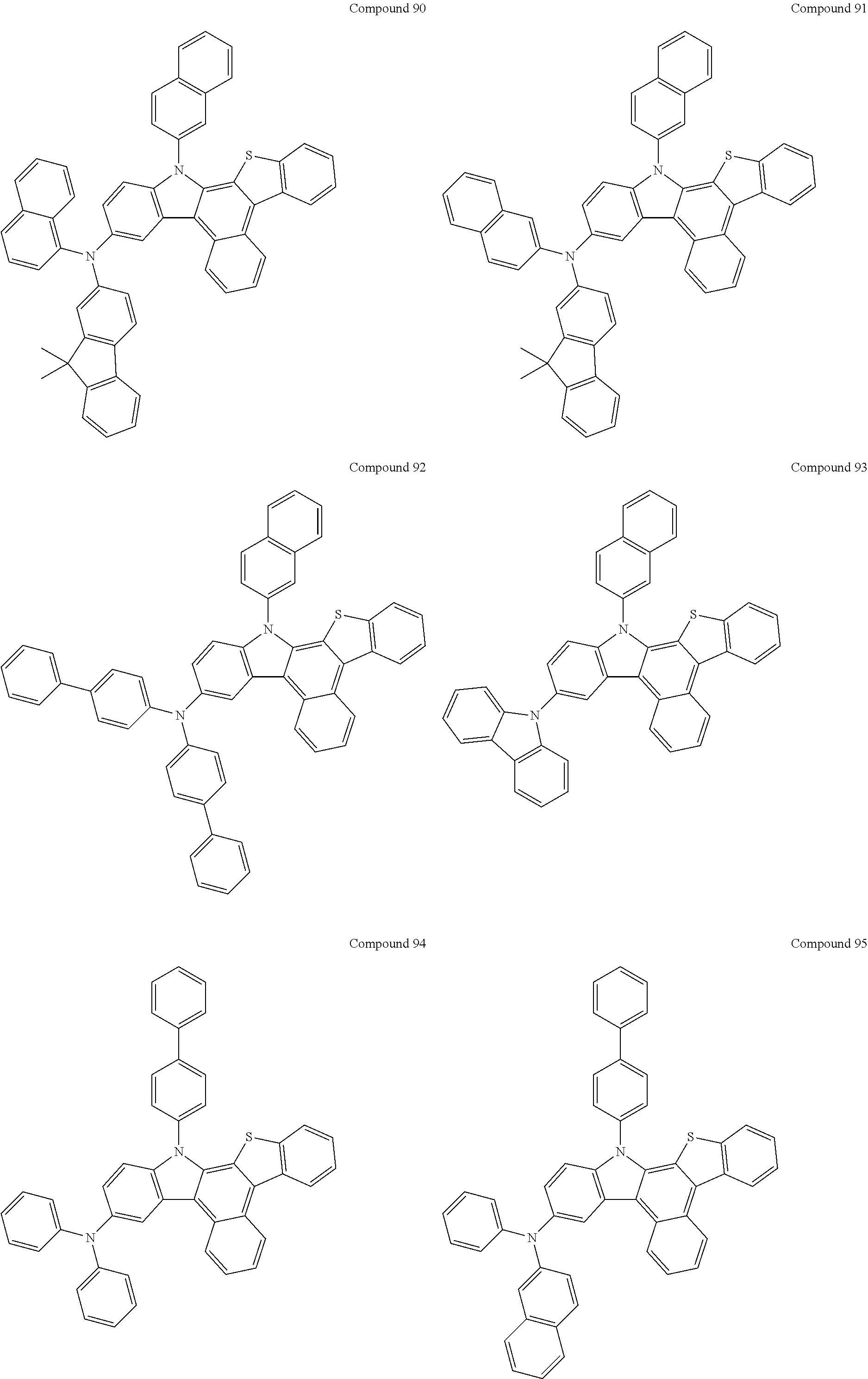

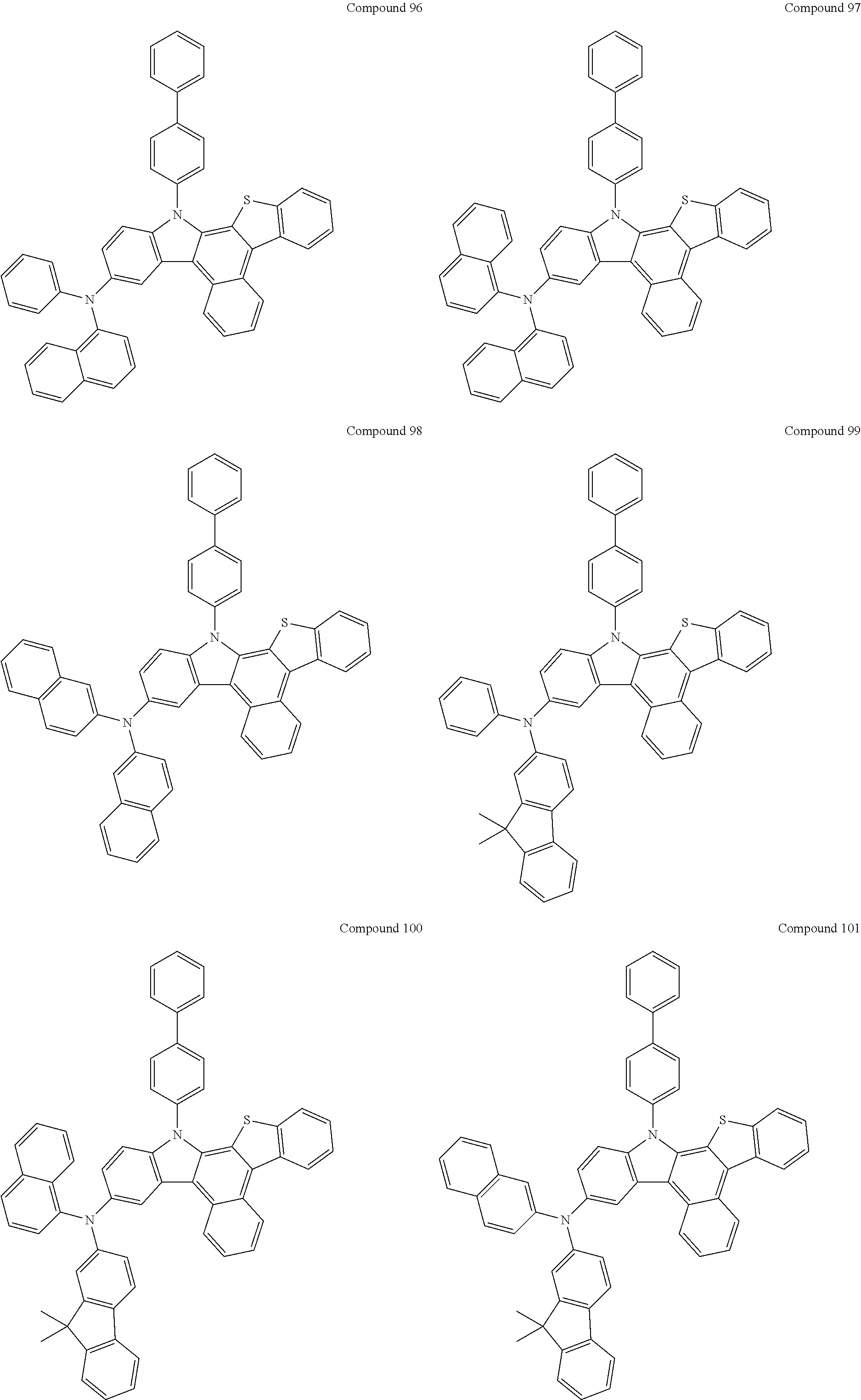

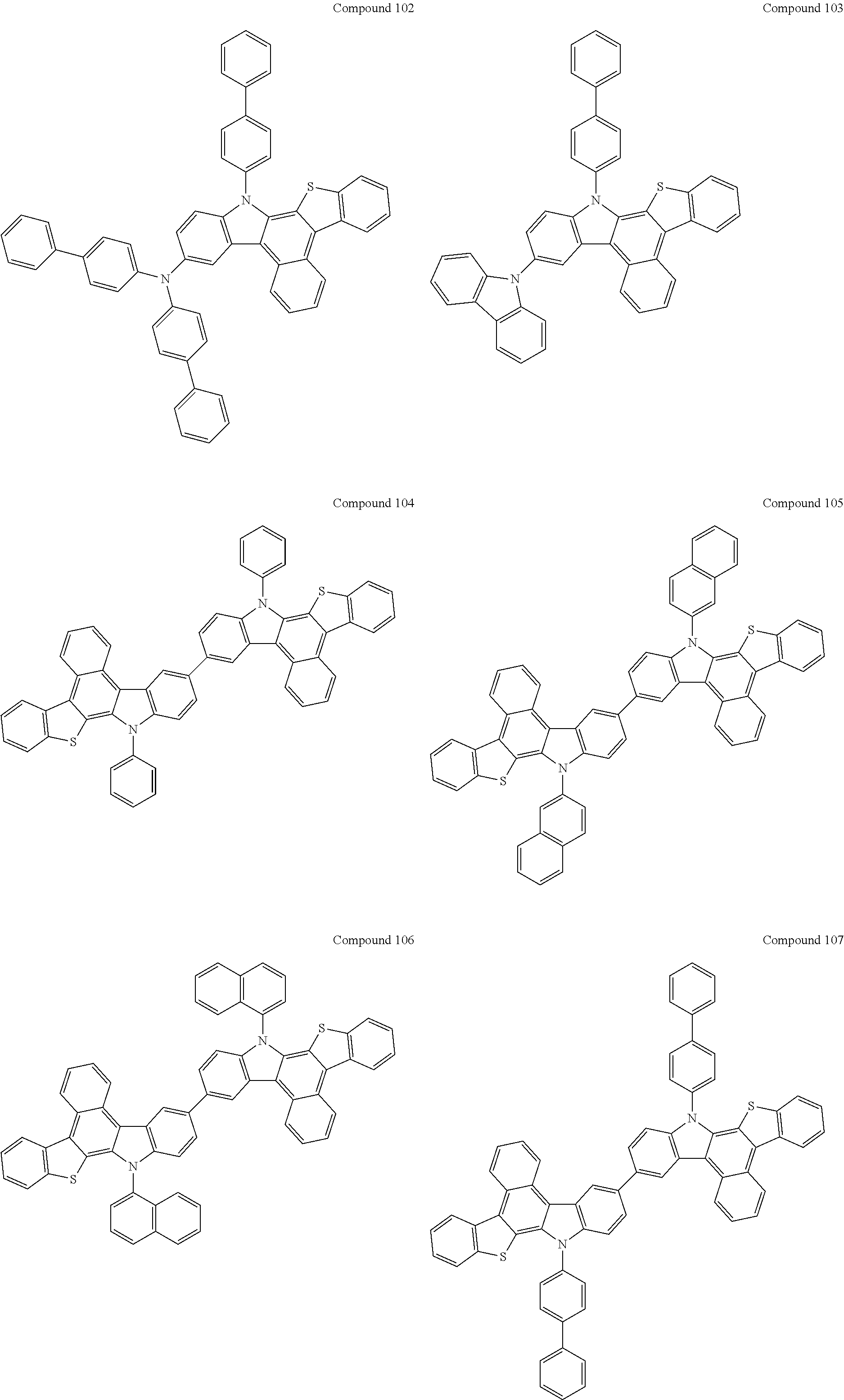

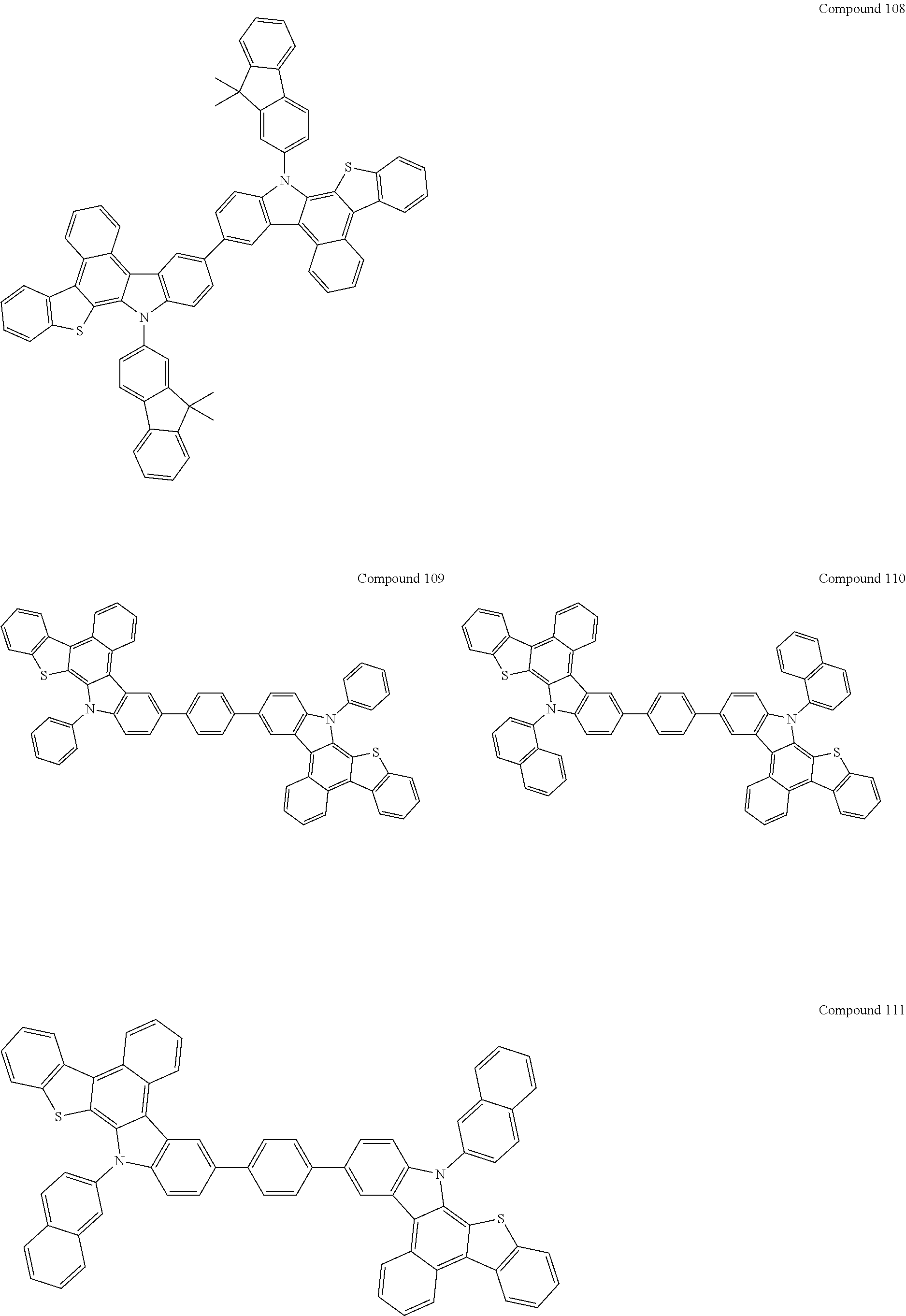 [SMILES: CC1(C)c2ccccc2-c2ccc(-n3c4ccc(-c5ccc6c(c5)c5c7ccccc7c7c8ccccc8sc7c5n6-c5ccc6c(c5)C(C)(C)c5ccccc5-6)cc4c4c5ccccc5c5c6ccccc6sc5c43)cc21 ; c1ccc(-n2c3ccc(-c4ccc(-c5ccc6c(c5)c5c7ccccc7c7c8ccccc8sc7c5n6-c5ccccc5)cc4)cc3c3c4ccccc4c4c5ccccc5sc4c32)cc1 ; c1ccc2c(-n3c4ccc(-c5ccc(-c6ccc7c(c6)c6c8ccccc8c8c9ccccc9sc8c6n7-c6cccc7ccccc67)cc5)cc4c4c5ccccc5c5c6ccccc6sc5c43)cccc2c1 ; c1ccc2cc(-n3c4ccc(-c5ccc(-c6ccc7c(c6)c6c8ccccc8c8c9ccccc9sc8c6n7-c6ccc7ccccc7c6)cc5)cc4c4c5ccccc5c5c6ccccc6sc5c43)ccc2c1]

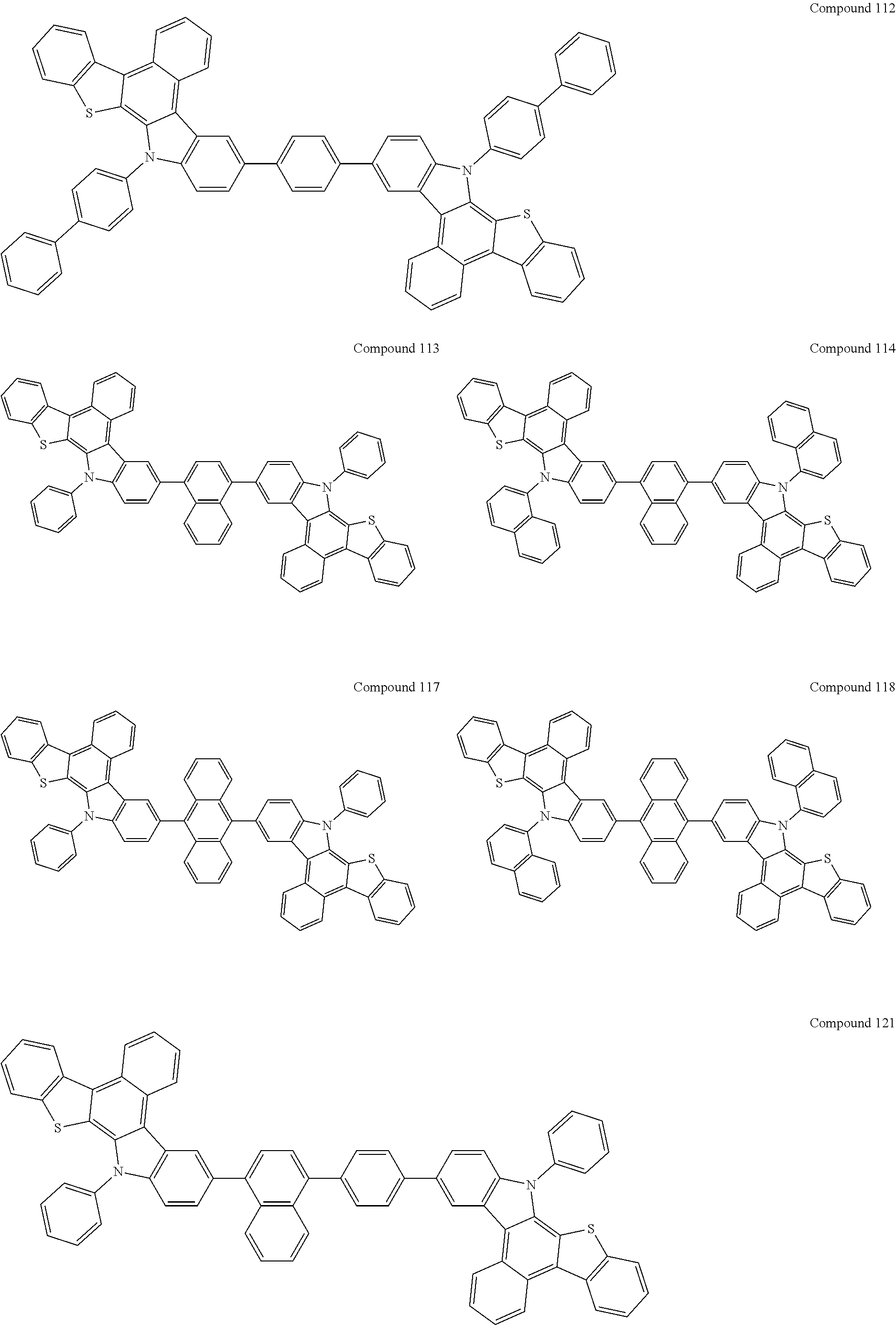

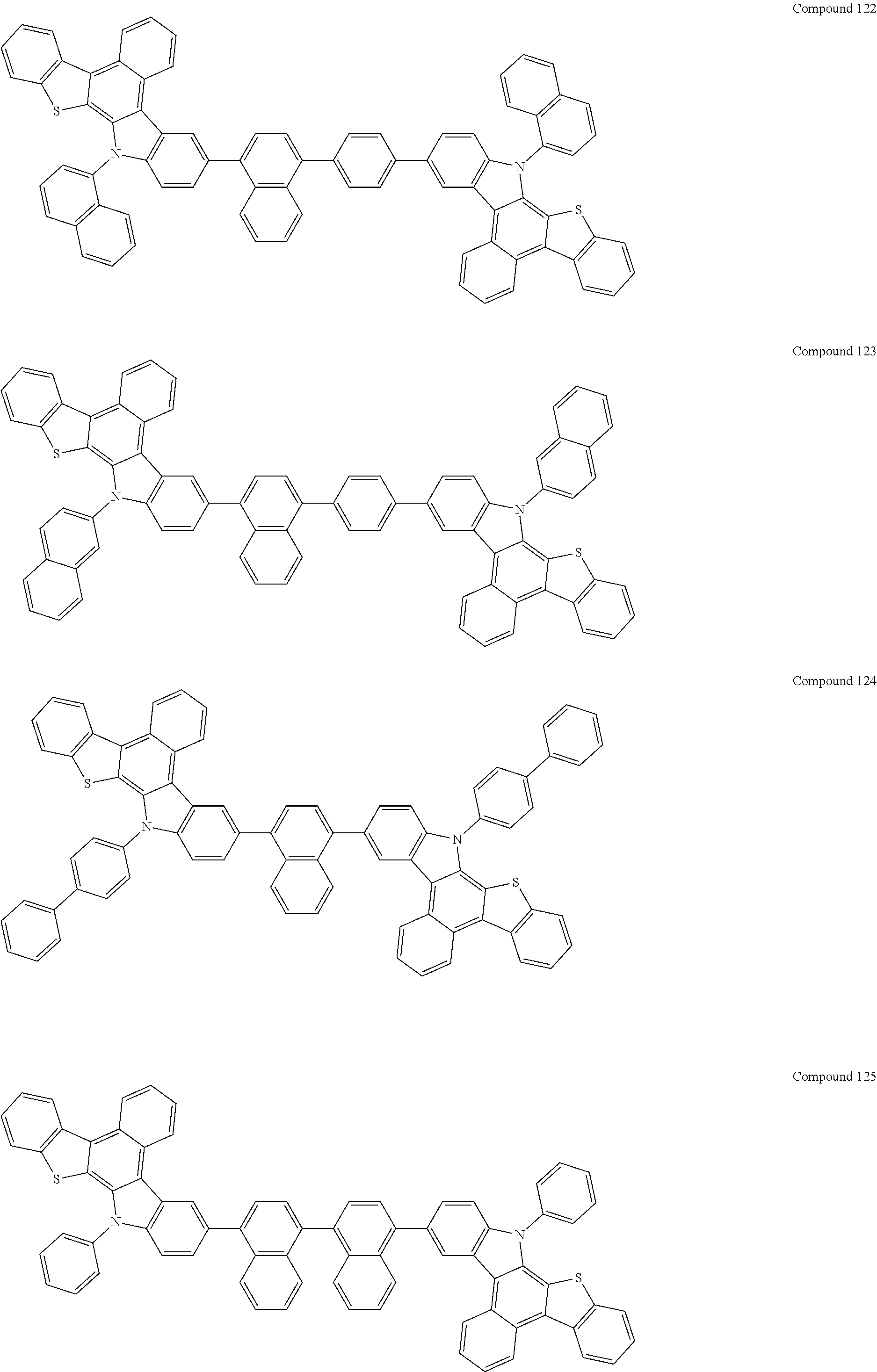

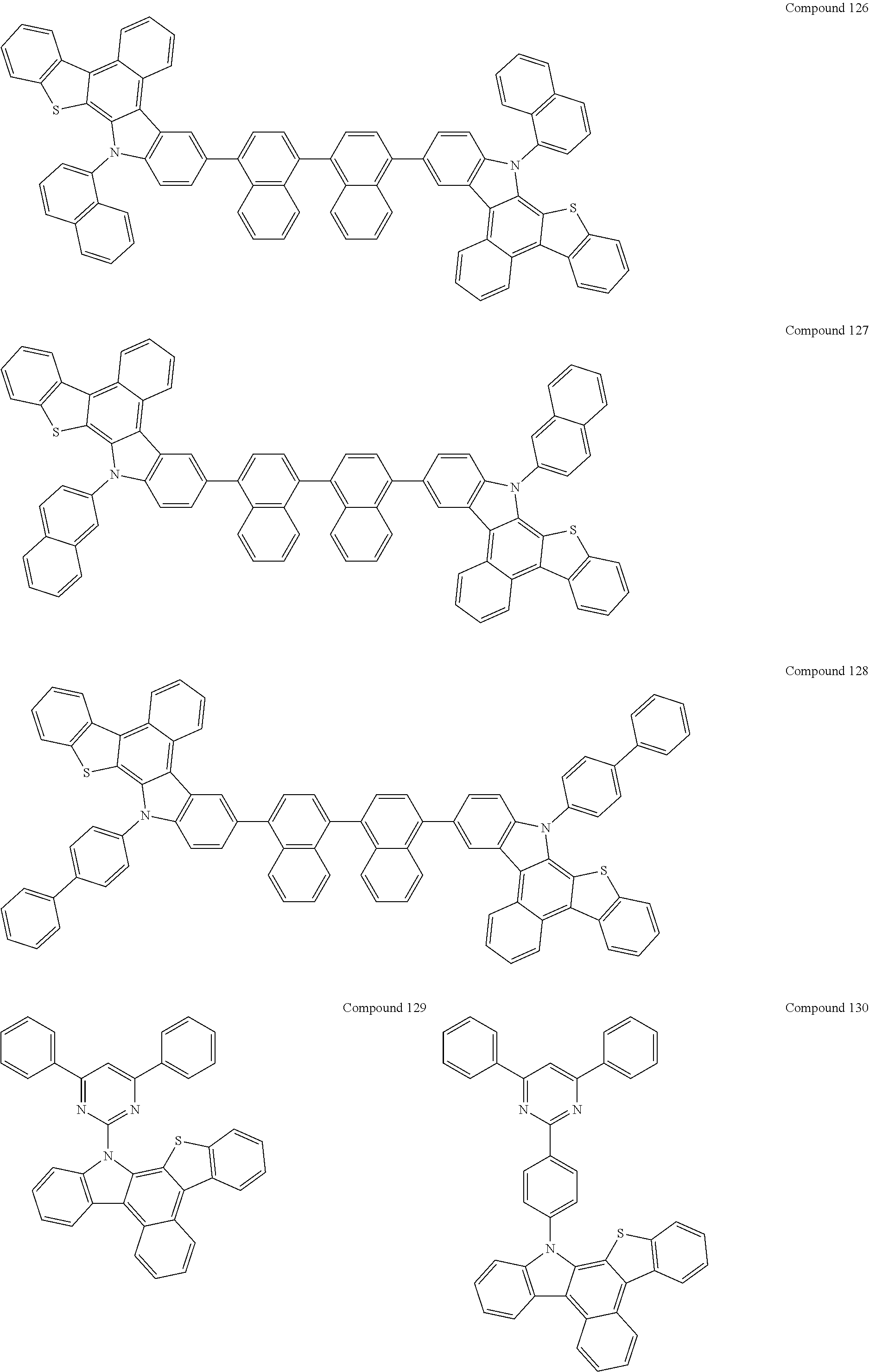

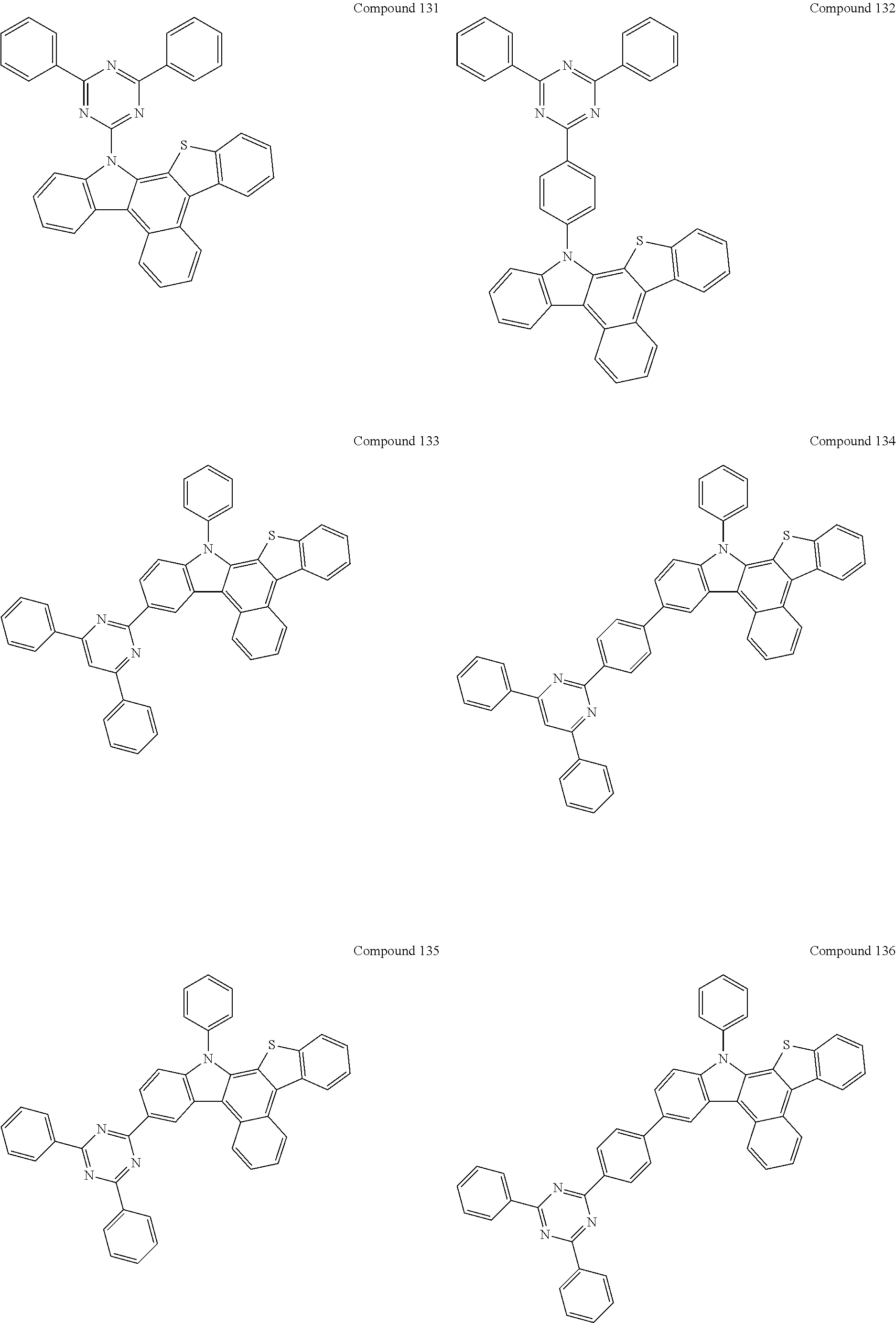

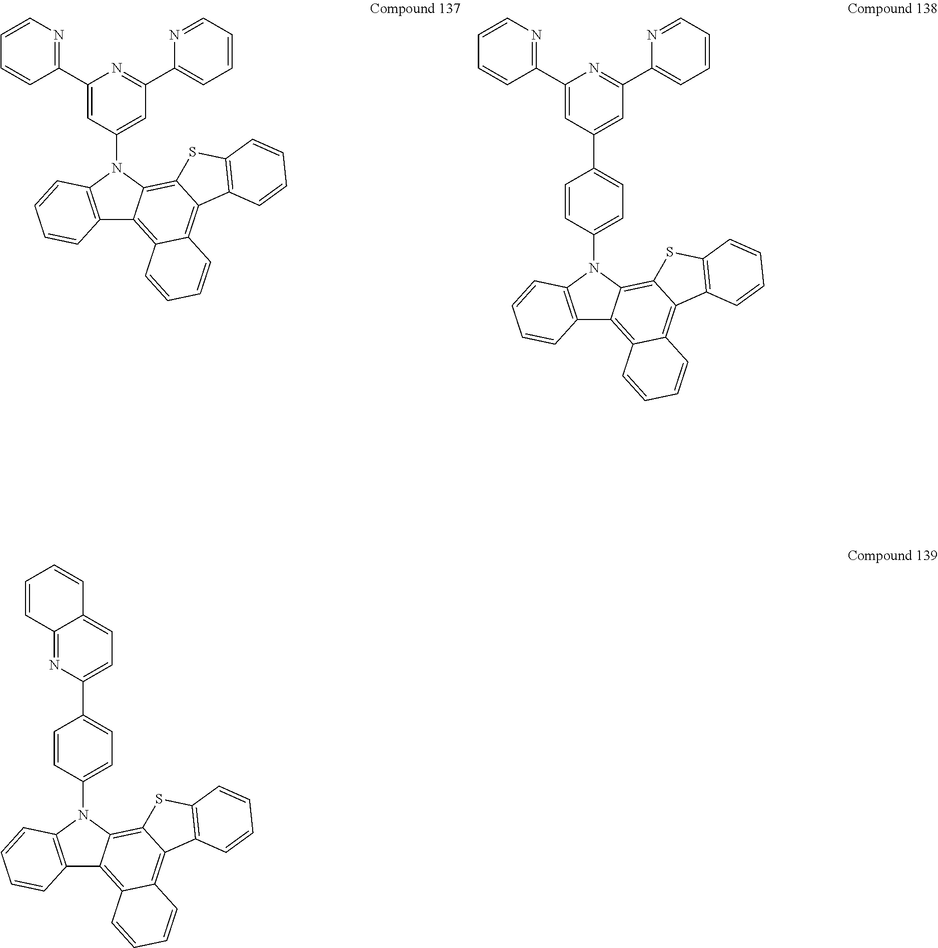 [SMILES: c1ccc(-c2cc(-n3c4ccccc4c4c5ccccc5c5c6ccccc6sc5c43)cc(-c3ccccn3)n2)nc1 ; c1ccc(-c2cc(-c3ccc(-n4c5ccccc5c5c6ccccc6c6c7ccccc7sc6c54)cc3)cc(-c3ccccn3)n2)nc1 ; c1ccc2nc(-c3ccc(-n4c5ccccc5c5c6ccccc6c6c7ccccc7sc6c54)cc3)ccc2c1]

5. The organic light emitting device as claimed in claim 1, further comprising a second host layer between the hole transport region and the emission layer, the second host layer including a third host.

6. The organic light emitting device as claimed in claim 5, wherein the third host is represented by Formula 1.

7. The organic light emitting device as claimed in claim 5, wherein the second host layer does not include the dopant.

8. The organic light emitting device as claimed in claim 5, wherein the third host includes one of the following Compounds 1 to 57, 59 to 71, 74 to 114, and 117 to 139:

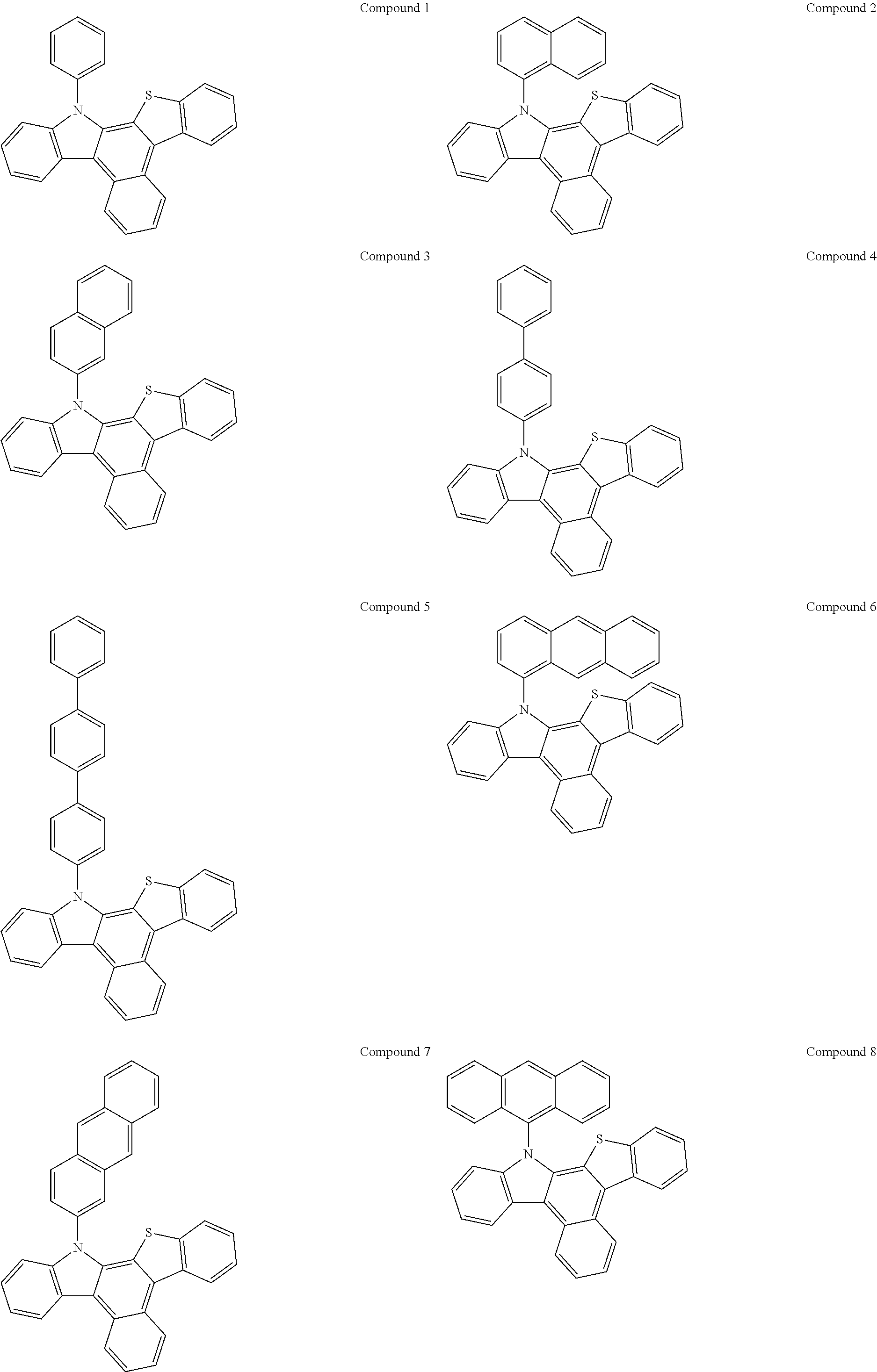

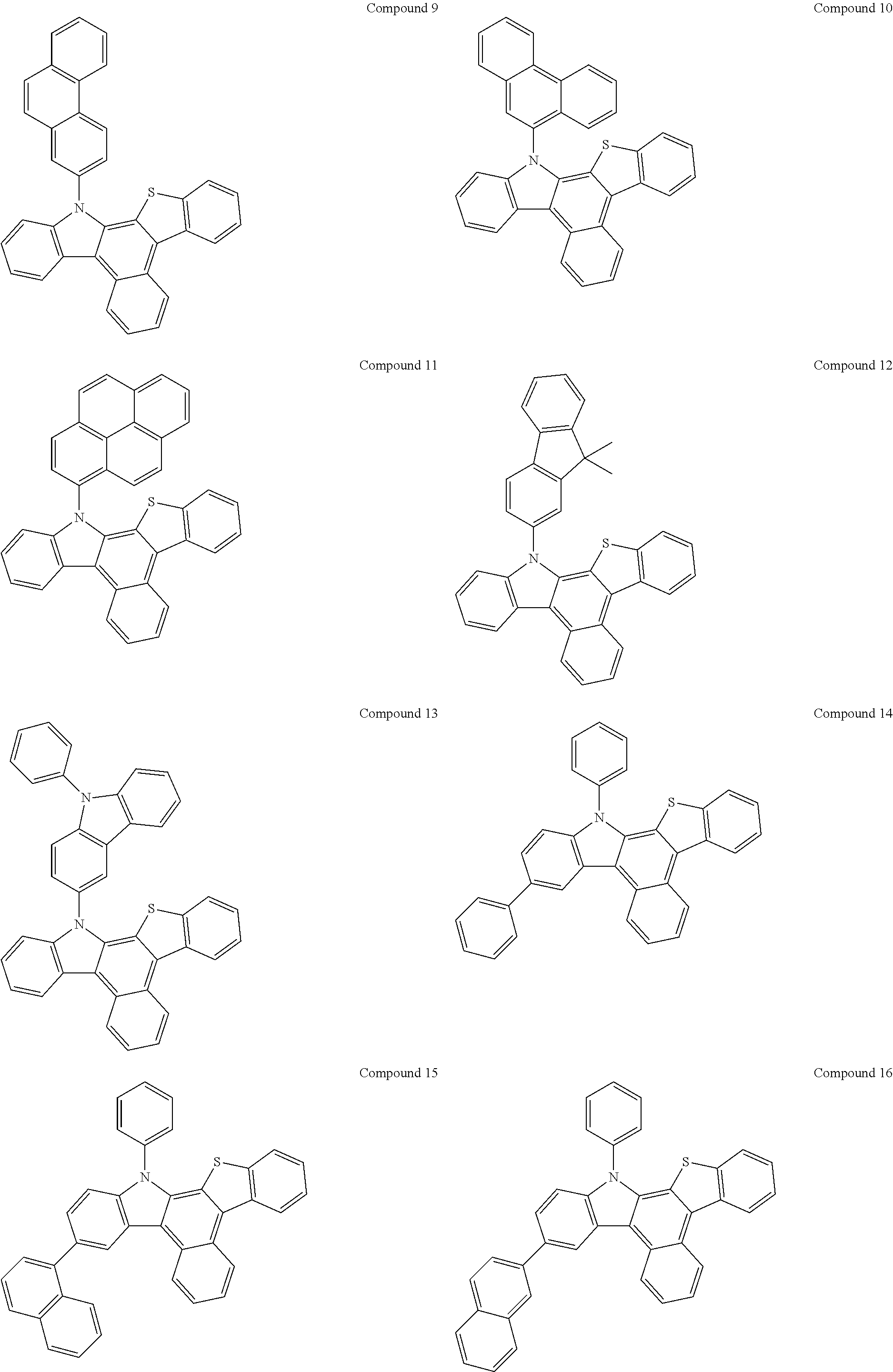

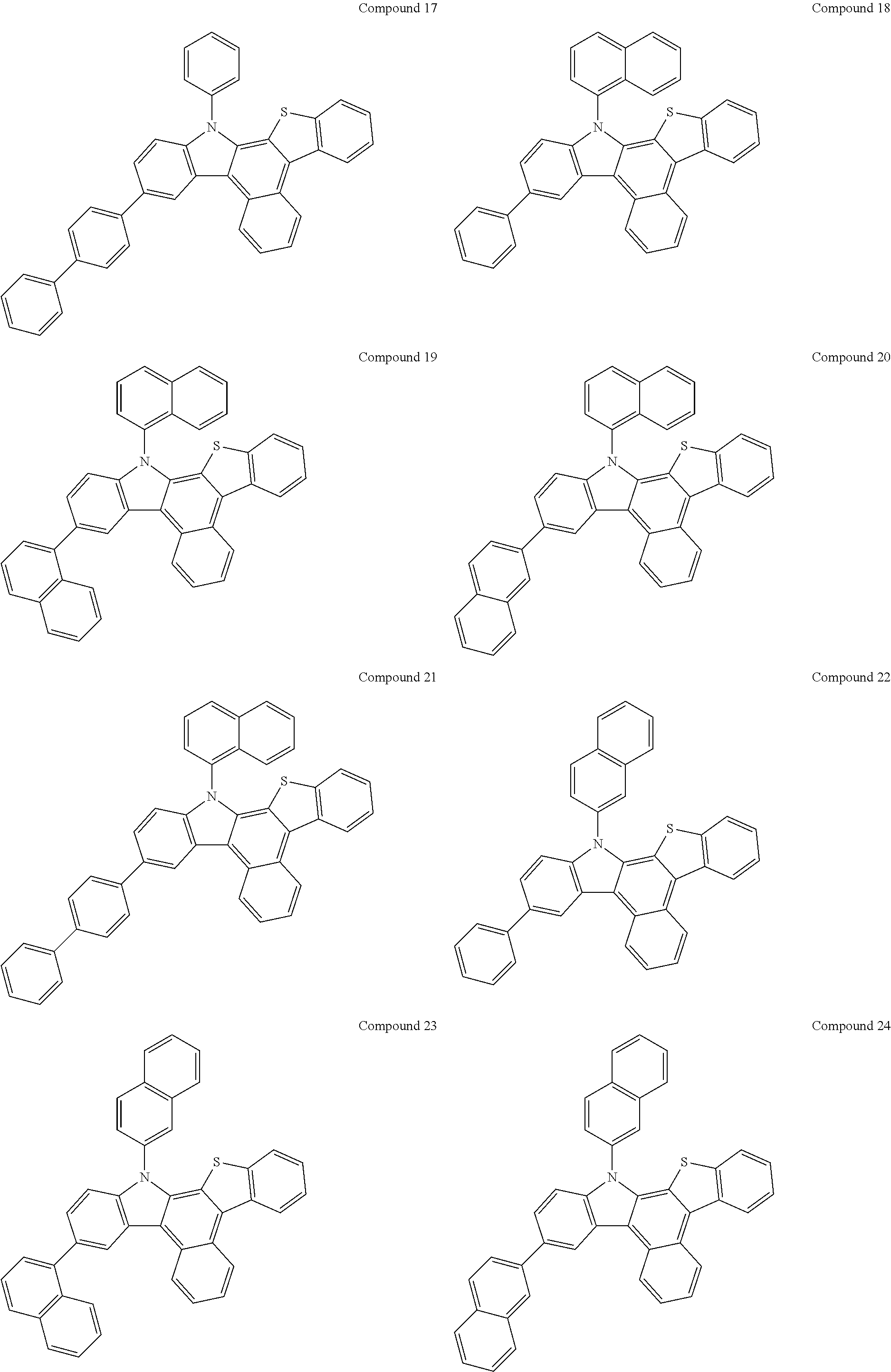

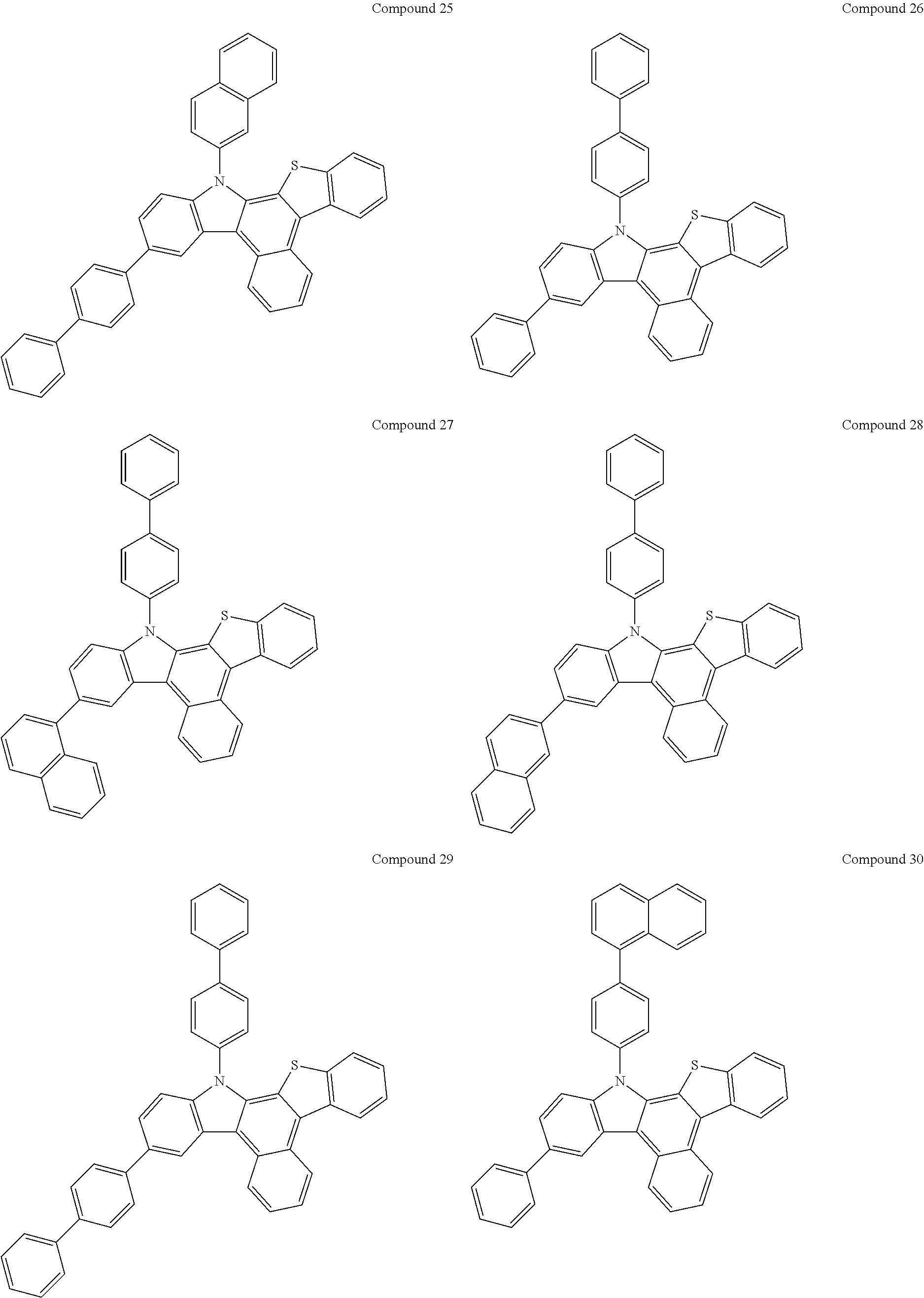 [SMILES: c1ccc(-c2ccc(-c3ccc4c(c3)c3c5ccccc5c5c6ccccc6sc5c3n4-c3ccc4ccccc4c3)cc2)cc1 ; c1ccc(-c2ccc(-n3c4ccc(-c5ccccc5)cc4c4c5ccccc5c5c6ccccc6sc5c43)cc2)cc1 ; c1ccc(-c2ccc(-n3c4ccc(-c5cccc6ccccc56)cc4c4c5ccccc5c5c6ccccc6sc5c43)cc2)cc1 ; c1ccc(-c2ccc(-n3c4ccc(-c5ccc6ccccc6c5)cc4c4c5ccccc5c5c6ccccc6sc5c43)cc2)cc1 ; c1ccc(-c2ccc(-c3ccc4c(c3)c3c5ccccc5c5c6ccccc6sc5c3n4-c3ccc(-c4ccccc4)cc3)cc2)cc1 ; c1ccc(-c2ccc3c(c2)c2c4ccccc4c4c5ccccc5sc4c2n3-c2ccc(-c3cccc4ccccc34)cc2)cc1]

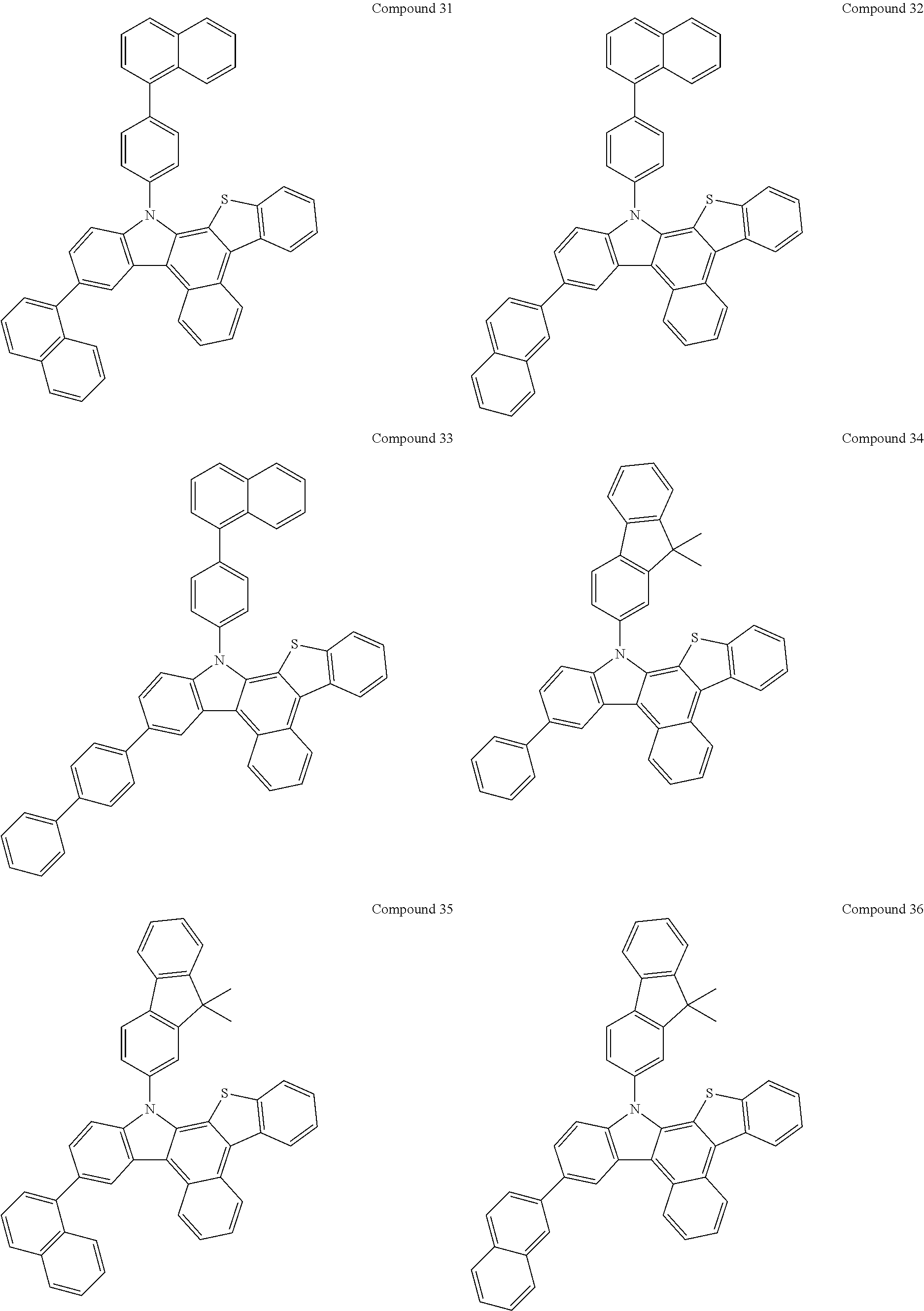 [SMILES: c1ccc2c(-c3ccc(-n4c5ccc(-c6cccc7ccccc67)cc5c5c6ccccc6c6c7ccccc7sc6c54)cc3)cccc2c1 ; c1ccc2cc(-c3ccc4c(c3)c3c5ccccc5c5c6ccccc6sc5c3n4-c3ccc(-c4cccc5ccccc45)cc3)ccc2c1 ; c1ccc(-c2ccc(-c3ccc4c(c3)c3c5ccccc5c5c6ccccc6sc5c3n4-c3ccc(-c4cccc5ccccc45)cc3)cc2)cc1 ; CC1(C)c2ccccc2-c2ccc(-n3c4ccc(-c5ccccc5)cc4c4c5ccccc5c5c6ccccc6sc5c43)cc21 ; CC1(C)c2ccccc2-c2ccc(-n3c4ccc(-c5cccc6ccccc56)cc4c4c5ccccc5c5c6ccccc6sc5c43)cc21 ; CC1(C)c2ccccc2-c2ccc(-n3c4ccc(-c5ccc6ccccc6c5)cc4c4c5ccccc5c5c6ccccc6sc5c43)cc21]

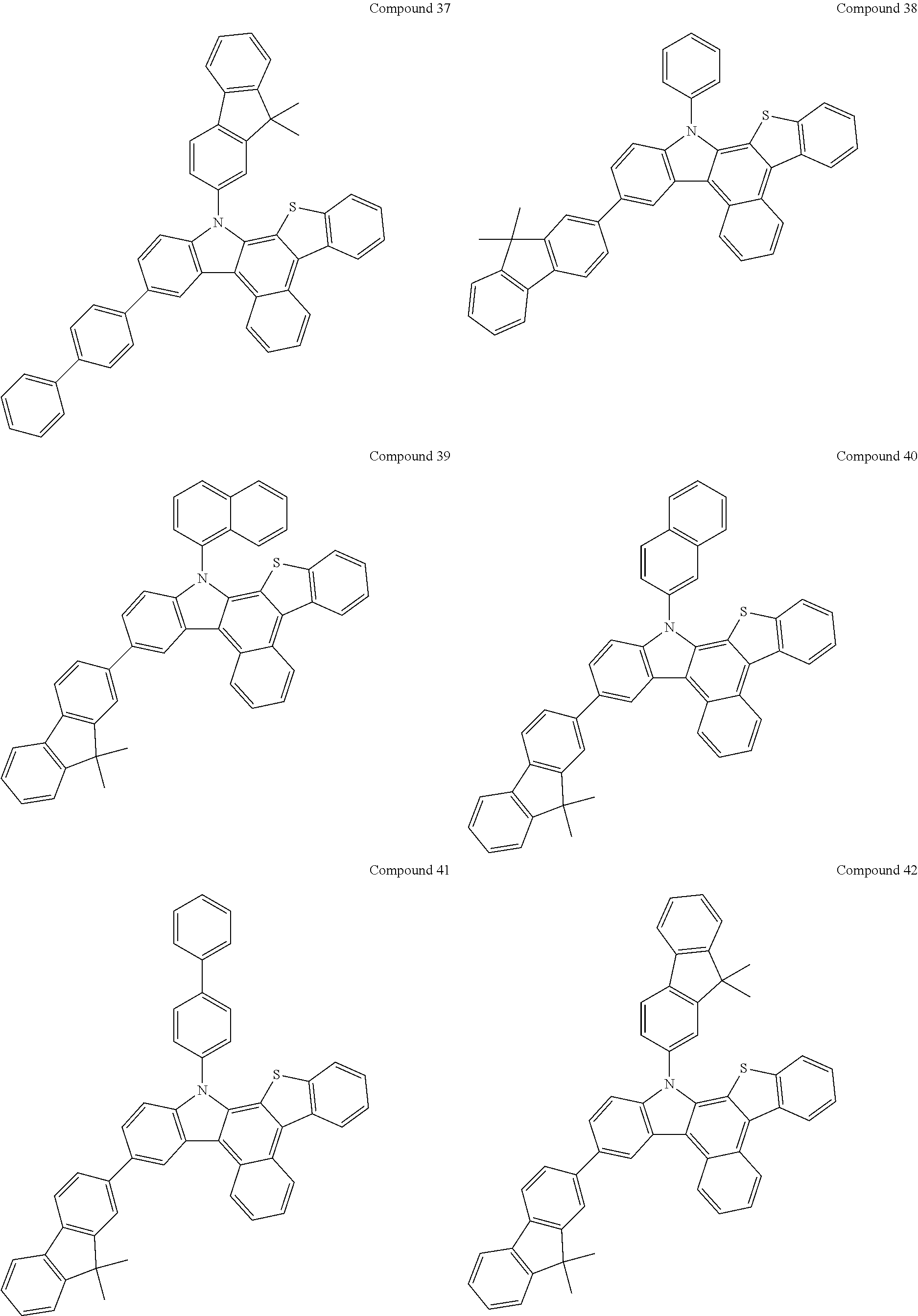

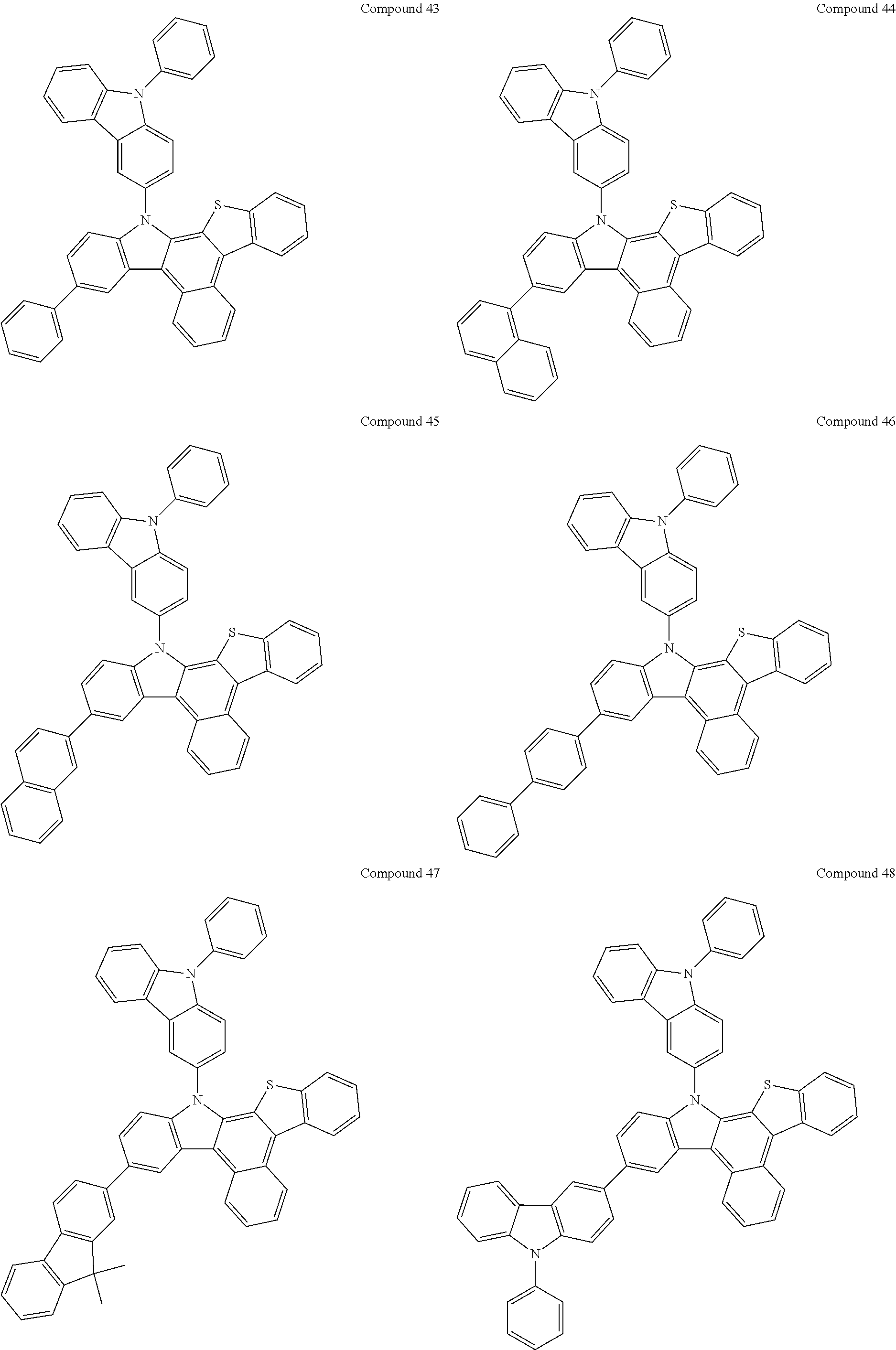

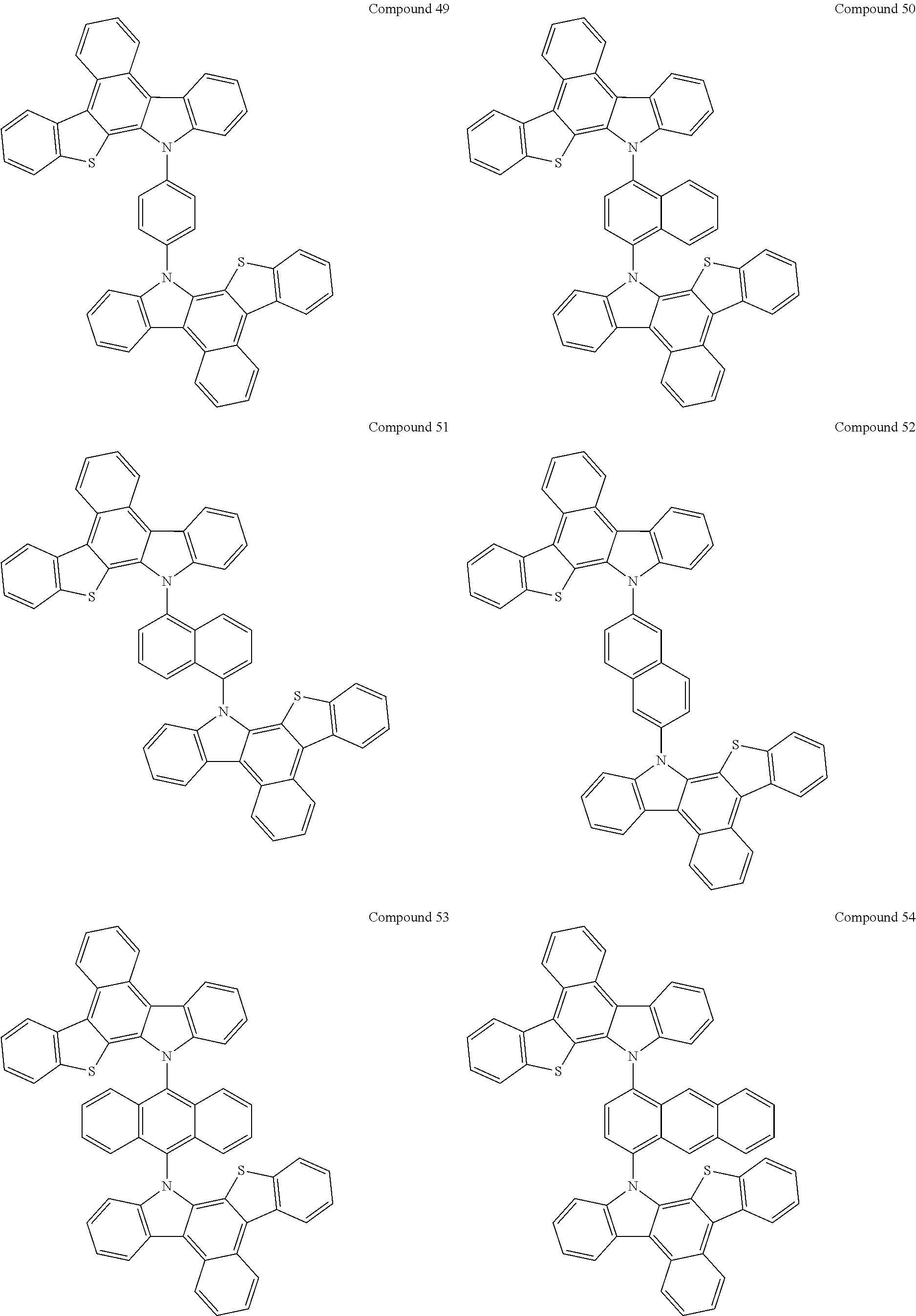

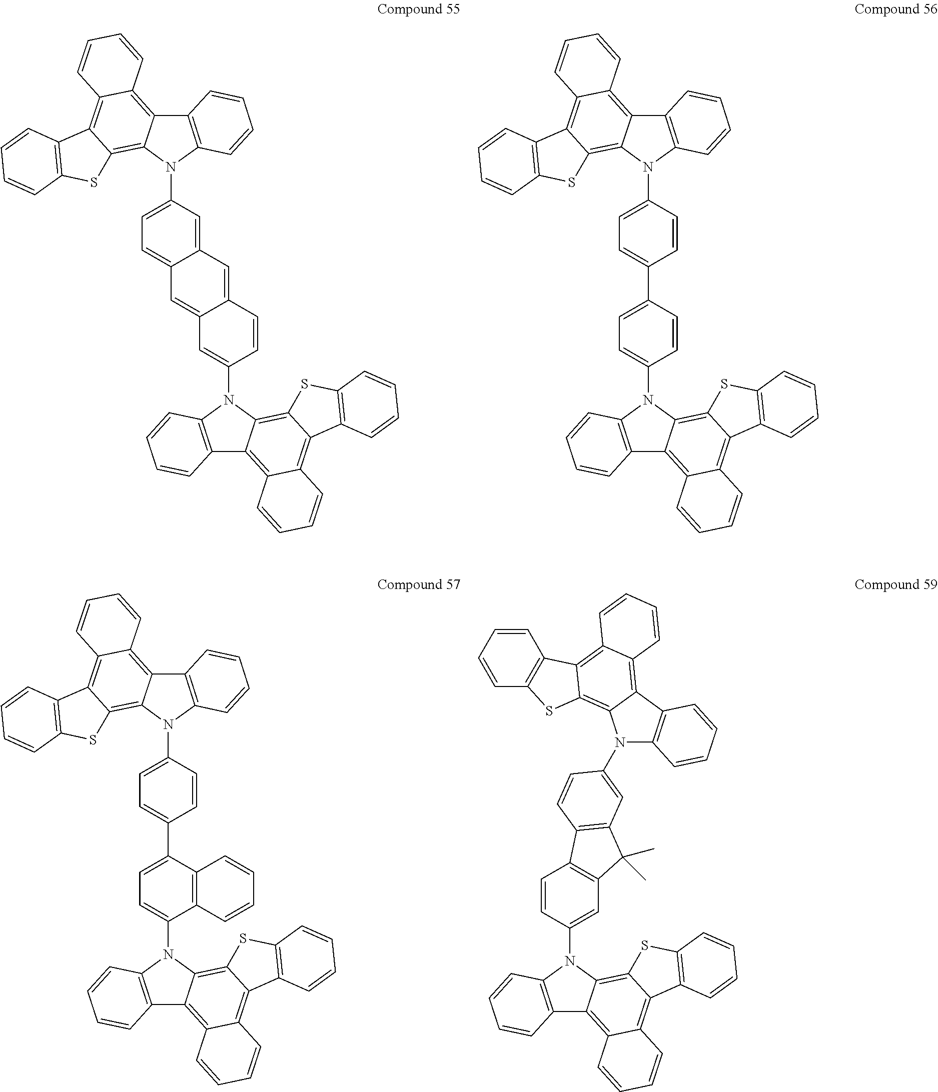 [SMILES: c1ccc2c(c1)sc1c2c2ccccc2c2c3ccccc3n(-c3ccc4cc5cc(-n6c7ccccc7c7c8ccccc8c8c9ccccc9sc8c76)ccc5cc4c3)c12 ; c1ccc2c(c1)sc1c2c2ccccc2c2c3ccccc3n(-c3ccc(-c4ccc(-n5c6ccccc6c6c7ccccc7c7c8ccccc8sc7c65)cc4)cc3)c12 ; c1ccc2c(c1)sc1c2c2ccccc2c2c3ccccc3n(-c3ccc(-c4ccc(-n5c6ccccc6c6c7ccccc7c7c8ccccc8sc7c65)c5ccccc45)cc3)c12 ; CC1(C)c2cc(-n3c4ccccc4c4c5ccccc5c5c6ccccc6sc5c43)ccc2-c2ccc(-n3c4ccccc4c4c5ccccc5c5c6ccccc6sc5c43)cc21]

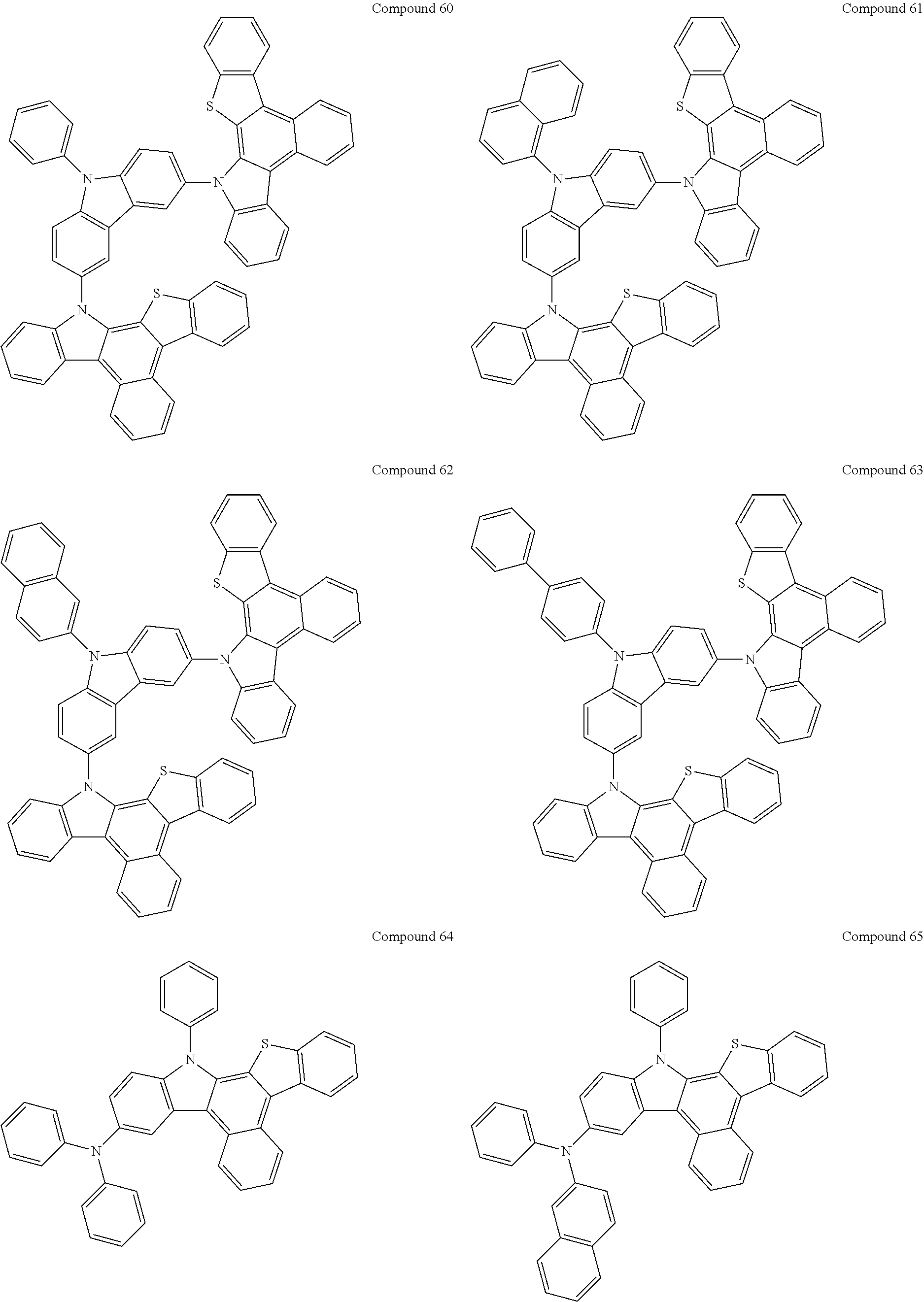

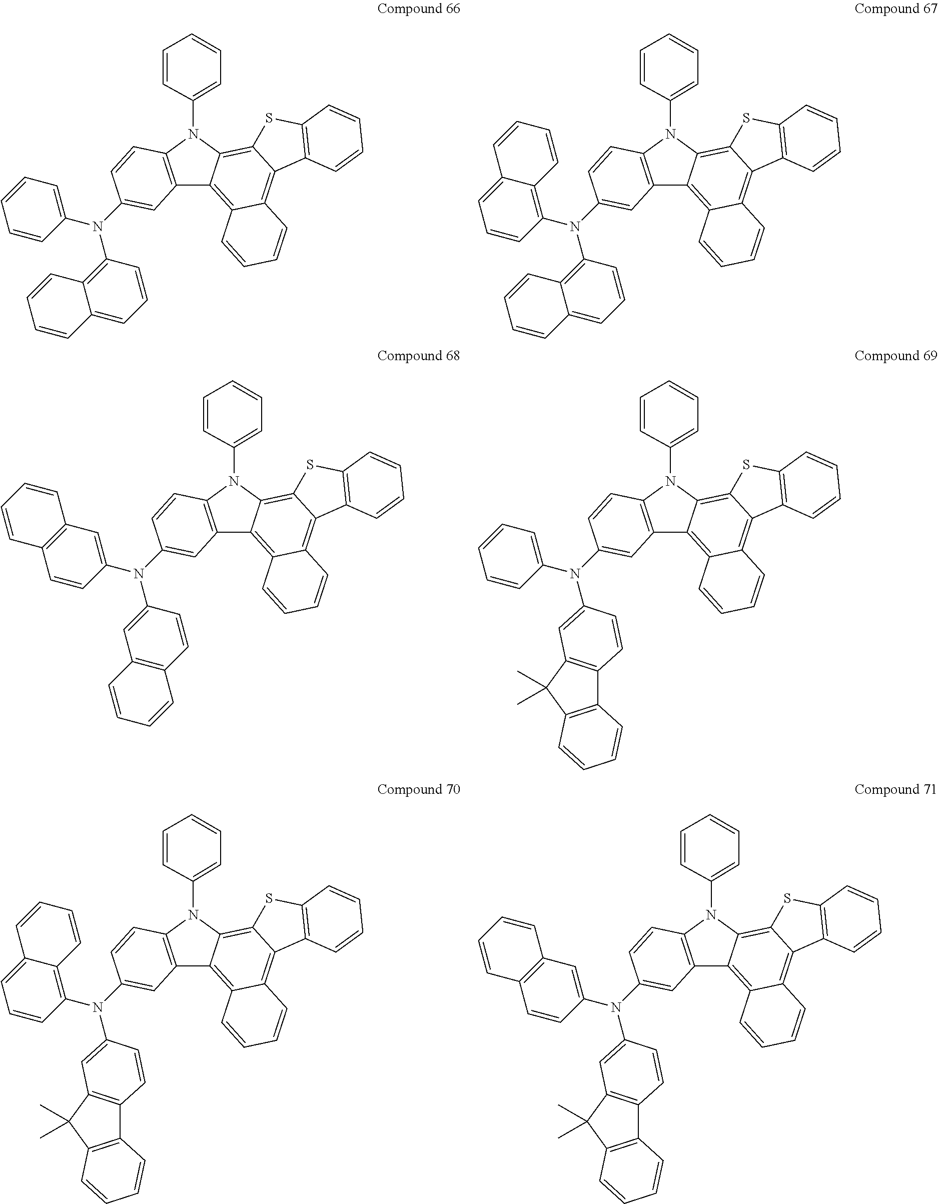

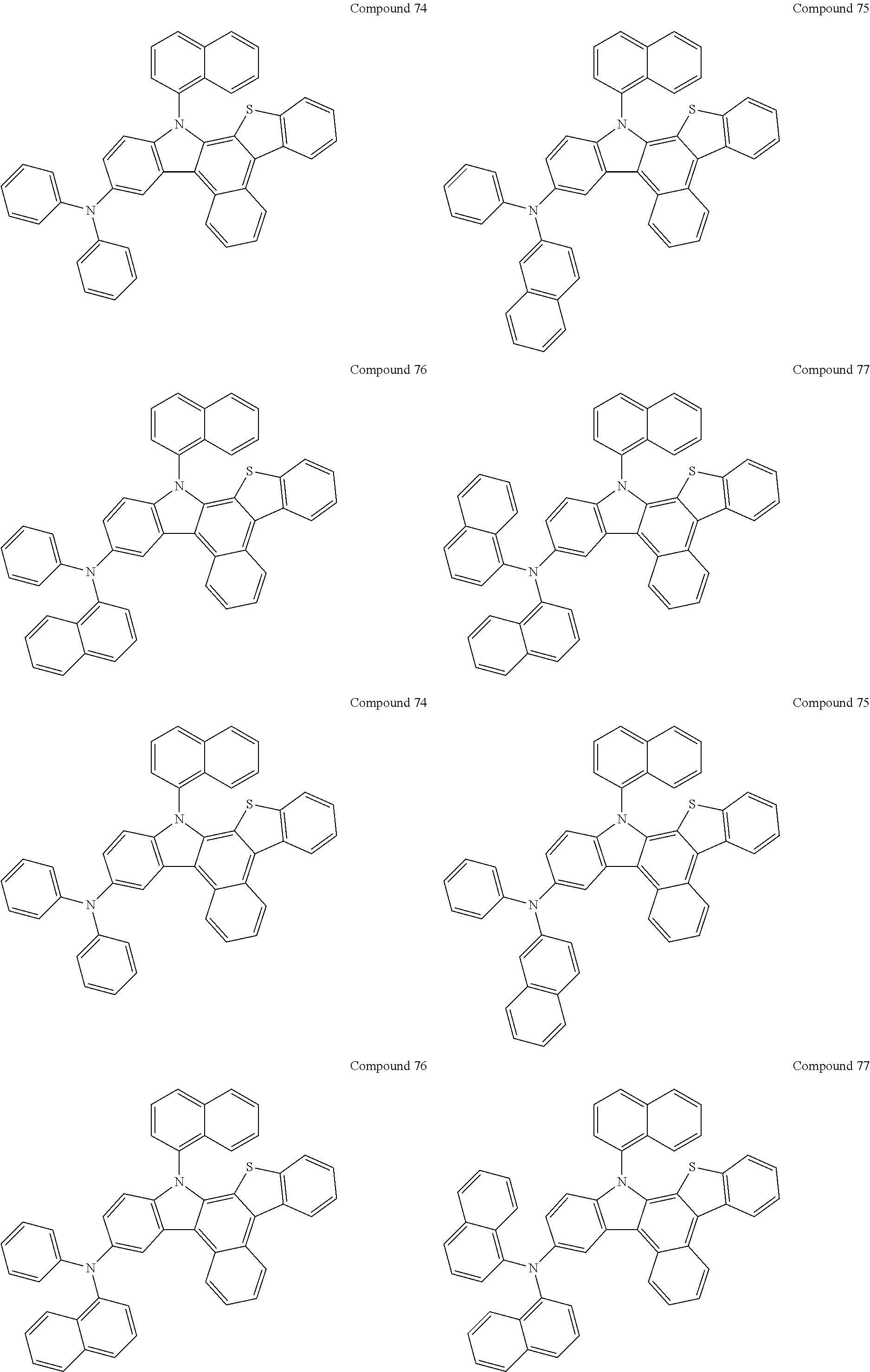

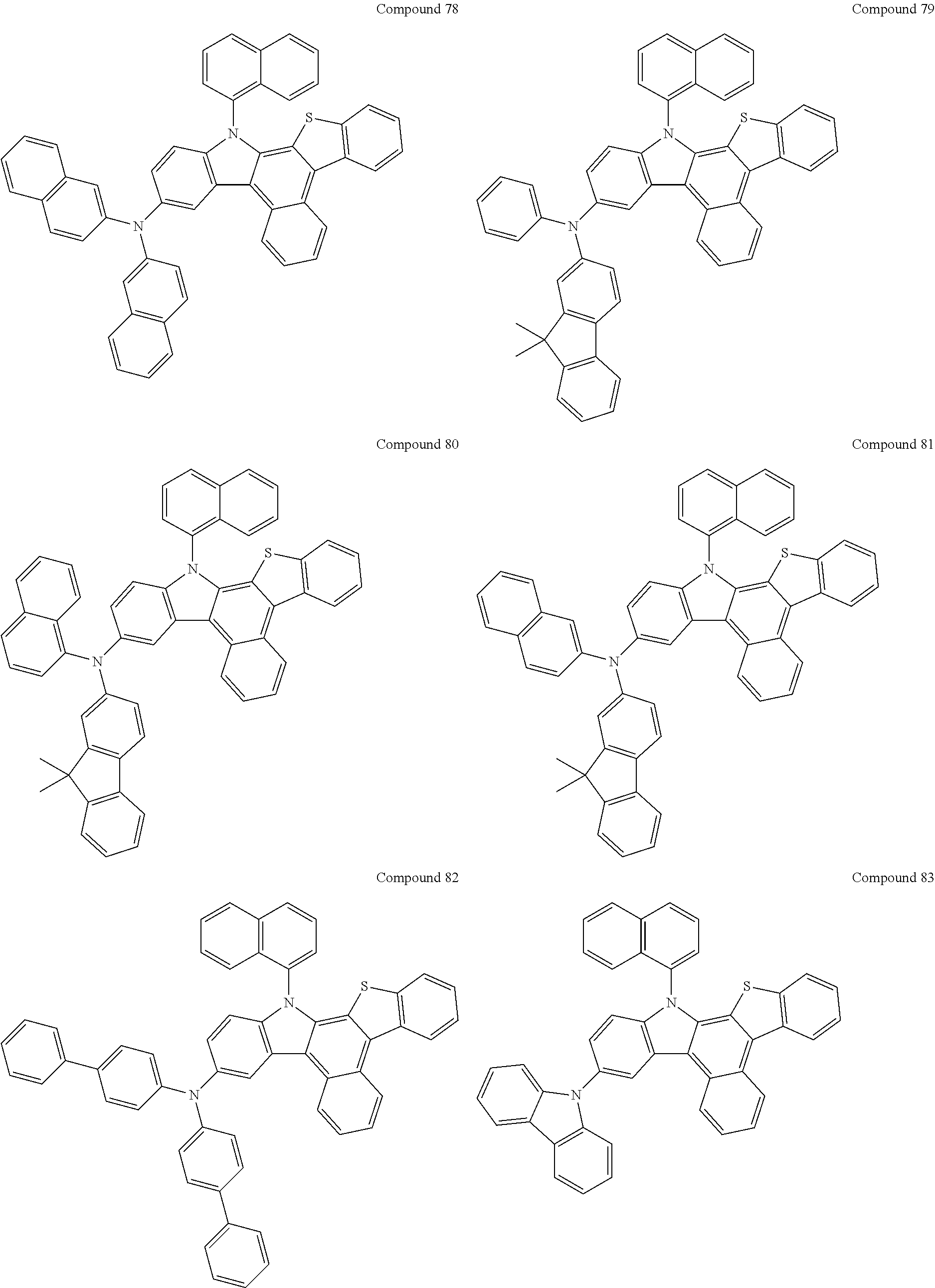

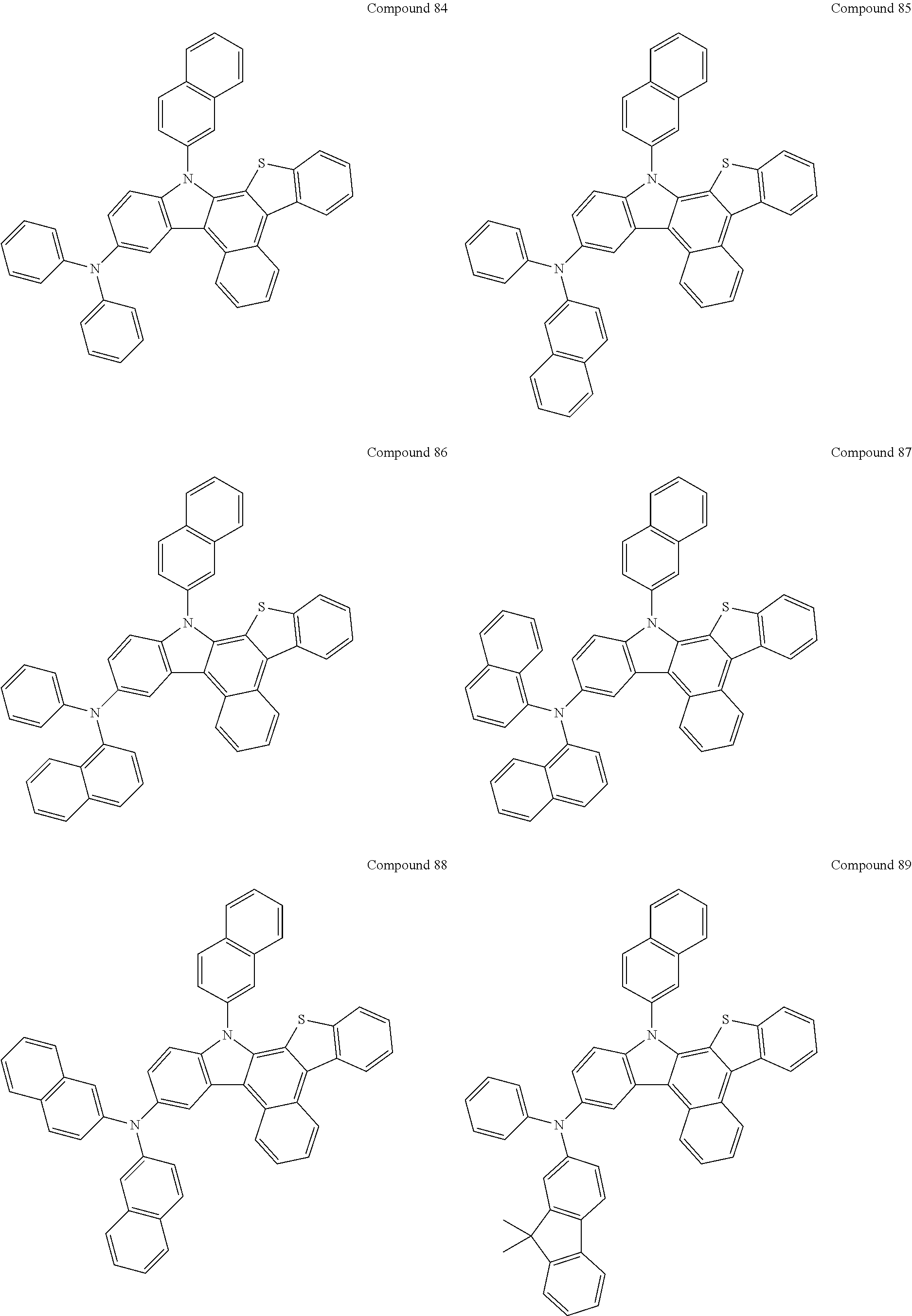

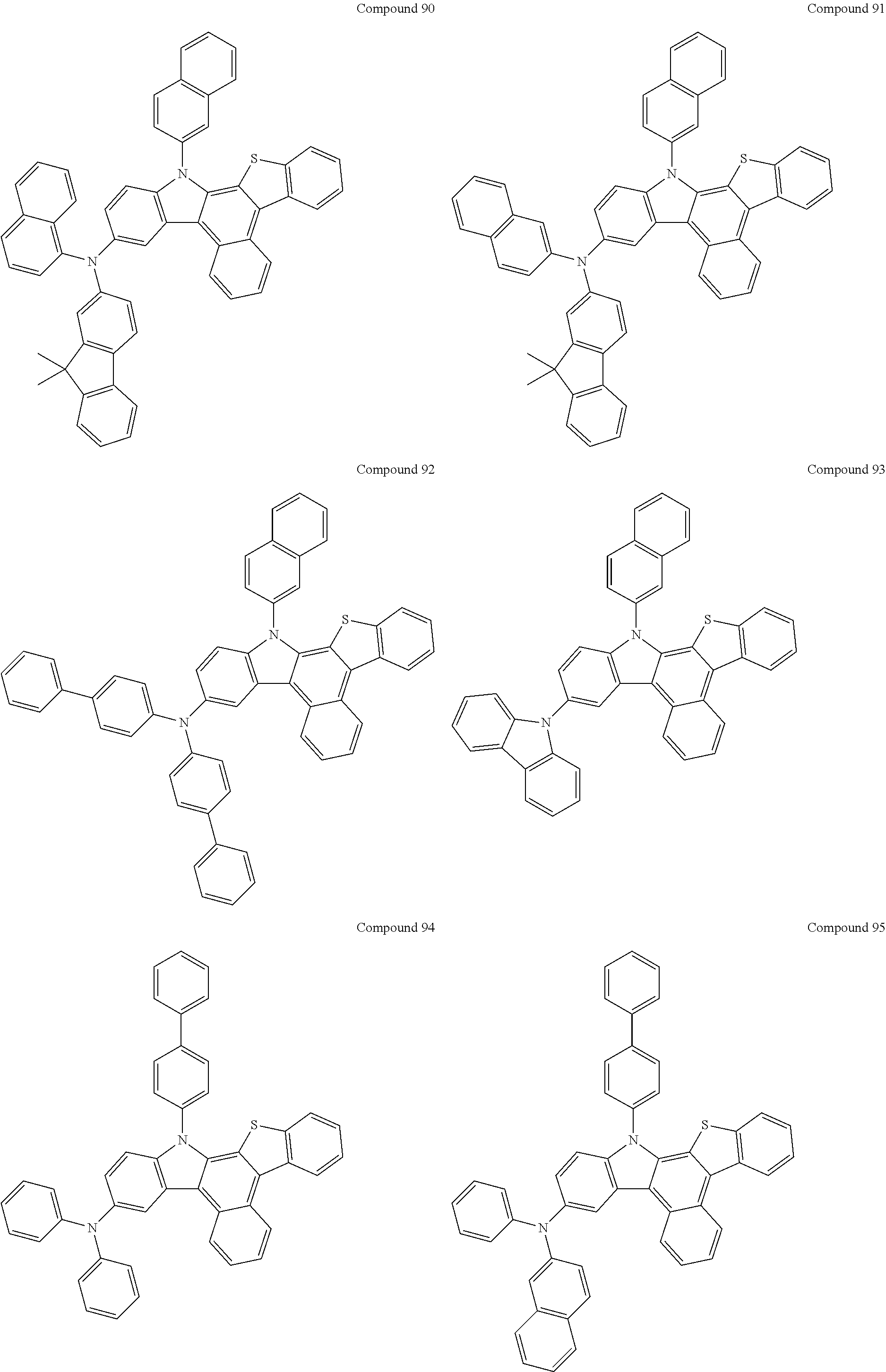

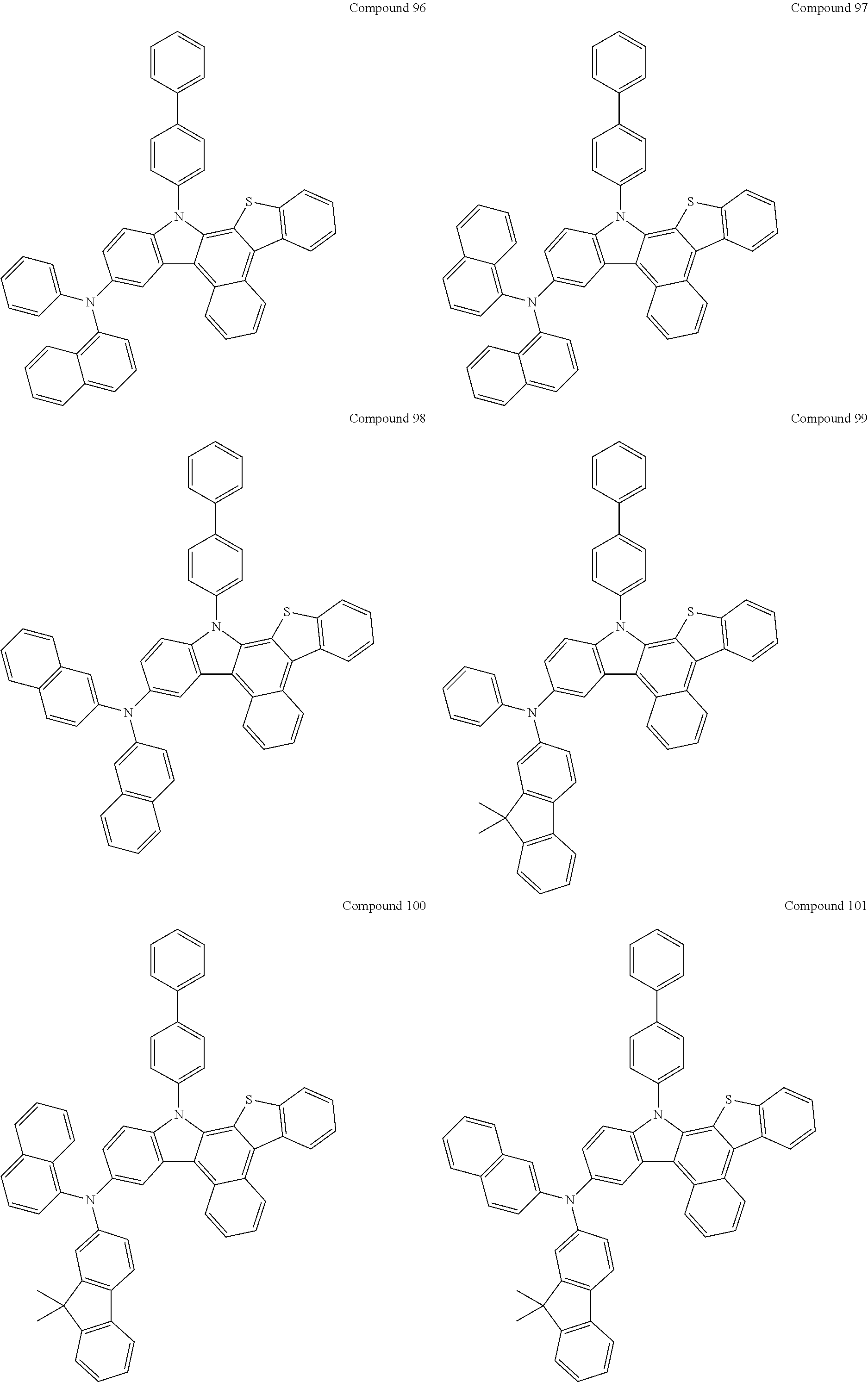

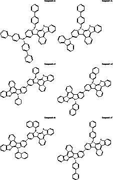

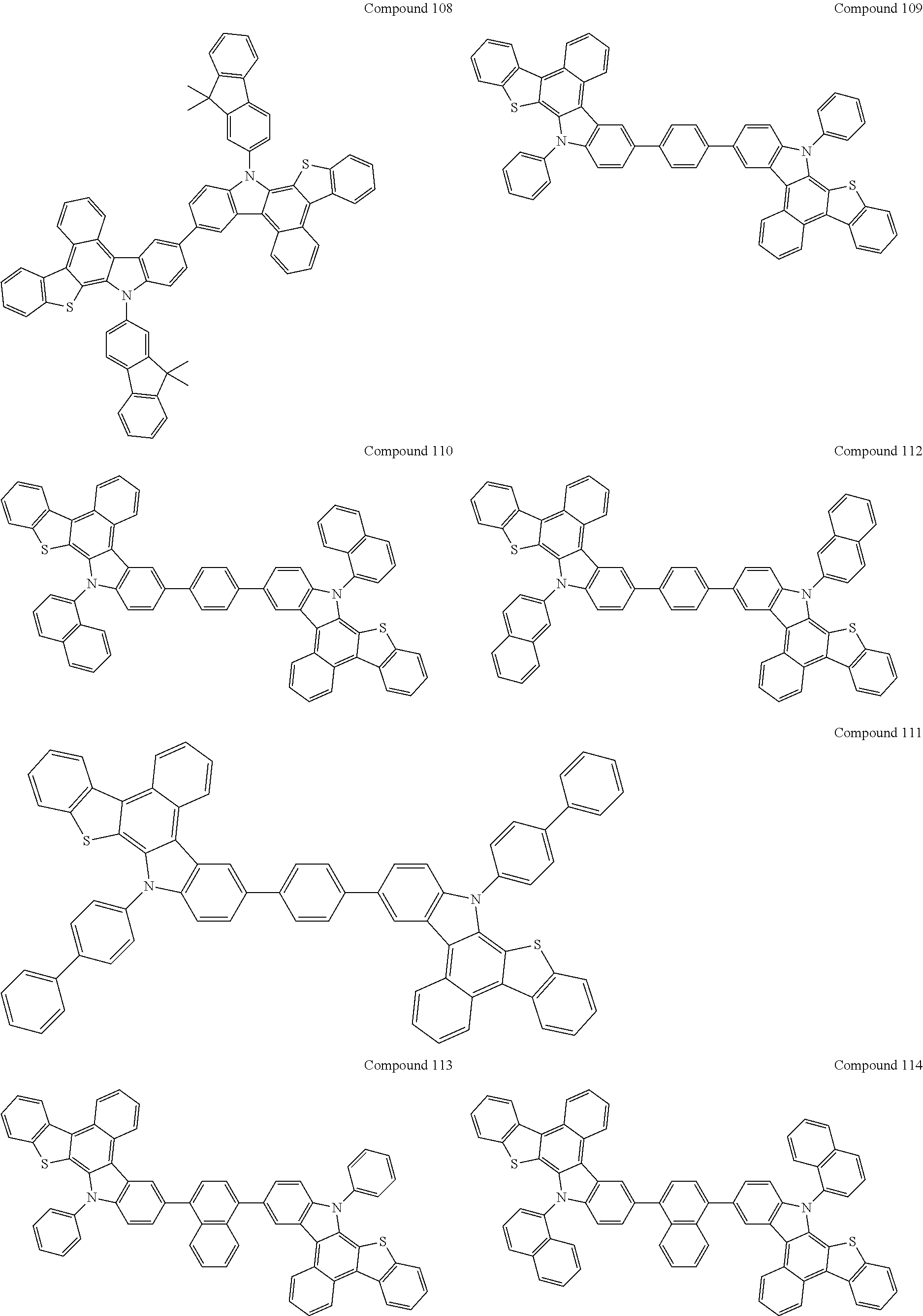

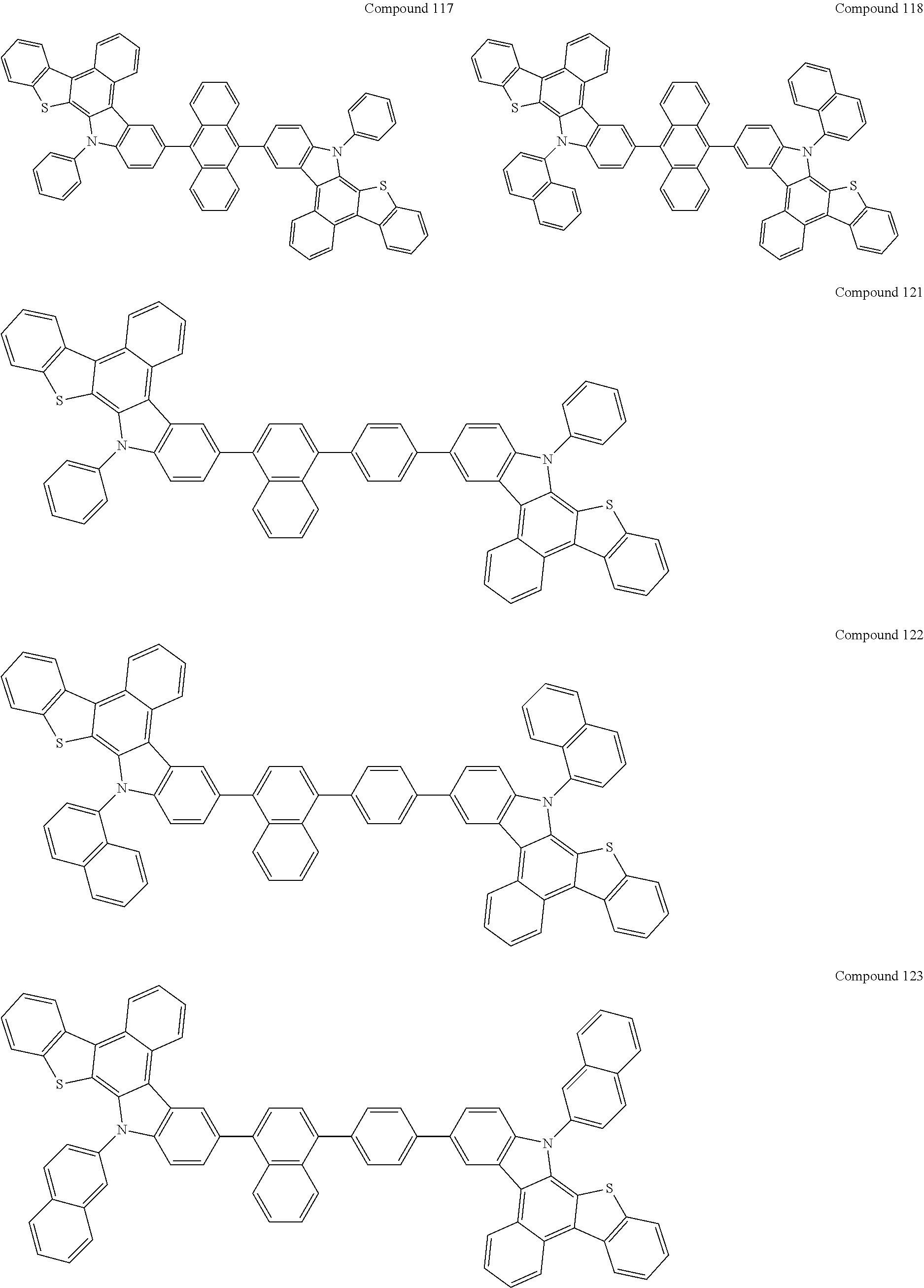

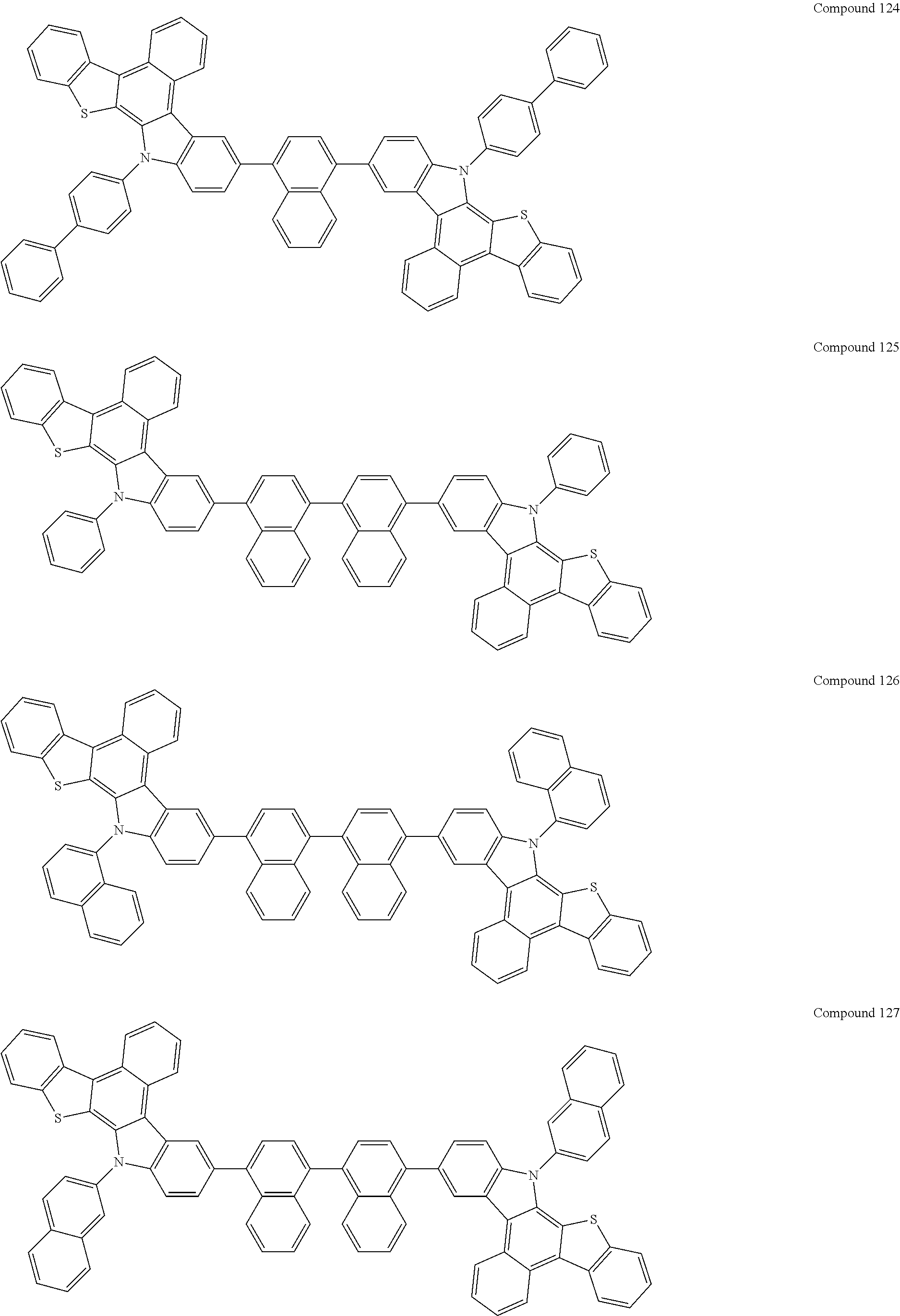

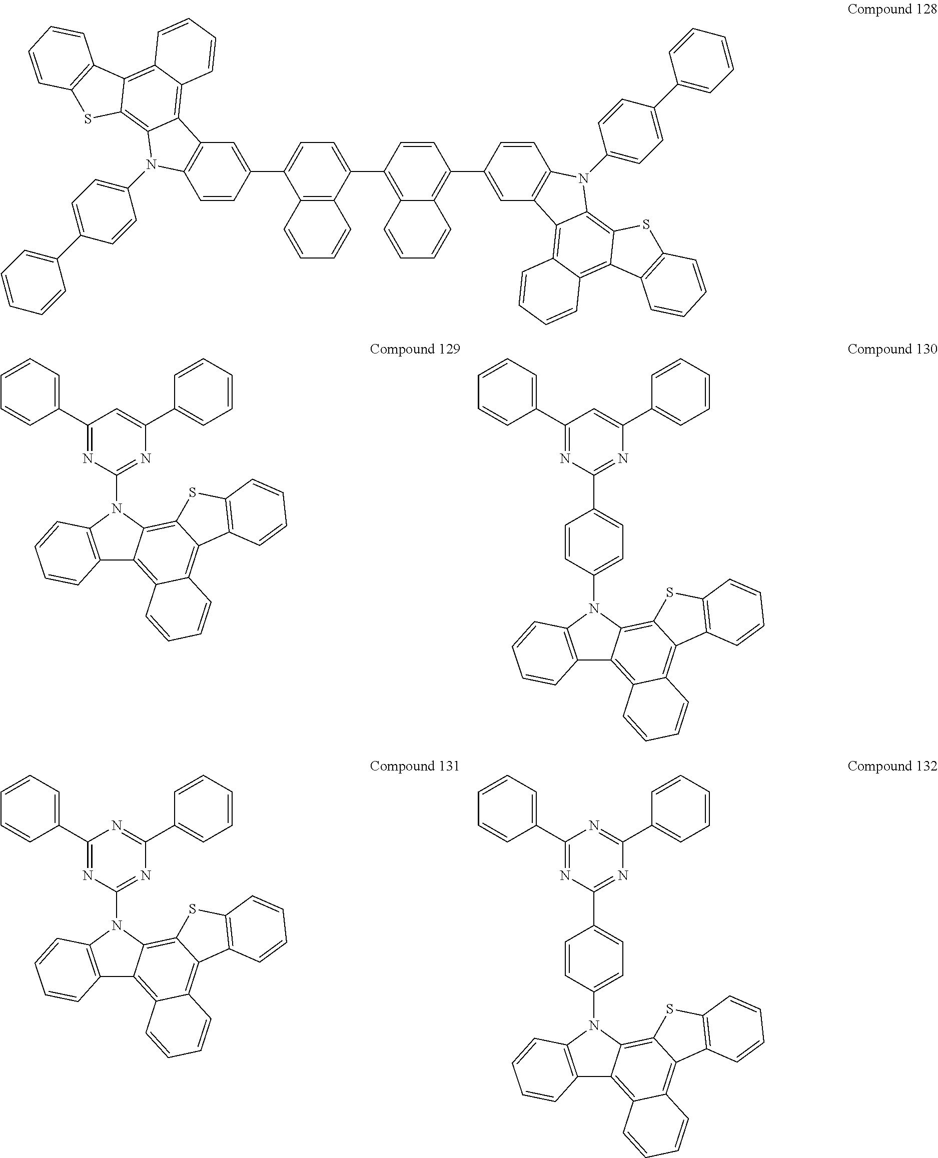

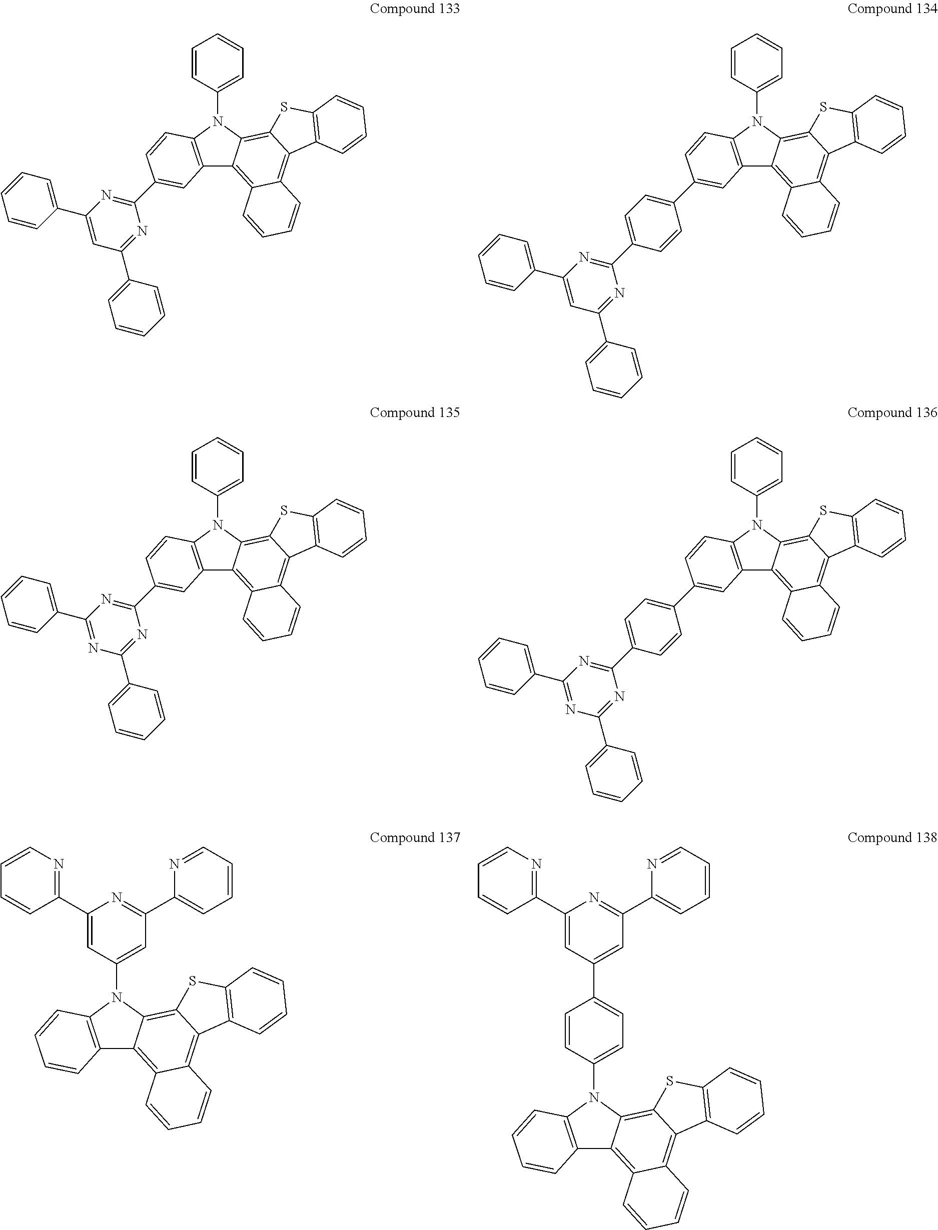

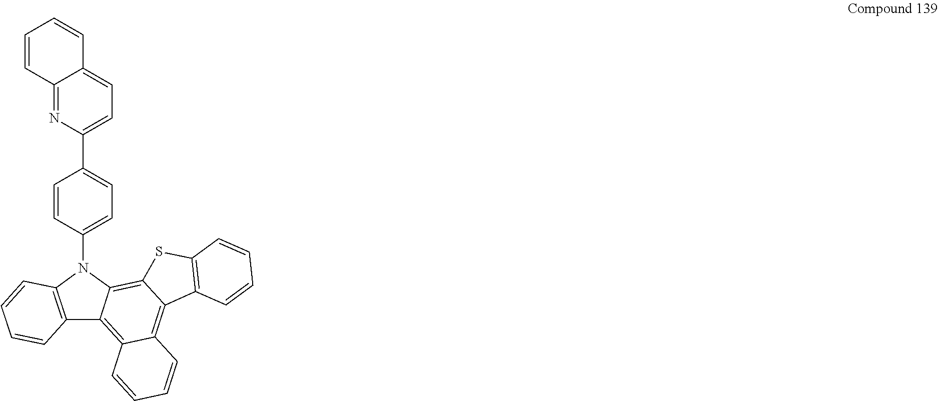 [SMILES: c1ccc2nc(-c3ccc(-n4c5ccccc5c5c6ccccc6c6c7ccccc7sc6c54)cc3)ccc2c1]

9. The organic light emitting device as claimed in claim 5, wherein the emission layer includes:
a first sub emission layer that includes the first host and the dopant;
a third host layer on the first sub emission layer, the third host layer including a fourth host; and
a second sub emission layer on the third host layer, the second sub emission layer including the first host and the dopant.

10. The organic light emitting device as claimed in claim 9, wherein the fourth host is represented by Formula 1.

11. The organic light emitting device as claimed in claim 9, wherein the third host layer does not include the dopant.

12. The organic light emitting device as claimed in claim 9, wherein the fourth host includes one of the following Compounds 1 to 57, 59 to 71, 74 to 114, and 117 to 139:

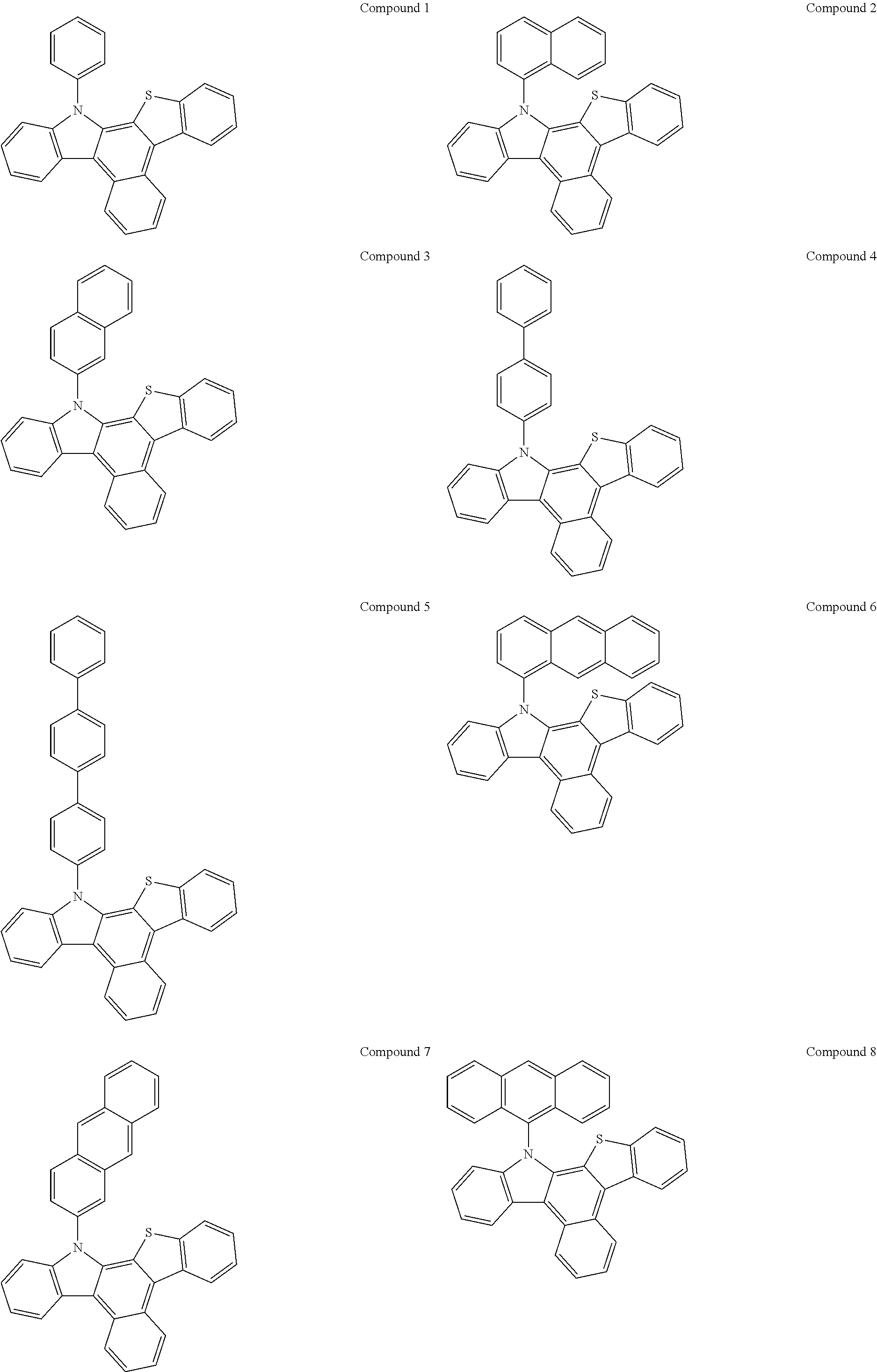

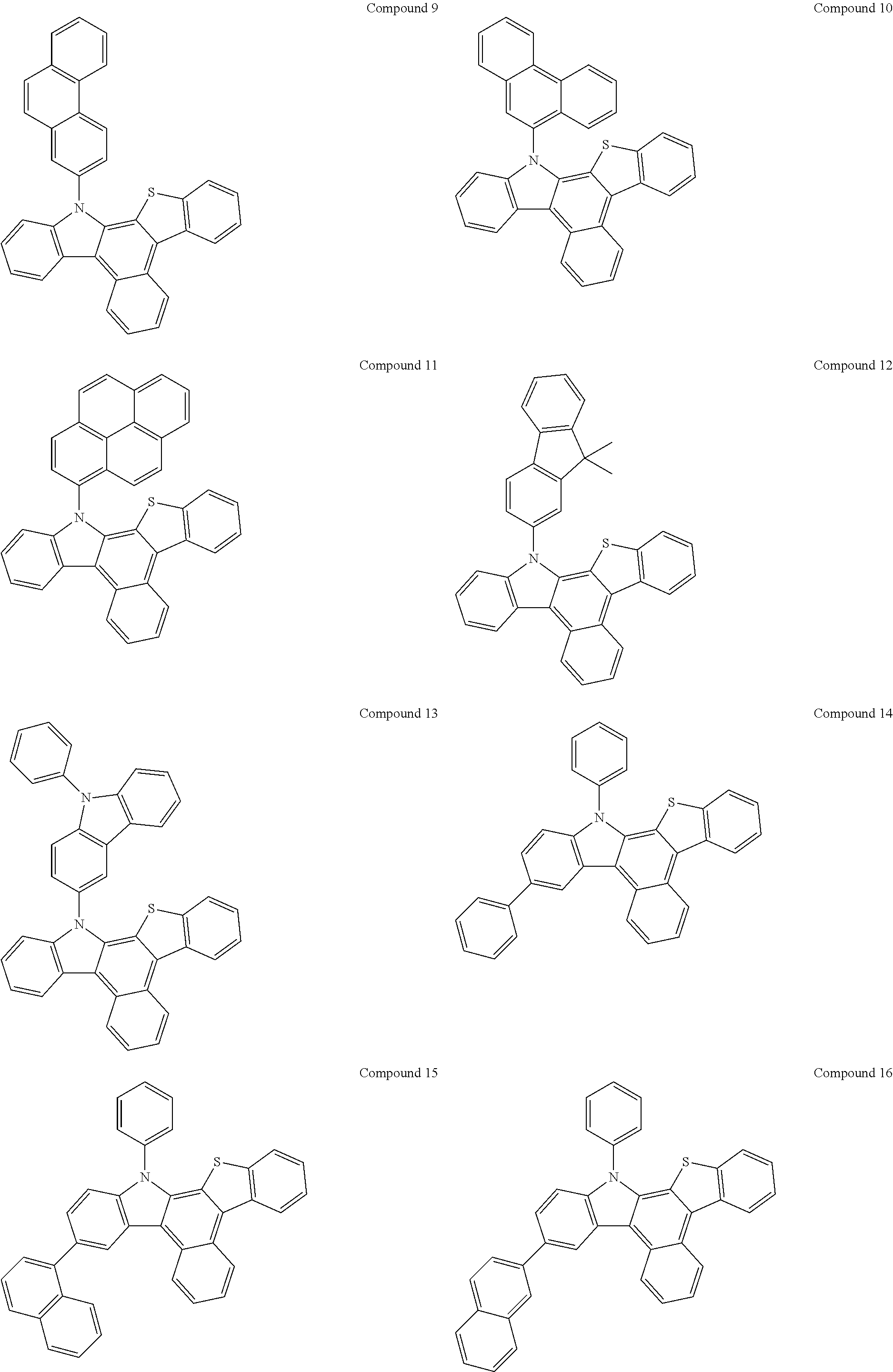

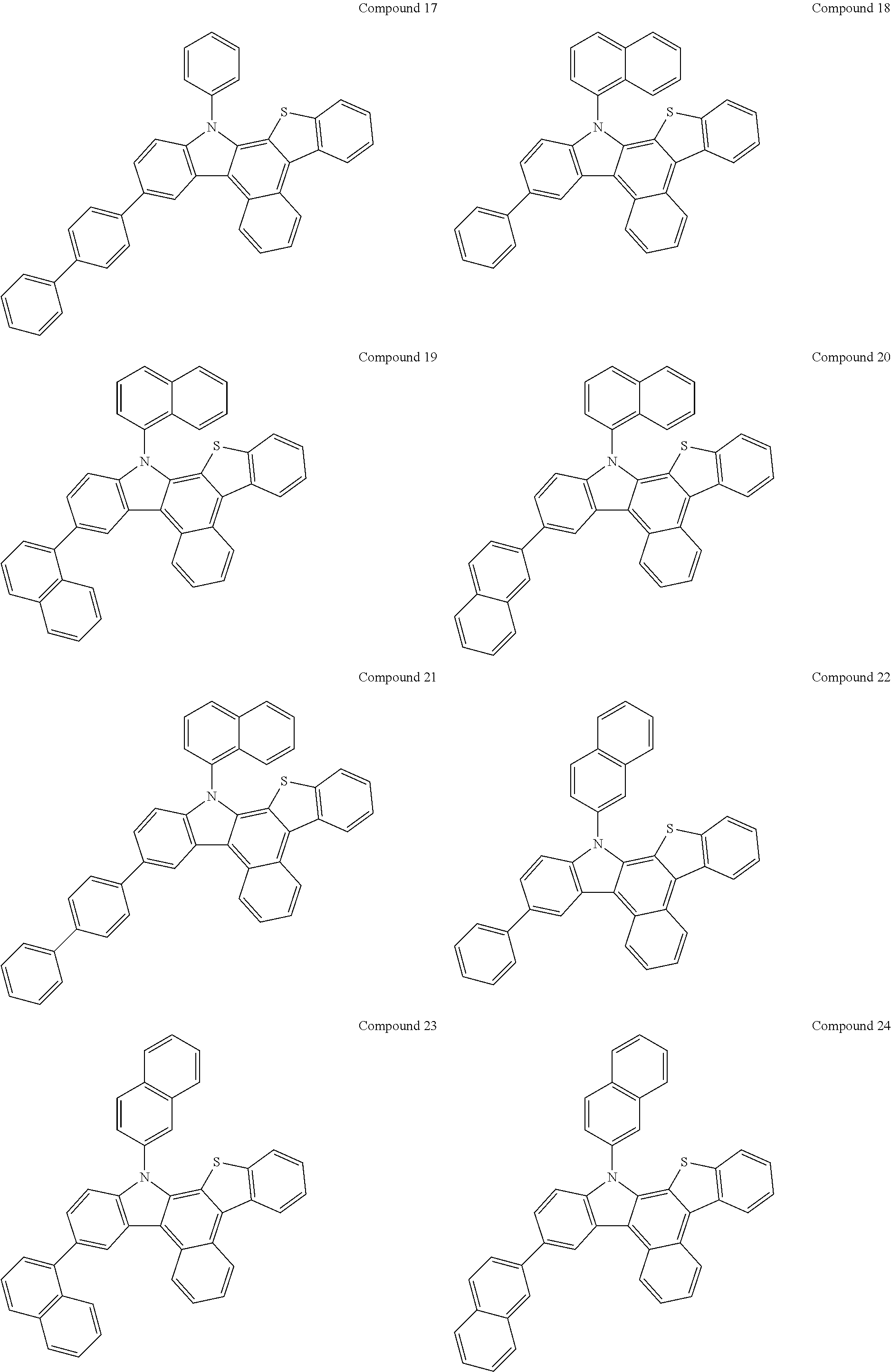

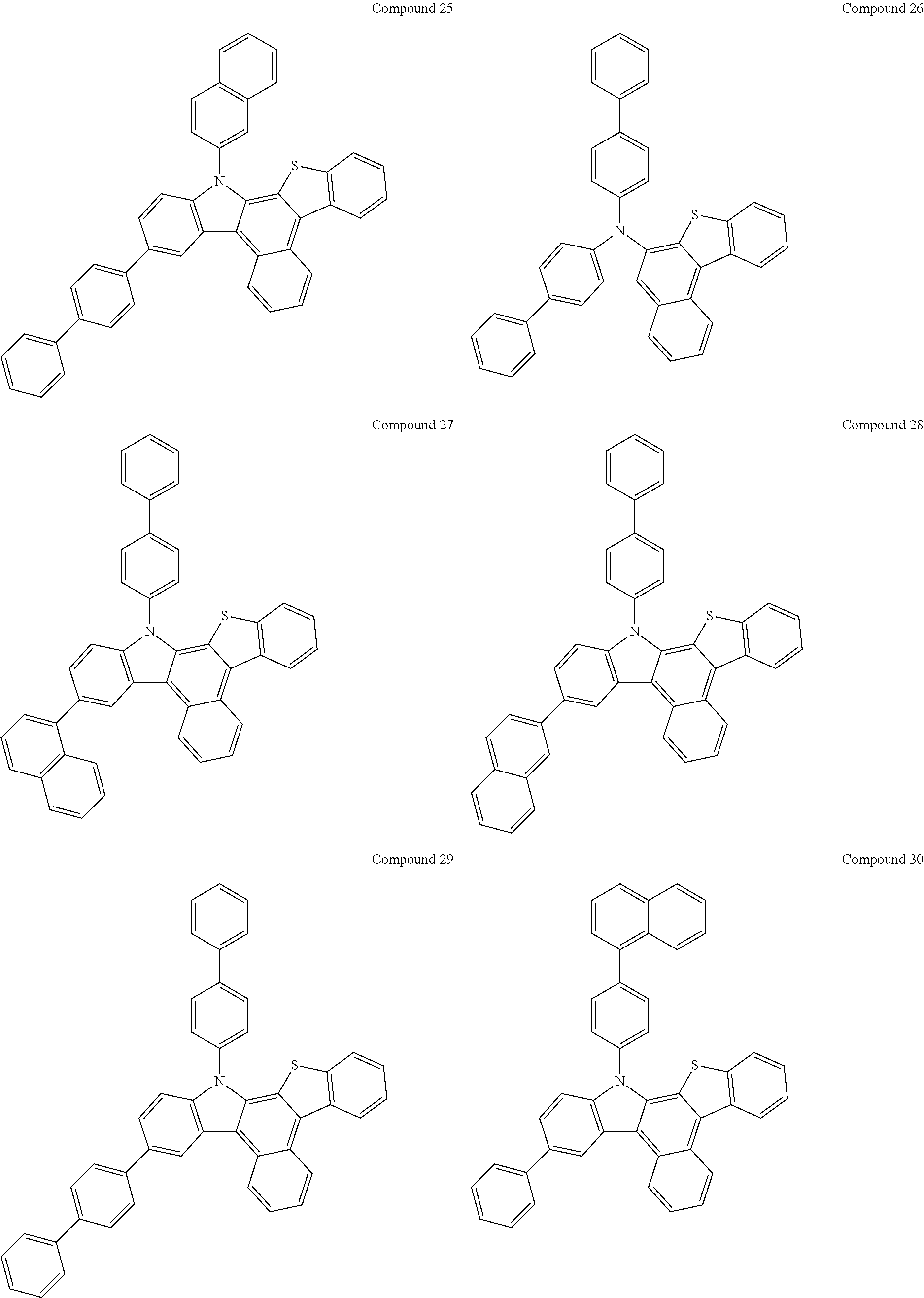 [SMILES: c1ccc(-c2ccc(-c3ccc4c(c3)c3c5ccccc5c5c6ccccc6sc5c3n4-c3ccc4ccccc4c3)cc2)cc1 ; c1ccc(-c2ccc(-n3c4ccc(-c5ccccc5)cc4c4c5ccccc5c5c6ccccc6sc5c43)cc2)cc1 ; c1ccc(-c2ccc(-n3c4ccc(-c5cccc6ccccc56)cc4c4c5ccccc5c5c6ccccc6sc5c43)cc2)cc1 ; c1ccc(-c2ccc(-n3c4ccc(-c5ccc6ccccc6c5)cc4c4c5ccccc5c5c6ccccc6sc5c43)cc2)cc1 ; c1ccc(-c2ccc(-c3ccc4c(c3)c3c5ccccc5c5c6ccccc6sc5c3n4-c3ccc(-c4ccccc4)cc3)cc2)cc1 ; c1ccc(-c2ccc3c(c2)c2c4ccccc4c4c5ccccc5sc4c2n3-c2ccc(-c3cccc4ccccc34)cc2)cc1]

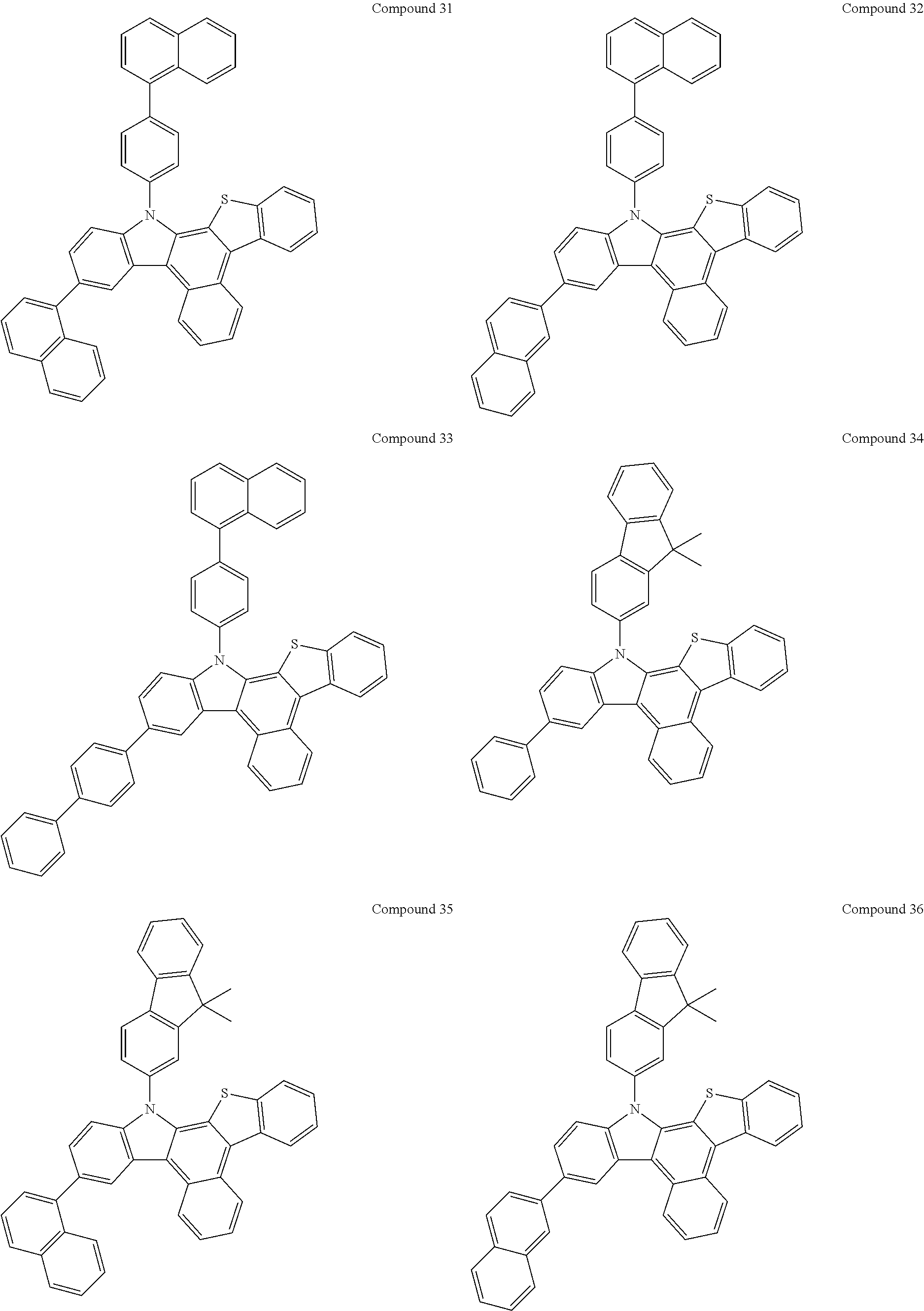 [SMILES: c1ccc2c(-c3ccc(-n4c5ccc(-c6cccc7ccccc67)cc5c5c6ccccc6c6c7ccccc7sc6c54)cc3)cccc2c1 ; c1ccc2cc(-c3ccc4c(c3)c3c5ccccc5c5c6ccccc6sc5c3n4-c3ccc(-c4cccc5ccccc45)cc3)ccc2c1 ; c1ccc(-c2ccc(-c3ccc4c(c3)c3c5ccccc5c5c6ccccc6sc5c3n4-c3ccc(-c4cccc5ccccc45)cc3)cc2)cc1 ; CC1(C)c2ccccc2-c2ccc(-n3c4ccc(-c5ccccc5)cc4c4c5ccccc5c5c6ccccc6sc5c43)cc21 ; CC1(C)c2ccccc2-c2ccc(-n3c4ccc(-c5cccc6ccccc56)cc4c4c5ccccc5c5c6ccccc6sc5c43)cc21 ; CC1(C)c2ccccc2-c2ccc(-n3c4ccc(-c5ccc6ccccc6c5)cc4c4c5ccccc5c5c6ccccc6sc5c43)cc21]

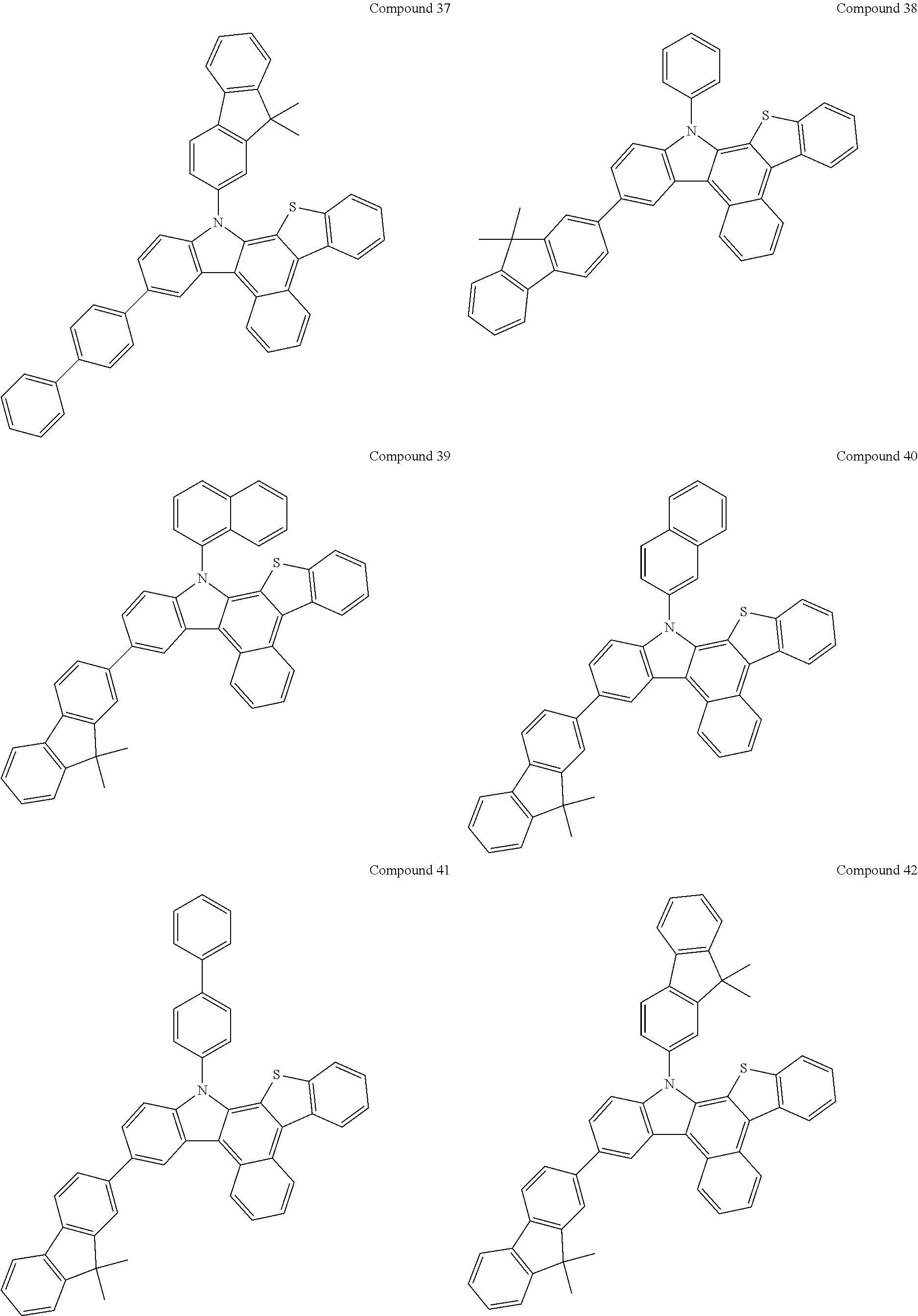

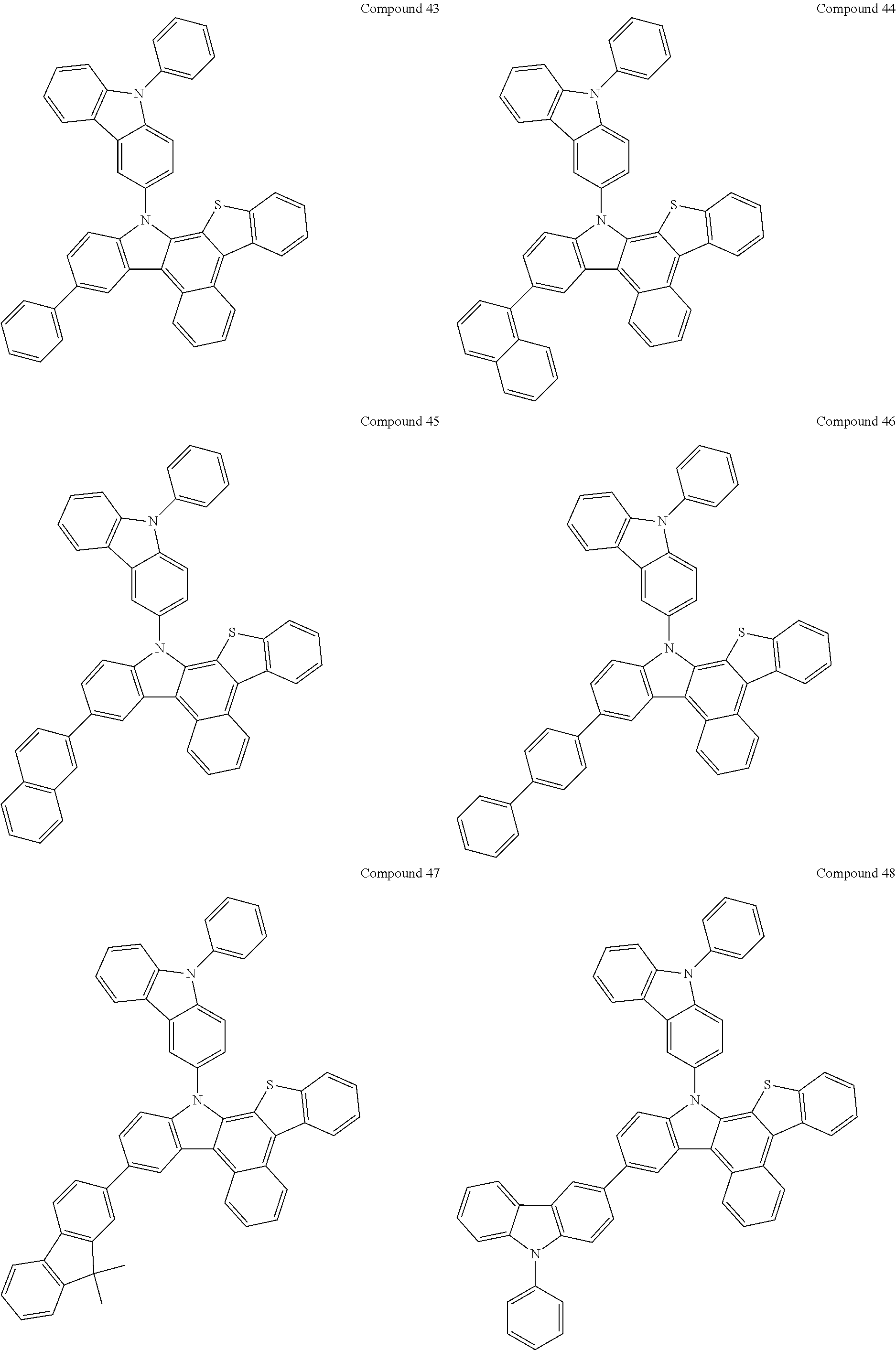

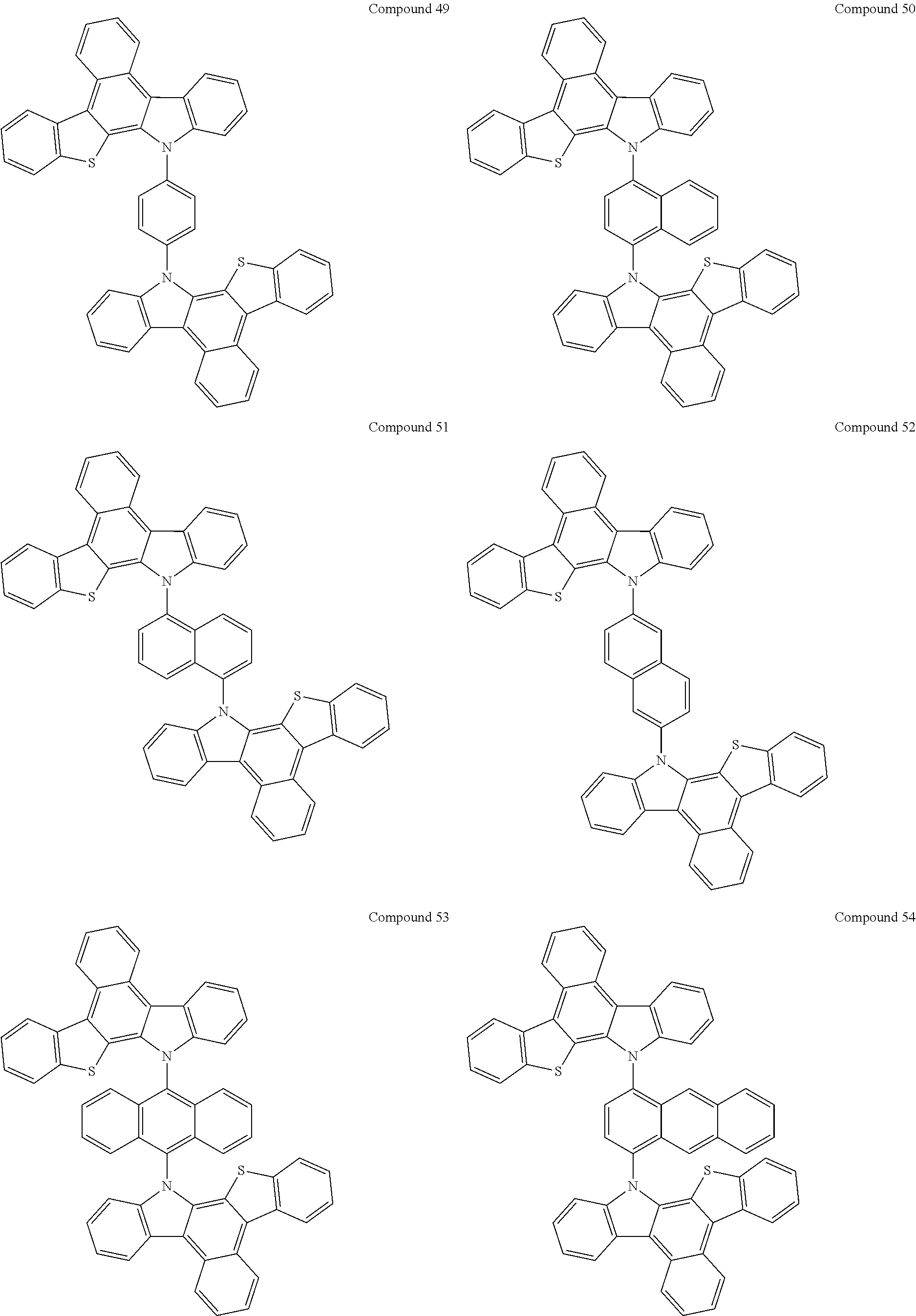

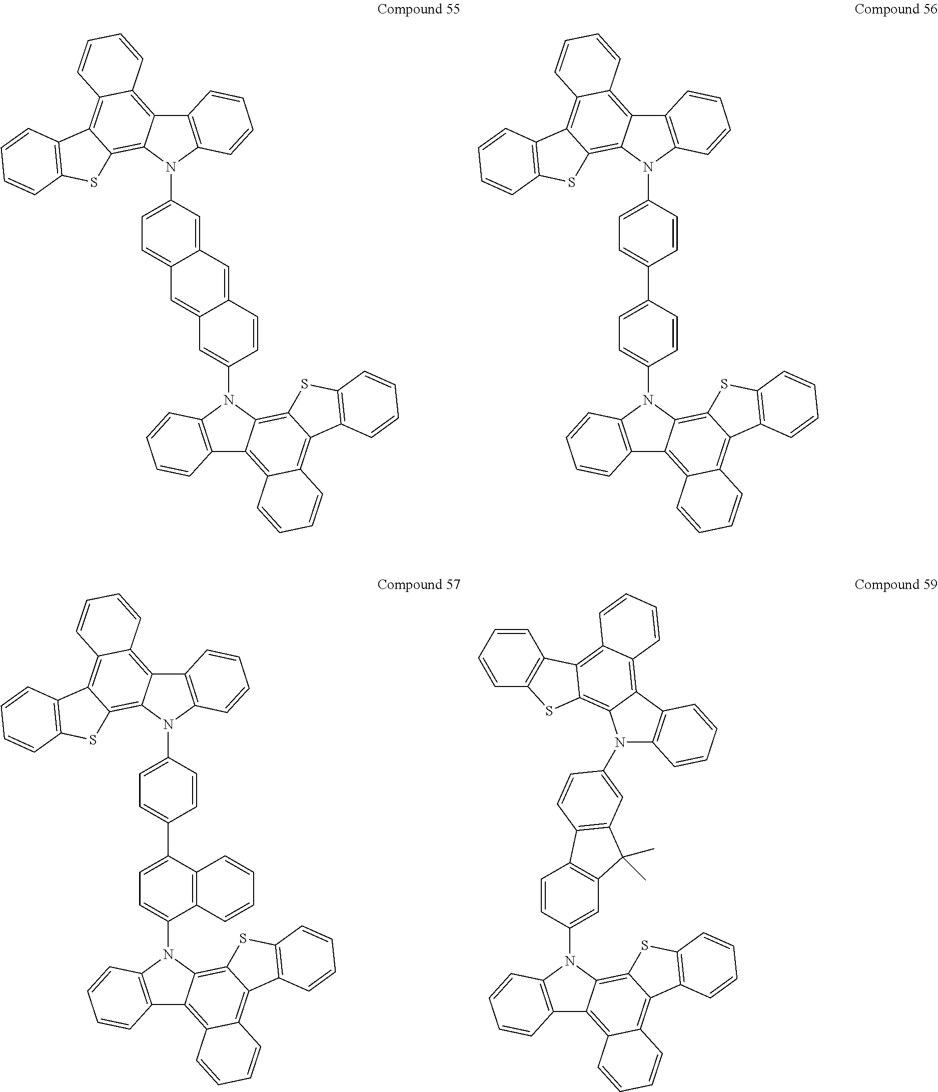 [SMILES: c1ccc2c(c1)sc1c2c2ccccc2c2c3ccccc3n(-c3ccc4cc5cc(-n6c7ccccc7c7c8ccccc8c8c9ccccc9sc8c76)ccc5cc4c3)c12 ; c1ccc2c(c1)sc1c2c2ccccc2c2c3ccccc3n(-c3ccc(-c4ccc(-n5c6ccccc6c6c7ccccc7c7c8ccccc8sc7c65)cc4)cc3)c12 ; c1ccc2c(c1)sc1c2c2ccccc2c2c3ccccc3n(-c3ccc(-c4ccc(-n5c6ccccc6c6c7ccccc7c7c8ccccc8sc7c65)c5ccccc45)cc3)c12 ; CC1(C)c2cc(-n3c4ccccc4c4c5ccccc5c5c6ccccc6sc5c43)ccc2-c2ccc(-n3c4ccccc4c4c5ccccc5c5c6ccccc6sc5c43)cc21]

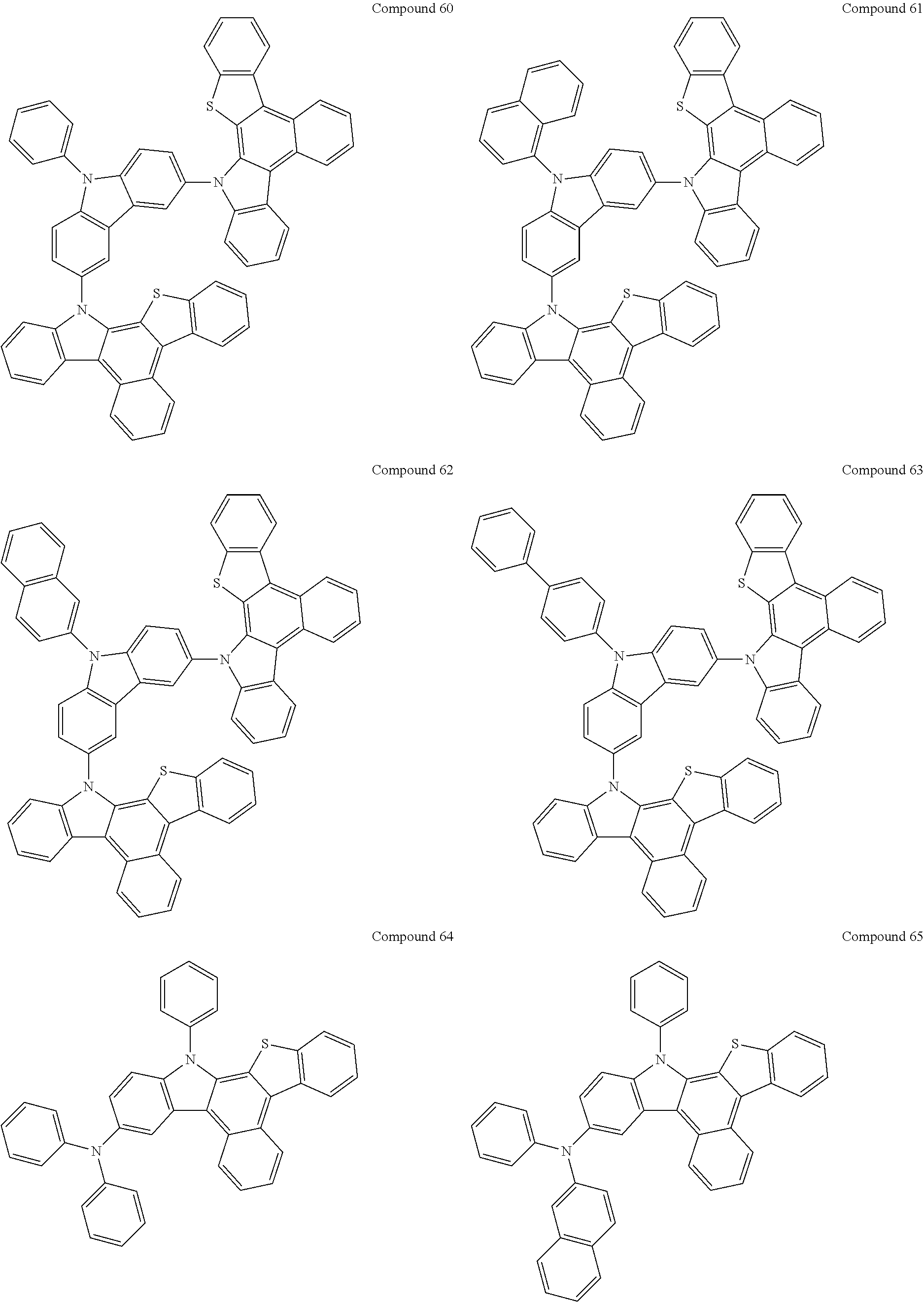

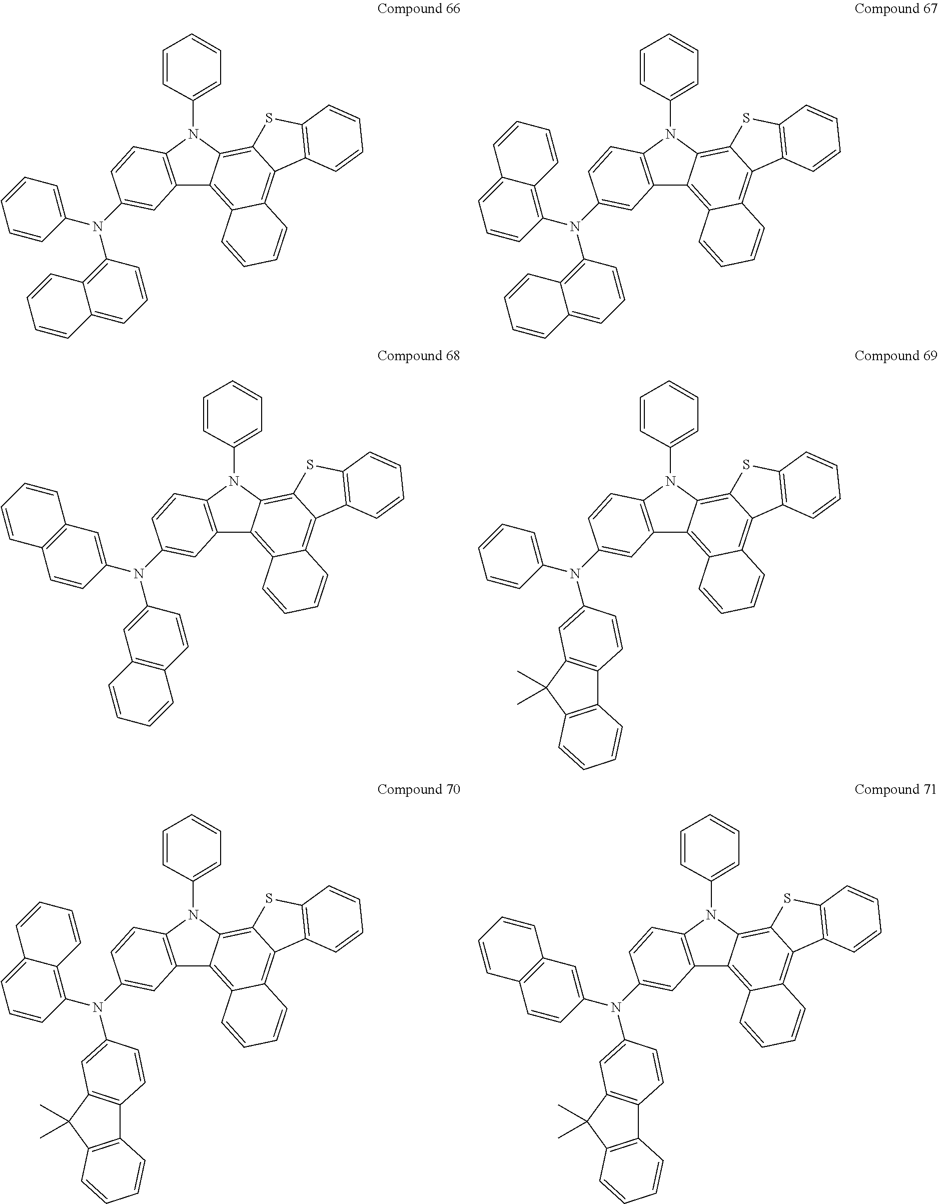

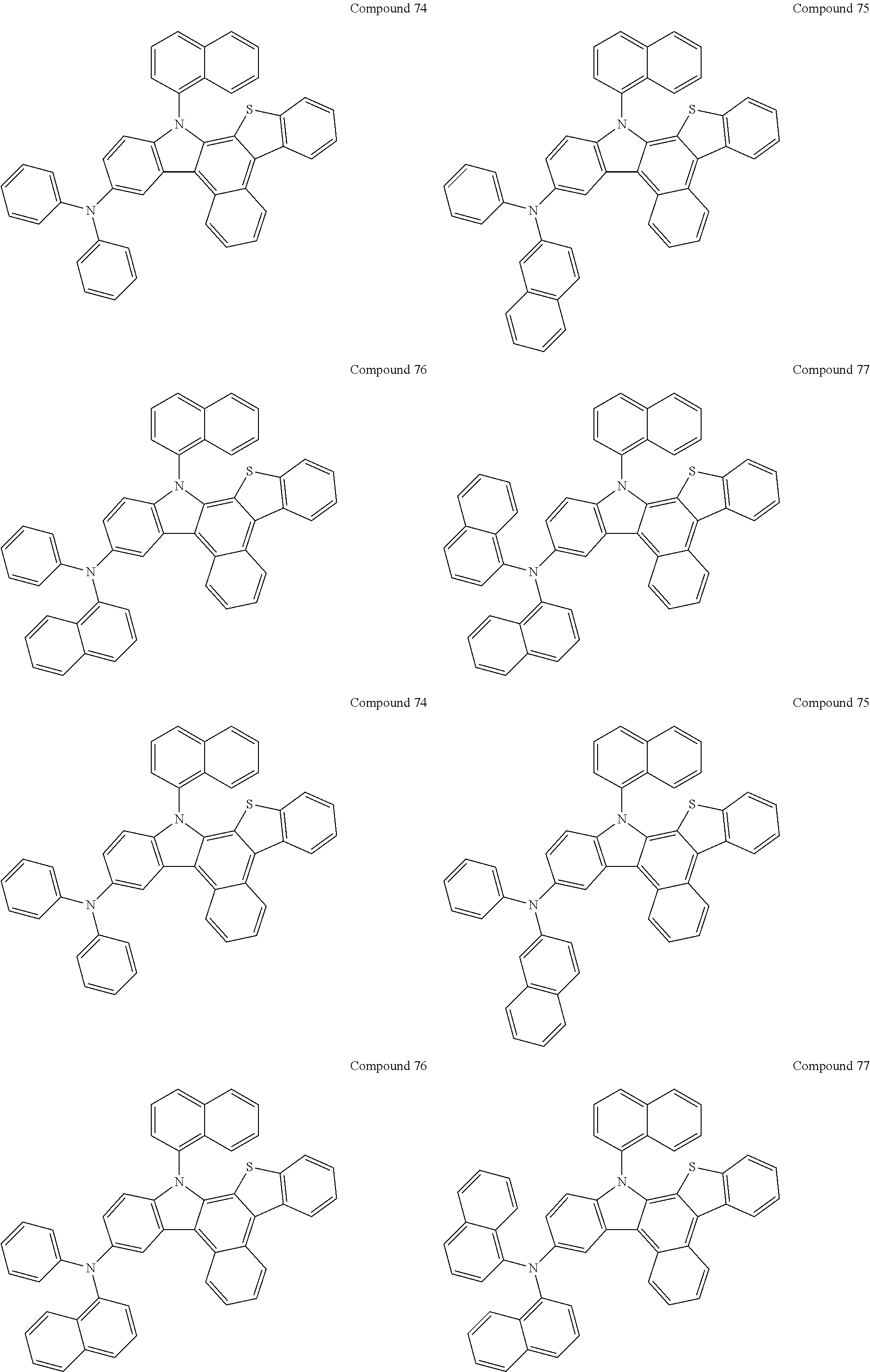

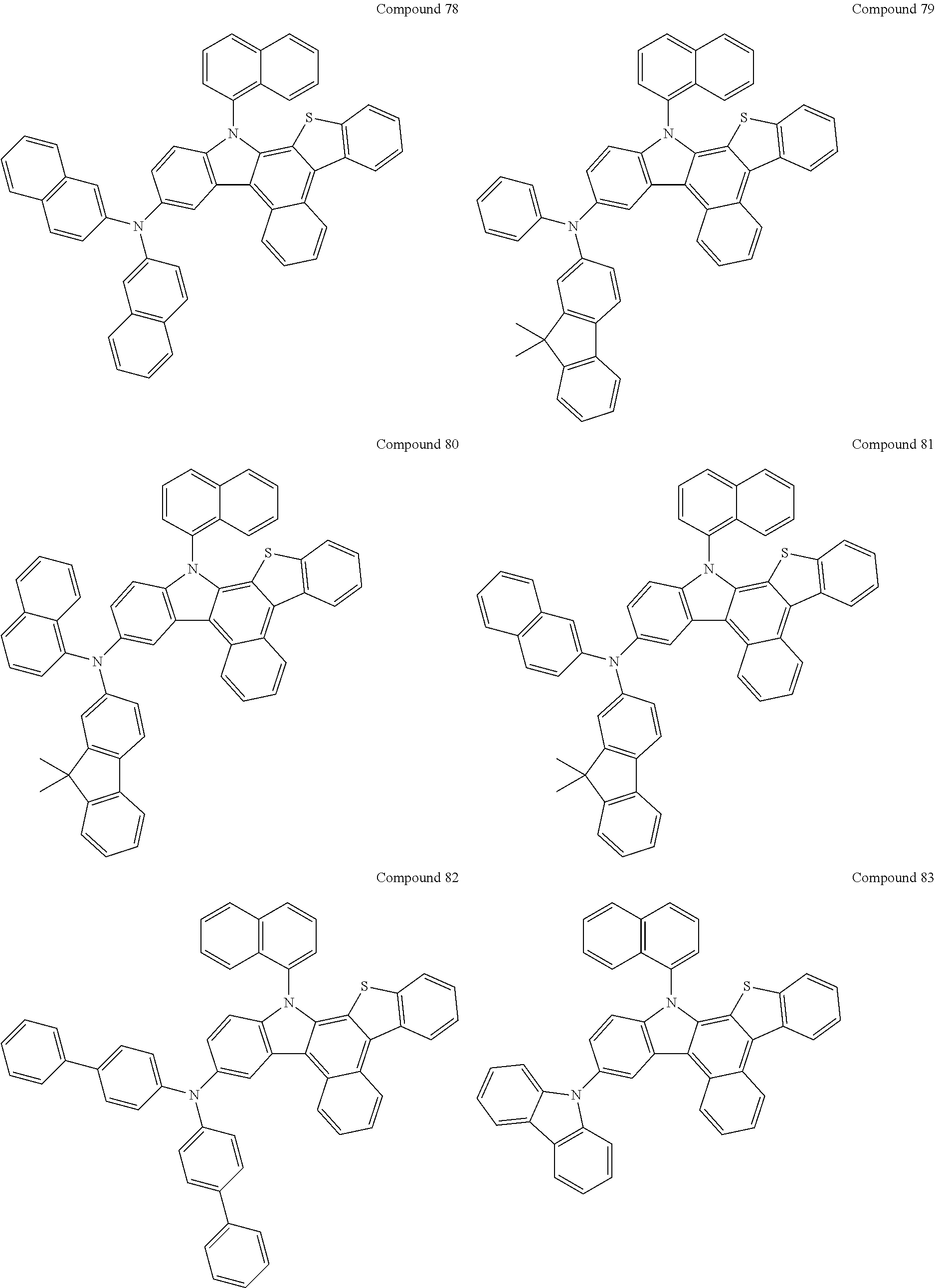

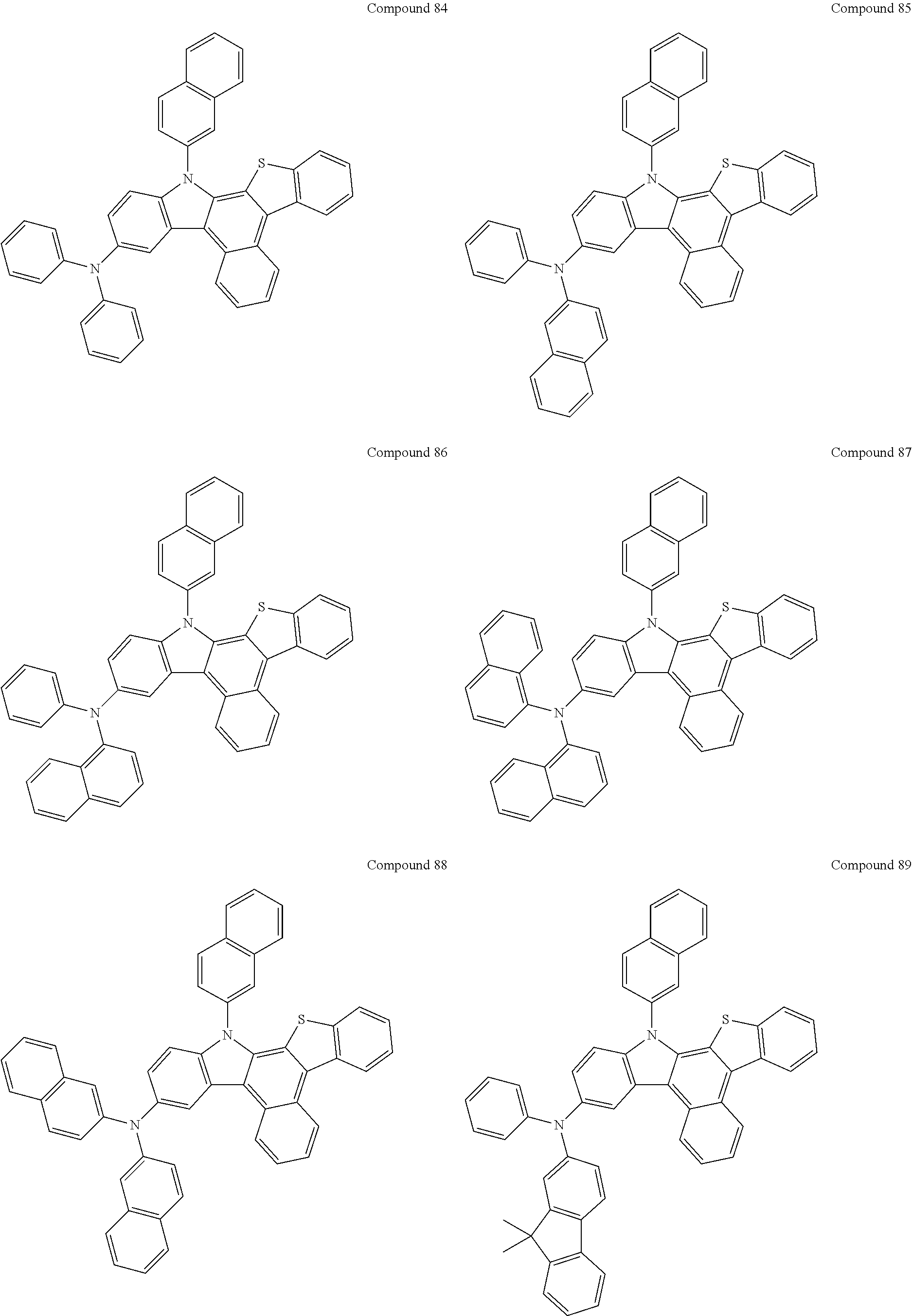

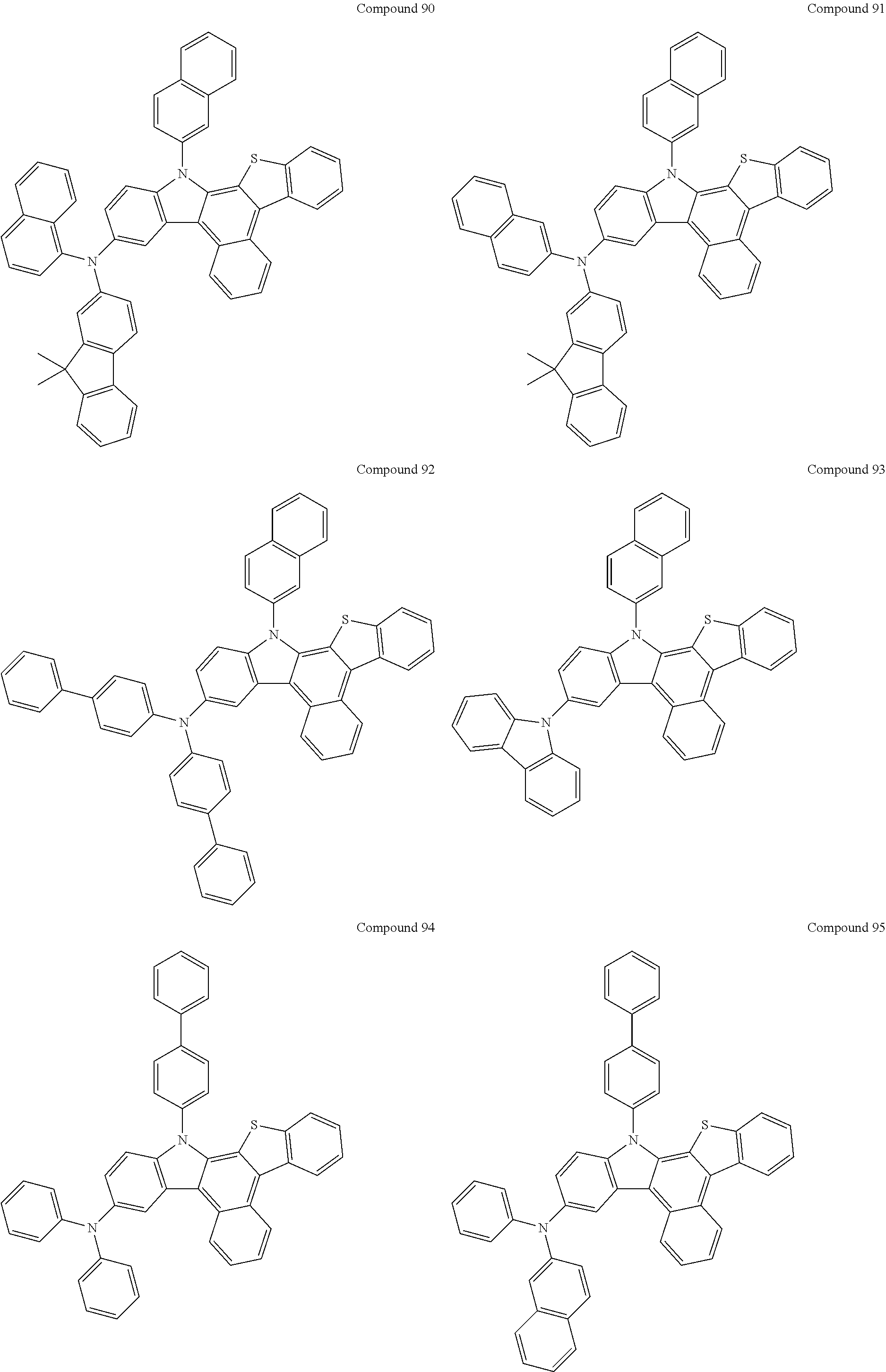

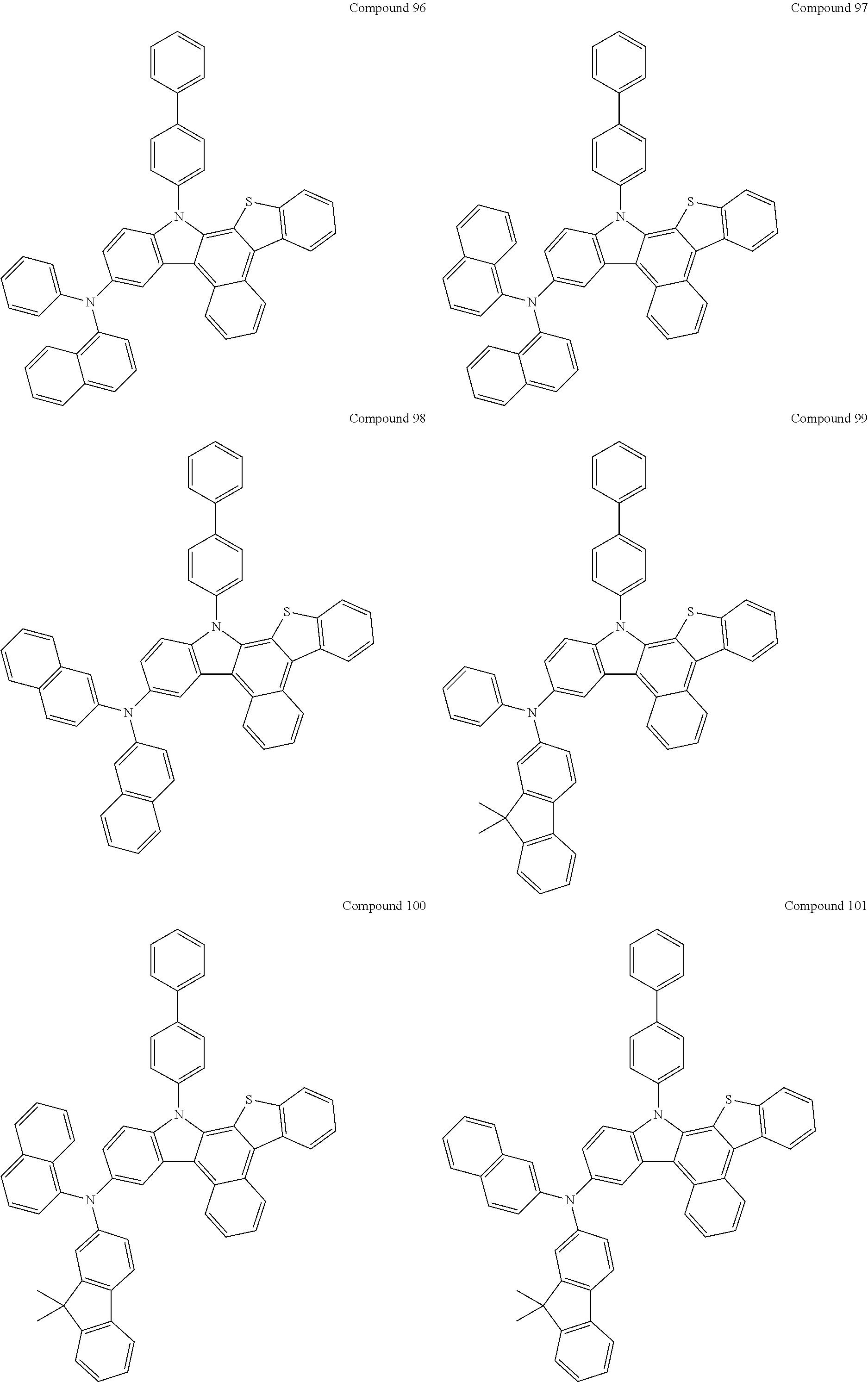

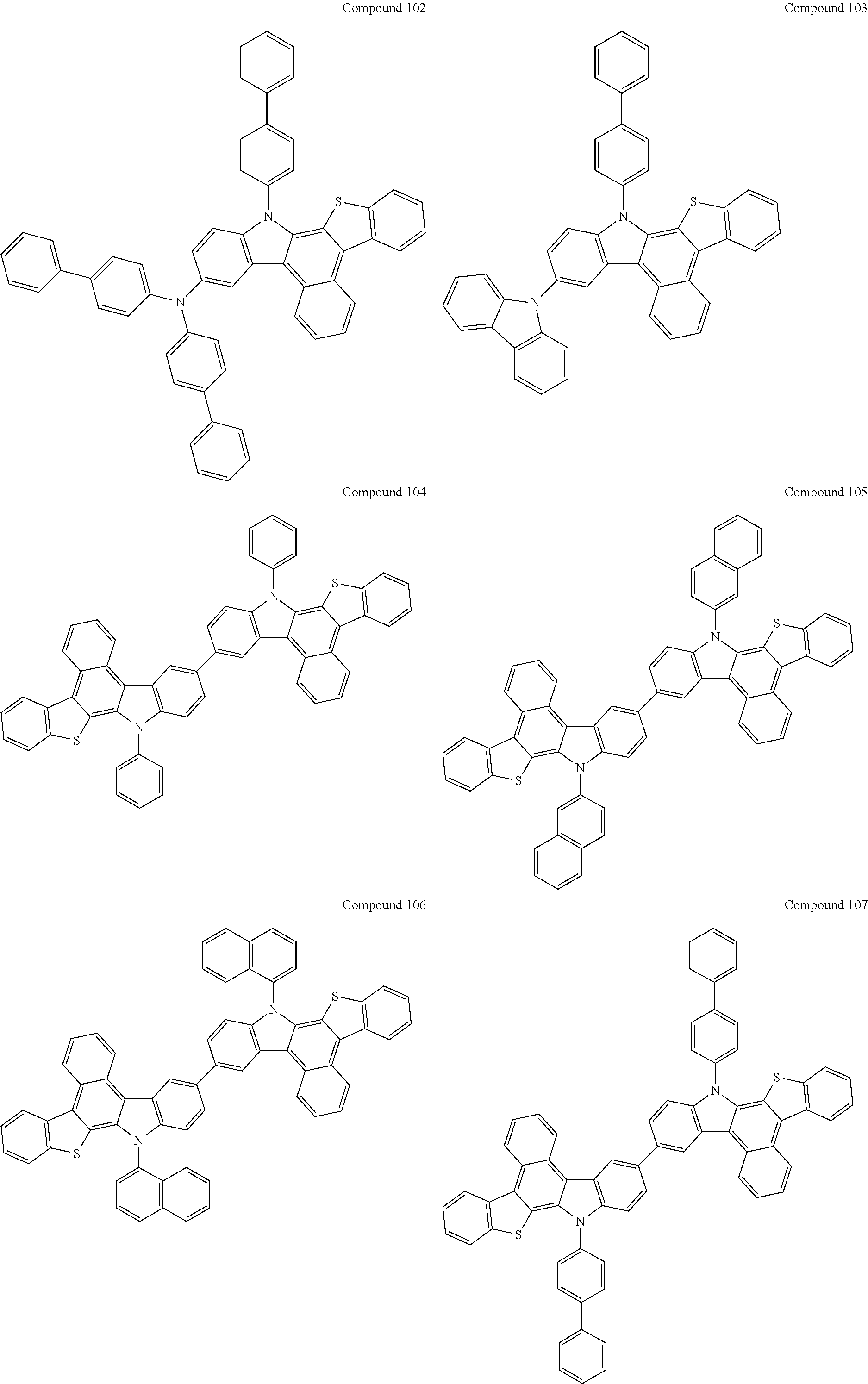

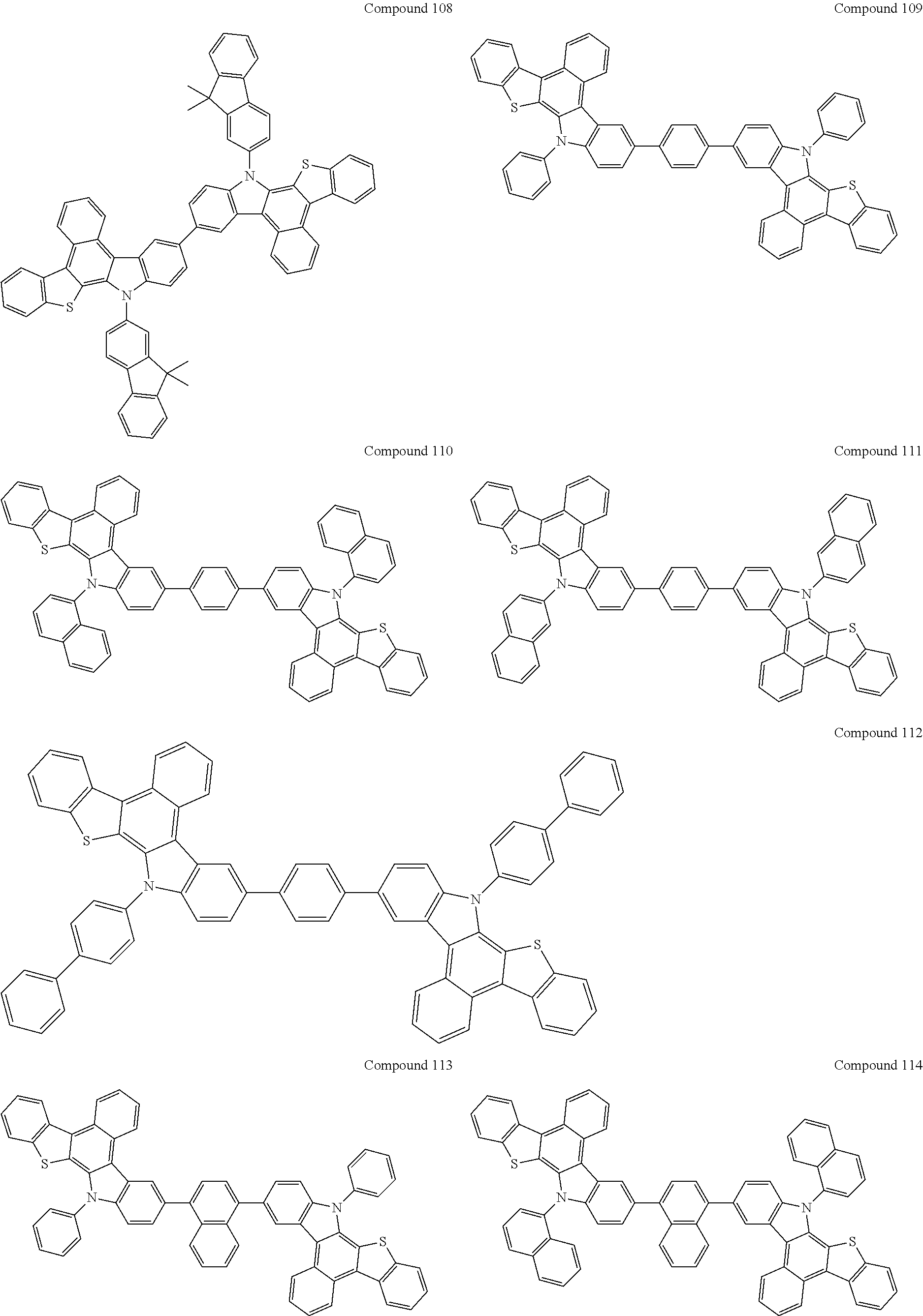

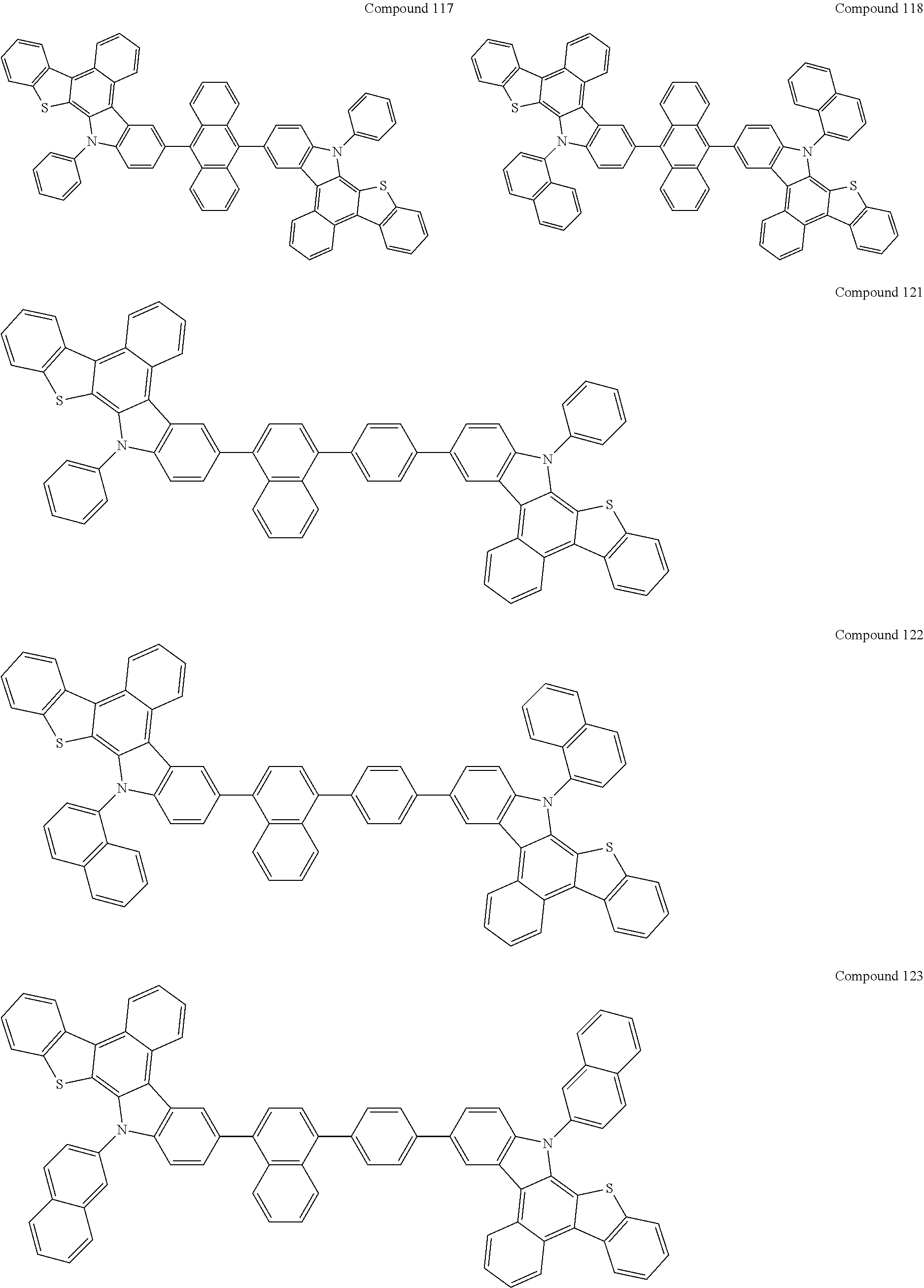

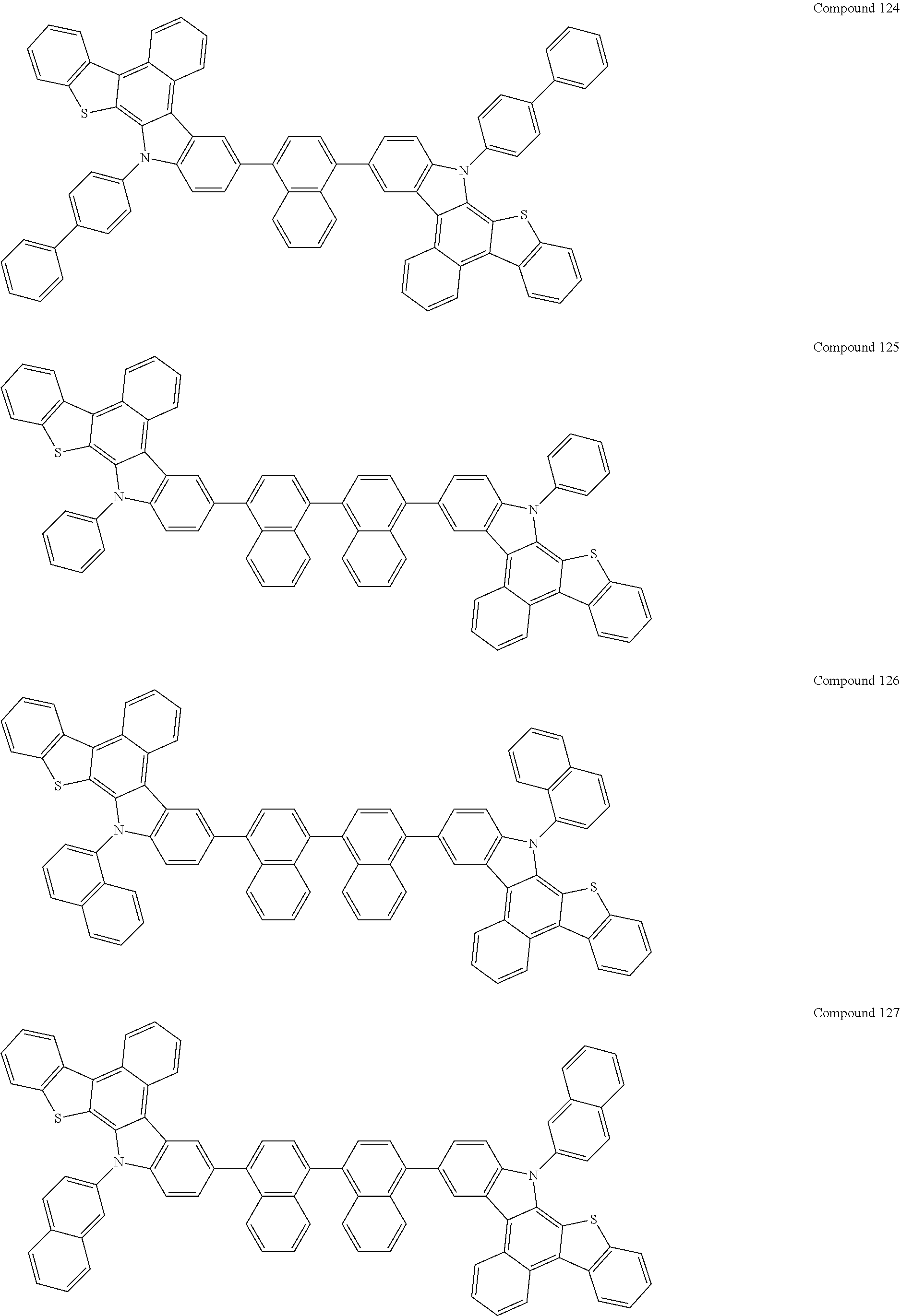

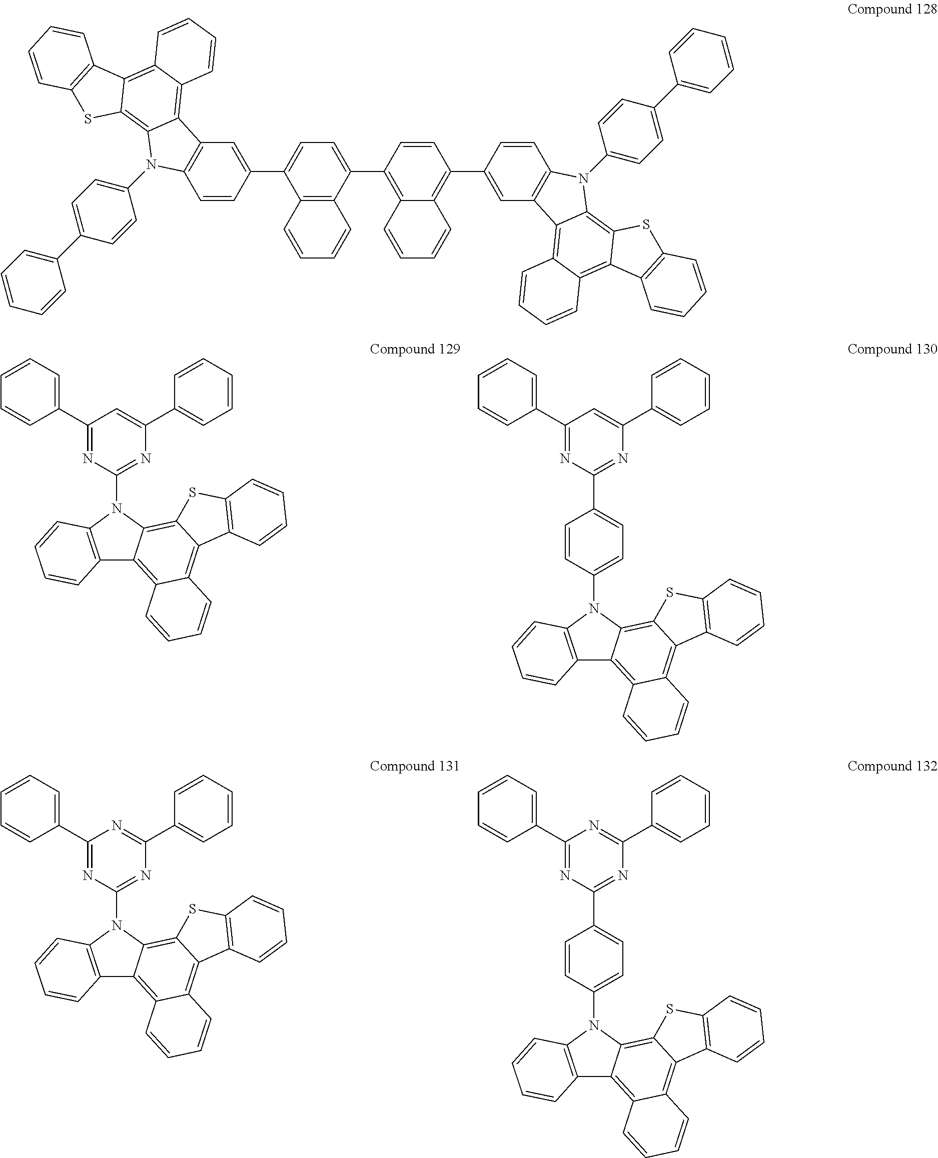

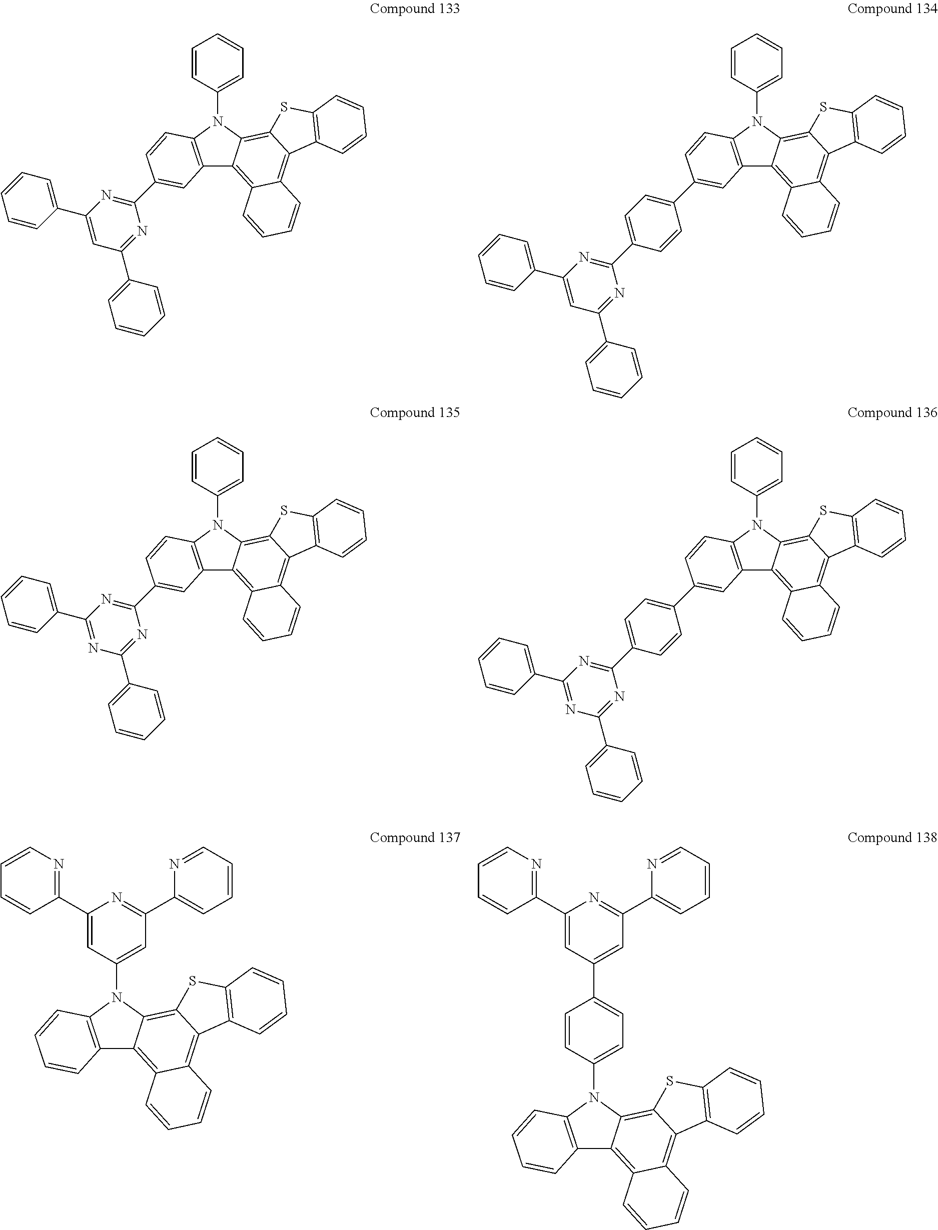

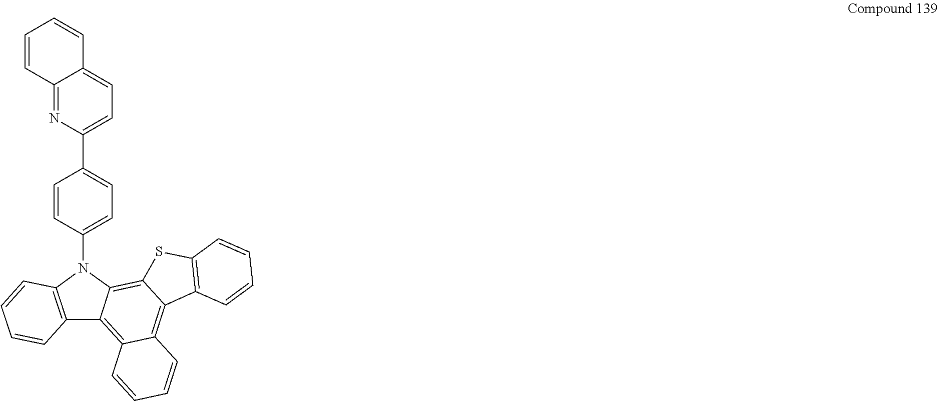 [SMILES: c1ccc2nc(-c3ccc(-n4c5ccccc5c5c6ccccc6c6c7ccccc7sc6c54)cc3)ccc2c1]

13. The organic light emitting device as claimed in claim 1, wherein the emission layer emits red light.

14. The organic light emitting device as claimed in claim 1, wherein the hole transport region includes:
a hole injection layer; and
a hole transport layer on the hole injection layer.

15. The organic light emitting device as claimed in claim 1, wherein the electron transport region includes:
an electron transport layer; and
an electron injection layer on the electron transport layer.

16. A display device comprising a plurality of pixels, wherein one of the pixels includes:
an anode;
a hole transport region on the anode;
an emission layer provided on the hole transport region, the emission layer including a first host and a dopant;
a first host layer on the emission layer, the first host layer including a second host;
an electron transport region on the first host layer; and
a cathode on the electron transport region,
wherein the second host is represented by the following Formula 1: 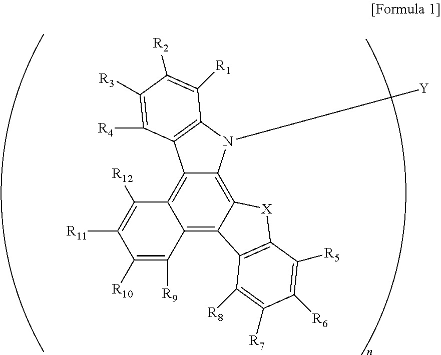
wherein, in Formula 1,
R₁, R₂, R₃, R₄, R₅, R₆, R₇, R₈, R₉, R₁₀, R₁₁, and R₁₂ are each independently a hydrogen atom, a halogen atom, a cyano group, an alkoxy group, a thiol group, a substituted or unsubstituted alkyl group having 1 to 50 carbon atoms, a substituted or unsubstituted alkoxy group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphorus, or silicon, a substituted or unsubstituted heteroaryl group having 5 to 60 carbon atoms and including at least one of sulfur, nitrogen, oxygen, phosphorus, or silicon, or a substituted or unsubstituted heteroaryloxy group having 5 to 60 carbon atoms and including at least one of sulfur, nitrogen, oxygen, phosphorus, or silicon,
R₁, R₂, R₃, R₄, R₅, R₆, R₇, R₈, R₉, R₁₀, R₁₁, and R₁₂ are separate or adjacent ones thereof are combined to form a ring
X is sulfur, oxygen, or silicon,
Y is a hydrogen atom, a halogen atom, a cyano group, an alkoxy group, a thiol group, a substituted or unsubstituted alkyl group having 1 to 50 carbon atoms, a substituted or unsubstituted alkenyl group having 1 to 50 carbon atoms, a substituted or unsubstituted arylene group having 5 to 60 carbon atoms, a substituted or unsubstituted aryl group having 5 to 60 carbon atoms, a substituted or unsubstituted aryloxy group having 5 to 60 carbon atoms, a substituted or unsubstituted alkyl group having 1 to 50 carbon atoms and including at least one of sulfur, nitrogen, oxygen, phosphorus, or silicon, a substituted or unsubstituted heteroaryl group having 5 to 60 carbon atoms and including at least one of sulfur, nitrogen, oxygen, phosphorus, or silicon, or a substituted or unsubstituted heteroaryloxy group having 5 to 60 carbon atoms and including at least one of sulfur, nitrogen, oxygen, phosphorus, or silicon, and
n is an integer of 1 to 3.

17. The display device as claimed in claim 16, wherein the first host layer does not include the dopant.

18. The display device as claimed in claim 16, wherein the second host includes one of the following Compounds 1 to 57, 59 to 71, 74 to 114, and 117 to 139:

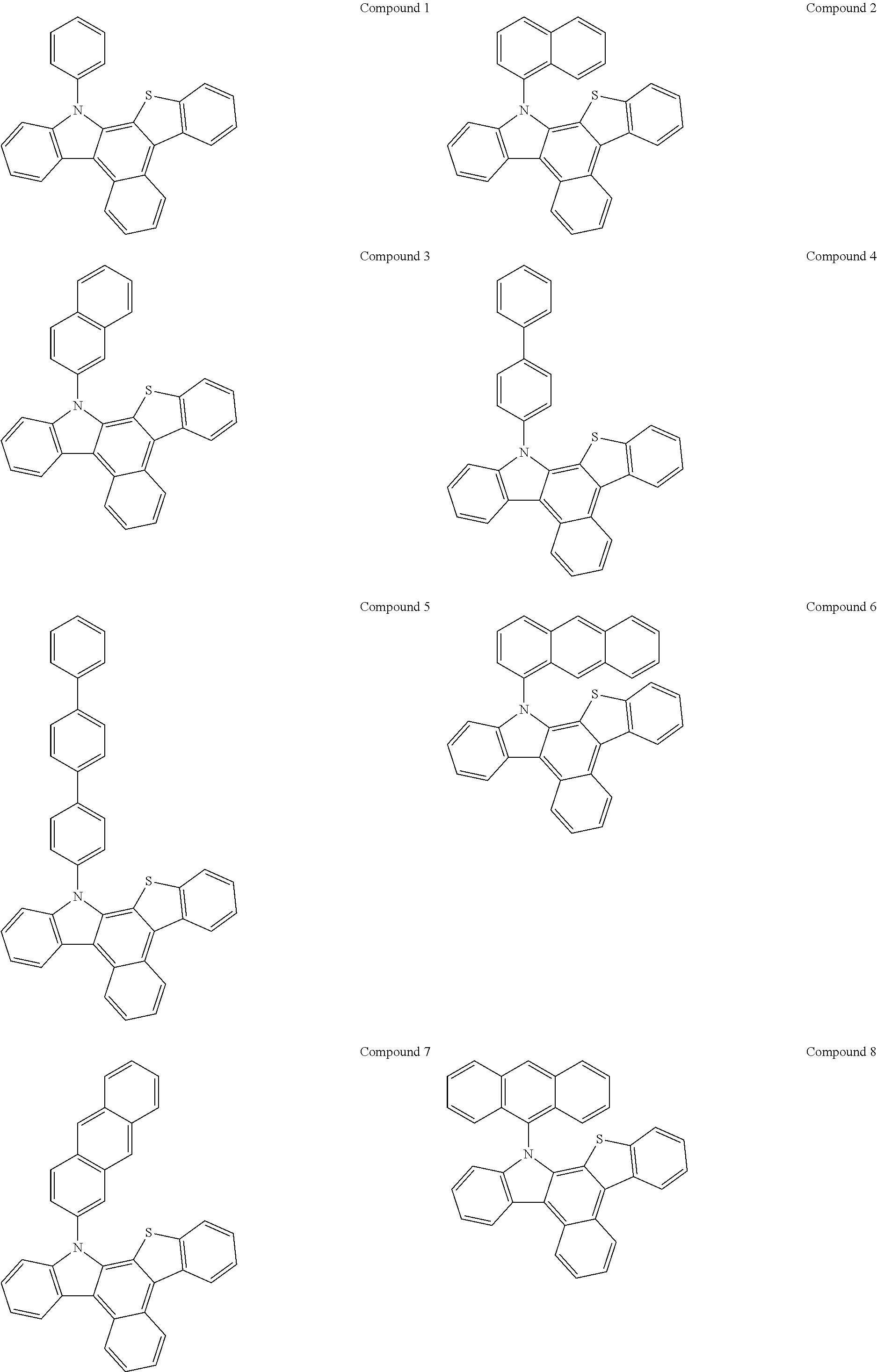

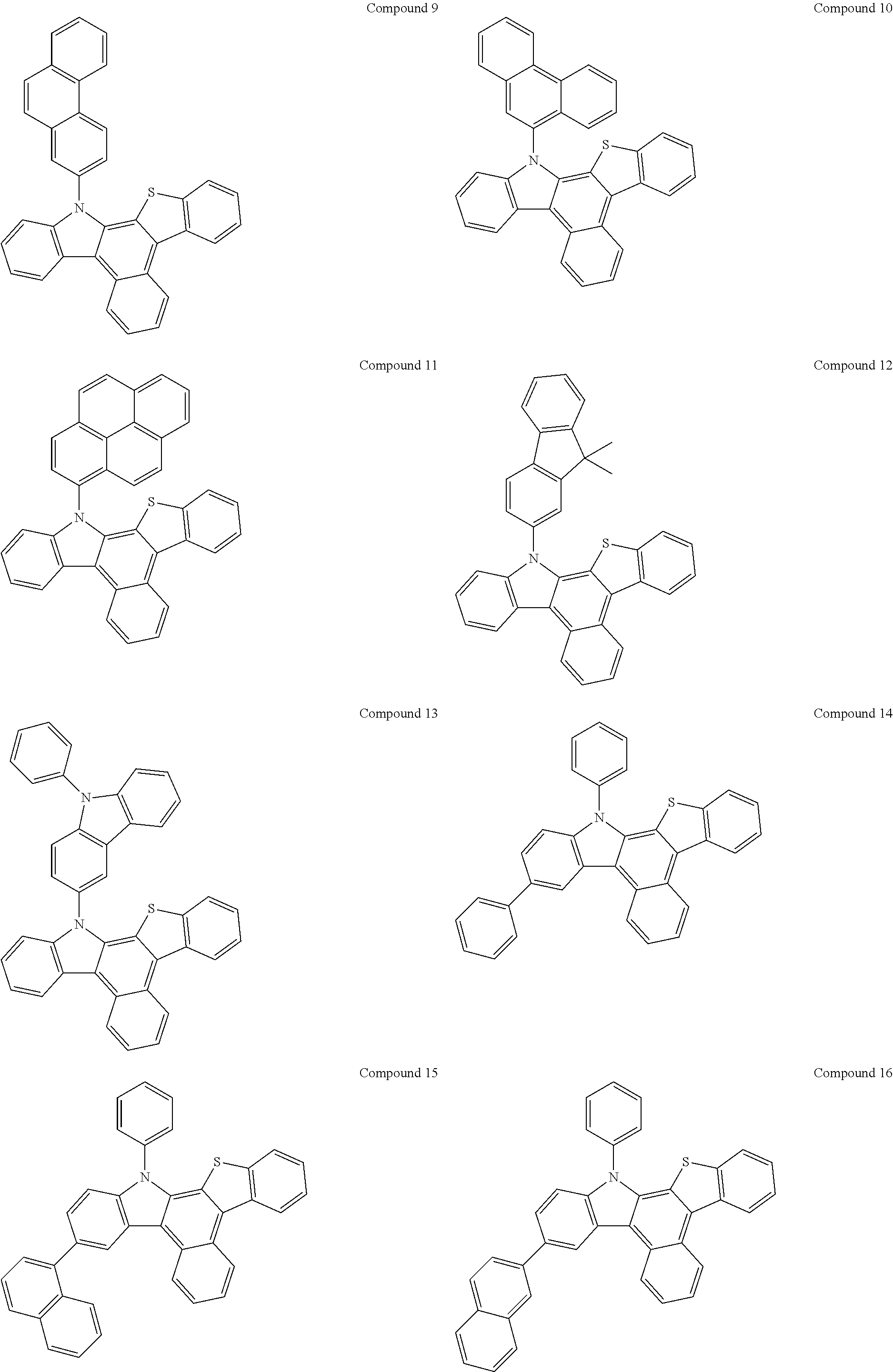

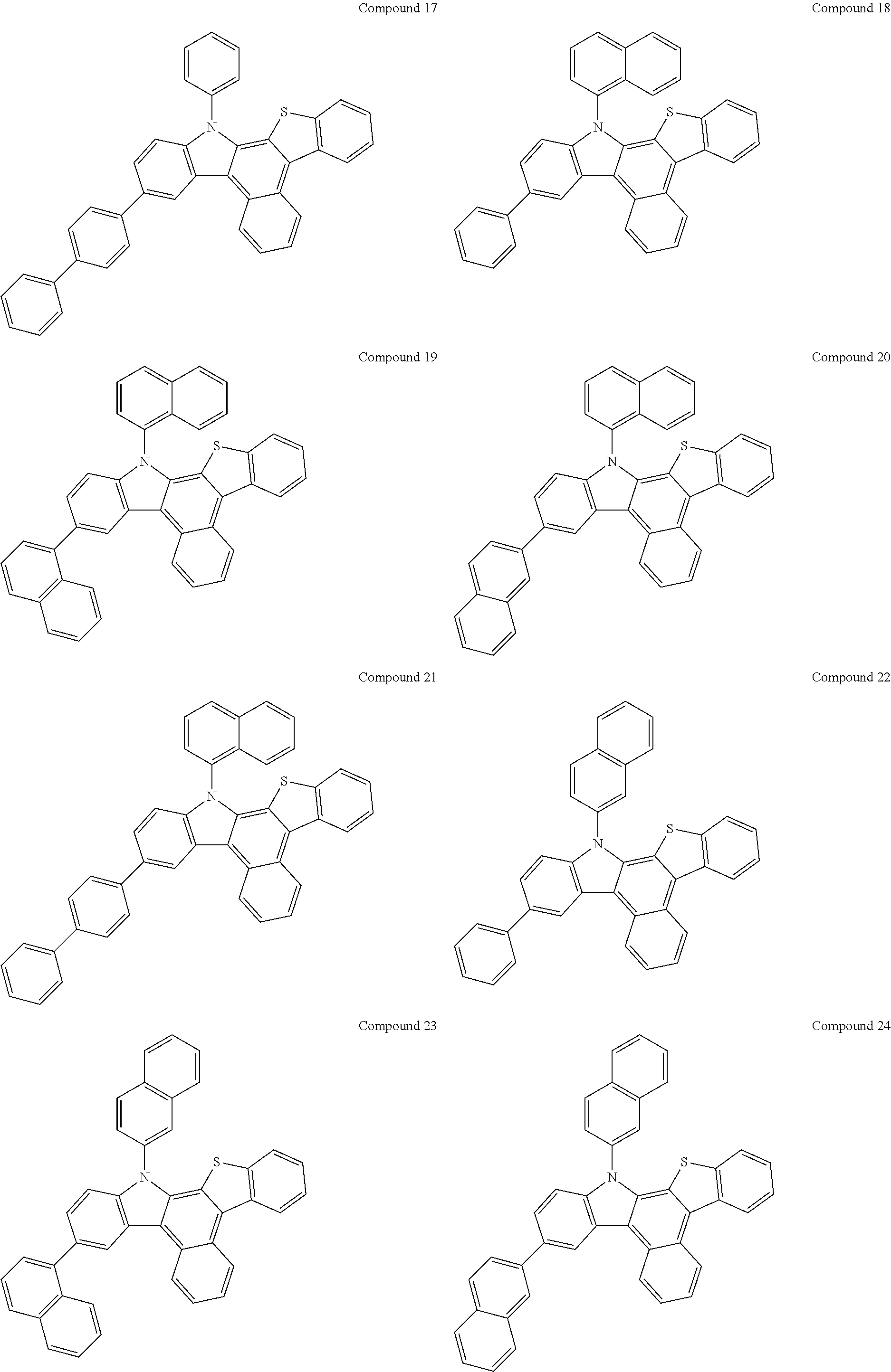

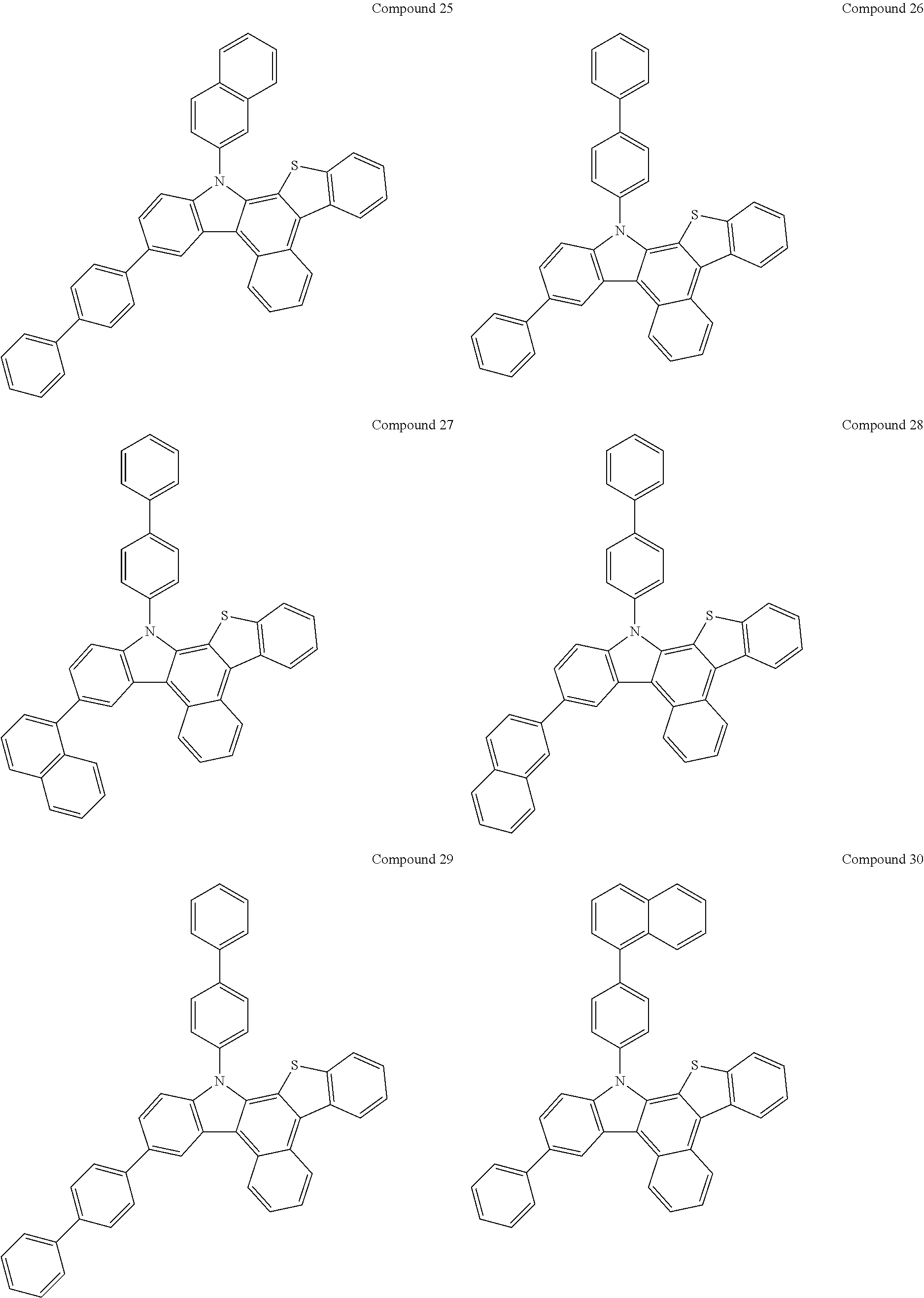 [SMILES: c1ccc(-c2ccc(-c3ccc4c(c3)c3c5ccccc5c5c6ccccc6sc5c3n4-c3ccc4ccccc4c3)cc2)cc1 ; c1ccc(-c2ccc(-n3c4ccc(-c5ccccc5)cc4c4c5ccccc5c5c6ccccc6sc5c43)cc2)cc1 ; c1ccc(-c2ccc(-n3c4ccc(-c5cccc6ccccc56)cc4c4c5ccccc5c5c6ccccc6sc5c43)cc2)cc1 ; c1ccc(-c2ccc(-n3c4ccc(-c5ccc6ccccc6c5)cc4c4c5ccccc5c5c6ccccc6sc5c43)cc2)cc1 ; c1ccc(-c2ccc(-c3ccc4c(c3)c3c5ccccc5c5c6ccccc6sc5c3n4-c3ccc(-c4ccccc4)cc3)cc2)cc1 ; c1ccc(-c2ccc3c(c2)c2c4ccccc4c4c5ccccc5sc4c2n3-c2ccc(-c3cccc4ccccc34)cc2)cc1]

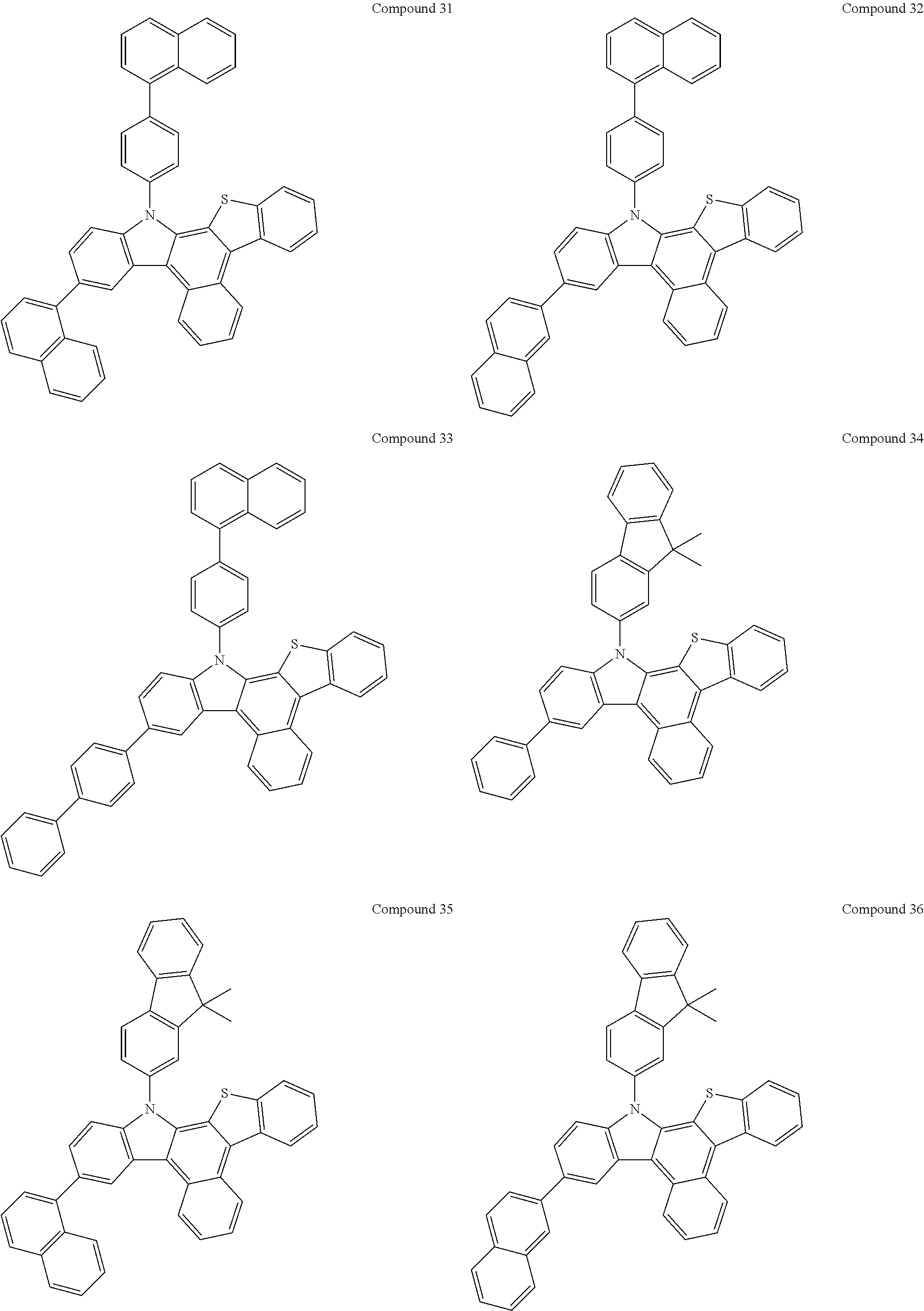 [SMILES: c1ccc2c(-c3ccc(-n4c5ccc(-c6cccc7ccccc67)cc5c5c6ccccc6c6c7ccccc7sc6c54)cc3)cccc2c1 ; c1ccc2cc(-c3ccc4c(c3)c3c5ccccc5c5c6ccccc6sc5c3n4-c3ccc(-c4cccc5ccccc45)cc3)ccc2c1 ; c1ccc(-c2ccc(-c3ccc4c(c3)c3c5ccccc5c5c6ccccc6sc5c3n4-c3ccc(-c4cccc5ccccc45)cc3)cc2)cc1 ; CC1(C)c2ccccc2-c2ccc(-n3c4ccc(-c5ccccc5)cc4c4c5ccccc5c5c6ccccc6sc5c43)cc21 ; CC1(C)c2ccccc2-c2ccc(-n3c4ccc(-c5cccc6ccccc56)cc4c4c5ccccc5c5c6ccccc6sc5c43)cc21 ; CC1(C)c2ccccc2-c2ccc(-n3c4ccc(-c5ccc6ccccc6c5)cc4c4c5ccccc5c5c6ccccc6sc5c43)cc21]

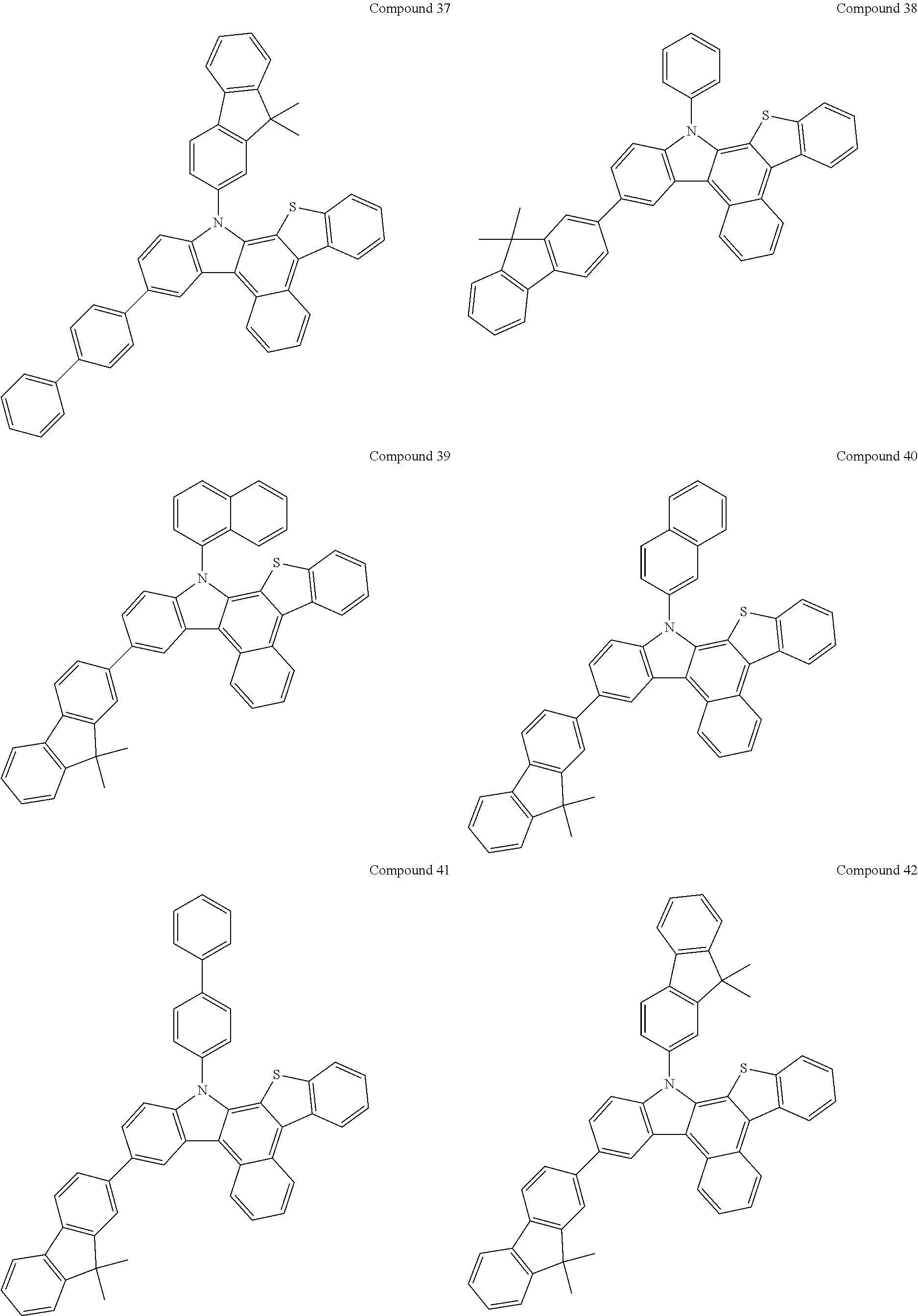

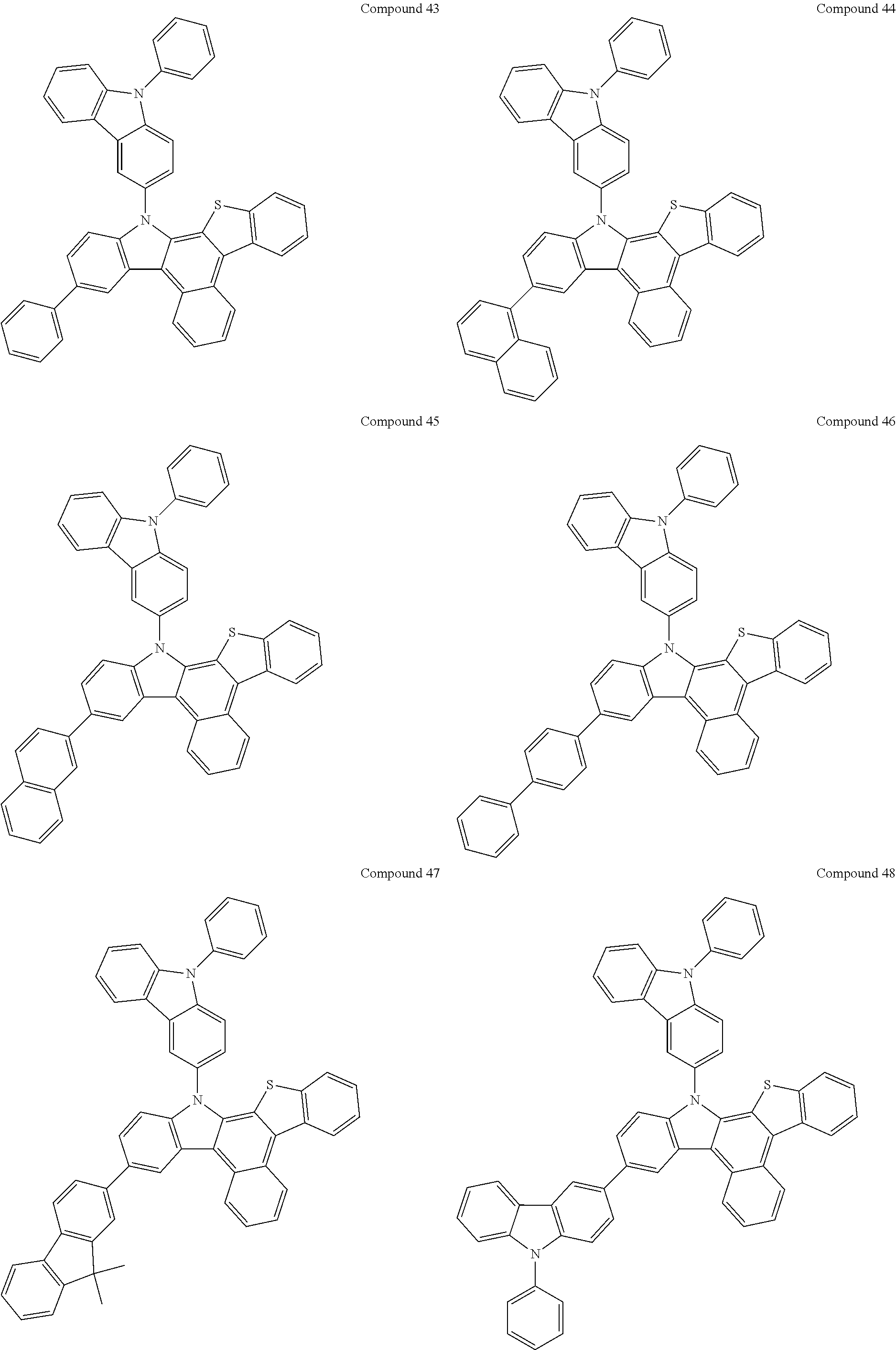

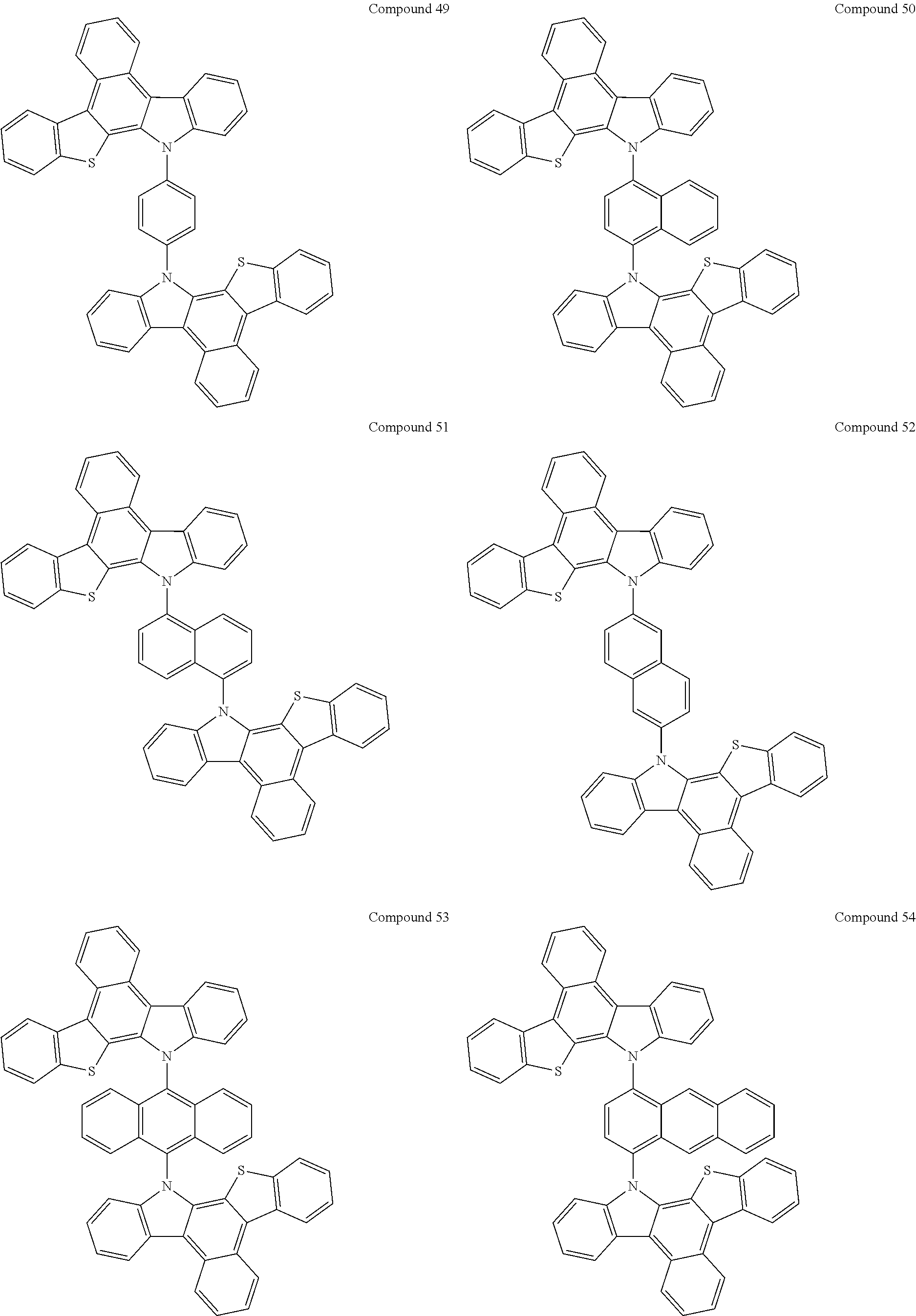

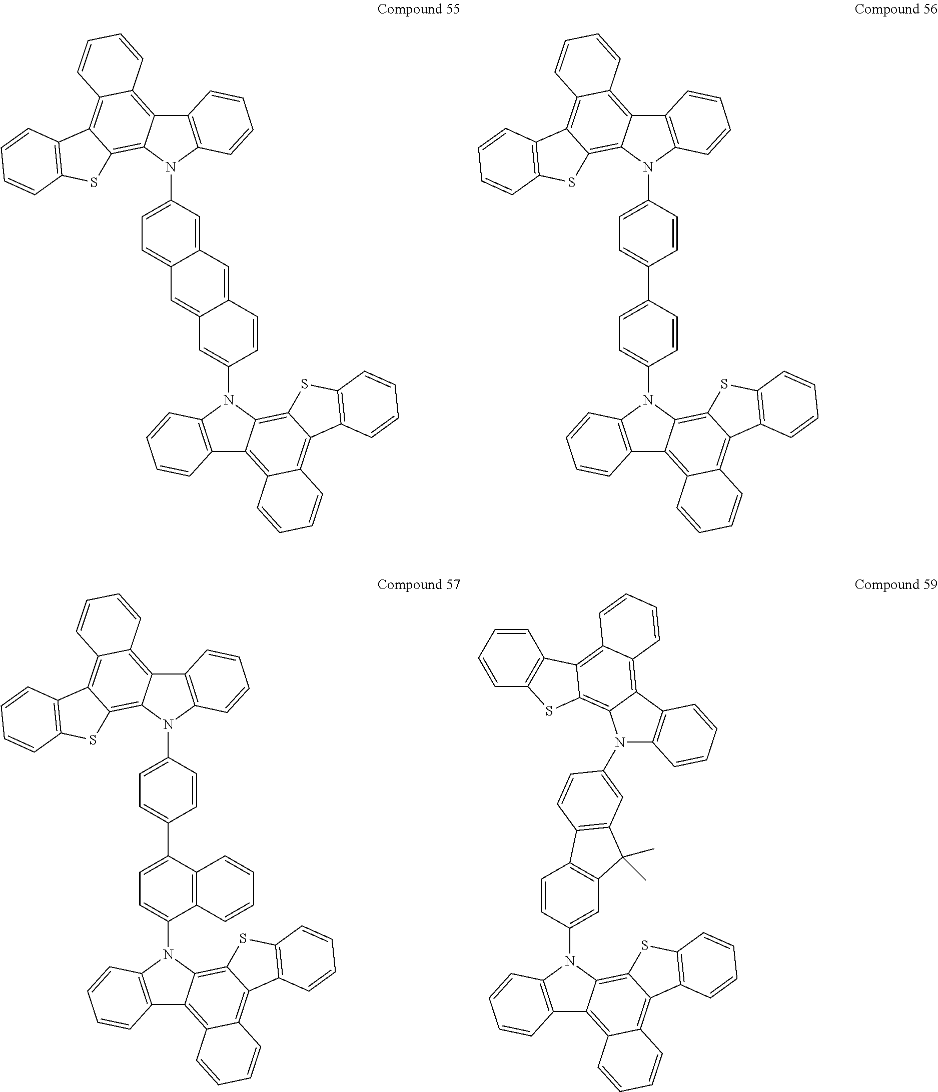 [SMILES: c1ccc2c(c1)sc1c2c2ccccc2c2c3ccccc3n(-c3ccc4cc5cc(-n6c7ccccc7c7c8ccccc8c8c9ccccc9sc8c76)ccc5cc4c3)c12 ; c1ccc2c(c1)sc1c2c2ccccc2c2c3ccccc3n(-c3ccc(-c4ccc(-n5c6ccccc6c6c7ccccc7c7c8ccccc8sc7c65)cc4)cc3)c12 ; c1ccc2c(c1)sc1c2c2ccccc2c2c3ccccc3n(-c3ccc(-c4ccc(-n5c6ccccc6c6c7ccccc7c7c8ccccc8sc7c65)c5ccccc45)cc3)c12 ; CC1(C)c2cc(-n3c4ccccc4c4c5ccccc5c5c6ccccc6sc5c43)ccc2-c2ccc(-n3c4ccccc4c4c5ccccc5c5c6ccccc6sc5c43)cc21]

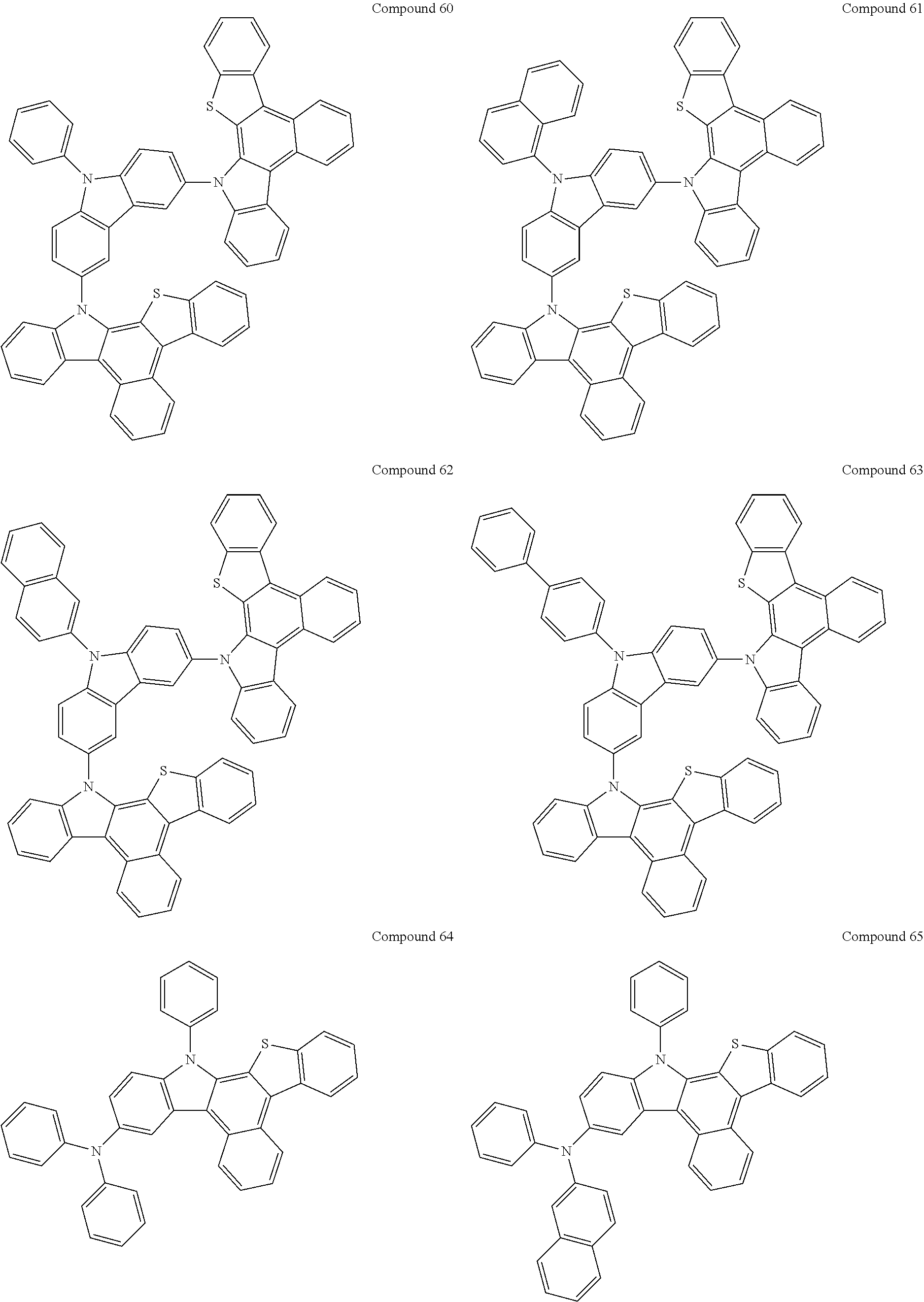

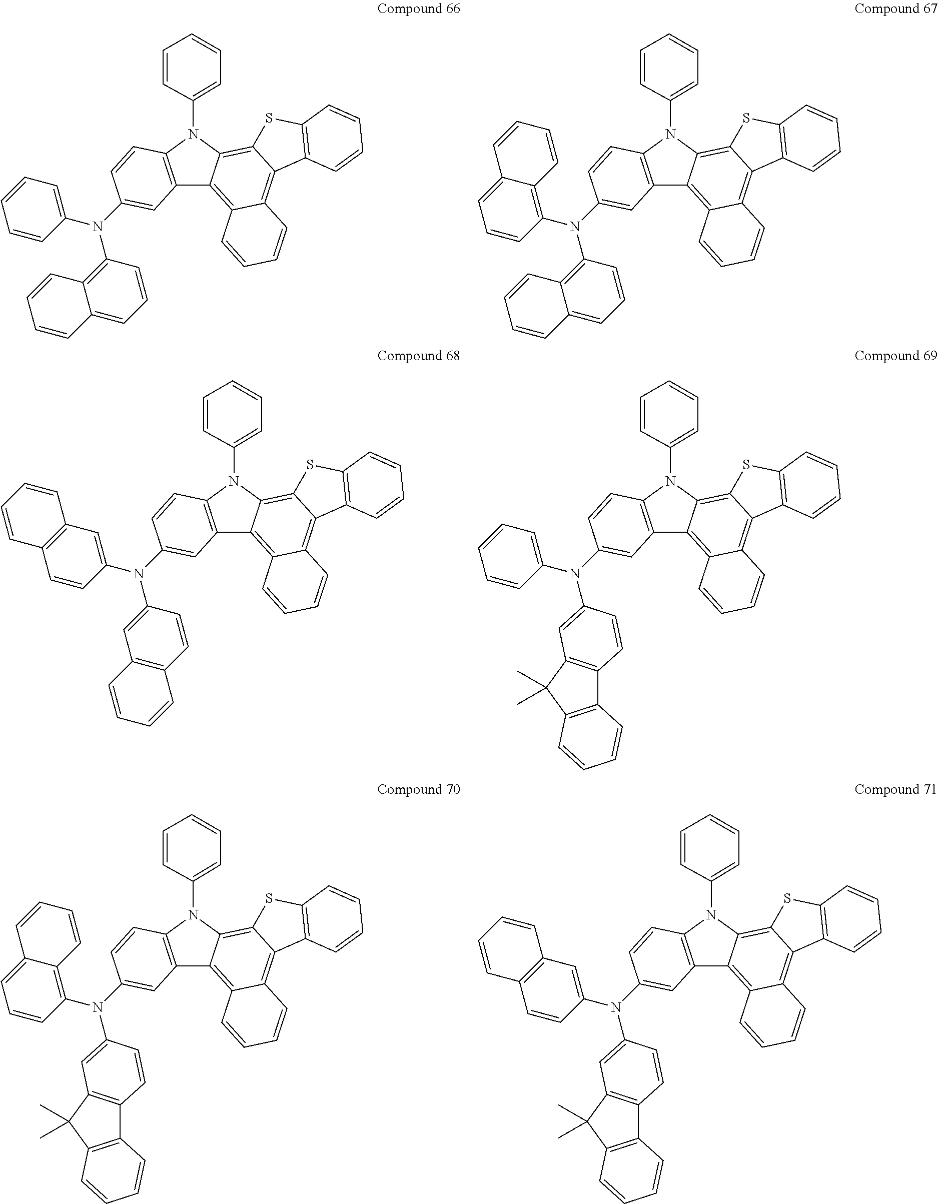

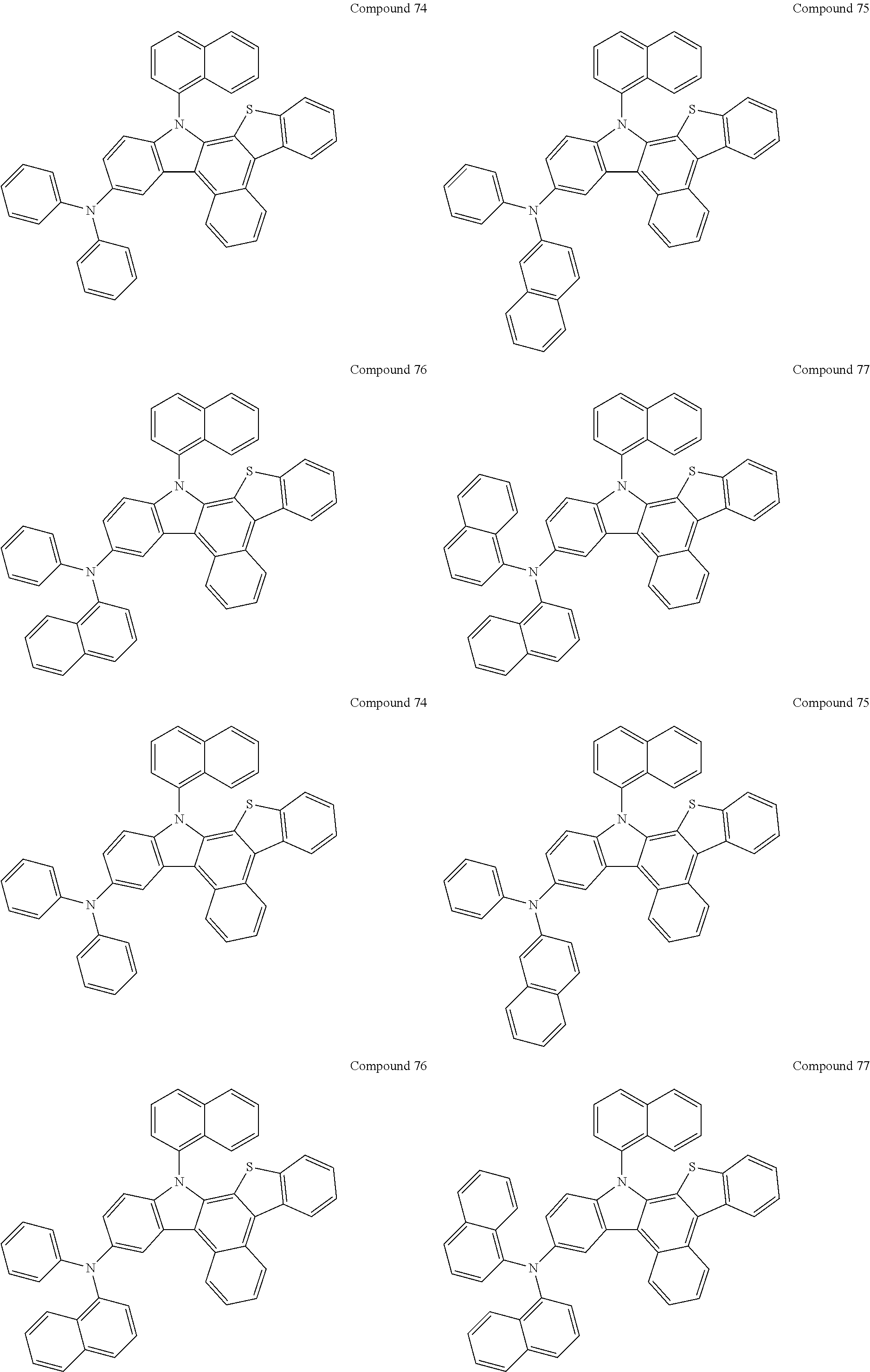

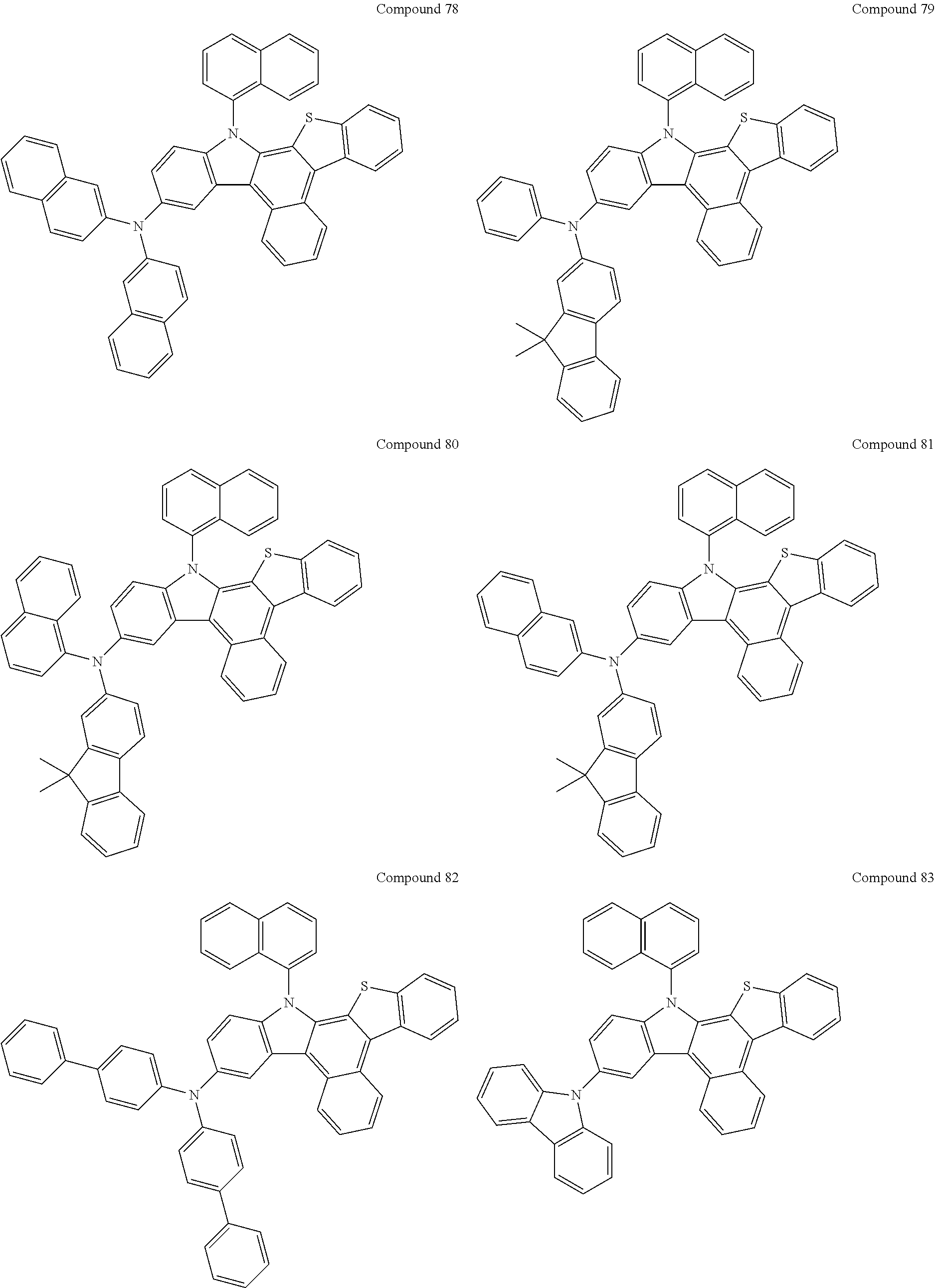

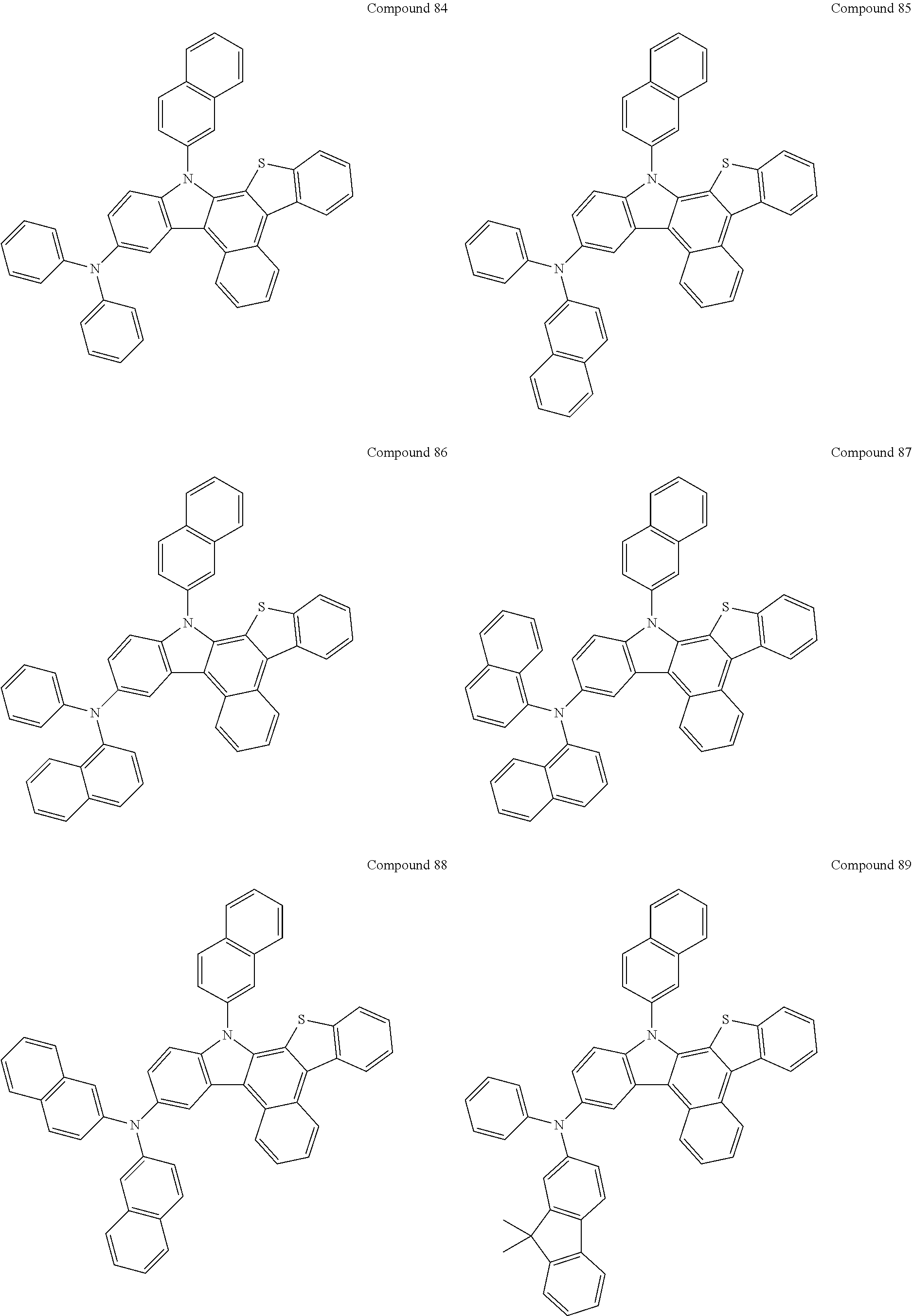

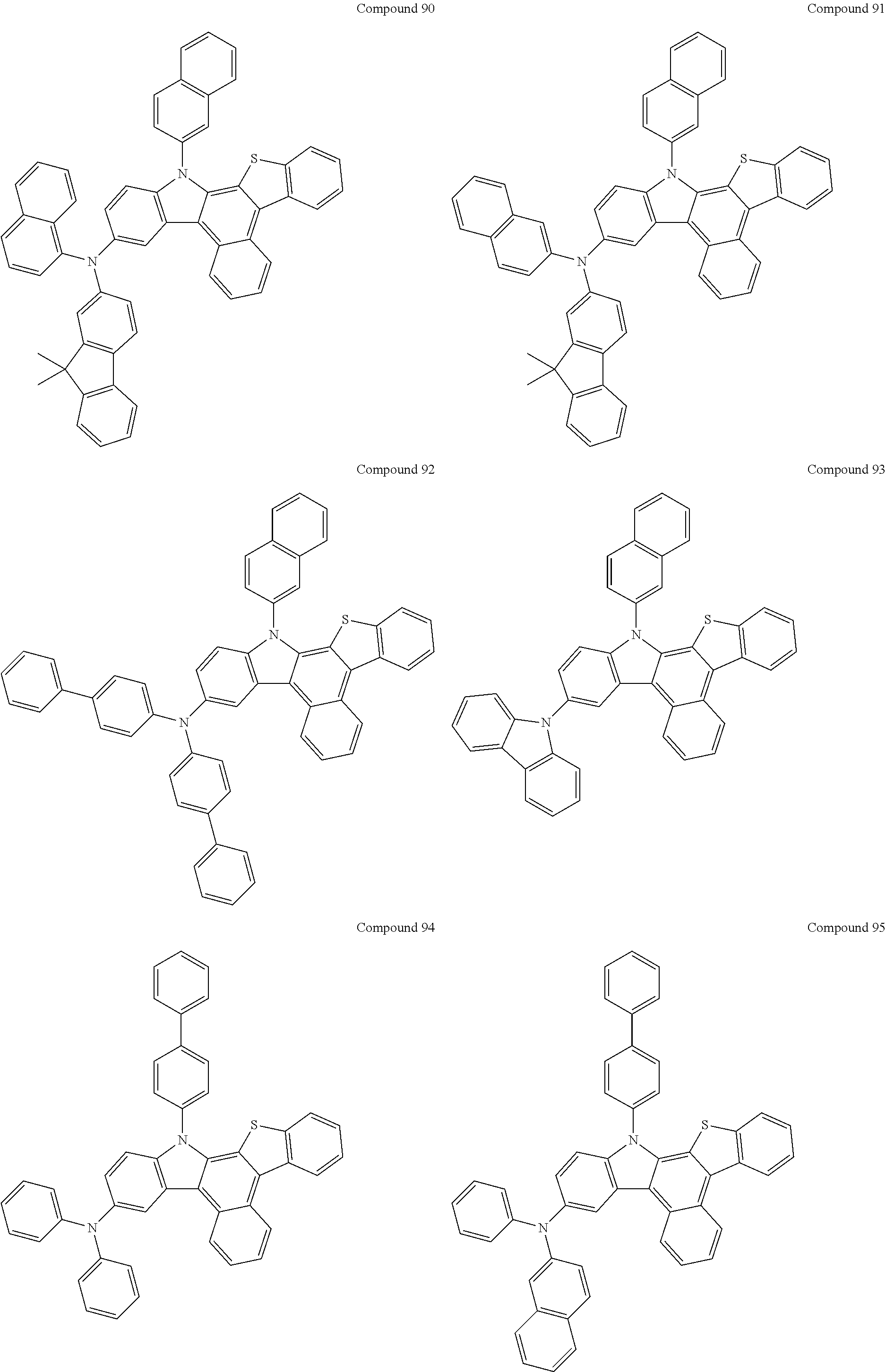

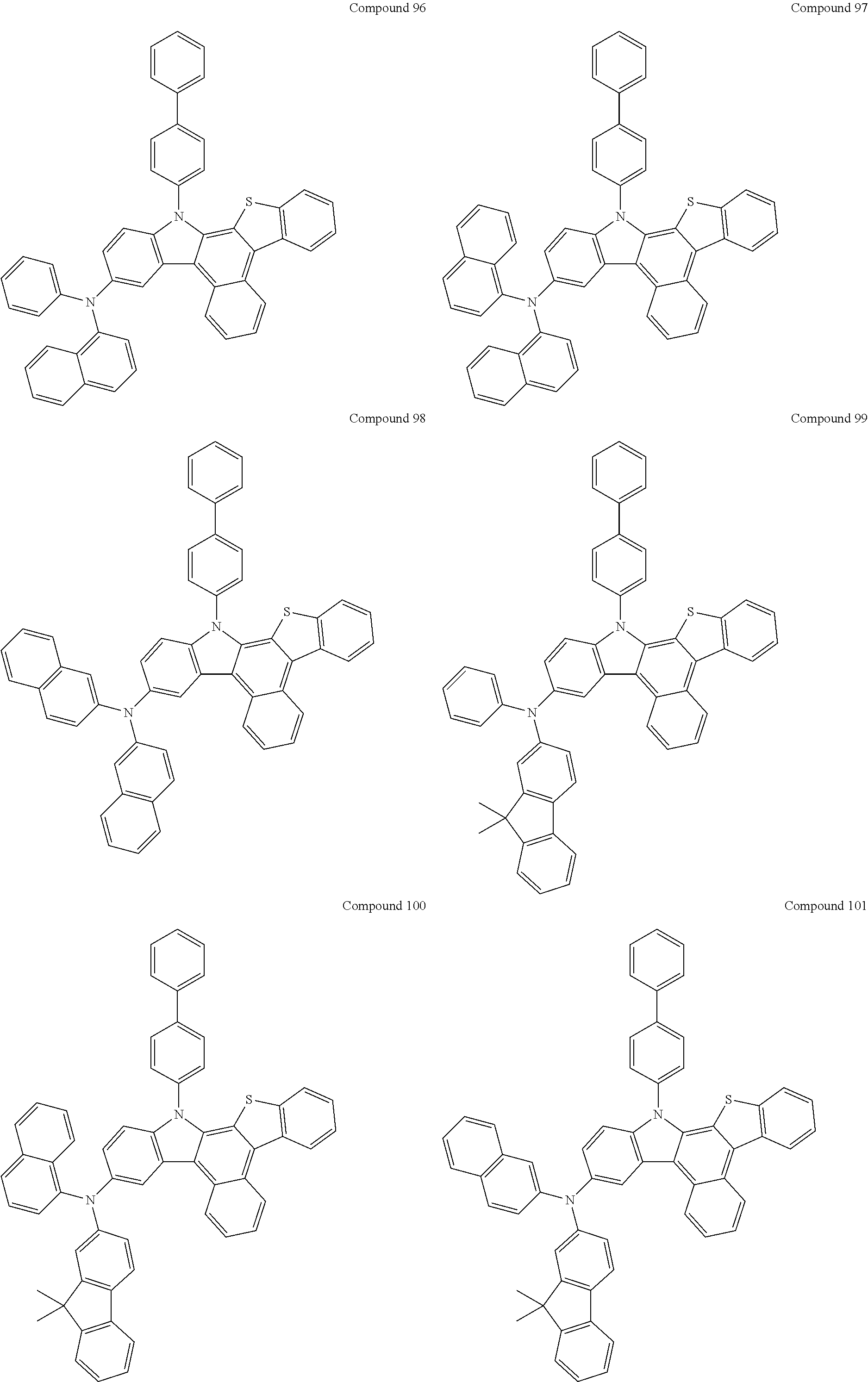

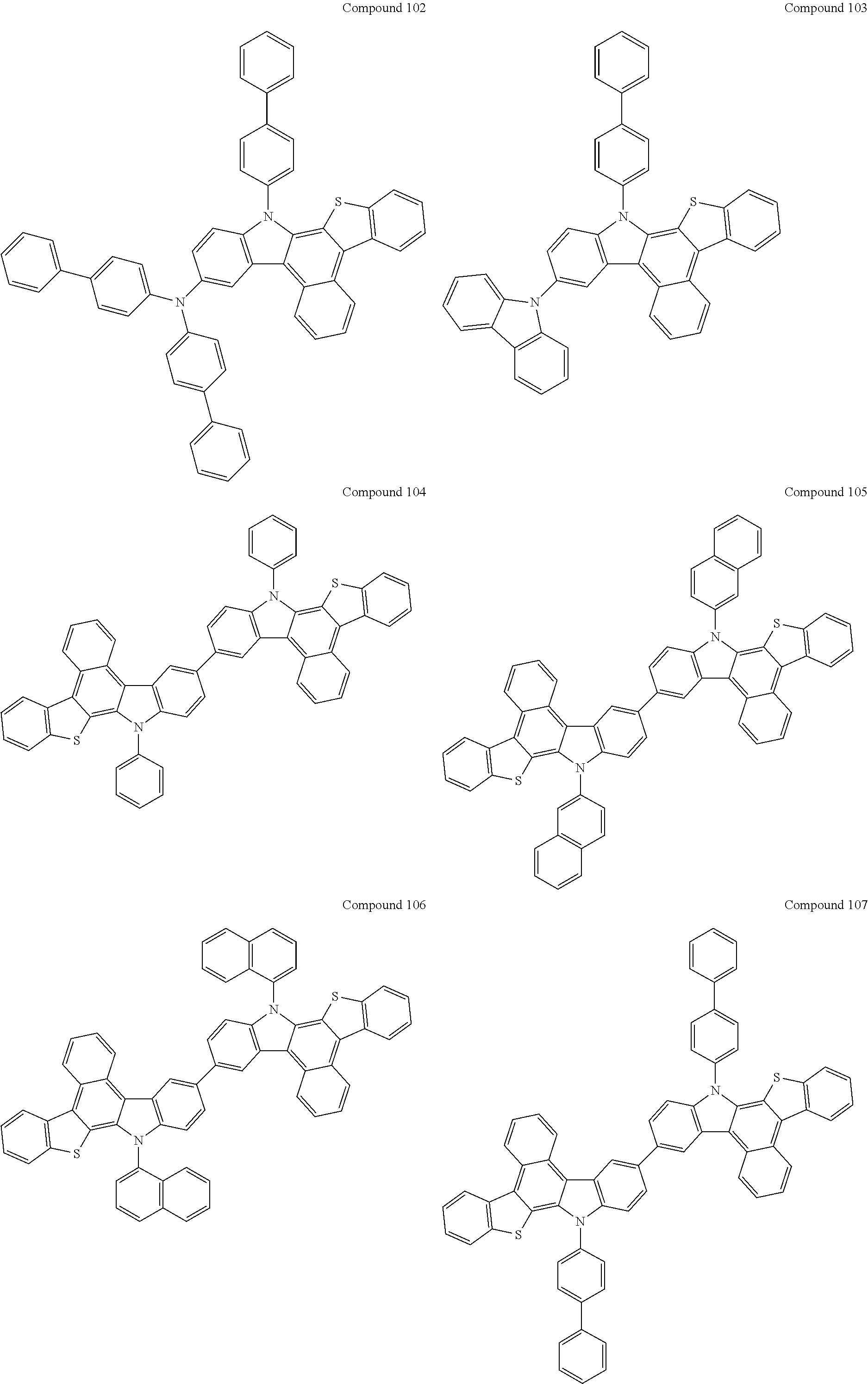

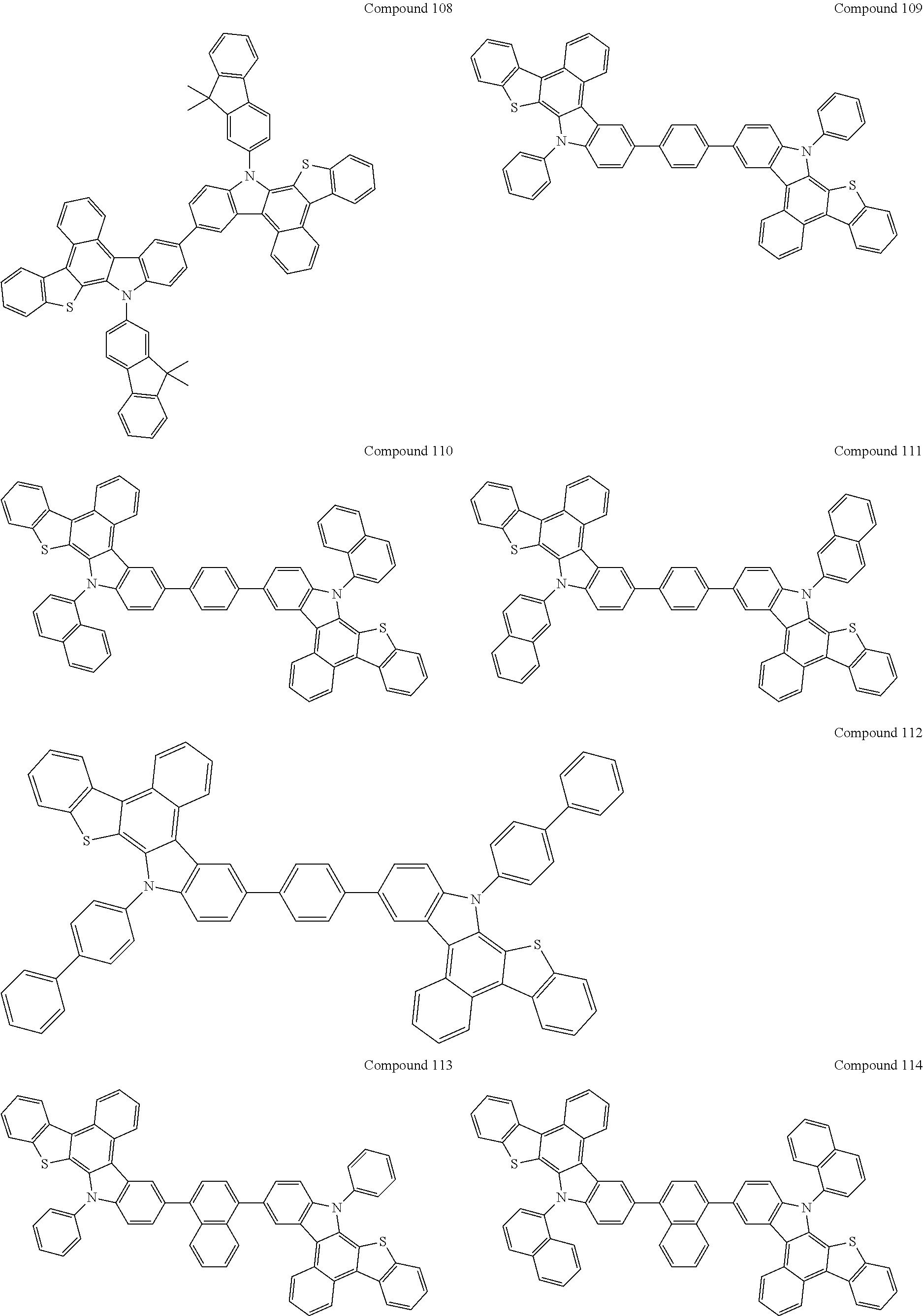

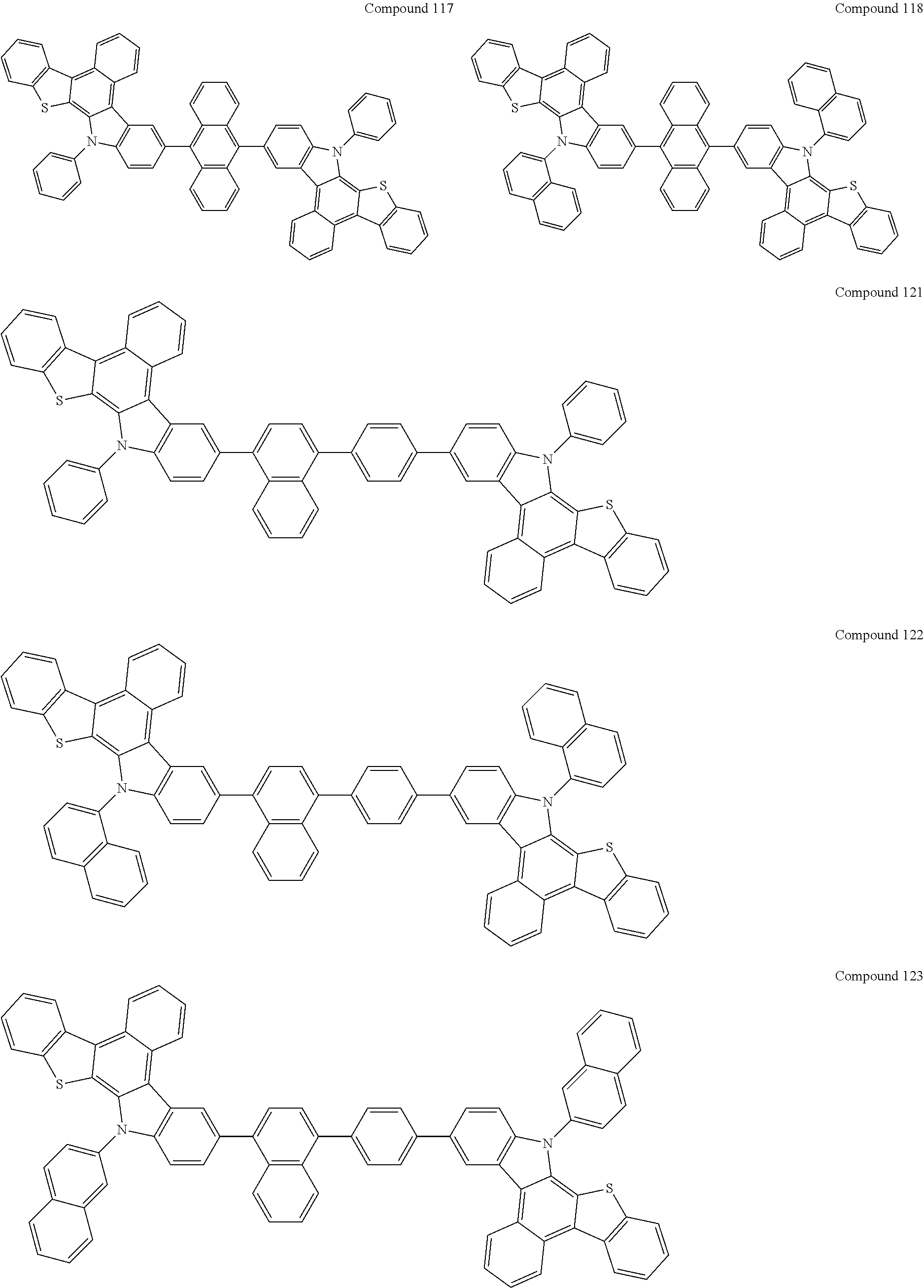

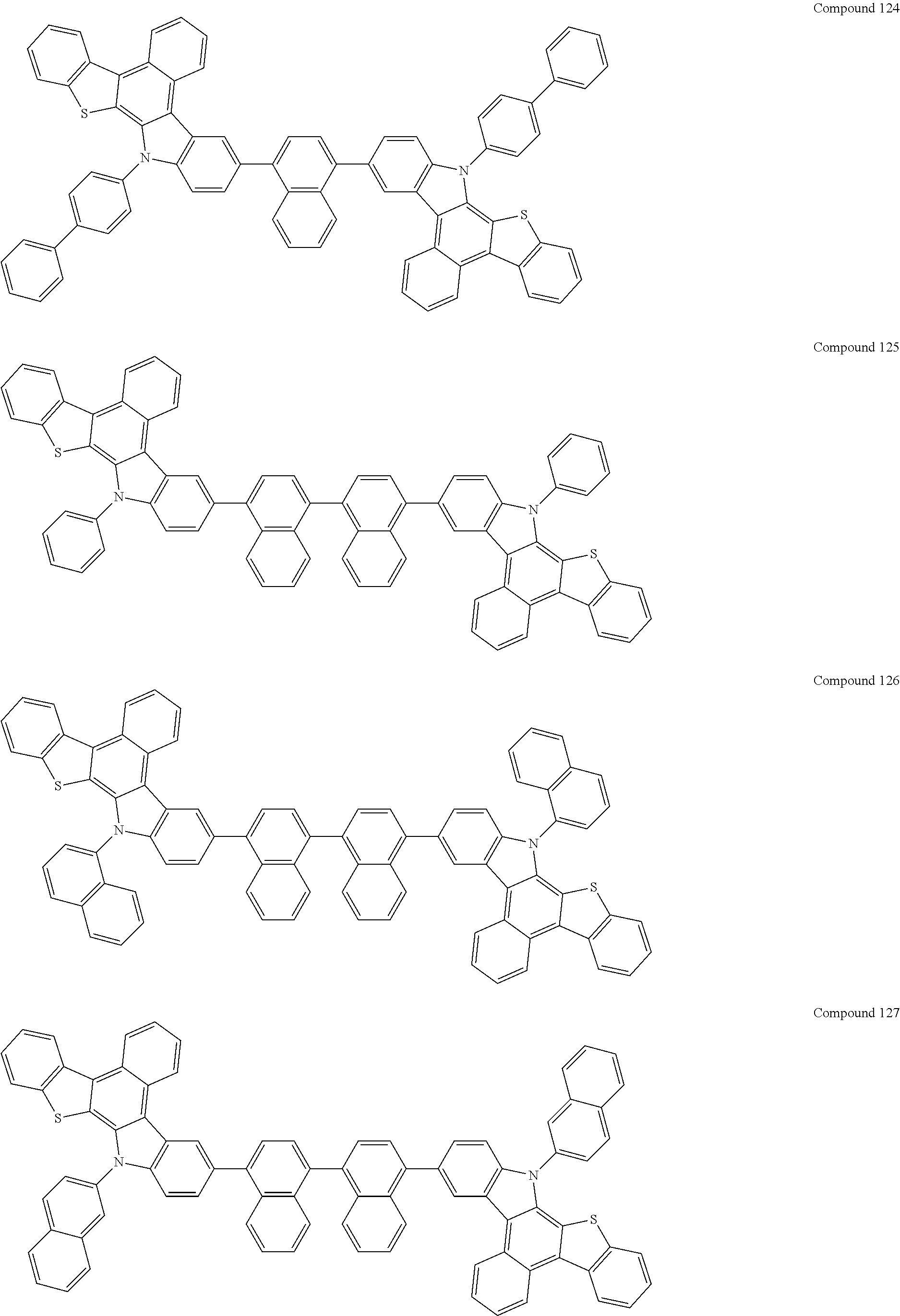

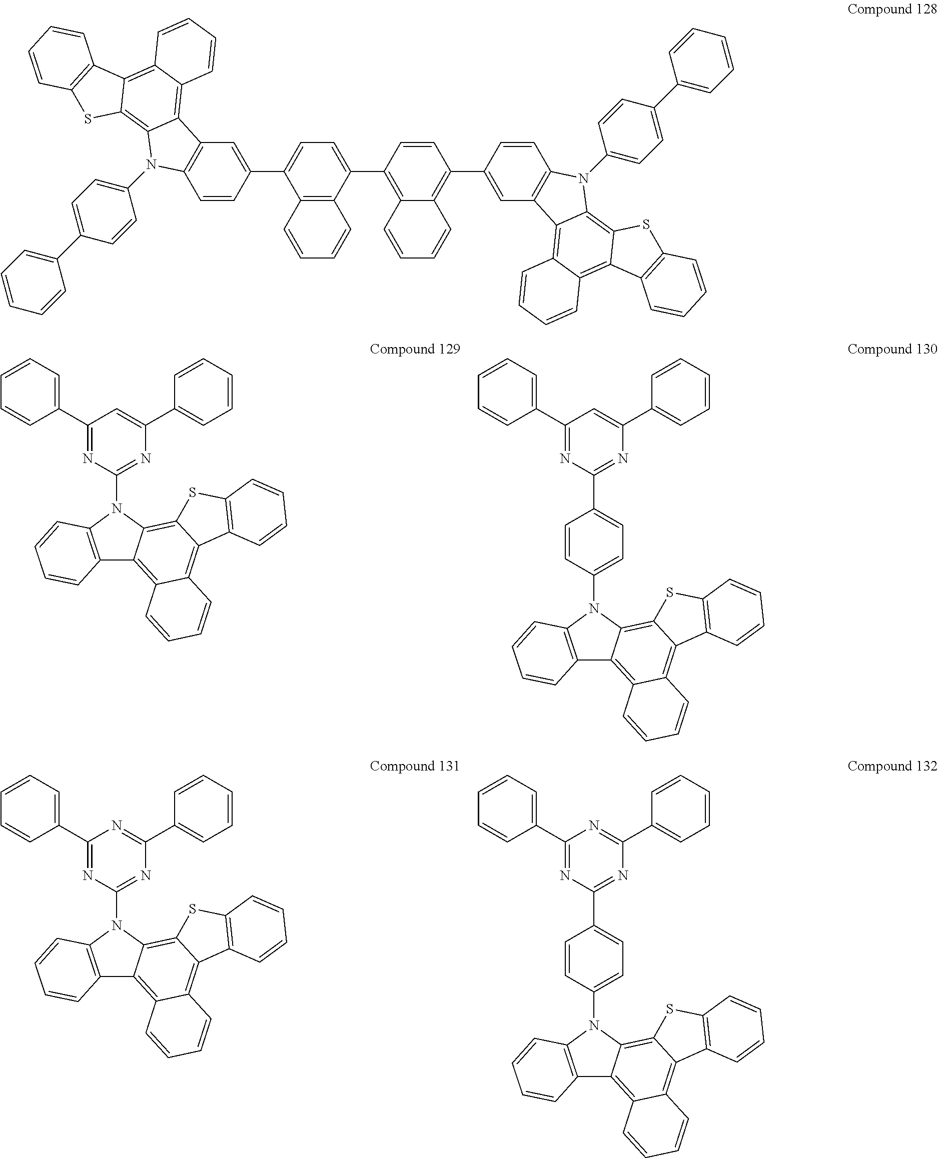

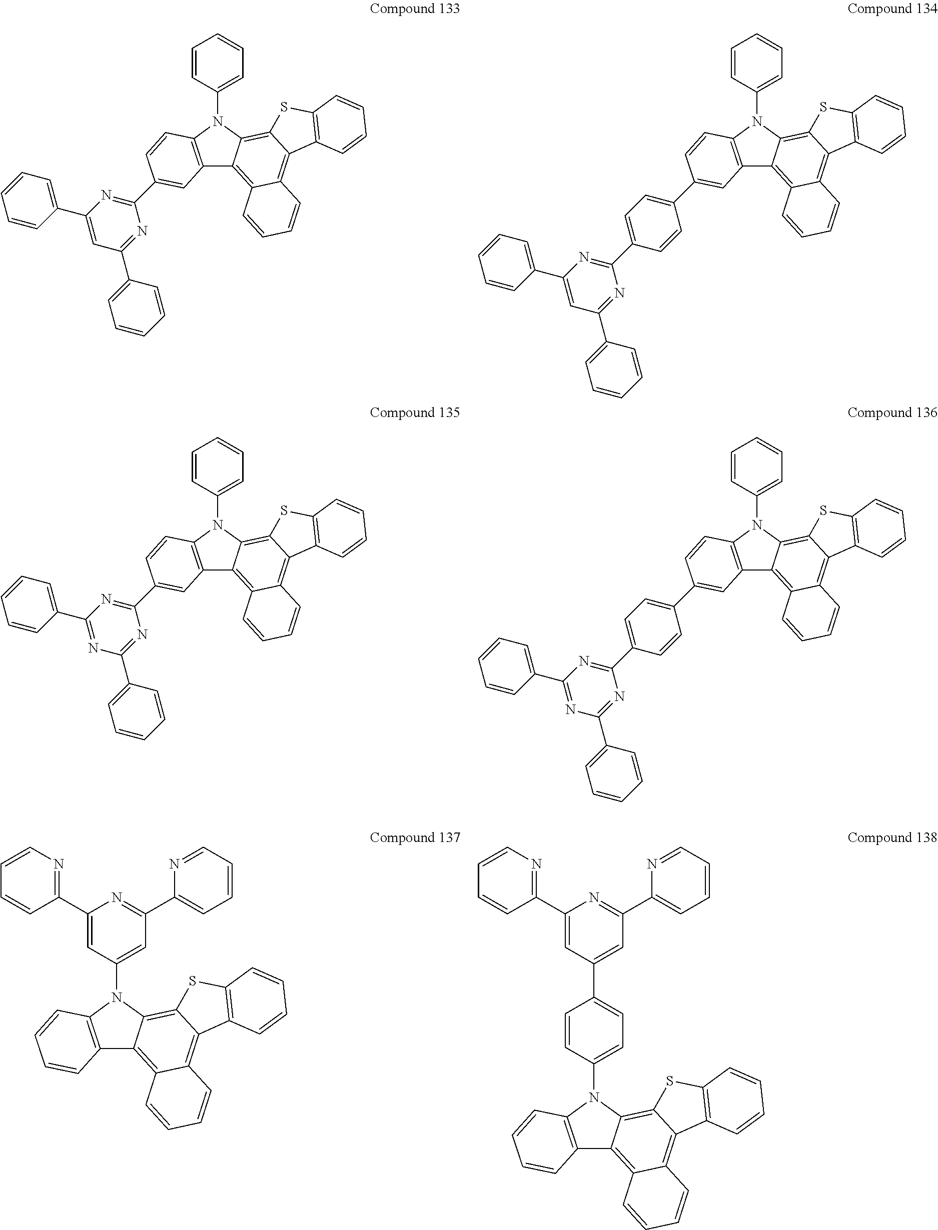

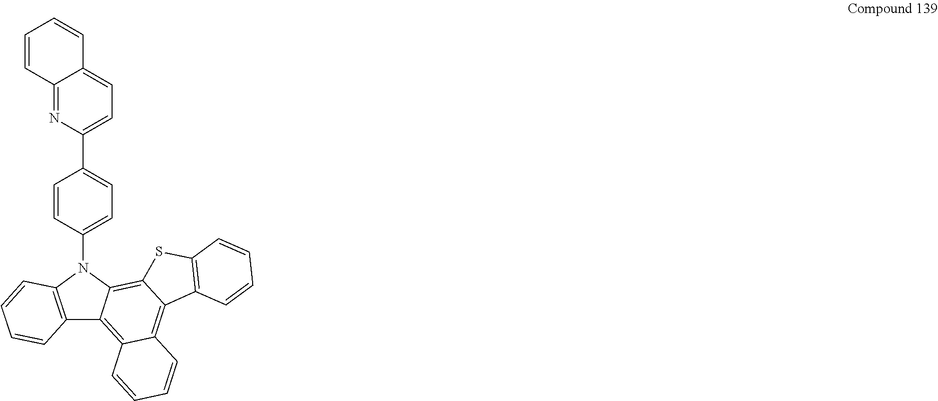 [SMILES: c1ccc2nc(-c3ccc(-n4c5ccccc5c5c6ccccc6c6c7ccccc7sc6c54)cc3)ccc2c1]

19. The display device as claimed in claim 16, further comprising a second host layer between the hole transport region and the emission layer, the second host layer including a third host, wherein the third host is represented by Formula 1.

20. The display device as claimed in claim 19, wherein:
the emission layer includes:
a first sub emission layer that includes the first host and the dopant;
a third host layer on the first sub emission layer, the third host layer including a fourth host; and
a second sub emission layer on the third host layer, the second sub emission layer including the first host and the dopant, and
the fourth host is represented by Formula 1.
